(19) United States
(12) Patent Application Publication
(10) Pub. No.: US 2020/0035922 A1
(43) Pub. Date: Jan. 30, 2020

(54) ORGANIC ELECTROLUMINESCENCE ELEMENT AND ELECTRONIC DEVICE

(71) Applicant: IDEMITSU KOSAN CO., LTD., Chiyoda-ku (JP)

(72) Inventors: Toshinari OGIWARA, Sodegaura-shi (JP); Kei YOSHIZAKI, Sodegaura-shi (JP); Masatoshi SAITO, Sodegaura-shi (JP); Yuichiro KAWAMURA, Sodegaura-shi (JP)

(73) Assignee: IDEMITSU KOSAN CO., LTD., Chiyoda-ku (JP)

(21) Appl. No.: 16/498,083

(22) PCT Filed: Mar. 26, 2018
(86) PCT No.: PCT/JP2018/012157

§ 371 Date: Sep. 26, 2019

(30) Foreign Application Priority Data
Mar. 31, 2017 (JP) 2017-072026

(51) Int. Cl. H01L 51/00; C09K 11/06

(52) U.S. Cl. CPC H01L 51/008; H01L 51/0072; H01L 51/5012; C09K 11/06; H01L 51/0094

(57) ABSTRACT

An organic electroluminescence device includes an anode, an emitting layer, and a cathode. The emitting layer contains a first compound and a second compound, the first compound being a thermally activated delayed fluorescent compound and represented by a formula (1) below, the second compound being a compound represented by a formula (2) below, a singlet energy S₁(M1) of the first compound and a singlet energy S₁(M2) of the second compound satisfying a relationship of a Numerical Formula 1 below.

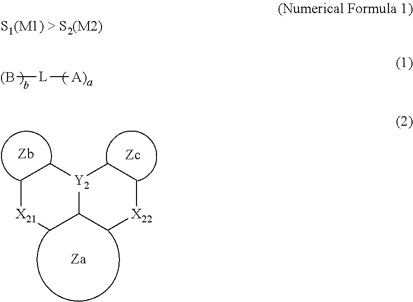

### TECHNICAL FIELD

The present invention relates to an organic electroluminescence device and an electronic device.

### BACKGROUND ART

When a voltage is applied to an organic electroluminescence device (hereinafter, occasionally referred to as “organic EL device”), holes and electrons are injected into an emitting layer from an anode and a cathode, respectively. The injected electrons and holes are recombined in an emitting layer to form excitons. According to the electron spin statistics theory, singlet excitons are generated at a ratio of 25% and triplet excitons are generated at a ratio of 75%.

A fluorescent organic EL device, which uses emission caused by singlet excitons, has been applied to a full-color display of a mobile phone, TV and the like, but is inferred to exhibit an internal quantum efficiency of 25% at the maximum. A fluorescent EL device is required to use triplet excitons in addition to singlet excitons to promote a further efficient emission from the organic EL device.

In view of the above, a highly efficient fluorescent organic EL device using delayed fluorescence has been studied.

For instance, a TADF (Thermally Activated Delayed Fluorescence) mechanism has been studied. The TADF mechanism uses such a phenomenon that inverse intersystem crossing from triplet excitons to singlet excitons thermally occurs when a material having a small energy difference (ΔST) between singlet energy level and triplet energy level is used. Delayed fluorescence (thermally activated delayed fluorescence) is explained in “Yuki Hando-tai no Debaisu Bussei (Device Physics of Organic Semiconductors)” (edited by ADACHI, Chihaya, published by Kodansha, issued on Apr. 1, 2012, on pages 261-262).

Polycyclic aromatic compounds and the like are known as materials for the organic EL device (Patent Literatures 1 to 3). A technique for using such polycyclic aromatic compounds in an organic EL device using the TADF mechanism has been developed (non-Patent Literature 1).

### CITATION LIST

### Patent Literature(S)

Patent Literature 1: International Publication No. WO2016/152544
Patent Literature 2: International Publication No. WO2016/152418
Patent Literature 3: International Publication No. WO2015/102118

### Non-Patent Literature

Non-Patent Literature 1: Ultrapure Blue Thermally Activated Delayed Fluorescence Molecules: Efficient HOMO-LUMO Separation by the Multiple Resonance Effect, Adv. Mater. 2016, 28, 2777-2781.

### SUMMARY OF THE INVENTION

### Problems to be Solved by the Invention

However, the luminous efficiency of the organic EL device is disadvantageously decreased in a high-current-density area at or around 10 mA/cm² (i.e. a practical area).

An object of the invention is to provide an organic electroluminescence device capable of emitting light with high efficiency and an electronic device including the organic electroluminescence device.

### Means for Solving the Problems

An organic electroluminescence device according to an aspect of the invention includes: an anode; an emitting layer; and a cathode, in which the emitting layer contains a first compound and a second compound, the first compound is a thermally activated delayed fluorescent compound, the first compound is a compound represented by a formula (1) below, the second compound is represented by a formula (2) below, and a singlet energy S₁(M1) of the first compound and a singlet energy S₁(M2) of the second compound satisfy a relationship of Numerical Formula 1 below,

S₁(M1)>S₁(M2) (Numerical Formula 1).

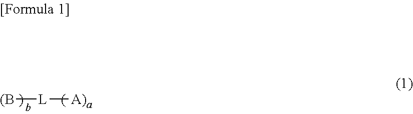

where, in the formula (1): A is a group having a partial structure selected from formulae (a-1) to (a-2) below;

B is a group having a partial structure selected from formulae (b-1) to (b-4) below;

L is a single bond or a substituent;

L serving as the linking group is a group derived from a group selected from the group consisting of a substituted or unsubstituted aryl group having 6 to 30 ring carbon atoms, a substituted or unsubstituted heteroaryl group having 5 to 30 ring atoms, and a group formed by mutually bonding two to five of the above aryl and/or heteroaryl groups, where the mutually bonded groups are the same or different;

a is an integer in a range from 1 to 5 and represents the number of A directly bonded to L;

when a is an integer ranging from 2 to 5, the plurality of A are mutually the same or different;

b is an integer in a range from 1 to 5 and represents the number of B directly bonded to L; and

when b is an integer ranging from 2 to 5, the plurality of B are mutually the same or different,

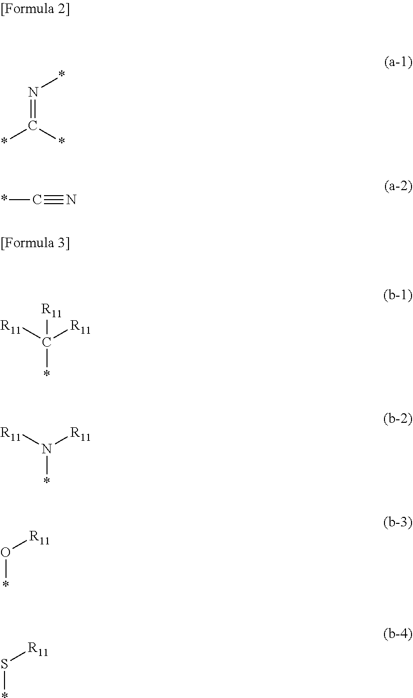

where, in the formulae (b-1) to (b-4):

R₁₁ is each independently a hydrogen atom or a substituent;

R₁₁ serving as the substituent is a group selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms;

when a plurality of R₁₁ are present, the plurality of R₁₁ are mutually the same or different, and are mutually bonded to form a ring or not bonded to form no ring,

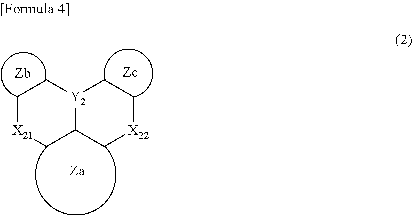

where, in the formula (2): Za ring, Zb ring and Zc ring are each independently a cyclic structure selected from the group consisting of a substituted or unsubstituted aryl ring having 6 to 30 ring carbon atoms, and a substituted or unsubstituted heteroaryl ring having 5 to 30 ring atoms;

X₂₁ and X₂₂ are each independently an oxygen atom, NRa, or a sulfur atom;

when X₂₁ is NRa, Ra is bonded to Za ring or Zb ring to form a ring or is not bonded to form no ring;

when X₂₂ is NRa, Ra is bonded to Za ring or Zc ring to form a ring or is not bonded to form no ring;

Ra is each independently a group selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms;

Y₂ is any one of a boron atom, a phosphorus arom, SiRb, P═O, or P═S;

Rb is each independently a group selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms.

According to another aspect of the invention, an electronic device including the organic electroluminescence device according to the above aspect of the invention is provided.

According to the above aspects of the invention, an organic electroluminescence device capable of emitting light with high efficiency and an electronic device including the organic electroluminescence device can be provided.

### BRIEF DESCRIPTION OF DRAWING

FIG. 1 schematically shows an exemplary arrangement of an organic electroluminescence device according to a first exemplary embodiment of the invention.

FIG. 2 schematically shows a device for measuring transient PL.

FIG. 3 shows examples of a transient PL decay curve.

FIG. 4 shows a relationship between energy levels of a first compound and a second compound and an energy transfer between the first compound and the second compound in an exemplary emitting layer of the organic electroluminescence device according to the first exemplary embodiment of the invention.

FIG. 5 shows a relationship between energy levels of a first compound, a second compound, and a third compound and an energy transfer between the first compound, the second compound, and the third compound in an exemplary emitting layer of an organic electroluminescence device according to a second exemplary embodiment of the invention.

### DESCRIPTION OF EMBODIMENT(S)

### First Exemplary Embodiment

### Organic EL Device

### Arrangement(s) of Organic EL Device

An arrangement of an organic EL device according to a first exemplary embodiment will be described below.

An organic device in the first exemplary embodiment includes a pair of electrodes and an organic layer between the pair of electrodes. The organic layer includes at least one layer formed of an organic compound. Alternatively, the organic layer includes a plurality of layers formed of an organic compound(s). The organic layer may further include an inorganic compound(s). In the organic EL device in the first exemplary embodiment, at least one layer of the organic layer(s) is an emitting layer. Specifically, for instance, the organic layer may consist of a single emitting layer, or alternatively, may further include other layer(s) usable in a typical organic EL device. Examples of the non-limiting other layer usable in the organic EL device include at least one layer selected from the group consisting of a hole injecting layer, a hole transporting layer, an electron injecting layer, an electron transporting layer and a blocking layer.

Typical device arrangements of the organic EL device include the following arrangements (a) to (f) and the like:

(a) anode/emitting layer/cathode;

(b) anode/hole injecting⋅transporting layer/emitting layer/cathode;

(c) anode/emitting layer/electron injecting-transporting layer/cathode;

(d) anode/hole injecting⋅transporting layer/emitting layer/electron injecting, transporting layer/cathode;

(e) anode/hole injecting⋅transporting layer/emitting layer/blocking layer/electron injecting⋅transporting layer/cathode; and

(f) anode/hole injecting⋅transporting layer/blocking layer/emitting layer/blocking layer/electron injecting, transporting layer/cathode.

The arrangement (d) is suitably used among the above arrangements. However, the arrangement of the invention is not limited to the above arrangements. The “emitting layer” refers to an organic layer having an emitting function. The term “hole injecting-transporting layer” means at least one of a hole injecting layer and a hole transporting layer. The term “electron injecting-transporting layer” means at least one of an electron injecting layer and an electron transporting layer. Herein, when the hole injecting layer and the hole transporting layer are provided, the hole injecting layer is preferably provided between the hole transporting layer and the anode. When the electron injecting layer and the electron transporting layer are provided, the electron injecting layer is preferably provided between the electron transporting layer and the cathode. The hole injecting layer, the hole transporting layer, the electron transporting layer and the electron injecting layer may each consist of a single layer or a plurality of layers.

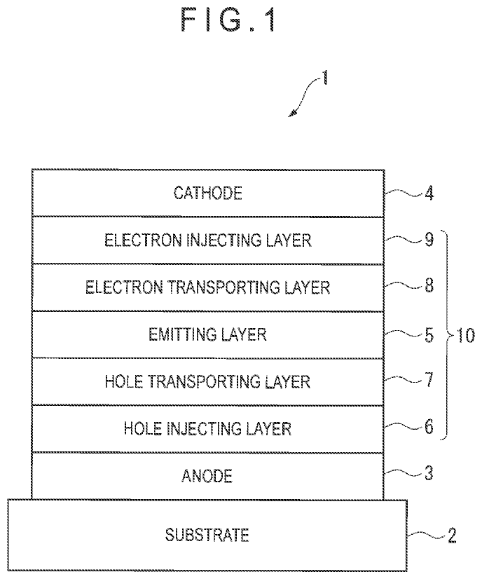

FIG. 1 schematically shows an arrangement of an exemplary organic EL device according to the first exemplary embodiment.

An organic EL device 1 includes a light-transmissive substrate 2, an anode 3, a cathode 4, and an organic layer 10 provided between the anode 3 and the cathode 4. The organic layer 10 includes: a hole injecting layer 6, a hole transporting layer 7, an emitting layer 5, an electron transporting layer 8, and an electron injecting layer 9. The organic layer 10 includes the hole injecting layer 6, the hole transporting layer 7, the emitting layer 5, the electron transporting layer 8, and the electron injecting layer 9 which are laminated on the anode 3 in this order.

### Emitting Layer

The emitting layer 5 of the organic EL device 1 contains a first compound and a second compound. The emitting layer 5 may contain a metal complex. The emitting layer 5 preferably does not contain a phosphorescent metal complex.

The first compound is also preferably a host material (occasionally referred to as a matrix material). The second compound is also preferably a dopant material (occasionally referred to as a guest material, emitter, or luminescent material).

### First Compound

The first compound is a thermally activated delayed fluorescent compound represented by a formula (1) below.

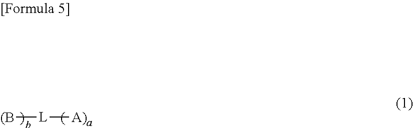

In the formula (1), A is a group having a partial structure selected from formulae (a-1) to (a-2) below;

B is a group having a partial structure selected from formulae (b-1) to (b-4) below;

L is a single bond or a linking group;

L serving as the linking group is a group derived from a group selected from the group consisting of a substituted or unsubstituted aryl group having 6 to 30 ring carbon atoms, a substituted or unsubstituted heteroaryl group having 5 to 30 ring atoms, and a group formed by mutually bonding two to five of the above aryl and/or heteroaryl groups, the mutually bonded groups being the same or different;

a is an integer in a range from 1 to 5 and represents the number of A directly bonded to L;

when a is an integer in a range from 2 to 5, the plurality of A are mutually the same or different;

b is an integer in a range from 1 to 5 and represents the number of B directly bonded to L; and

when b is an integer in a range from 2 to 5, the plurality of B are mutually the same or different.

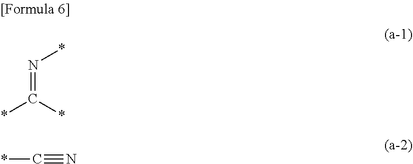

In the formulae (a-1) and (a-2), * each independently represent a bonding position to another atom in the molecules of the first compound (i.e. the compound represented by the formula (1)).

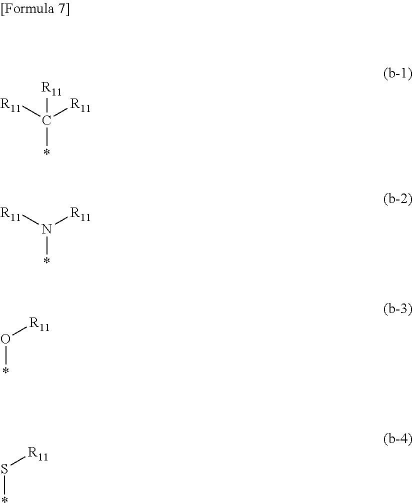

In the formulae (b-1) to (b-4): R₁₁ are each independently a hydrogen atom or a substituent;

R₁₁ serving as the substituent is selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms;

when a plurality of R₁₁ are present, the plurality of R₁₁ are mutually the same or different, the plurality of R₁₁ being mutually bonded to form a ring or not bonded to form no ring; and

* each independently represent a bonding position to another atom in the molecules of the first compound (i.e. the compound represented by the formula (1)).

In the formula (1), A represents an acceptor (electron-accepting) moiety and B represents a donor (electron-donating) moiety.

Examples of the group having the partial structure selected from the group consisting of the partial structures represented by the formulae (a-1) to (a-2) are shown below.

The group having the partial structure represented by the formula (a-1) is exemplified by a group represented by a formula (a-1-1) below.

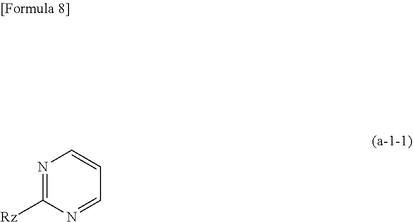

In the formula (a-1-1), Rz is a hydrogen atom, a substituent, or a bonding position to L or B in the formula (1), and

Rz serving as the substituent is selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms.

Examples of the group having the partial structure selected from the group consisting of the partial structures represented by the formulae (b-1) to (b-4) are shown below.

The group having the partial structure represented by the formula (b-2) is exemplified by a group represented by a formula (b-2-1) below.

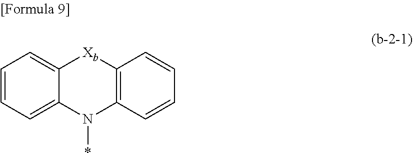

In the formula (b-2-1), X_{b} is a single bond, an oxygen atom, a sulfur atom, CR_{b1}R_{b2} or a carbon atom bonded to L or A in the formula (1).

The formula (b-2-1) in which X_{b} is a single bond is represented by a formula (b-2-2). The formula (b-2-1) in which X_{b} is an oxygen atom is represented by a formula (b-2-3). The formula (b-2-1) in which X_{b} is a sulfur atom is represented by a formula (b-2-4). The formula (b-2-1) in which X_{b} is CR_{b1}R_{b2} is represented by a formula (b-2-5).

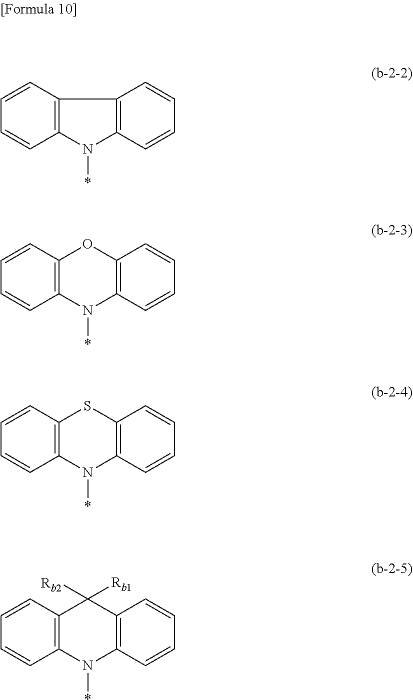

R_{b1} and R_{b2} are each independently a hydrogen atom or a substituent. R_{b1} and R_{b2} serving as the substituent are each independently a group selected from the group consisting of a substituted or unsubstituted alkyl group having 1 to 30 carbon atoms and a substituted or unsubstituted aryl group having 6 to 30 ring carbon atoms.

R_{b1} and R_{b2} are each preferably a group selected from the group consisting of a substituted or unsubstituted alkyl group having 1 to 30 carbon atoms and a substituted or unsubstituted aryl group having 6 to 30 ring carbon atoms, more preferably a group selected from the group consisting of a substituted or unsubstituted alkyl group having 1 to 30 carbon atoms.

In the organic EL device according to the first exemplary embodiment, L in the formula (1) is preferably a single bond or a substituted or unsubstituted aryl group having 6 to 30 ring carbon atoms, more preferably a single bond or a substituted or unsubstituted phenyl group.

In the organic EL device according to the first exemplary embodiment, B in the formula (1) is preferably a group having a partial structure selected from the group consisting of the partial structures represented by the formulae (b-2), (b-3) and (b-4), more preferably a group having the partial structure selected from the group consisting of the partial structures represented by the formula (b-2).

B in the formula (1) is also preferably represented by a formula (100) below.

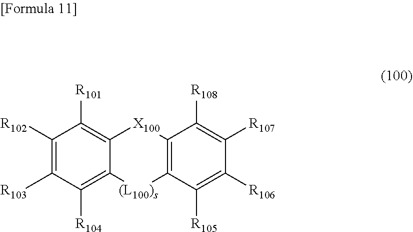

In the formula (100): R₁₀₁ to R₁₀₈ are each independently a hydrogen atom or a substituent;

R₁₀₁ to R₁₀₈ serving as the substituents are each independently a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted silyl group, a substituted or unsubstituted alkoxy group having 1 to 30 carbon atoms, a substituted or unsubstituted aryloxy group having 6 to 30 ring carbon atoms, a substituted or unsubstituted alkylamino group having 2 to 30 carbon atoms, a substituted or unsubstituted arylamino group having 6 to 60 ring carbon atoms, a substituted or unsubstituted alkylthio group having 1 to 30 carbon atoms, and a substituted or unsubstituted arylthio group having 6 to 30 ring carbon atoms,

with a proviso that a combination of groups selected from the group consisting of a combination of R₁₀₁ and R₁₀₂, a combination of R₁₀₂ and R₁₀₃, a combination of R₁₀₃ and R₁₀₄, a combination of R₁₀₅ and R₁₀₆, a combination of R₁₀₆ and R₁₀₇, and a combination of R₁₀₇ and R₁₀₈ forms a saturated or unsaturated ring or forms no ring;

L₁₀₀ is any one linking group selected from linking groups represented by formulae (111) to (117) below, s being an integer of 0 to 3, a plurality of L₁₀₀ being mutually the same or different; and

X₁₀₀ is any one linking group selected from linking groups represented by formulae (121) to (125) below.

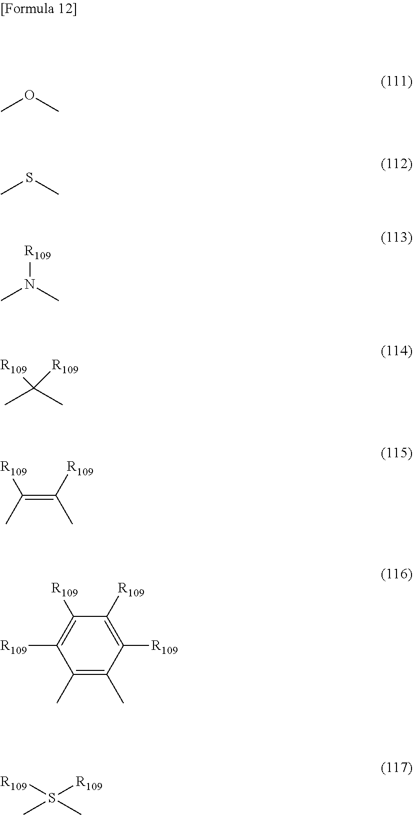

In the formulae (113) to (117), R₁₀₉ each independently represents the same as R₁₀₁ to R₁₀₈ in the formula (100).

One of R₁₀₁ to R₁₀₈ in the formula (100) or one of R₁₀₉ is a single bond to be bonded to L or A in the formula (1).

The substituents in a combination of R₁₀₉ and R₁₀₄ of the formula (100) or a combination of R₁₀₉ and R₁₀₅ of the formula (100) form a saturated or unsaturated ring, or do not form a ring.

A plurality of R₁₀₉ are mutually the same or different.

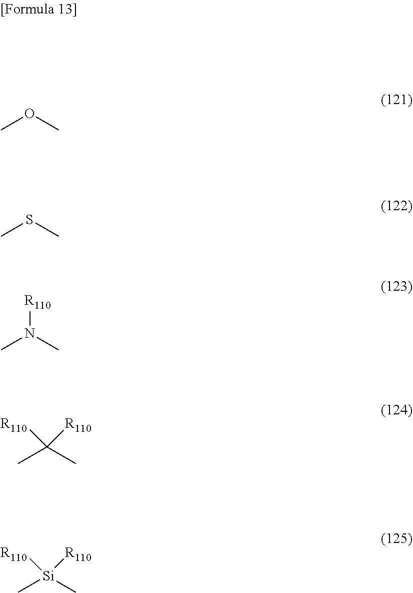

In the formulae (123) to (125): R₁₁₀ are each independently a hydrogen atom or a substituent;

R₁₁₀ serving as the substituent is selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms;

a plurality of R₁₁₀ are mutually the same or different; and

the substituents in a combination of R₁₁₀ and R₁₀₁ of the formula (100) or a combination of R₁₁₀ and R₁₀₈ of the formula (100) form a saturated or unsaturated ring, or do not form a ring.

In the formula (100), s is preferably 0 or 1.

When s in the formula (100) is 0, B in the formula (1) is represented by a formula (100A) below.

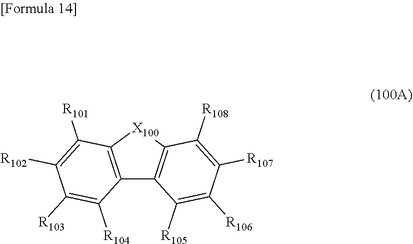

X₁₀₀ and R₁₀₁ to R₁₀₈ in the formula (100A) represent the same as X₁₀₀ and R₁₀₁ to R₁₀₈ in the formula (100), respectively.

L₁₀₀ is preferably represented by any one of the formulae (111) to (114), more preferably represented by the formula (113) or (114).

X₁₀₀ is preferably represented by any one of the formulae (121) to (124), more preferably represented by the formula (123) or (124).

In the organic EL device of the first exemplary embodiment, the first compound is also preferably a compound represented by a formula (11A) below.

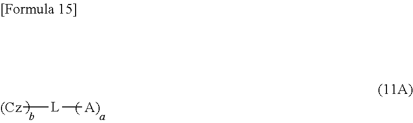

In the formula (11A): A, L, a, and b represent the same as A, L, a, and b in the formula (1), respectively.

Cz is a group represented by a formula (11a) below.

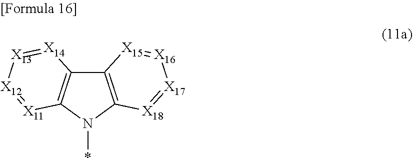

In the formula (11a): X₁₁ to X₁₈ are each independently a nitrogen atom or CRx (a carbon atom having a substituent Rx);

Rx are each independently a hydrogen atom or a substituent;

Rx serving as the substituent is selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxyl group;

a plurality of Rx are mutually the same or different;

when a plurality of ones of X₁₁ to X₁₈ are CRx and Rx are substituents, Rx are bonded to each other to form a ring, or are not bonded to form no ring; and

* represents a bonding position to a carbon atom of the cyclic structure represented by L or A in the formula (11A).

In the formula (11a), X₁₁ to X₁₈ are preferably CRx.

In the organic EL device according to the first exemplary embodiment, L in the formula (11A) is preferably a single bond or a substituted or unsubstituted aryl group having 6 to 30 ring carbon atoms, more preferably a single bond or a substituted or unsubstituted phenyl group.

In the organic EL device of the first exemplary embodiment, the first compound is also preferably a compound represented by a formula (11B) below.

[Formula 17]

Cz-Az (11B)

In the formula (11B): Cz represents the same as Cz in the formula (11A); and

Az is a cyclic structure selected from the group consisting of a substituted or unsubstituted pyridine group, a substituted or unsubstituted pyrimidine group, a substituted or unsubstituted triazine group, and a substituted or unsubstituted pyrazine group.

In the organic EL device of the first exemplary embodiment, the first compound is also preferably a compound represented by a formula (11C) below.

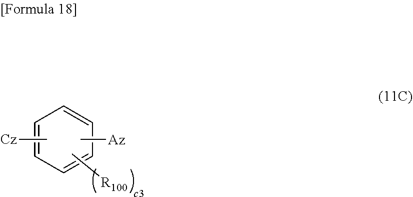

In the formula (11C): Cz represents the same as Cz in the formula (11A);

Az represents the same as Az in the formula (11B);

c3 is 4;

R₁₀₀ is a hydrogen atom or a substituent; and

R₁₀₀ serving as the substituent is selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group, the plurality of R₁₀₀ being the same or different.

In the organic EL device of the first exemplary embodiment, the first compound is also preferably a compound represented by a formula (11D) below.

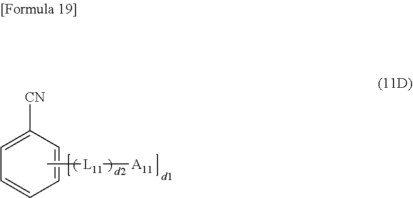

In the formula (11D): d1 is 5, d2 are each independently 0 or 1;

L₁₁ are each independently a single bond or a linking group;

L₁₁ serving as the substituents are each independently a group derived from a group selected from the group consisting of a substituted or unsubstituted aryl group having 6 to 30 ring carbon atoms, and a substituted or unsubstituted heteroaryl group having 5 to 30 ring atoms;

A₁₁ are each independently a hydrogen atom or a substituent; and

A₁₁ serving as the substituents are each independently a group selected from the group consisting of a cyano group, a substituted or unsubstituted aryl group having 6 to 30 ring carbon atoms, and a substituted or unsubstituted heteroaryl group having 5 to 30 ring atoms,

with a proviso that at least one of A₁₁ is a group represented by the formula (11a).

In the organic EL device of the first exemplary embodiment, the first compound is also preferably a compound represented by a formula (11E) below.

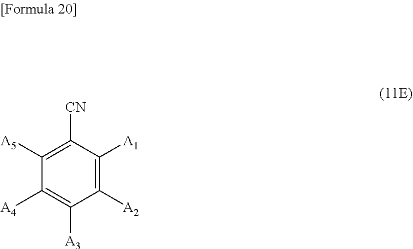

In the formula (11E): A₁ to A₅ are each independently a hydrogen atom or a substituent; and

A₁ to A₅ serving as the substituents are each independently a group selected from the group consisting of a cyano group, a substituted or unsubstituted aryl group having 6 to 30 ring carbon atoms, and a substituted or unsubstituted heteroaryl group having 5 to 30 ring atoms,

with a proviso that at least one of A₁ to A₅ is a group represented by the formula (11a).

In the organic EL device of the first exemplary embodiment, at least one of A₁, A₂, A₄, and A₅ of the formula (11E) is preferably the group represented by the formula (11a). It is more preferable that all of A₁, A₂, A₄, and A₅ of the formula (11E) are groups represented by the formula (11a).

Cz is also preferably represented by a formula (12a), (12b) or (12c) below.

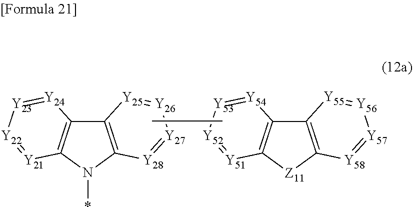

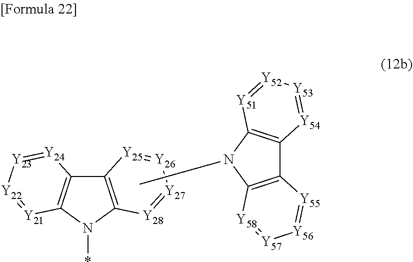

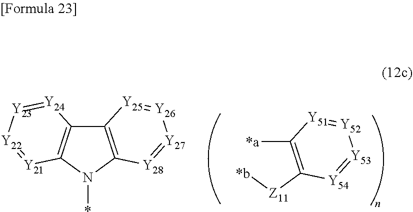

In the formulae (12a), (12b) and (12c): Y₂₁ to Y₂₈, and Y₅₁ to Y₅₈ are each independently a nitrogen atom or CRy (a carbon atom having a substituent Ry).

In the formula (12a), at least one of Y₂₅ to Y₂₈ is a carbon atom bonded to one of Y₅₁ to Y₅₄, and at least one of Y₅₁ to Y₅₄ is a carbon atom bonded to one of Y₂₅ to Y₂₈.

In the formula (12b), at least one of Y₂₅ to Y₂₈ is a carbon atom bonded to a nitrogen atom in a five-membered ring of a nitrogen-containing fused ring including Y₅₁ to Y₅₈.

In the formula (12c), *a and *b each represent a bonding position to one of Y₂₁ to Y₂₈. At least one of Y₂₅ to Y₂₈ is the bonding position represented by *a. At least one of Y₂₅ to Y₂₈ is the bonding position represented by *b.

In the formulae (12a) to (12c), n is an integer in a range from 1 to 4;

Ry are each independently a hydrogen atom or a substituent;

Ry serving as the substituents are each independently a group selected from the group consisting of a substituted or unsubstituted aryl group having 6 to 30 ring carbon atoms, a substituted or unsubstituted heteroaryl group having 5 to 30 ring atoms;

a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group,

a plurality of R_{y} being mutually the same or different;

when a plurality of ones of Y₂₁ to Y₂₈ are CRy and Ry are substituents, Ry are bonded to each other to form a ring, or are not bonded to form no ring;

when a plurality of ones of Y₅₁ to Y₅₈ are CRy and Ry are substituents, Ry are bonded to each other to form a ring, or are not bonded to form no ring;

Z₁₁ is any one selected from the group consisting of an oxygen atom, a sulfur atom, NR₄₅ and CR₄₆R₄₇;

R₄₅ to R₄₇ are each independently a hydrogen atom or a substituent;

R₄₅ to R₄₇ serving as the substituents are each independently a group selected from the group consisting of a substituted or unsubstituted aryl group having 6 to 30 ring carbon atoms, a substituted or unsubstituted heteroaryl group having 5 to 30 ring atoms; a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group;

a plurality of R₄₅ are mutually the same or different;

a plurality of R₄₆ are mutually the same or different;

a plurality of R₄₇ are mutually the same or different;

when R₄₆ and R₄₇ are substituents, the substituents are bonded to each other to form a ring, or are not bonded to form no ring; and

* represents a bonding position to a carbon atom of the cyclic structure represented by Az.

Z₁₁ is preferably NR₄₅.

When Z₁₁ is NR₄₅, R₄₅ is preferably a substituted or unsubstituted aryl group having 6 to 30 ring carbon atoms.

Y₅₁ to Y₅₈ are preferably CRy, provided that at least one of Y₅₁ to Y₅₈ is a carbon atom bonded to the cyclic structure represented by the formula (11a).

Cz is also preferably represented by the formula (12c) in which n is 1.

Cz is also preferably represented by a formula (12c-1) below. A group represented by the formula (12c-1) is an example of the group represented by the formula (12c), in which Y₂₆ is the bonding position represented by *a and Y₂₇ is the bonding position represented by *b.

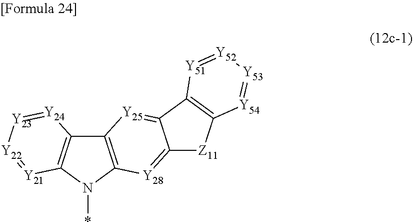

In the formula (12C-1): Y₂₁ to Y₂₅, Y₂₈, and Y₅₁ to Y₅₄ are each independently a nitrogen atom or CRy, in which Ry are each independently a hydrogen atom or a substituent;

Ry serving as the substituents are each independently a group selected from the group consisting of a substituted or unsubstituted aryl group having 6 to 30 ring carbon atoms, a substituted or unsubstituted heteroaryl group having 5 to 30 ring atoms;

a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group,

a plurality of Ry being mutually the same or different;

when a plurality of ones of Y₂₁ to Y₂₅ and Y₂₈ are CRy and Ry are substituents, Ry are bonded to each other to form a ring, or are not bonded to form no ring;

when a plurality of ones of Y₅₁ to Y₅₄ are CRy and Ry are substituents, Ry are bonded to each other to form a ring, or are not bonded to form no ring;

Z₁₁ is any one selected from the group consisting of an oxygen atom, a sulfur atom, NR₄₅ and CR₄₆R₄₇;

R₄₅ to R₄₇ are each independently a hydrogen atom or a substituent;

R₄₅ to R₄₇ serving as the substituents are each independently a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group;

a plurality of R₄₅ are mutually the same or different;

a plurality of R₄₆ are mutually the same or different;

a plurality of R₄₇ are mutually the same or different;

when R₄₆ and R₄₇ are substituents, the substituents are bonded to each other to form a ring, or are not bonded to form no ring; and

* represents a bonding position to a carbon atom of the cyclic structure represented by Az.

When an index n in the formula (12c) is 2, Cz is exemplarily represented by a formula (12c-2) below. Specifically, when n is 2, two structures enclosed by brackets with the index n are fused to the cyclic structure represented by the formula (12c). Cz represented by the formula (12c-2) is an example of the group represented by the formula (12c), in which Y₂₂ is the bonding position represented by *b, Y₂₃ is the bonding position represented by *a, Y₂₆ is the bonding position represented by *a and Y₂₇ is the bonding position represented by *b.

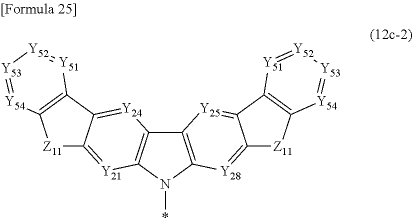

In the formula (12c-2), Y₂₁, Y₂₄, Y₂₅, Y₂₈, Y₅₁ to Y₅₄, Z₁₁, and * respectively represent the same as Y₂₁, Y₂₄, Y₂₅, Y₂₈, Y₅₁ to Y₅₄, Z₁₁, and * in the formula (12c-1). A plurality of Y₅₁ are mutually the same or different. A plurality of Y₅₂ are mutually the same or different. A plurality of Y₅₃ are mutually the same or different. A plurality of Y₅₄ are mutually the same or different. A plurality of Z₁₁ are mutually the same or different.

Az is preferably a cyclic structure selected from the group consisting of a substituted or unsubstituted pyrimidine ring and a substituted or unsubstituted triazine ring.

Az is more preferably a cyclic structure selected from the group consisting of a substituted pyrimidine ring and a substituted triazine ring, in which a substituent of each of the substituted pyrimidine ring and the substituted triazine ring is a group selected from the group consisting of a substituted or unsubstituted aryl group having 6 to 30 ring carbon atoms and a substituted or unsubstituted heteroaryl group having 5 to 30 ring atoms. Az is further preferably a cyclic structure selected from the group consisting of a substituted pyrimidine ring and a substituted triazine ring, in which a substituent of each of the substituted pyrimidine ring and the substituted triazine ring is a substituted or unsubstituted aryl group having 6 to 30 ring carbon atoms.

When the pyrimidine ring and the triazine ring as Az have a substituted or unsubstituted aryl group as a substituent, the aryl group preferably has 6 to ring carbon atoms, more preferably 6 to 14 ring carbon atoms, further preferably 6 to 12 ring carbon atoms.

When Az has a substituted or unsubstituted aryl group as the substituent, the substituent is preferably a group selected from the group consisting of a substituted or unsubstituted phenyl group, a substituted or unsubstituted biphenyl group, a substituted or unsubstituted naphthyl group, a substituted or unsubstituted phenanthryl group, a substituted or unsubstituted terphenyl group, and a substituted or unsubstituted fluorenyl group, more preferably a group selected from the group consisting of a substituted or unsubstituted phenyl group, a substituted or unsubstituted biphenyl group, and a substituted or unsubstituted naphthyl group.

When Az has a substituted or unsubstituted heteroaryl group as the substituent, the substituent is preferably a group selected from the group consisting of a substituted or unsubstituted carbazolyl group, a substituted or unsubstituted dibenzofuranyl group, and a substituted or unsubstituted dibenzothienyl group.

Ry is each independently a hydrogen atom or a substituent. Ry serving as the substituent is preferably each independently a group selected from the group consisting of a substituted or unsubstituted aryl group having 6 to 30 ring carbon atoms and a substituted or unsubstituted heteroaryl group having to 30 ring atoms.

When Ry as the substituent is each a substituted or unsubstituted aryl group having 6 to 30 ring carbon atoms, Ry as the substituent is each preferably a group selected from the group consisting of a substituted or unsubstituted phenyl group, a substituted or unsubstituted biphenyl group, a substituted or unsubstituted naphthyl group, a substituted or unsubstituted phenanthryl group, a substituted or unsubstituted terphenyl group, and a substituted or unsubstituted fluorenyl group, more preferably a group selected from the group consisting of a substituted or unsubstituted phenyl group, a substituted or unsubstituted biphenyl group, and a substituted or unsubstituted naphthyl group.

When Ry as the substituent is a substituted or unsubstituted heteroaryl group having 5 to 30 ring atoms, Ry as the substituent is preferably a substituent selected from the group consisting of a substituted or unsubstituted carbazolyl group, a substituted or unsubstituted dibenzofuranyl group, and a substituted or unsubstituted dibenzothienyl group.

R₄₅ to R₄₇ serving as the substituents are preferably each independently a group selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms.

### Delayed Fluorescence

Delayed fluorescence (thermally activated delayed fluorescence) is explained in “Yuki Hando-tai no Debaisu Bussei (Device Physics of Organic Semiconductors)” (edited by ADACHI, Chihaya, published by Kodansha, on pages 261-268). This document describes that, when an energy difference ΔE₁₃ between a singlet state and a triplet state of a fluorescent material can be decreased, in spite of a typical low transition probability, inverse energy transfer from the triplet state to the singlet state occurs at a high efficiency to express TADF (Thermally Activated Delayed Fluorescence). Further, FIG. 10.38 in this literature illustrates an occurrence mechanism of the delayed fluorescence. The first compound in the exemplary embodiment is a compound emitting thermally activated delayed fluorescence (“thermally activated delayed fluorescent compound”) to be generated by such a mechanism.

Occurrence of delayed fluorescence emission can be determined by transient PL (Photo Luminescence) measurement.

The behavior of delayed fluorescence can be analyzed based on the decay curve obtained by the transient PL measurement. The transient PL measurement is a process where a sample is irradiated with a pulse laser to be excited, and a decay behavior (transient characteristics) of PL emission after the irradiation is stopped is measured. PL emission using a TADF material is divided into an emission component from singlet excitons generated by the first FPL excitation and an emission component from singlet excitons generated via triplet excitons. The lifetime of the singlet excitons generated by the initial PL excitation is in a nano-second order and considerably short. Accordingly, the emission from the singlet excitons is rapidly reduced after pulse laser radiation.

On the other hand, since delayed fluorescence provides emission from singlet excitons generated through long-life triplet excitons, emission is gradually reduced. There is thus a large difference in time between emission from the singlet excitons generated by the initial PL excitation and emission from the singlet excitons generated via triplet excitons. Accordingly, a luminous intensity derived from delayed fluorescence is obtainable.

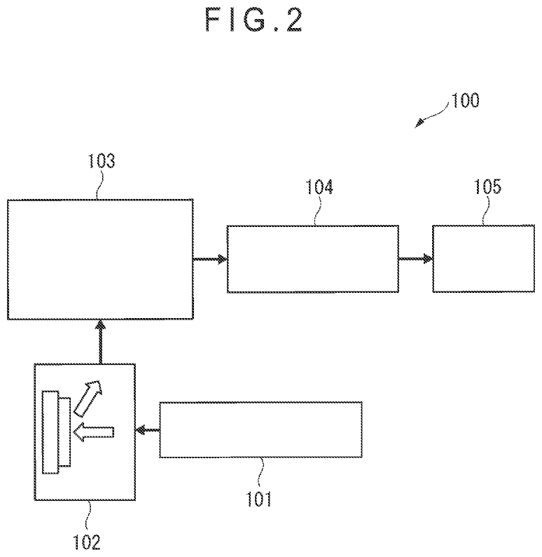

FIG. 2 schematically shows an exemplary device for measuring transient PL.

A transient PL measurement device 100 of the first exemplary embodiment includes: a pulse laser unit 101 capable of emitting light with a predetermined wavelength; a sample chamber 102 configured to house a measurement sample; a spectrometer 103 configured to disperse light emitted from the measurement sample; a streak camera 104 configured to form a two-dimensional image; and a personal computer 105 configured to analyze the two-dimensional image imported thereinto. It should be noted that transient PL may be measured by a device different from one described in the first exemplary embodiment.

The sample to be housed in the sample chamber 102 is prepared by forming a thin film, which is made of a matrix material doped with a doping material at a concentration of 12 mass %, on a quartz substrate.

The thus-obtained thin film sample is housed in the sample chamber 102, and is irradiated with a pulse laser emitted from the pulse laser unit 101 to excite the doping material. The emitted excitation light is taken in a 90-degree direction with respect to the irradiation direction of the excitation light, and is dispersed by the spectrometer 103. A two-dimensional image of the light is formed through the streak camera 104. In the thus-obtained two-dimensional image, an ordinate axis corresponds to time, an abscissa axis corresponds to wavelength, and a bright spot corresponds to luminous intensity. The two-dimensional image is taken at a predetermined time axis, thereby obtaining an emission spectrum with an ordinate axis representing luminous intensity and an abscissa axis representing wavelength. Further, the two-dimensional image is taken at a wavelength axis, thereby obtaining a decay curve (transient PL) with an ordinate axis representing the logarithm of luminous intensity and an abscissa axis representing time.

For instance, using a reference compound H1 below as the matrix material and a reference compound D1 as the doping material, a thin film sample A was prepared as described above and the transitional PL was measured.

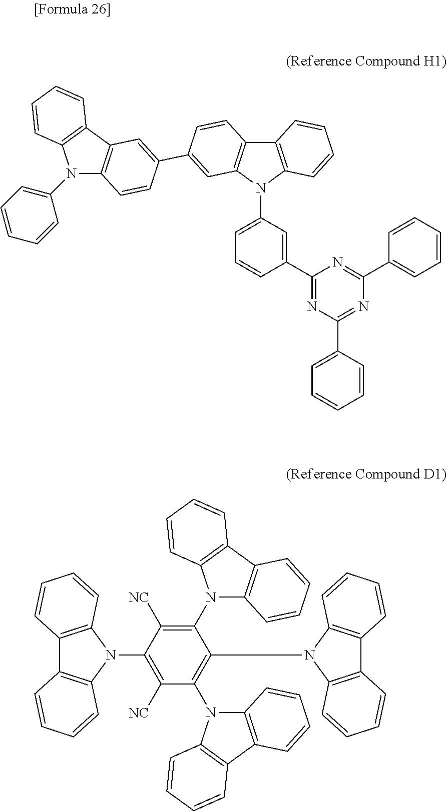 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

The decay curve was analyzed with respect to the above thin film sample A and a thin film sample B. The thin film sample B was prepared as described above, using a reference compound H2 below as the matrix material and the reference compound D1 as the doping material.

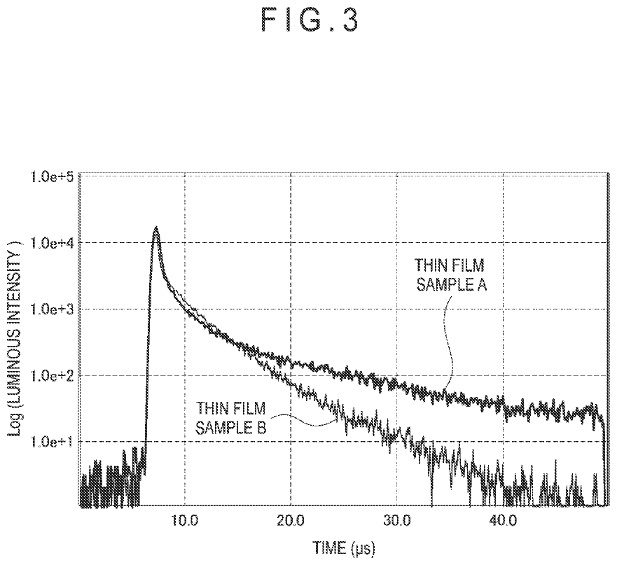

FIG. 3 schematically shows decay curves obtained from transient PL obtained by measuring the respective thin film samples A and B.

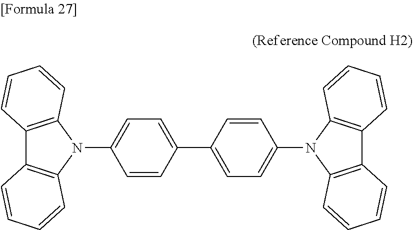 [SMILES: c1ccc2c(c1)c1ccccc1n2-c1ccc(-c2ccc(-n3c4ccccc4c4ccccc43)cc2)cc1]

As described above, an emission decay curve with an ordinate axis representing luminous intensity and an abscissa axis representing time can be obtained by the transient PL measurement. Based on the emission decay curve, a fluorescence intensity ratio between fluorescence in the single state generated by light excitation and the delayed fluorescence in the singlet state generated by the inverse energy transfer through the triplet state can be estimated. In a delayed fluorescent material, a ratio of the intensity of the slowly decaying delayed fluorescence to the intensity of the promptly decaying fluorescence is relatively large.

In the first exemplary embodiment, the luminescence amount of the delayed fluorescence can be obtained using the device shown in FIG. 2. Emission from the first compound includes: Prompt emission observed immediately when the excited state is achieved by exciting the first compound with a pulse beam (i.e., a beam emitted from a pulse laser unit) having an absorbable wavelength; and Delayed emission observed not immediately when but after the excited state is achieved. In the first exemplary embodiment, when the amount of Prompt emission is denoted by X_{P} and the amount of Delayed emission is denoted by X_{D}, a value of X_{D}/X_{P} is preferably 0.05 or more.

The amount of Prompt emission and the amount of Delayed emission can be obtained through the same method as a method described in “Nature 492, 234-238, 2012.” The amount of Prompt emission and the amount of Delayed emission may be calculated using a device different from one described in the above Reference Literature.

For instance, a sample usable for measuring the delayed fluorescence may be prepared by co-depositing the first compound and a compound TH-2 below on a quartz substrate at a ratio of the first compound being 12 mass % to form a 100-nm-thick thin film.

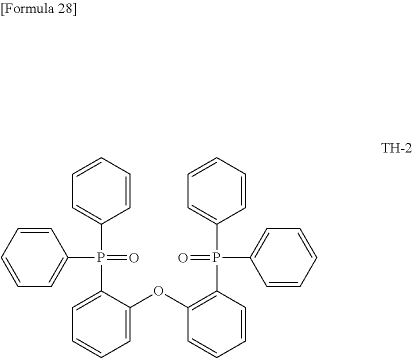 [SMILES: O=P(c1ccccc1)(c1ccccc1)c1ccccc1Oc1ccccc1P(=O)(c1ccccc1)c1ccccc1]

### Method of Manufacturing First Compound

The first compound can be exemplarily manufactured through a method described in Chemical Communications p. 10385-10387 (2013) and NATURE Photonics p. 326-332 (2014). Moreover, the first compound can be exemplarily manufactured by a method described in International Publications WO2013/180241, WO2014/092083, WO2014/104346 and the like. Furthermore, the first compound can be exemplarily manufactured with use of a known alternative reaction and a starting material depending on a target object with reference to a reaction described later in Examples.

Specific examples of the first compound of the exemplary embodiment are shown below. The first compound according to the invention is not limited to these specific examples.

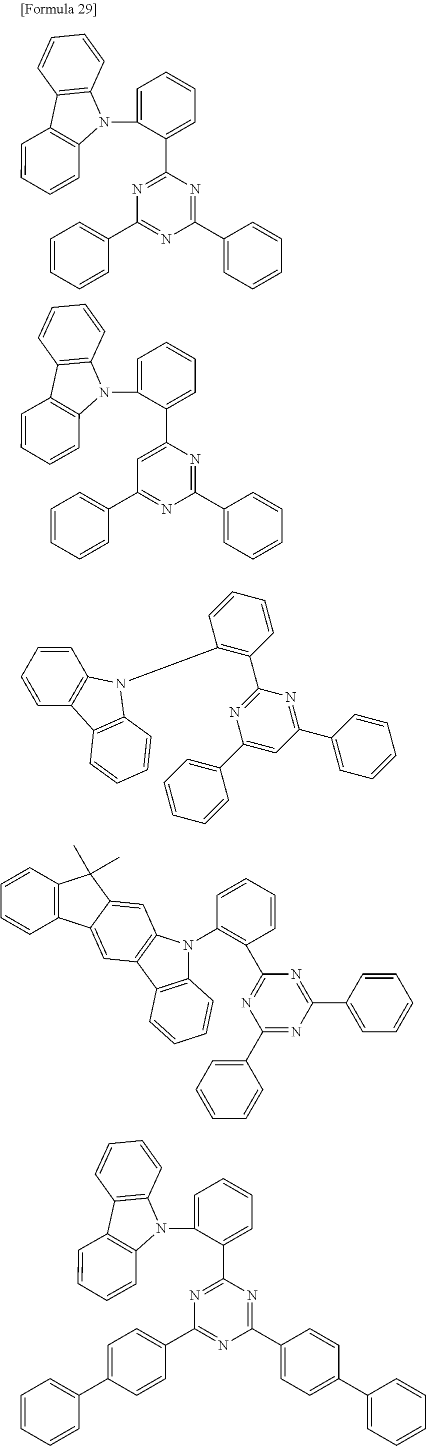

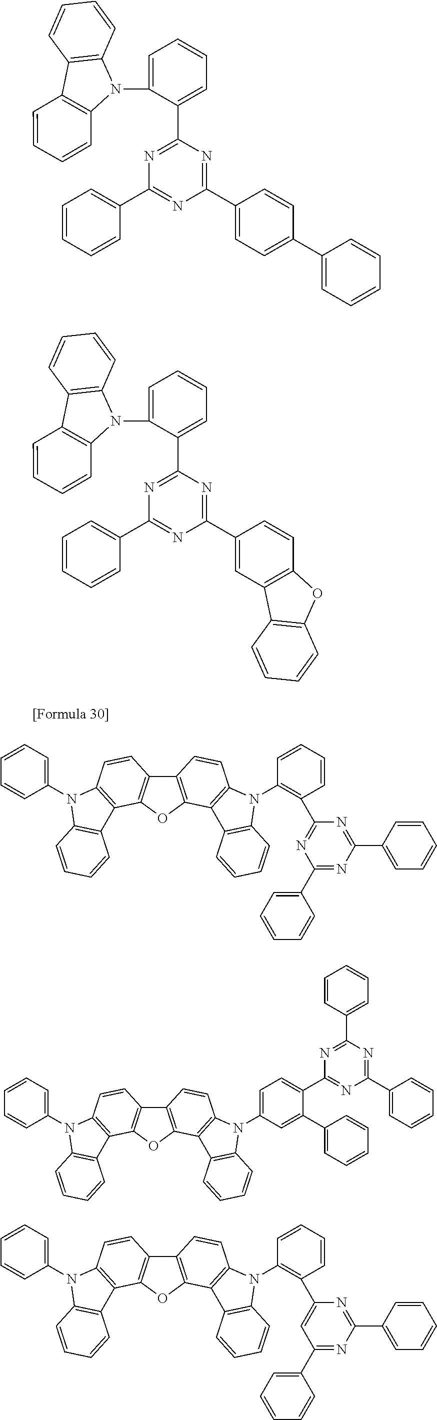 [SMILES: c1ccc(-c2ccc(-c3nc(-c4ccccc4)nc(-c4ccccc4-n4c5ccccc5c5ccccc54)n3)cc2)cc1 ; c1ccc(-c2nc(-c3ccc4oc5ccccc5c4c3)nc(-c3ccccc3-n3c4ccccc4c4ccccc43)n2)cc1 ; c1ccc(-c2nc(-c3ccccc3)nc(-c3ccccc3-n3c4ccccc4c4c5oc6c(ccc7c6c6ccccc6n7-c6ccccc6)c5ccc43)n2)cc1 ; c1ccc(-c2nc(-c3ccccc3)nc(-c3ccc(-n4c5ccccc5c5c6oc7c(ccc8c7c7ccccc7n8-c7ccccc7)c6ccc54)cc3-c3ccccc3)n2)cc1 ; c1ccc(-c2cc(-c3ccccc3-n3c4ccccc4c4c5oc6c(ccc7c6c6ccccc6n7-c6ccccc6)c5ccc43)nc(-c3ccccc3)n2)cc1]

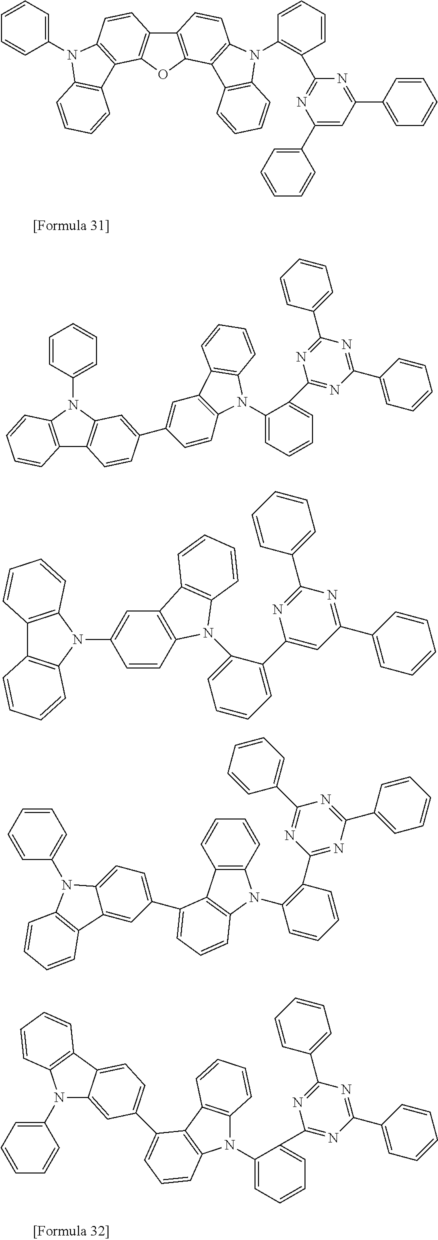

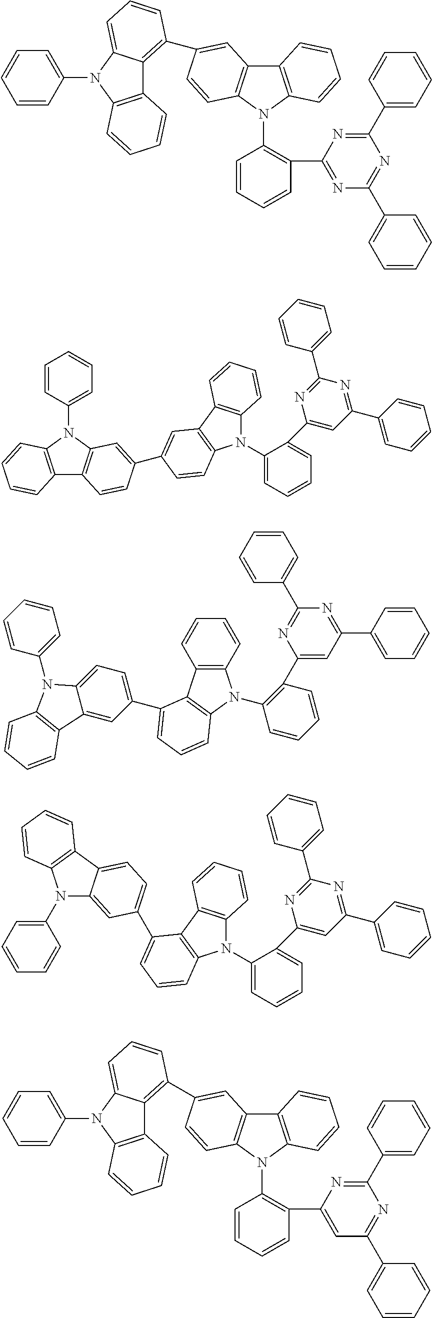

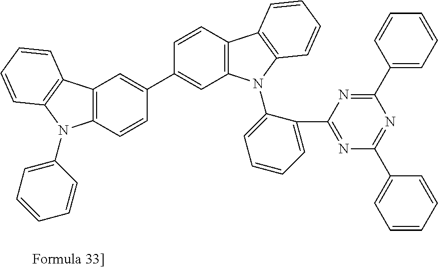 [SMILES: c1ccc(-c2nc(-c3ccccc3)nc(-c3ccccc3-n3c4ccccc4c4ccc(-c5ccc6c(c5)c5ccccc5n6-c5ccccc5)cc43)n2)cc1]

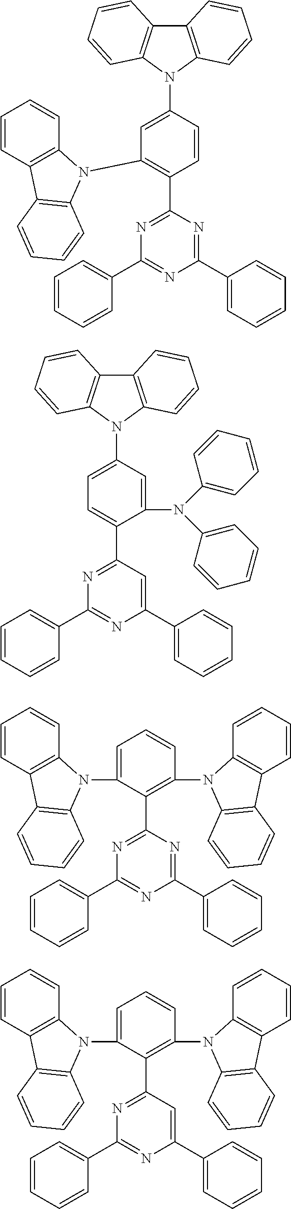

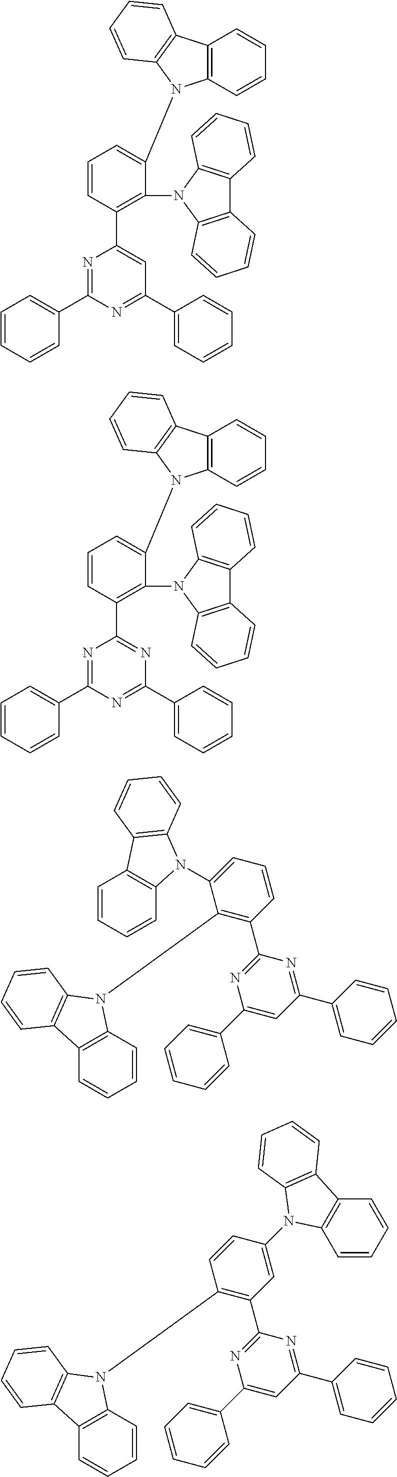

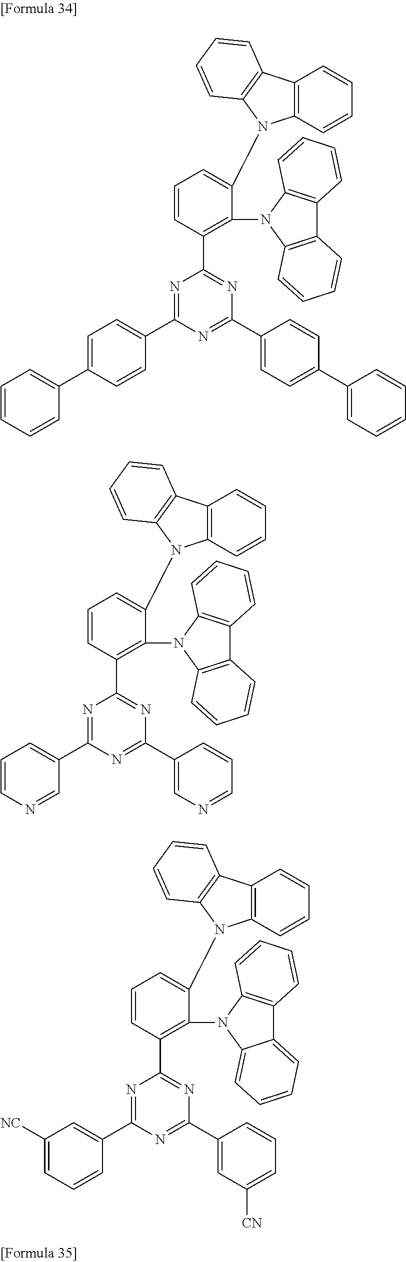

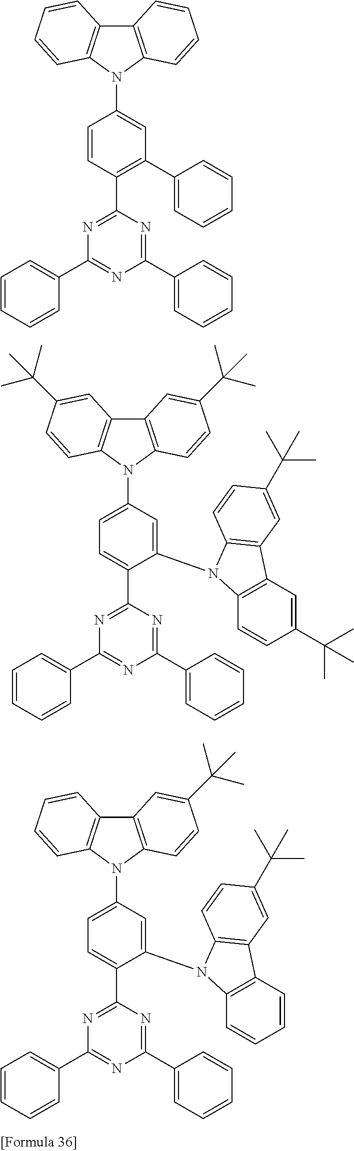

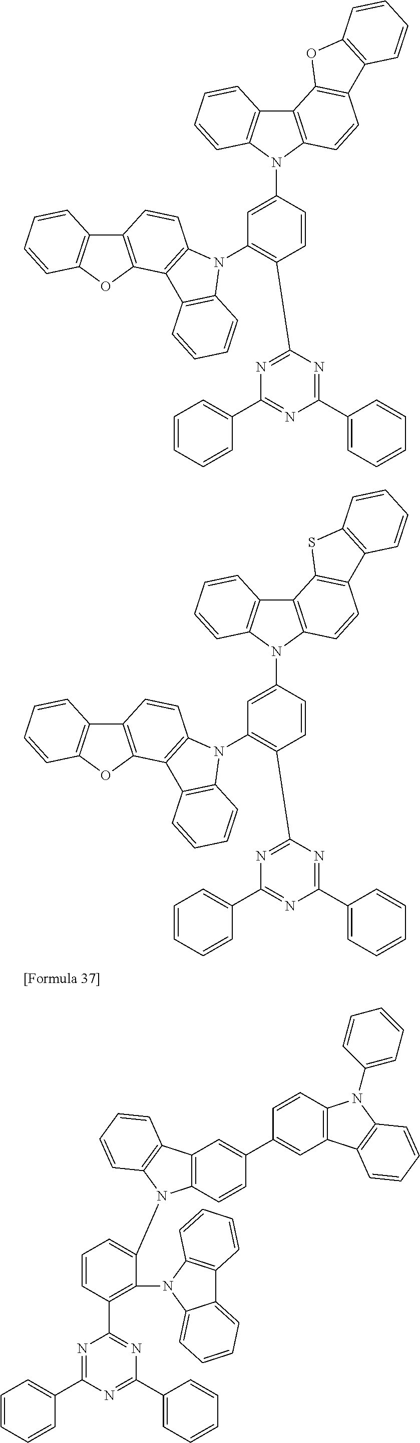

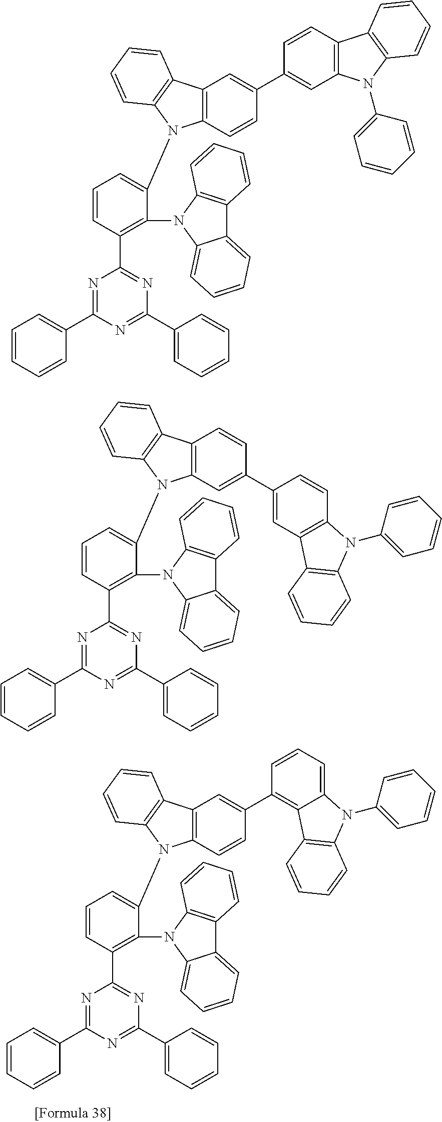 [SMILES: c1ccc(-c2nc(-c3ccccc3)nc(-c3cccc(-n4c5ccccc5c5cc(-c6ccc7c8ccccc8n(-c8ccccc8)c7c6)ccc54)c3-n3c4ccccc4c4ccccc43)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3-n3c4ccccc4c4ccccc43)n2)cc1 ; c1ccc(-c2nc(-c3ccccc3)nc(-c3cccc(-n4c5ccccc5c5cc(-c6cccc7c6c6ccccc6n7-c6ccccc6)ccc54)c3-n3c4ccccc4c4ccccc43)n2)cc1]

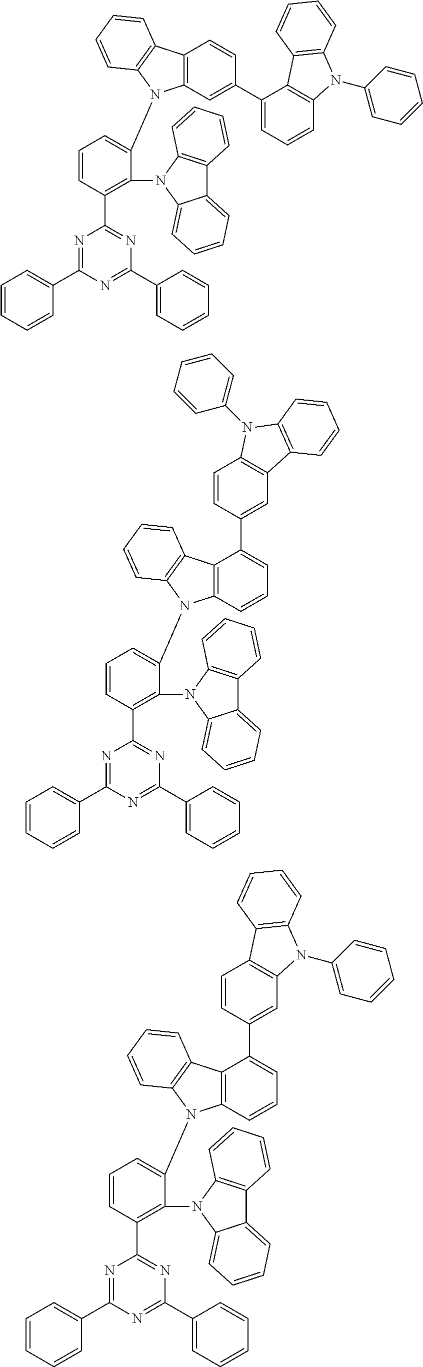

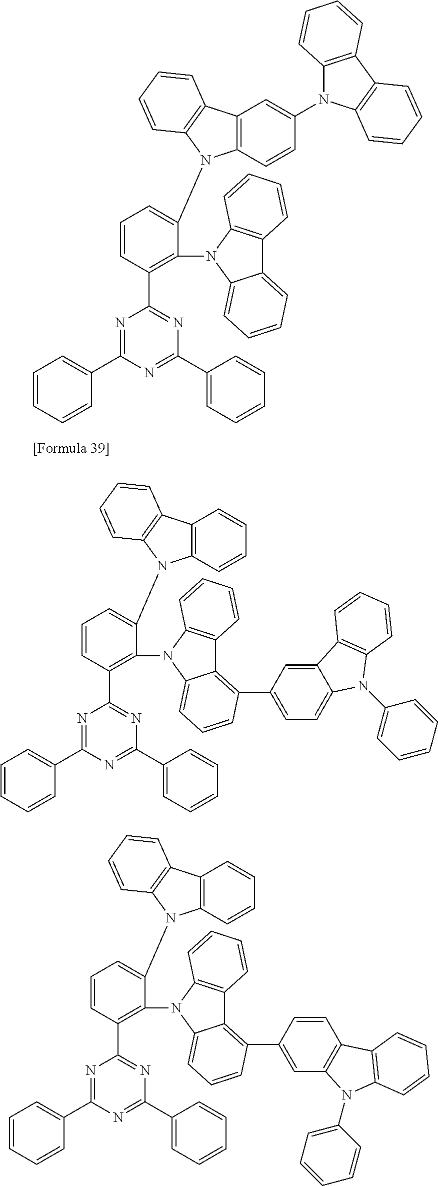

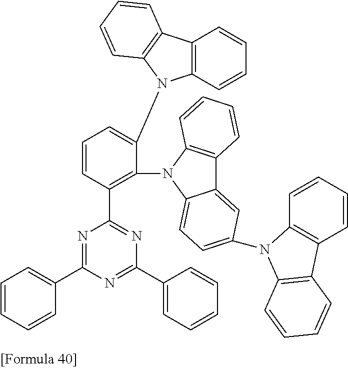 [SMILES: c1ccc(-c2nc(-c3ccccc3)nc(-c3cccc(-n4c5ccccc5c5ccccc54)c3-n3c4ccccc4c4cc(-n5c6ccccc6c6ccccc65)ccc43)n2)cc1]

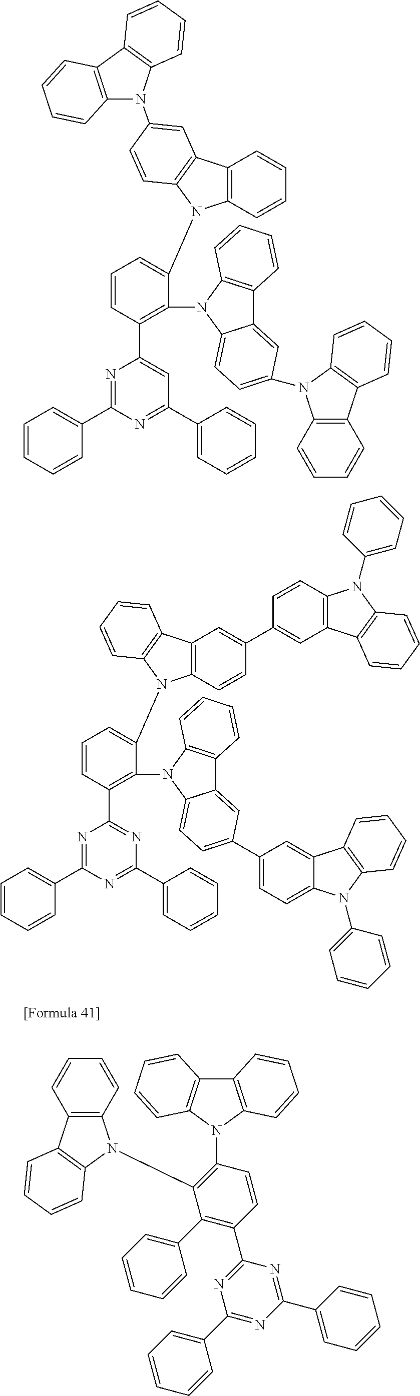

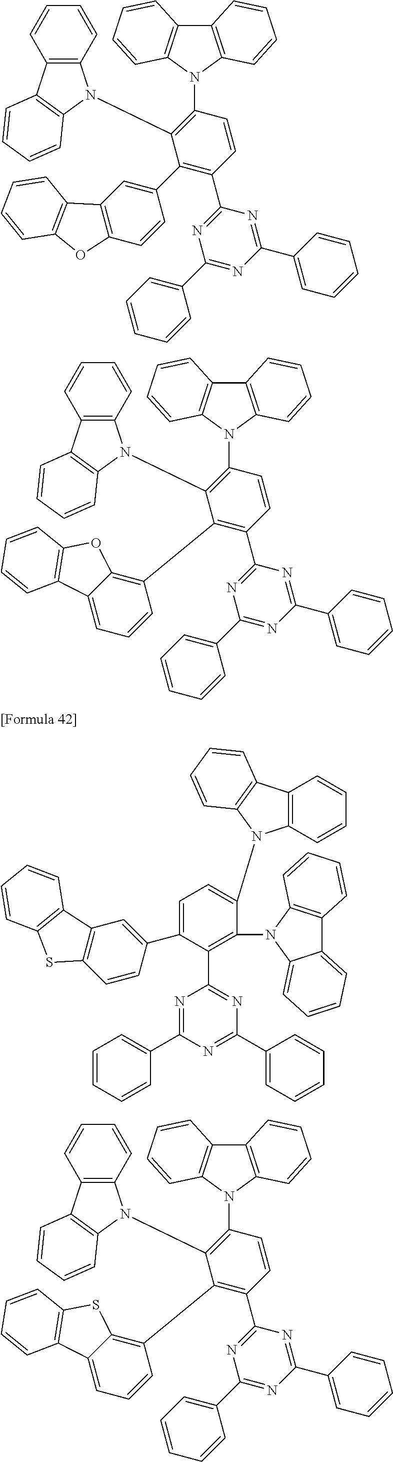

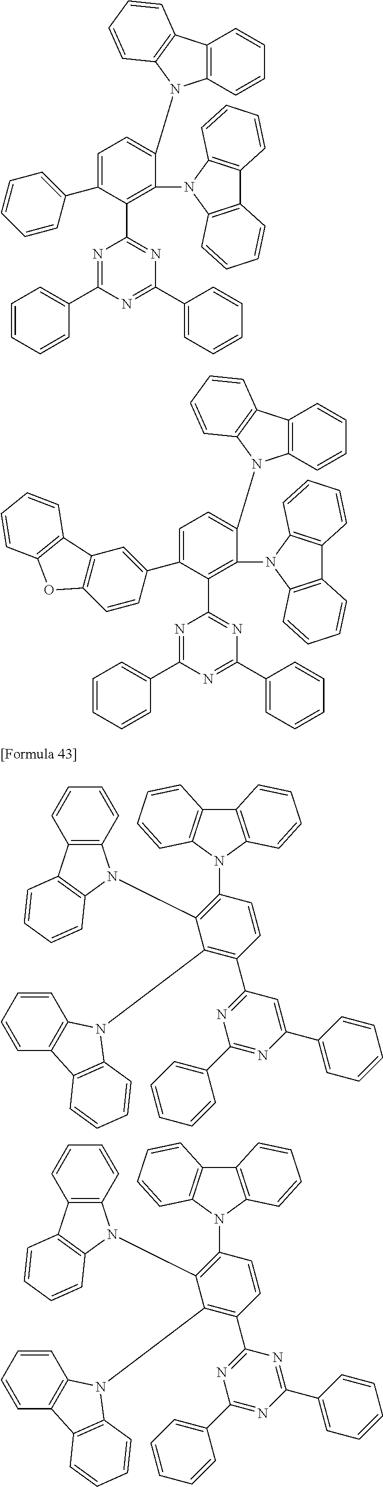

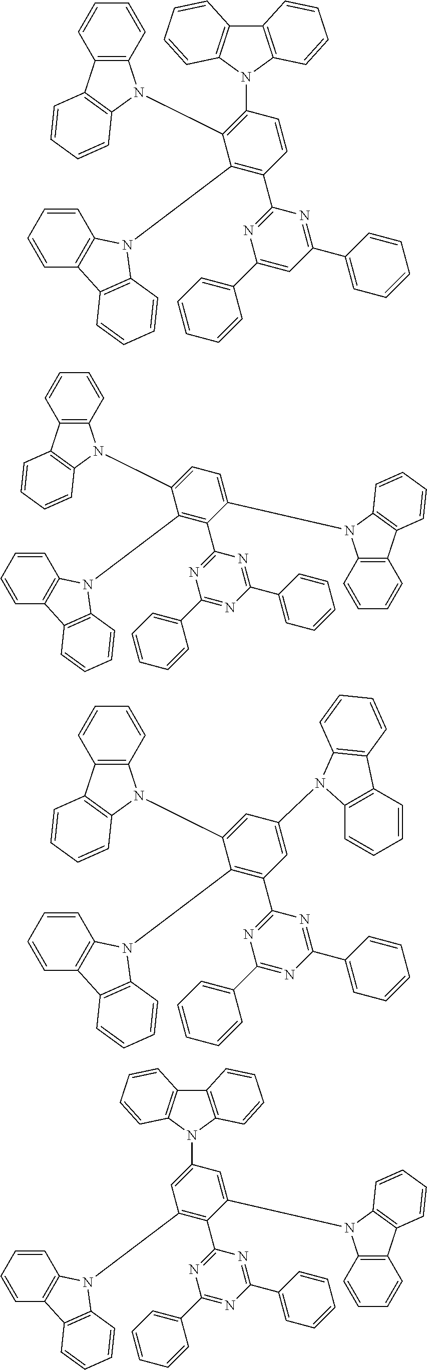

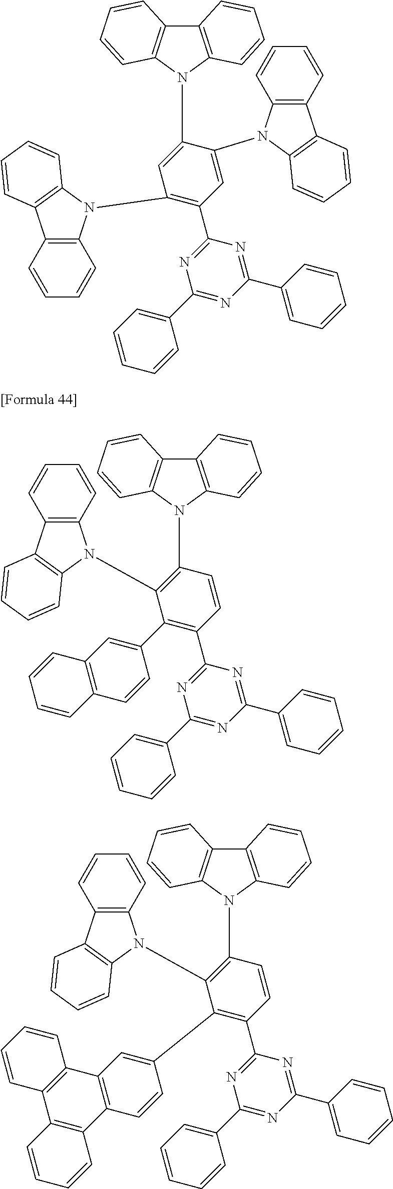

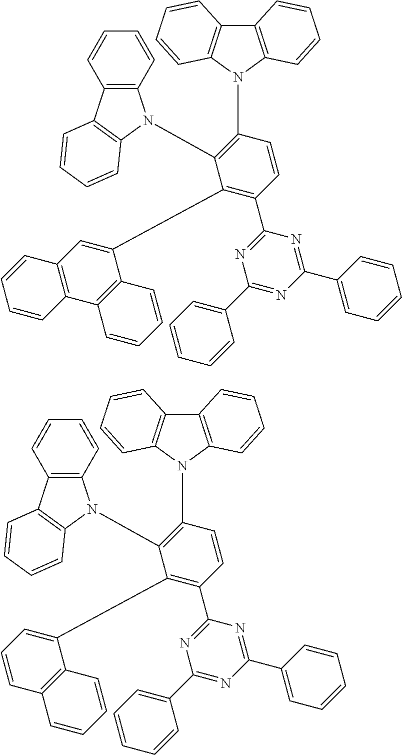

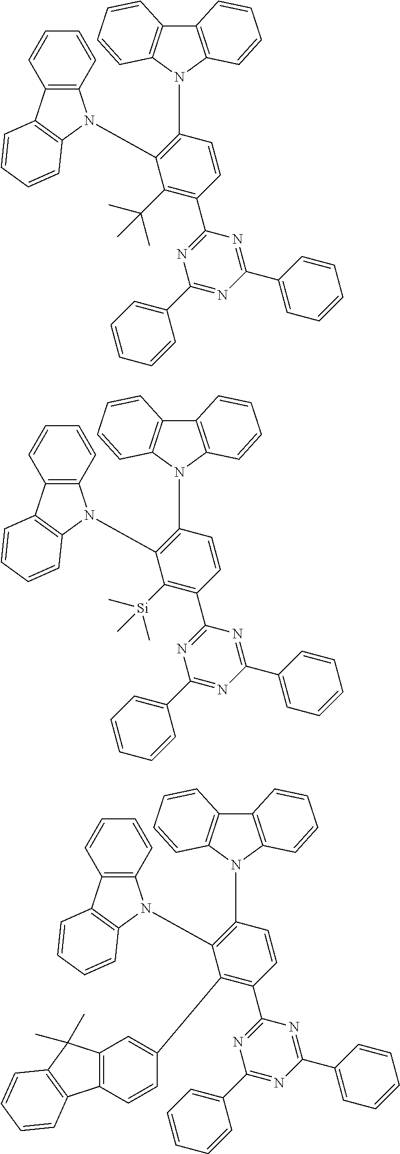

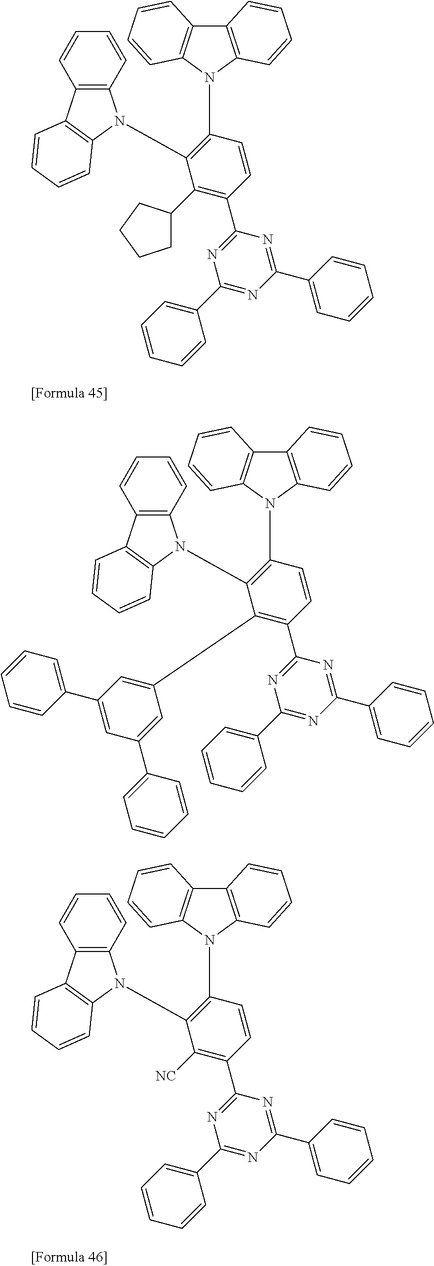

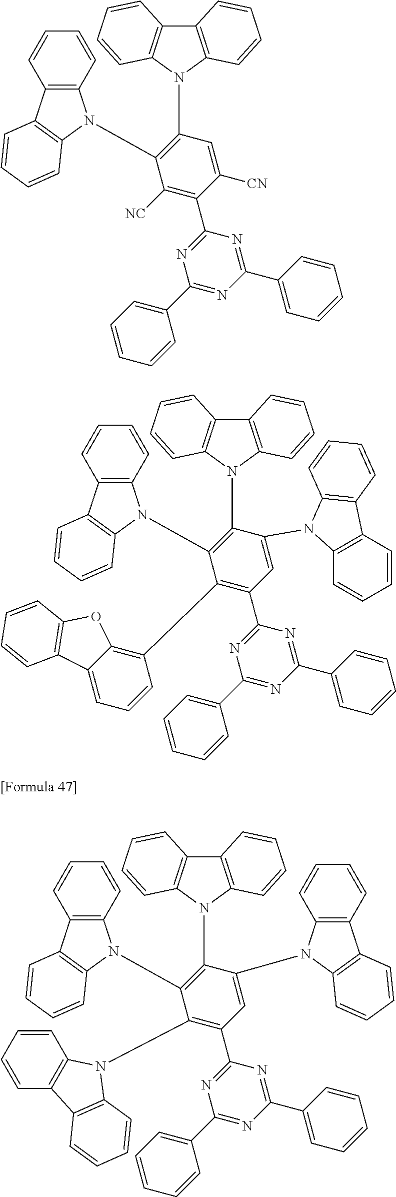

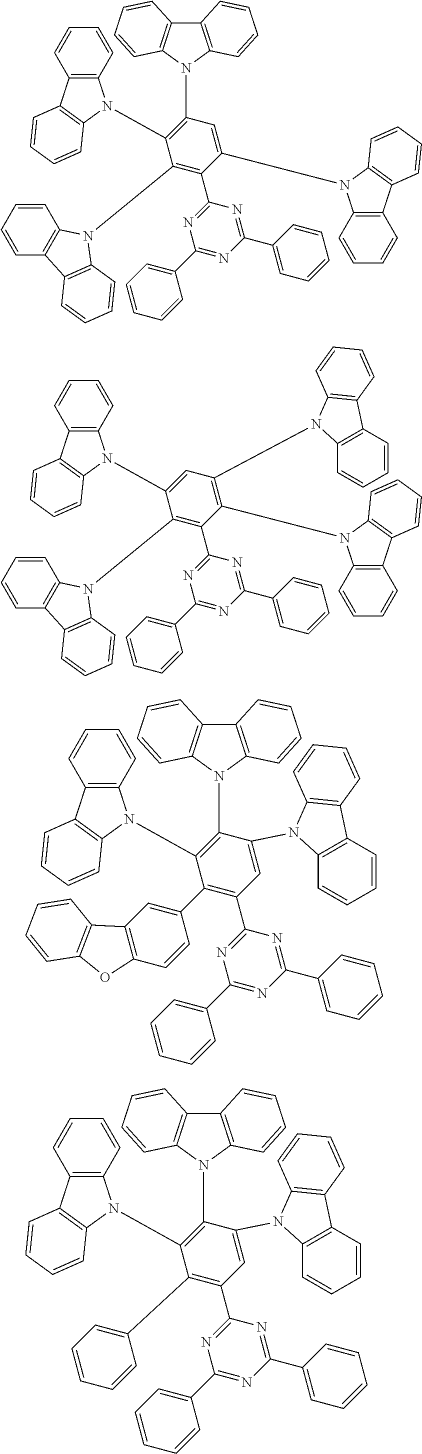

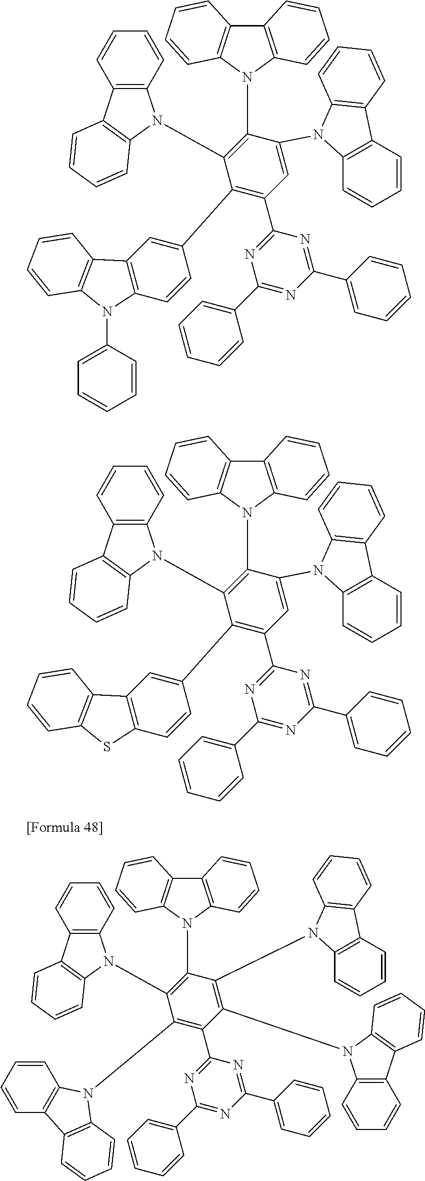 [SMILES: c1ccc(-c2nc(-c3ccccc3)nc(-c3cc(-n4c5ccccc5c5ccccc54)c(-n4c5ccccc5c5ccccc54)c(-n4c5ccccc5c5ccccc54)c3-c3ccc4c(c3)c3ccccc3n4-c3ccccc3)n2)cc1 ; c1ccc(-c2nc(-c3ccccc3)nc(-c3cc(-n4c5ccccc5c5ccccc54)c(-n4c5ccccc5c5ccccc54)c(-n4c5ccccc5c5ccccc54)c3-c3ccc4sc5ccccc5c4c3)n2)cc1 ; c1ccc(-c2nc(-c3ccccc3)nc(-c3c(-n4c5ccccc5c5ccccc54)c(-n4c5ccccc5c5ccccc54)c(-n4c5ccccc5c5ccccc54)c(-n4c5ccccc5c5ccccc54)c3-n3c4ccccc4c4ccccc43)n2)cc1]

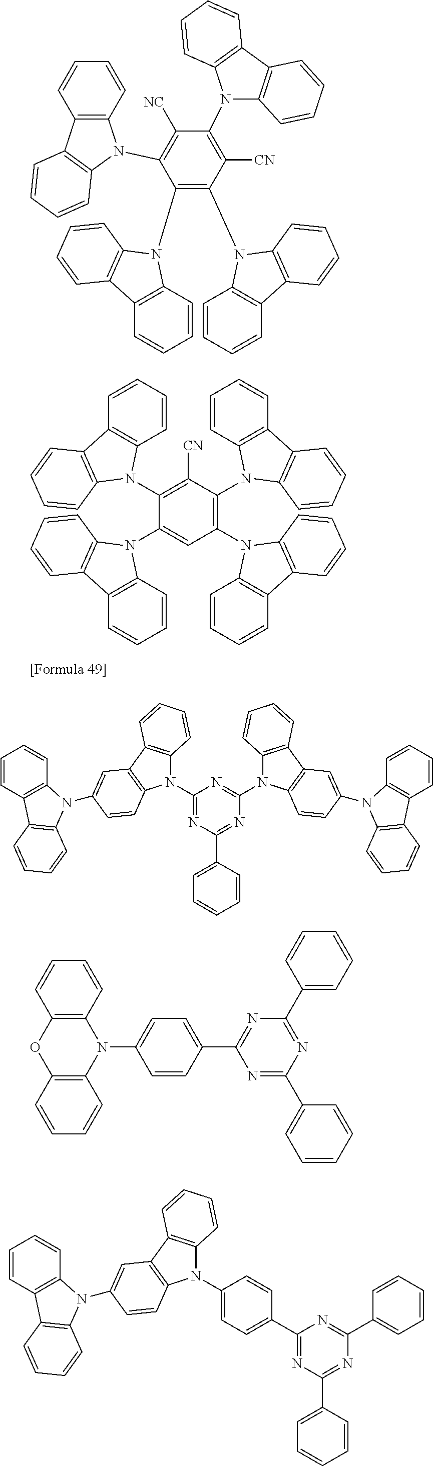

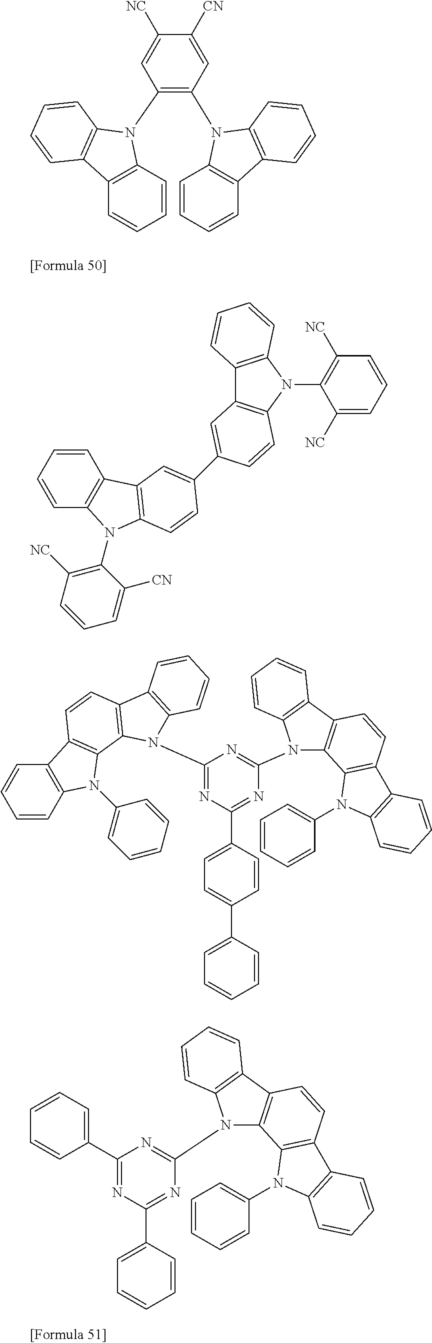

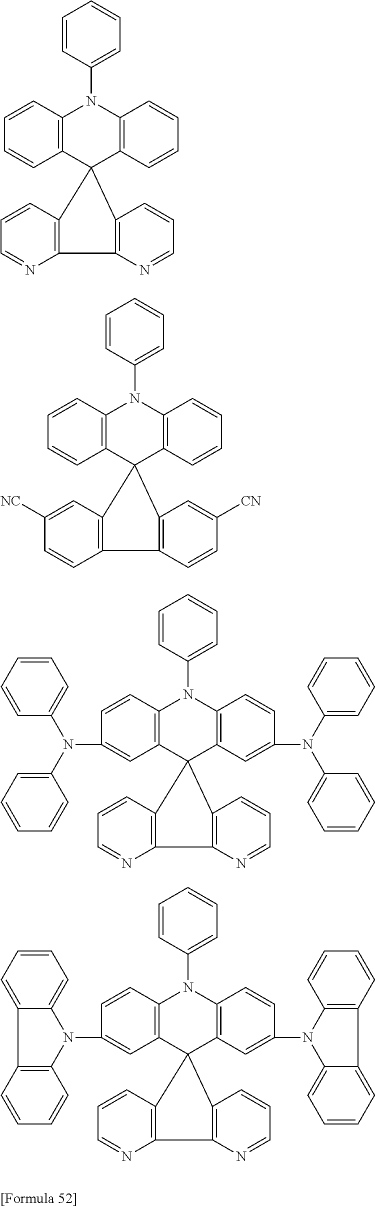

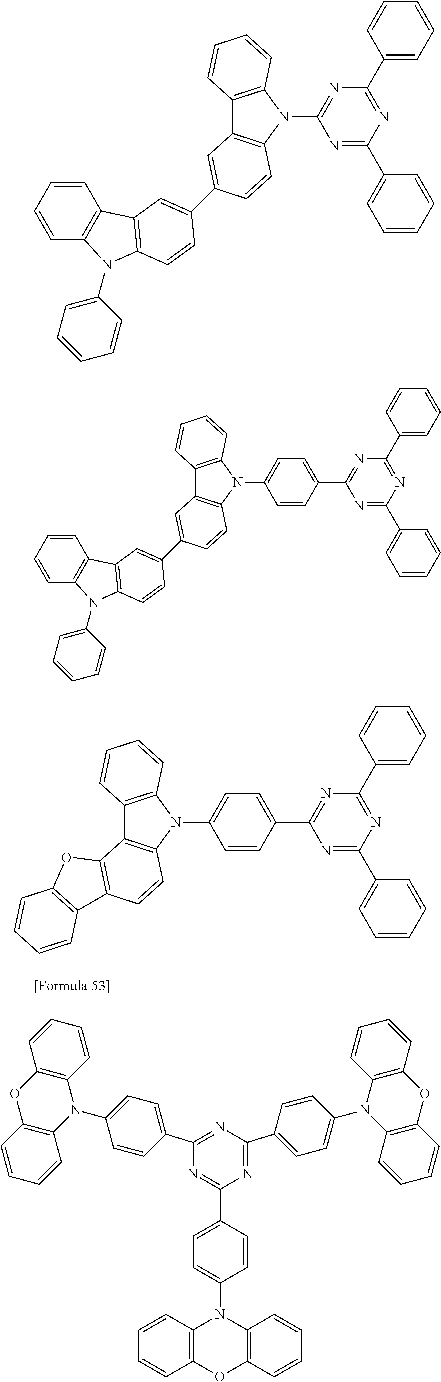 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-c3ccc(-n4c5ccccc5c5c6oc7ccccc7c6ccc54)cc3)n2)cc1 ; c1ccc2c(c1)Oc1ccccc1N2c1ccc(-c2nc(-c3ccc(N4c5ccccc5Oc5ccccc54)cc3)nc(-c3ccc(N4c5ccccc5Oc5ccccc54)cc3)n2)cc1]

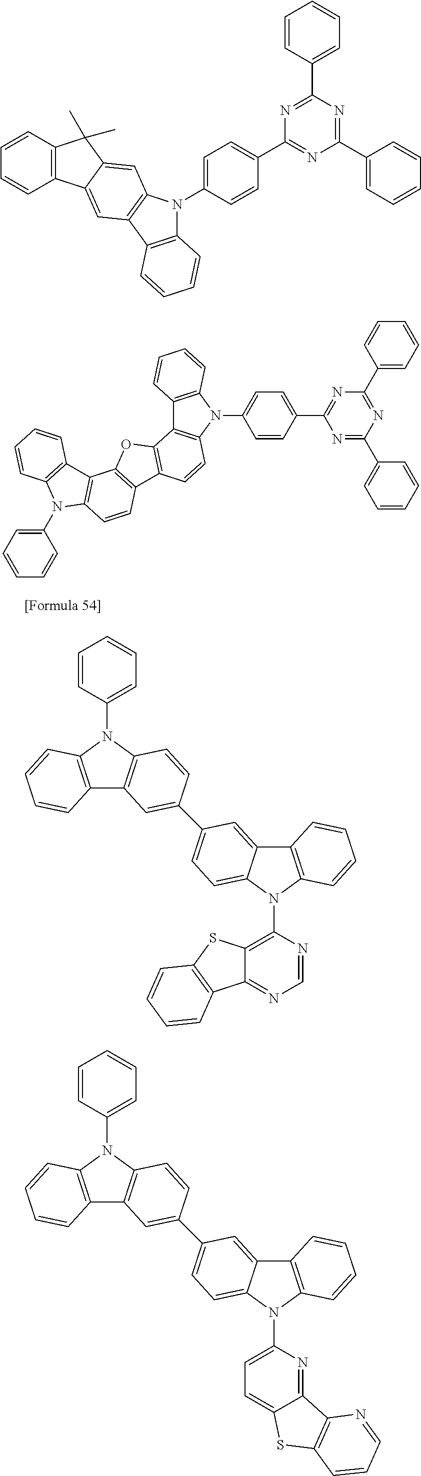 [SMILES: CC1(C)c2ccccc2-c2cc3c4ccccc4n(-c4ccc(-c5nc(-c6ccccc6)nc(-c6ccccc6)n5)cc4)c3cc21 ; c1ccc(-c2nc(-c3ccccc3)nc(-c3ccc(-n4c5ccccc5c5c6oc7c(ccc8c7c7ccccc7n8-c7ccccc7)c6ccc54)cc3)n2)cc1 ; c1ccc(-n2c3ccccc3c3cc(-c4ccc5c(c4)c4ccccc4n5-c4ncnc5c4sc4ccccc45)ccc32)cc1 ; c1ccc(-n2c3ccccc3c3cc(-c4ccc5c(c4)c4ccccc4n5-c4ccc5sc6cccnc6c5n4)ccc32)cc1]

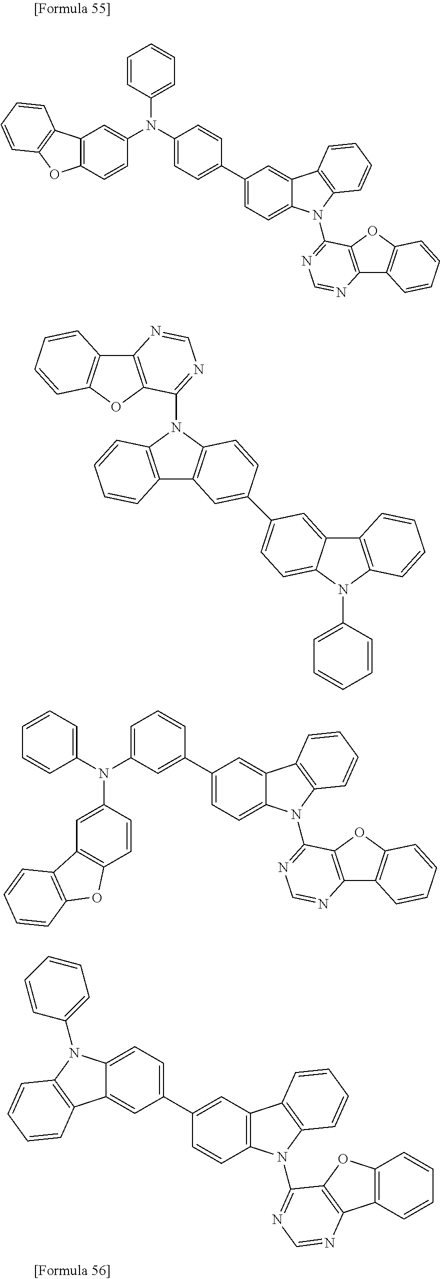

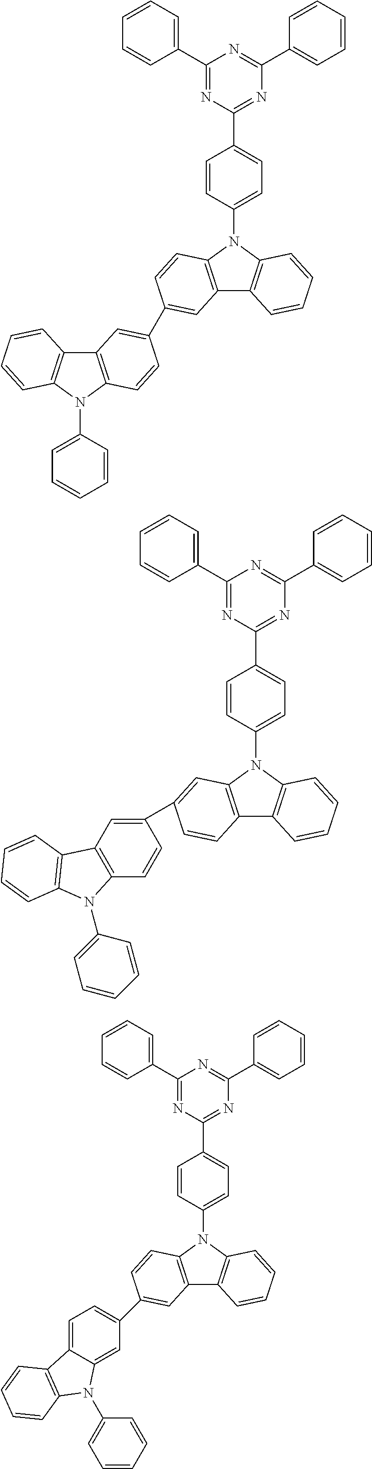

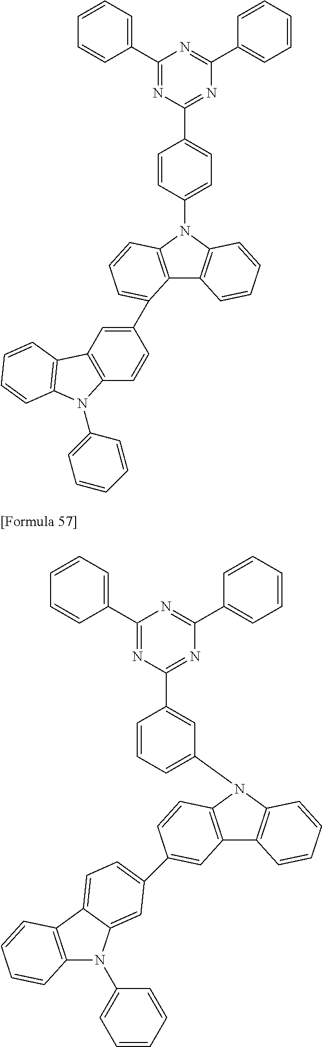 [SMILES: c1ccc(-c2nc(-c3ccccc3)nc(-c3ccc(-n4c5ccccc5c5c(-c6ccc7c(c6)c6ccccc6n7-c6ccccc6)cccc54)cc3)n2)cc1 ; c1ccc(-c2nc(-c3ccccc3)nc(-c3cccc(-n4c5ccccc5c5cc(-c6ccc7c8ccccc8n(-c8ccccc8)c7c6)ccc54)c3)n2)cc1]

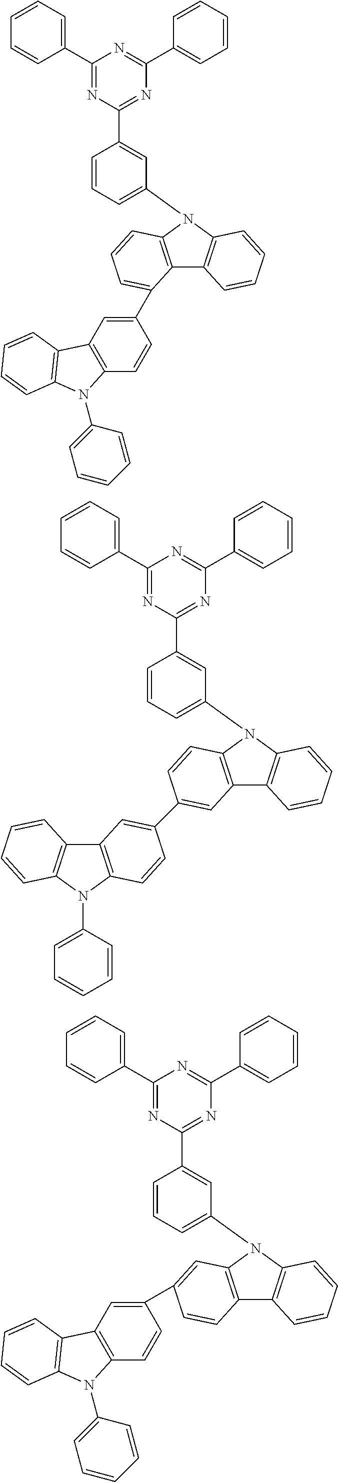

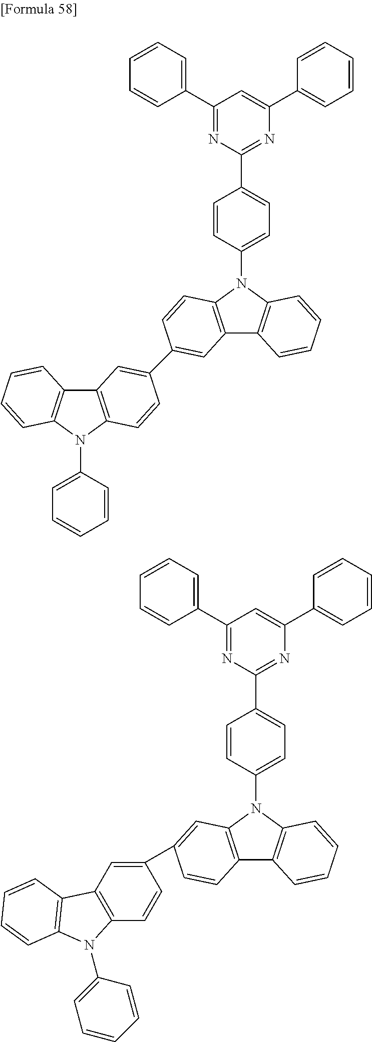 [SMILES: c1ccc(-c2cc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2cc(-c3ccccc3)nc(-c3ccc(-n4c5ccccc5c5ccc(-c6ccc7c(c6)c6ccccc6n7-c6ccccc6)cc54)cc3)n2)cc1]

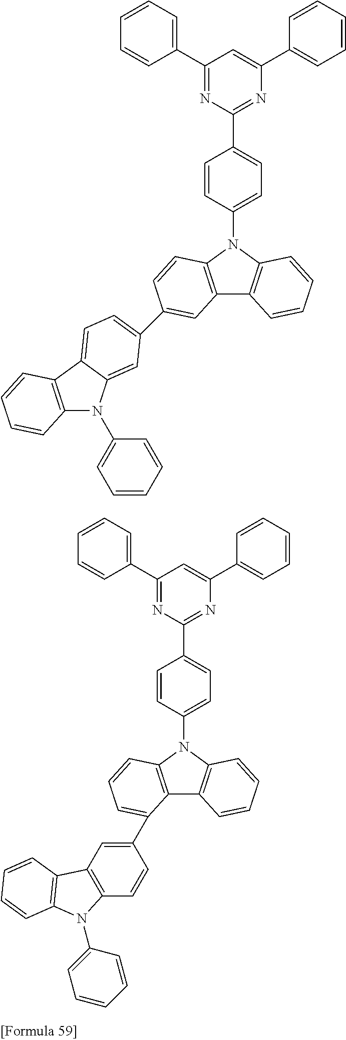

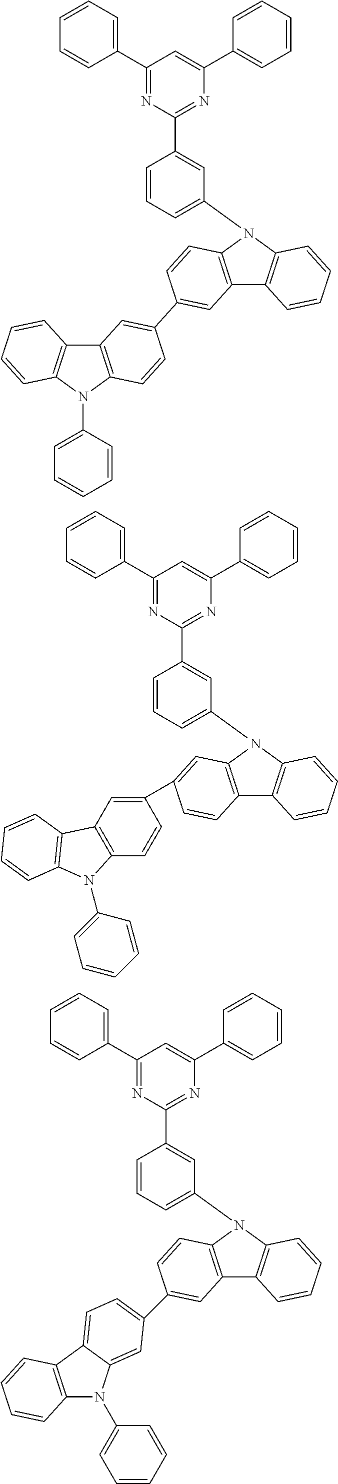

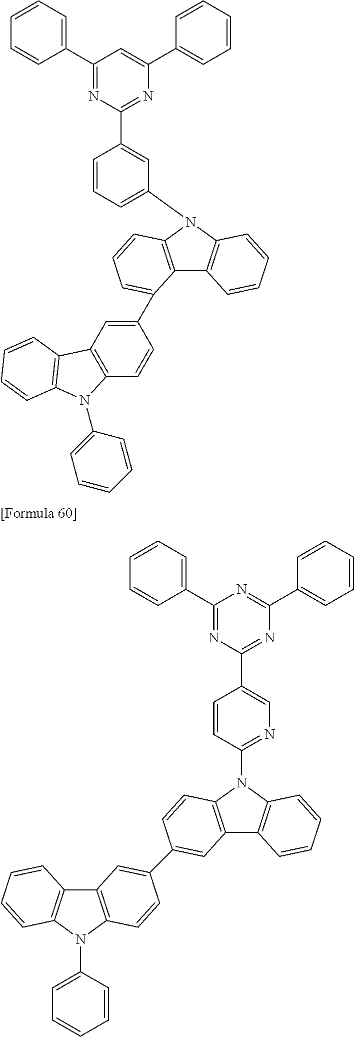 [SMILES: c1ccc(-c2cc(-c3ccccc3)nc(-c3cccc(-n4c5ccccc5c5c(-c6ccc7c(c6)c6ccccc6n7-c6ccccc6)cccc54)c3)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)nc3)n2)cc1]

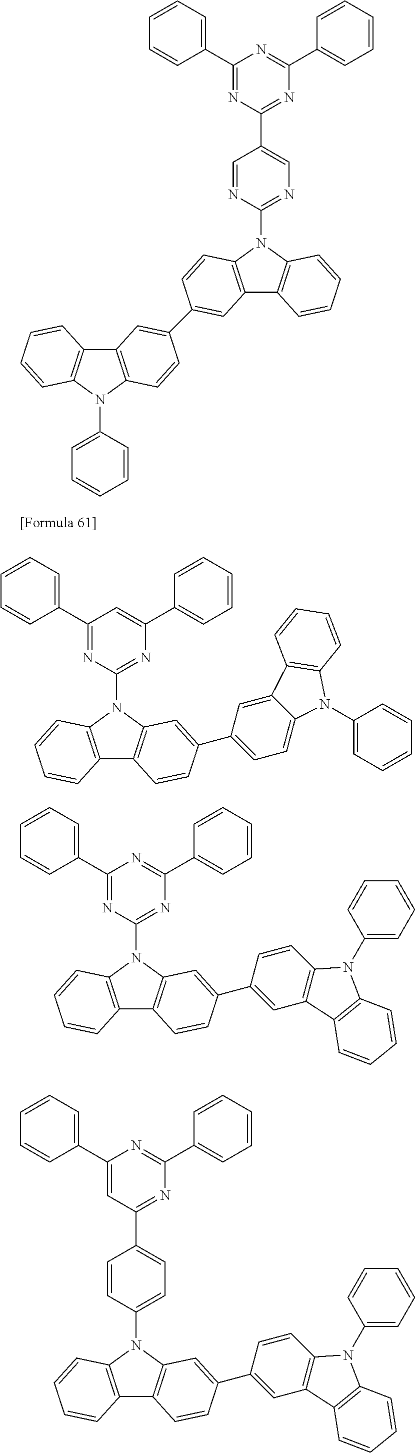

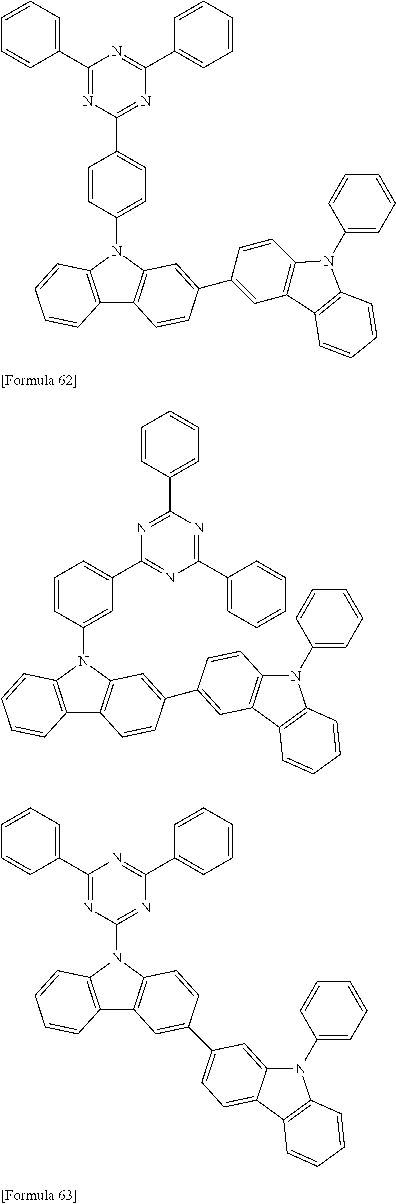 [SMILES: c1ccc(-c2nc(-c3ccccc3)nc(-c3ccc(-n4c5ccccc5c5ccc(-c6ccc7c(c6)c6ccccc6n7-c6ccccc6)cc54)cc3)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; c1ccc(-c2nc(-c3ccccc3)nc(-n3c4ccccc4c4cc(-c5ccc6c7ccccc7n(-c7ccccc7)c6c5)ccc43)n2)cc1]

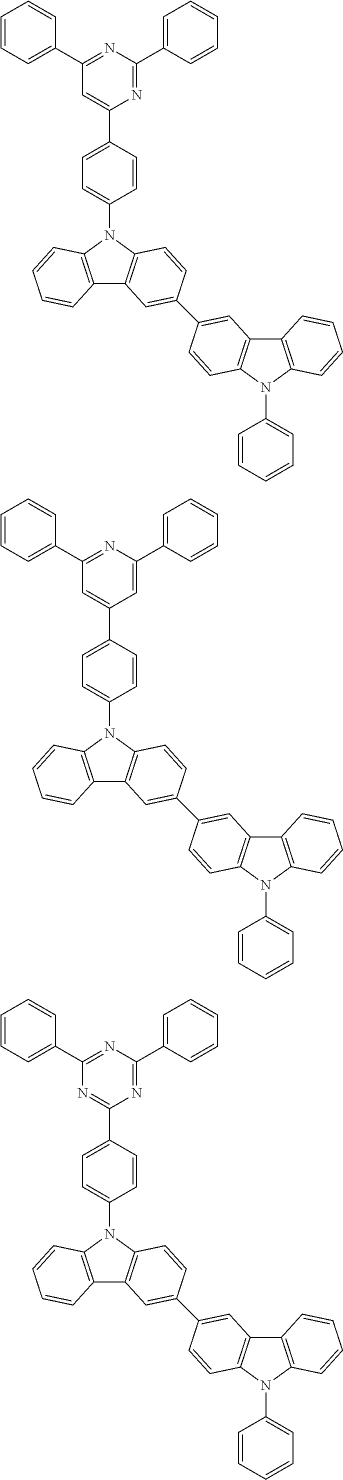 [SMILES: c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; c1ccc(-c2cc(-c3ccc(-n4c5ccccc5c5cc(-c6ccc7c(c6)c6ccccc6n7-c6ccccc6)ccc54)cc3)cc(-c3ccccc3)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

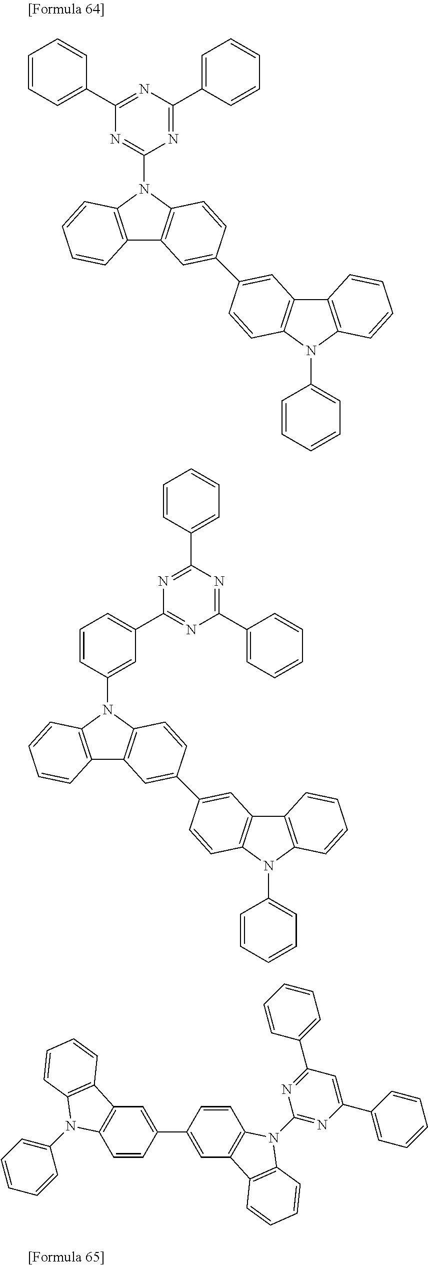

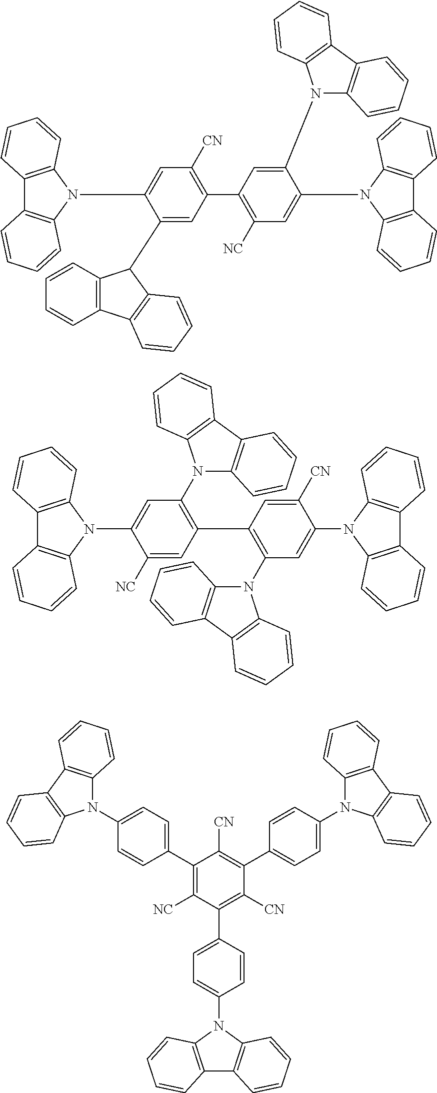

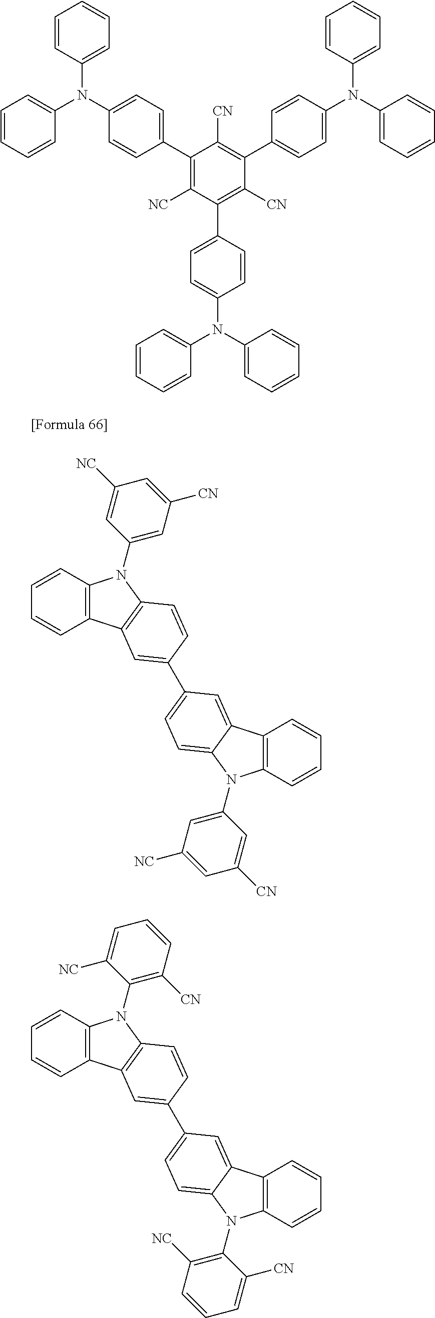 [SMILES: N#Cc1c(-c2ccc(N(c3ccccc3)c3ccccc3)cc2)c(C#N)c(-c2ccc(N(c3ccccc3)c3ccccc3)cc2)c(C#N)c1-c1ccc(N(c2ccccc2)c2ccccc2)cc1 ; N#Cc1cc(C#N)cc(-n2c3ccccc3c3cc(-c4ccc5c(c4)c4ccccc4n5-c4cc(C#N)cc(C#N)c4)ccc32)c1 ; N#Cc1cccc(C#N)c1-n1c2ccccc2c2cc(-c3ccc4c(c3)c3ccccc3n4-c3c(C#N)cccc3C#N)ccc21]

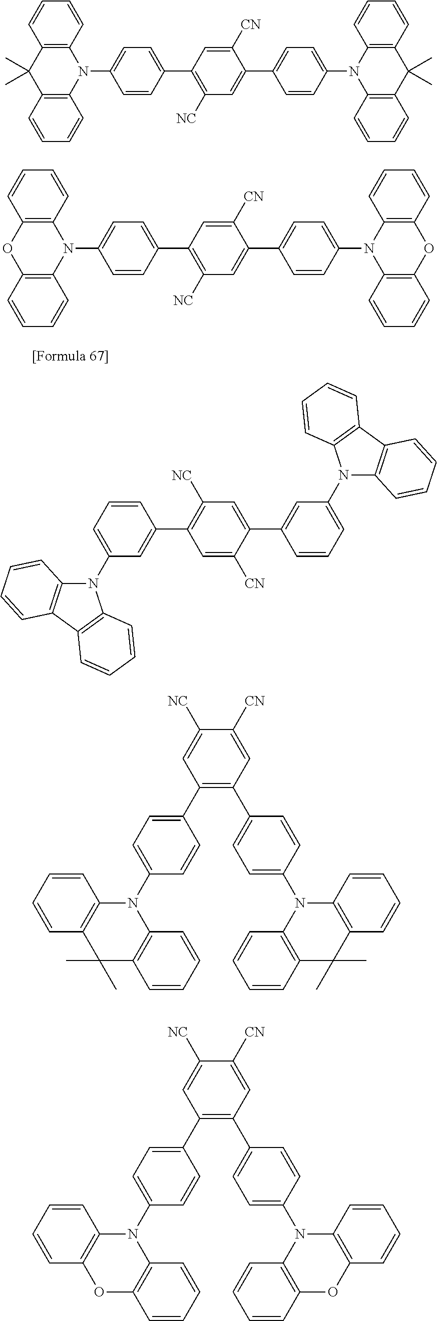

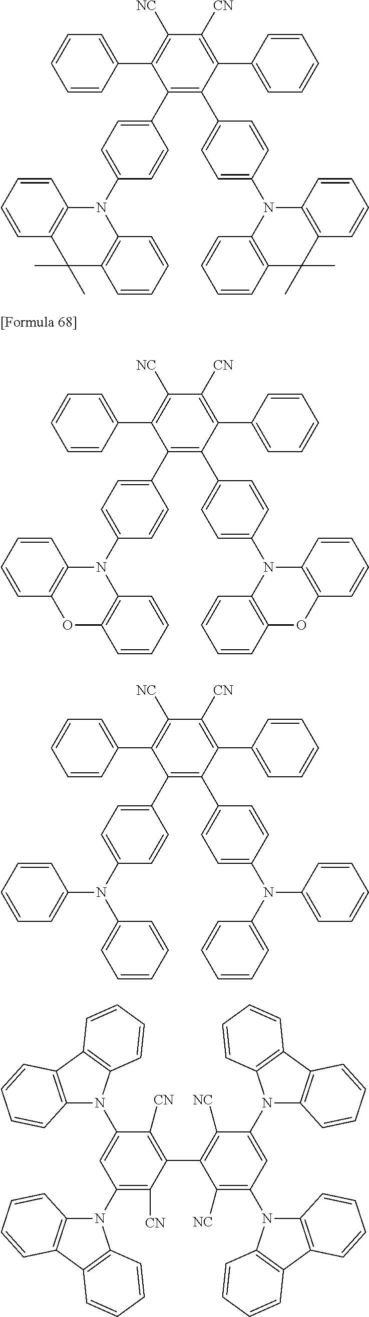

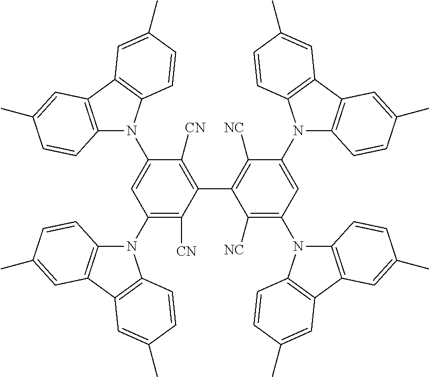

### Second Compound

The second compound is represented by a formula (2) below.

In the organic EL device of the first exemplary embodiment, the second compound is sometimes a delayed fluorescent (thermally activated delayed fluorescent) compound.

When the second compound is a delayed fluorescent compound, the delayed fluorescence of the second compound can be determined through a measurement method disclosed in Non-Patent Literature 1. For instance, Non-Patent Literature 1 discloses that a compound BN-1 (an example of the second compound) used in Example exhibits delayed fluorescence through the measurement method described in Non-Patent Literature 1.

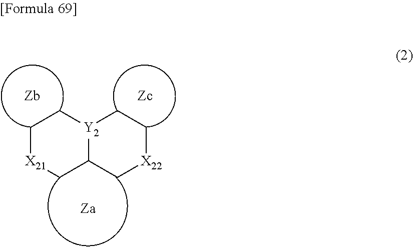

In the formula (2): Za ring, Zb ring and Zc ring are each independently a cyclic structure selected from the group consisting of a substituted or unsubstituted aryl ring having 6 to 30 ring carbon atoms, and a substituted or unsubstituted heteroaryl ring having 5 to 30 ring atoms;

X₂₁ and X₂₂ are each independently an oxygen atom, NRa (a nitrogen atom having a substituent Ra), or a sulfur atom;

when X₂₁ is NRa, Ra is bonded to Za ring or Zb ring to form a ring or is not bonded to form no ring;

When X₂₂ is NRa, Ra is bonded to Za ring or Zc ring to form a ring or is not bonded to form no ring;

Ra is each independently a group selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms;

Y₂ is any one of a boron atom, a phosphorus atom, SiRb (a silicon atom having a substituent Rb), P═O, and P═S; and

Rb is each independently a group selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms.

In the organic EL device according to the first exemplary embodiment, Ra in the formula (2) is preferably a substituted or unsubstituted aryl group having 6 to 30 ring carbon atoms, more preferably a substituted or unsubstituted phenyl group.

In the organic EL device according to the first exemplary embodiment, Za ring, Zb ring, and Zc ring in the formula (2) are preferably each independently a substituted or unsubstituted aryl ring having 6 to 30 ring carbon atoms.

In the organic EL device according to the first exemplary embodiment, when X₂₁ in the formula (2) is NRa, Ra is also preferably not bonded to any of Za ring and Zb ring to form no ring.

In the organic EL device according to the first exemplary embodiment, when X₂₂ in the formula (2) is NRa, Ra is also preferably not bonded to any of Za ring and Zc ring to form no ring.

In the organic EL device according to the first exemplary embodiment, the compound represented by the formula (2) is also preferably a compound symmetric about an x-y axis below.

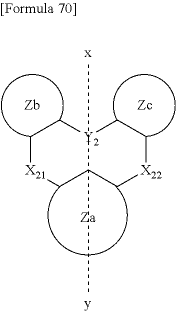

In the organic EL device of the first exemplary embodiment, Y₂ in the formula (2) is preferably a boron atom.

In the organic EL device of the first exemplary embodiment, the second compound is also preferably a compound represented by a formula (2A) below.

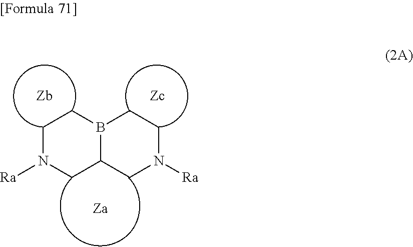

In the formula (2A), Za ring, Zb ring, Zc ring, and Ra represent the same as Za ring, Zb ring, Zc ring, and Ra in the formula (2), respectively.

In the organic EL device according to the first exemplary embodiment, Za ring, Zb ring and Zc ring in the formula (2A) are preferably each independently a substituted or unsubstituted aryl ring having 6 to 30 ring carbon atoms.

In the organic EL device according to the first exemplary embodiment, Ra in the formula (2A) is preferably a substituted or unsubstituted aryl group having 6 to 30 ring carbon atoms, more preferably a substituted or unsubstituted phenyl group.

In the organic EL device of the first exemplary embodiment, it is also preferable that Ra in the formula (2A) is not bonded to any of Za ring and Zb ring to form no ring, and Ra in the formula (2A) is not bonded to any of Za ring and Zc ring to form no ring.

In the organic EL device of the first exemplary embodiment, the second compound is also preferably a compound represented by a formula (20) below.

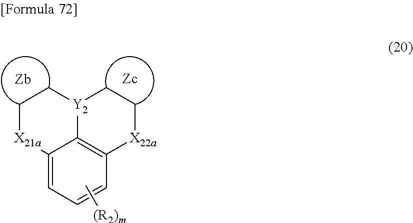

In the formula (20): X₂₁ₐ and X₂₂ₐ, which are mutually the same, are any one of oxygen atoms, NRa (nitrogen atoms each having a substituent Ra), and sulfur atoms;

m is 3;

R₂ are each independently a hydrogen atom or a substituent; and

R₂ serving as the substituents are each independently a group selected from the group consisting of a substituted or unsubstituted aryl group having 6 to 30 ring carbon atoms, a substituted or unsubstituted heteroaryl group having 5 to 30 ring atoms;

a substituted or unsubstituted alkyl group having 1 to 30 carbon atoms, a substituted or unsubstituted aryloxy group having 6 to 30 ring carbon atoms, a substituted or unsubstituted amino group, and a substituted silyl group.

In the formula (20), Zb ring, Zc ring, Y₂, and Ra represent the same as Zb ring, Zc ring, Y₂, and Ra in the formula (2), respectively.

In the formula (20), when R₂ is a substituted or unsubstituted amino group, the amino group may be a cyclic amino group. The ring of the cyclic amino group may include one or two hetero atoms selected from the group consisting of a nitrogen atom, an oxygen atom, and a sulfur atom. Examples of the cyclic amino group include a piperidinyl group and a morpholinyl group.

In the organic EL device of the first exemplary embodiment, Y₂ in the formula (20) is preferably a boron atom.

In the organic EL device according to the first exemplary embodiment, Zb ring and Zc ring in the formula (20) are preferably each independently a substituted or unsubstituted aryl ring having 6 to 30 ring carbon atoms.

In the organic EL device of the first exemplary embodiment, the second compound is also preferably a compound represented by a formula (20A) below.

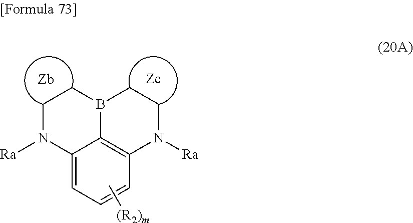

In the formula (20A), Zb ring, Zc ring, Ra, R₂, and m represent the same as Zb ring, Zc ring, Ra, R₂, and m in the formula (20), respectively.

In the organic EL device according to the first exemplary embodiment, Zb ring and Zc ring in the formula (20A) are preferably each independently a substituted or unsubstituted aryl ring having 6 to 30 ring carbon atoms.

In the organic EL device according to the first exemplary embodiment, Ra in the formula (20A) is preferably a substituted or unsubstituted aryl group having 6 to 30 ring carbon atoms, more preferably a substituted or unsubstituted phenyl group.

In the organic EL device of the first exemplary embodiment, it is also preferable that Ra in the formula (20A) is not bonded to any of Za ring in a form of a benzene ring and Zb ring to form no ring, and Ra in the formula (20A) is not bonded to any of Za ring in a form of a benzene ring and Zc ring to form no ring.

In the organic EL device of the first exemplary embodiment, the second compound is also preferably a compound represented by a formula (21) below.

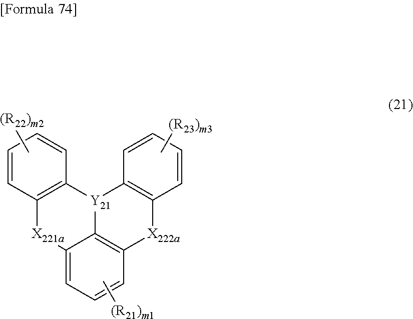

In the formula (21): X₂₂₁ₐ and X₂₂₂ₐ, which are mutually the same, are any one of oxygen atoms, NRa (carbon atoms each having a substituent Ra), and sulfur atoms;

m1 is 3, and each of m2 and m3 is 4;

R₂₁ to R₂₃ are each independently a hydrogen atom or a substituent;

R₂₁ to R₂₃ serving as the substituents are each independently a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted aryloxy group having 6 to 30 ring carbon atoms, a substituted or unsubstituted amino group, and a substituted silyl group.

In the formula (21), Y₂₁ represents the same as Y₂ in the formula (2).

The substituted or unsubstituted amino group in the formula (21) may be a cyclic amino group. Examples of the cyclic amino group are the same as described above.

In the organic EL device of the first exemplary embodiment, Y₂₁ in the formula (21) is preferably a boron atom.

In the organic EL device according to the first exemplary embodiment, Ra in the formula (21) is preferably a substituted or unsubstituted aryl group having 6 to 30 ring carbon atoms, more preferably a substituted or unsubstituted phenyl group.

In the organic EL device of the first exemplary embodiment, it is also preferable that Ra in the formula (21) is not bonded to any of Za ring in a form of a benzene ring and Zb ring in a form of a benzene ring to form no ring, and Ra in the formula (21) is not bonded to any of Za ring in a form of a benzene ring and Zc ring in a form of a benzene ring to form no ring.

In the organic EL device of the first exemplary embodiment, the second compound is also preferably a compound represented by a formula (21A) below.

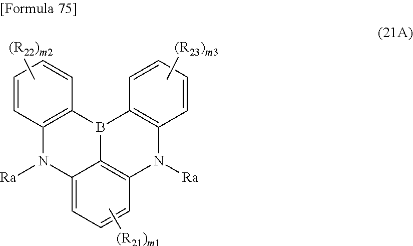

Ra, m1 to m3, and R₂₁ to R₂₃ in the formula (21A) represent the same as Ra, m1 to m3, and R₂₁ to R₂₃ in the formula (21), respectively.

In the organic EL device according to the first exemplary embodiment, Ra in the formula (21A) is preferably a substituted or unsubstituted aryl group having 6 to 30 ring carbon atoms, more preferably a substituted or unsubstituted phenyl group.

In the organic EL device of the first exemplary embodiment, it is also preferable that Ra in the formula (21A) is not bonded to any of Za ring in a form of a benzene ring and Zb ring in a form of a benzene ring to form no ring, and Ra in the formula (21A) is not bonded to any of Za ring in a form of a benzene ring and Zc ring in a form of a benzene ring to form no ring.

The main peak wavelength of the second compound is preferably in a range from 430 nm to 480 nm, more preferably in a range from 445 nm to 480 nm.

The main peak wavelength herein means a peak wavelength of emission spectrum exhibiting a maximum luminous intensity among emission spectra measured in a toluene solution in which a target compound is dissolved at a concentration in a range from 10⁻⁶ mol/L to 10⁻⁵ mol/L

The second compound preferably emits a blue fluorescence.

The second compound is preferably a material with a high emission quantum efficiency.

### Method of Manufacturing Compound

The manufacturing method of the second compound is not particularly limited, and the second compound can be manufactured through known methods.

Specific examples of the second compound of the exemplary embodiment are shown below. The second compound according to the invention is not limited to these specific examples.

R in the specific examples below are each independently a hydrogen atom or a substituent;

R serving as the substituents are each independently a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted aryloxy group having 6 to ring carbon atoms, a substituted or unsubstituted amino group (including a cyclic amino group), and a substituted silyl group.

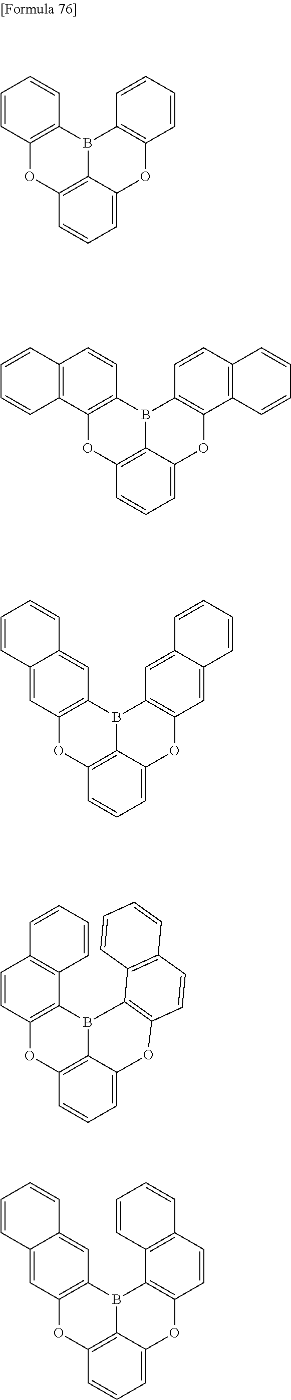 [SMILES: c1ccc2c(c1)Oc1cccc3c1B2c1ccccc1O3 ; c1cc2c3c(c1)Oc1c(ccc4ccccc14)B3c1ccc3ccccc3c1O2 ; c1cc2c3c(c1)Oc1cc4ccccc4cc1B3c1cc3ccccc3cc1O2 ; c1cc2c3c(c1)Oc1ccc4ccccc4c1B3c1c(ccc3ccccc13)O2 ; c1cc2c3c(c1)Oc1ccc4ccccc4c1B3c1cc3ccccc3cc1O2]

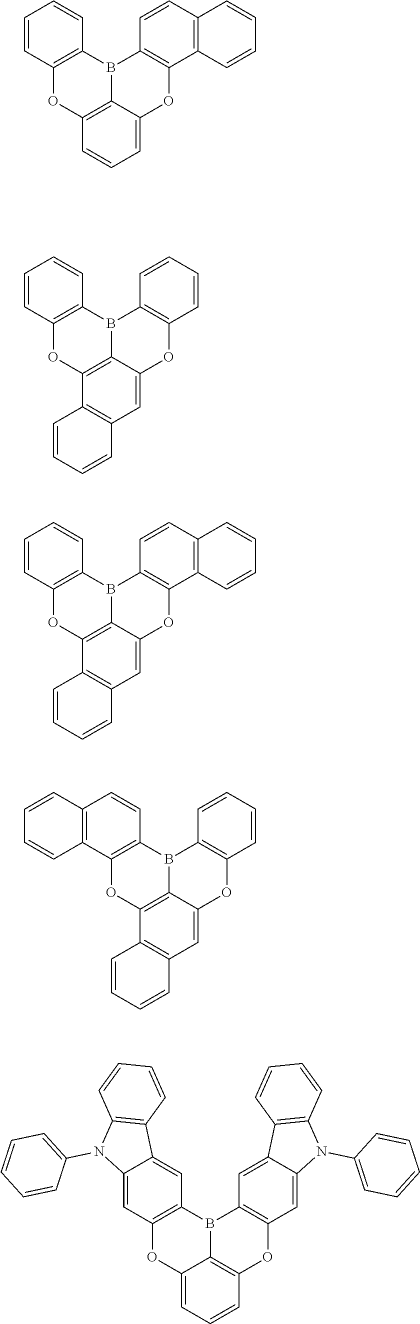 [SMILES: c1ccc2c(c1)Oc1cccc3c1B2c1ccc2ccccc2c1O3 ; c1ccc2c(c1)Oc1cc3ccccc3c3c1B2c1ccccc1O3 ; c1ccc2c(c1)Oc1c3c(cc4ccccc14)Oc1c(ccc4ccccc14)B23 ; c1ccc2c(c1)Oc1cc3ccccc3c3c1B2c1ccc2ccccc2c1O3 ; c1ccc(-n2c3ccccc3c3cc4c(cc32)Oc2cccc3c2B4c2cc4c5ccccc5n(-c5ccccc5)c4cc2O3)cc1]

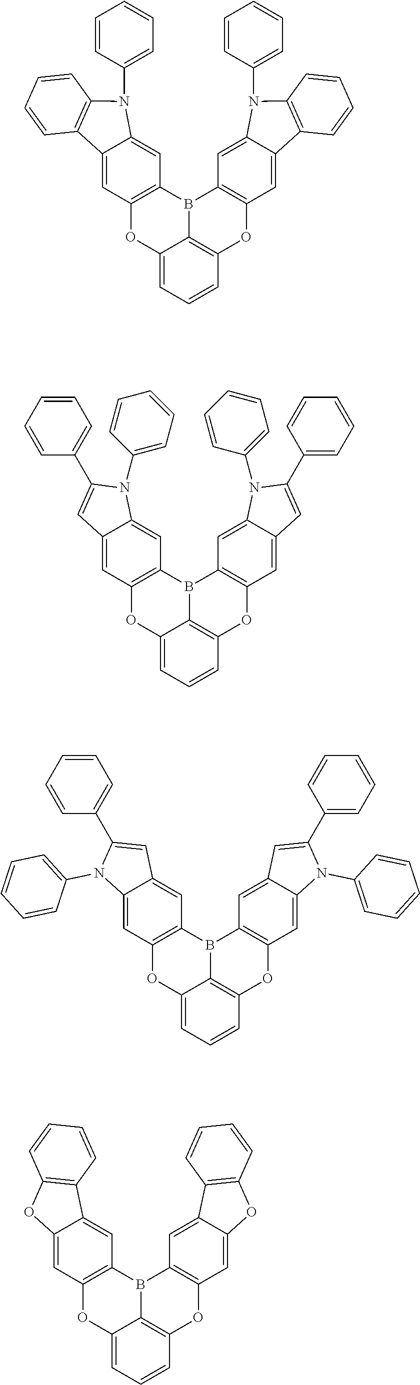 [SMILES: c1ccc(-n2c3ccccc3c3cc4c(cc32)B2c3cc5c(cc3Oc3cccc(c32)O4)c2ccccc2n5-c2ccccc2)cc1 ; c1ccc(-c2cc3cc4c(cc3n2-c2ccccc2)B2c3cc5c(cc3Oc3cccc(c32)O4)cc(-c2ccccc2)n5-c2ccccc2)cc1 ; c1ccc(-c2cc3cc4c(cc3n2-c2ccccc2)Oc2cccc3c2B4c2cc4cc(-c5ccccc5)n(-c5ccccc5)c4cc2O3)cc1 ; c1cc2c3c(c1)Oc1cc4oc5ccccc5c4cc1B3c1cc3c(cc1O2)oc1ccccc13]

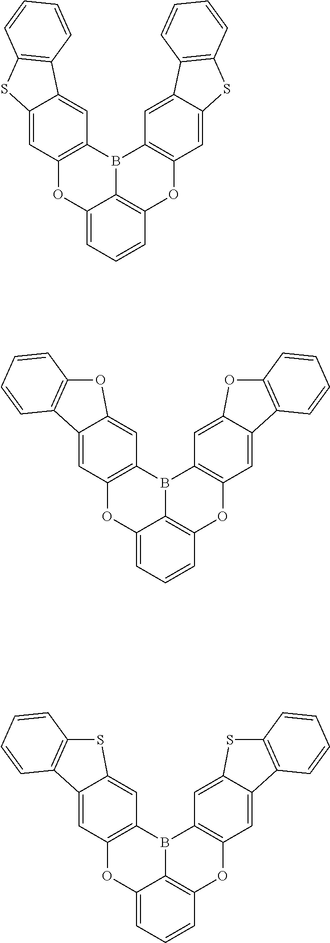 [SMILES: c1cc2c3c(c1)Oc1cc4sc5ccccc5c4cc1B3c1cc3c(cc1O2)sc1ccccc13 ; c1cc2c3c(c1)Oc1cc4c(cc1B3c1cc3oc5ccccc5c3cc1O2)oc1ccccc14 ; c1cc2c3c(c1)Oc1cc4c(cc1B3c1cc3sc5ccccc5c3cc1O2)sc1ccccc14]

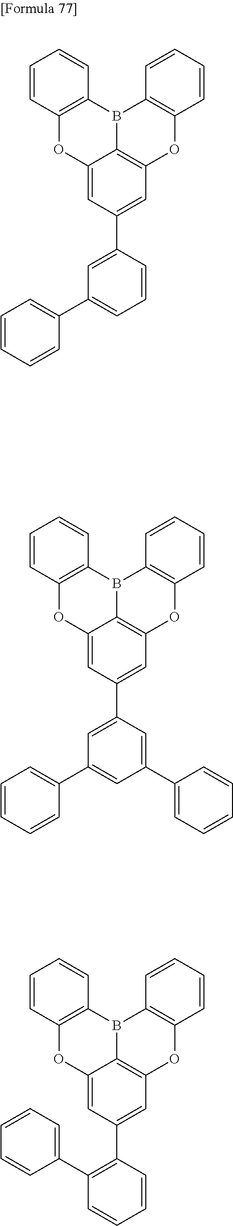 [SMILES: c1ccc(-c2cccc(-c3cc4c5c(c3)Oc3ccccc3B5c3ccccc3O4)c2)cc1 ; c1ccc(-c2cc(-c3ccccc3)cc(-c3cc4c5c(c3)Oc3ccccc3B5c3ccccc3O4)c2)cc1 ; c1ccc(-c2ccccc2-c2cc3c4c(c2)Oc2ccccc2B4c2ccccc2O3)cc1]

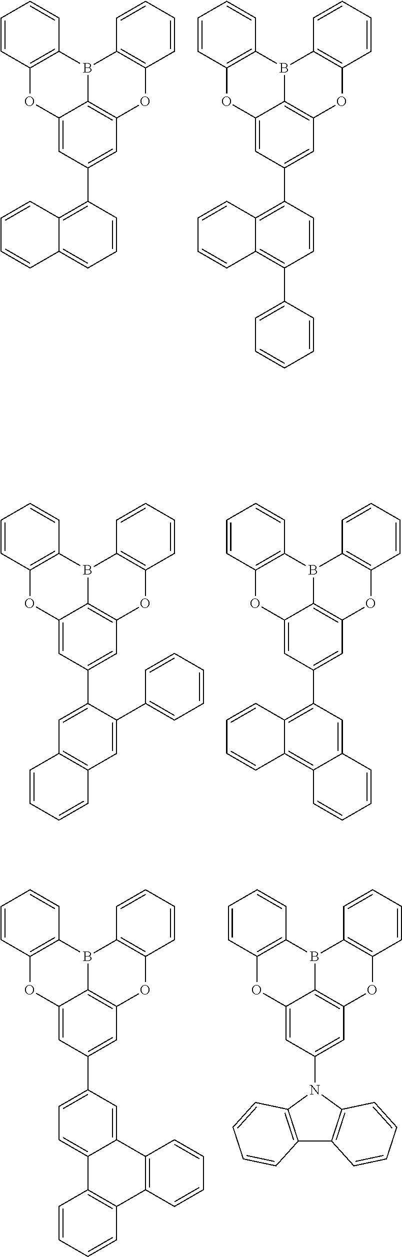

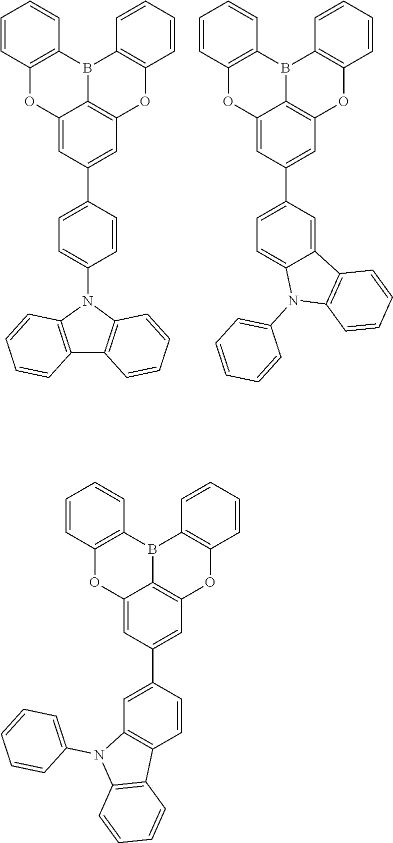

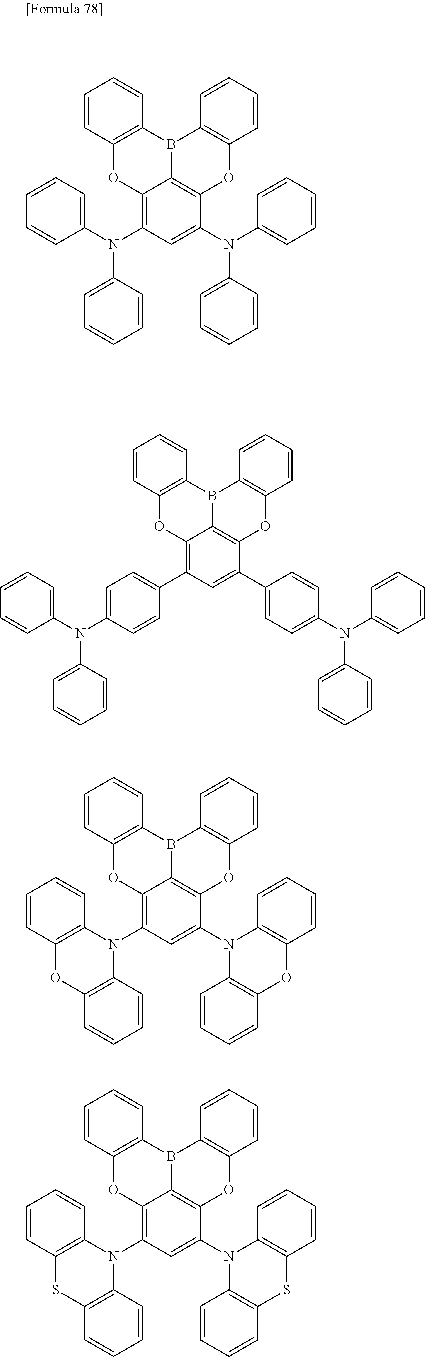

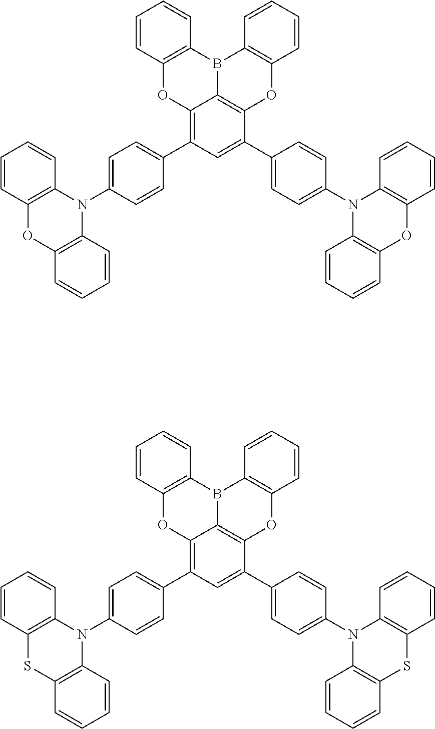 [SMILES: c1ccc2c(c1)Oc1c(-c3ccc(N4c5ccccc5Oc5ccccc54)cc3)cc(-c3ccc(N4c5ccccc5Oc5ccccc54)cc3)c3c1B2c1ccccc1O3 ; c1ccc2c(c1)Oc1c(-c3ccc(N4c5ccccc5Sc5ccccc54)cc3)cc(-c3ccc(N4c5ccccc5Sc5ccccc54)cc3)c3c1B2c1ccccc1O3]

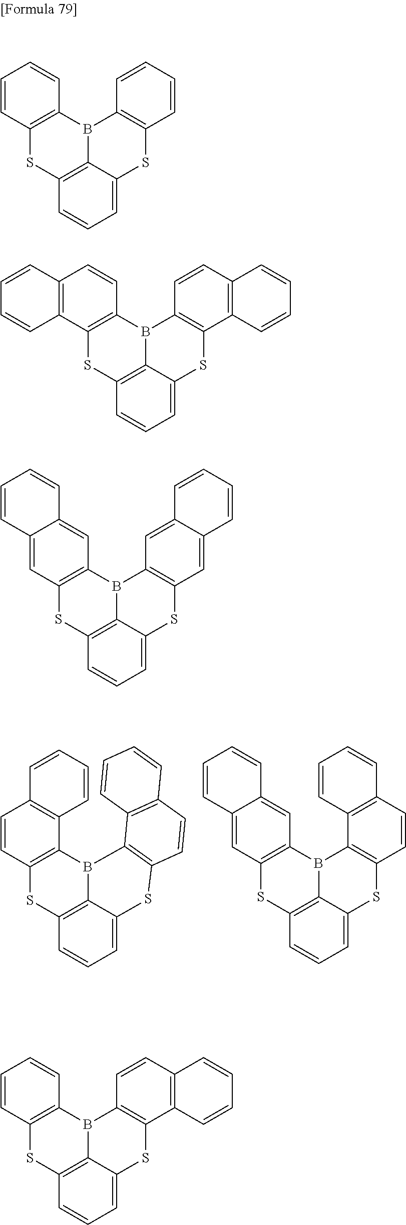

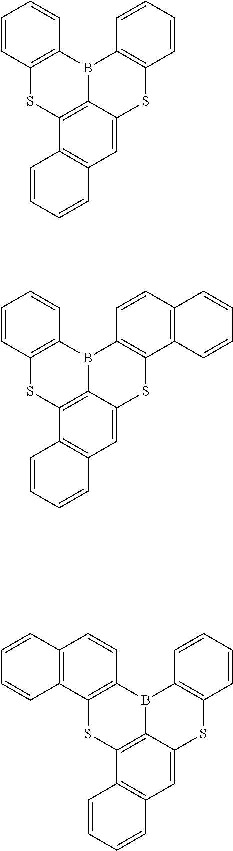 [SMILES: c1ccc2c(c1)Sc1cc3ccccc3c3c1B2c1ccccc1S3 ; c1ccc2c(c1)Sc1c3c(cc4ccccc14)Sc1c(ccc4ccccc14)B23 ; c1ccc2c(c1)Sc1cc3ccccc3c3c1B2c1ccc2ccccc2c1S3]

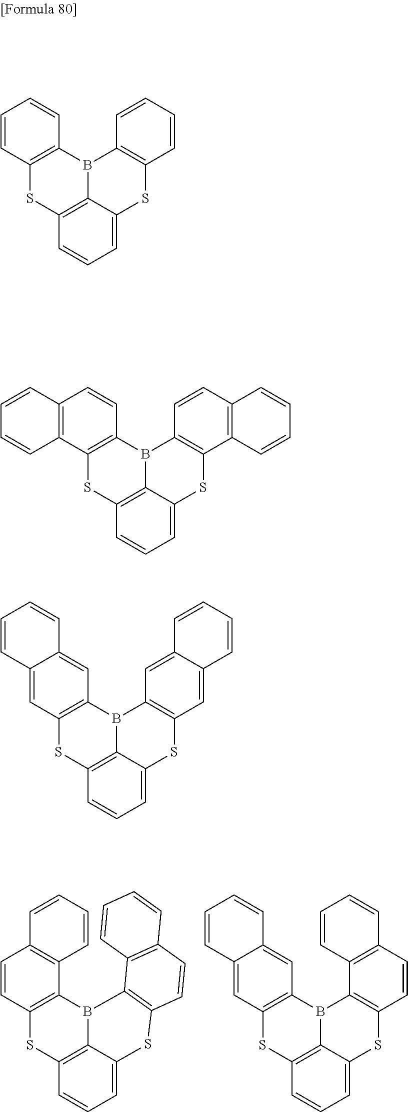

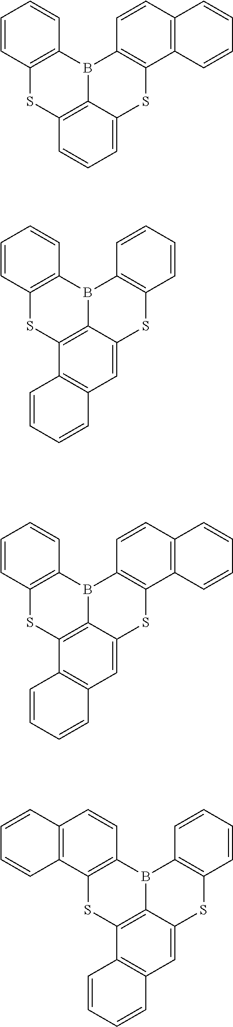 [SMILES: c1ccc2c(c1)Sc1cccc3c1B2c1ccc2ccccc2c1S3 ; c1ccc2c(c1)Sc1cc3ccccc3c3c1B2c1ccccc1S3 ; c1ccc2c(c1)Sc1c3c(cc4ccccc14)Sc1c(ccc4ccccc14)B23 ; c1ccc2c(c1)Sc1cc3ccccc3c3c1B2c1ccc2ccccc2c1S3]

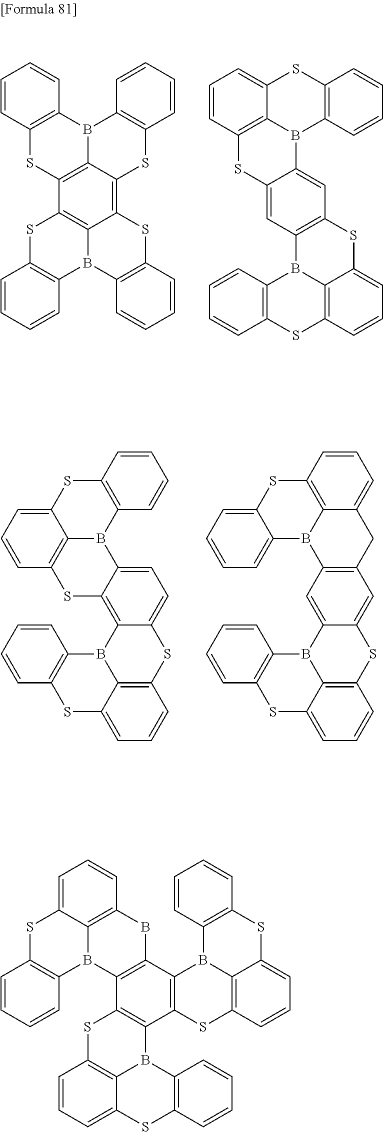

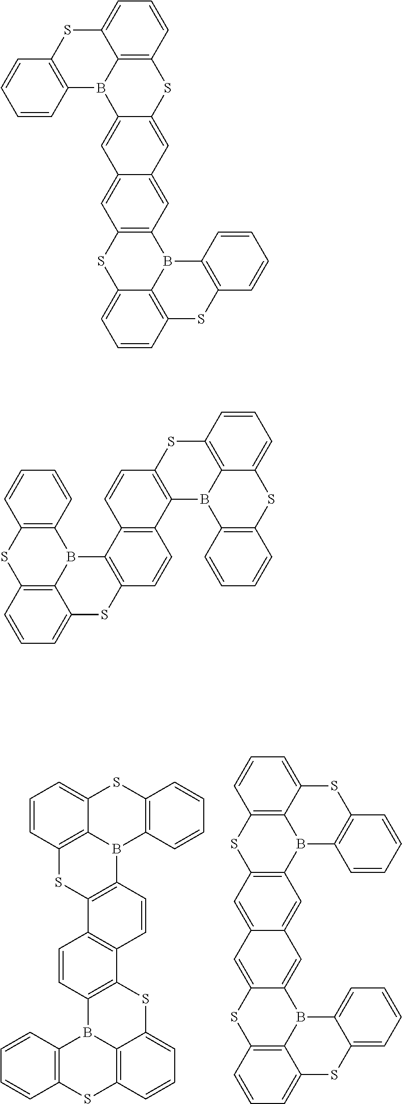

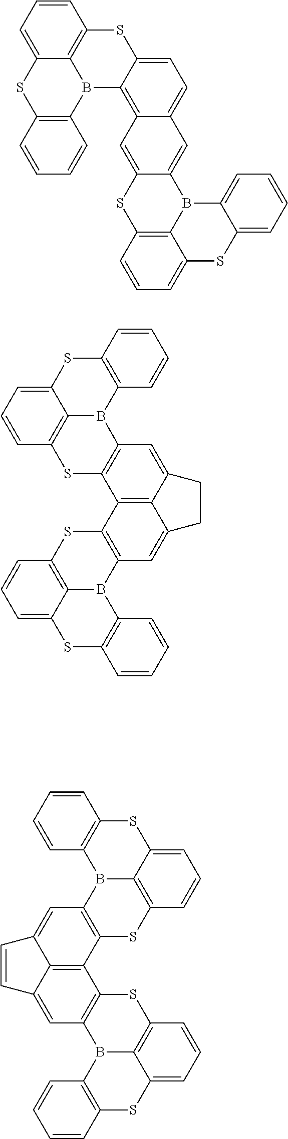

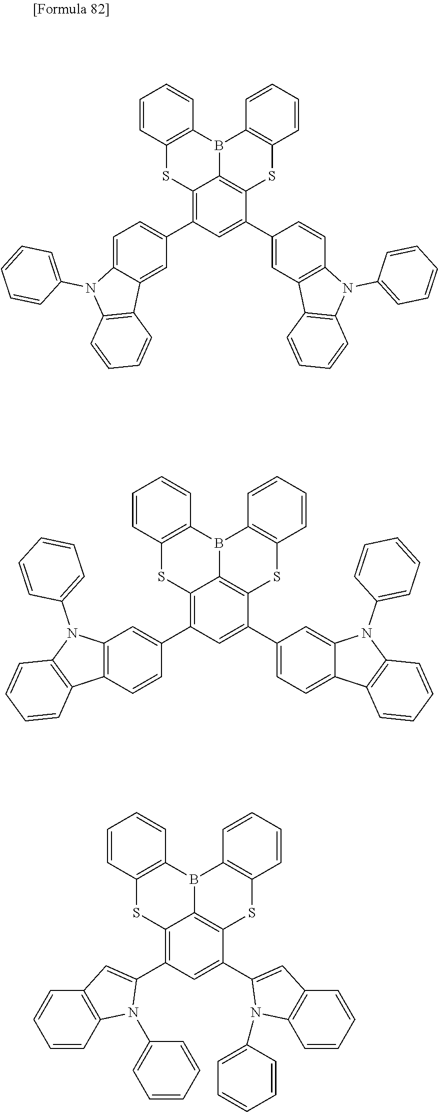 [SMILES: c1ccc(-n2c3ccccc3c3cc(-c4cc(-c5ccc6c(c5)c5ccccc5n6-c5ccccc5)c5c6c4Sc4ccccc4B6c4ccccc4S5)ccc32)cc1 ; c1ccc(-n2c3ccccc3c3ccc(-c4cc(-c5ccc6c7ccccc7n(-c7ccccc7)c6c5)c5c6c4Sc4ccccc4B6c4ccccc4S5)cc32)cc1 ; c1ccc(-n2c(-c3cc(-c4cc5ccccc5n4-c4ccccc4)c4c5c3Sc3ccccc3B5c3ccccc3S4)cc3ccccc32)cc1]

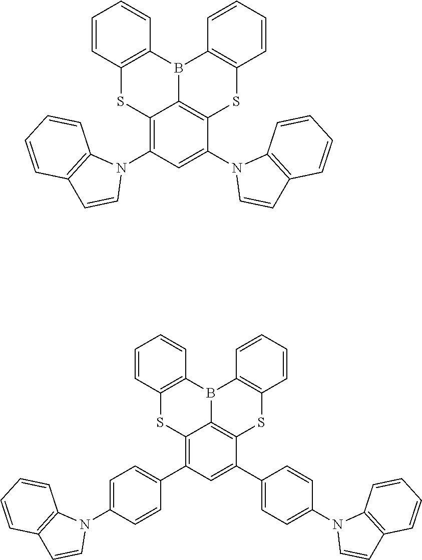 [SMILES: c1ccc2c(c1)Sc1c(-n3ccc4ccccc43)cc(-n3ccc4ccccc43)c3c1B2c1ccccc1S3 ; c1ccc2c(c1)Sc1c(-c3ccc(-n4ccc5ccccc54)cc3)cc(-c3ccc(-n4ccc5ccccc54)cc3)c3c1B2c1ccccc1S3]

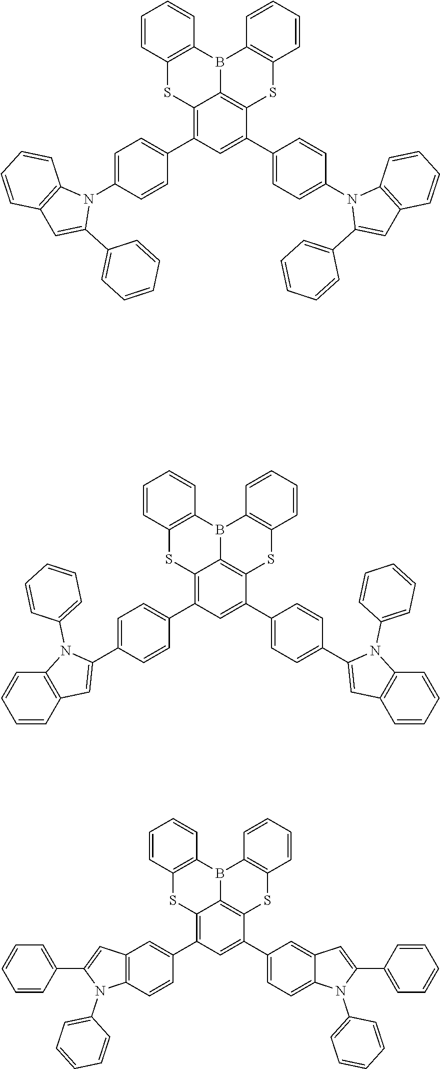 [SMILES: c1ccc(-c2cc3ccccc3n2-c2ccc(-c3cc(-c4ccc(-n5c(-c6ccccc6)cc6ccccc65)cc4)c4c5c3Sc3ccccc3B5c3ccccc3S4)cc2)cc1 ; c1ccc(-n2c(-c3ccc(-c4cc(-c5ccc(-c6cc7ccccc7n6-c6ccccc6)cc5)c5c6c4Sc4ccccc4B6c4ccccc4S5)cc3)cc3ccccc32)cc1 ; c1ccc(-c2cc3cc(-c4cc(-c5ccc6c(c5)cc(-c5ccccc5)n6-c5ccccc5)c5c6c4Sc4ccccc4B6c4ccccc4S5)ccc3n2-c2ccccc2)cc1]

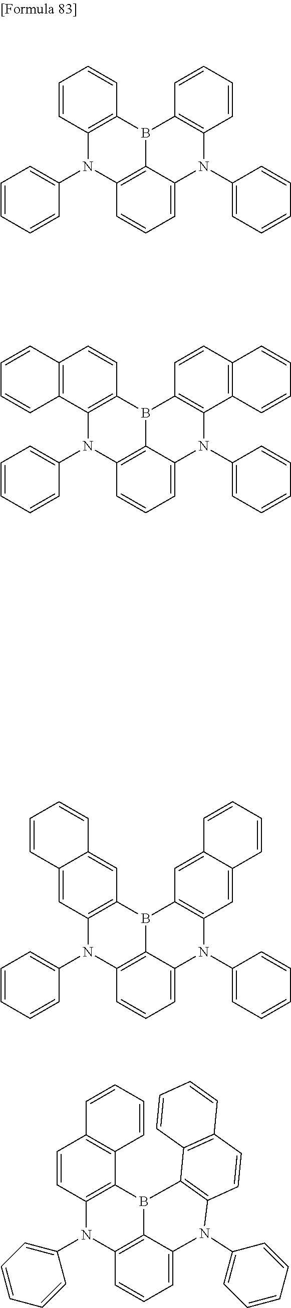 [SMILES: c1ccc(N2c3ccccc3B3c4ccccc4N(c4ccccc4)c4cccc2c43)cc1 ; c1ccc(N2c3cccc4c3B(c3ccc5ccccc5c32)c2ccc3ccccc3c2N4c2ccccc2)cc1 ; c1ccc(N2c3cc4ccccc4cc3B3c4cc5ccccc5cc4N(c4ccccc4)c4cccc2c43)cc1 ; c1ccc(N2c3cccc4c3B(c3c2ccc2ccccc32)c2c(ccc3ccccc23)N4c2ccccc2)cc1]

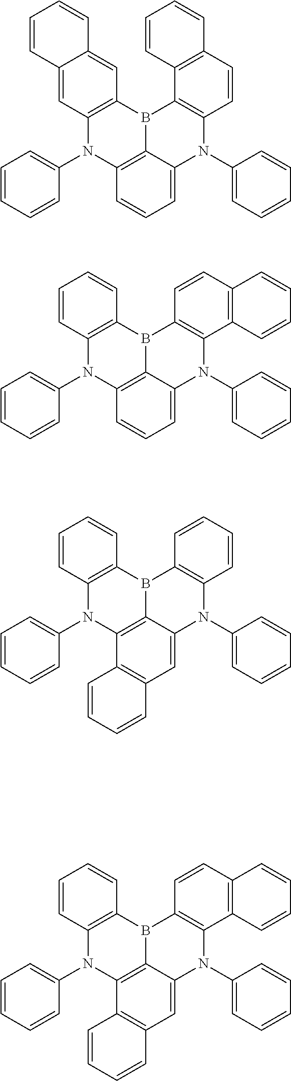 [SMILES: c1ccc(N2c3cc4ccccc4cc3B3c4c2cccc4N(c2ccccc2)c2ccc4ccccc4c23)cc1 ; c1ccc(N2c3ccccc3B3c4ccc5ccccc5c4N(c4ccccc4)c4cccc2c43)cc1 ; c1ccc(N2c3ccccc3B3c4ccccc4N(c4ccccc4)c4c3c2cc2ccccc42)cc1 ; c1ccc(N2c3cc4ccccc4c4c3B(c3ccccc3N4c3ccccc3)c3ccc4ccccc4c32)cc1]

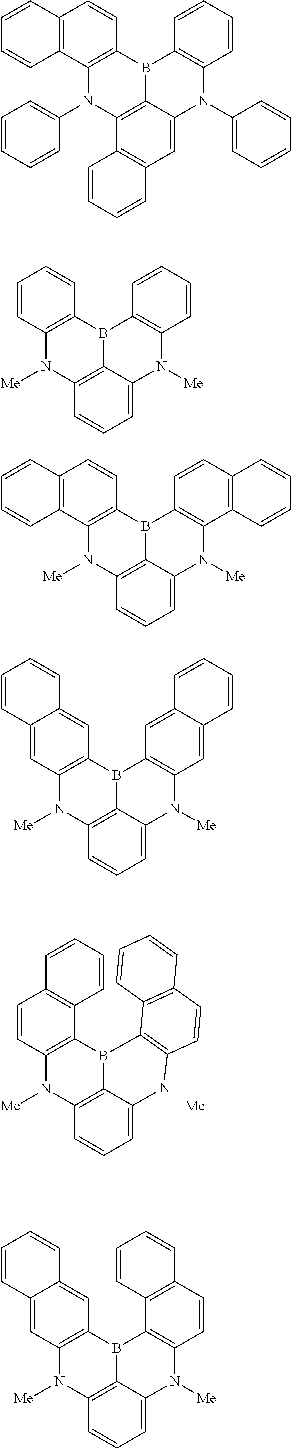

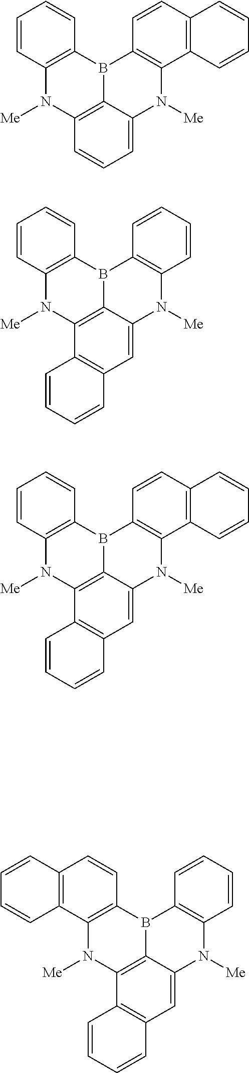 [SMILES: CN1c2ccccc2B2c3ccc4ccccc4c3N(C)c3cccc1c32 ; CN1c2ccccc2B2c3ccccc3N(C)c3c2c1cc1ccccc31 ; CN1c2cc3ccccc3c3c2B(c2ccccc2N3C)c2ccc3ccccc3c21 ; CN1c2ccccc2B2c3ccc4ccccc4c3N(C)c3c2c1cc1ccccc31]

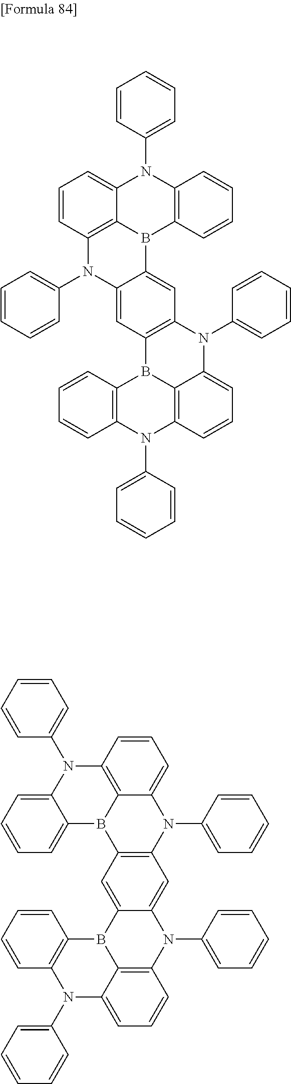 [SMILES: c1ccc(N2c3ccccc3B3c4cc5c(cc4N(c4ccccc4)c4cccc2c43)B2c3ccccc3N(c3ccccc3)c3cccc(c32)N5c2ccccc2)cc1 ; c1ccc(N2c3ccccc3B3c4cc5c(cc4N(c4ccccc4)c4cccc2c43)N(c2ccccc2)c2cccc3c2B5c2ccccc2N3c2ccccc2)cc1]

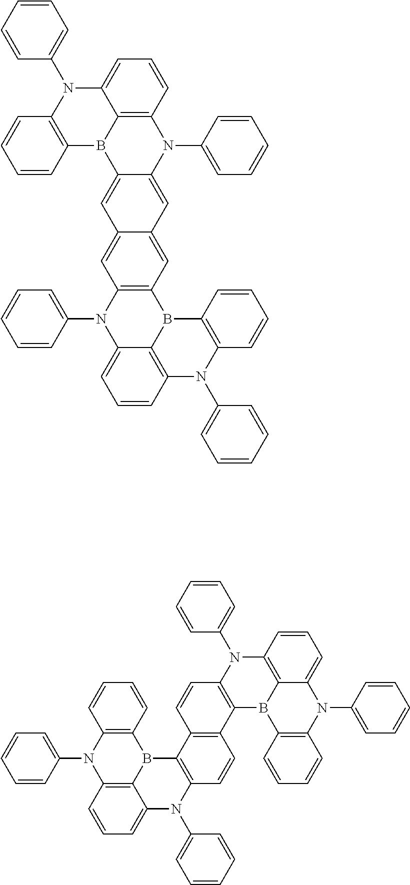 [SMILES: c1ccc(N2c3ccccc3B3c4cc5cc6c(cc5cc4N(c4ccccc4)c4cccc2c43)B2c3ccccc3N(c3ccccc3)c3cccc(c32)N6c2ccccc2)cc1 ; c1ccc(N2c3ccccc3B3c4c2cccc4N(c2ccccc2)c2ccc4c5c(ccc4c23)N(c2ccccc2)c2cccc3c2B5c2ccccc2N3c2ccccc2)cc1]

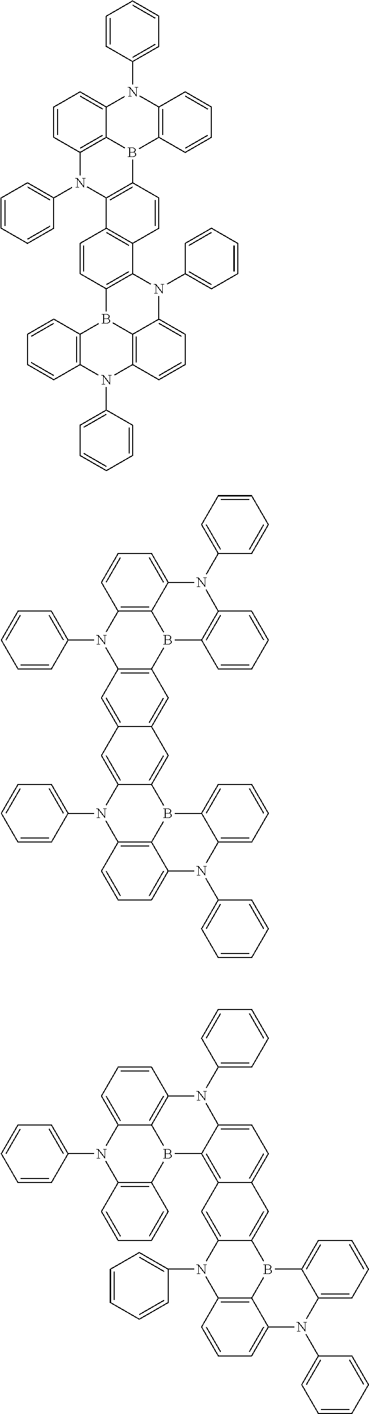 [SMILES: c1ccc(N2c3ccccc3B3c4ccc5c6c(ccc5c4N(c4ccccc4)c4cccc2c43)B2c3ccccc3N(c3ccccc3)c3cccc(c32)N6c2ccccc2)cc1 ; c1ccc(N2c3ccccc3B3c4cc5cc6c(cc5cc4N(c4ccccc4)c4cccc2c43)N(c2ccccc2)c2cccc3c2B6c2ccccc2N3c2ccccc2)cc1 ; c1ccc(N2c3ccccc3B3c4cc5ccc6c(c5cc4N(c4ccccc4)c4cccc2c43)B2c3ccccc3N(c3ccccc3)c3cccc(c32)N6c2ccccc2)cc1]

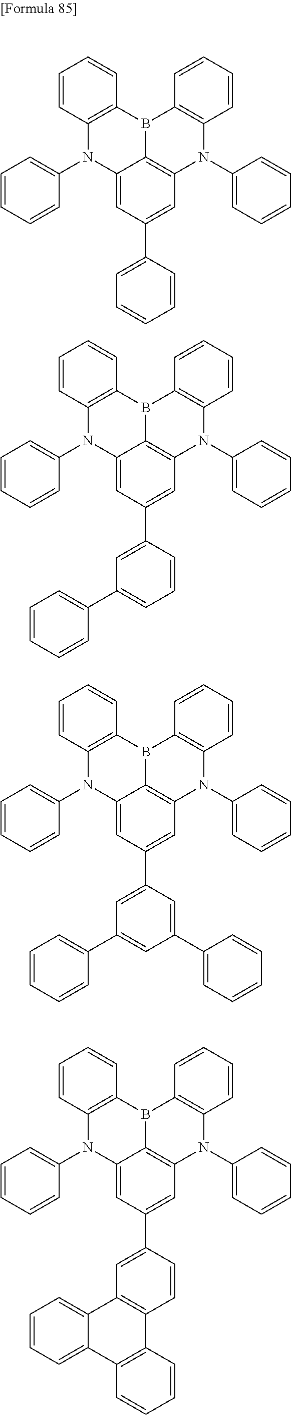

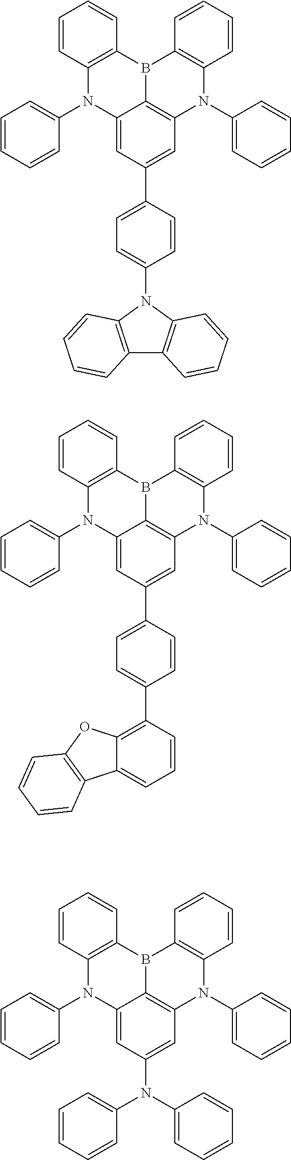 [SMILES: c1ccc(N2c3ccccc3B3c4ccccc4N(c4ccccc4)c4cc(-c5ccc(-n6c7ccccc7c7ccccc76)cc5)cc2c43)cc1 ; c1ccc(N2c3ccccc3B3c4ccccc4N(c4ccccc4)c4cc(-c5ccc(-c6cccc7c6oc6ccccc67)cc5)cc2c43)cc1 ; c1ccc(N(c2ccccc2)c2cc3c4c(c2)N(c2ccccc2)c2ccccc2B4c2ccccc2N3c2ccccc2)cc1]

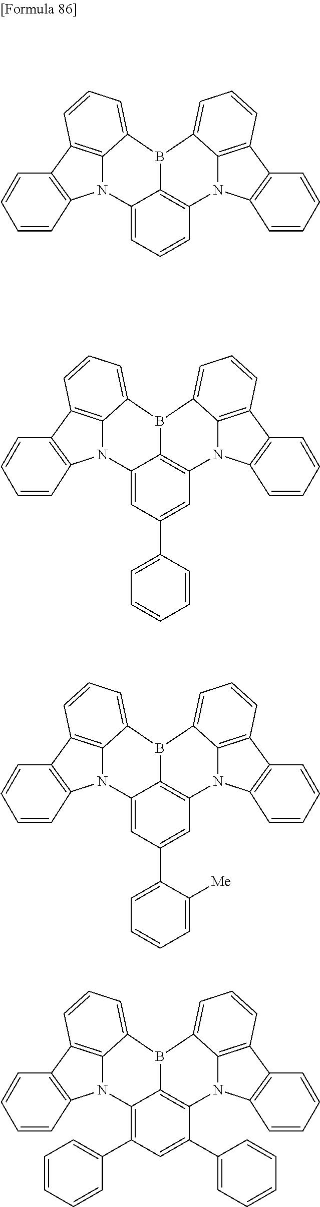 [SMILES: c1cc2c3c(c1)-n1c4ccccc4c4cccc(c41)B3c1cccc3c4ccccc4n-2c13 ; c1ccc(-c2cc3c4c(c2)-n2c5ccccc5c5cccc(c52)B4c2cccc4c5ccccc5n-3c24)cc1 ; Cc1ccccc1-c1cc2c3c(c1)-n1c4ccccc4c4cccc(c41)B3c1cccc3c4ccccc4n-2c13 ; c1ccc(-c2cc(-c3ccccc3)c3c4c2-n2c5ccccc5c5cccc(c52)B4c2cccc4c5ccccc5n-3c24)cc1]

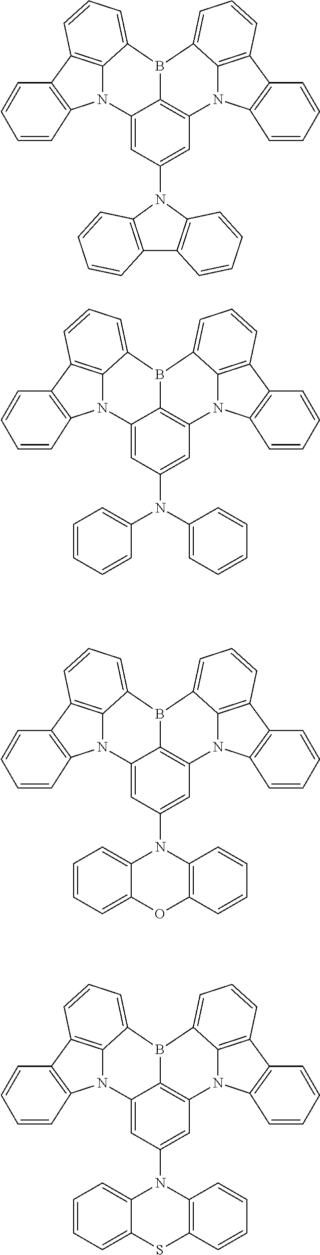

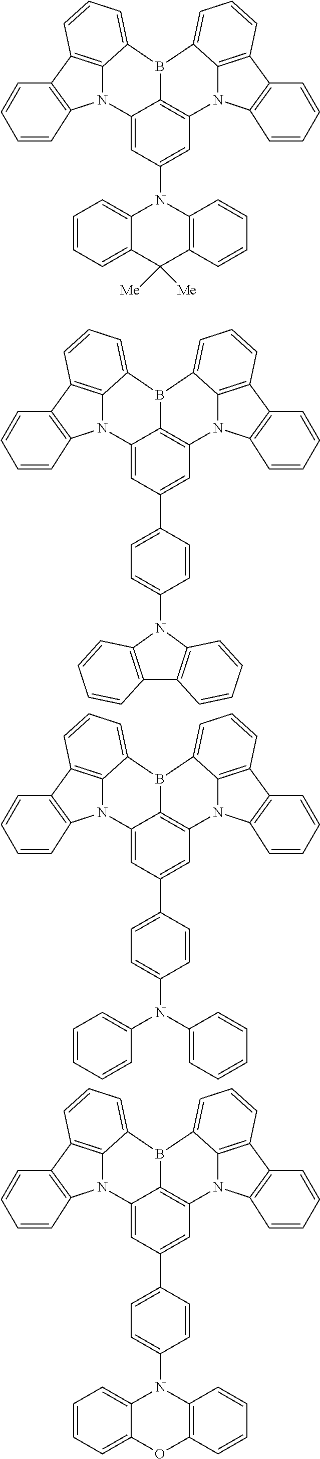

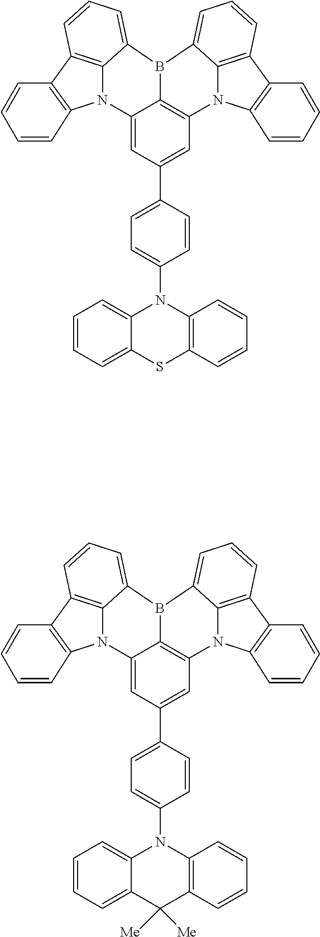 [SMILES: c1ccc2c(c1)Sc1ccccc1N2c1ccc(-c2cc3c4c(c2)-n2c5ccccc5c5cccc(c52)B4c2cccc4c5ccccc5n-3c24)cc1 ; CC1(C)c2ccccc2N(c2ccc(-c3cc4c5c(c3)-n3c6ccccc6c6cccc(c63)B5c3cccc5c6ccccc6n-4c35)cc2)c2ccccc21]

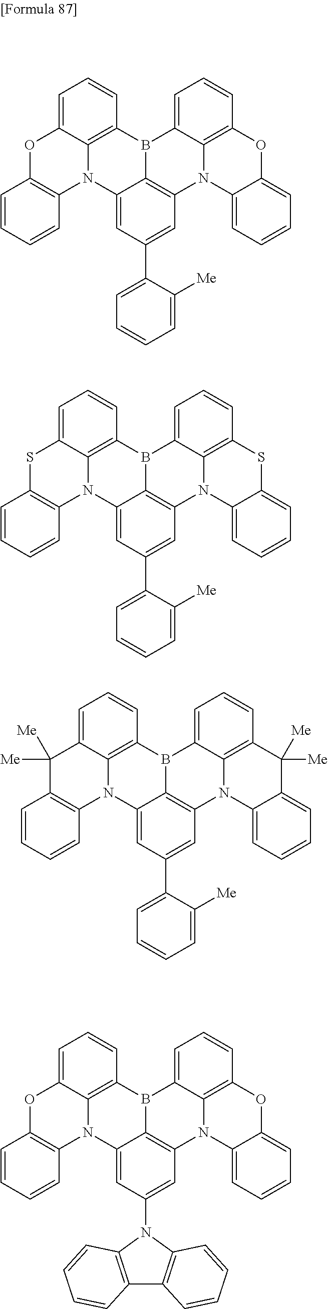 [SMILES: Cc1ccccc1-c1cc2c3c(c1)N1c4ccccc4Oc4cccc(c41)B3c1cccc3c1N2c1ccccc1O3 ; Cc1ccccc1-c1cc2c3c(c1)N1c4ccccc4Sc4cccc(c41)B3c1cccc3c1N2c1ccccc1S3 ; Cc1ccccc1-c1cc2c3c(c1)N1c4ccccc4C(C)(C)c4cccc(c41)B3c1cccc3c1N2c1ccccc1C3(C)C ; c1ccc2c(c1)Oc1cccc3c1N2c1cc(-n2c4ccccc4c4ccccc42)cc2c1B3c1cccc3c1N2c1ccccc1O3]

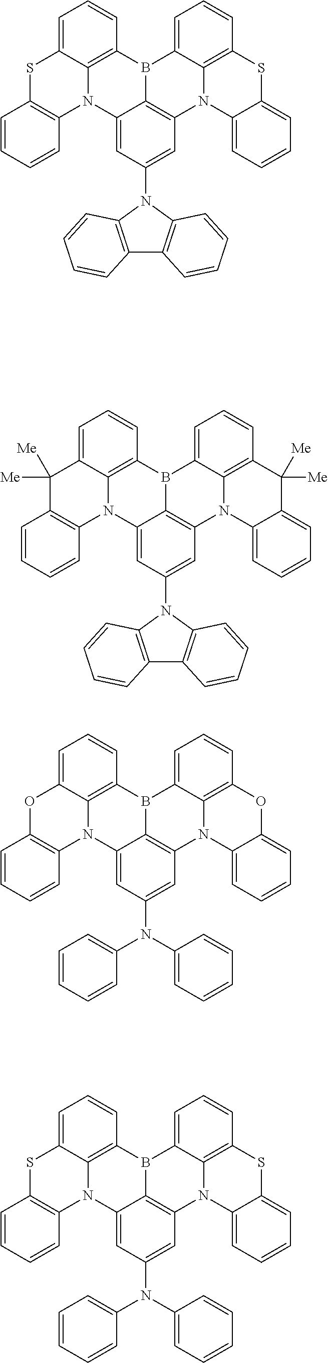 [SMILES: c1ccc2c(c1)Sc1cccc3c1N2c1cc(-n2c4ccccc4c4ccccc42)cc2c1B3c1cccc3c1N2c1ccccc1S3 ; CC1(C)c2ccccc2N2c3cc(-n4c5ccccc5c5ccccc54)cc4c3B(c3cccc1c32)c1cccc2c1N4c1ccccc1C2(C)C ; c1ccc(N(c2ccccc2)c2cc3c4c(c2)N2c5ccccc5Oc5cccc(c52)B4c2cccc4c2N3c2ccccc2O4)cc1 ; c1ccc(N(c2ccccc2)c2cc3c4c(c2)N2c5ccccc5Sc5cccc(c52)B4c2cccc4c2N3c2ccccc2S4)cc1]

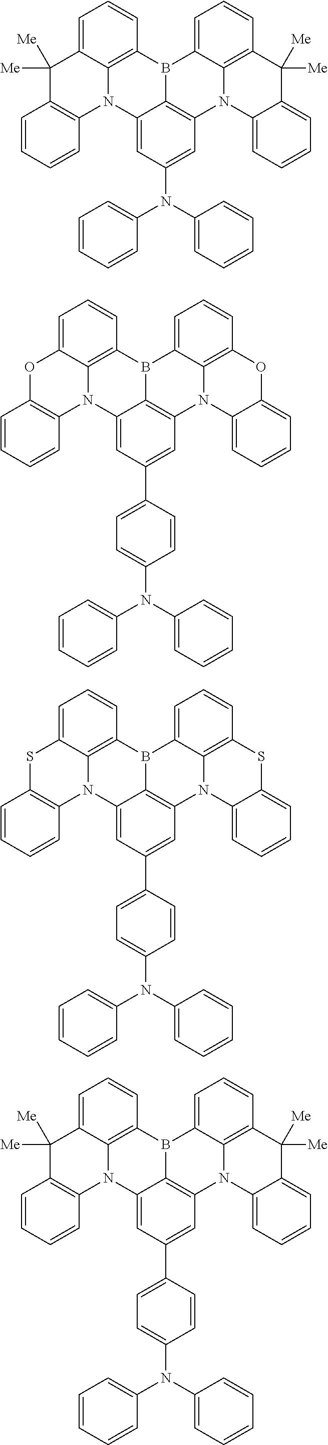

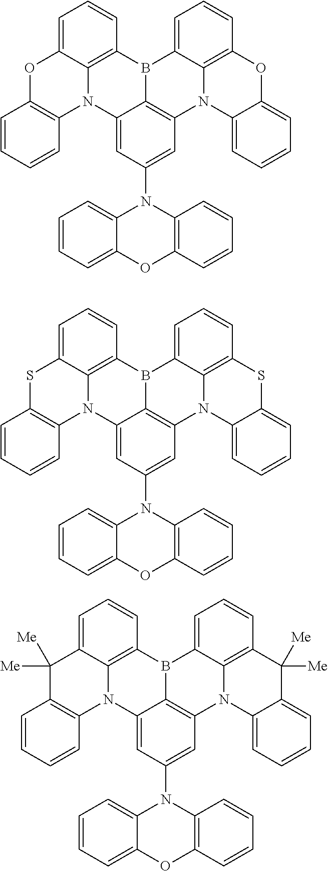

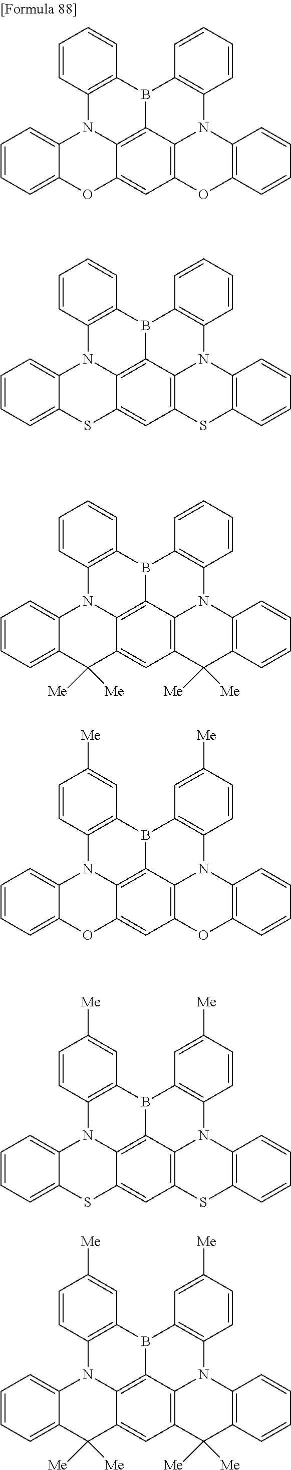

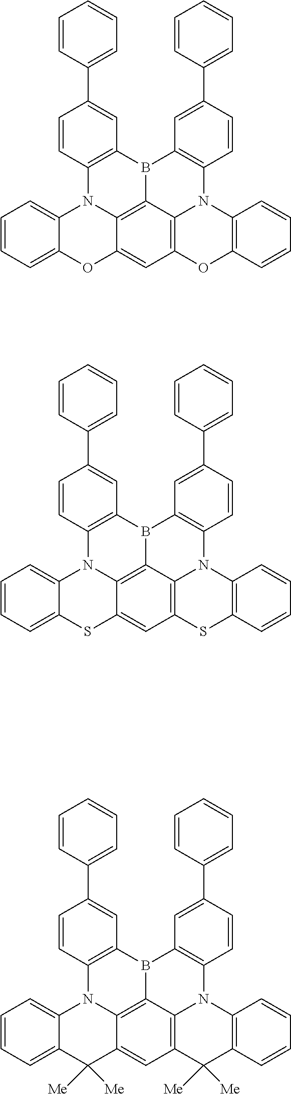 [SMILES: c1ccc(-c2ccc3c(c2)B2c4cc(-c5ccccc5)ccc4-n4c5ccccc5oc5cc6oc7ccccc7n-3c6c2c54)cc1 ; c1ccc(-c2ccc3c(c2)B2c4cc(-c5ccccc5)ccc4-n4c5ccccc5sc5cc6sc7ccccc7n-3c6c2c54)cc1 ; CC1(C)c2ccccc2N2c3ccc(-c4ccccc4)cc3B3c4cc(-c5ccccc5)ccc4N4c5ccccc5C(C)(C)c5cc1c2c3c54]

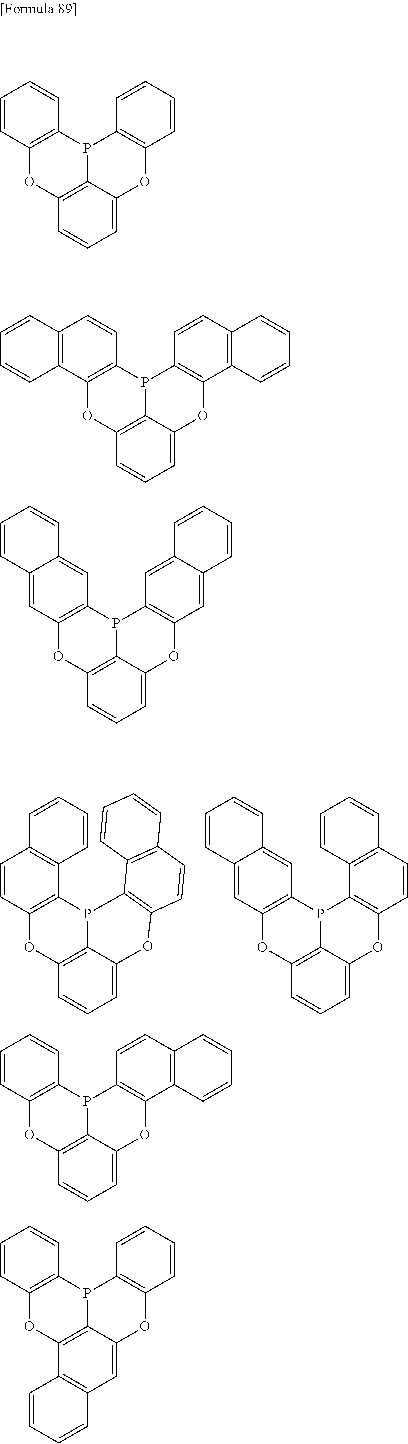

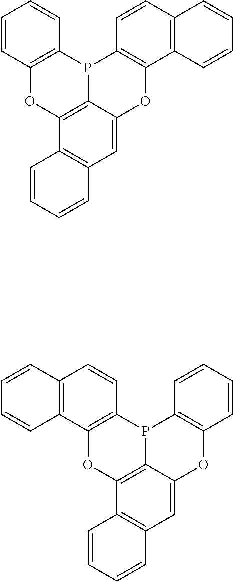 [SMILES: c1ccc2c(c1)Oc1c3c(cc4ccccc14)Oc1c(ccc4ccccc14)P23 ; c1ccc2c(c1)Oc1cc3ccccc3c3c1P2c1ccc2ccccc2c1O3]

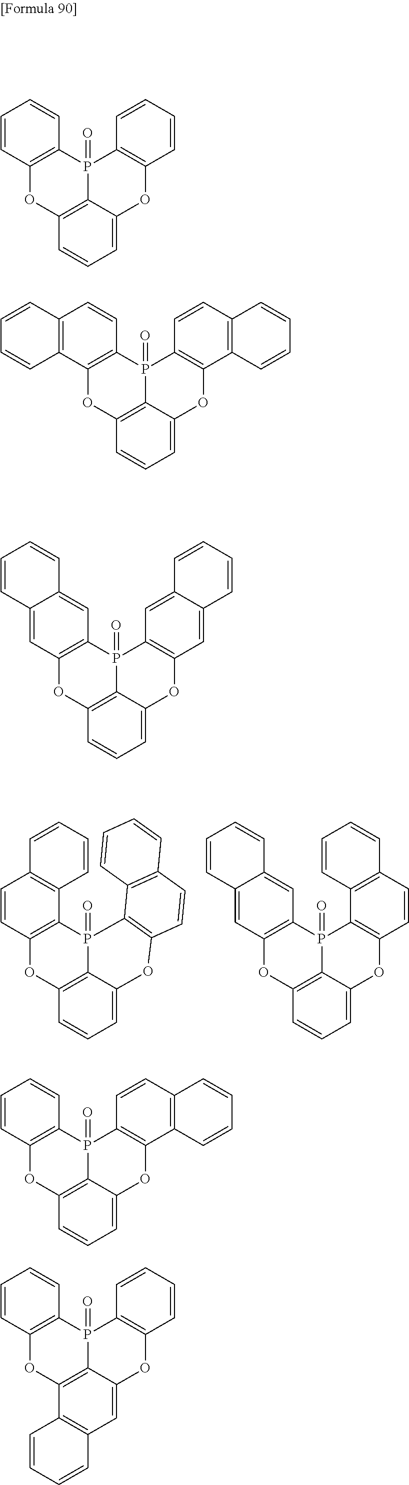

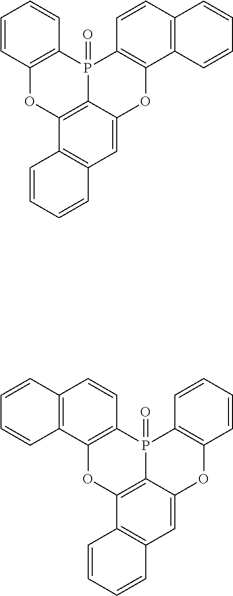 [SMILES: O=P12c3ccccc3Oc3c1c(cc1ccccc31)Oc1c2ccc2ccccc12 ; O=P12c3ccccc3Oc3cc4ccccc4c(c31)Oc1c2ccc2ccccc12]

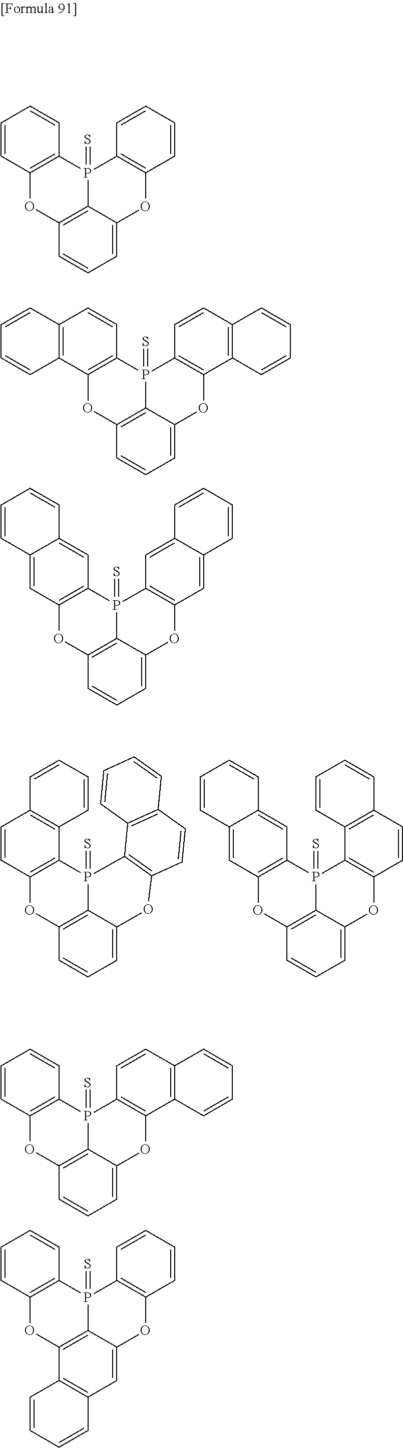

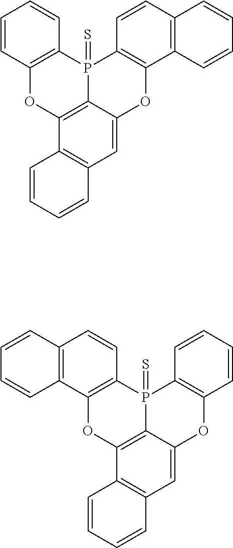 [SMILES: S=P12c3ccccc3Oc3c1c(cc1ccccc31)Oc1c2ccc2ccccc12 ; S=P12c3ccccc3Oc3cc4ccccc4c(c31)Oc1c2ccc2ccccc12]

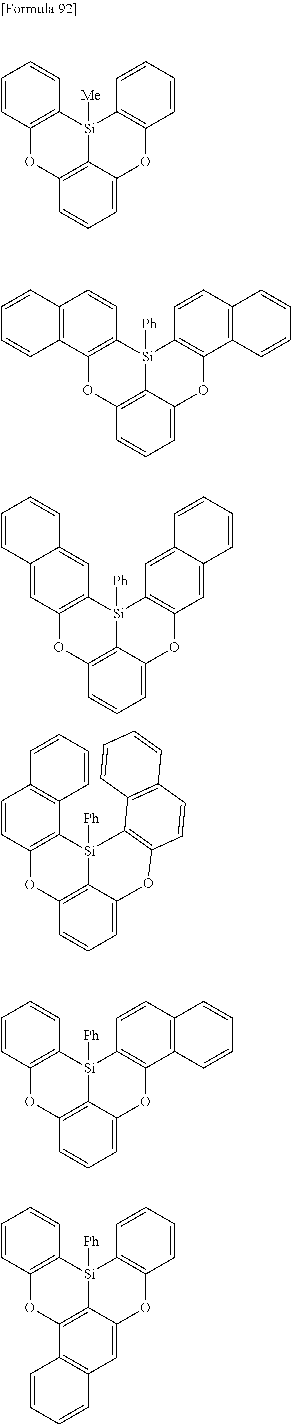

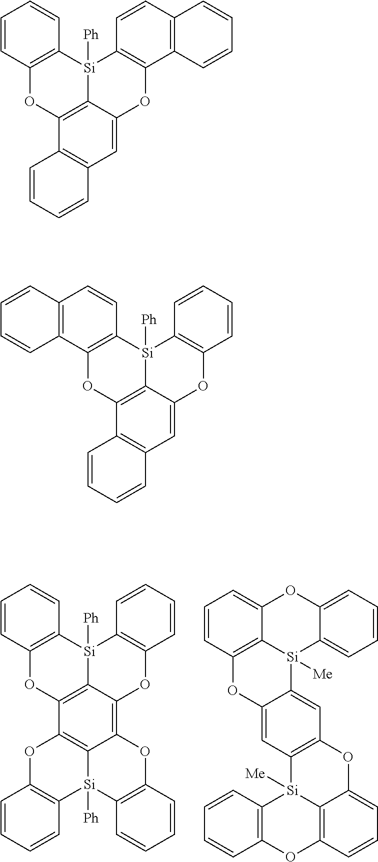

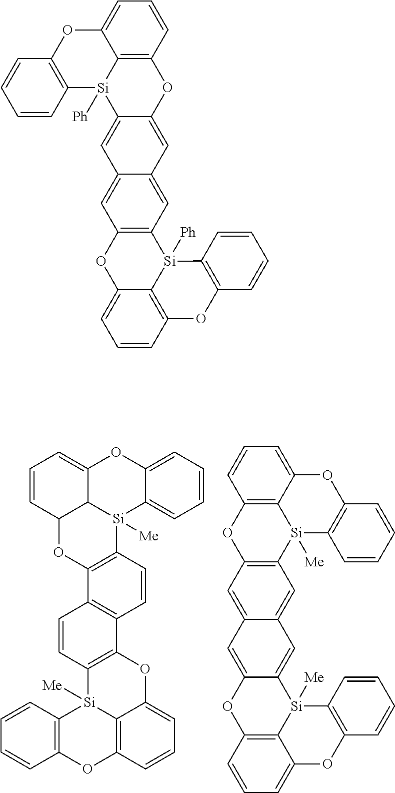

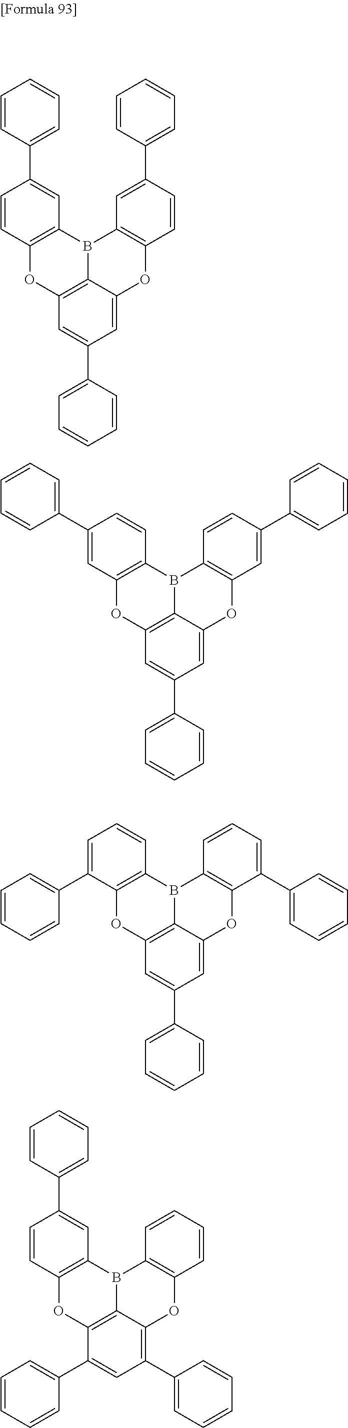

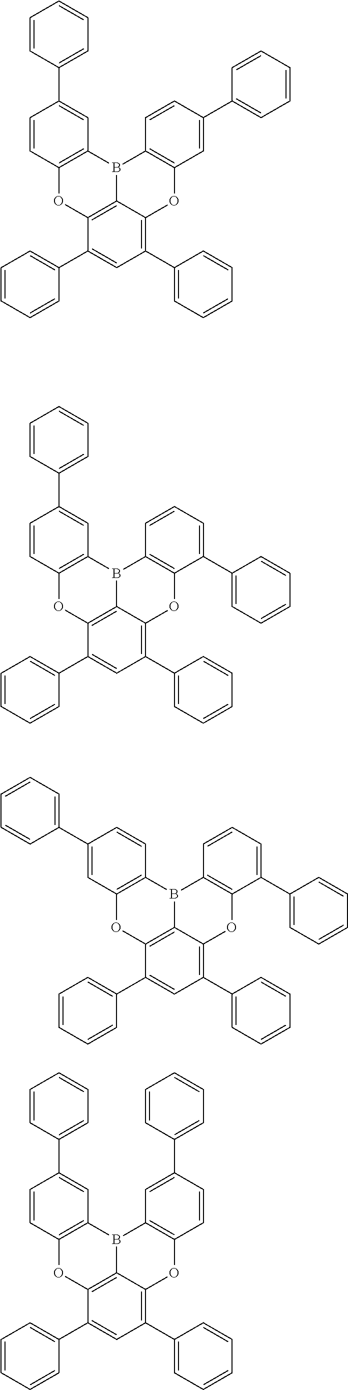

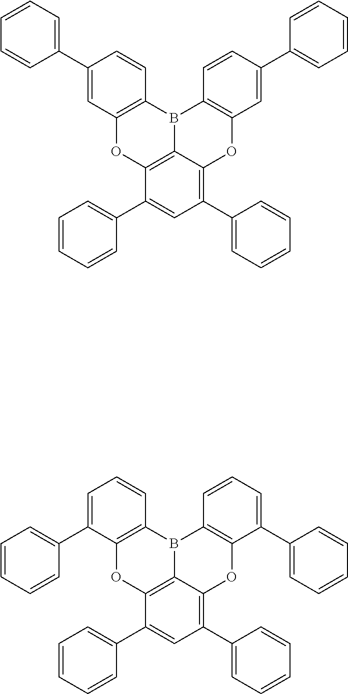 [SMILES: c1ccc(-c2ccc3c(c2)Oc2c(-c4ccccc4)cc(-c4ccccc4)c4c2B3c2ccc(-c3ccccc3)cc2O4)cc1 ; c1ccc(-c2cccc3c2Oc2c(-c4ccccc4)cc(-c4ccccc4)c4c2B3c2cccc(-c3ccccc3)c2O4)cc1]

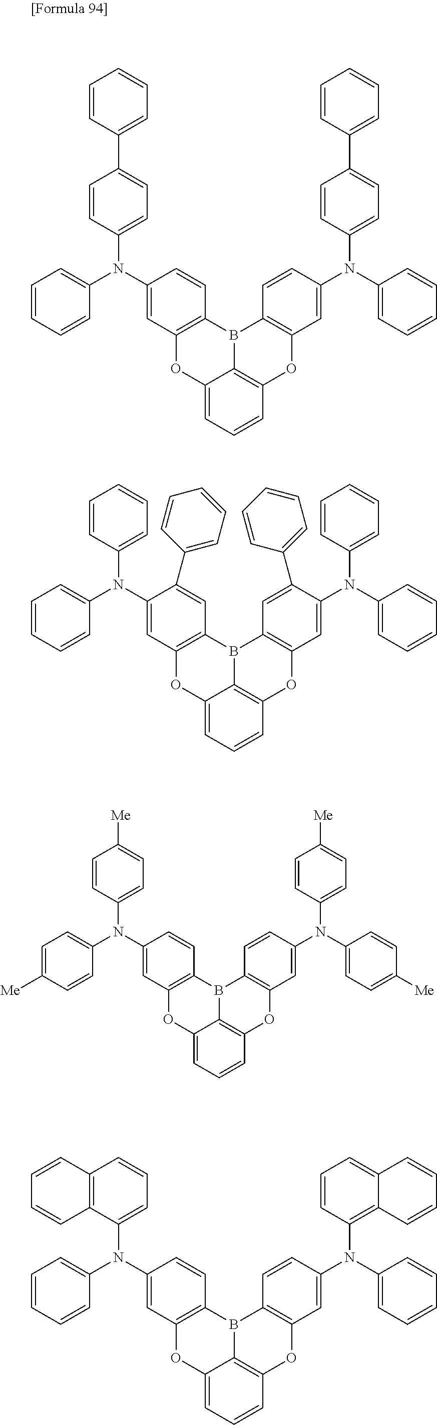 [SMILES: c1ccc(-c2ccc(N(c3ccccc3)c3ccc4c(c3)Oc3cccc5c3B4c3ccc(N(c4ccccc4)c4ccc(-c6ccccc6)cc4)cc3O5)cc2)cc1 ; c1ccc(-c2cc3c(cc2N(c2ccccc2)c2ccccc2)Oc2cccc4c2B3c2cc(-c3ccccc3)c(N(c3ccccc3)c3ccccc3)cc2O4)cc1 ; Cc1ccc(N(c2ccc(C)cc2)c2ccc3c(c2)Oc2cccc4c2B3c2ccc(N(c3ccc(C)cc3)c3ccc(C)cc3)cc2O4)cc1 ; c1ccc(N(c2ccc3c(c2)Oc2cccc4c2B3c2ccc(N(c3ccccc3)c3cccc5ccccc35)cc2O4)c2cccc3ccccc23)cc1]

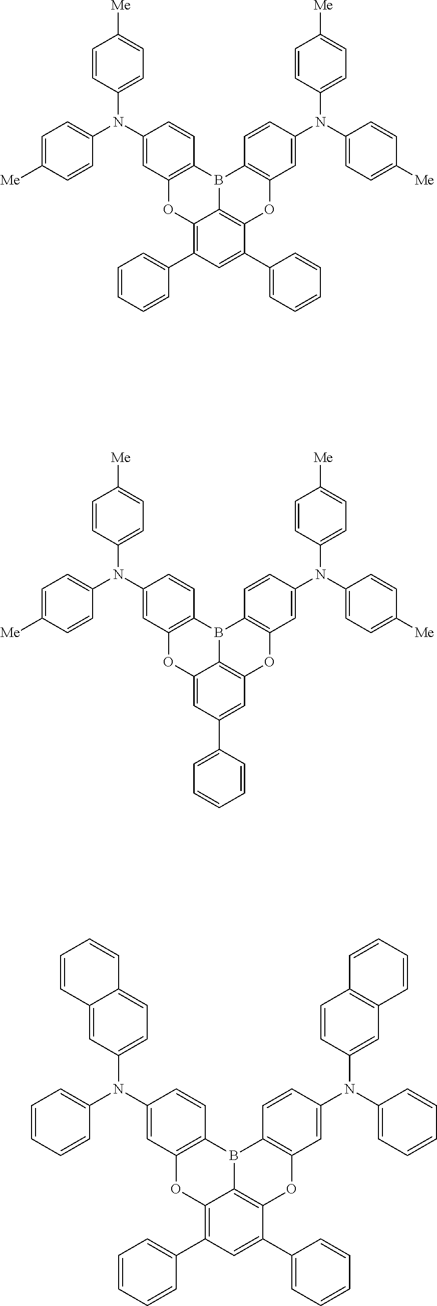 [SMILES: Cc1ccc(N(c2ccc(C)cc2)c2ccc3c(c2)Oc2c(-c4ccccc4)cc(-c4ccccc4)c4c2B3c2ccc(N(c3ccc(C)cc3)c3ccc(C)cc3)cc2O4)cc1 ; Cc1ccc(N(c2ccc(C)cc2)c2ccc3c(c2)Oc2cc(-c4ccccc4)cc4c2B3c2ccc(N(c3ccc(C)cc3)c3ccc(C)cc3)cc2O4)cc1 ; c1ccc(-c2cc(-c3ccccc3)c3c4c2Oc2cc(N(c5ccccc5)c5ccc6ccccc6c5)ccc2B4c2ccc(N(c4ccccc4)c4ccc5ccccc5c4)cc2O3)cc1]

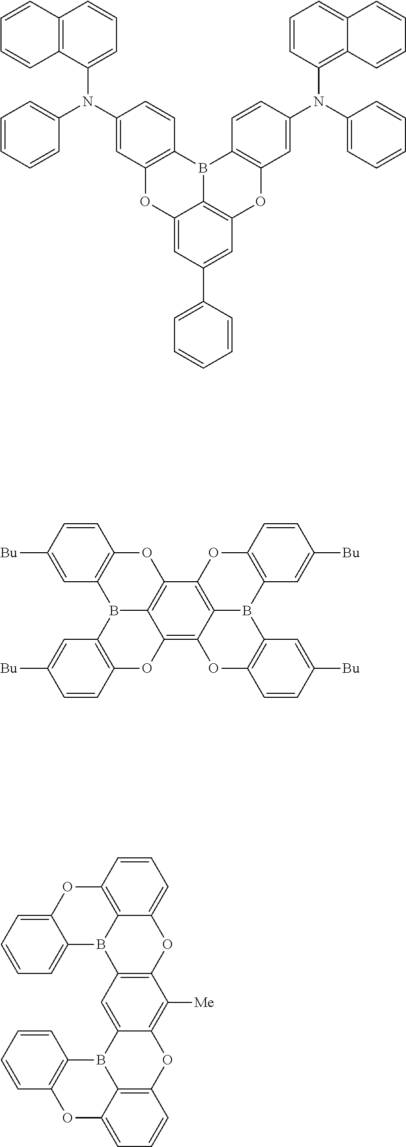

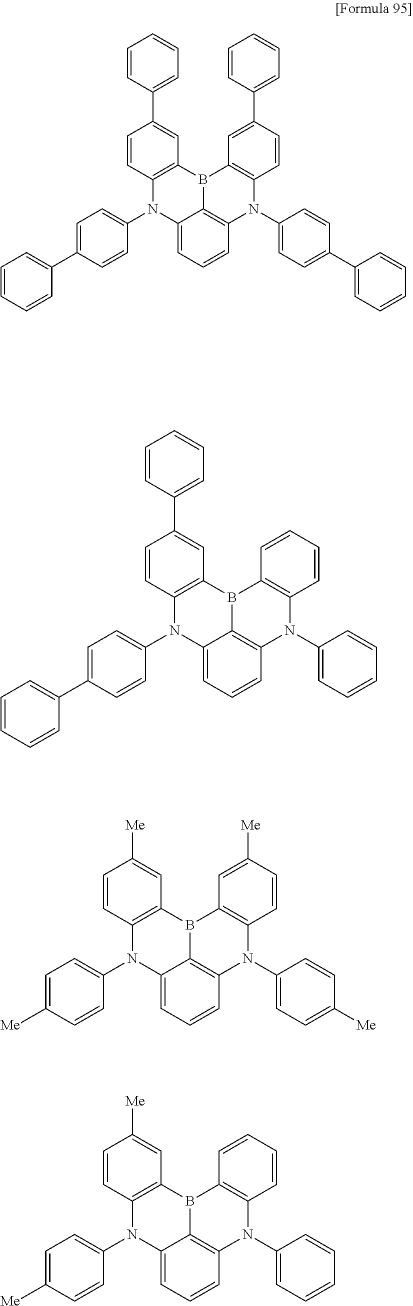 [SMILES: c1ccc(-c2ccc(N3c4ccc(-c5ccccc5)cc4B4c5cc(-c6ccccc6)ccc5N(c5ccc(-c6ccccc6)cc5)c5cccc3c54)cc2)cc1 ; c1ccc(-c2ccc(N3c4ccc(-c5ccccc5)cc4B4c5ccccc5N(c5ccccc5)c5cccc3c54)cc2)cc1 ; Cc1ccc(N2c3ccc(C)cc3B3c4cc(C)ccc4N(c4ccc(C)cc4)c4cccc2c43)cc1 ; Cc1ccc(N2c3ccc(C)cc3B3c4ccccc4N(c4ccccc4)c4cccc2c43)cc1]

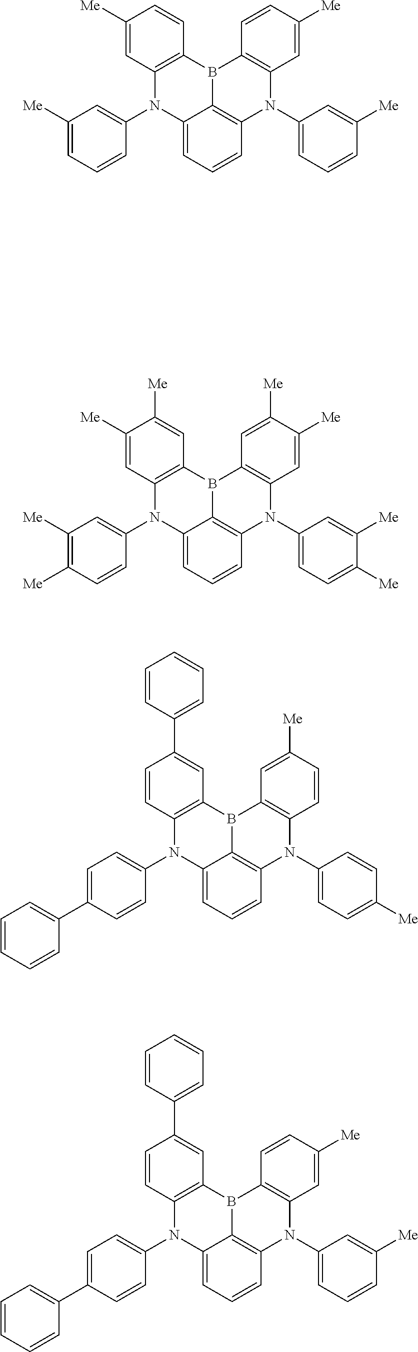 [SMILES: Cc1cccc(N2c3cc(C)ccc3B3c4ccc(C)cc4N(c4cccc(C)c4)c4cccc2c43)c1 ; Cc1ccc(N2c3cc(C)c(C)cc3B3c4cc(C)c(C)cc4N(c4ccc(C)c(C)c4)c4cccc2c43)cc1C ; Cc1ccc(N2c3ccc(C)cc3B3c4cc(-c5ccccc5)ccc4N(c4ccc(-c5ccccc5)cc4)c4cccc2c43)cc1 ; Cc1cccc(N2c3cc(C)ccc3B3c4cc(-c5ccccc5)ccc4N(c4ccc(-c5ccccc5)cc4)c4cccc2c43)c1]

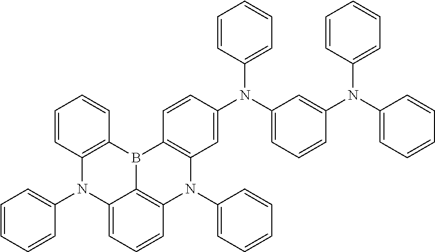 [SMILES: c1ccc(N(c2ccccc2)c2cccc(N(c3ccccc3)c3ccc4c(c3)N(c3ccccc3)c3cccc5c3B4c3ccccc3N5c3ccccc3)c2)cc1]

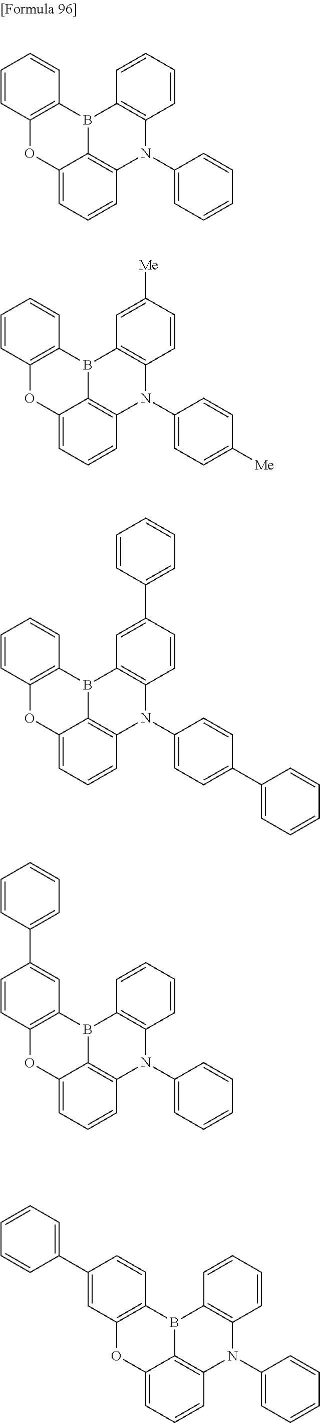 [SMILES: c1ccc(N2c3ccccc3B3c4ccccc4Oc4cccc2c43)cc1 ; Cc1ccc(N2c3ccc(C)cc3B3c4ccccc4Oc4cccc2c43)cc1 ; c1ccc(-c2ccc(N3c4ccc(-c5ccccc5)cc4B4c5ccccc5Oc5cccc3c54)cc2)cc1 ; c1ccc(-c2ccc3c(c2)B2c4ccccc4N(c4ccccc4)c4cccc(c42)O3)cc1 ; c1ccc(-c2ccc3c(c2)Oc2cccc4c2B3c2ccccc2N4c2ccccc2)cc1]

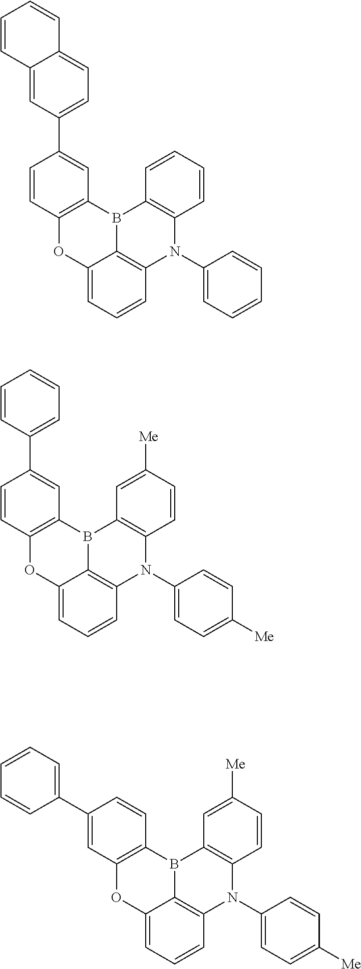 [SMILES: c1ccc(N2c3ccccc3B3c4cc(-c5ccc6ccccc6c5)ccc4Oc4cccc2c43)cc1 ; Cc1ccc(N2c3ccc(C)cc3B3c4cc(-c5ccccc5)ccc4Oc4cccc2c43)cc1 ; Cc1ccc(N2c3ccc(C)cc3B3c4ccc(-c5ccccc5)cc4Oc4cccc2c43)cc1]

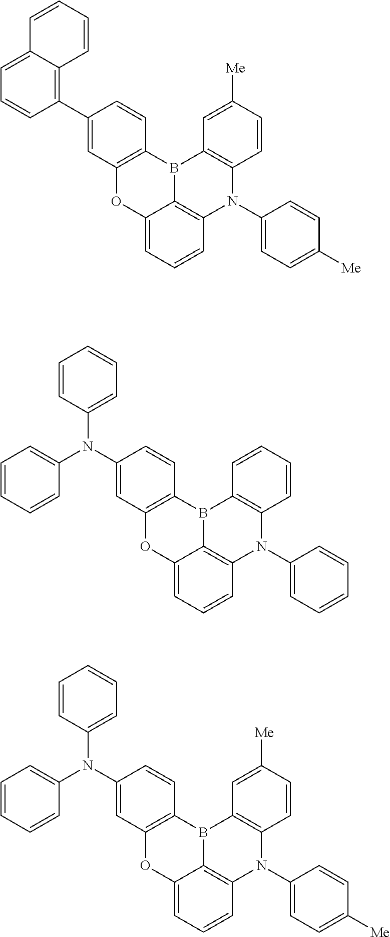 [SMILES: Cc1ccc(N2c3ccc(C)cc3B3c4ccc(-c5cccc6ccccc56)cc4Oc4cccc2c43)cc1 ; c1ccc(N(c2ccccc2)c2ccc3c(c2)Oc2cccc4c2B3c2ccccc2N4c2ccccc2)cc1 ; Cc1ccc(N2c3ccc(C)cc3B3c4ccc(N(c5ccccc5)c5ccccc5)cc4Oc4cccc2c43)cc1]

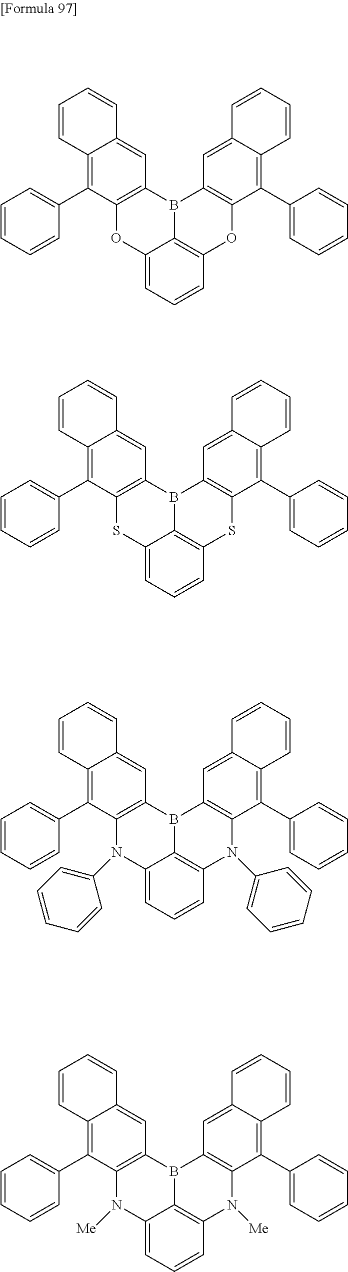 [SMILES: c1ccc(-c2c3c(cc4ccccc24)B2c4cc5ccccc5c(-c5ccccc5)c4Oc4cccc(c42)O3)cc1 ; c1ccc(-c2c3c(cc4ccccc24)B2c4cc5ccccc5c(-c5ccccc5)c4Sc4cccc(c42)S3)cc1 ; c1ccc(-c2c3c(cc4ccccc24)B2c4cc5ccccc5c(-c5ccccc5)c4N(c4ccccc4)c4cccc(c42)N3c2ccccc2)cc1 ; CN1c2cccc3c2B(c2cc4ccccc4c(-c4ccccc4)c21)c1cc2ccccc2c(-c2ccccc2)c1N3C]

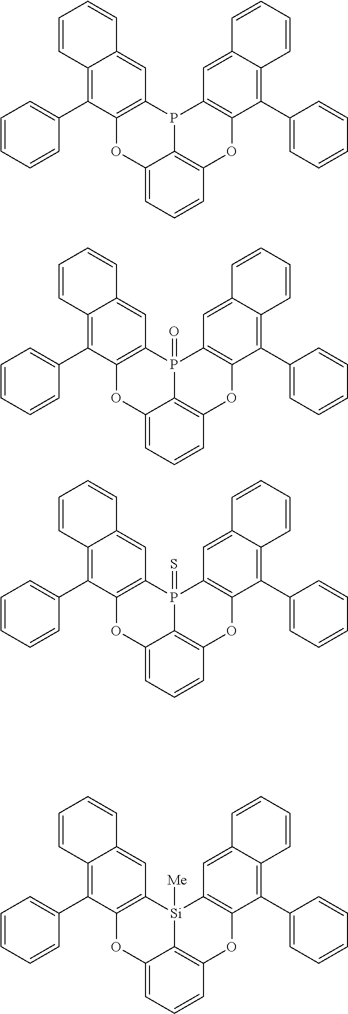 [SMILES: c1ccc(-c2c3c(cc4ccccc24)P2c4cc5ccccc5c(-c5ccccc5)c4Oc4cccc(c42)O3)cc1 ; O=P12c3cc4ccccc4c(-c4ccccc4)c3Oc3cccc(c31)Oc1c2cc2ccccc2c1-c1ccccc1 ; S=P12c3cc4ccccc4c(-c4ccccc4)c3Oc3cccc(c31)Oc1c2cc2ccccc2c1-c1ccccc1 ; C[Si]12c3cc4ccccc4c(-c4ccccc4)c3Oc3cccc(c31)Oc1c2cc2ccccc2c1-c1ccccc1]

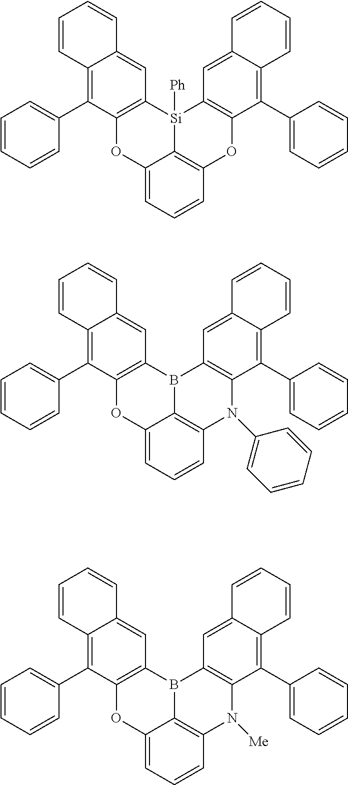 [SMILES: c1ccc(-c2c3c(cc4ccccc24)[Si]2(c4ccccc4)c4cc5ccccc5c(-c5ccccc5)c4Oc4cccc(c42)O3)cc1 ; c1ccc(-c2c3c(cc4ccccc24)B2c4cc5ccccc5c(-c5ccccc5)c4N(c4ccccc4)c4cccc(c42)O3)cc1 ; CN1c2cccc3c2B(c2cc4ccccc4c(-c4ccccc4)c2O3)c2cc3ccccc3c(-c3ccccc3)c21]

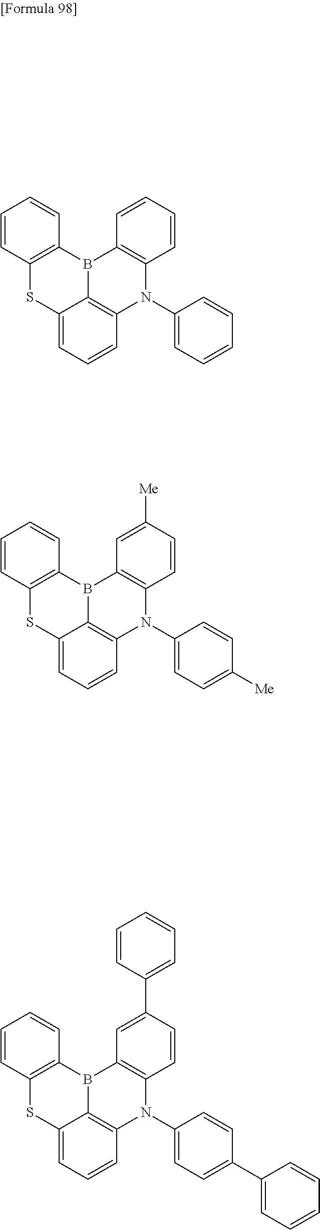 [SMILES: c1ccc(N2c3ccccc3B3c4ccccc4Sc4cccc2c43)cc1 ; Cc1ccc(N2c3ccc(C)cc3B3c4ccccc4Sc4cccc2c43)cc1 ; c1ccc(-c2ccc(N3c4ccc(-c5ccccc5)cc4B4c5ccccc5Sc5cccc3c54)cc2)cc1]

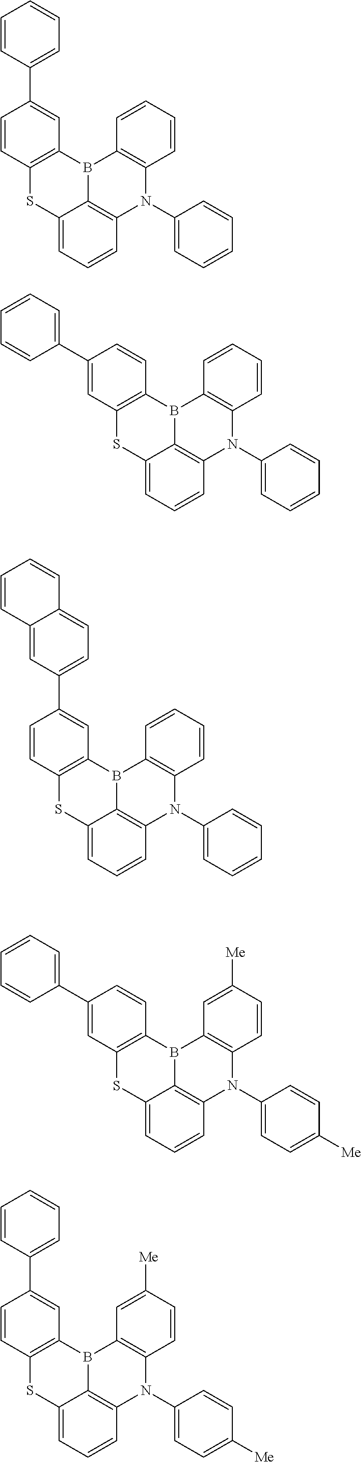 [SMILES: c1ccc(-c2ccc3c(c2)B2c4ccccc4N(c4ccccc4)c4cccc(c42)S3)cc1 ; c1ccc(-c2ccc3c(c2)Sc2cccc4c2B3c2ccccc2N4c2ccccc2)cc1 ; c1ccc(N2c3ccccc3B3c4cc(-c5ccc6ccccc6c5)ccc4Sc4cccc2c43)cc1 ; Cc1ccc(N2c3ccc(C)cc3B3c4ccc(-c5ccccc5)cc4Sc4cccc2c43)cc1 ; Cc1ccc(N2c3ccc(C)cc3B3c4cc(-c5ccccc5)ccc4Sc4cccc2c43)cc1]

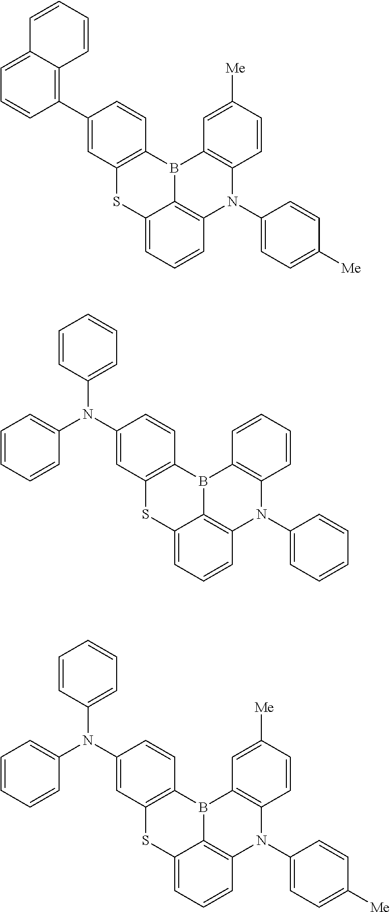 [SMILES: Cc1ccc(N2c3ccc(C)cc3B3c4ccc(-c5cccc6ccccc56)cc4Sc4cccc2c43)cc1 ; c1ccc(N(c2ccccc2)c2ccc3c(c2)Sc2cccc4c2B3c2ccccc2N4c2ccccc2)cc1 ; Cc1ccc(N2c3ccc(C)cc3B3c4ccc(N(c5ccccc5)c5ccccc5)cc4Sc4cccc2c43)cc1]

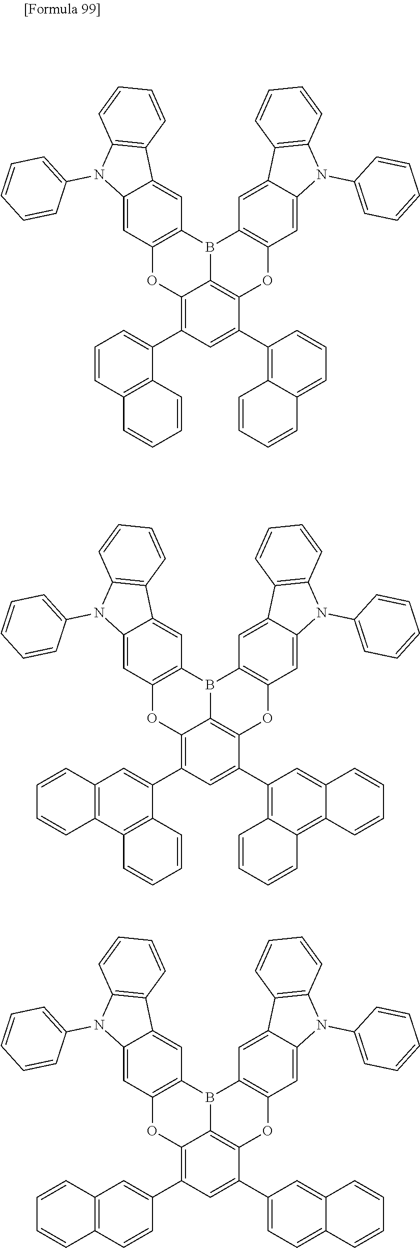 [SMILES: c1ccc(-n2c3ccccc3c3cc4c(cc32)Oc2c(-c3cccc5ccccc35)cc(-c3cccc5ccccc35)c3c2B4c2cc4c5ccccc5n(-c5ccccc5)c4cc2O3)cc1 ; c1ccc(-n2c3ccccc3c3cc4c(cc32)Oc2c(-c3cc5ccccc5c5ccccc35)cc(-c3cc5ccccc5c5ccccc35)c3c2B4c2cc4c5ccccc5n(-c5ccccc5)c4cc2O3)cc1 ; c1ccc(-n2c3ccccc3c3cc4c(cc32)Oc2c(-c3ccc5ccccc5c3)cc(-c3ccc5ccccc5c3)c3c2B4c2cc4c5ccccc5n(-c5ccccc5)c4cc2O3)cc1]

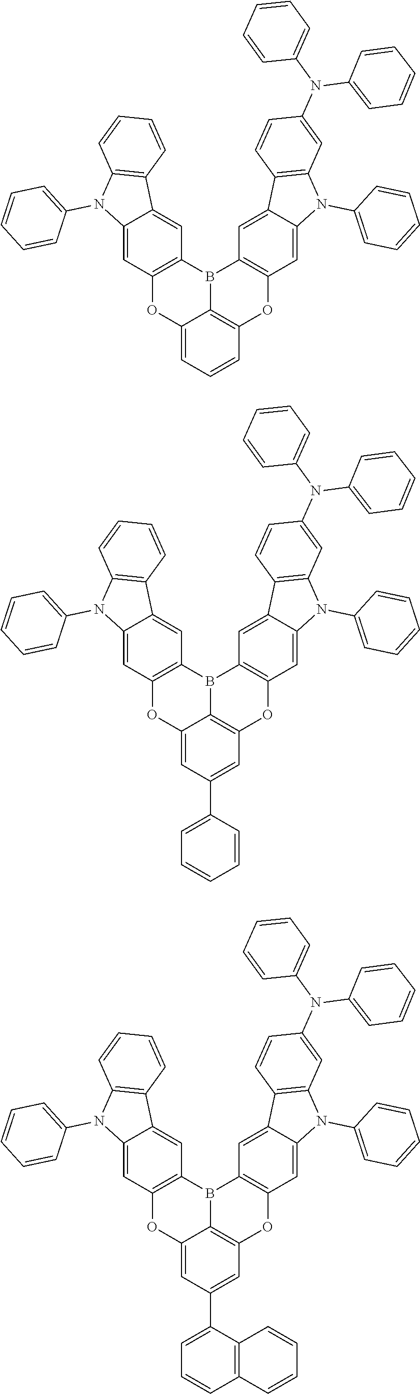 [SMILES: c1ccc(N(c2ccccc2)c2ccc3c4cc5c(cc4n(-c4ccccc4)c3c2)Oc2cccc3c2B5c2cc4c5ccccc5n(-c5ccccc5)c4cc2O3)cc1 ; c1ccc(-c2cc3c4c(c2)Oc2cc5c(cc2B4c2cc4c6ccccc6n(-c6ccccc6)c4cc2O3)c2ccc(N(c3ccccc3)c3ccccc3)cc2n5-c2ccccc2)cc1 ; c1ccc(N(c2ccccc2)c2ccc3c4cc5c(cc4n(-c4ccccc4)c3c2)Oc2cc(-c3cccc4ccccc34)cc3c2B5c2cc4c5ccccc5n(-c5ccccc5)c4cc2O3)cc1]

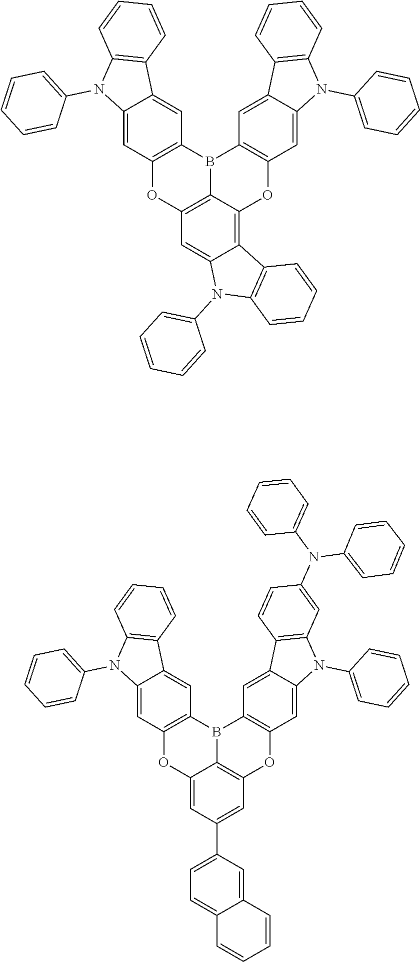 [SMILES: c1ccc(-n2c3ccccc3c3cc4c(cc32)Oc2cc3c(c5c2B4c2cc4c6ccccc6n(-c6ccccc6)c4cc2O5)c2ccccc2n3-c2ccccc2)cc1 ; c1ccc(N(c2ccccc2)c2ccc3c4cc5c(cc4n(-c4ccccc4)c3c2)Oc2cc(-c3ccc4ccccc4c3)cc3c2B5c2cc4c5ccccc5n(-c5ccccc5)c4cc2O3)cc1]

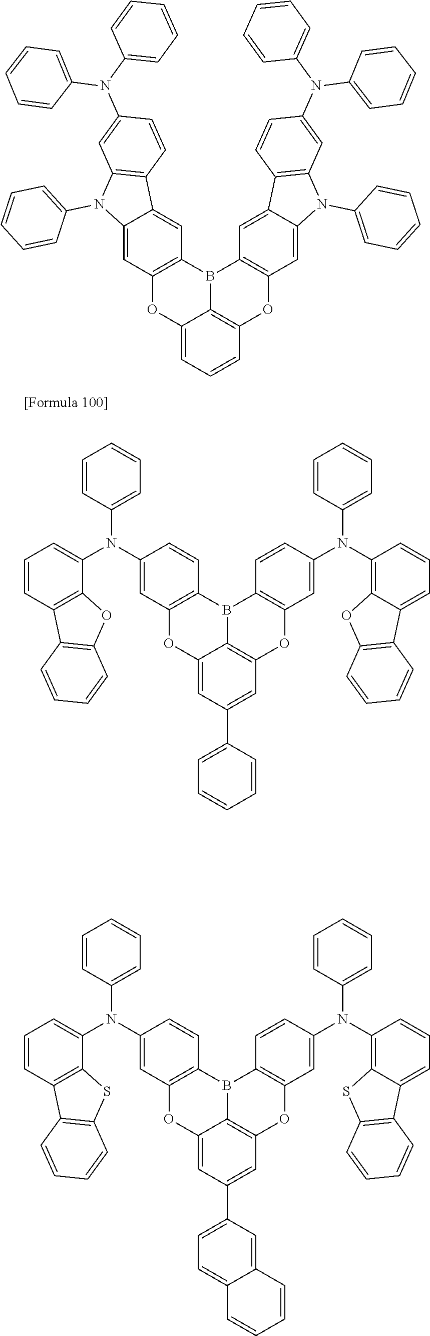 [SMILES: c1ccc(N(c2ccccc2)c2ccc3c4cc5c(cc4n(-c4ccccc4)c3c2)Oc2cccc3c2B5c2cc4c5ccc(N(c6ccccc6)c6ccccc6)cc5n(-c5ccccc5)c4cc2O3)cc1 ; c1ccc(-c2cc3c4c(c2)Oc2cc(N(c5ccccc5)c5cccc6c5oc5ccccc56)ccc2B4c2ccc(N(c4ccccc4)c4cccc5c4oc4ccccc45)cc2O3)cc1 ; c1ccc(N(c2ccc3c(c2)Oc2cc(-c4ccc5ccccc5c4)cc4c2B3c2ccc(N(c3ccccc3)c3cccc5c3sc3ccccc35)cc2O4)c2cccc3c2sc2ccccc23)cc1]

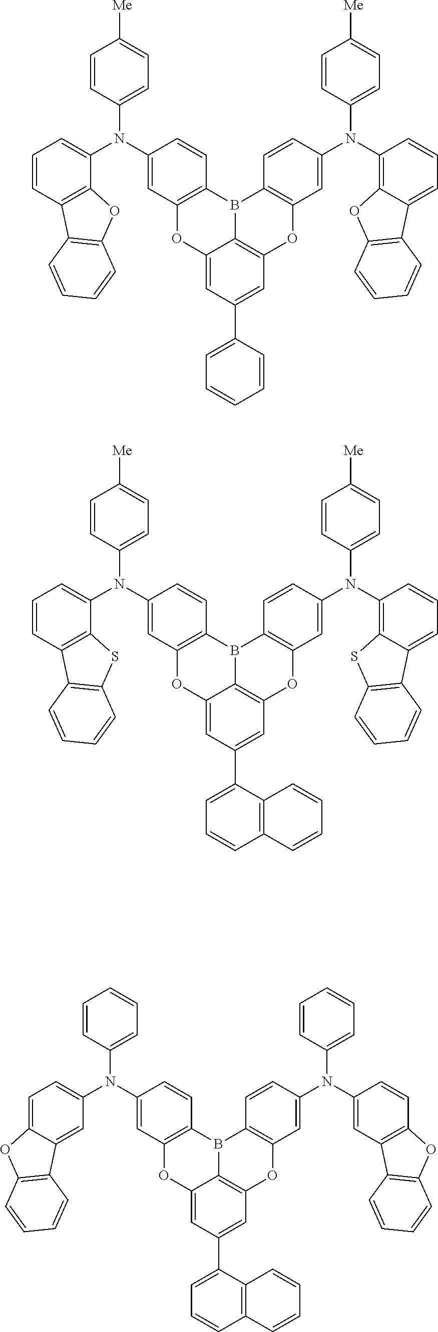 [SMILES: Cc1ccc(N(c2ccc3c(c2)Oc2cc(-c4ccccc4)cc4c2B3c2ccc(N(c3ccc(C)cc3)c3cccc5c3oc3ccccc35)cc2O4)c2cccc3c2oc2ccccc23)cc1 ; Cc1ccc(N(c2ccc3c(c2)Oc2cc(-c4cccc5ccccc45)cc4c2B3c2ccc(N(c3ccc(C)cc3)c3cccc5c3sc3ccccc35)cc2O4)c2cccc3c2sc2ccccc23)cc1 ; c1ccc(N(c2ccc3c(c2)Oc2cc(-c4cccc5ccccc45)cc4c2B3c2ccc(N(c3ccccc3)c3ccc5oc6ccccc6c5c3)cc2O4)c2ccc3oc4ccccc4c3c2)cc1]

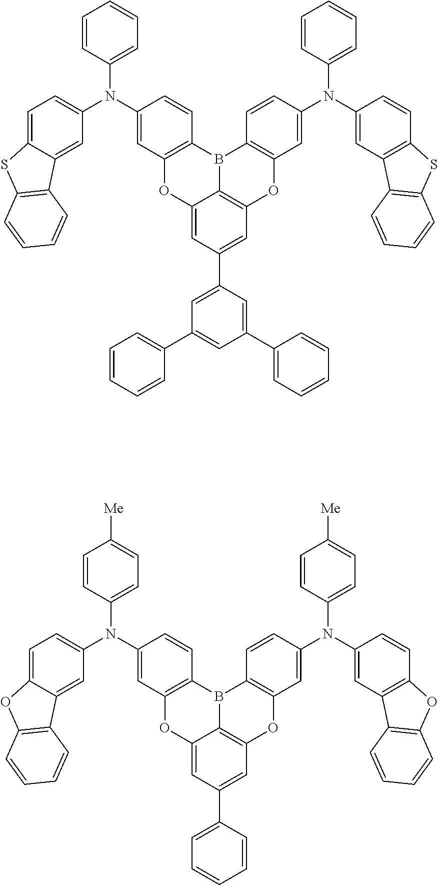 [SMILES: c1ccc(-c2cc(-c3ccccc3)cc(-c3cc4c5c(c3)Oc3cc(N(c6ccccc6)c6ccc7sc8ccccc8c7c6)ccc3B5c3ccc(N(c5ccccc5)c5ccc6sc7ccccc7c6c5)cc3O4)c2)cc1 ; Cc1ccc(N(c2ccc3c(c2)Oc2cc(-c4ccccc4)cc4c2B3c2ccc(N(c3ccc(C)cc3)c3ccc5oc6ccccc6c5c3)cc2O4)c2ccc3oc4ccccc4c3c2)cc1]

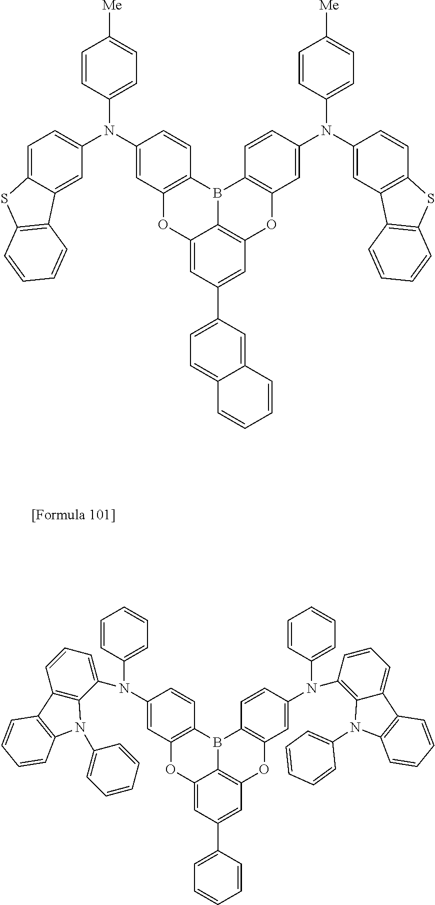 [SMILES: Cc1ccc(N(c2ccc3c(c2)Oc2cc(-c4ccc5ccccc5c4)cc4c2B3c2ccc(N(c3ccc(C)cc3)c3ccc5sc6ccccc6c5c3)cc2O4)c2ccc3sc4ccccc4c3c2)cc1 ; c1ccc(-c2cc3c4c(c2)Oc2cc(N(c5ccccc5)c5cccc6c7ccccc7n(-c7ccccc7)c56)ccc2B4c2ccc(N(c4ccccc4)c4cccc5c6ccccc6n(-c6ccccc6)c45)cc2O3)cc1]

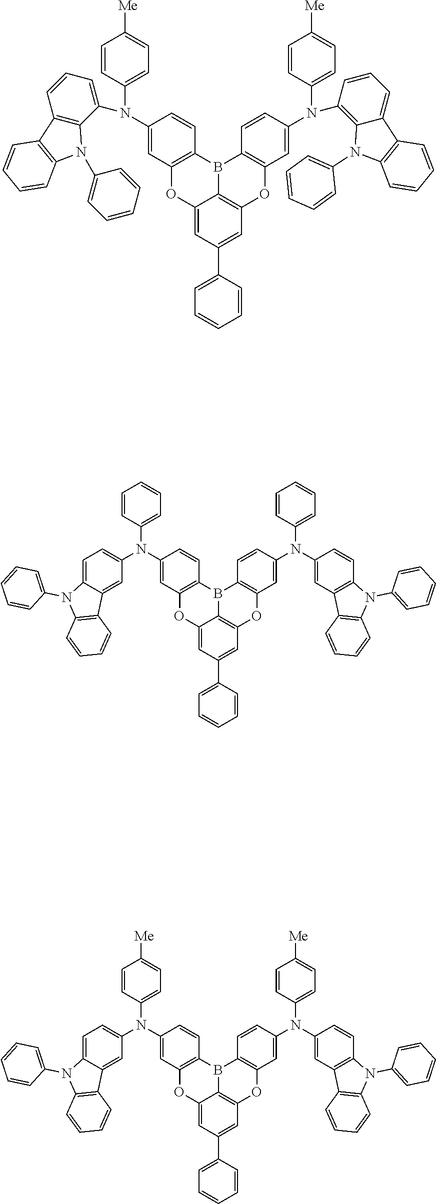 [SMILES: Cc1ccc(N(c2ccc3c(c2)Oc2cc(-c4ccccc4)cc4c2B3c2ccc(N(c3ccc(C)cc3)c3cccc5c6ccccc6n(-c6ccccc6)c35)cc2O4)c2cccc3c4ccccc4n(-c4ccccc4)c23)cc1 ; c1ccc(-c2cc3c4c(c2)Oc2cc(N(c5ccccc5)c5ccc6c(c5)c5ccccc5n6-c5ccccc5)ccc2B4c2ccc(N(c4ccccc4)c4ccc5c(c4)c4ccccc4n5-c4ccccc4)cc2O3)cc1 ; Cc1ccc(N(c2ccc3c(c2)Oc2cc(-c4ccccc4)cc4c2B3c2ccc(N(c3ccc(C)cc3)c3ccc5c(c3)c3ccccc3n5-c3ccccc3)cc2O4)c2ccc3c(c2)c2ccccc2n3-c2ccccc2)cc1]

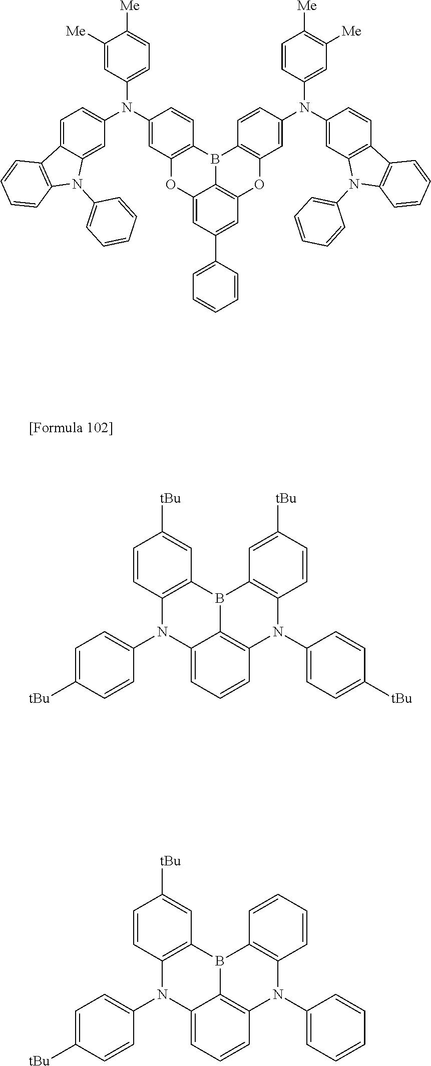

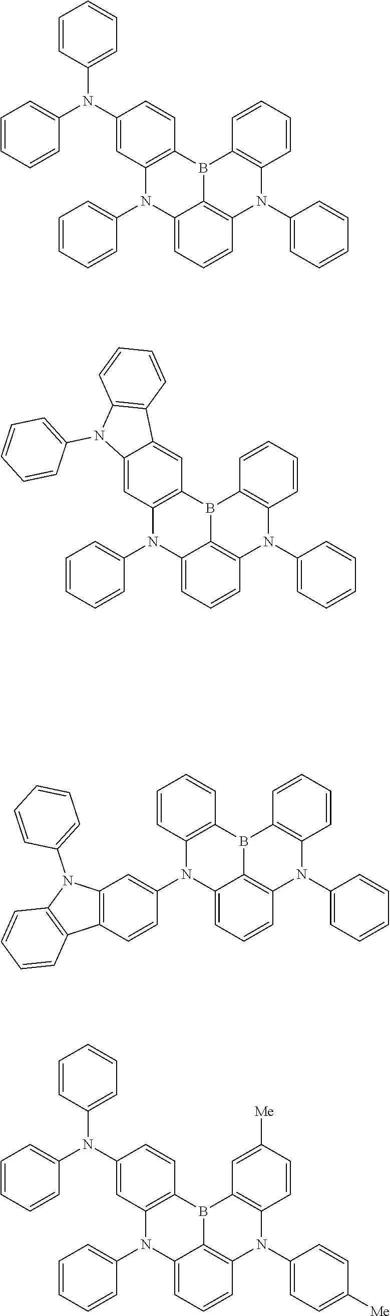

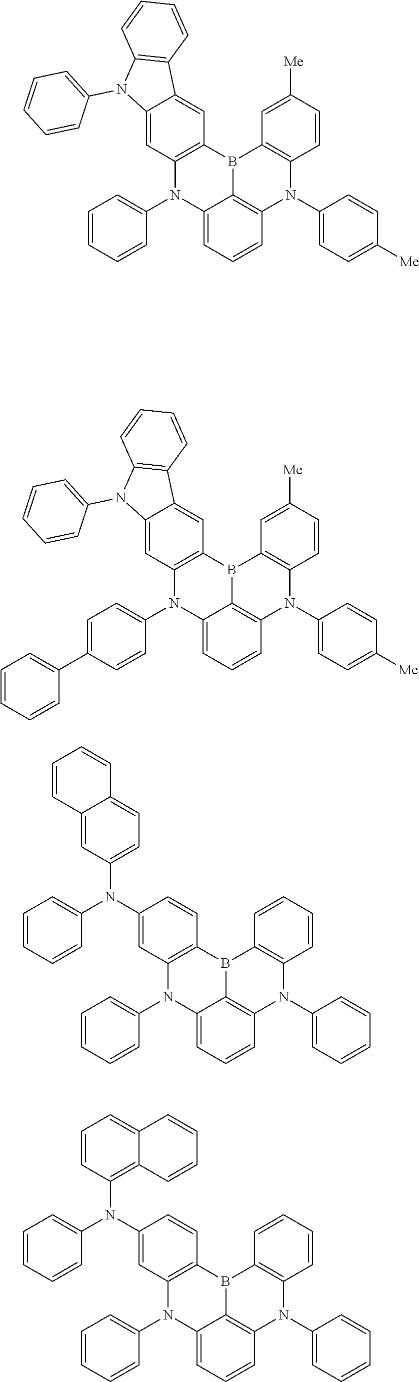 [SMILES: Cc1ccc(N2c3ccc(C)cc3B3c4cc5c6ccccc6n(-c6ccccc6)c5cc4N(c4ccccc4)c4cccc2c43)cc1 ; Cc1ccc(N2c3ccc(C)cc3B3c4cc5c6ccccc6n(-c6ccccc6)c5cc4N(c4ccc(-c5ccccc5)cc4)c4cccc2c43)cc1 ; c1ccc(N(c2ccc3c(c2)N(c2ccccc2)c2cccc4c2B3c2ccccc2N4c2ccccc2)c2ccc3ccccc3c2)cc1 ; c1ccc(N2c3ccccc3B3c4ccc(N(c5ccccc5)c5cccc6ccccc56)cc4N(c4ccccc4)c4cccc2c43)cc1]

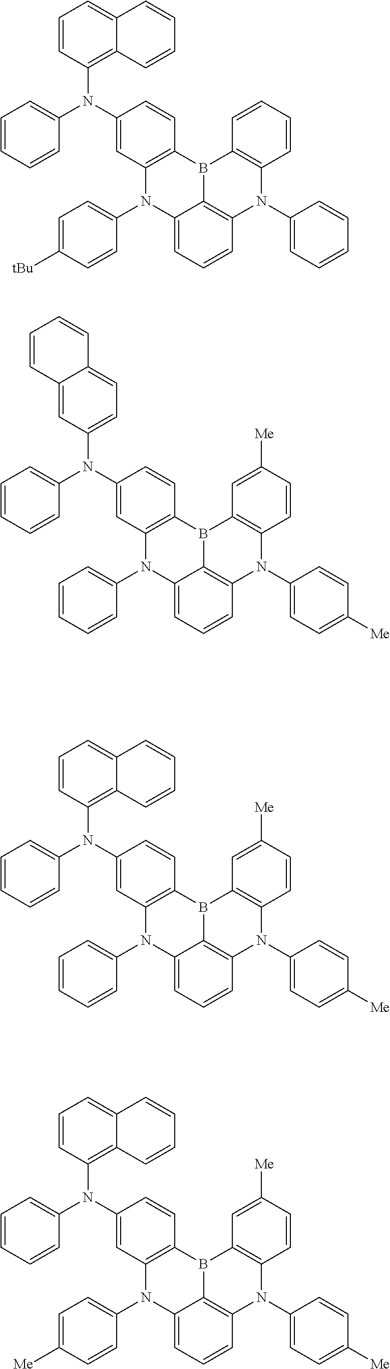 [SMILES: CC(C)(C)c1ccc(N2c3cc(N(c4ccccc4)c4cccc5ccccc45)ccc3B3c4ccccc4N(c4ccccc4)c4cccc2c43)cc1 ; Cc1ccc(N2c3ccc(C)cc3B3c4ccc(N(c5ccccc5)c5ccc6ccccc6c5)cc4N(c4ccccc4)c4cccc2c43)cc1 ; Cc1ccc(N2c3ccc(C)cc3B3c4ccc(N(c5ccccc5)c5cccc6ccccc56)cc4N(c4ccccc4)c4cccc2c43)cc1 ; Cc1ccc(N2c3ccc(C)cc3B3c4ccc(N(c5ccccc5)c5cccc6ccccc56)cc4N(c4ccc(C)cc4)c4cccc2c43)cc1]

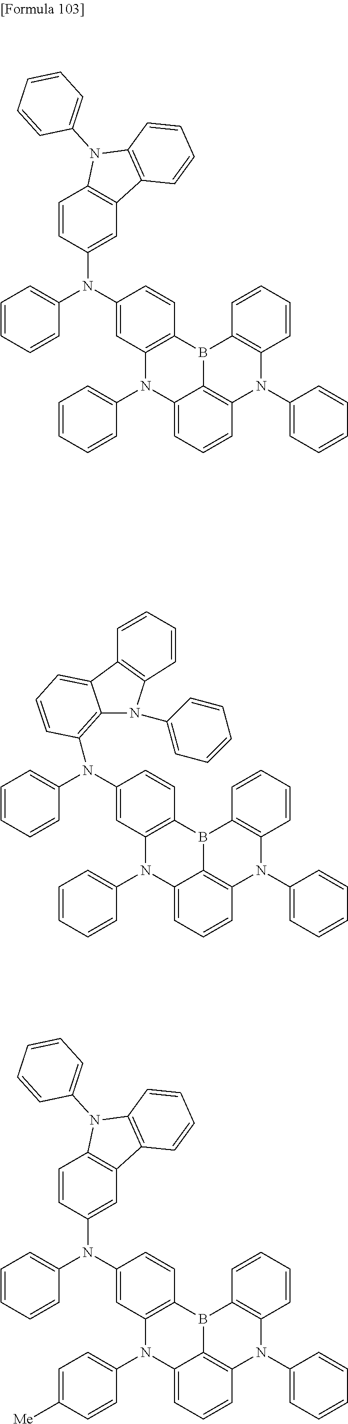 [SMILES: c1ccc(N(c2ccc3c(c2)N(c2ccccc2)c2cccc4c2B3c2ccccc2N4c2ccccc2)c2ccc3c(c2)c2ccccc2n3-c2ccccc2)cc1 ; c1ccc(N2c3ccccc3B3c4ccc(N(c5ccccc5)c5cccc6c7ccccc7n(-c7ccccc7)c56)cc4N(c4ccccc4)c4cccc2c43)cc1 ; Cc1ccc(N2c3cc(N(c4ccccc4)c4ccc5c(c4)c4ccccc4n5-c4ccccc4)ccc3B3c4ccccc4N(c4ccccc4)c4cccc2c43)cc1]

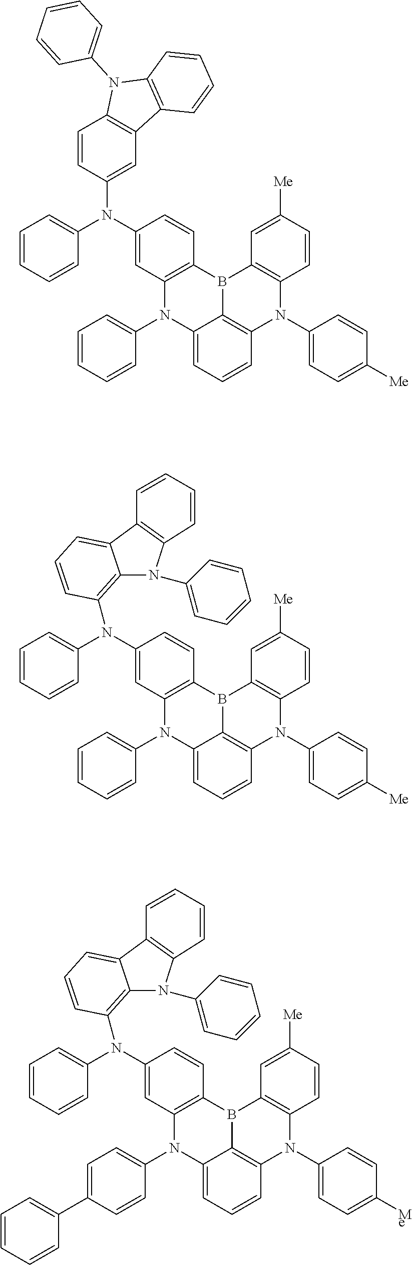 [SMILES: Cc1ccc(N2c3ccc(C)cc3B3c4ccc(N(c5ccccc5)c5ccc6c(c5)c5ccccc5n6-c5ccccc5)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccc(-c5ccccc5)cc4)c4cccc2c43)cc1]

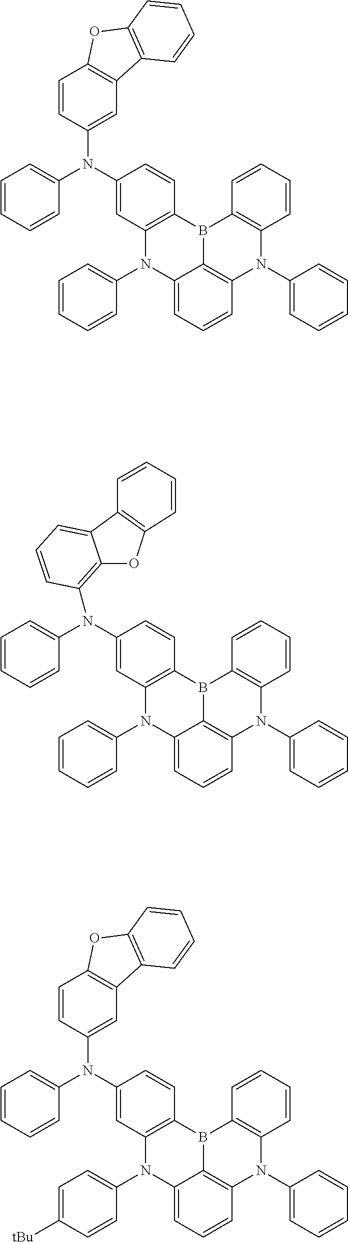 [SMILES: c1ccc(N(c2ccc3c(c2)N(c2ccccc2)c2cccc4c2B3c2ccccc2N4c2ccccc2)c2ccc3oc4ccccc4c3c2)cc1 ; c1ccc(N2c3ccccc3B3c4ccc(N(c5ccccc5)c5cccc6c5oc5ccccc56)cc4N(c4ccccc4)c4cccc2c43)cc1 ; CC(C)(C)c1ccc(N2c3cc(N(c4ccccc4)c4ccc5oc6ccccc6c5c4)ccc3B3c4ccccc4N(c4ccccc4)c4cccc2c43)cc1]

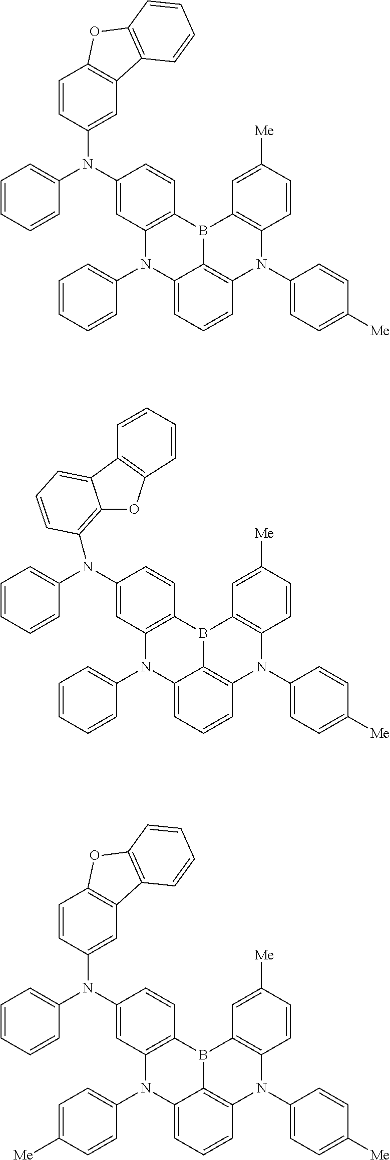 [SMILES: Cc1ccc(N2c3ccc(C)cc3B3c4ccc(N(c5ccccc5)c5ccc6oc7ccccc7c6c5)cc4N(c4ccccc4)c4cccc2c43)cc1 ; Cc1ccc(N2c3ccc(C)cc3B3c4ccc(N(c5ccccc5)c5cccc6c5oc5ccccc56)cc4N(c4ccccc4)c4cccc2c43)cc1 ; Cc1ccc(N2c3ccc(C)cc3B3c4ccc(N(c5ccccc5)c5ccc6oc7ccccc7c6c5)cc4N(c4ccc(C)cc4)c4cccc2c43)cc1]

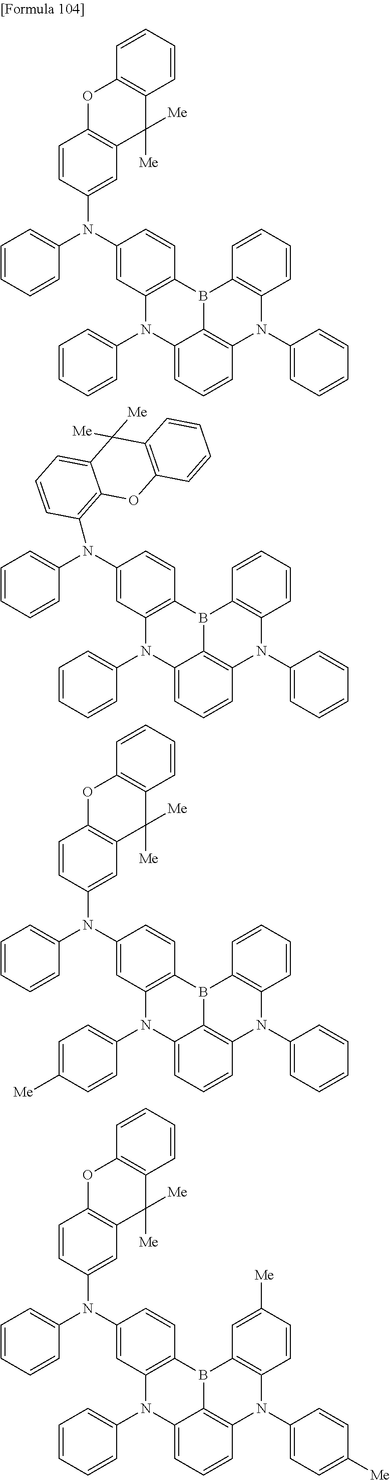

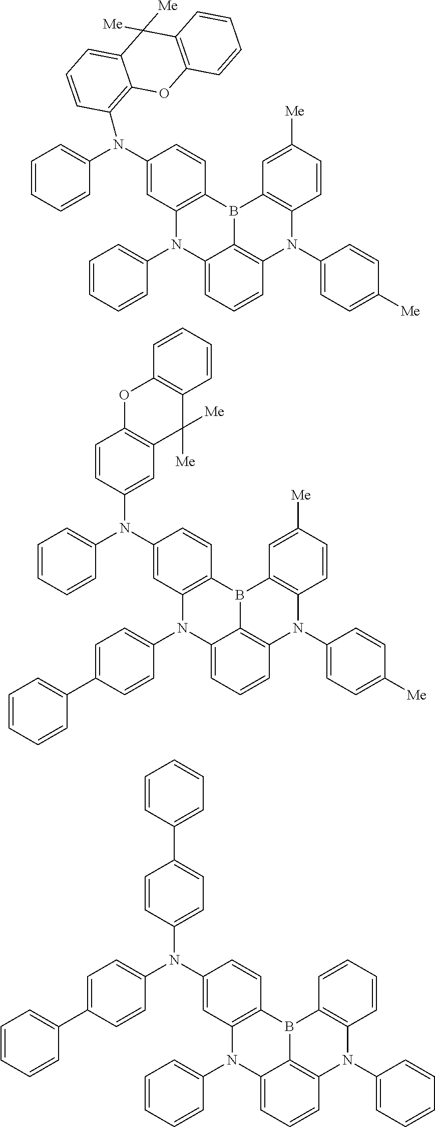

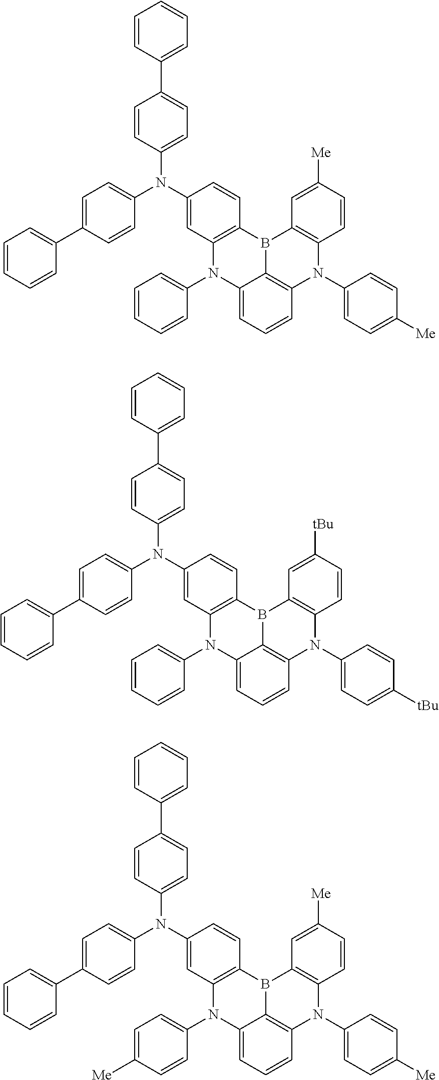

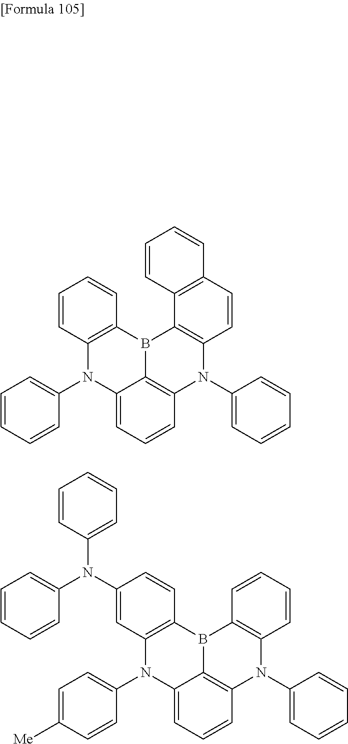 [SMILES: c1ccc(N2c3ccccc3B3c4c2cccc4N(c2ccccc2)c2ccc4ccccc4c23)cc1 ; Cc1ccc(N2c3cc(N(c4ccccc4)c4ccccc4)ccc3B3c4ccccc4N(c4ccccc4)c4cccc2c43)cc1]

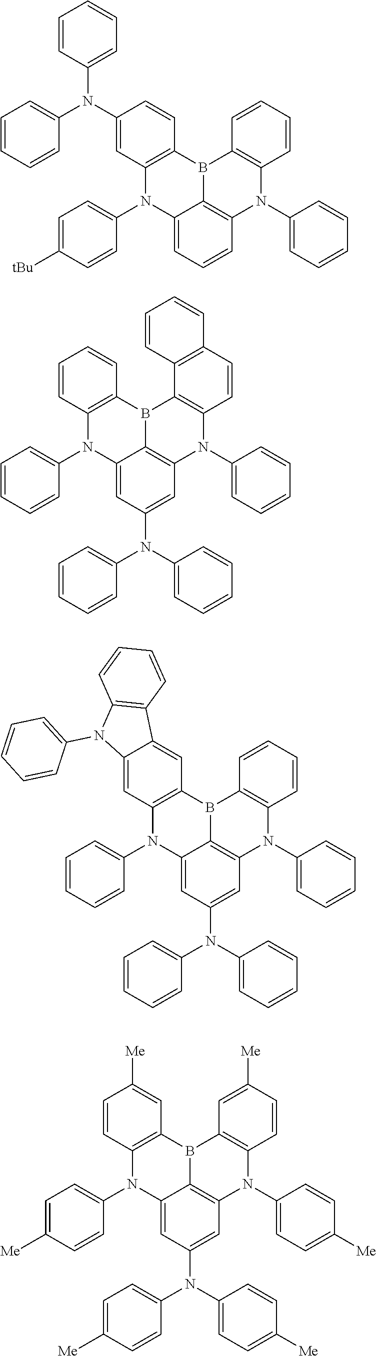

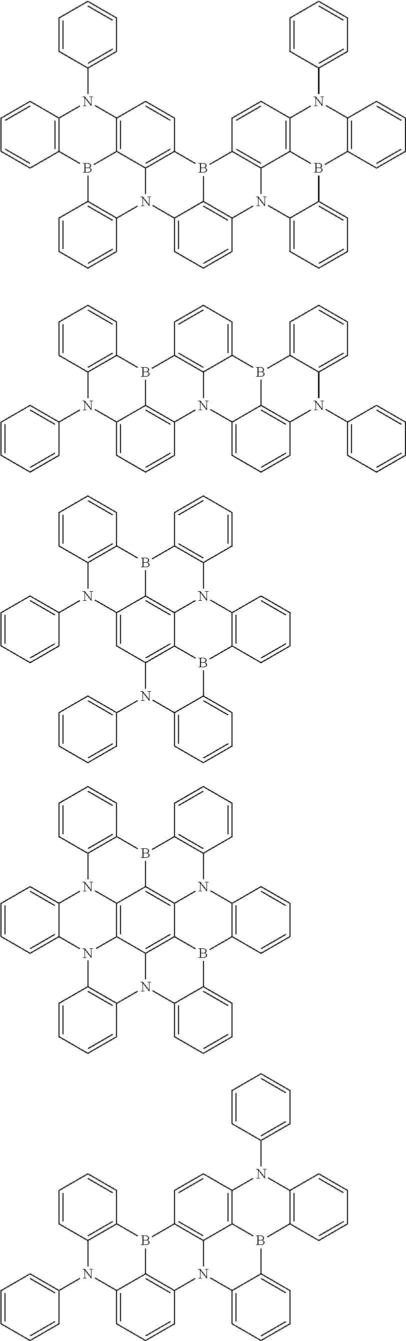

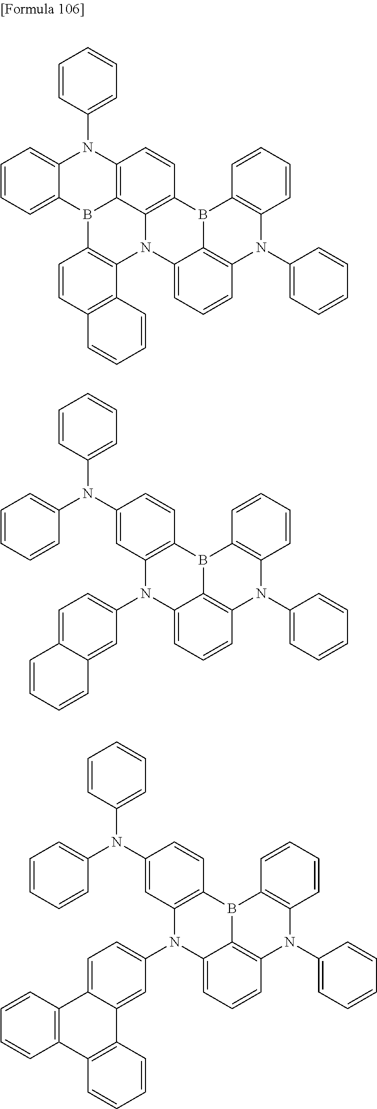

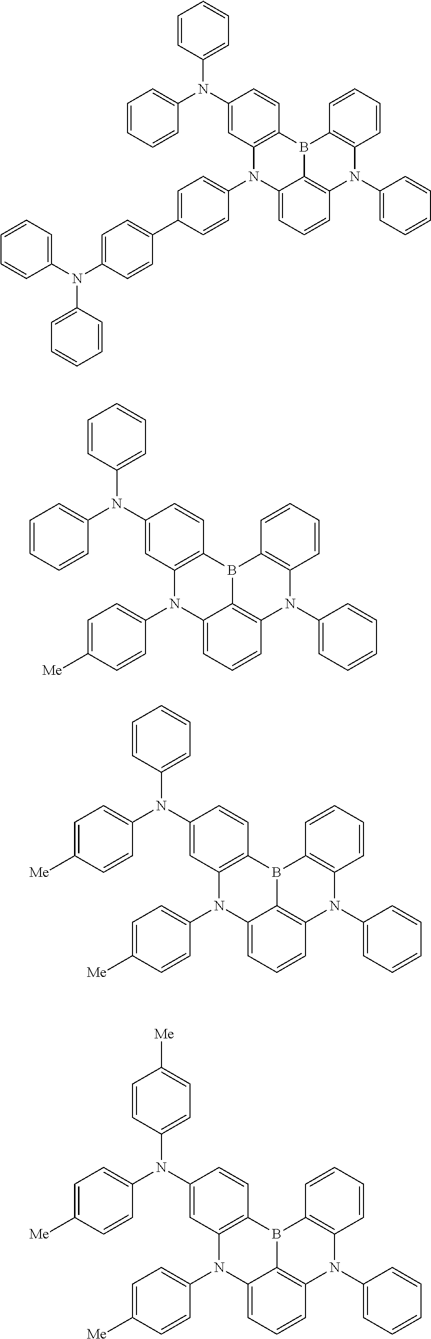 [SMILES: c1ccc(N(c2ccccc2)c2ccc(-c3ccc(N4c5cc(N(c6ccccc6)c6ccccc6)ccc5B5c6ccccc6N(c6ccccc6)c6cccc4c65)cc3)cc2)cc1 ; Cc1ccc(N2c3cc(N(c4ccccc4)c4ccccc4)ccc3B3c4ccccc4N(c4ccccc4)c4cccc2c43)cc1 ; Cc1ccc(N(c2ccccc2)c2ccc3c(c2)N(c2ccc(C)cc2)c2cccc4c2B3c2ccccc2N4c2ccccc2)cc1 ; Cc1ccc(N(c2ccc(C)cc2)c2ccc3c(c2)N(c2ccc(C)cc2)c2cccc4c2B3c2ccccc2N4c2ccccc2)cc1]

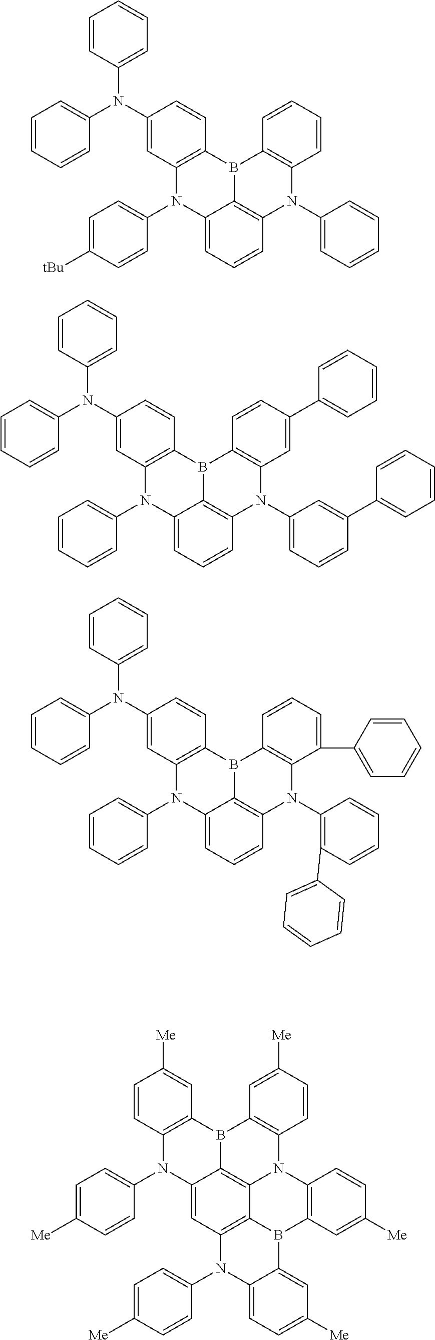

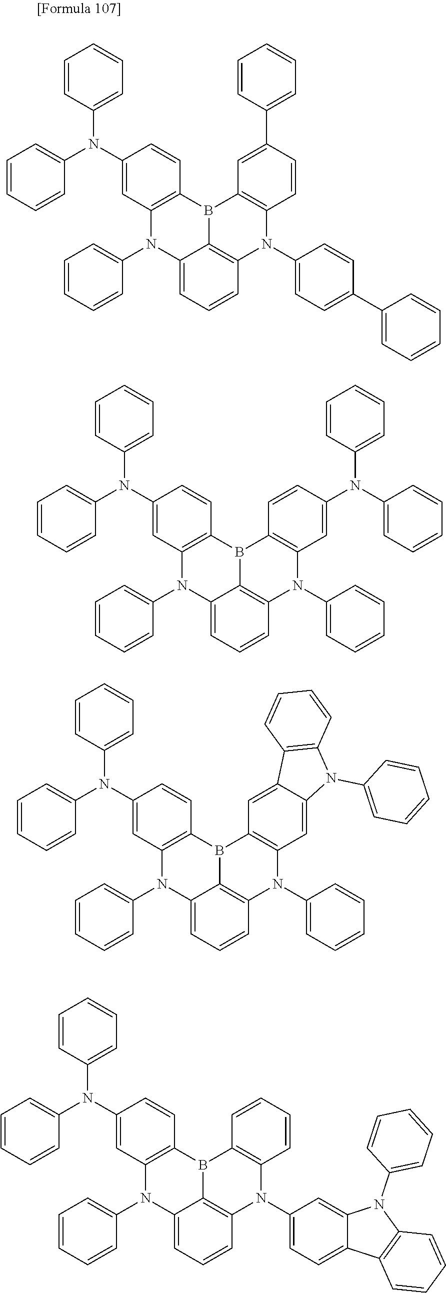

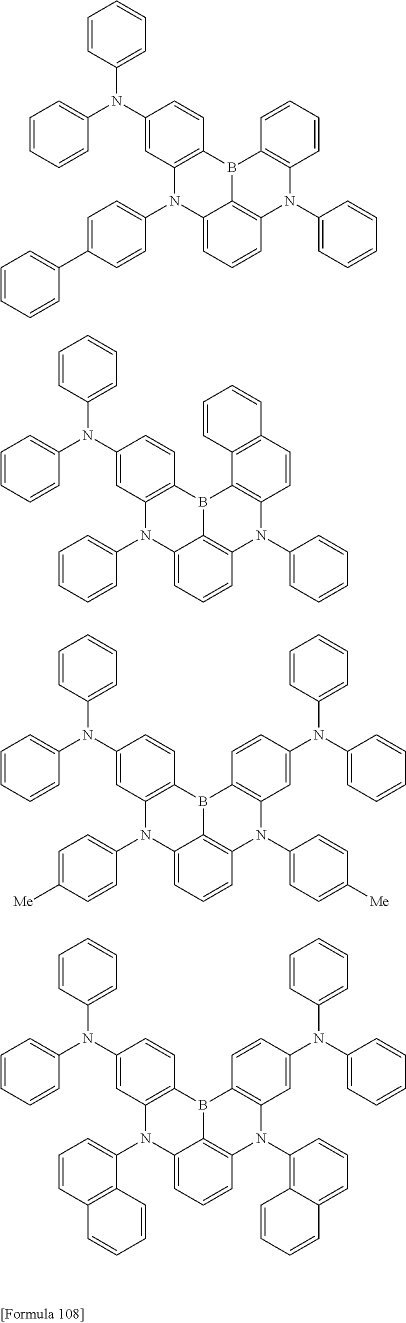

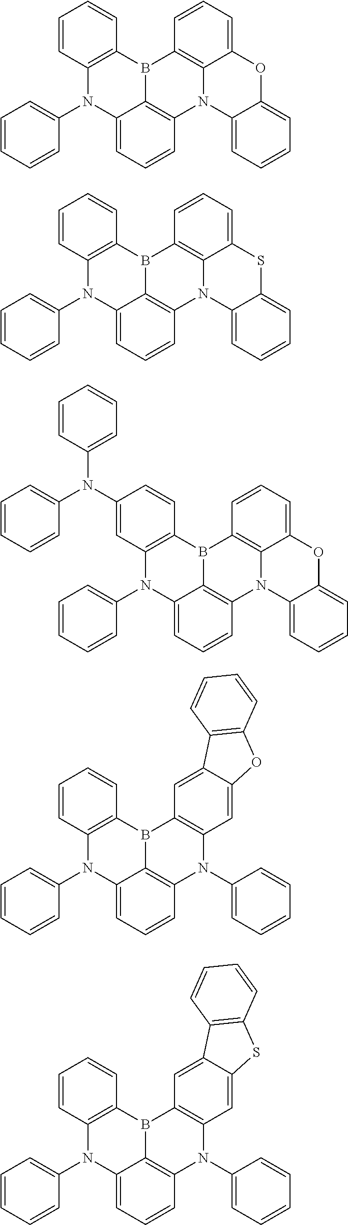

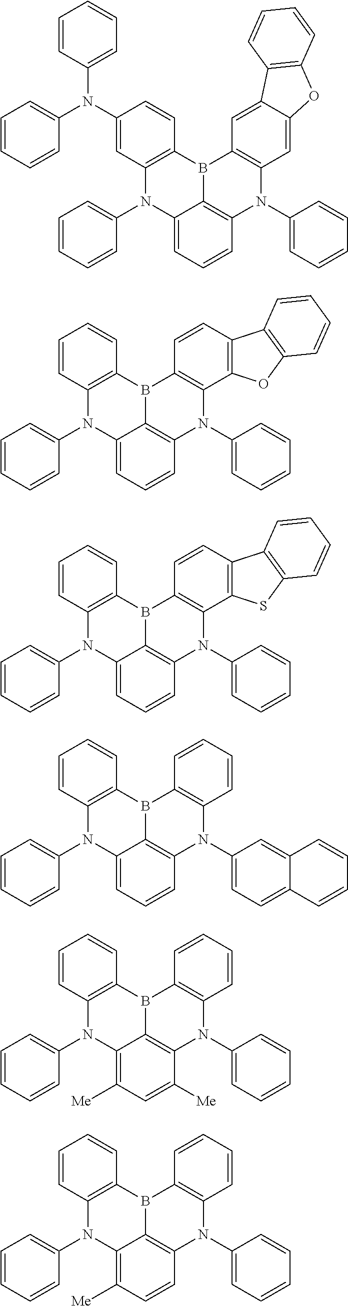

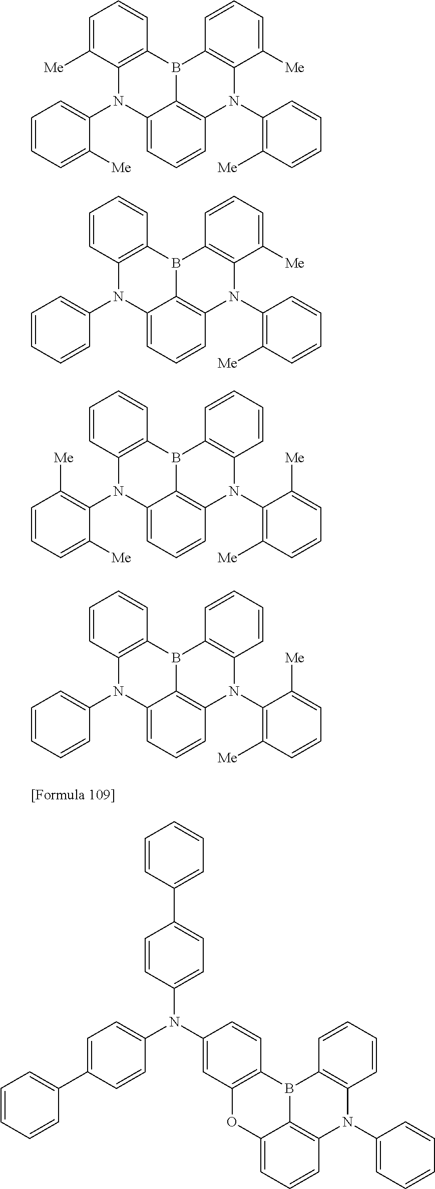

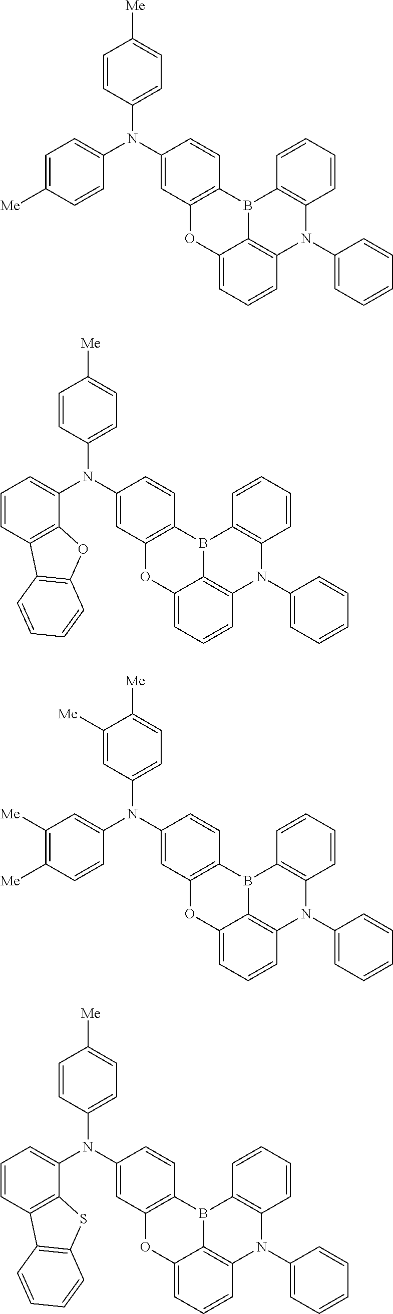 [SMILES: Cc1ccc(N(c2ccc(C)cc2)c2ccc3c(c2)Oc2cccc4c2B3c2ccccc2N4c2ccccc2)cc1 ; Cc1ccc(N(c2ccc3c(c2)Oc2cccc4c2B3c2ccccc2N4c2ccccc2)c2cccc3c2oc2ccccc23)cc1 ; Cc1ccc(N(c2ccc(C)c(C)c2)c2ccc3c(c2)Oc2cccc4c2B3c2ccccc2N4c2ccccc2)cc1C ; Cc1ccc(N(c2ccc3c(c2)Oc2cccc4c2B3c2ccccc2N4c2ccccc2)c2cccc3c2sc2ccccc23)cc1]

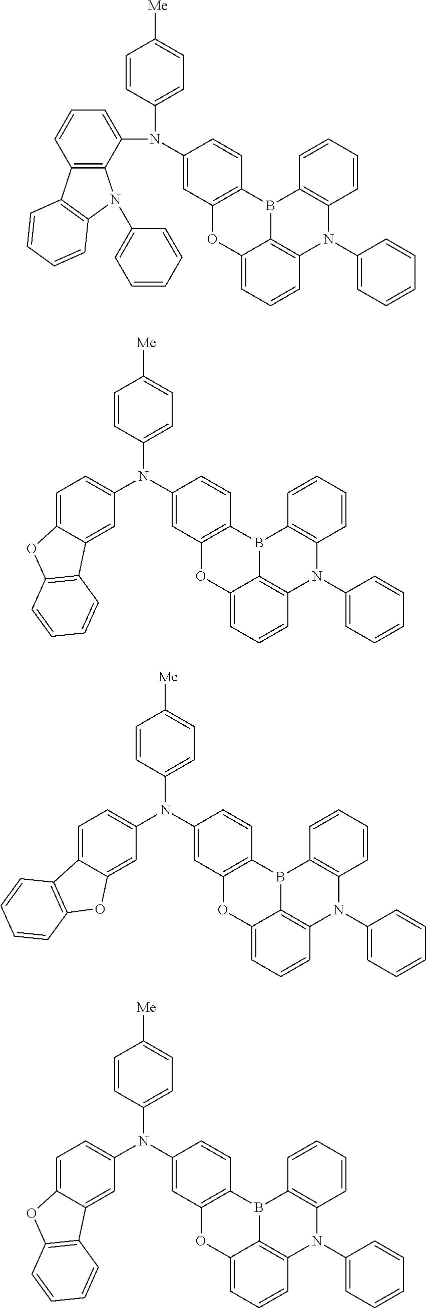 [SMILES: Cc1ccc(N(c2ccc3c(c2)Oc2cccc4c2B3c2ccccc2N4c2ccccc2)c2cccc3c4ccccc4n(-c4ccccc4)c23)cc1 ; Cc1ccc(N(c2ccc3c(c2)Oc2cccc4c2B3c2ccccc2N4c2ccccc2)c2ccc3oc4ccccc4c3c2)cc1 ; Cc1ccc(N(c2ccc3c(c2)Oc2cccc4c2B3c2ccccc2N4c2ccccc2)c2ccc3c(c2)oc2ccccc23)cc1 ; Cc1ccc(N(c2ccc3c(c2)Oc2cccc4c2B3c2ccccc2N4c2ccccc2)c2ccc3oc4ccccc4c3c2)cc1]

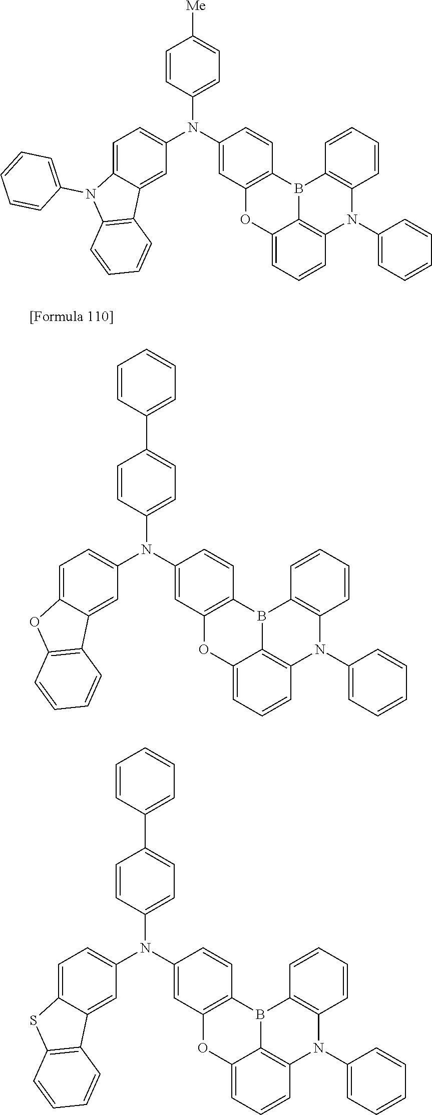 [SMILES: Cc1ccc(N(c2ccc3c(c2)Oc2cccc4c2B3c2ccccc2N4c2ccccc2)c2ccc3c(c2)c2ccccc2n3-c2ccccc2)cc1 ; c1ccc(-c2ccc(N(c3ccc4c(c3)Oc3cccc5c3B4c3ccccc3N5c3ccccc3)c3ccc4oc5ccccc5c4c3)cc2)cc1 ; c1ccc(-c2ccc(N(c3ccc4c(c3)Oc3cccc5c3B4c3ccccc3N5c3ccccc3)c3ccc4sc5ccccc5c4c3)cc2)cc1]

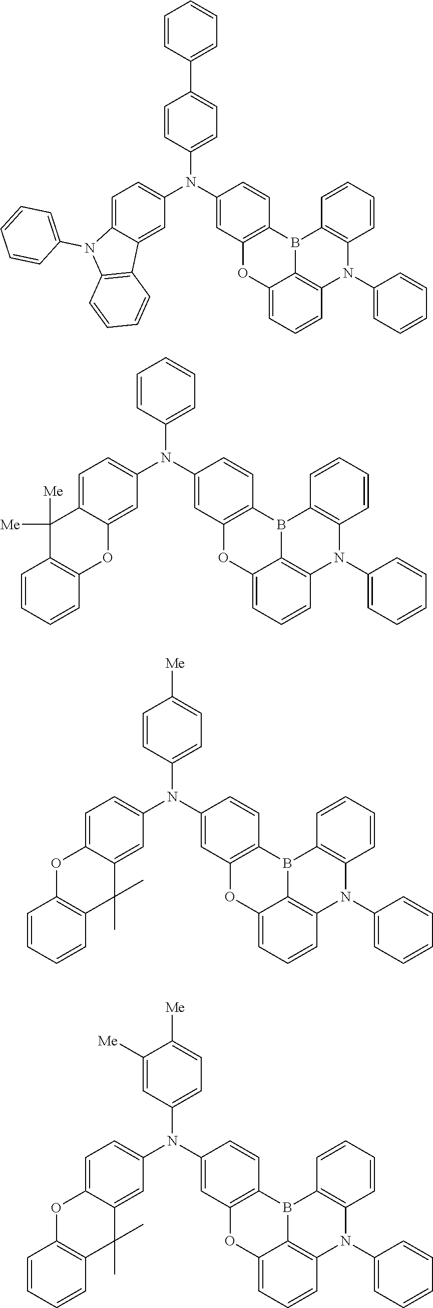

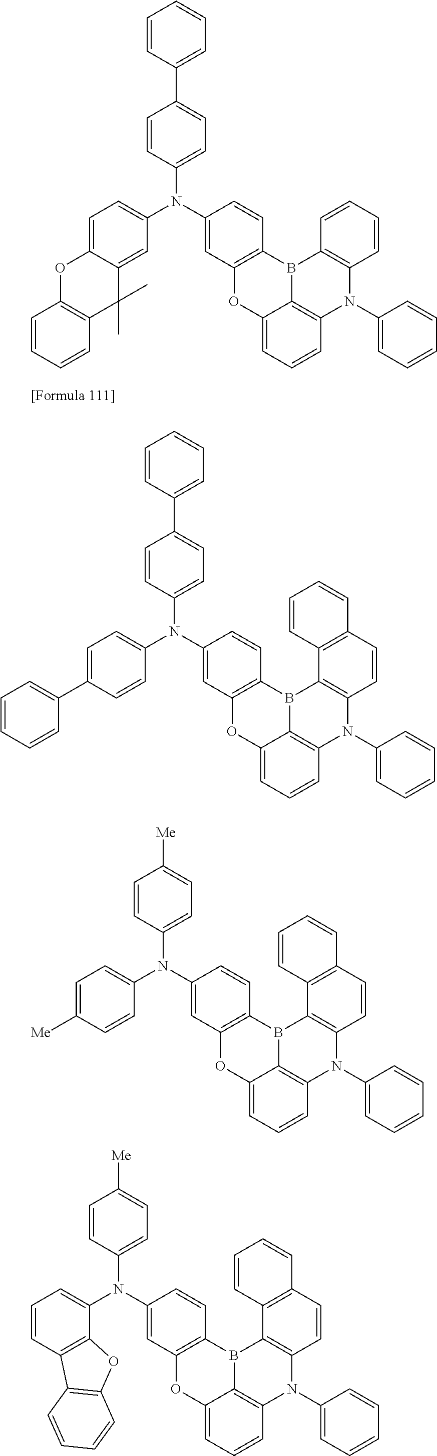 [SMILES: CC1(C)c2ccccc2Oc2ccc(N(c3ccc(-c4ccccc4)cc3)c3ccc4c(c3)Oc3cccc5c3B4c3ccccc3N5c3ccccc3)cc21 ; c1ccc(-c2ccc(N(c3ccc(-c4ccccc4)cc3)c3ccc4c(c3)Oc3cccc5c3B4c3c(ccc4ccccc34)N5c3ccccc3)cc2)cc1 ; Cc1ccc(N(c2ccc(C)cc2)c2ccc3c(c2)Oc2cccc4c2B3c2c(ccc3ccccc23)N4c2ccccc2)cc1 ; Cc1ccc(N(c2ccc3c(c2)Oc2cccc4c2B3c2c(ccc3ccccc23)N4c2ccccc2)c2cccc3c2oc2ccccc23)cc1]

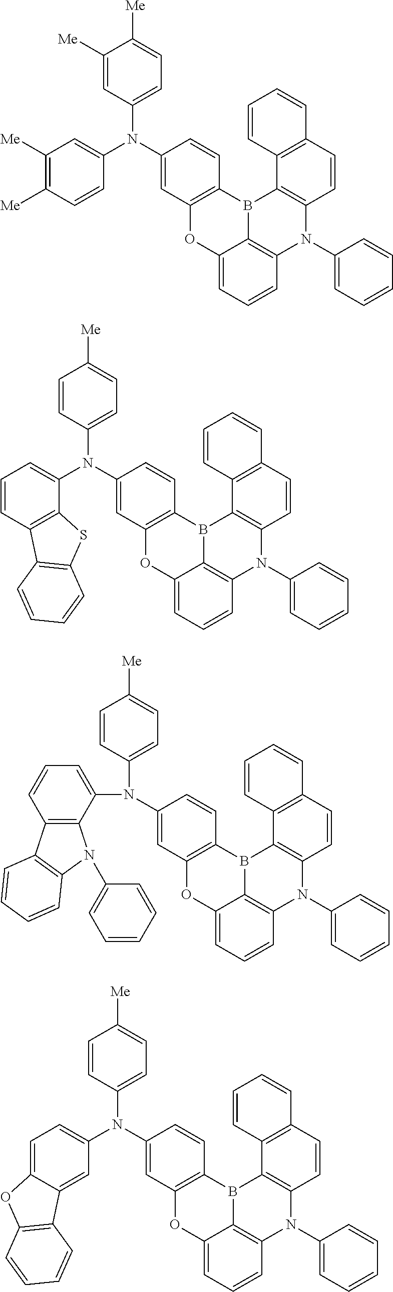 [SMILES: Cc1ccc(N(c2ccc(C)c(C)c2)c2ccc3c(c2)Oc2cccc4c2B3c2c(ccc3ccccc23)N4c2ccccc2)cc1C ; Cc1ccc(N(c2ccc3c(c2)Oc2cccc4c2B3c2c(ccc3ccccc23)N4c2ccccc2)c2cccc3c2sc2ccccc23)cc1 ; Cc1ccc(N(c2ccc3c(c2)Oc2cccc4c2B3c2c(ccc3ccccc23)N4c2ccccc2)c2cccc3c4ccccc4n(-c4ccccc4)c23)cc1 ; Cc1ccc(N(c2ccc3c(c2)Oc2cccc4c2B3c2c(ccc3ccccc23)N4c2ccccc2)c2ccc3oc4ccccc4c3c2)cc1]

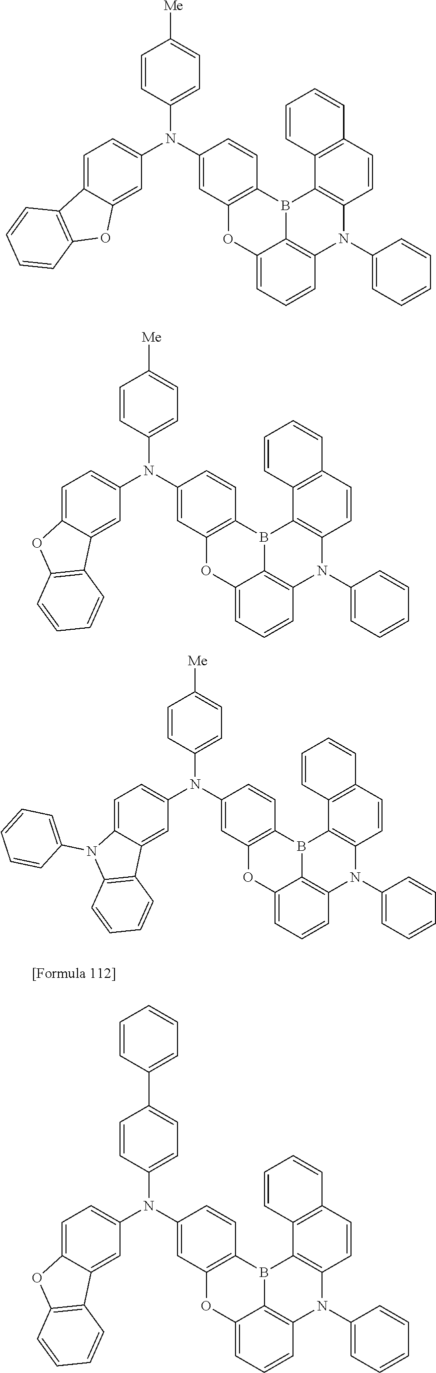 [SMILES: Cc1ccc(N(c2ccc3c(c2)Oc2cccc4c2B3c2c(ccc3ccccc23)N4c2ccccc2)c2ccc3c(c2)oc2ccccc23)cc1 ; Cc1ccc(N(c2ccc3c(c2)Oc2cccc4c2B3c2c(ccc3ccccc23)N4c2ccccc2)c2ccc3oc4ccccc4c3c2)cc1 ; Cc1ccc(N(c2ccc3c(c2)Oc2cccc4c2B3c2c(ccc3ccccc23)N4c2ccccc2)c2ccc3c(c2)c2ccccc2n3-c2ccccc2)cc1 ; c1ccc(-c2ccc(N(c3ccc4c(c3)Oc3cccc5c3B4c3c(ccc4ccccc34)N5c3ccccc3)c3ccc4oc5ccccc5c4c3)cc2)cc1]

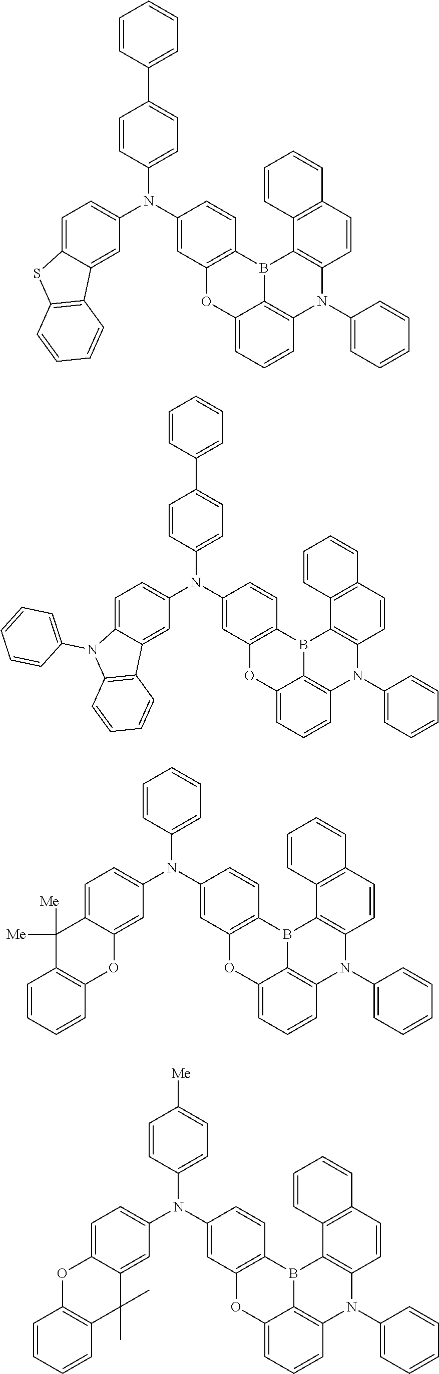 [SMILES: c1ccc(-c2ccc(N(c3ccc4c(c3)Oc3cccc5c3B4c3c(ccc4ccccc34)N5c3ccccc3)c3ccc4sc5ccccc5c4c3)cc2)cc1 ; c1ccc(-c2ccc(N(c3ccc4c(c3)Oc3cccc5c3B4c3c(ccc4ccccc34)N5c3ccccc3)c3ccc4c(c3)c3ccccc3n4-c3ccccc3)cc2)cc1 ; CC1(C)c2ccccc2Oc2cc(N(c3ccccc3)c3ccc4c(c3)Oc3cccc5c3B4c3c(ccc4ccccc34)N5c3ccccc3)ccc21 ; Cc1ccc(N(c2ccc3c(c2)Oc2cccc4c2B3c2c(ccc3ccccc23)N4c2ccccc2)c2ccc3c(c2)C(C)(C)c2ccccc2O3)cc1]

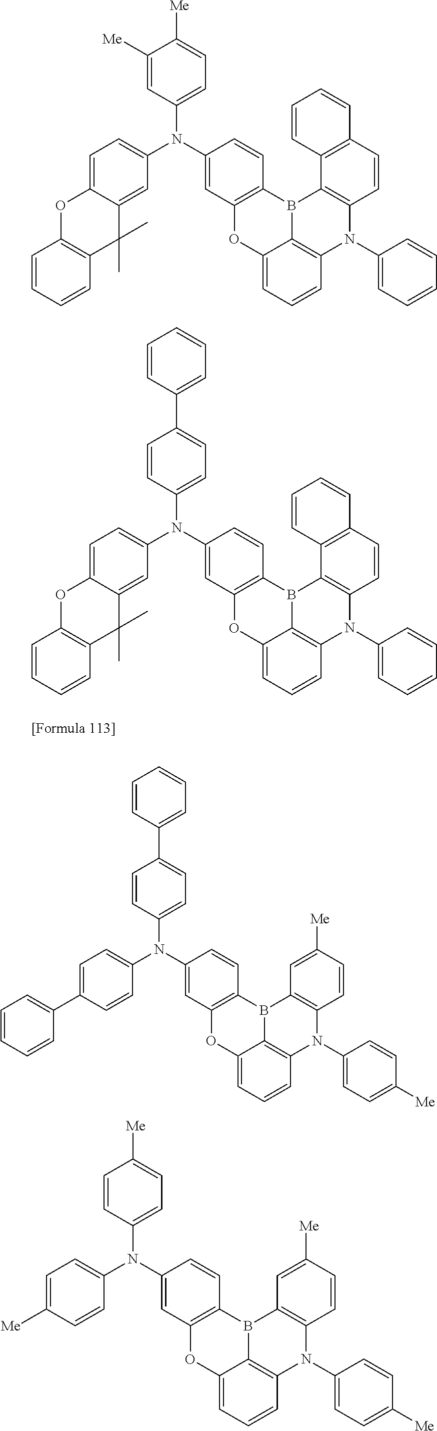 [SMILES: Cc1ccc(N(c2ccc3c(c2)Oc2cccc4c2B3c2c(ccc3ccccc23)N4c2ccccc2)c2ccc3c(c2)C(C)(C)c2ccccc2O3)cc1C ; CC1(C)c2ccccc2Oc2ccc(N(c3ccc(-c4ccccc4)cc3)c3ccc4c(c3)Oc3cccc5c3B4c3c(ccc4ccccc34)N5c3ccccc3)cc21 ; Cc1ccc(N2c3ccc(C)cc3B3c4ccc(N(c5ccc(-c6ccccc6)cc5)c5ccc(-c6ccccc6)cc5)cc4Oc4cccc2c43)cc1 ; Cc1ccc(N(c2ccc(C)cc2)c2ccc3c(c2)Oc2cccc4c2B3c2cc(C)ccc2N4c2ccc(C)cc2)cc1]

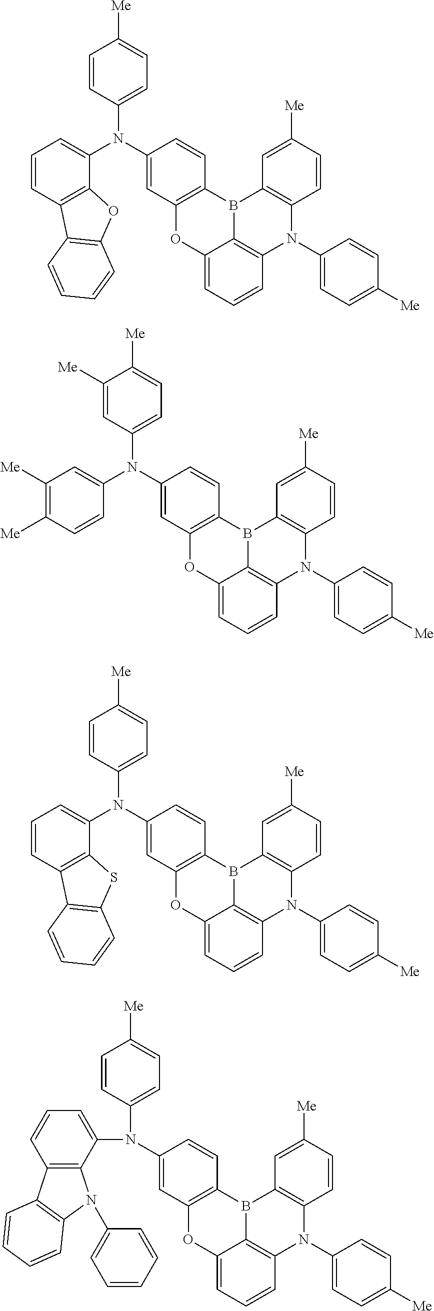 [SMILES: Cc1ccc(N2c3ccc(C)cc3B3c4ccc(N(c5ccc(C)cc5)c5cccc6c5oc5ccccc56)cc4Oc4cccc2c43)cc1 ; Cc1ccc(N2c3ccc(C)cc3B3c4ccc(N(c5ccc(C)c(C)c5)c5ccc(C)c(C)c5)cc4Oc4cccc2c43)cc1 ; Cc1ccc(N2c3ccc(C)cc3B3c4ccc(N(c5ccc(C)cc5)c5cccc6c5sc5ccccc56)cc4Oc4cccc2c43)cc1 ; Cc1ccc(N2c3ccc(C)cc3B3c4ccc(N(c5ccc(C)cc5)c5cccc6c7ccccc7n(-c7ccccc7)c56)cc4Oc4cccc2c43)cc1]

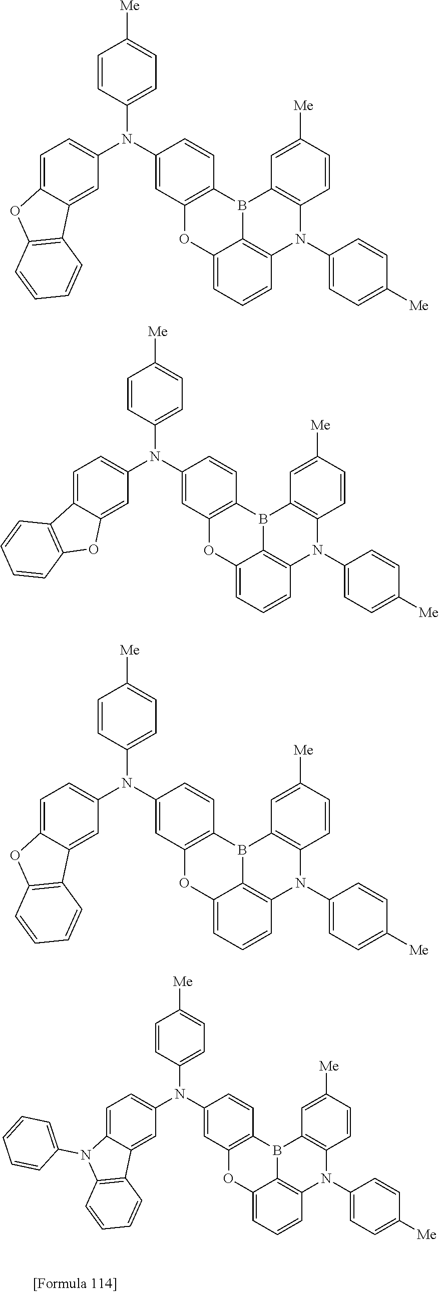 [SMILES: Cc1ccc(N(c2ccc3c(c2)Oc2cccc4c2B3c2cc(C)ccc2N4c2ccc(C)cc2)c2ccc3oc4ccccc4c3c2)cc1 ; Cc1ccc(N(c2ccc3c(c2)Oc2cccc4c2B3c2cc(C)ccc2N4c2ccc(C)cc2)c2ccc3c(c2)oc2ccccc23)cc1 ; Cc1ccc(N(c2ccc3c(c2)Oc2cccc4c2B3c2cc(C)ccc2N4c2ccc(C)cc2)c2ccc3oc4ccccc4c3c2)cc1 ; Cc1ccc(N(c2ccc3c(c2)Oc2cccc4c2B3c2cc(C)ccc2N4c2ccc(C)cc2)c2ccc3c(c2)c2ccccc2n3-c2ccccc2)cc1]

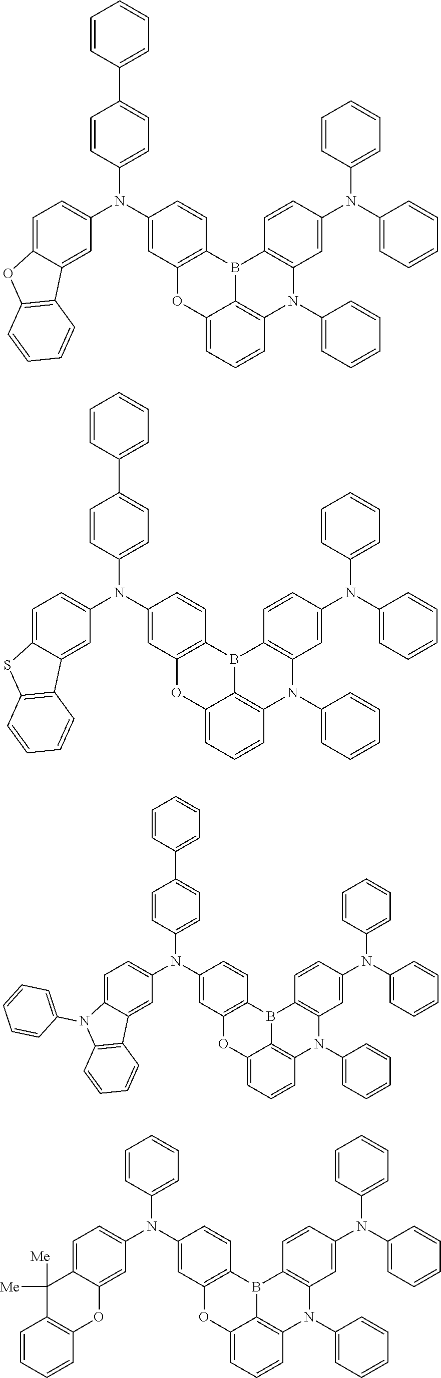

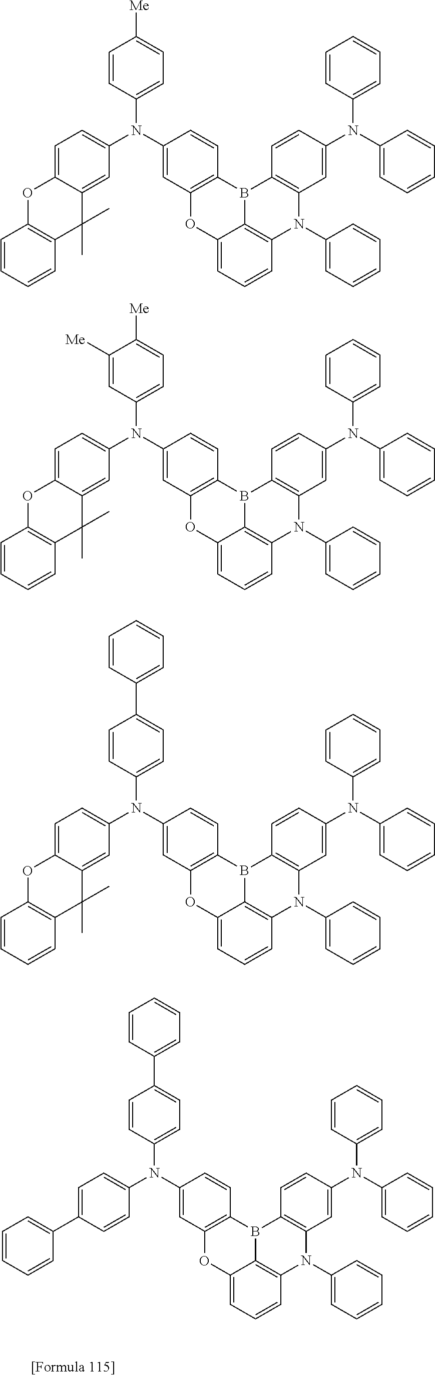 [SMILES: Cc1ccc(N(c2ccc3c(c2)Oc2cccc4c2B3c2ccc(N(c3ccccc3)c3ccccc3)cc2N4c2ccccc2)c2ccc3c(c2)C(C)(C)c2ccccc2O3)cc1 ; Cc1ccc(N(c2ccc3c(c2)Oc2cccc4c2B3c2ccc(N(c3ccccc3)c3ccccc3)cc2N4c2ccccc2)c2ccc3c(c2)C(C)(C)c2ccccc2O3)cc1C ; CC1(C)c2ccccc2Oc2ccc(N(c3ccc(-c4ccccc4)cc3)c3ccc4c(c3)Oc3cccc5c3B4c3ccc(N(c4ccccc4)c4ccccc4)cc3N5c3ccccc3)cc21 ; c1ccc(-c2ccc(N(c3ccc(-c4ccccc4)cc3)c3ccc4c(c3)Oc3cccc5c3B4c3ccc(N(c4ccccc4)c4ccccc4)cc3N5c3ccccc3)cc2)cc1]

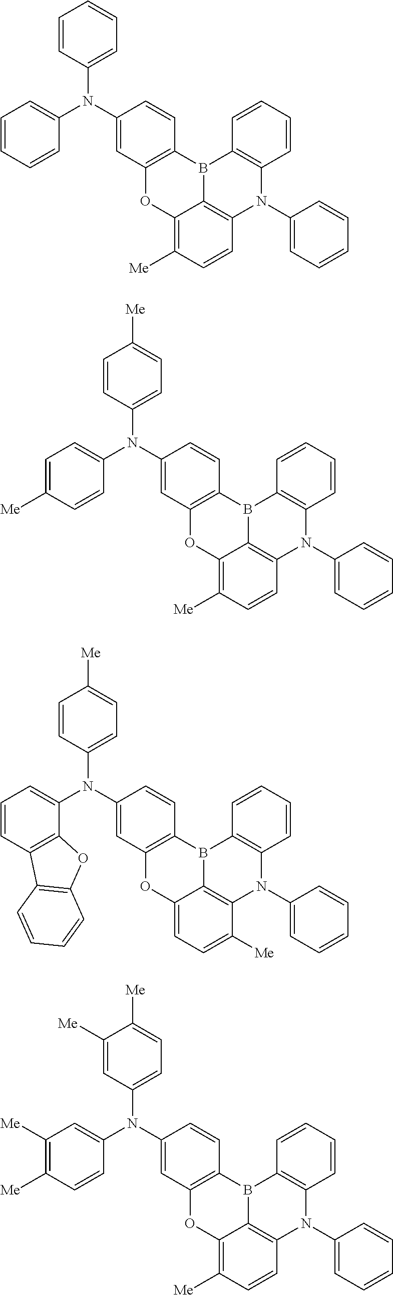

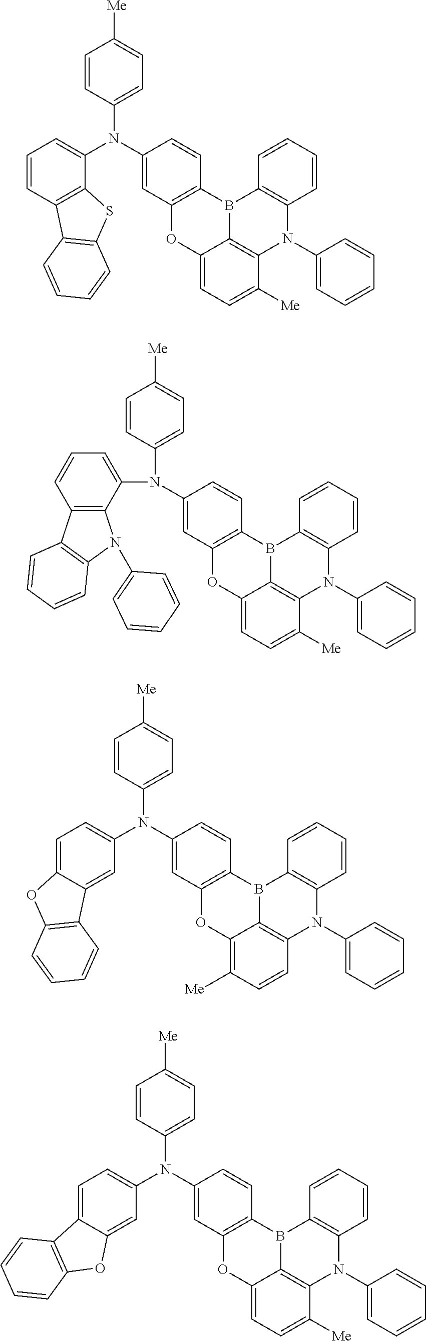 [SMILES: Cc1ccc(N(c2ccc3c(c2)Oc2ccc(C)c4c2B3c2ccccc2N4c2ccccc2)c2cccc3c2sc2ccccc23)cc1 ; Cc1ccc(N(c2ccc3c(c2)Oc2ccc(C)c4c2B3c2ccccc2N4c2ccccc2)c2cccc3c4ccccc4n(-c4ccccc4)c23)cc1 ; Cc1ccc(N(c2ccc3c(c2)Oc2c(C)ccc4c2B3c2ccccc2N4c2ccccc2)c2ccc3oc4ccccc4c3c2)cc1 ; Cc1ccc(N(c2ccc3c(c2)Oc2ccc(C)c4c2B3c2ccccc2N4c2ccccc2)c2ccc3c(c2)oc2ccccc23)cc1]

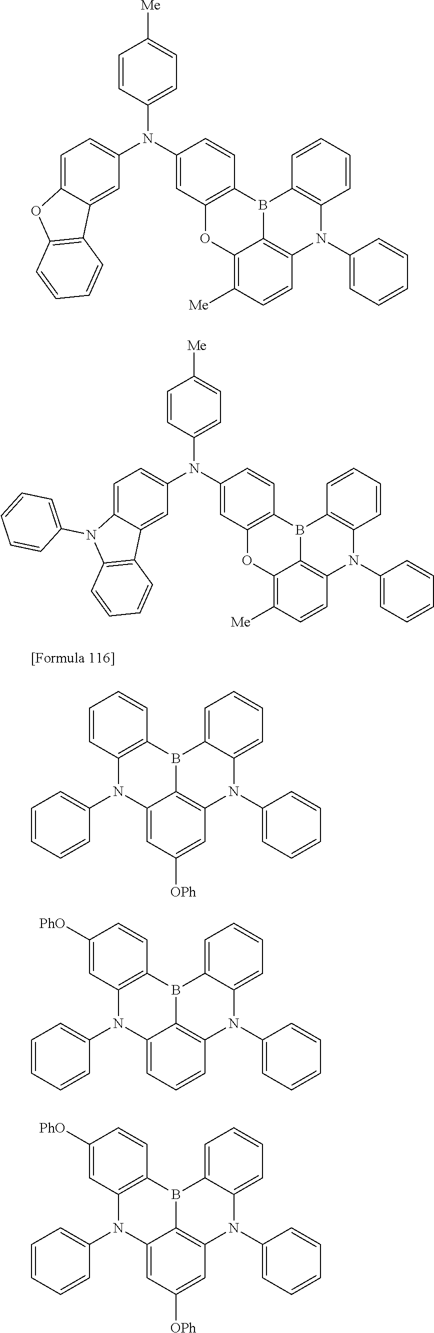

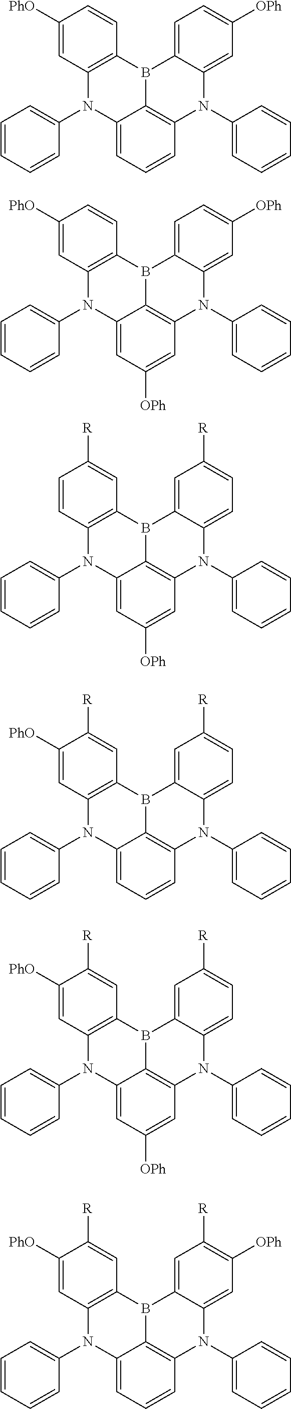

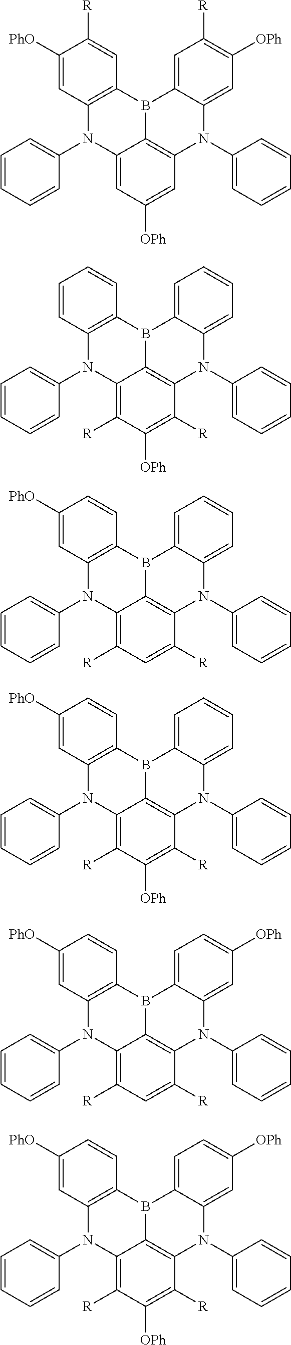

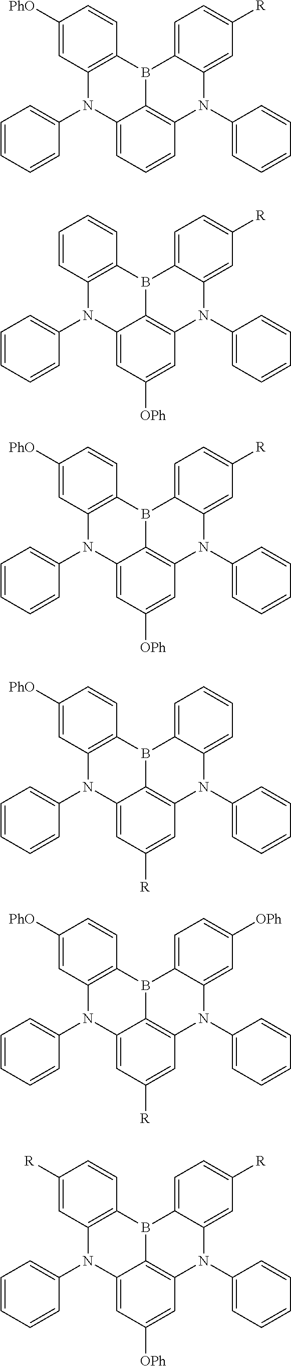

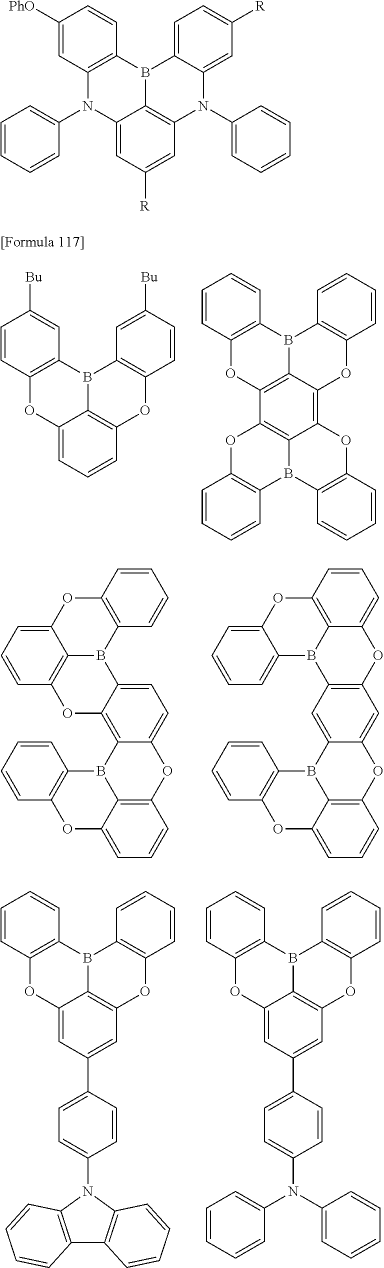

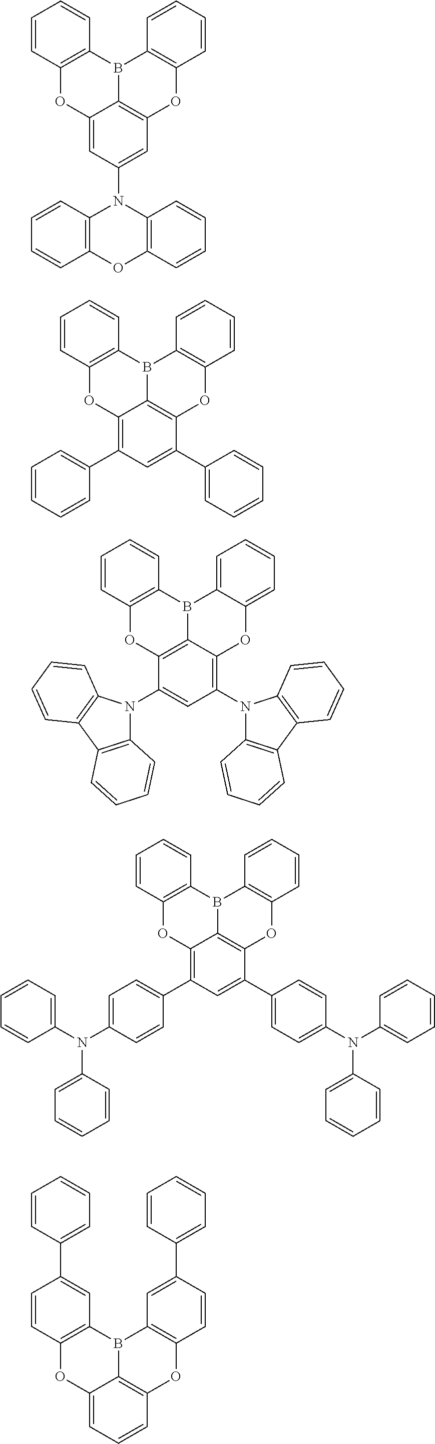

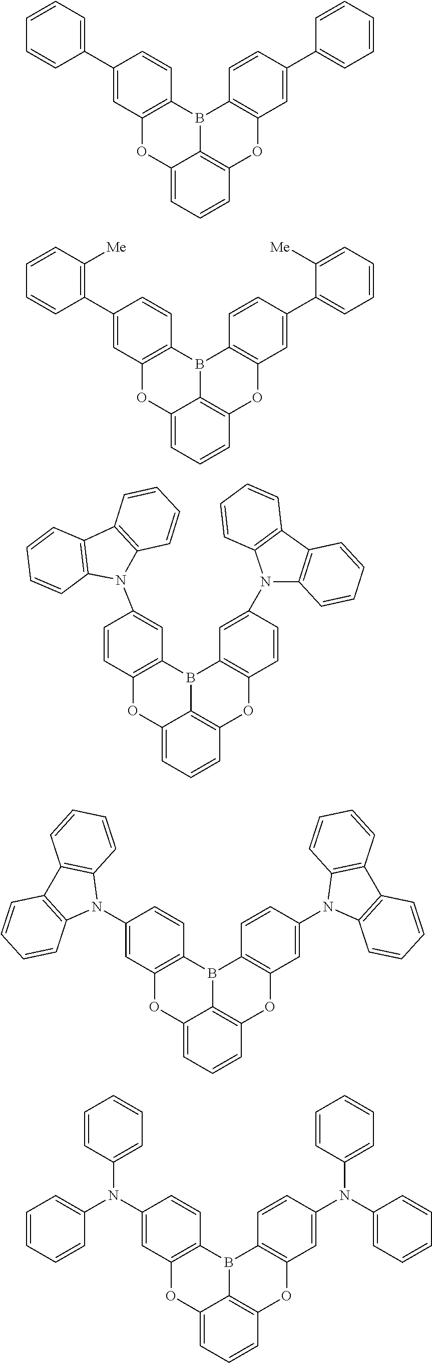

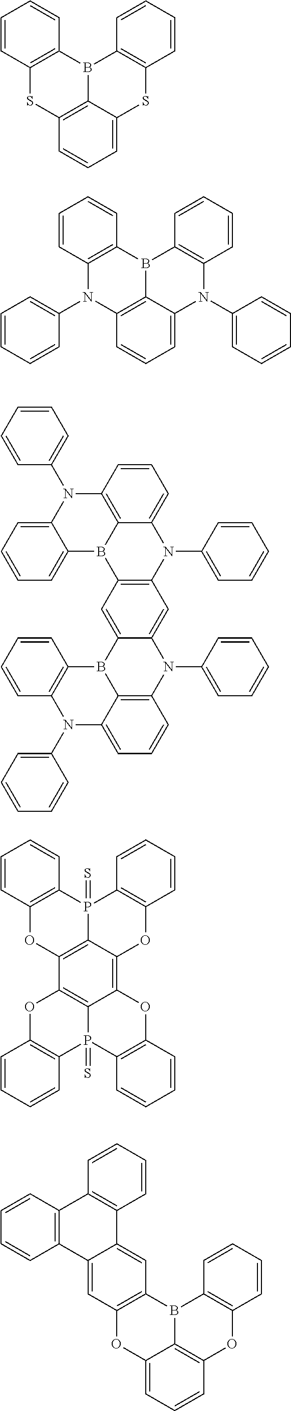

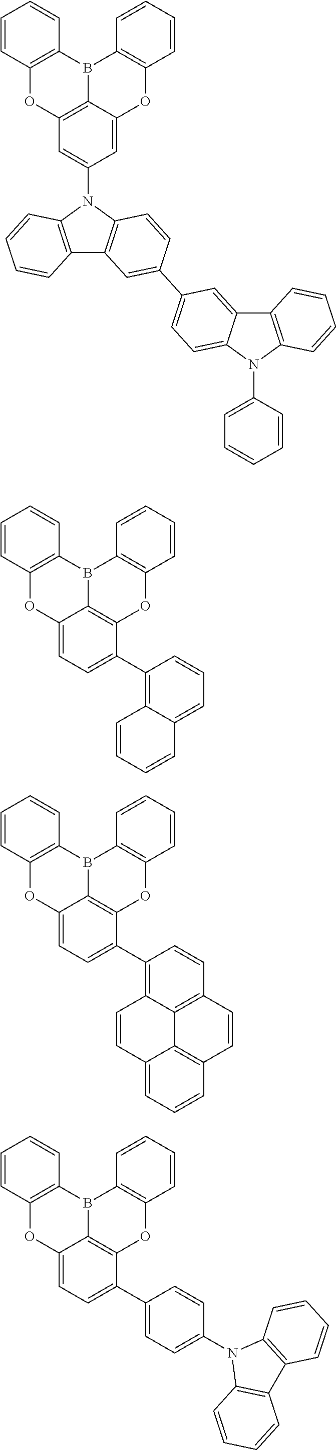

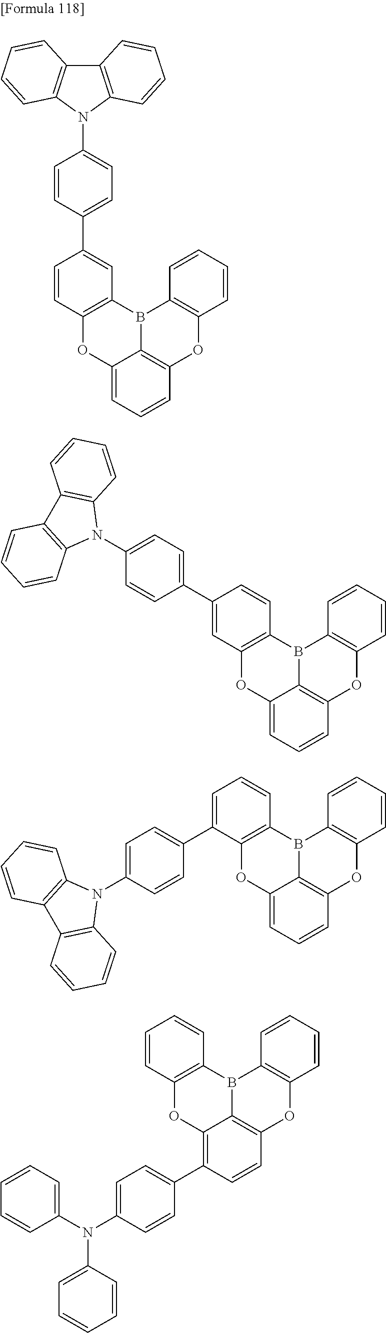

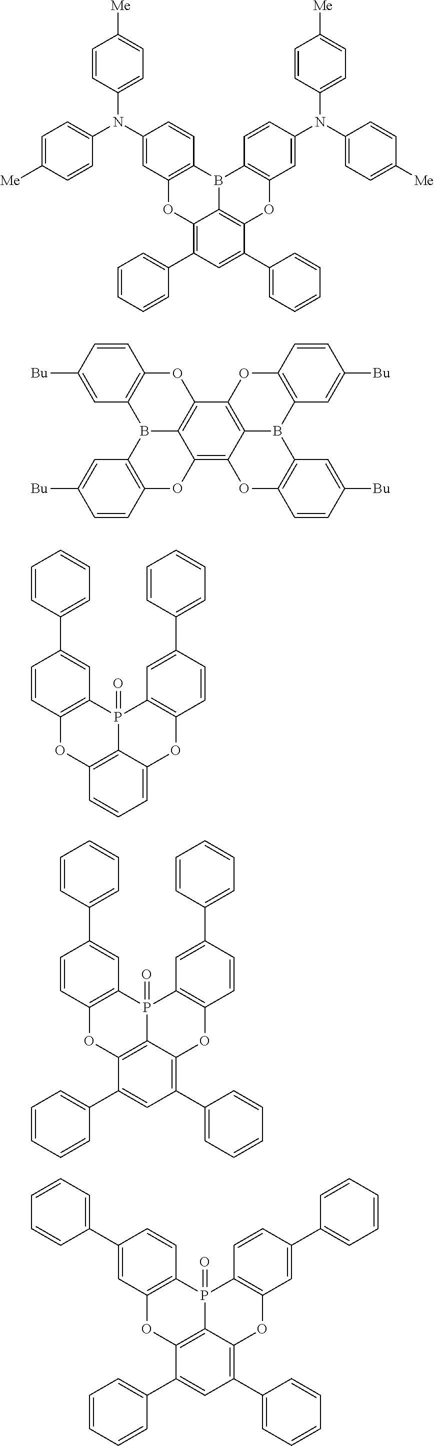

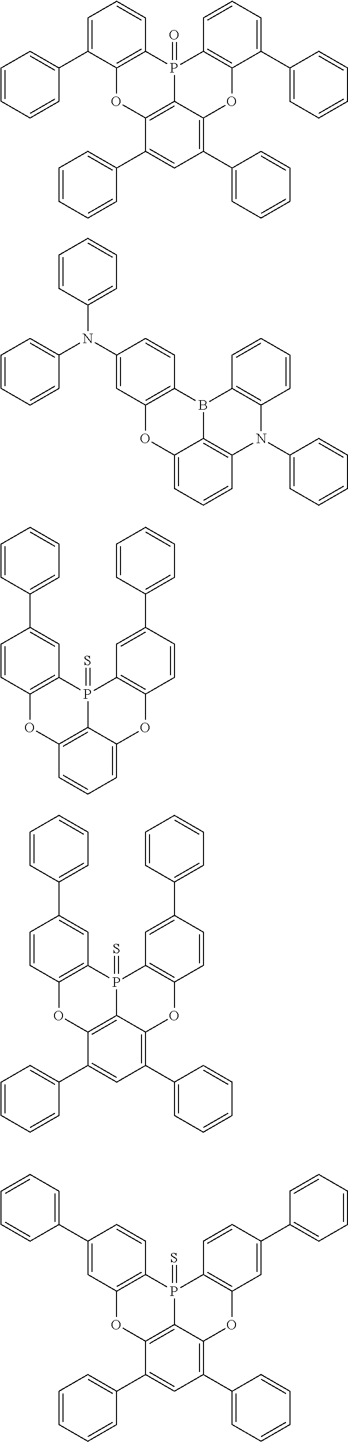

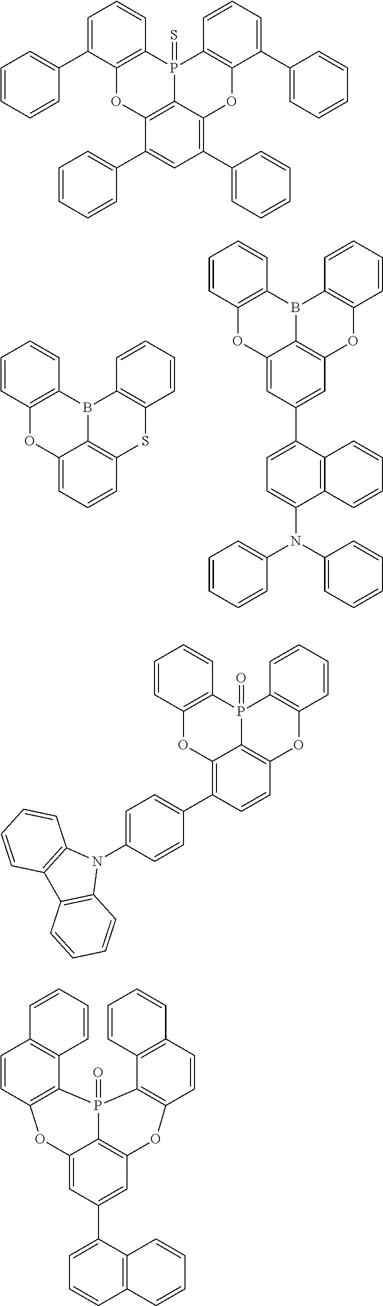

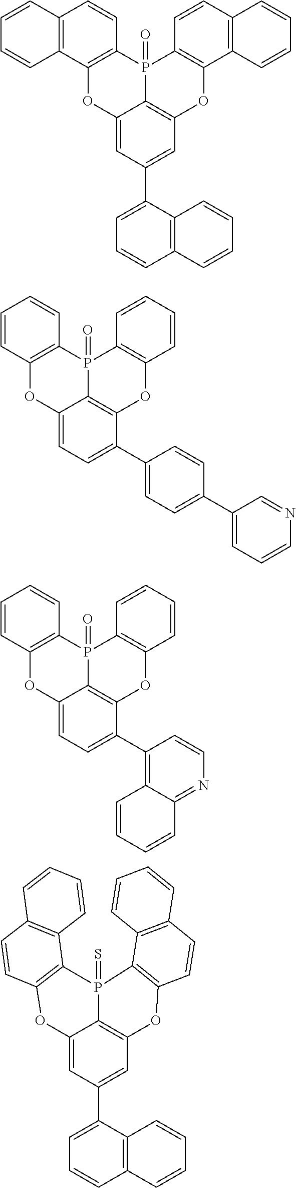

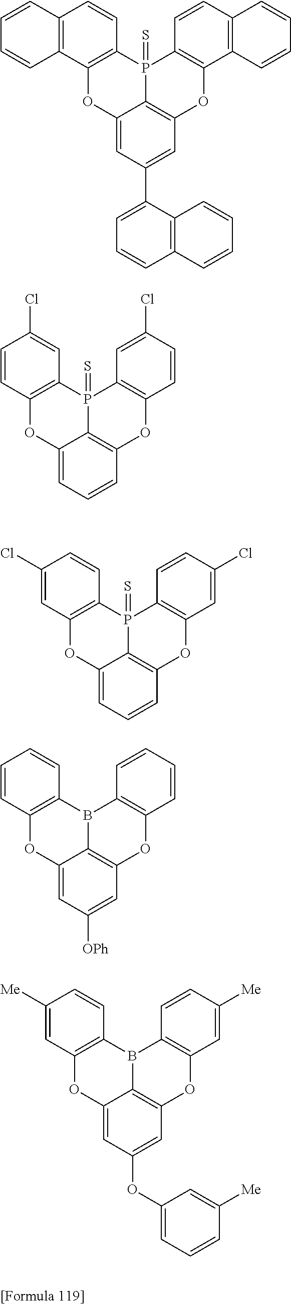

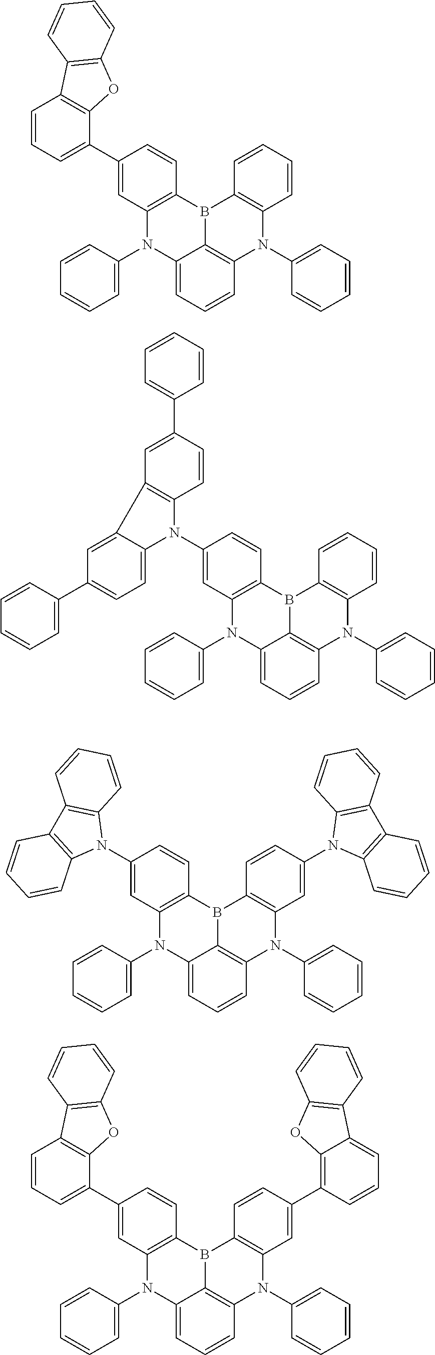

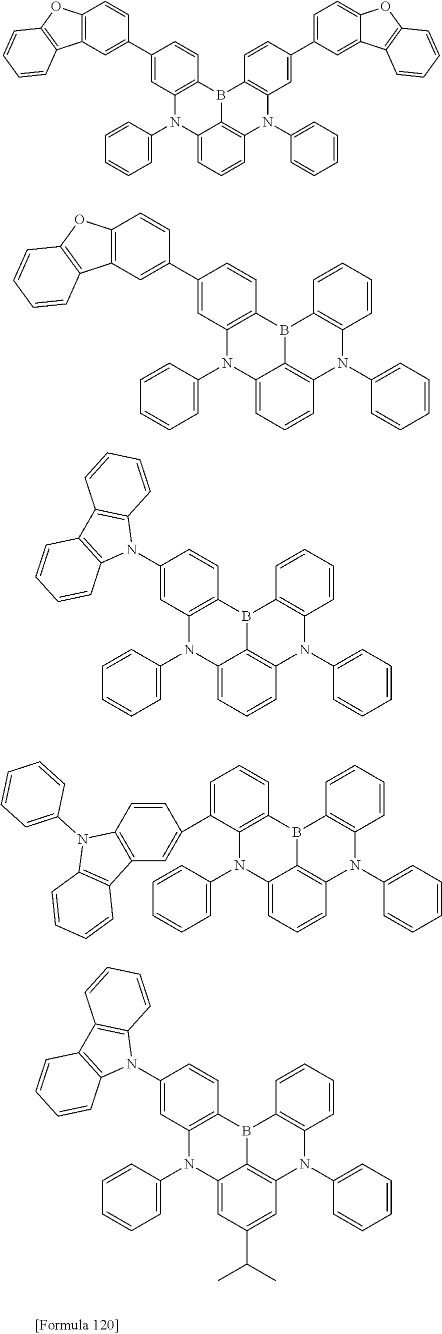

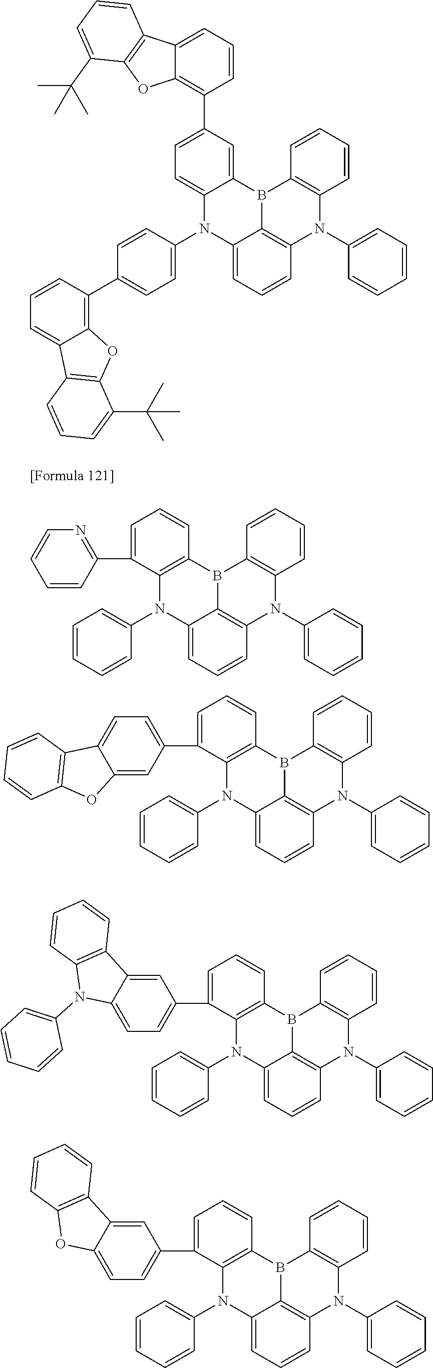

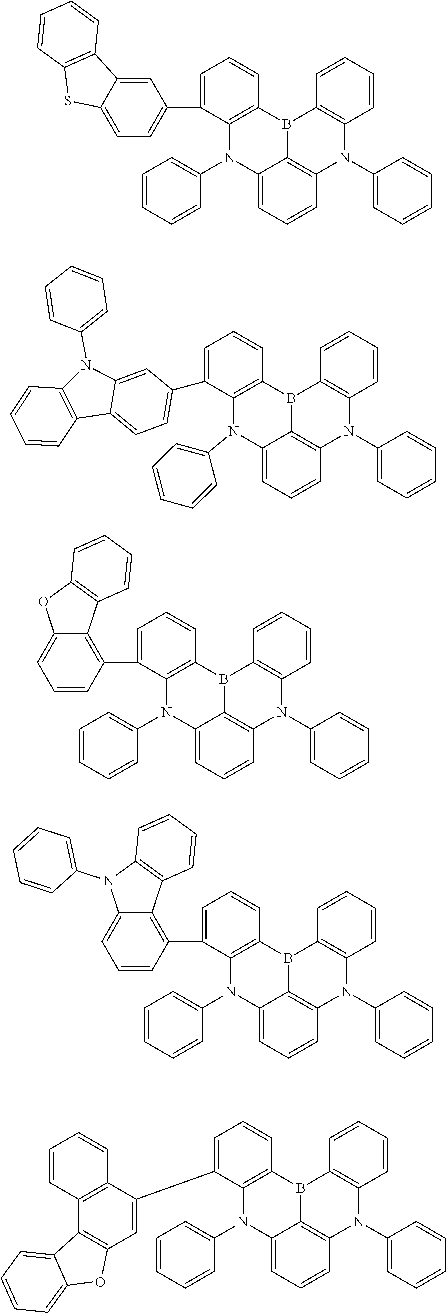 [SMILES: c1ccc(N2c3ccccc3B3c4cccc(-c5ccc6sc7ccccc7c6c5)c4N(c4ccccc4)c4cccc2c43)cc1 ; c1ccc(N2c3ccccc3B3c4cccc(-c5ccc6c7ccccc7n(-c7ccccc7)c6c5)c4N(c4ccccc4)c4cccc2c43)cc1 ; c1ccc(N2c3ccccc3B3c4cccc(-c5cccc6oc7ccccc7c56)c4N(c4ccccc4)c4cccc2c43)cc1 ; c1ccc(N2c3ccccc3B3c4cccc(-c5cccc6c5c5ccccc5n6-c5ccccc5)c4N(c4ccccc4)c4cccc2c43)cc1 ; c1ccc(N2c3ccccc3B3c4cccc(-c5cc6oc7ccccc7c6c6ccccc56)c4N(c4ccccc4)c4cccc2c43)cc1]

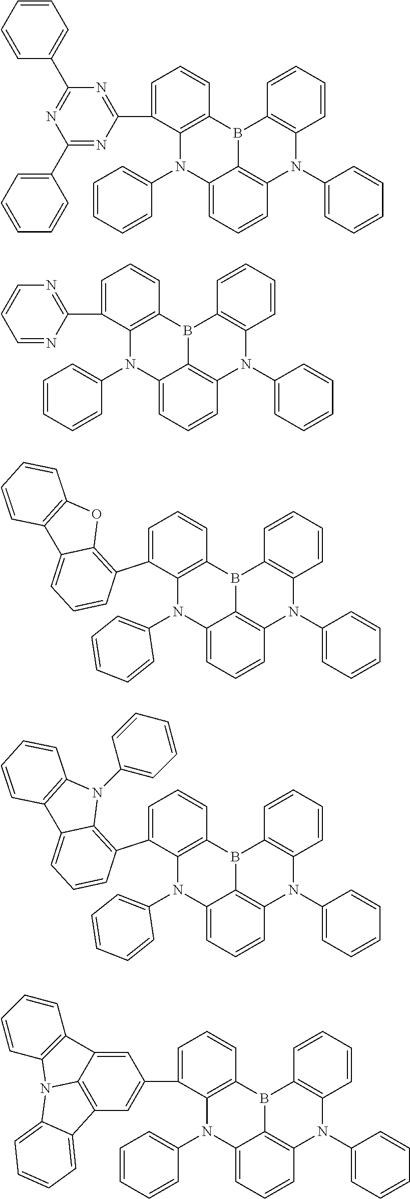

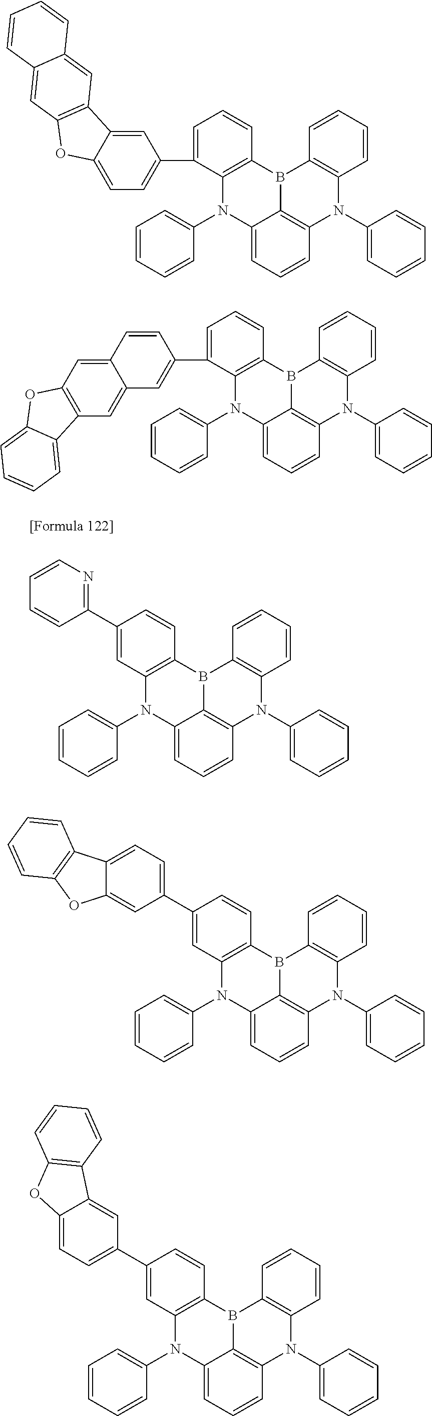 [SMILES: c1ccc(N2c3ccccc3B3c4cccc(-c5ccc6oc7cc8ccccc8cc7c6c5)c4N(c4ccccc4)c4cccc2c43)cc1 ; c1ccc(N2c3ccccc3B3c4cccc(-c5ccc6cc7oc8ccccc8c7cc6c5)c4N(c4ccccc4)c4cccc2c43)cc1 ; c1ccc(N2c3ccccc3B3c4ccc(-c5ccccn5)cc4N(c4ccccc4)c4cccc2c43)cc1 ; c1ccc(N2c3ccccc3B3c4ccc(-c5ccc6c(c5)oc5ccccc56)cc4N(c4ccccc4)c4cccc2c43)cc1 ; c1ccc(N2c3ccccc3B3c4ccc(-c5ccc6oc7ccccc7c6c5)cc4N(c4ccccc4)c4cccc2c43)cc1]

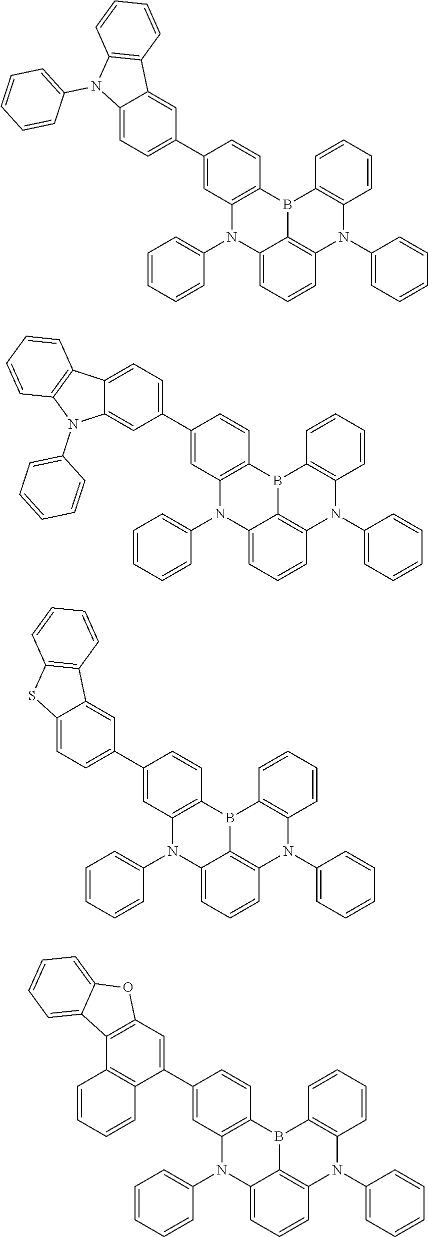 [SMILES: c1ccc(N2c3ccccc3B3c4ccc(-c5ccc6c(c5)c5ccccc5n6-c5ccccc5)cc4N(c4ccccc4)c4cccc2c43)cc1 ; c1ccc(N2c3ccccc3B3c4ccc(-c5ccc6c7ccccc7n(-c7ccccc7)c6c5)cc4N(c4ccccc4)c4cccc2c43)cc1 ; c1ccc(N2c3ccccc3B3c4ccc(-c5ccc6sc7ccccc7c6c5)cc4N(c4ccccc4)c4cccc2c43)cc1 ; c1ccc(N2c3ccccc3B3c4ccc(-c5cc6oc7ccccc7c6c6ccccc56)cc4N(c4ccccc4)c4cccc2c43)cc1]

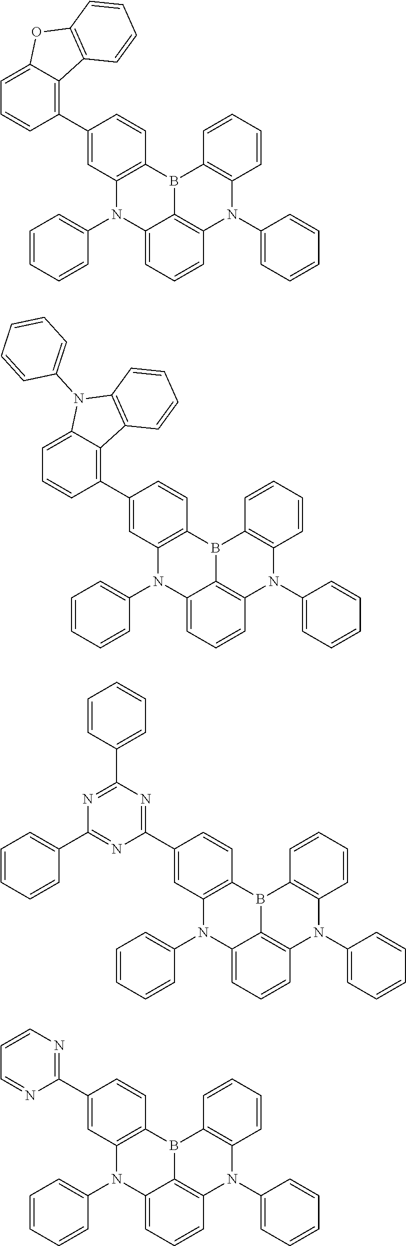

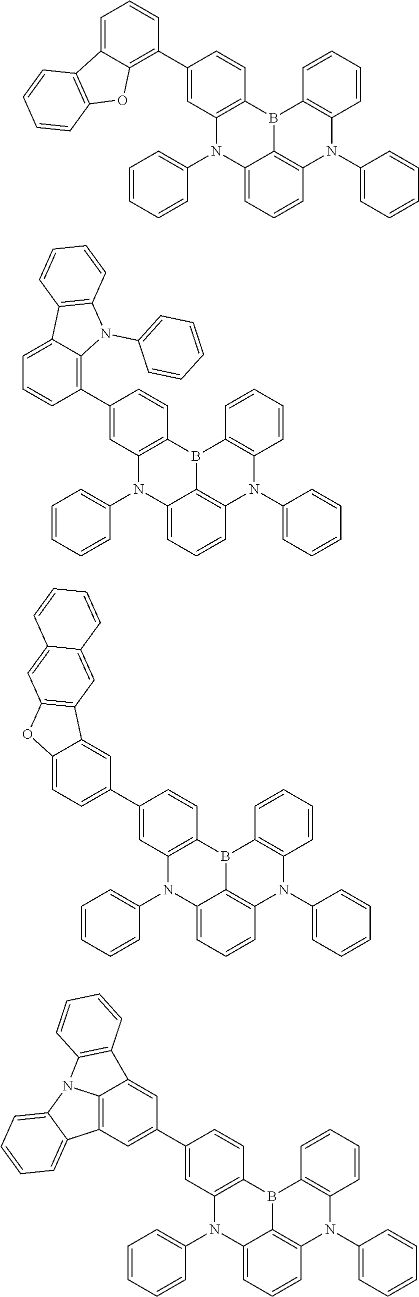

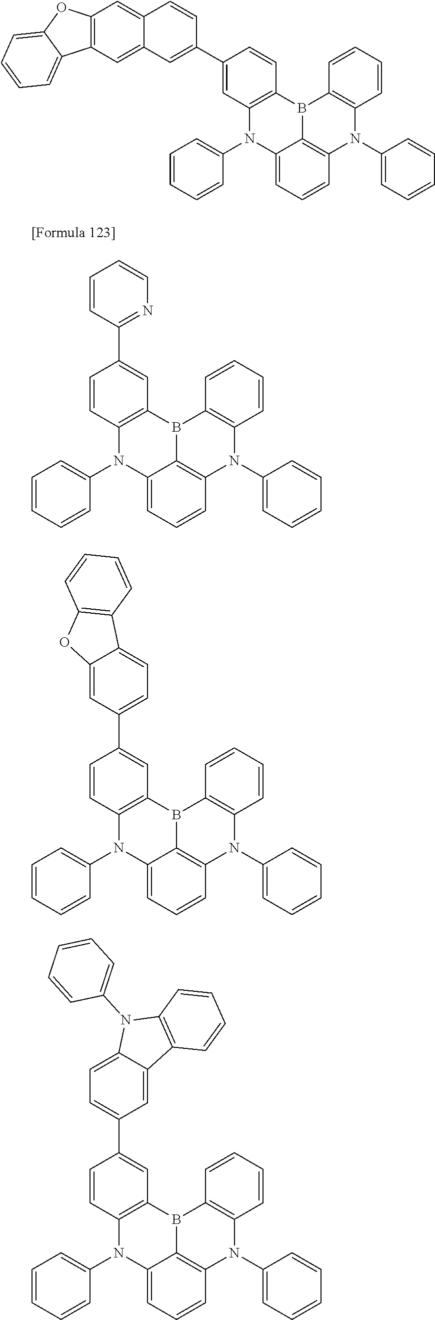

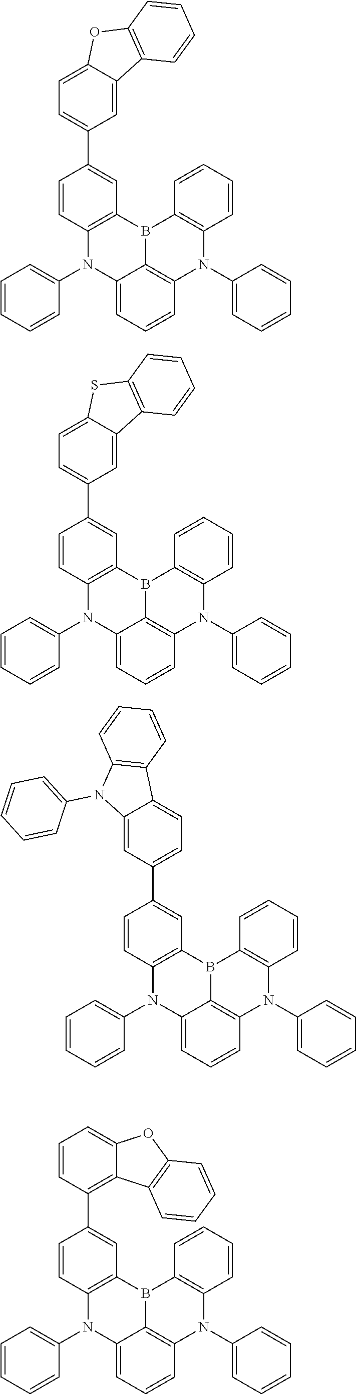

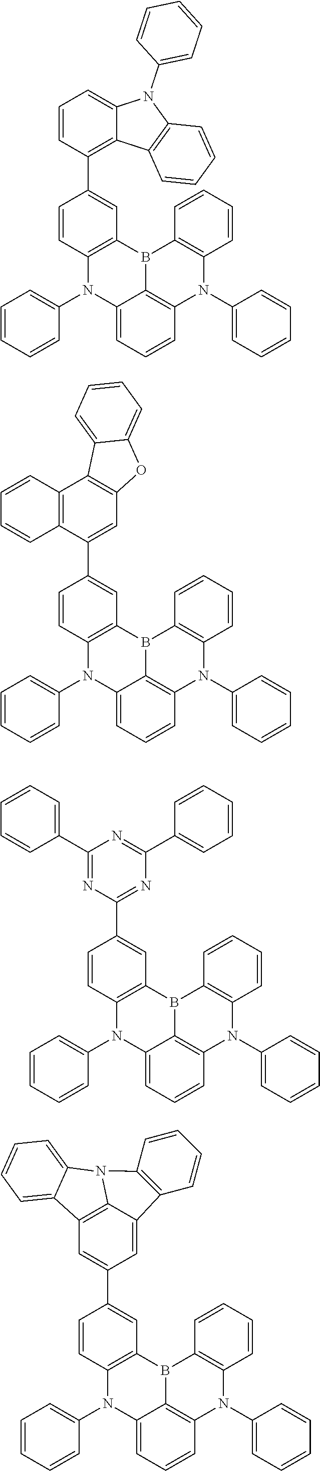

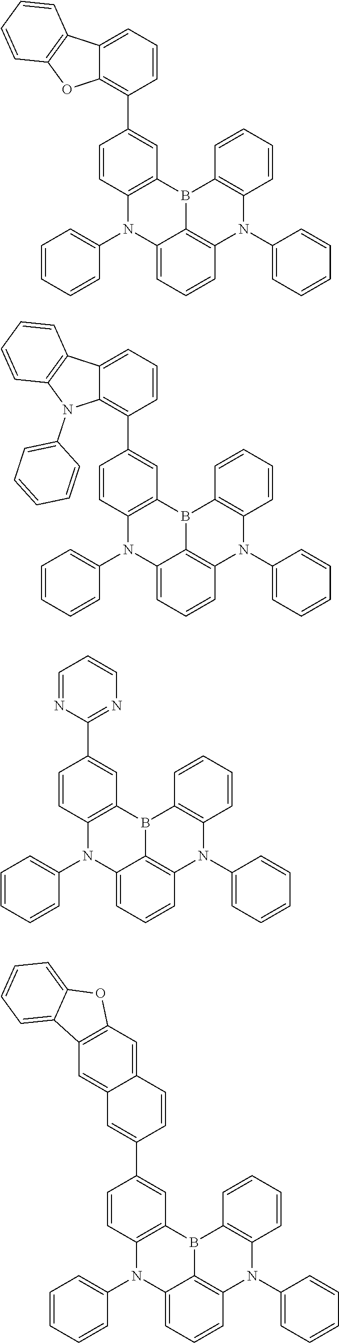

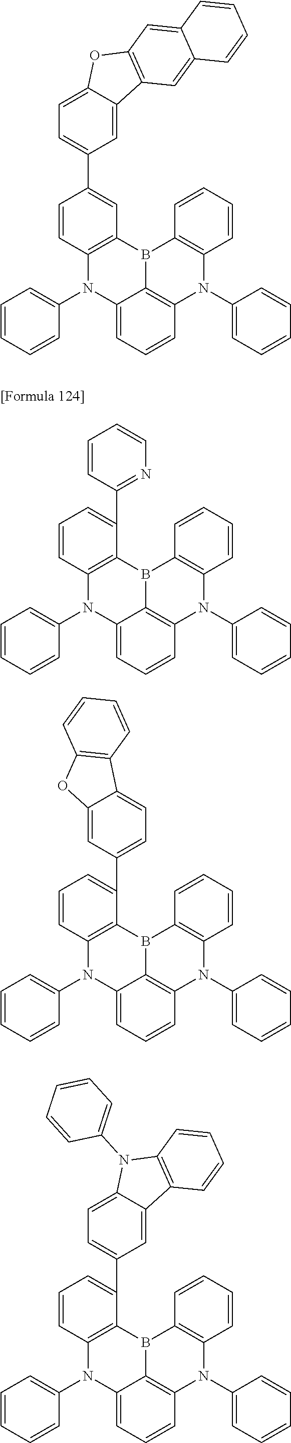

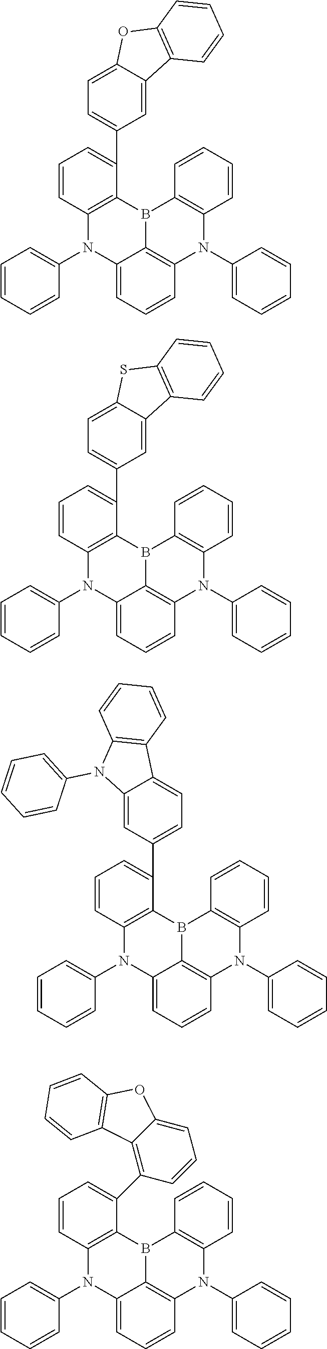

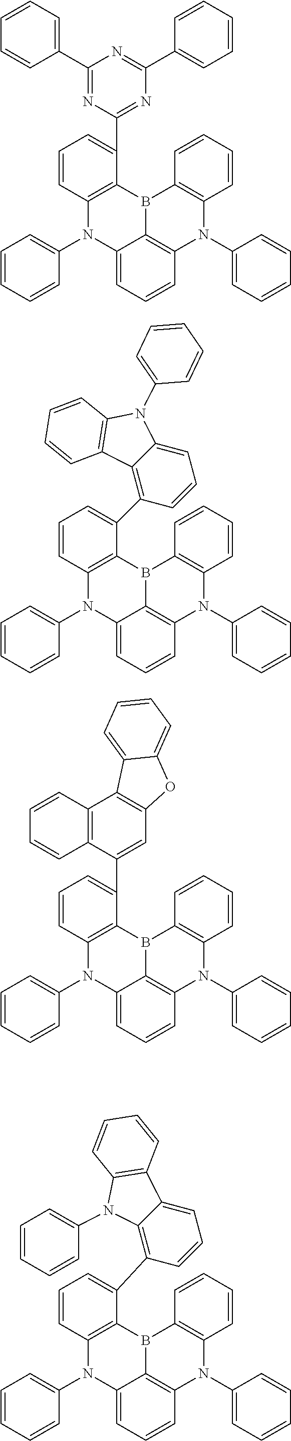

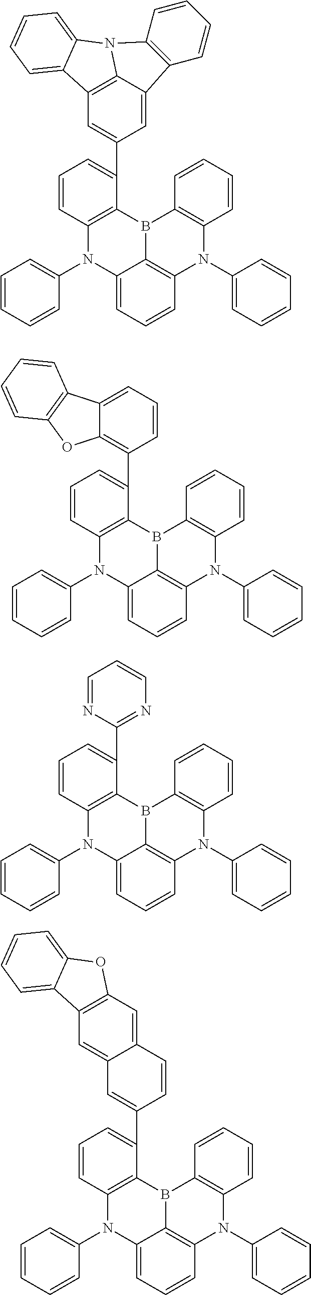

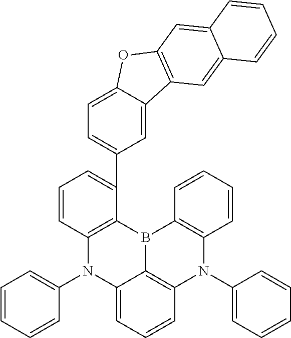 [SMILES: c1ccc(N2c3ccccc3B3c4c(-c5ccc6oc7cc8ccccc8cc7c6c5)cccc4N(c4ccccc4)c4cccc2c43)cc1]

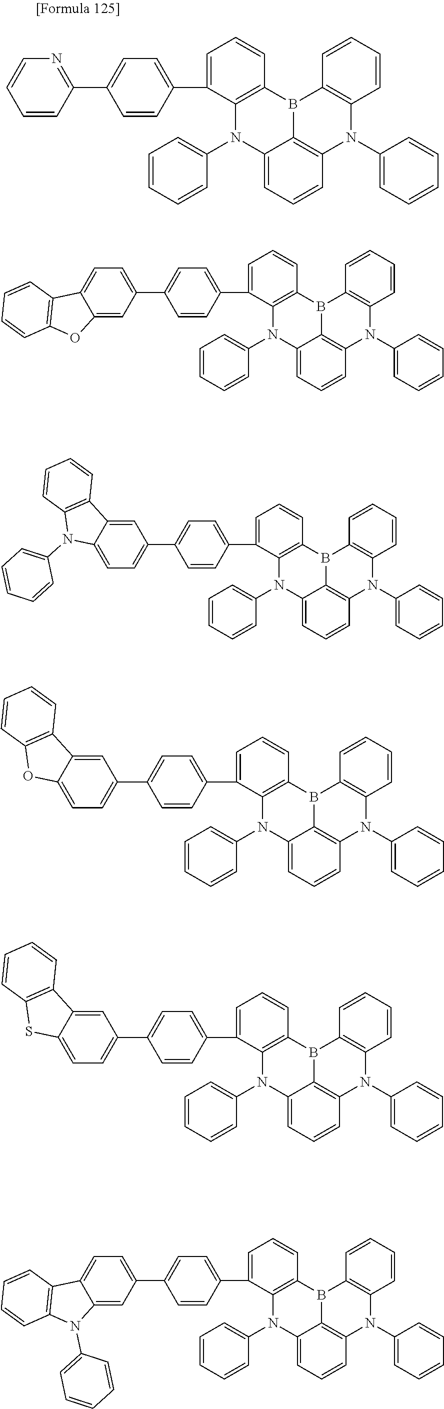

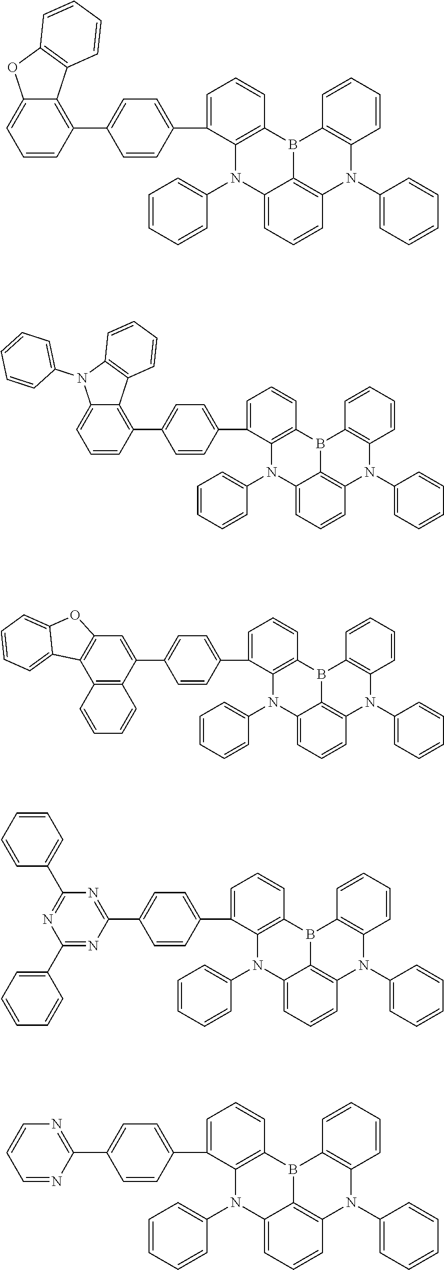 [SMILES: c1ccc(N2c3ccccc3B3c4cccc(-c5ccc(-c6cccc7oc8ccccc8c67)cc5)c4N(c4ccccc4)c4cccc2c43)cc1 ; c1ccc(N2c3ccccc3B3c4cccc(-c5ccc(-c6cccc7c6c6ccccc6n7-c6ccccc6)cc5)c4N(c4ccccc4)c4cccc2c43)cc1 ; c1ccc(N2c3ccccc3B3c4cccc(-c5ccc(-c6cc7oc8ccccc8c7c7ccccc67)cc5)c4N(c4ccccc4)c4cccc2c43)cc1 ; c1ccc(-c2nc(-c3ccccc3)nc(-c3ccc(-c4cccc5c4N(c4ccccc4)c4cccc6c4B5c4ccccc4N6c4ccccc4)cc3)n2)cc1 ; c1ccc(N2c3ccccc3B3c4cccc(-c5ccc(-c6ncccn6)cc5)c4N(c4ccccc4)c4cccc2c43)cc1]

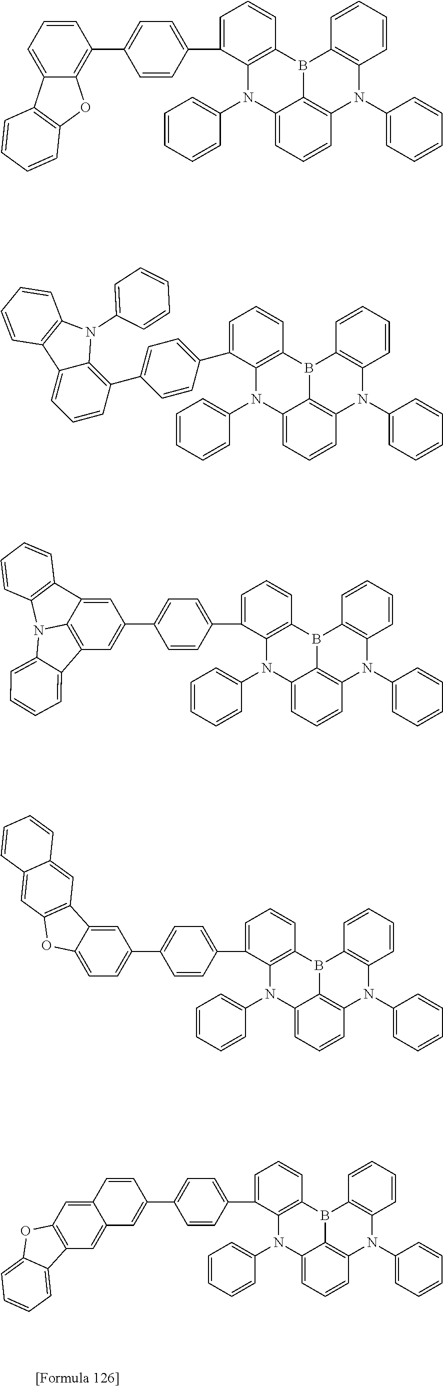 [SMILES: c1ccc(N2c3ccccc3B3c4cccc(-c5ccc(-c6cccc7c6oc6ccccc67)cc5)c4N(c4ccccc4)c4cccc2c43)cc1 ; c1ccc(N2c3ccccc3B3c4cccc(-c5ccc(-c6cccc7c8ccccc8n(-c8ccccc8)c67)cc5)c4N(c4ccccc4)c4cccc2c43)cc1 ; c1ccc(N2c3ccccc3B3c4cccc(-c5ccc(-c6cc7c8ccccc8n8c9ccccc9c(c6)c78)cc5)c4N(c4ccccc4)c4cccc2c43)cc1 ; c1ccc(N2c3ccccc3B3c4cccc(-c5ccc(-c6ccc7oc8cc9ccccc9cc8c7c6)cc5)c4N(c4ccccc4)c4cccc2c43)cc1 ; c1ccc(N2c3ccccc3B3c4cccc(-c5ccc(-c6ccc7cc8oc9ccccc9c8cc7c6)cc5)c4N(c4ccccc4)c4cccc2c43)cc1]

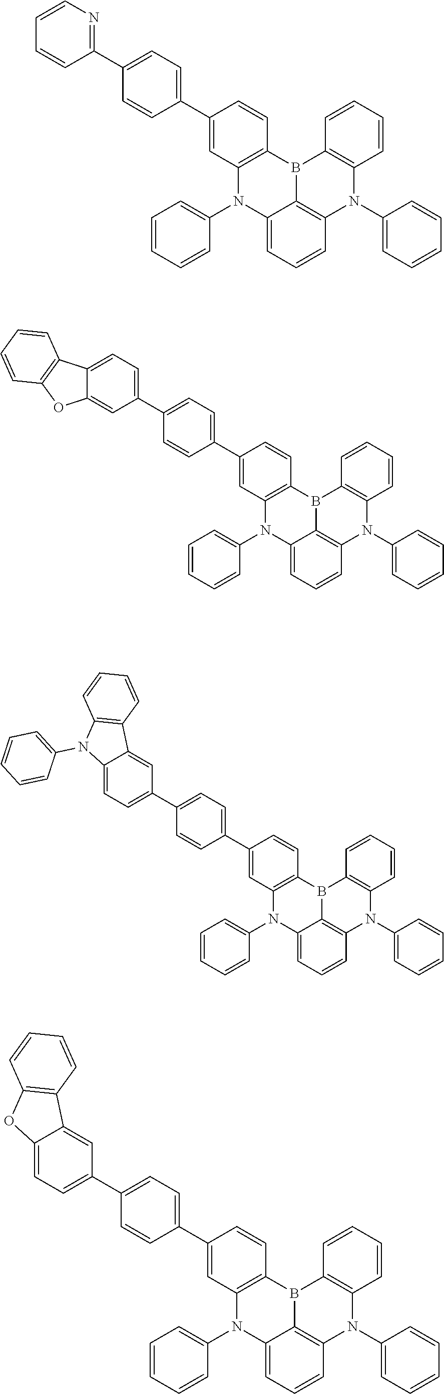 [SMILES: c1ccc(N2c3ccccc3B3c4ccc(-c5ccc(-c6ccccn6)cc5)cc4N(c4ccccc4)c4cccc2c43)cc1 ; c1ccc(N2c3ccccc3B3c4ccc(-c5ccc(-c6ccc7c(c6)oc6ccccc67)cc5)cc4N(c4ccccc4)c4cccc2c43)cc1 ; c1ccc(N2c3ccccc3B3c4ccc(-c5ccc(-c6ccc7c(c6)c6ccccc6n7-c6ccccc6)cc5)cc4N(c4ccccc4)c4cccc2c43)cc1 ; c1ccc(N2c3ccccc3B3c4ccc(-c5ccc(-c6ccc7oc8ccccc8c7c6)cc5)cc4N(c4ccccc4)c4cccc2c43)cc1]

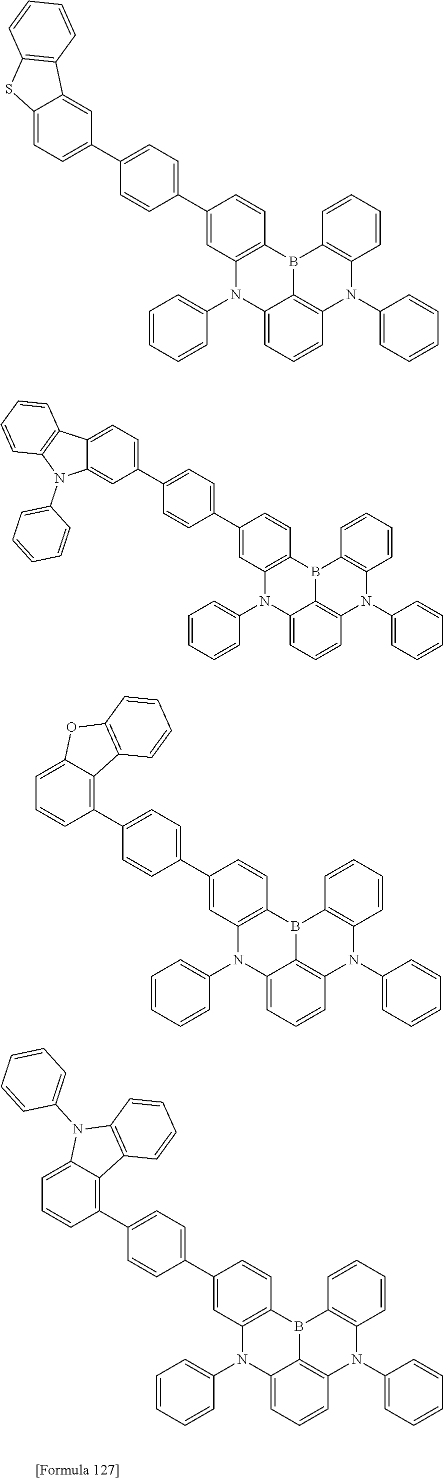 [SMILES: c1ccc(N2c3ccccc3B3c4ccc(-c5ccc(-c6ccc7sc8ccccc8c7c6)cc5)cc4N(c4ccccc4)c4cccc2c43)cc1 ; c1ccc(N2c3ccccc3B3c4ccc(-c5ccc(-c6ccc7c8ccccc8n(-c8ccccc8)c7c6)cc5)cc4N(c4ccccc4)c4cccc2c43)cc1 ; c1ccc(N2c3ccccc3B3c4ccc(-c5ccc(-c6cccc7oc8ccccc8c67)cc5)cc4N(c4ccccc4)c4cccc2c43)cc1 ; c1ccc(N2c3ccccc3B3c4ccc(-c5ccc(-c6cccc7c6c6ccccc6n7-c6ccccc6)cc5)cc4N(c4ccccc4)c4cccc2c43)cc1]

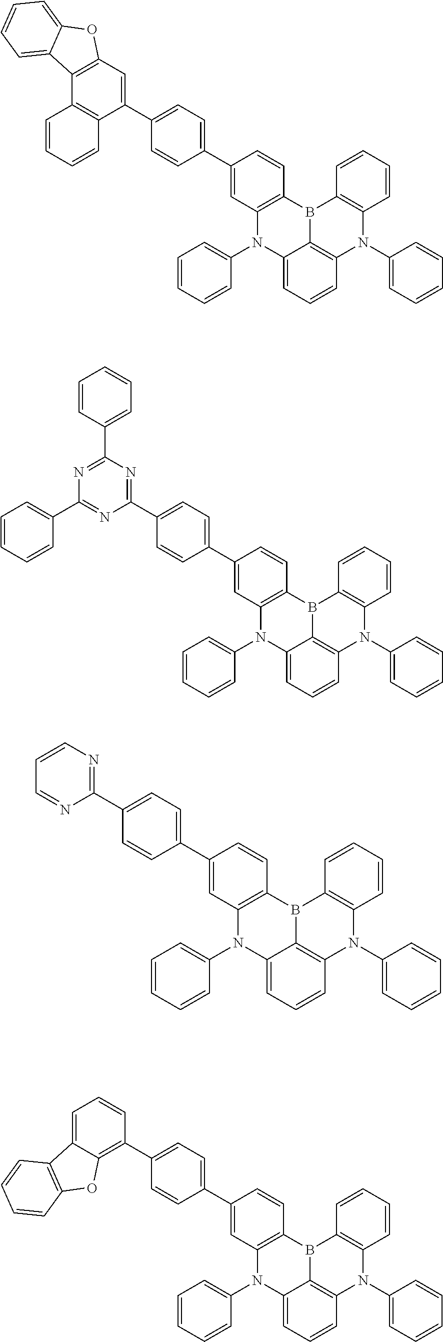 [SMILES: c1ccc(N2c3ccccc3B3c4ccc(-c5ccc(-c6cc7oc8ccccc8c7c7ccccc67)cc5)cc4N(c4ccccc4)c4cccc2c43)cc1 ; c1ccc(-c2nc(-c3ccccc3)nc(-c3ccc(-c4ccc5c(c4)N(c4ccccc4)c4cccc6c4B5c4ccccc4N6c4ccccc4)cc3)n2)cc1 ; c1ccc(N2c3ccccc3B3c4ccc(-c5ccc(-c6ncccn6)cc5)cc4N(c4ccccc4)c4cccc2c43)cc1 ; c1ccc(N2c3ccccc3B3c4ccc(-c5ccc(-c6cccc7c6oc6ccccc67)cc5)cc4N(c4ccccc4)c4cccc2c43)cc1]

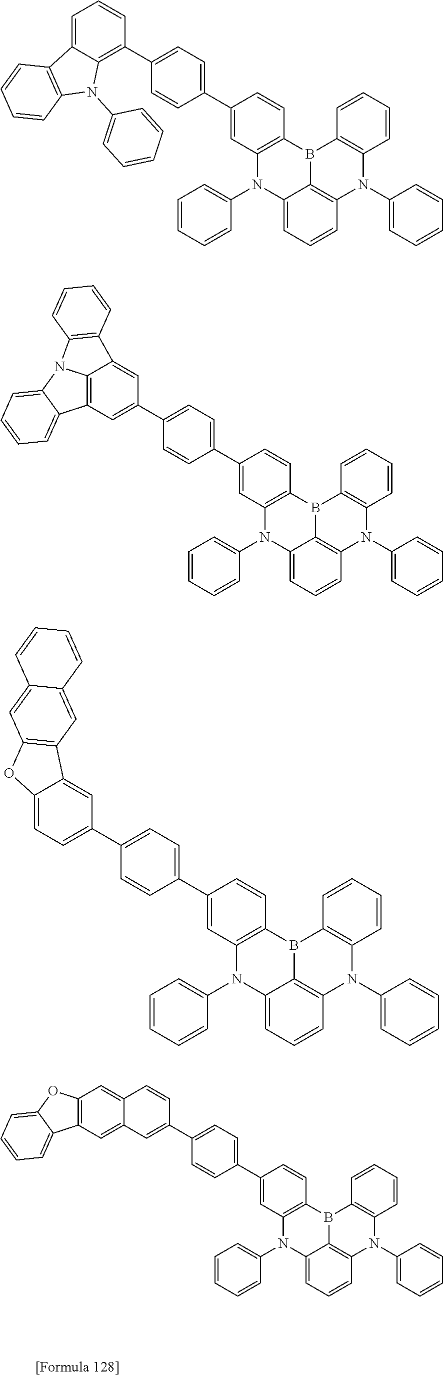 [SMILES: c1ccc(N2c3ccccc3B3c4ccc(-c5ccc(-c6cccc7c8ccccc8n(-c8ccccc8)c67)cc5)cc4N(c4ccccc4)c4cccc2c43)cc1 ; c1ccc(N2c3ccccc3B3c4ccc(-c5ccc(-c6cc7c8ccccc8n8c9ccccc9c(c6)c78)cc5)cc4N(c4ccccc4)c4cccc2c43)cc1 ; c1ccc(N2c3ccccc3B3c4ccc(-c5ccc(-c6ccc7oc8cc9ccccc9cc8c7c6)cc5)cc4N(c4ccccc4)c4cccc2c43)cc1 ; c1ccc(N2c3ccccc3B3c4ccc(-c5ccc(-c6ccc7cc8oc9ccccc9c8cc7c6)cc5)cc4N(c4ccccc4)c4cccc2c43)cc1]

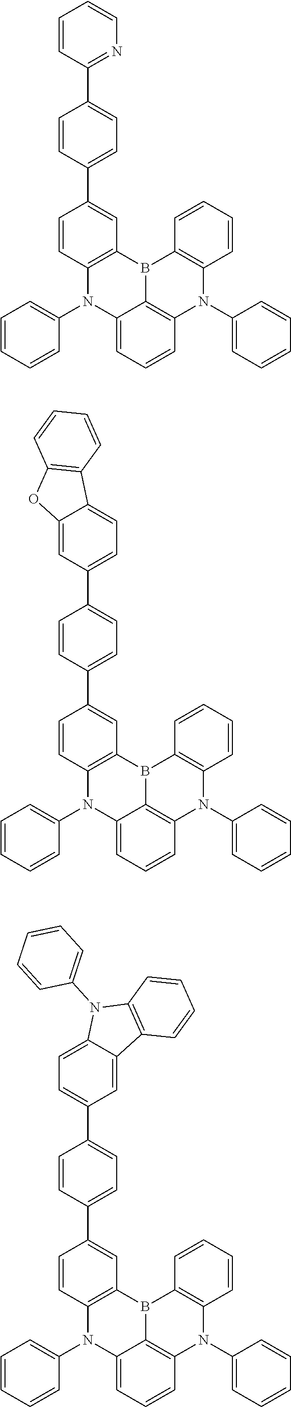 [SMILES: c1ccc(N2c3ccccc3B3c4cc(-c5ccc(-c6ccccn6)cc5)ccc4N(c4ccccc4)c4cccc2c43)cc1 ; c1ccc(N2c3ccccc3B3c4cc(-c5ccc(-c6ccc7c(c6)oc6ccccc67)cc5)ccc4N(c4ccccc4)c4cccc2c43)cc1 ; c1ccc(N2c3ccccc3B3c4cc(-c5ccc(-c6ccc7c(c6)c6ccccc6n7-c6ccccc6)cc5)ccc4N(c4ccccc4)c4cccc2c43)cc1]

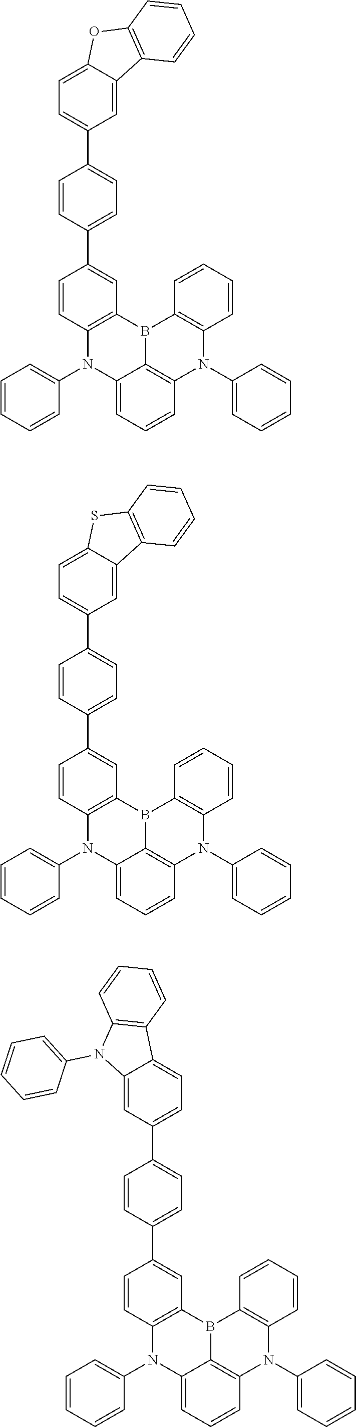 [SMILES: c1ccc(N2c3ccccc3B3c4cc(-c5ccc(-c6ccc7oc8ccccc8c7c6)cc5)ccc4N(c4ccccc4)c4cccc2c43)cc1 ; c1ccc(N2c3ccccc3B3c4cc(-c5ccc(-c6ccc7sc8ccccc8c7c6)cc5)ccc4N(c4ccccc4)c4cccc2c43)cc1 ; c1ccc(N2c3ccccc3B3c4cc(-c5ccc(-c6ccc7c8ccccc8n(-c8ccccc8)c7c6)cc5)ccc4N(c4ccccc4)c4cccc2c43)cc1]

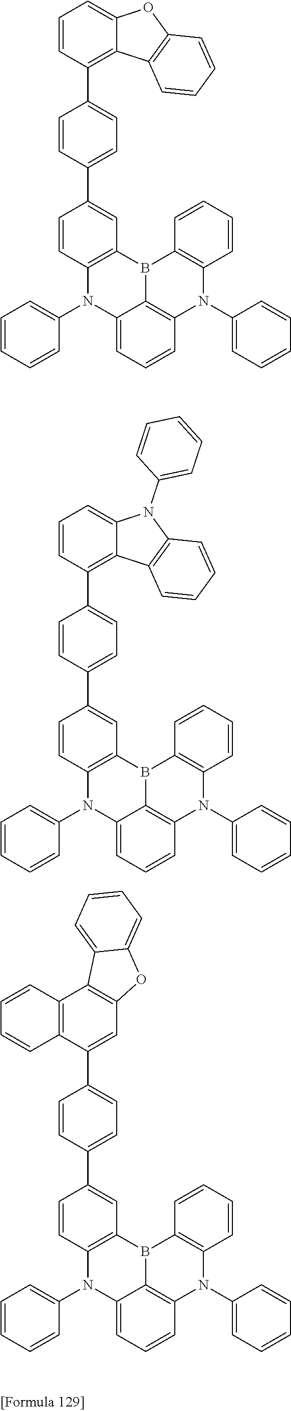

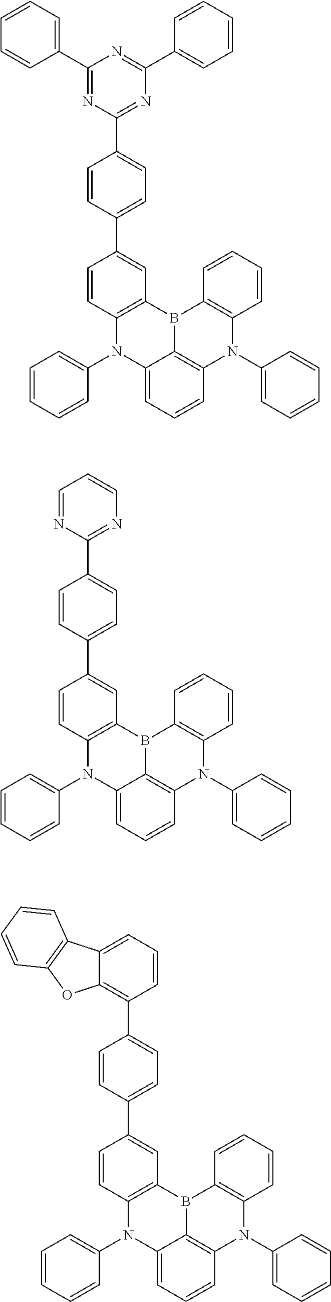 [SMILES: c1ccc(-c2nc(-c3ccccc3)nc(-c3ccc(-c4ccc5c(c4)B4c6ccccc6N(c6ccccc6)c6cccc(c64)N5c4ccccc4)cc3)n2)cc1 ; c1ccc(N2c3ccccc3B3c4cc(-c5ccc(-c6ncccn6)cc5)ccc4N(c4ccccc4)c4cccc2c43)cc1 ; c1ccc(N2c3ccccc3B3c4cc(-c5ccc(-c6cccc7c6oc6ccccc67)cc5)ccc4N(c4ccccc4)c4cccc2c43)cc1]

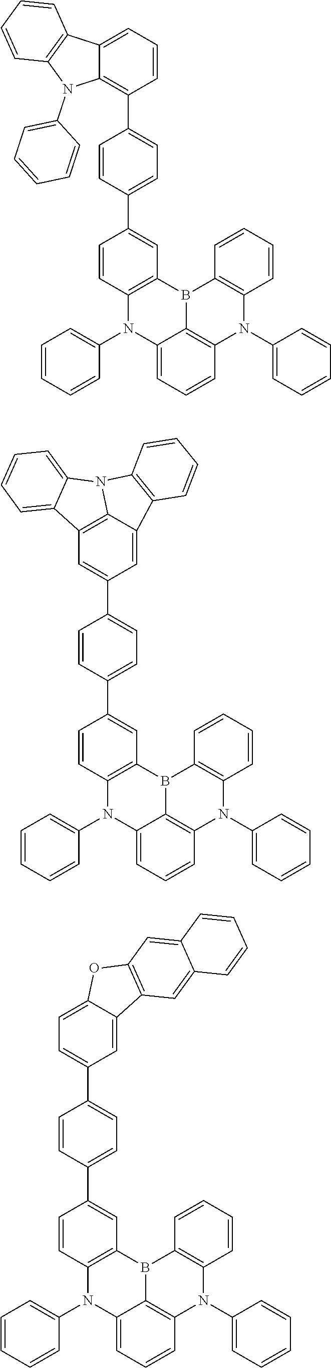

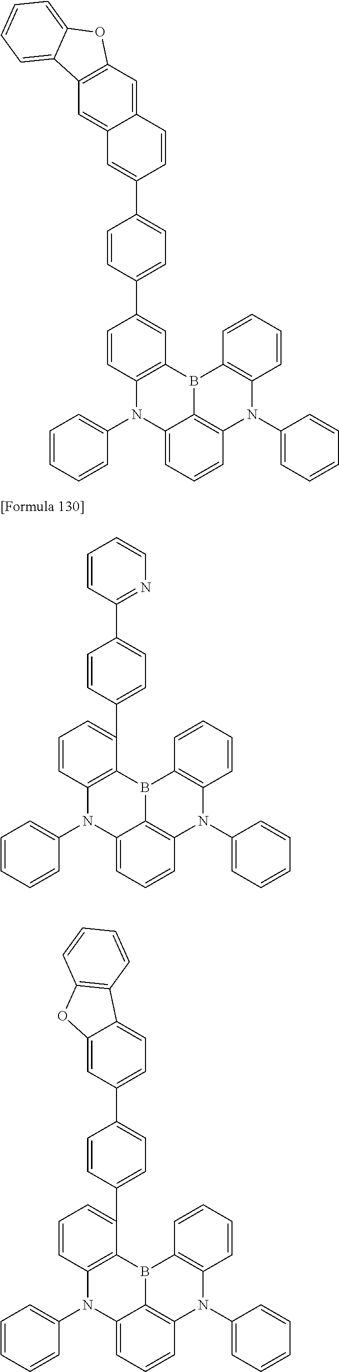 [SMILES: c1ccc(N2c3ccccc3B3c4cc(-c5ccc(-c6ccc7cc8oc9ccccc9c8cc7c6)cc5)ccc4N(c4ccccc4)c4cccc2c43)cc1 ; c1ccc(N2c3ccccc3B3c4c(-c5ccc(-c6ccccn6)cc5)cccc4N(c4ccccc4)c4cccc2c43)cc1 ; c1ccc(N2c3ccccc3B3c4c(-c5ccc(-c6ccc7c(c6)oc6ccccc67)cc5)cccc4N(c4ccccc4)c4cccc2c43)cc1]

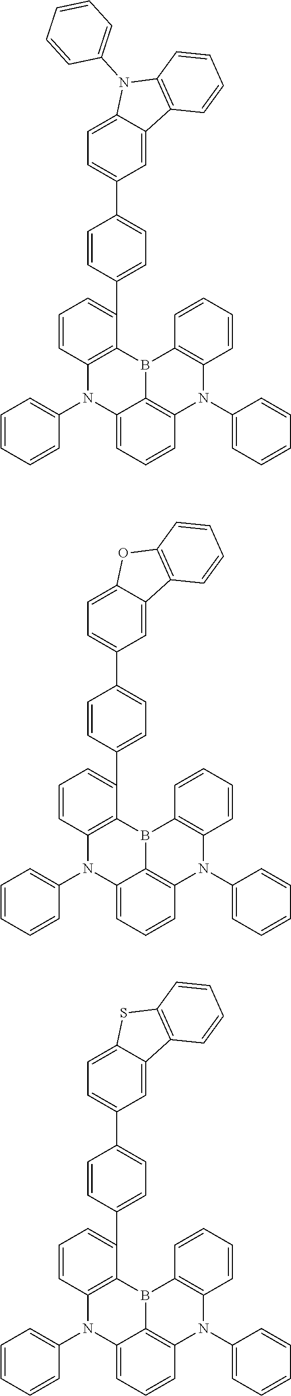 [SMILES: c1ccc(N2c3ccccc3B3c4c(-c5ccc(-c6ccc7c(c6)c6ccccc6n7-c6ccccc6)cc5)cccc4N(c4ccccc4)c4cccc2c43)cc1 ; c1ccc(N2c3ccccc3B3c4c(-c5ccc(-c6ccc7oc8ccccc8c7c6)cc5)cccc4N(c4ccccc4)c4cccc2c43)cc1 ; c1ccc(N2c3ccccc3B3c4c(-c5ccc(-c6ccc7sc8ccccc8c7c6)cc5)cccc4N(c4ccccc4)c4cccc2c43)cc1]

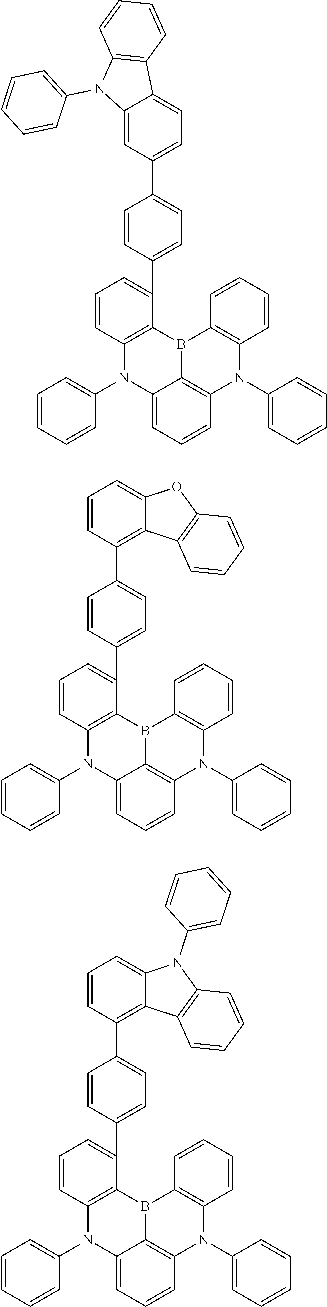

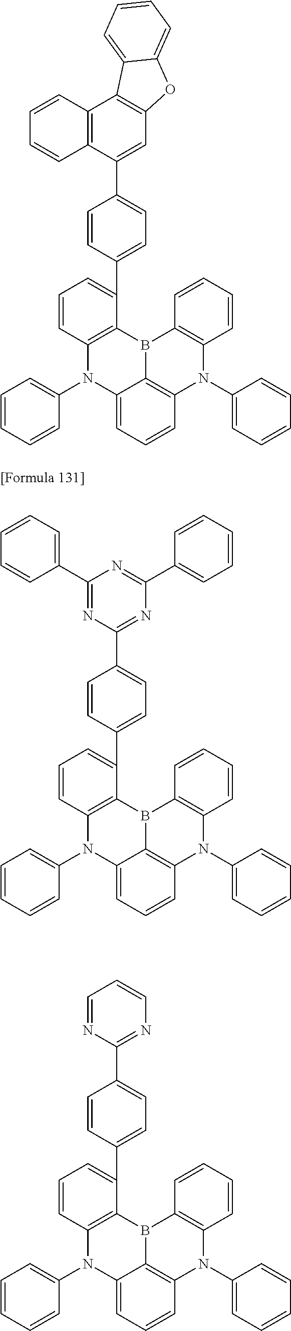 [SMILES: c1ccc(N2c3ccccc3B3c4c(-c5ccc(-c6cc7oc8ccccc8c7c7ccccc67)cc5)cccc4N(c4ccccc4)c4cccc2c43)cc1 ; c1ccc(-c2nc(-c3ccccc3)nc(-c3ccc(-c4cccc5c4B4c6ccccc6N(c6ccccc6)c6cccc(c64)N5c4ccccc4)cc3)n2)cc1 ; c1ccc(N2c3ccccc3B3c4c(-c5ccc(-c6ncccn6)cc5)cccc4N(c4ccccc4)c4cccc2c43)cc1]

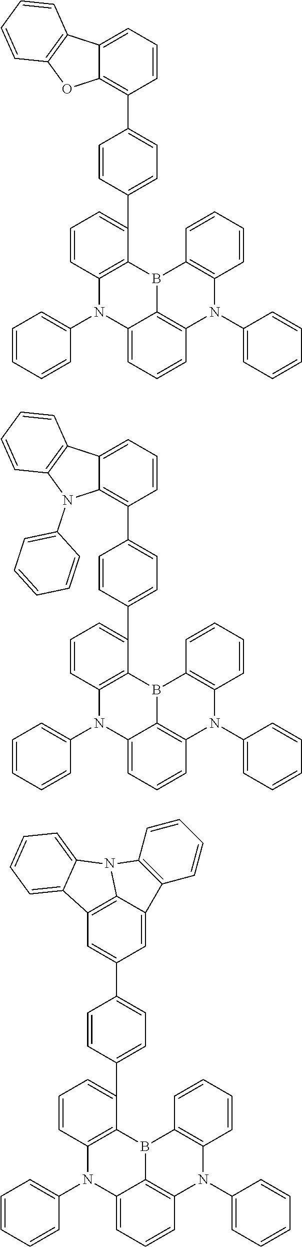

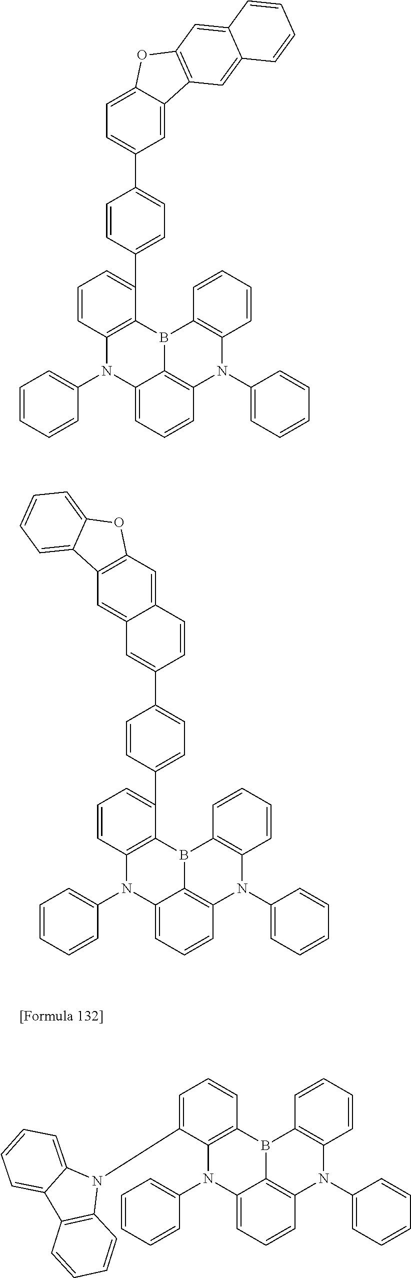 [SMILES: c1ccc(N2c3ccccc3B3c4c(-c5ccc(-c6ccc7oc8cc9ccccc9cc8c7c6)cc5)cccc4N(c4ccccc4)c4cccc2c43)cc1 ; c1ccc(N2c3ccccc3B3c4c(-c5ccc(-c6ccc7cc8oc9ccccc9c8cc7c6)cc5)cccc4N(c4ccccc4)c4cccc2c43)cc1 ; c1ccc(N2c3ccccc3B3c4cccc(-n5c6ccccc6c6ccccc65)c4N(c4ccccc4)c4cccc2c43)cc1]

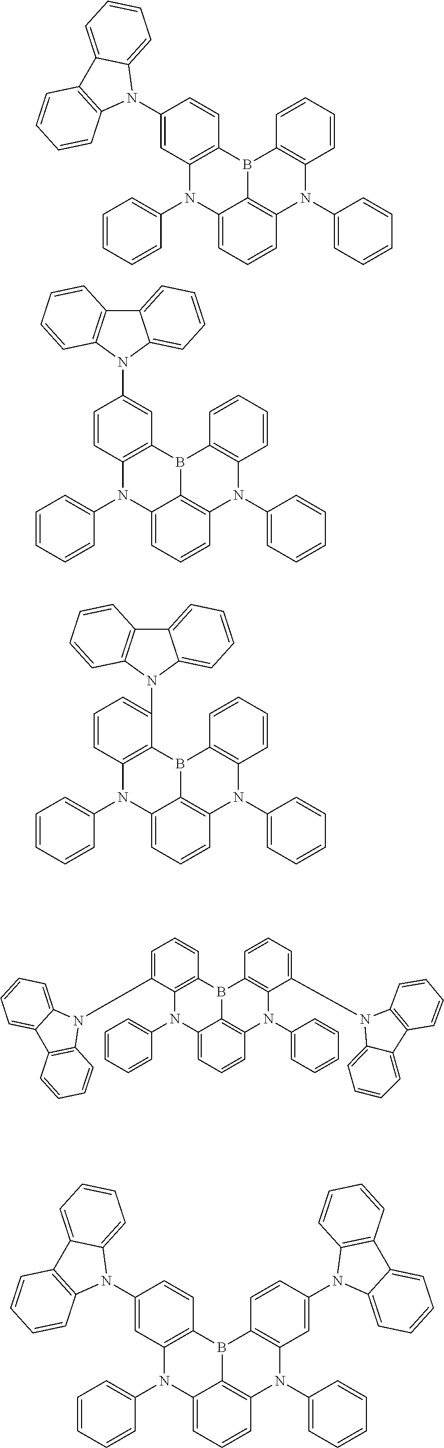

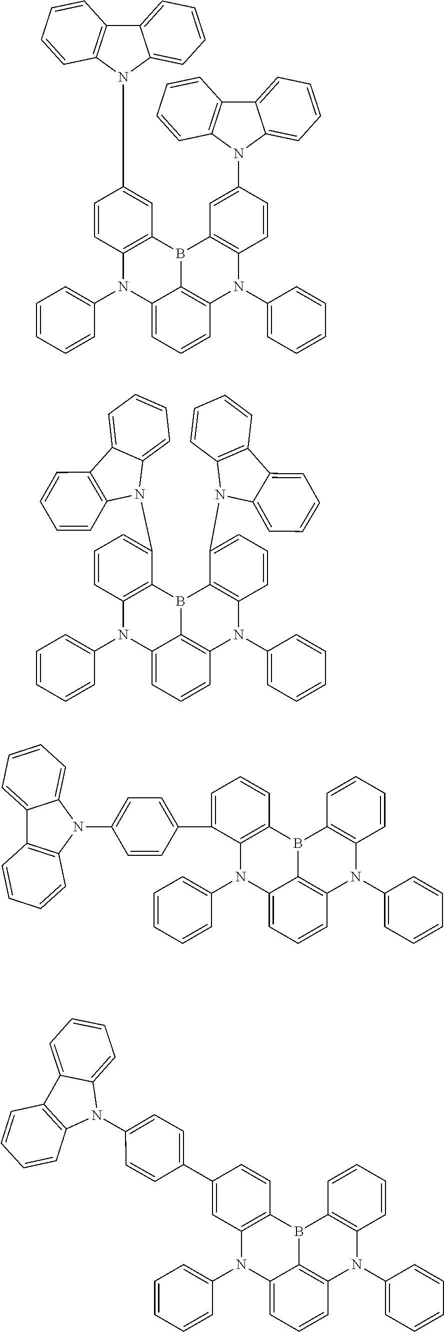 [SMILES: c1ccc(N2c3ccc(-n4c5ccccc5c5ccccc54)cc3B3c4cc(-n5c6ccccc6c6ccccc65)ccc4N(c4ccccc4)c4cccc2c43)cc1 ; c1ccc(N2c3cccc4c3B(c3c2cccc3-n2c3ccccc3c3ccccc32)c2c(cccc2-n2c3ccccc3c3ccccc32)N4c2ccccc2)cc1 ; c1ccc(N2c3ccccc3B3c4cccc(-c5ccc(-n6c7ccccc7c7ccccc76)cc5)c4N(c4ccccc4)c4cccc2c43)cc1 ; c1ccc(N2c3ccccc3B3c4ccc(-c5ccc(-n6c7ccccc7c7ccccc76)cc5)cc4N(c4ccccc4)c4cccc2c43)cc1]

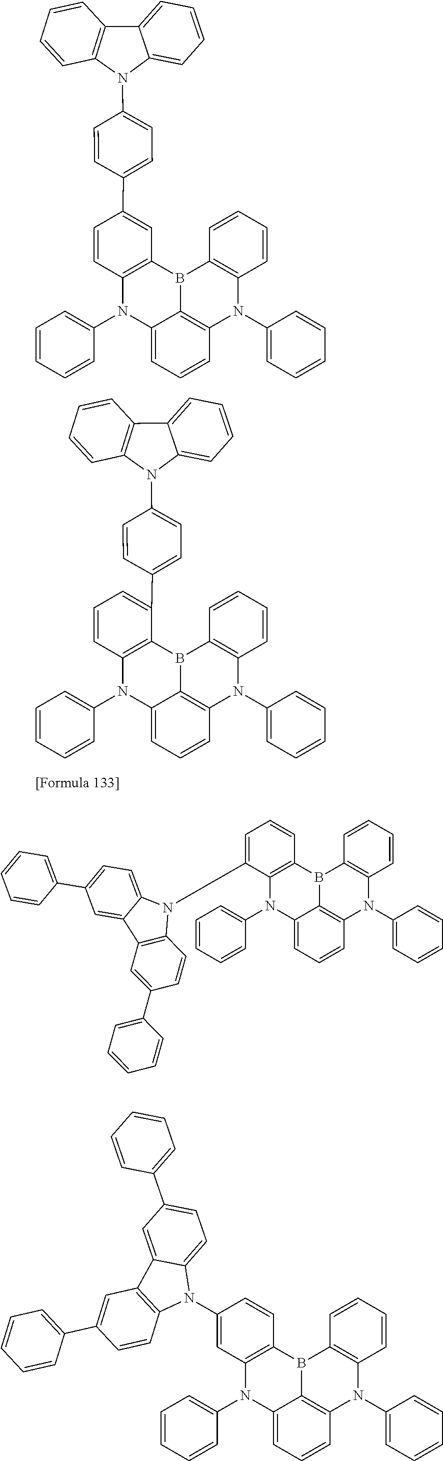

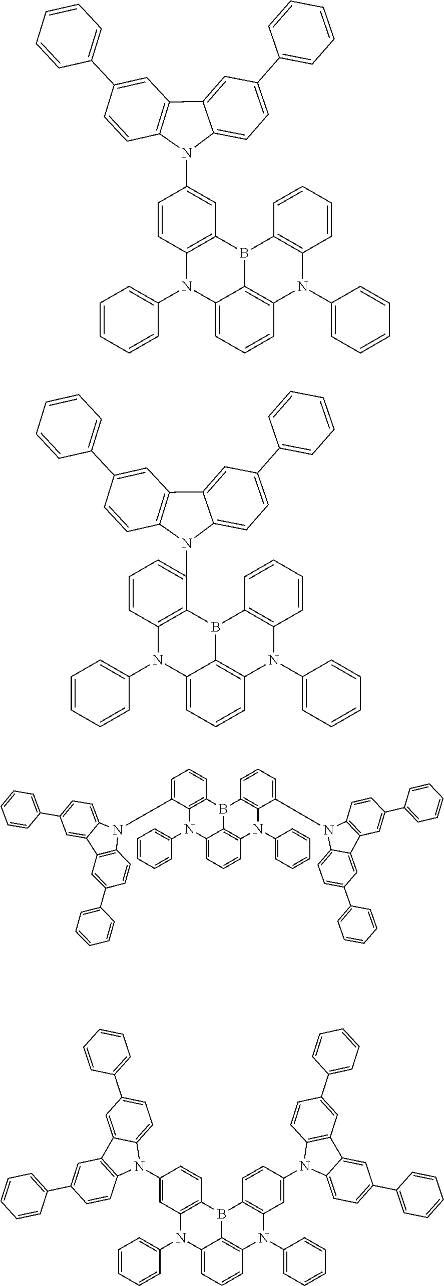 [SMILES: c1ccc(-c2ccc3c(c2)c2cc(-c4ccccc4)ccc2n3-c2ccc3c(c2)B2c4ccccc4N(c4ccccc4)c4cccc(c42)N3c2ccccc2)cc1 ; c1ccc(-c2ccc3c(c2)c2cc(-c4ccccc4)ccc2n3-c2cccc3c2B2c4ccccc4N(c4ccccc4)c4cccc(c42)N3c2ccccc2)cc1 ; c1ccc(-c2ccc3c(c2)c2cc(-c4ccccc4)ccc2n3-c2cccc3c2N(c2ccccc2)c2cccc4c2B3c2cccc(-n3c5ccc(-c6ccccc6)cc5c5cc(-c6ccccc6)ccc53)c2N4c2ccccc2)cc1 ; c1ccc(-c2ccc3c(c2)c2cc(-c4ccccc4)ccc2n3-c2ccc3c(c2)N(c2ccccc2)c2cccc4c2B3c2ccc(-n3c5ccc(-c6ccccc6)cc5c5cc(-c6ccccc6)ccc53)cc2N4c2ccccc2)cc1]

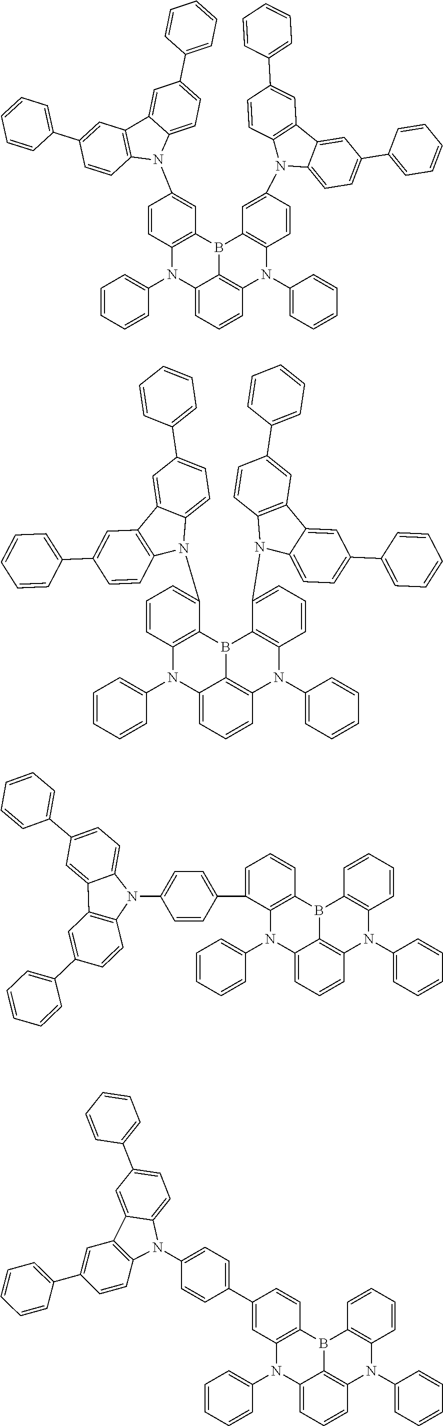 [SMILES: c1ccc(-c2ccc3c(c2)c2cc(-c4ccccc4)ccc2n3-c2ccc3c(c2)B2c4cc(-n5c6ccc(-c7ccccc7)cc6c6cc(-c7ccccc7)ccc65)ccc4N(c4ccccc4)c4cccc(c42)N3c2ccccc2)cc1 ; c1ccc(-c2ccc3c(c2)c2cc(-c4ccccc4)ccc2n3-c2cccc3c2B2c4c(cccc4N(c4ccccc4)c4cccc(-n5c6ccc(-c7ccccc7)cc6c6cc(-c7ccccc7)ccc65)c42)N3c2ccccc2)cc1 ; c1ccc(-c2ccc3c(c2)c2cc(-c4ccccc4)ccc2n3-c2ccc(-c3cccc4c3N(c3ccccc3)c3cccc5c3B4c3ccccc3N5c3ccccc3)cc2)cc1 ; c1ccc(-c2ccc3c(c2)c2cc(-c4ccccc4)ccc2n3-c2ccc(-c3ccc4c(c3)N(c3ccccc3)c3cccc5c3B4c3ccccc3N5c3ccccc3)cc2)cc1]

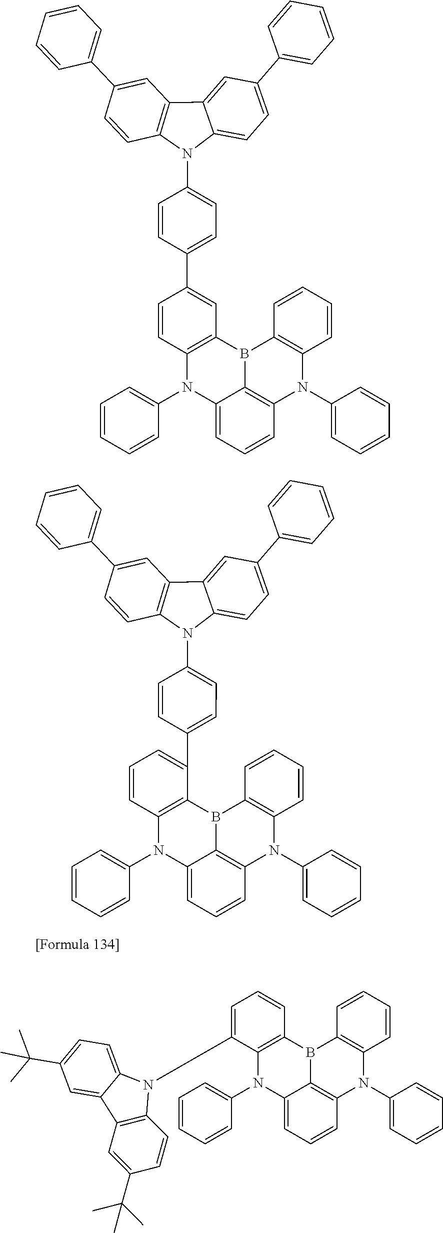

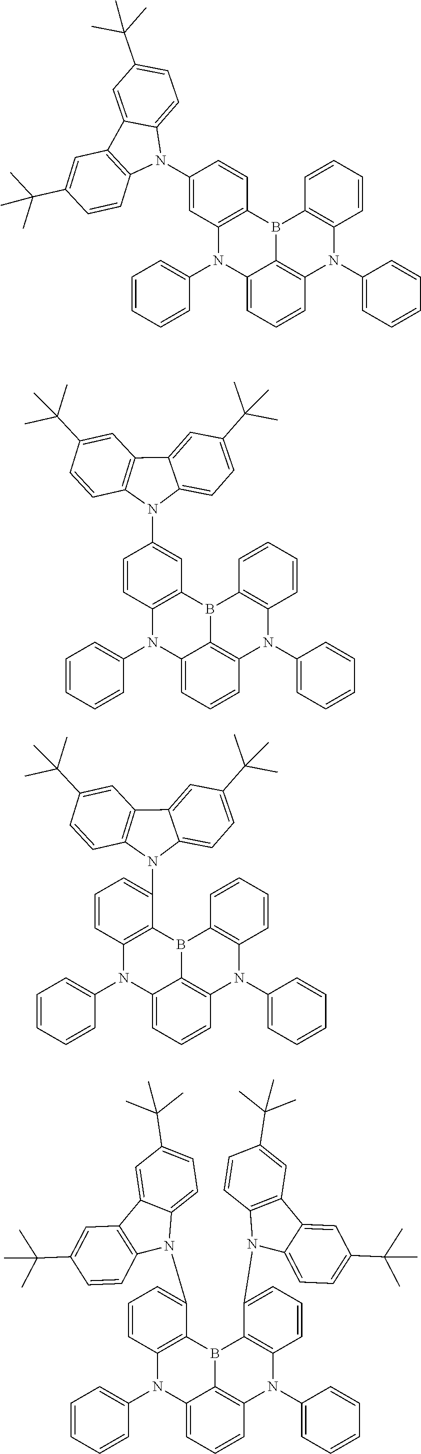

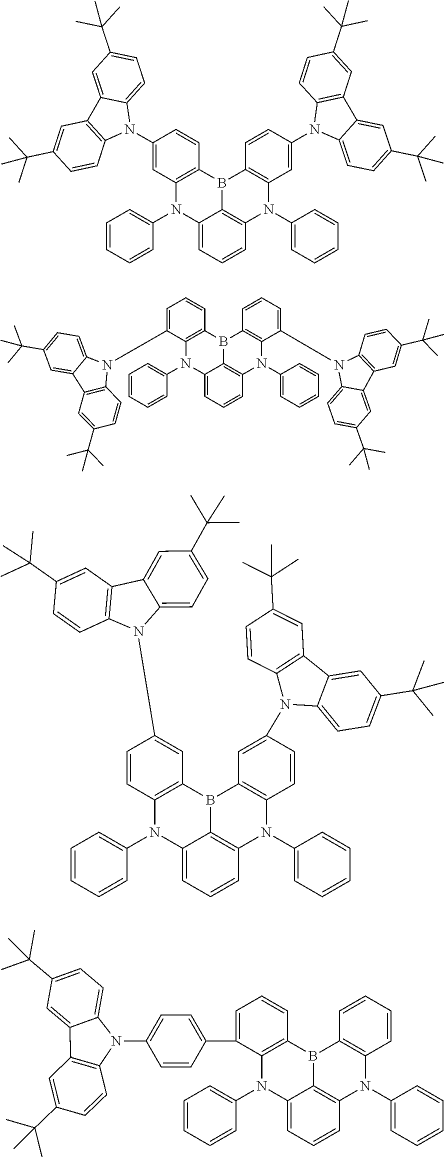

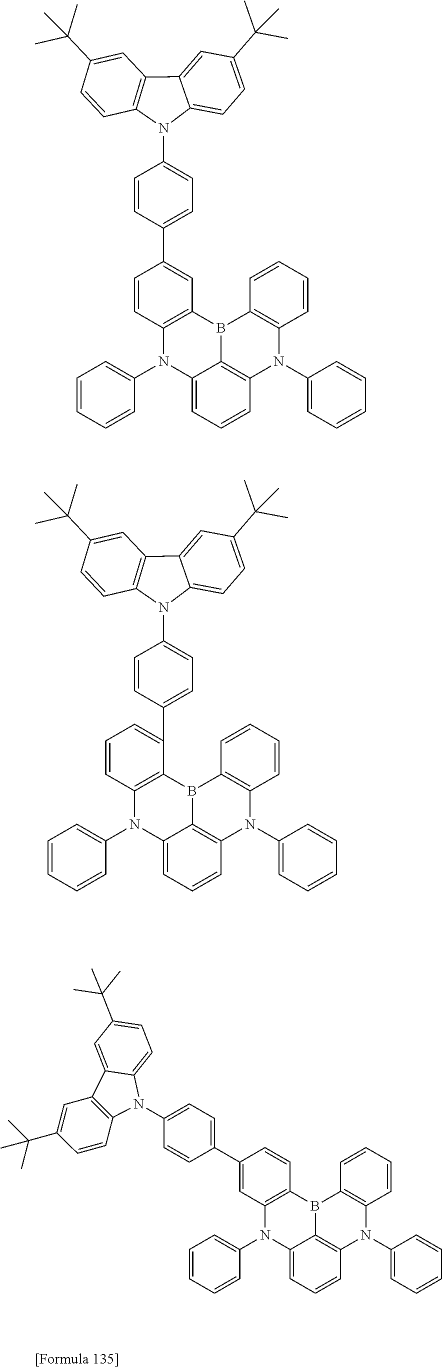 [SMILES: CC(C)(C)c1ccc2c(c1)c1cc(C(C)(C)C)ccc1n2-c1ccc(-c2ccc3c(c2)B2c4ccccc4N(c4ccccc4)c4cccc(c42)N3c2ccccc2)cc1 ; CC(C)(C)c1ccc2c(c1)c1cc(C(C)(C)C)ccc1n2-c1ccc(-c2cccc3c2B2c4ccccc4N(c4ccccc4)c4cccc(c42)N3c2ccccc2)cc1 ; CC(C)(C)c1ccc2c(c1)c1cc(C(C)(C)C)ccc1n2-c1ccc(-c2ccc3c(c2)N(c2ccccc2)c2cccc4c2B3c2ccccc2N4c2ccccc2)cc1]

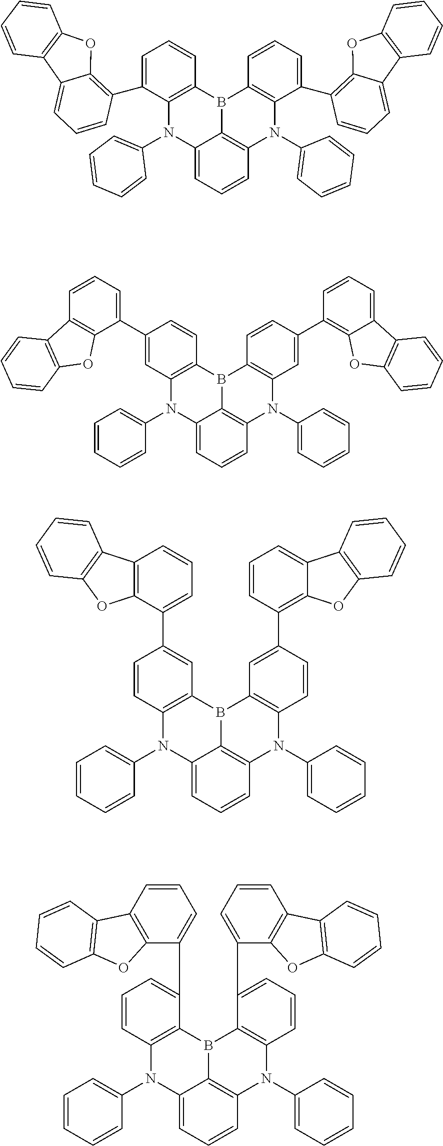 [SMILES: c1ccc(N2c3cccc4c3B(c3cccc(-c5cccc6c5oc5ccccc56)c32)c2cccc(-c3cccc5c3oc3ccccc35)c2N4c2ccccc2)cc1 ; c1ccc(N2c3cc(-c4cccc5c4oc4ccccc45)ccc3B3c4ccc(-c5cccc6c5oc5ccccc56)cc4N(c4ccccc4)c4cccc2c43)cc1 ; c1ccc(N2c3ccc(-c4cccc5c4oc4ccccc45)cc3B3c4cc(-c5cccc6c5oc5ccccc56)ccc4N(c4ccccc4)c4cccc2c43)cc1 ; c1ccc(N2c3cccc(-c4cccc5c4oc4ccccc45)c3B3c4c(-c5cccc6c5oc5ccccc56)cccc4N(c4ccccc4)c4cccc2c43)cc1]

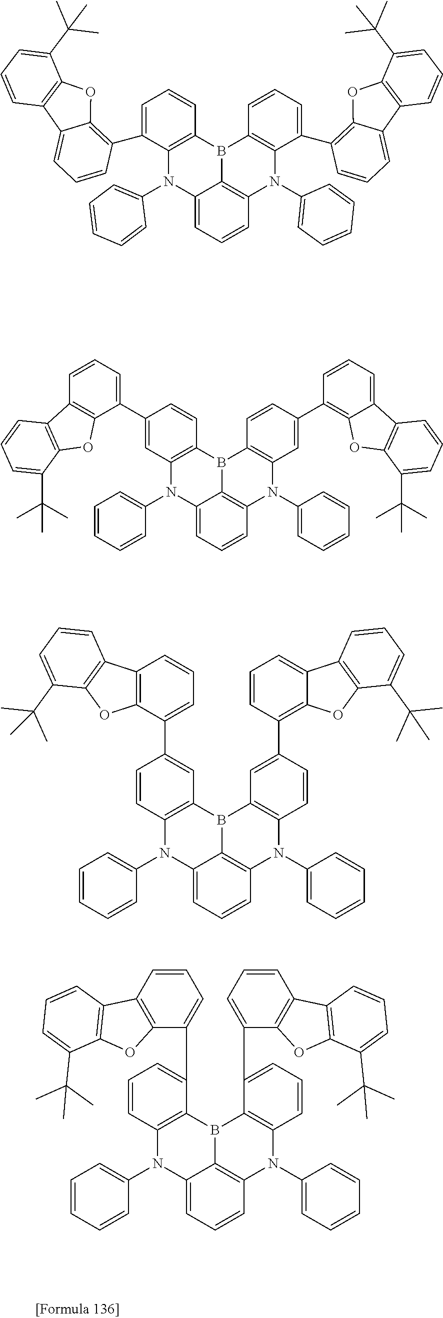

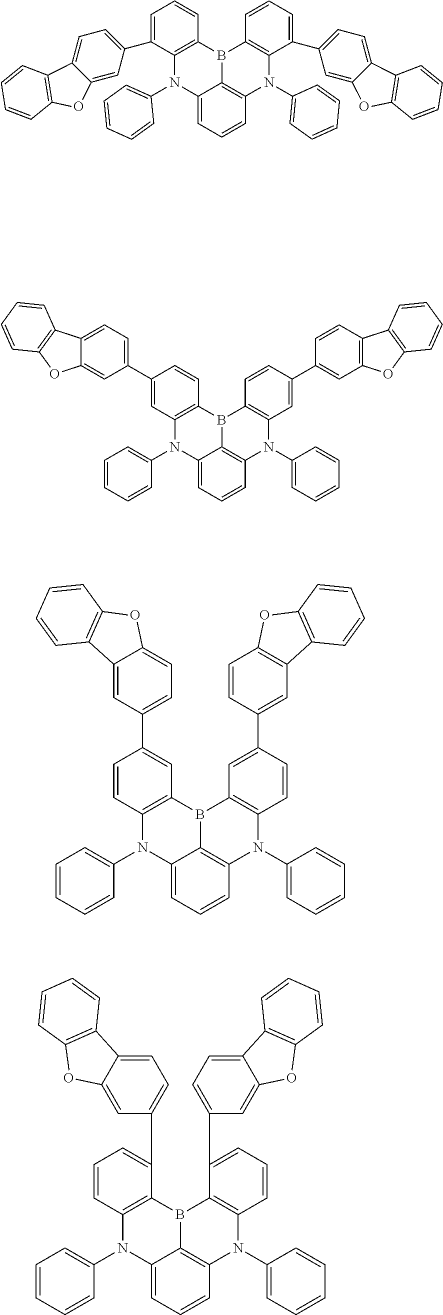 [SMILES: c1ccc(N2c3cccc4c3B(c3cccc(-c5ccc6c(c5)oc5ccccc56)c32)c2cccc(-c3ccc5c(c3)oc3ccccc35)c2N4c2ccccc2)cc1 ; c1ccc(N2c3cc(-c4ccc5c(c4)oc4ccccc45)ccc3B3c4ccc(-c5ccc6c(c5)oc5ccccc56)cc4N(c4ccccc4)c4cccc2c43)cc1 ; c1ccc(N2c3ccc(-c4ccc5oc6ccccc6c5c4)cc3B3c4cc(-c5ccc6oc7ccccc7c6c5)ccc4N(c4ccccc4)c4cccc2c43)cc1 ; c1ccc(N2c3cccc(-c4ccc5c(c4)oc4ccccc45)c3B3c4c(-c5ccc6c(c5)oc5ccccc56)cccc4N(c4ccccc4)c4cccc2c43)cc1]

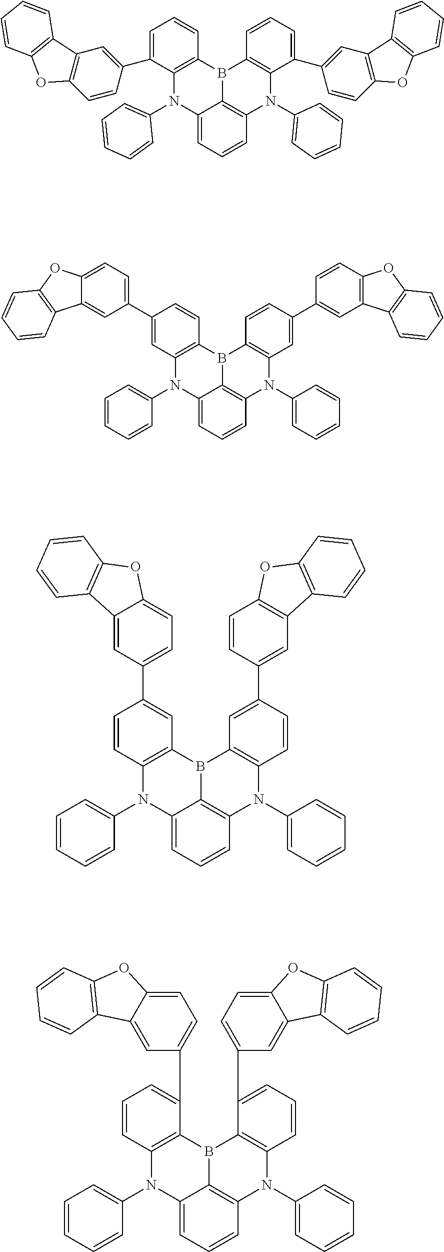 [SMILES: c1ccc(N2c3cccc4c3B(c3cccc(-c5ccc6oc7ccccc7c6c5)c32)c2cccc(-c3ccc5oc6ccccc6c5c3)c2N4c2ccccc2)cc1 ; c1ccc(N2c3cc(-c4ccc5oc6ccccc6c5c4)ccc3B3c4ccc(-c5ccc6oc7ccccc7c6c5)cc4N(c4ccccc4)c4cccc2c43)cc1 ; c1ccc(N2c3ccc(-c4ccc5oc6ccccc6c5c4)cc3B3c4cc(-c5ccc6oc7ccccc7c6c5)ccc4N(c4ccccc4)c4cccc2c43)cc1 ; c1ccc(N2c3cccc(-c4ccc5oc6ccccc6c5c4)c3B3c4c(-c5ccc6oc7ccccc7c6c5)cccc4N(c4ccccc4)c4cccc2c43)cc1]

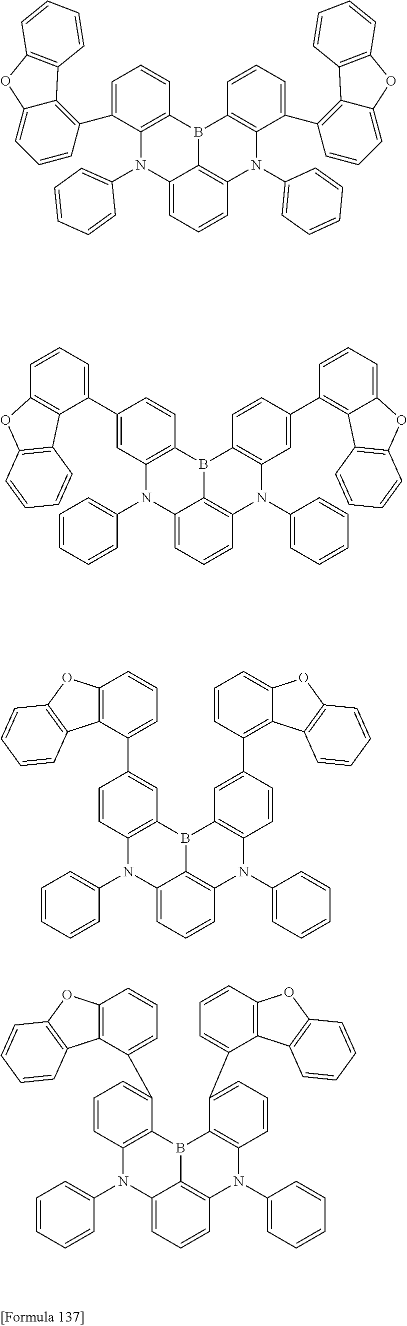 [SMILES: c1ccc(N2c3cccc4c3B(c3cccc(-c5cccc6oc7ccccc7c56)c32)c2cccc(-c3cccc5oc6ccccc6c35)c2N4c2ccccc2)cc1 ; c1ccc(N2c3cc(-c4cccc5oc6ccccc6c45)ccc3B3c4ccc(-c5cccc6oc7ccccc7c56)cc4N(c4ccccc4)c4cccc2c43)cc1 ; c1ccc(N2c3ccc(-c4cccc5oc6ccccc6c45)cc3B3c4cc(-c5cccc6oc7ccccc7c56)ccc4N(c4ccccc4)c4cccc2c43)cc1 ; c1ccc(N2c3cccc(-c4cccc5oc6ccccc6c45)c3B3c4c(-c5cccc6oc7ccccc7c56)cccc4N(c4ccccc4)c4cccc2c43)cc1]

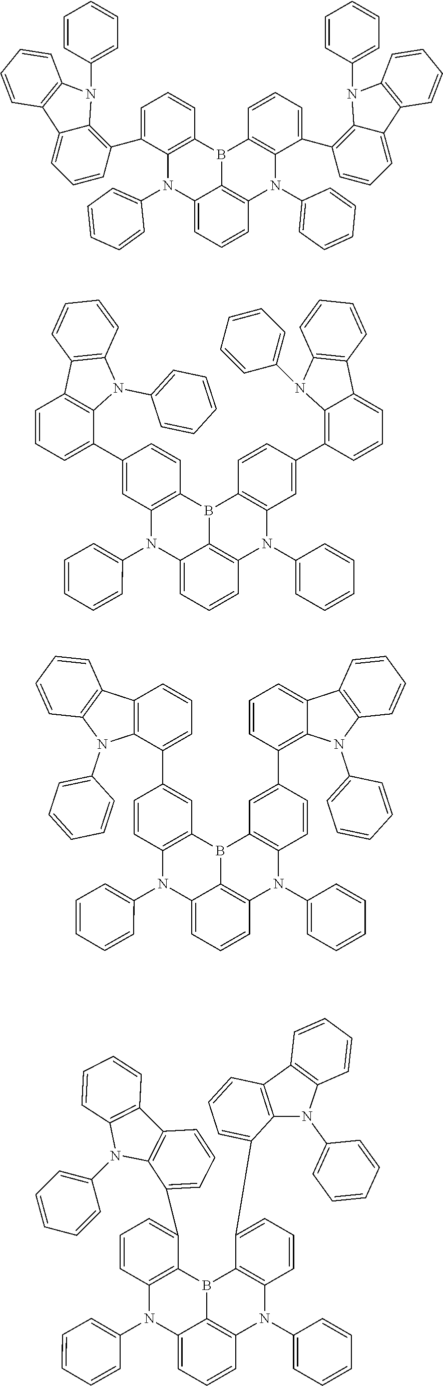 [SMILES: c1ccc(N2c3cccc4c3B(c3cccc(-c5cccc6c7ccccc7n(-c7ccccc7)c56)c32)c2cccc(-c3cccc5c6ccccc6n(-c6ccccc6)c35)c2N4c2ccccc2)cc1 ; c1ccc(N2c3cc(-c4cccc5c6ccccc6n(-c6ccccc6)c45)ccc3B3c4ccc(-c5cccc6c7ccccc7n(-c7ccccc7)c56)cc4N(c4ccccc4)c4cccc2c43)cc1 ; c1ccc(N2c3ccc(-c4cccc5c6ccccc6n(-c6ccccc6)c45)cc3B3c4cc(-c5cccc6c7ccccc7n(-c7ccccc7)c56)ccc4N(c4ccccc4)c4cccc2c43)cc1 ; c1ccc(N2c3cccc(-c4cccc5c6ccccc6n(-c6ccccc6)c45)c3B3c4c(-c5cccc6c7ccccc7n(-c7ccccc7)c56)cccc4N(c4ccccc4)c4cccc2c43)cc1]

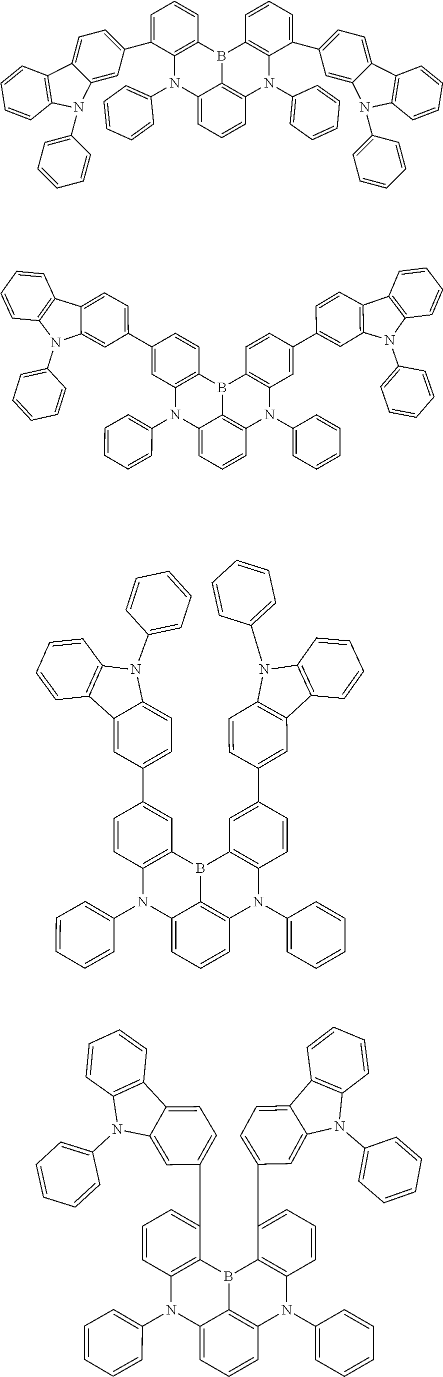 [SMILES: c1ccc(N2c3cccc4c3B(c3cccc(-c5ccc6c7ccccc7n(-c7ccccc7)c6c5)c32)c2cccc(-c3ccc5c6ccccc6n(-c6ccccc6)c5c3)c2N4c2ccccc2)cc1 ; c1ccc(N2c3cc(-c4ccc5c6ccccc6n(-c6ccccc6)c5c4)ccc3B3c4ccc(-c5ccc6c7ccccc7n(-c7ccccc7)c6c5)cc4N(c4ccccc4)c4cccc2c43)cc1 ; c1ccc(N2c3ccc(-c4ccc5c(c4)c4ccccc4n5-c4ccccc4)cc3B3c4cc(-c5ccc6c(c5)c5ccccc5n6-c5ccccc5)ccc4N(c4ccccc4)c4cccc2c43)cc1 ; c1ccc(N2c3cccc(-c4ccc5c6ccccc6n(-c6ccccc6)c5c4)c3B3c4c(-c5ccc6c7ccccc7n(-c7ccccc7)c6c5)cccc4N(c4ccccc4)c4cccc2c43)cc1]

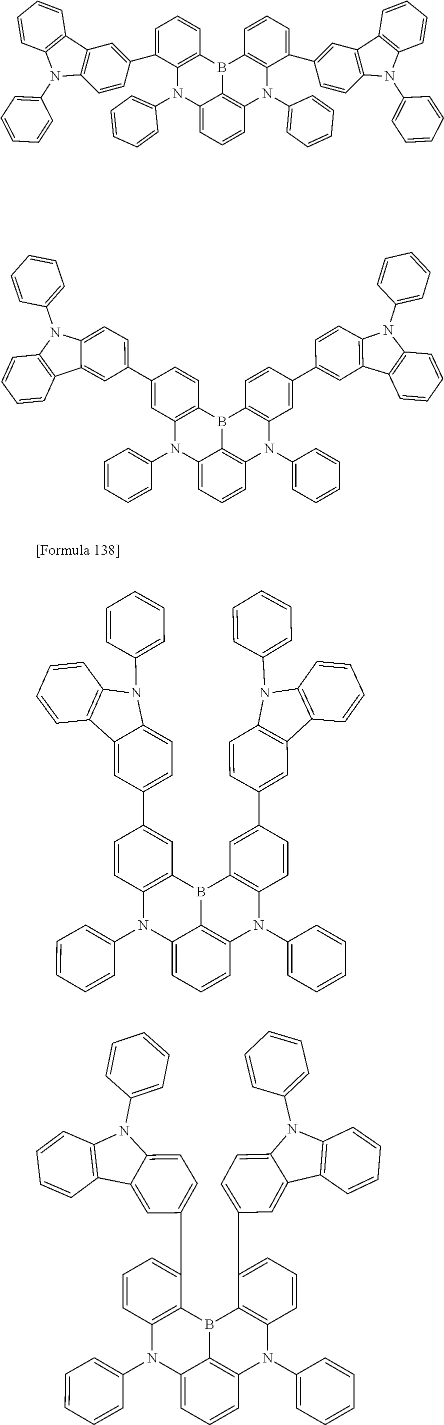 [SMILES: c1ccc(N2c3cccc4c3B(c3cccc(-c5ccc6c(c5)c5ccccc5n6-c5ccccc5)c32)c2cccc(-c3ccc5c(c3)c3ccccc3n5-c3ccccc3)c2N4c2ccccc2)cc1 ; c1ccc(N2c3cc(-c4ccc5c(c4)c4ccccc4n5-c4ccccc4)ccc3B3c4ccc(-c5ccc6c(c5)c5ccccc5n6-c5ccccc5)cc4N(c4ccccc4)c4cccc2c43)cc1 ; c1ccc(N2c3ccc(-c4ccc5c(c4)c4ccccc4n5-c4ccccc4)cc3B3c4cc(-c5ccc6c(c5)c5ccccc5n6-c5ccccc5)ccc4N(c4ccccc4)c4cccc2c43)cc1 ; c1ccc(N2c3cccc(-c4ccc5c(c4)c4ccccc4n5-c4ccccc4)c3B3c4c(-c5ccc6c(c5)c5ccccc5n6-c5ccccc5)cccc4N(c4ccccc4)c4cccc2c43)cc1]

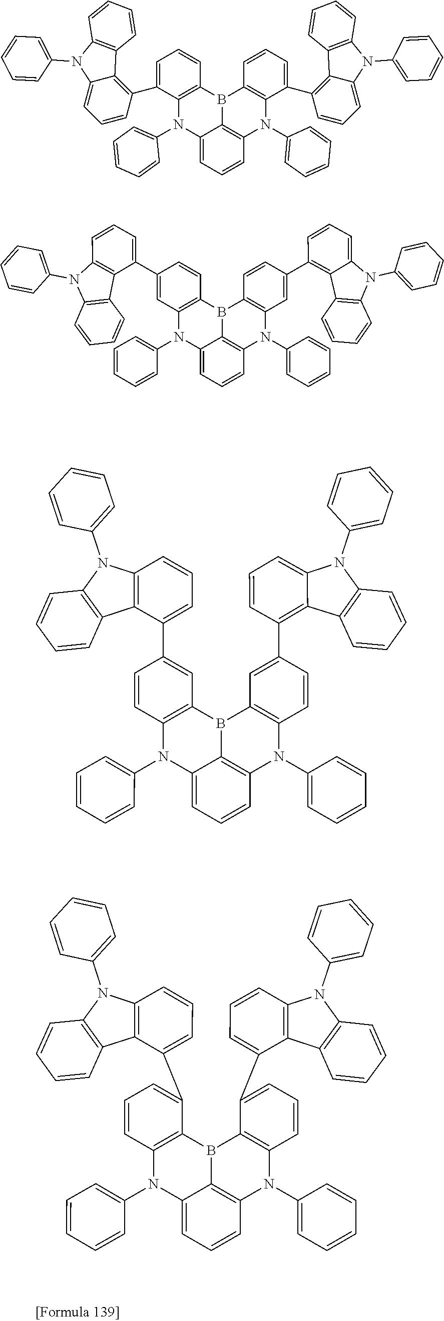 [SMILES: c1ccc(N2c3cccc4c3B(c3cccc(-c5cccc6c5c5ccccc5n6-c5ccccc5)c32)c2cccc(-c3cccc5c3c3ccccc3n5-c3ccccc3)c2N4c2ccccc2)cc1 ; c1ccc(N2c3cc(-c4cccc5c4c4ccccc4n5-c4ccccc4)ccc3B3c4ccc(-c5cccc6c5c5ccccc5n6-c5ccccc5)cc4N(c4ccccc4)c4cccc2c43)cc1 ; c1ccc(N2c3ccc(-c4cccc5c4c4ccccc4n5-c4ccccc4)cc3B3c4cc(-c5cccc6c5c5ccccc5n6-c5ccccc5)ccc4N(c4ccccc4)c4cccc2c43)cc1 ; c1ccc(N2c3cccc(-c4cccc5c4c4ccccc4n5-c4ccccc4)c3B3c4c(-c5cccc6c5c5ccccc5n6-c5ccccc5)cccc4N(c4ccccc4)c4cccc2c43)cc1]

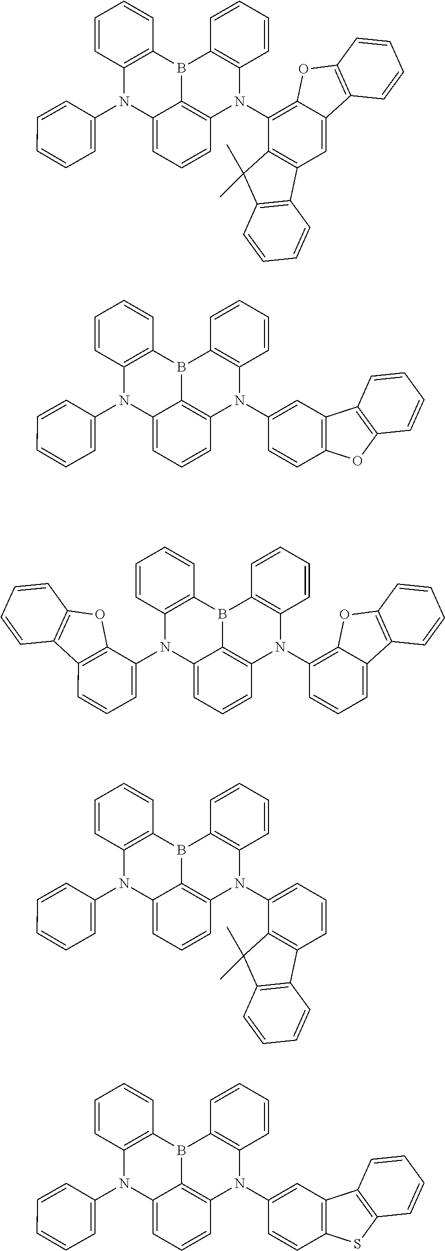

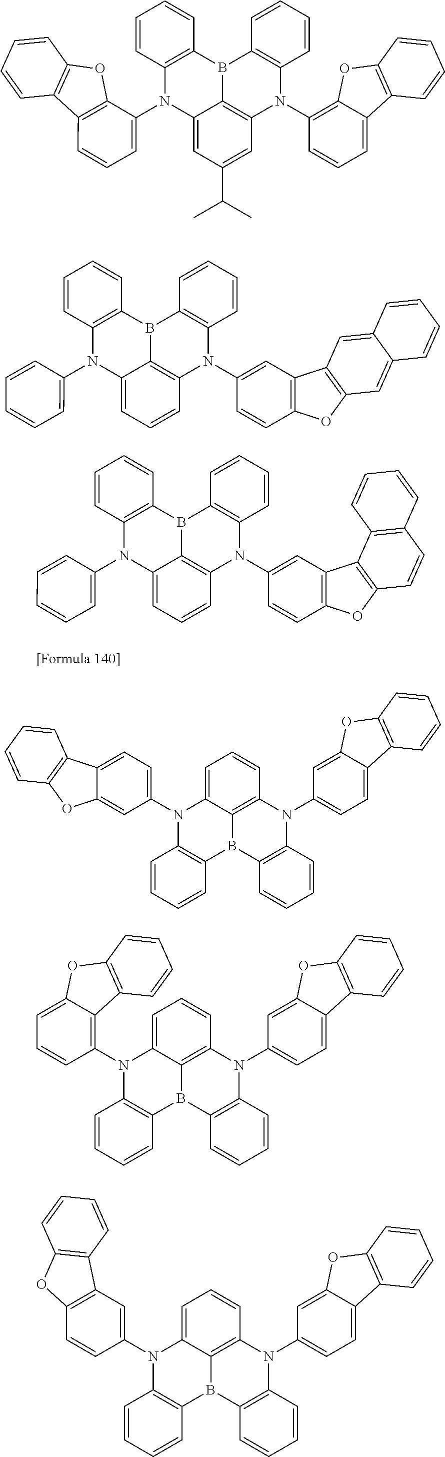

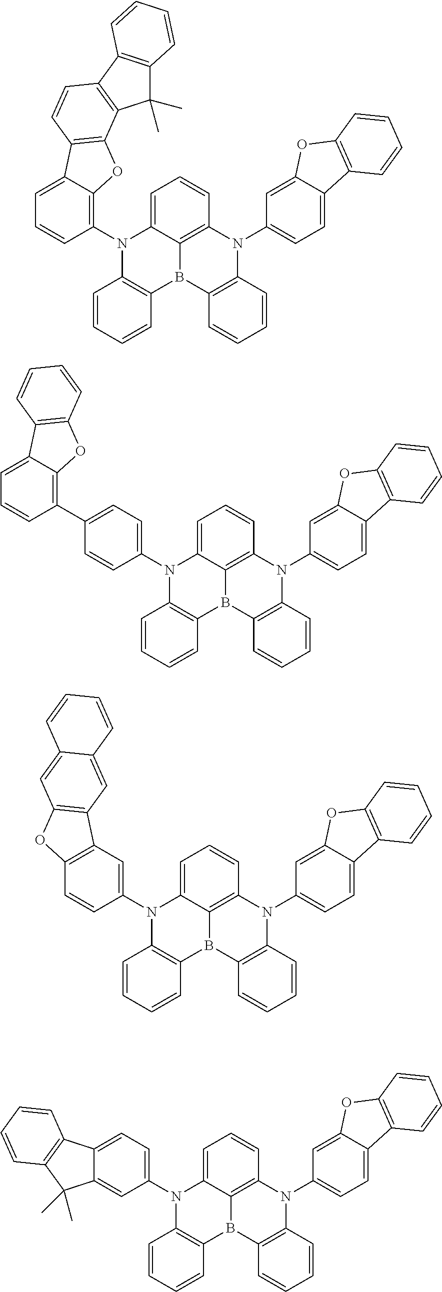 [SMILES: CC1(C)c2ccccc2-c2ccc3c(oc4c(N5c6ccccc6B6c7ccccc7N(c7ccc8c(c7)oc7ccccc78)c7cccc5c76)cccc43)c21 ; c1ccc2c(c1)B1c3ccccc3N(c3ccc4c(c3)oc3ccccc34)c3cccc(c31)N2c1ccc(-c2cccc3c2oc2ccccc23)cc1 ; c1ccc2c(c1)B1c3ccccc3N(c3ccc4oc5cc6ccccc6cc5c4c3)c3cccc(c31)N2c1ccc2c(c1)oc1ccccc12 ; CC1(C)c2ccccc2-c2ccc(N3c4ccccc4B4c5ccccc5N(c5ccc6c(c5)oc5ccccc56)c5cccc3c54)cc21]

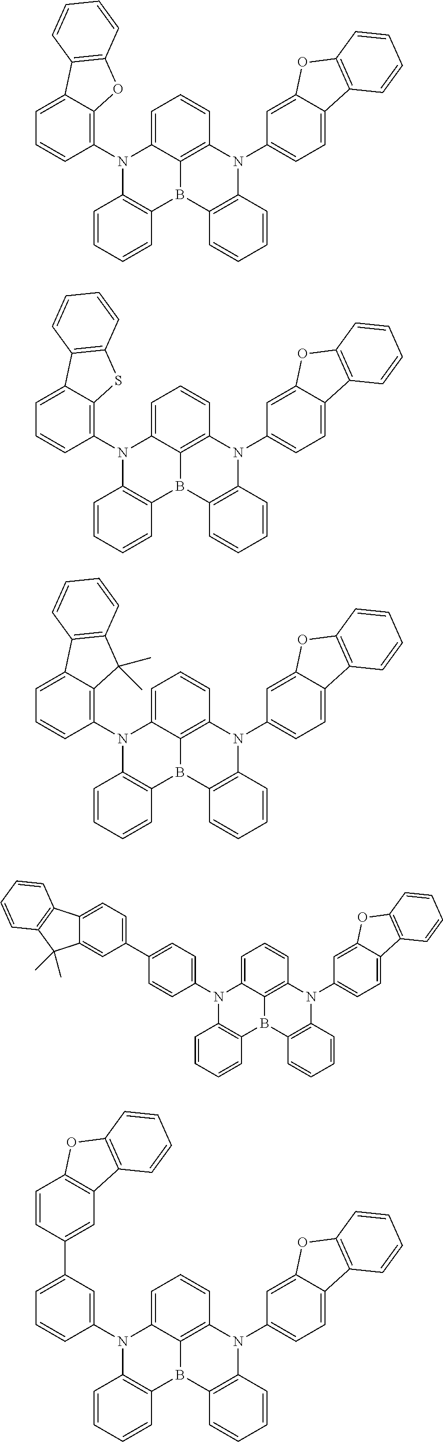

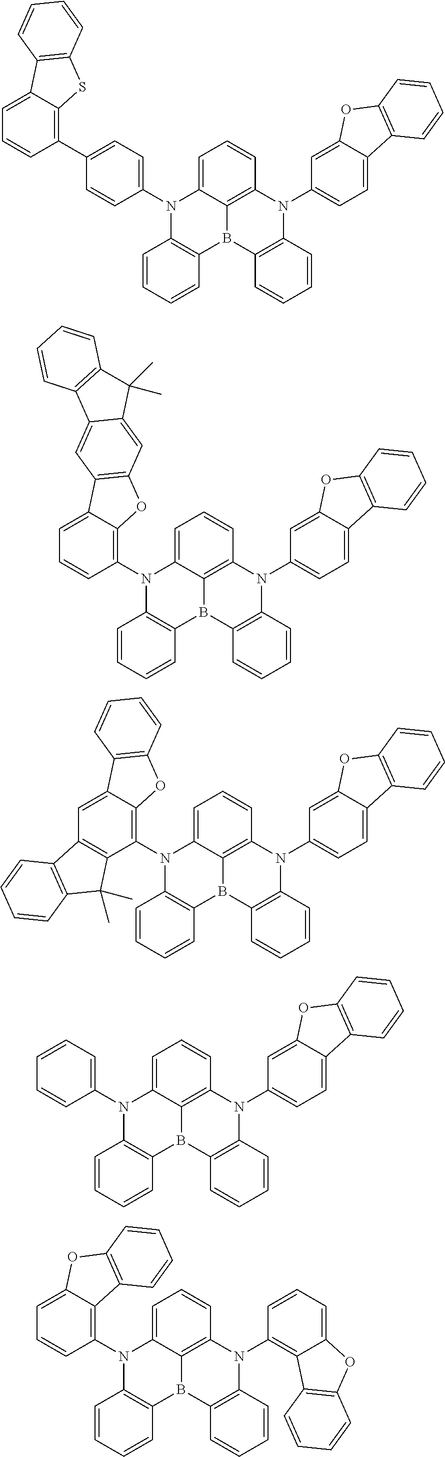

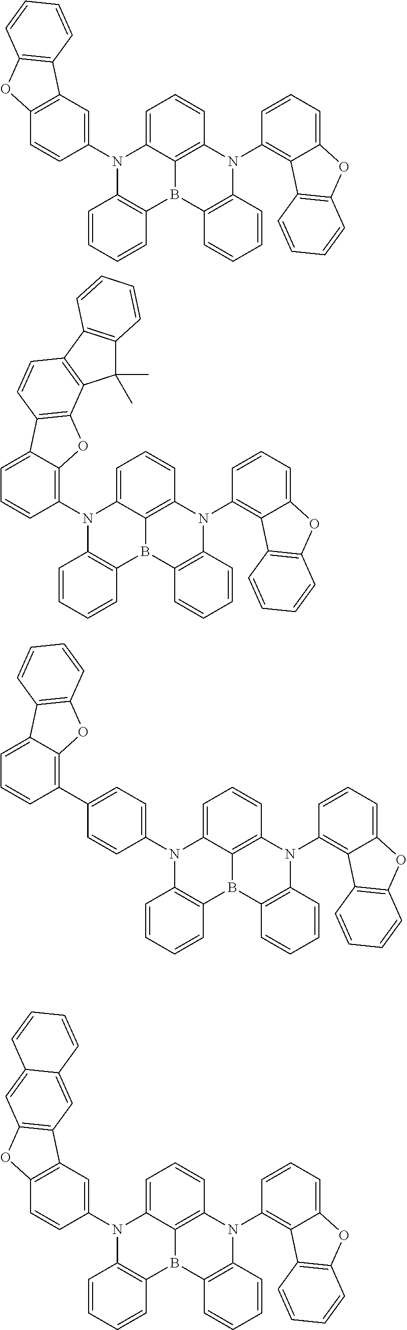

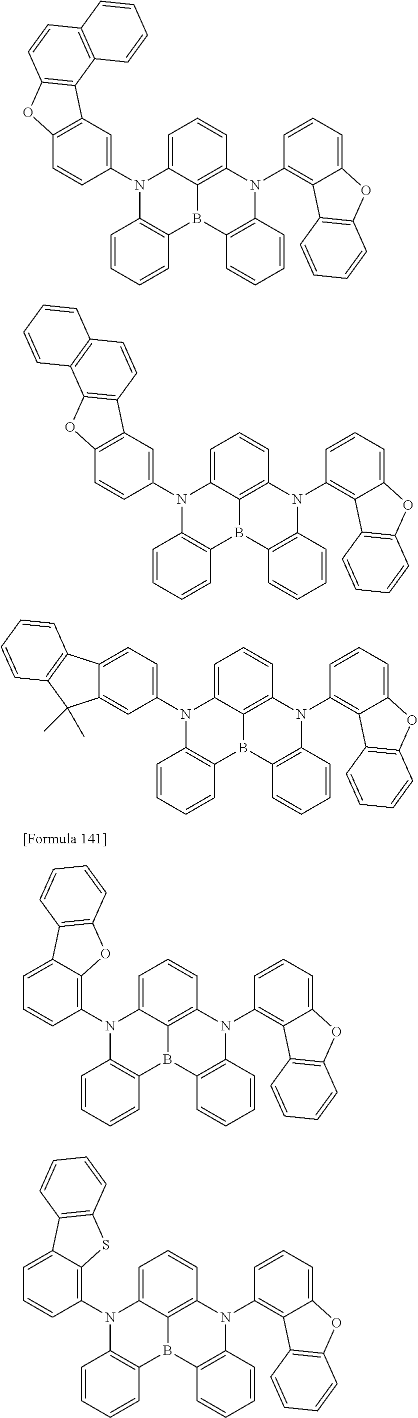

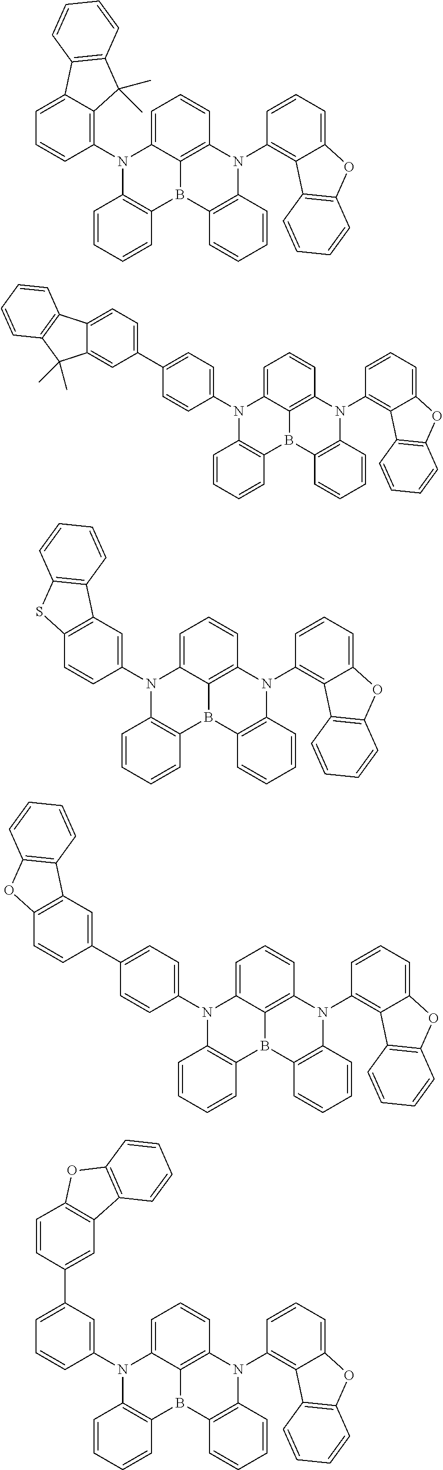 [SMILES: CC1(C)c2ccccc2-c2cccc(N3c4ccccc4B4c5ccccc5N(c5cccc6oc7ccccc7c56)c5cccc3c54)c21 ; CC1(C)c2ccccc2-c2ccc(-c3ccc(N4c5ccccc5B5c6ccccc6N(c6cccc7oc8ccccc8c67)c6cccc4c65)cc3)cc21 ; c1ccc2c(c1)B1c3ccccc3N(c3cccc4oc5ccccc5c34)c3cccc(c31)N2c1ccc2sc3ccccc3c2c1 ; c1ccc2c(c1)B1c3ccccc3N(c3cccc4oc5ccccc5c34)c3cccc(c31)N2c1ccc(-c2ccc3oc4ccccc4c3c2)cc1 ; c1cc(-c2ccc3oc4ccccc4c3c2)cc(N2c3ccccc3B3c4ccccc4N(c4cccc5oc6ccccc6c45)c4cccc2c43)c1]

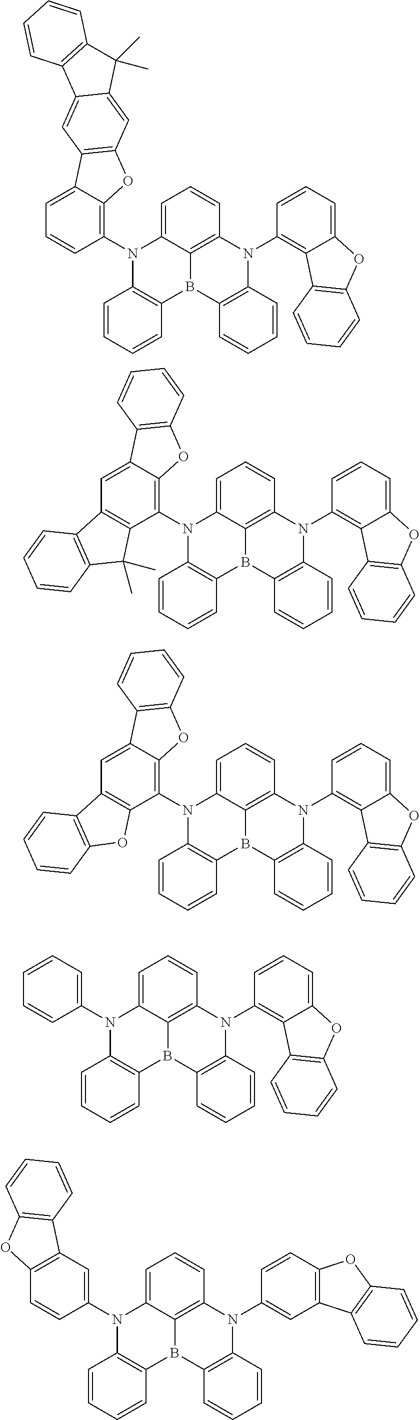

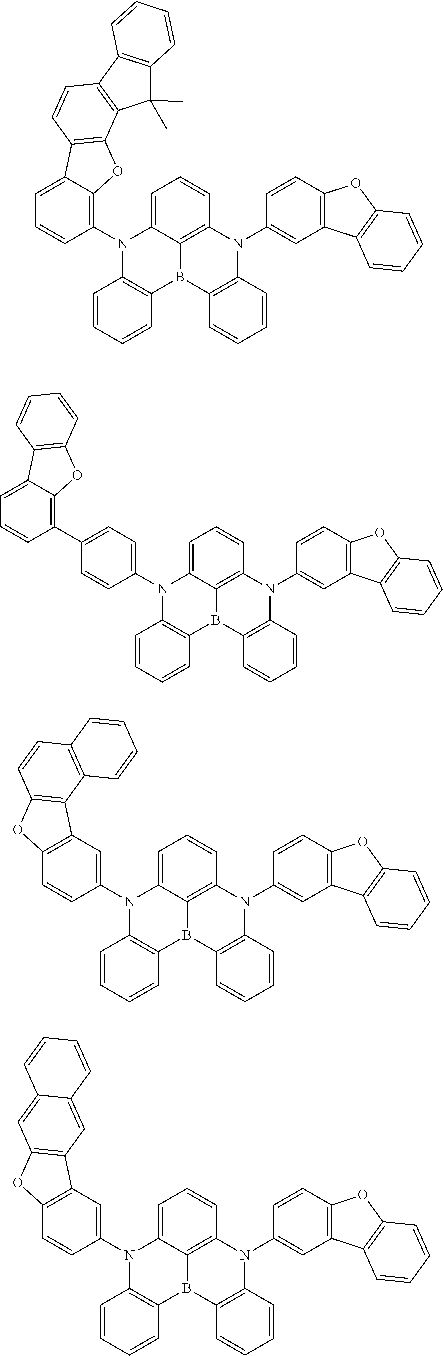 [SMILES: CC1(C)c2ccccc2-c2ccc3c(oc4c(N5c6ccccc6B6c7ccccc7N(c7ccc8oc9ccccc9c8c7)c7cccc5c76)cccc43)c21 ; c1ccc2c(c1)B1c3ccccc3N(c3ccc4oc5ccccc5c4c3)c3cccc(c31)N2c1ccc(-c2cccc3c2oc2ccccc23)cc1 ; c1ccc2c(c1)B1c3ccccc3N(c3ccc4oc5ccc6ccccc6c5c4c3)c3cccc(c31)N2c1ccc2oc3ccccc3c2c1 ; c1ccc2c(c1)B1c3ccccc3N(c3ccc4oc5cc6ccccc6cc5c4c3)c3cccc(c31)N2c1ccc2oc3ccccc3c2c1]

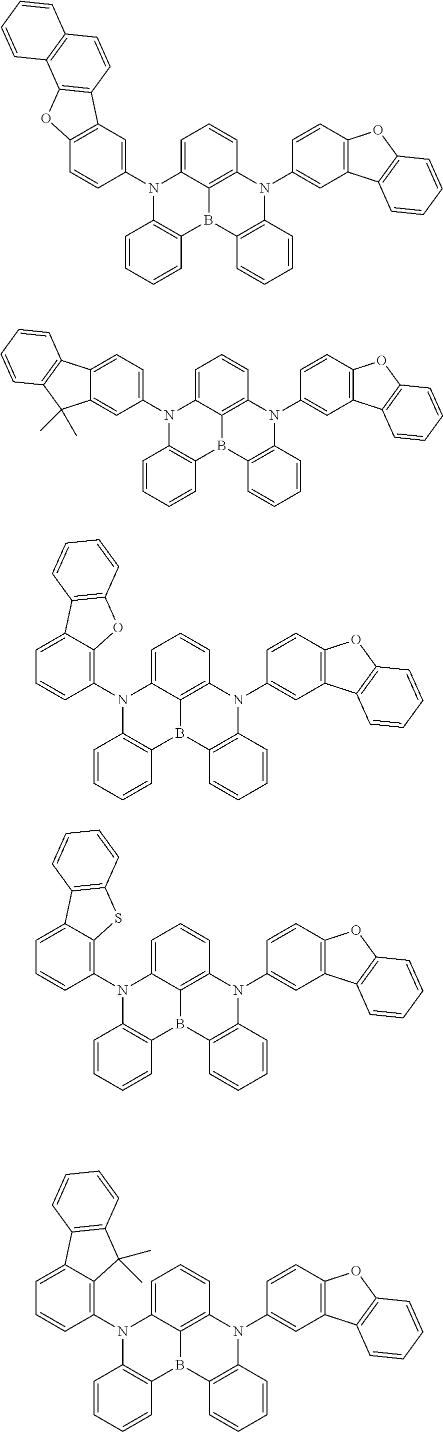

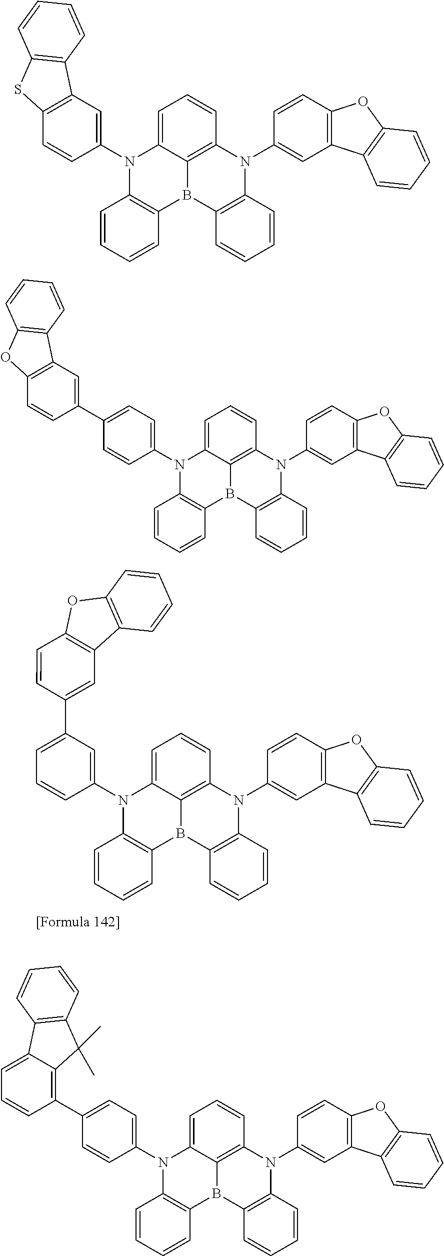

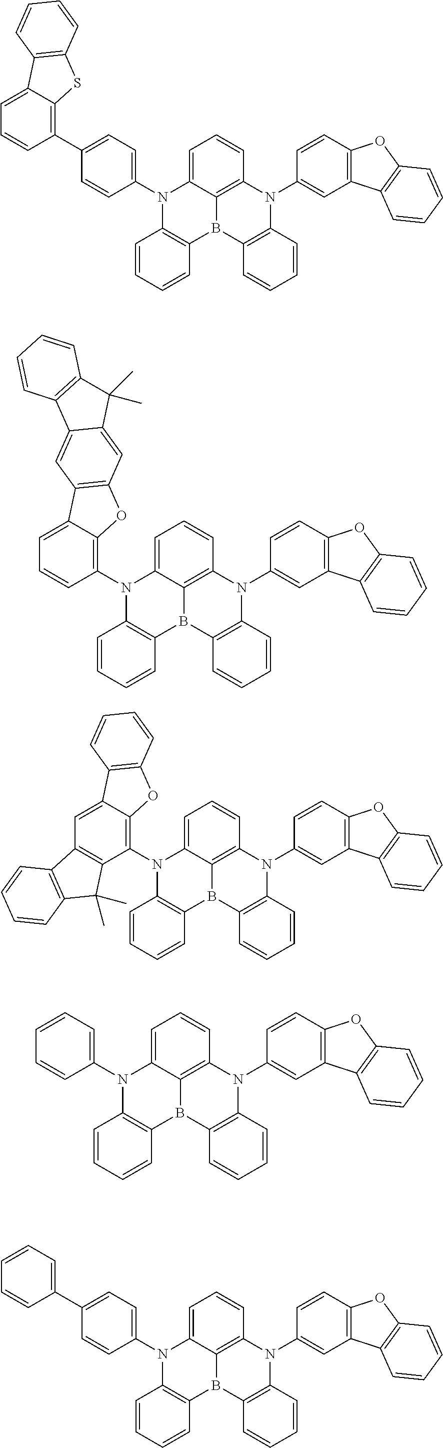

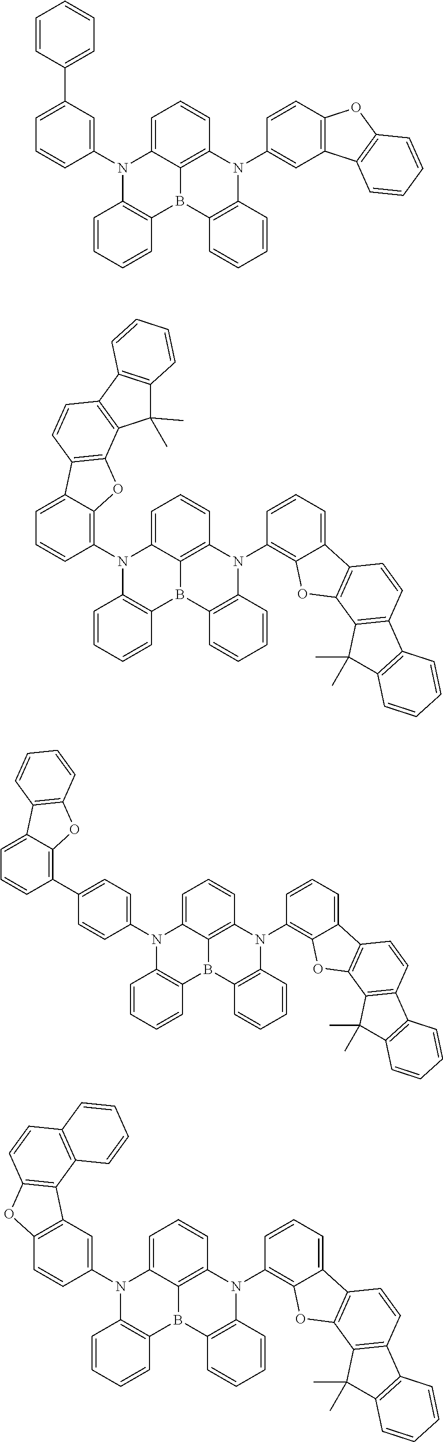 [SMILES: c1ccc(-c2cccc(N3c4ccccc4B4c5ccccc5N(c5ccc6oc7ccccc7c6c5)c5cccc3c54)c2)cc1 ; CC1(C)c2ccccc2-c2ccc3c(oc4c(N5c6ccccc6B6c7ccccc7N(c7cccc8c7oc7c9c(ccc78)-c7ccccc7C9(C)C)c7cccc5c76)cccc43)c21 ; CC1(C)c2ccccc2-c2ccc3c(oc4c(N5c6ccccc6B6c7ccccc7N(c7ccc(-c8cccc9c8oc8ccccc89)cc7)c7cccc5c76)cccc43)c21 ; CC1(C)c2ccccc2-c2ccc3c(oc4c(N5c6ccccc6B6c7ccccc7N(c7ccc8oc9ccc%10ccccc%10c9c8c7)c7cccc5c76)cccc43)c21]

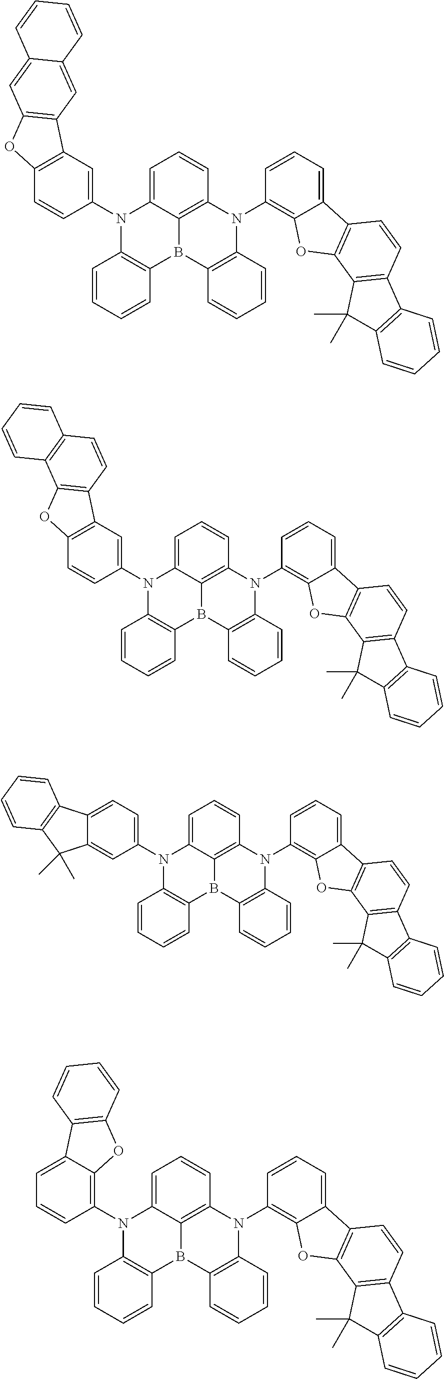 [SMILES: CC1(C)c2ccccc2-c2ccc3c(oc4c(N5c6ccccc6B6c7ccccc7N(c7ccc8oc9cc%10ccccc%10cc9c8c7)c7cccc5c76)cccc43)c21 ; CC1(C)c2ccccc2-c2ccc3c(oc4c(N5c6ccccc6B6c7ccccc7N(c7ccc8oc9c%10ccccc%10ccc9c8c7)c7cccc5c76)cccc43)c21 ; CC1(C)c2ccccc2-c2ccc(N3c4ccccc4B4c5ccccc5N(c5cccc6c5oc5c7c(ccc56)-c5ccccc5C7(C)C)c5cccc3c54)cc21 ; CC1(C)c2ccccc2-c2ccc3c(oc4c(N5c6ccccc6B6c7ccccc7N(c7cccc8c7oc7ccccc78)c7cccc5c76)cccc43)c21]

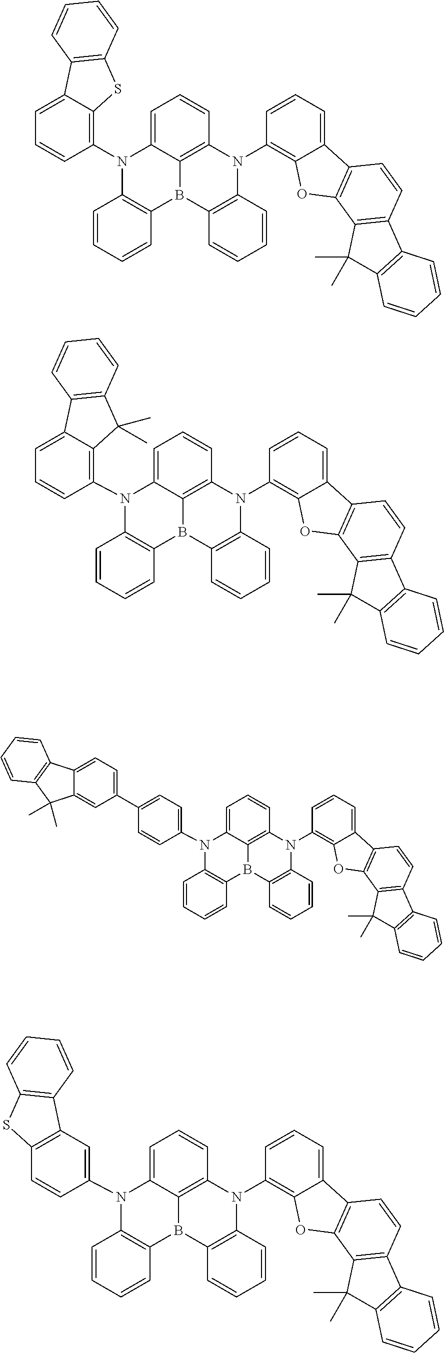 [SMILES: CC1(C)c2ccccc2-c2ccc3c(oc4c(N5c6ccccc6B6c7ccccc7N(c7cccc8c7sc7ccccc78)c7cccc5c76)cccc43)c21 ; CC1(C)c2ccccc2-c2cccc(N3c4ccccc4B4c5ccccc5N(c5cccc6c5oc5c7c(ccc56)-c5ccccc5C7(C)C)c5cccc3c54)c21 ; CC1(C)c2ccccc2-c2ccc(-c3ccc(N4c5ccccc5B5c6ccccc6N(c6cccc7c6oc6c8c(ccc67)-c6ccccc6C8(C)C)c6cccc4c65)cc3)cc21 ; CC1(C)c2ccccc2-c2ccc3c(oc4c(N5c6ccccc6B6c7ccccc7N(c7ccc8sc9ccccc9c8c7)c7cccc5c76)cccc43)c21]

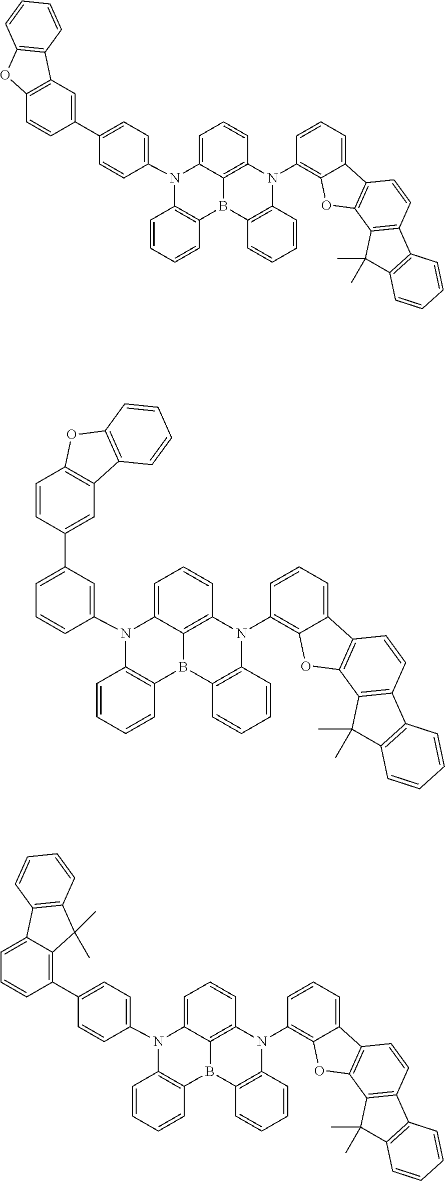 [SMILES: CC1(C)c2ccccc2-c2ccc3c(oc4c(N5c6ccccc6B6c7ccccc7N(c7ccc(-c8ccc9oc%10ccccc%10c9c8)cc7)c7cccc5c76)cccc43)c21 ; CC1(C)c2ccccc2-c2ccc3c(oc4c(N5c6ccccc6B6c7ccccc7N(c7cccc(-c8ccc9oc%10ccccc%10c9c8)c7)c7cccc5c76)cccc43)c21 ; CC1(C)c2ccccc2-c2cccc(-c3ccc(N4c5ccccc5B5c6ccccc6N(c6cccc7c6oc6c8c(ccc67)-c6ccccc6C8(C)C)c6cccc4c65)cc3)c21]

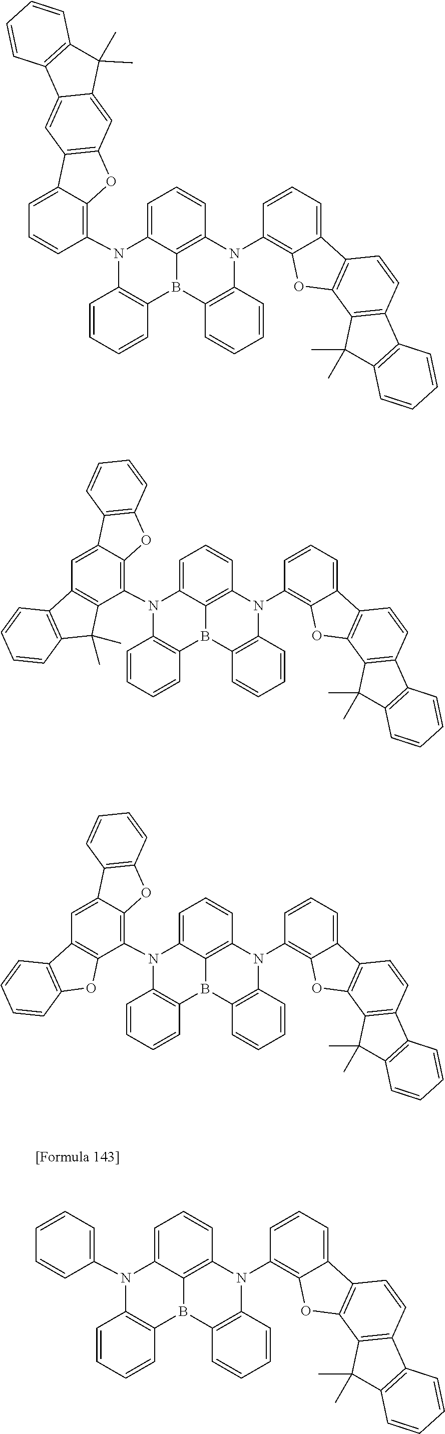 [SMILES: CC1(C)c2ccccc2-c2cc3c(cc21)oc1c(N2c4ccccc4B4c5ccccc5N(c5cccc6c5oc5c7c(ccc56)-c5ccccc5C7(C)C)c5cccc2c54)cccc13 ; CC1(C)c2ccccc2-c2cc3c(oc4ccccc43)c(N3c4ccccc4B4c5ccccc5N(c5cccc6c5oc5c7c(ccc56)-c5ccccc5C7(C)C)c5cccc3c54)c21 ; CC1(C)c2ccccc2-c2ccc3c(oc4c(N5c6ccccc6B6c7ccccc7N(c7c8oc9ccccc9c8cc8c7oc7ccccc78)c7cccc5c76)cccc43)c21 ; CC1(C)c2ccccc2-c2ccc3c(oc4c(N5c6ccccc6B6c7ccccc7N(c7ccccc7)c7cccc5c76)cccc43)c21]

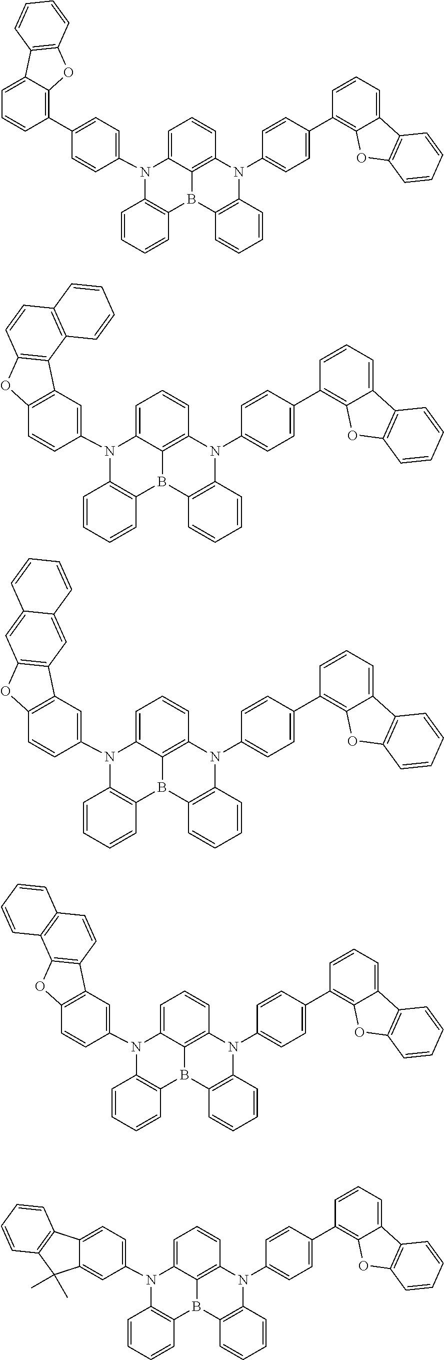 [SMILES: c1ccc2c(c1)B1c3ccccc3N(c3ccc(-c4cccc5c4oc4ccccc45)cc3)c3cccc(c31)N2c1ccc(-c2cccc3c2oc2ccccc23)cc1 ; c1ccc2c(c1)B1c3ccccc3N(c3ccc4oc5ccc6ccccc6c5c4c3)c3cccc(c31)N2c1ccc(-c2cccc3c2oc2ccccc23)cc1 ; c1ccc2c(c1)B1c3ccccc3N(c3ccc4oc5cc6ccccc6cc5c4c3)c3cccc(c31)N2c1ccc(-c2cccc3c2oc2ccccc23)cc1 ; c1ccc2c(c1)B1c3ccccc3N(c3ccc4oc5c6ccccc6ccc5c4c3)c3cccc(c31)N2c1ccc(-c2cccc3c2oc2ccccc23)cc1 ; CC1(C)c2ccccc2-c2ccc(N3c4ccccc4B4c5ccccc5N(c5ccc(-c6cccc7c6oc6ccccc67)cc5)c5cccc3c54)cc21]

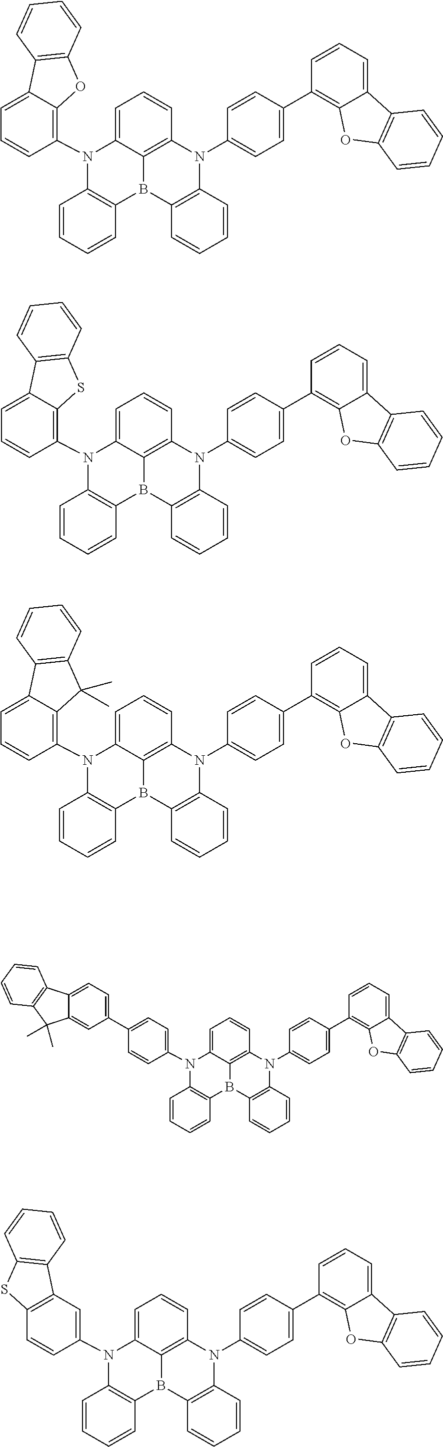 [SMILES: c1ccc2c(c1)B1c3ccccc3N(c3cccc4c3oc3ccccc34)c3cccc(c31)N2c1ccc(-c2cccc3c2oc2ccccc23)cc1 ; c1ccc2c(c1)B1c3ccccc3N(c3cccc4c3sc3ccccc34)c3cccc(c31)N2c1ccc(-c2cccc3c2oc2ccccc23)cc1 ; CC1(C)c2ccccc2-c2cccc(N3c4ccccc4B4c5ccccc5N(c5ccc(-c6cccc7c6oc6ccccc67)cc5)c5cccc3c54)c21 ; CC1(C)c2ccccc2-c2ccc(-c3ccc(N4c5ccccc5B5c6ccccc6N(c6ccc(-c7cccc8c7oc7ccccc78)cc6)c6cccc4c65)cc3)cc21 ; c1ccc2c(c1)B1c3ccccc3N(c3ccc4sc5ccccc5c4c3)c3cccc(c31)N2c1ccc(-c2cccc3c2oc2ccccc23)cc1]

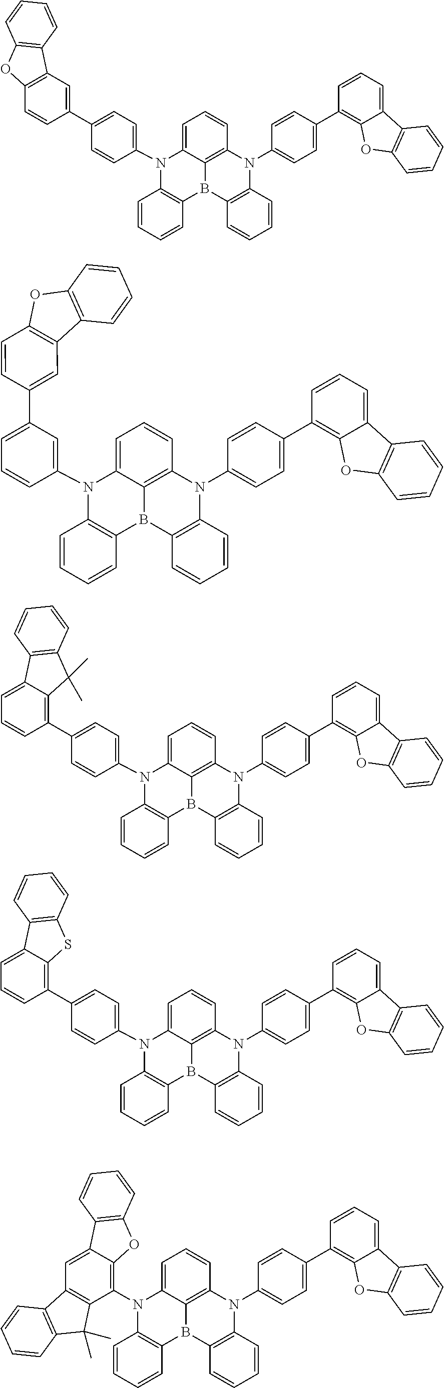

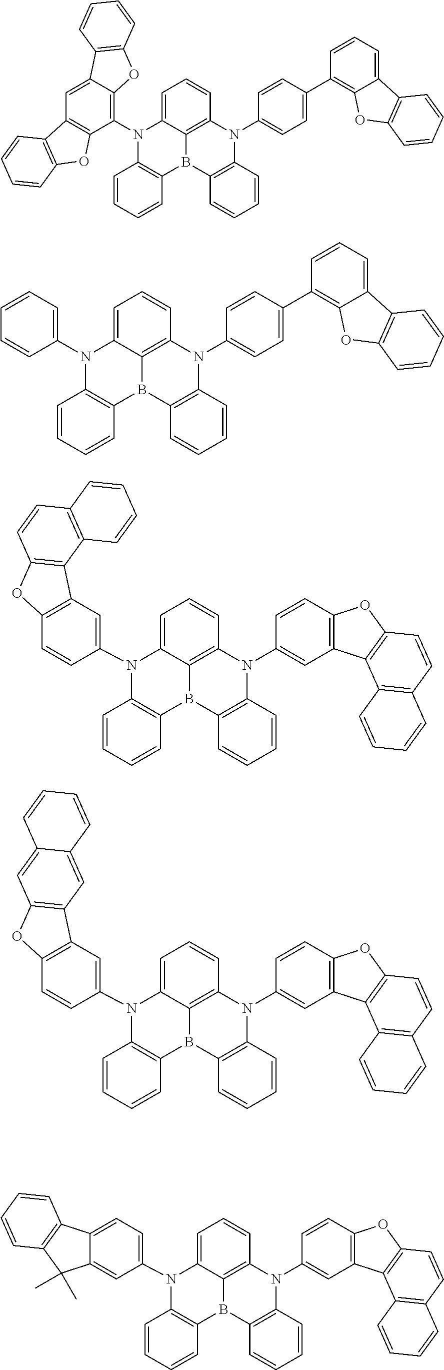

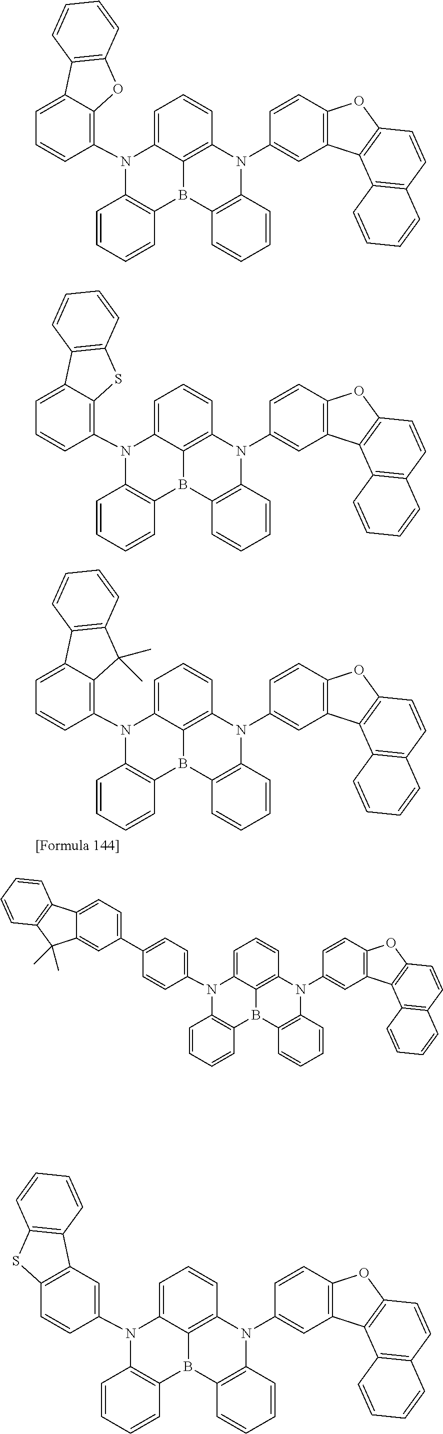

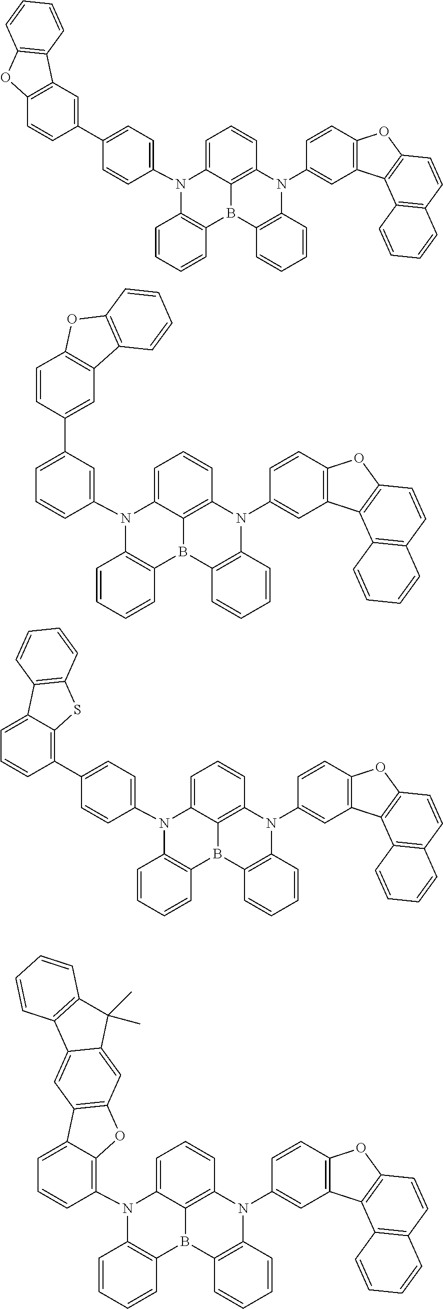

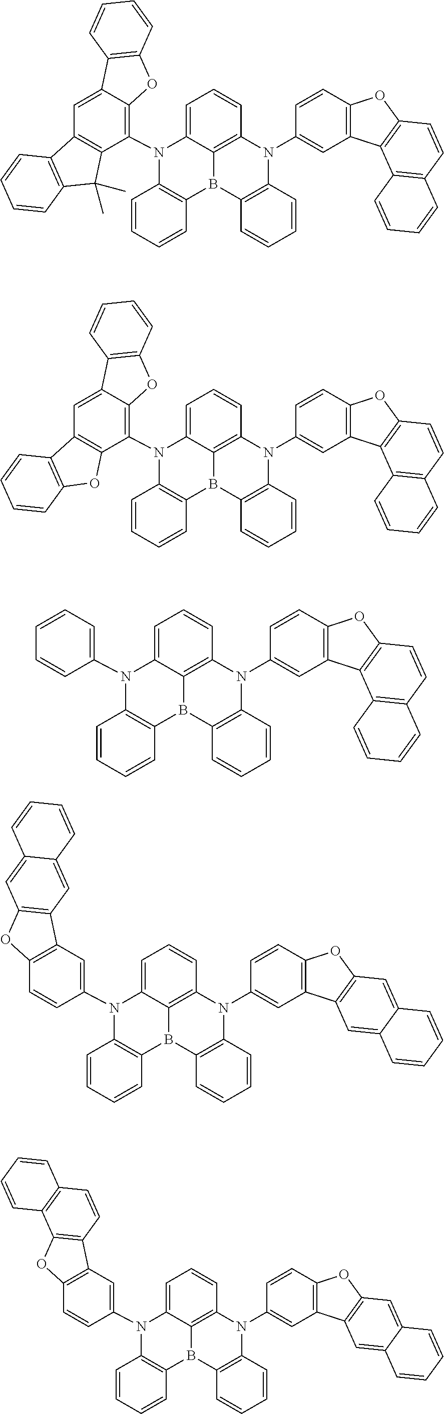 [SMILES: CC1(C)c2ccccc2-c2cc3c(oc4ccccc43)c(N3c4ccccc4B4c5ccccc5N(c5ccc6oc7ccc8ccccc8c7c6c5)c5cccc3c54)c21 ; c1ccc2c(c1)B1c3ccccc3N(c3c4oc5ccccc5c4cc4c3oc3ccccc34)c3cccc(c31)N2c1ccc2oc3ccc4ccccc4c3c2c1 ; c1ccc(N2c3ccccc3B3c4ccccc4N(c4ccc5oc6ccc7ccccc7c6c5c4)c4cccc2c43)cc1 ; c1ccc2c(c1)B1c3ccccc3N(c3ccc4oc5cc6ccccc6cc5c4c3)c3cccc(c31)N2c1ccc2oc3cc4ccccc4cc3c2c1 ; c1ccc2c(c1)B1c3ccccc3N(c3ccc4oc5c6ccccc6ccc5c4c3)c3cccc(c31)N2c1ccc2oc3cc4ccccc4cc3c2c1]

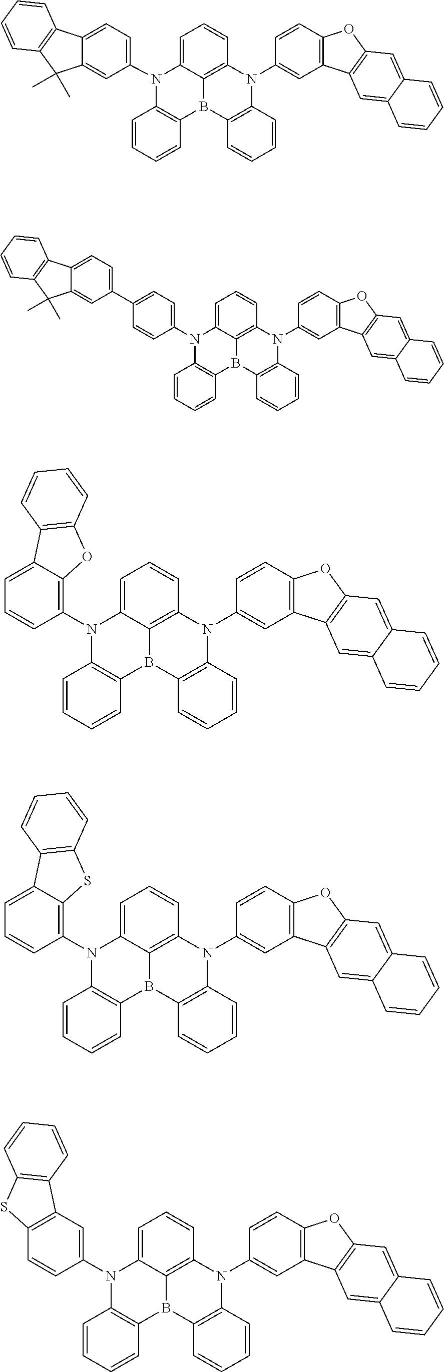 [SMILES: CC1(C)c2ccccc2-c2ccc(N3c4ccccc4B4c5ccccc5N(c5ccc6oc7cc8ccccc8cc7c6c5)c5cccc3c54)cc21 ; CC1(C)c2ccccc2-c2ccc(-c3ccc(N4c5ccccc5B5c6ccccc6N(c6ccc7oc8cc9ccccc9cc8c7c6)c6cccc4c65)cc3)cc21 ; c1ccc2c(c1)B1c3ccccc3N(c3cccc4c3oc3ccccc34)c3cccc(c31)N2c1ccc2oc3cc4ccccc4cc3c2c1 ; c1ccc2c(c1)B1c3ccccc3N(c3cccc4c3sc3ccccc34)c3cccc(c31)N2c1ccc2oc3cc4ccccc4cc3c2c1 ; c1ccc2c(c1)B1c3ccccc3N(c3ccc4sc5ccccc5c4c3)c3cccc(c31)N2c1ccc2oc3cc4ccccc4cc3c2c1]

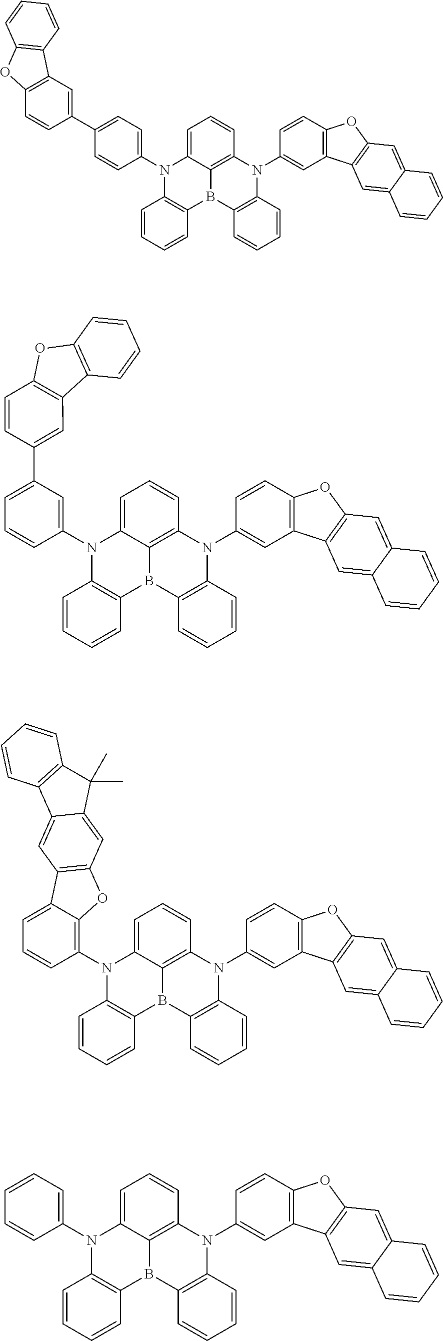 [SMILES: c1ccc2c(c1)B1c3ccccc3N(c3ccc4oc5cc6ccccc6cc5c4c3)c3cccc(c31)N2c1ccc(-c2ccc3oc4ccccc4c3c2)cc1 ; c1cc(-c2ccc3oc4ccccc4c3c2)cc(N2c3ccccc3B3c4ccccc4N(c4ccc5oc6cc7ccccc7cc6c5c4)c4cccc2c43)c1 ; CC1(C)c2ccccc2-c2cc3c(cc21)oc1c(N2c4ccccc4B4c5ccccc5N(c5ccc6oc7cc8ccccc8cc7c6c5)c5cccc2c54)cccc13 ; c1ccc(N2c3ccccc3B3c4ccccc4N(c4ccc5oc6cc7ccccc7cc6c5c4)c4cccc2c43)cc1]

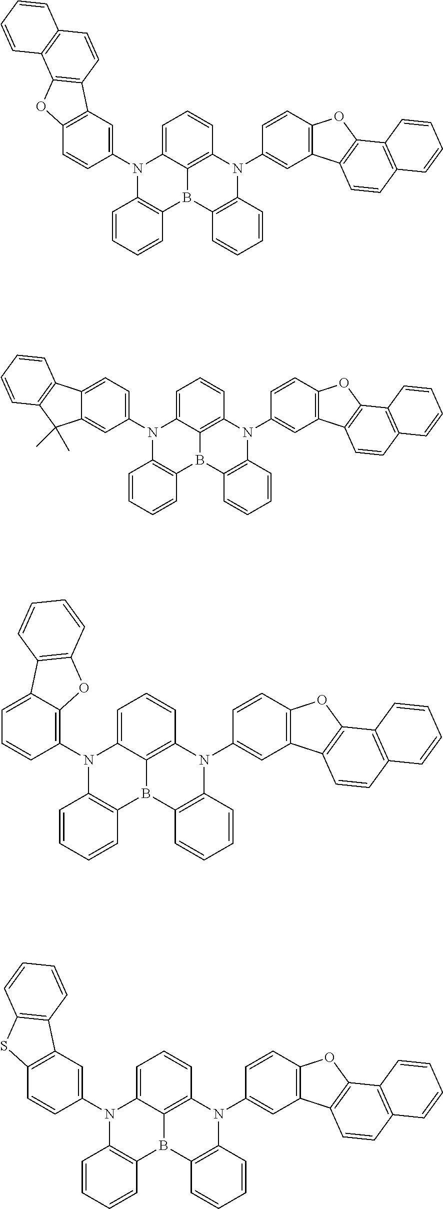 [SMILES: c1ccc2c(c1)B1c3ccccc3N(c3ccc4oc5c6ccccc6ccc5c4c3)c3cccc(c31)N2c1ccc2oc3c4ccccc4ccc3c2c1 ; CC1(C)c2ccccc2-c2ccc(N3c4ccccc4B4c5ccccc5N(c5ccc6oc7c8ccccc8ccc7c6c5)c5cccc3c54)cc21 ; c1ccc2c(c1)B1c3ccccc3N(c3cccc4c3oc3ccccc34)c3cccc(c31)N2c1ccc2oc3c4ccccc4ccc3c2c1 ; c1ccc2c(c1)B1c3ccccc3N(c3ccc4sc5ccccc5c4c3)c3cccc(c31)N2c1ccc2oc3c4ccccc4ccc3c2c1]

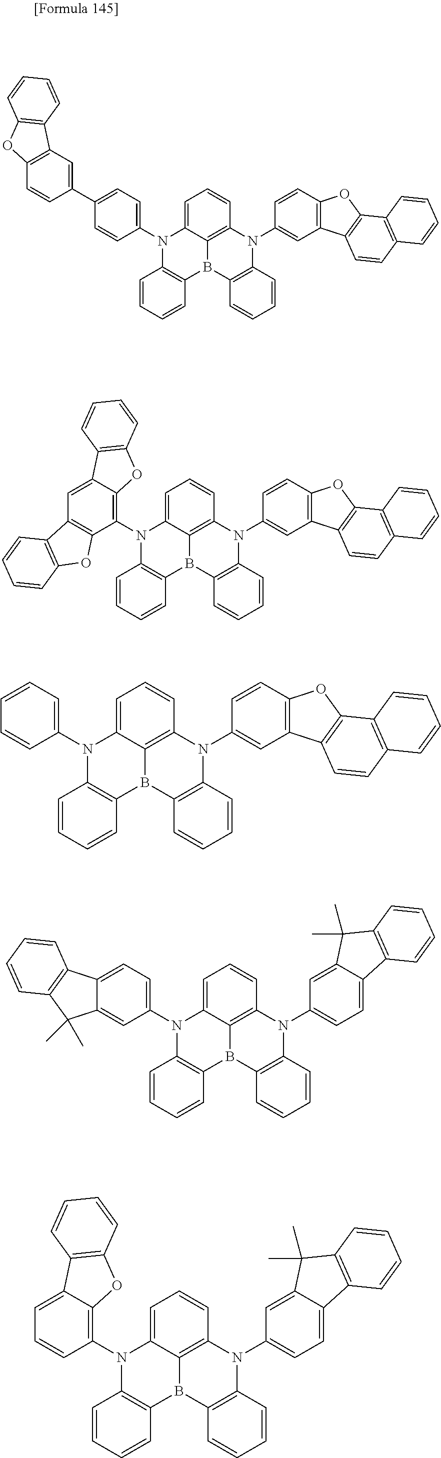 [SMILES: c1ccc2c(c1)B1c3ccccc3N(c3ccc4oc5c6ccccc6ccc5c4c3)c3cccc(c31)N2c1ccc(-c2ccc3oc4ccccc4c3c2)cc1 ; c1ccc2c(c1)B1c3ccccc3N(c3c4oc5ccccc5c4cc4c3oc3ccccc34)c3cccc(c31)N2c1ccc2oc3c4ccccc4ccc3c2c1 ; c1ccc(N2c3ccccc3B3c4ccccc4N(c4ccc5oc6c7ccccc7ccc6c5c4)c4cccc2c43)cc1 ; CC1(C)c2ccccc2-c2ccc(N3c4ccccc4B4c5ccccc5N(c5ccc6c(c5)C(C)(C)c5ccccc5-6)c5cccc3c54)cc21 ; CC1(C)c2ccccc2-c2ccc(N3c4ccccc4B4c5ccccc5N(c5cccc6c5oc5ccccc56)c5cccc3c54)cc21]

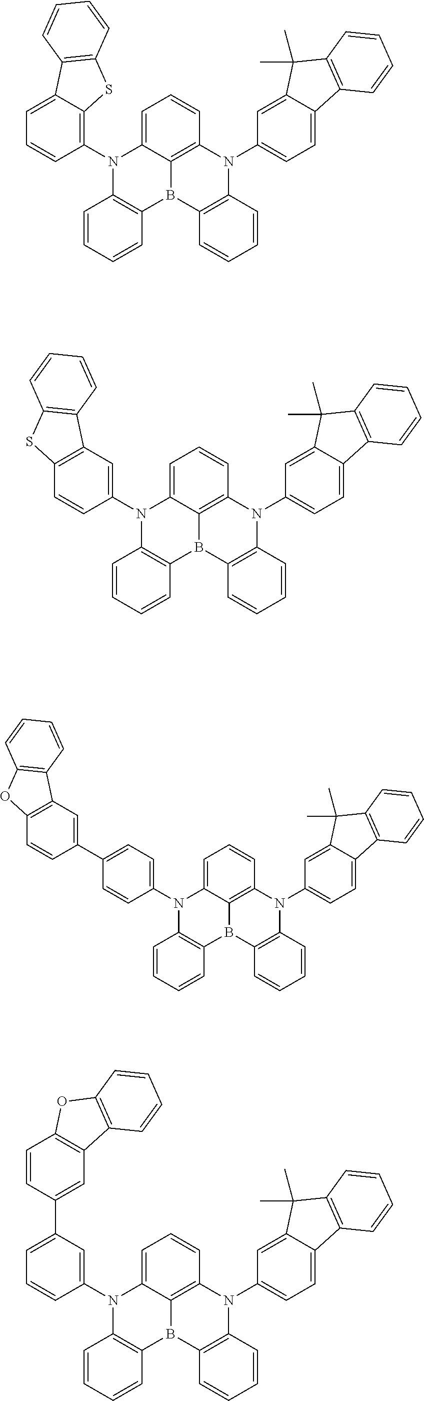 [SMILES: CC1(C)c2ccccc2-c2ccc(N3c4ccccc4B4c5ccccc5N(c5cccc6c5sc5ccccc56)c5cccc3c54)cc21 ; CC1(C)c2ccccc2-c2ccc(N3c4ccccc4B4c5ccccc5N(c5ccc6sc7ccccc7c6c5)c5cccc3c54)cc21 ; CC1(C)c2ccccc2-c2ccc(N3c4ccccc4B4c5ccccc5N(c5ccc(-c6ccc7oc8ccccc8c7c6)cc5)c5cccc3c54)cc21 ; CC1(C)c2ccccc2-c2ccc(N3c4ccccc4B4c5ccccc5N(c5cccc(-c6ccc7oc8ccccc8c7c6)c5)c5cccc3c54)cc21]

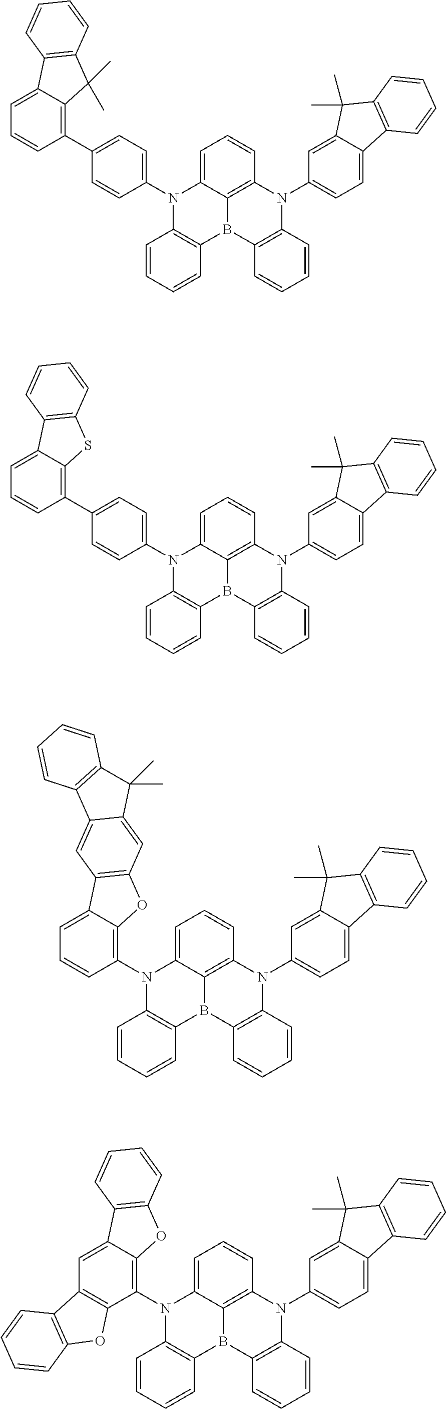 [SMILES: CC1(C)c2ccccc2-c2ccc(N3c4ccccc4B4c5ccccc5N(c5ccc(-c6cccc7c6C(C)(C)c6ccccc6-7)cc5)c5cccc3c54)cc21 ; CC1(C)c2ccccc2-c2ccc(N3c4ccccc4B4c5ccccc5N(c5ccc(-c6cccc7c6sc6ccccc67)cc5)c5cccc3c54)cc21 ; CC1(C)c2ccccc2-c2ccc(N3c4ccccc4B4c5ccccc5N(c5cccc6c5oc5cc7c(cc56)-c5ccccc5C7(C)C)c5cccc3c54)cc21 ; CC1(C)c2ccccc2-c2ccc(N3c4ccccc4B4c5ccccc5N(c5c6oc7ccccc7c6cc6c5oc5ccccc56)c5cccc3c54)cc21]

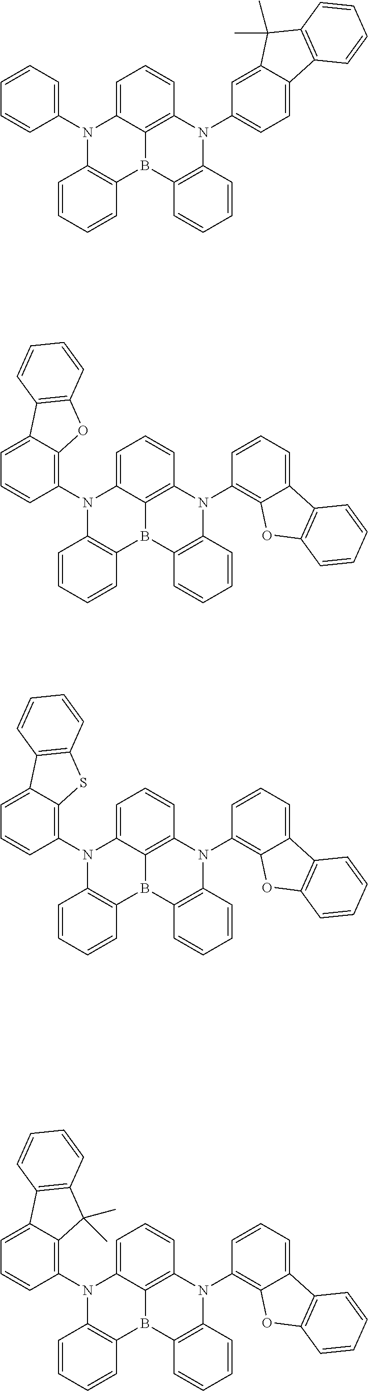 [SMILES: CC1(C)c2ccccc2-c2ccc(N3c4ccccc4B4c5ccccc5N(c5ccccc5)c5cccc3c54)cc21 ; c1ccc2c(c1)B1c3ccccc3N(c3cccc4c3oc3ccccc34)c3cccc(c31)N2c1cccc2c1oc1ccccc12 ; c1ccc2c(c1)B1c3ccccc3N(c3cccc4c3sc3ccccc34)c3cccc(c31)N2c1cccc2c1oc1ccccc12 ; CC1(C)c2ccccc2-c2cccc(N3c4ccccc4B4c5ccccc5N(c5cccc6c5oc5ccccc56)c5cccc3c54)c21]

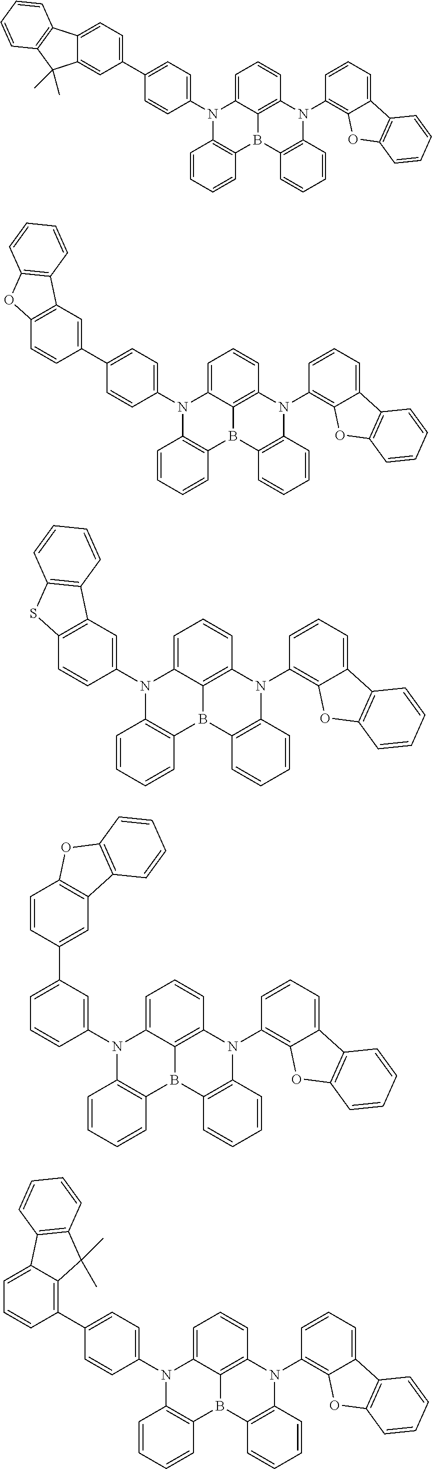

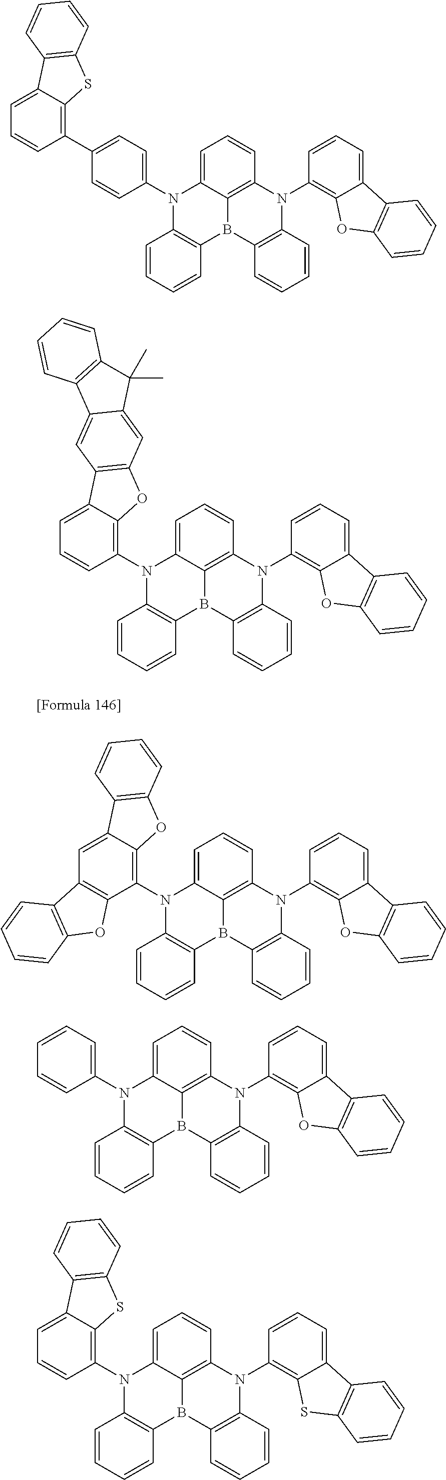

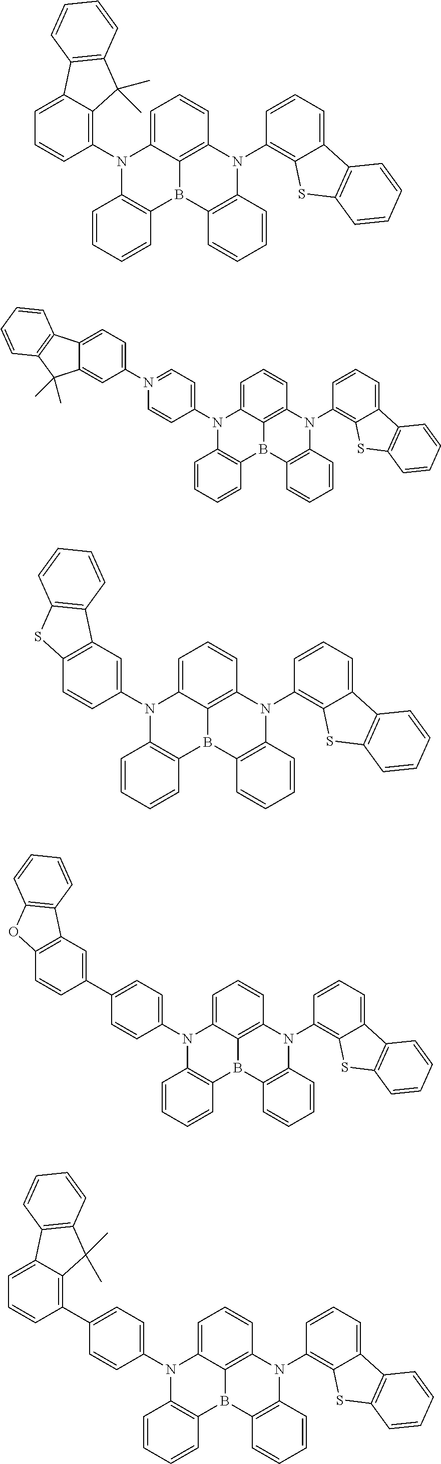

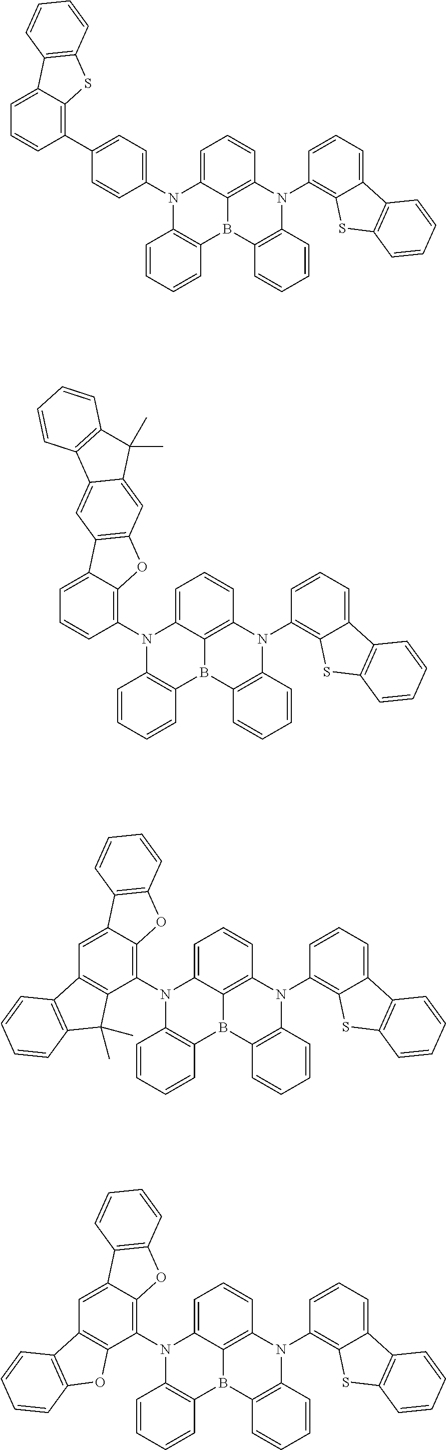 [SMILES: c1ccc2c(c1)B1c3ccccc3N(c3cccc4c3sc3ccccc34)c3cccc(c31)N2c1ccc(-c2cccc3c2sc2ccccc23)cc1 ; CC1(C)c2ccccc2-c2cc3c(cc21)oc1c(N2c4ccccc4B4c5ccccc5N(c5cccc6c5sc5ccccc56)c5cccc2c54)cccc13 ; CC1(C)c2ccccc2-c2cc3c(oc4ccccc43)c(N3c4ccccc4B4c5ccccc5N(c5cccc6c5sc5ccccc56)c5cccc3c54)c21 ; c1ccc2c(c1)B1c3ccccc3N(c3cccc4c3sc3ccccc34)c3cccc(c31)N2c1c2oc3ccccc3c2cc2c1oc1ccccc12]

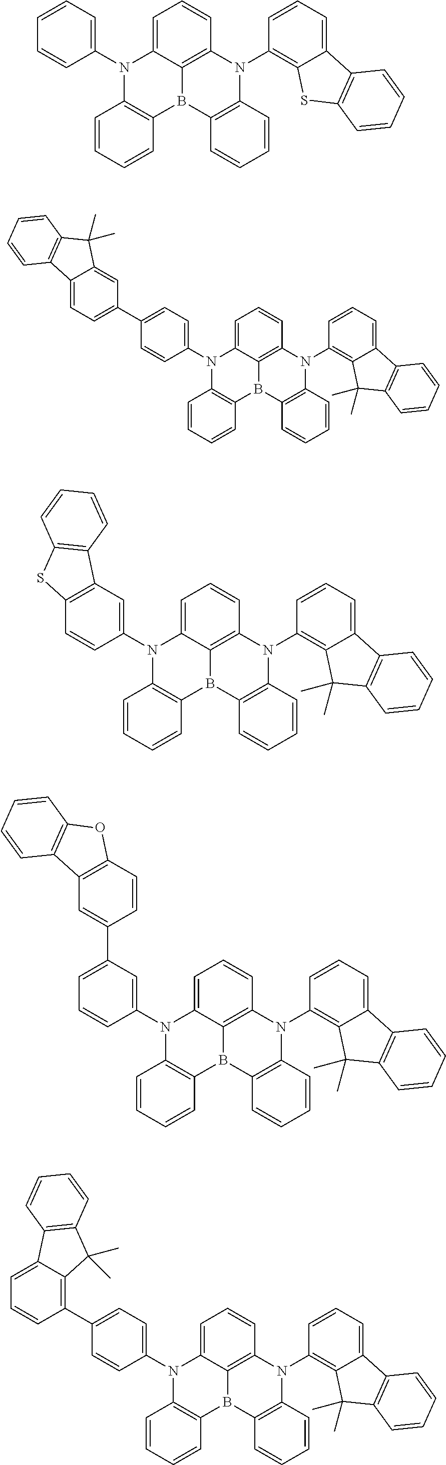 [SMILES: c1ccc(N2c3ccccc3B3c4ccccc4N(c4cccc5c4sc4ccccc45)c4cccc2c43)cc1 ; CC1(C)c2ccccc2-c2ccc(-c3ccc(N4c5ccccc5B5c6ccccc6N(c6cccc7c6C(C)(C)c6ccccc6-7)c6cccc4c65)cc3)cc21 ; CC1(C)c2ccccc2-c2cccc(N3c4ccccc4B4c5ccccc5N(c5ccc6sc7ccccc7c6c5)c5cccc3c54)c21 ; CC1(C)c2ccccc2-c2cccc(N3c4ccccc4B4c5ccccc5N(c5cccc(-c6ccc7oc8ccccc8c7c6)c5)c5cccc3c54)c21 ; CC1(C)c2ccccc2-c2cccc(-c3ccc(N4c5ccccc5B5c6ccccc6N(c6cccc7c6C(C)(C)c6ccccc6-7)c6cccc4c65)cc3)c21]

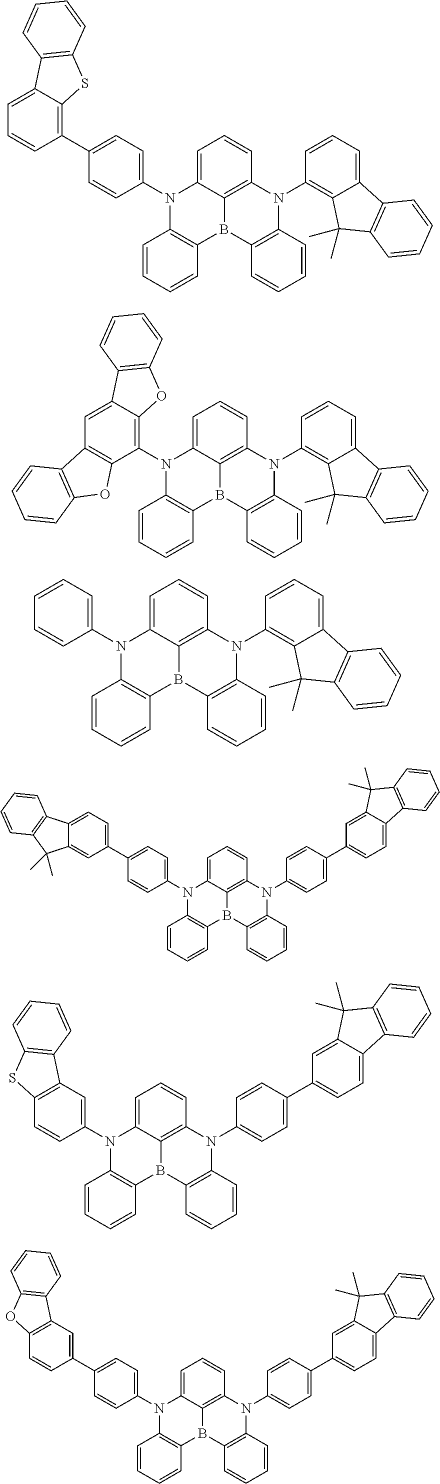

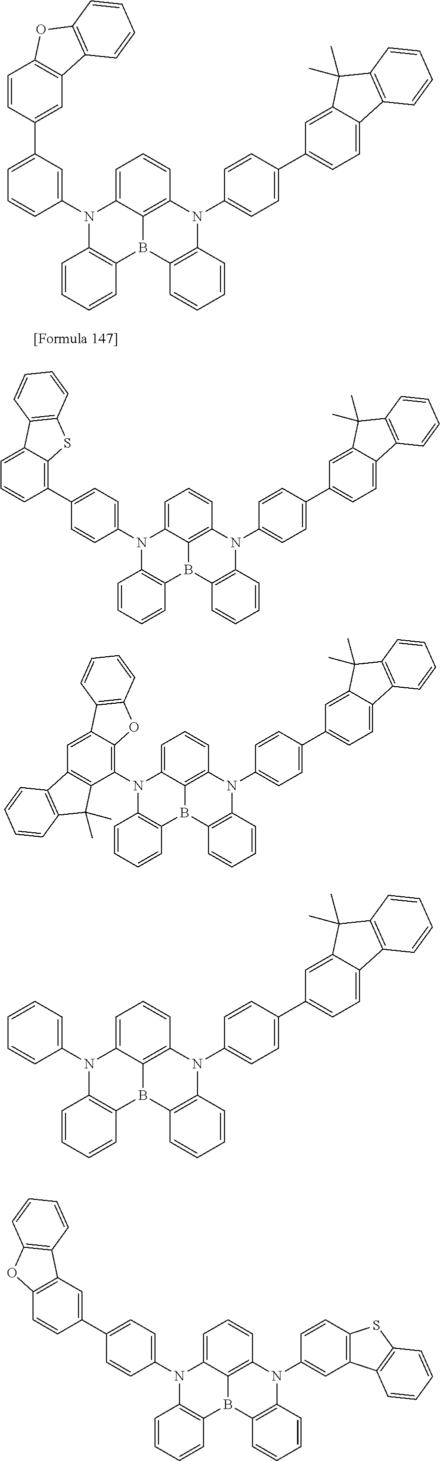

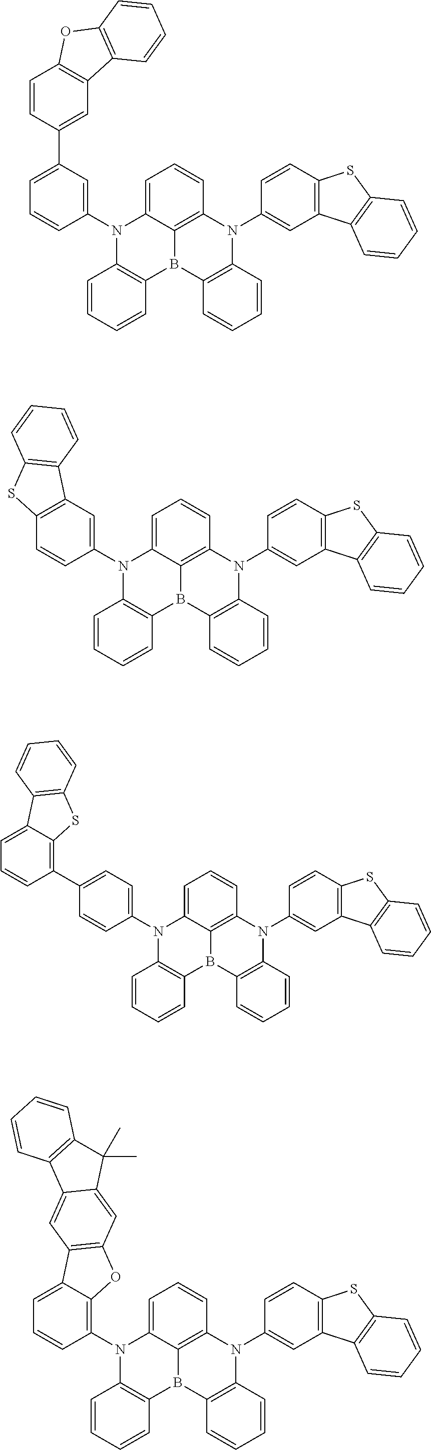 [SMILES: c1cc(-c2ccc3oc4ccccc4c3c2)cc(N2c3ccccc3B3c4ccccc4N(c4ccc5sc6ccccc6c5c4)c4cccc2c43)c1 ; c1ccc2c(c1)B1c3ccccc3N(c3ccc4sc5ccccc5c4c3)c3cccc(c31)N2c1ccc2sc3ccccc3c2c1 ; c1ccc2c(c1)B1c3ccccc3N(c3ccc4sc5ccccc5c4c3)c3cccc(c31)N2c1ccc(-c2cccc3c2sc2ccccc23)cc1 ; CC1(C)c2ccccc2-c2cc3c(cc21)oc1c(N2c4ccccc4B4c5ccccc5N(c5ccc6sc7ccccc7c6c5)c5cccc2c54)cccc13]

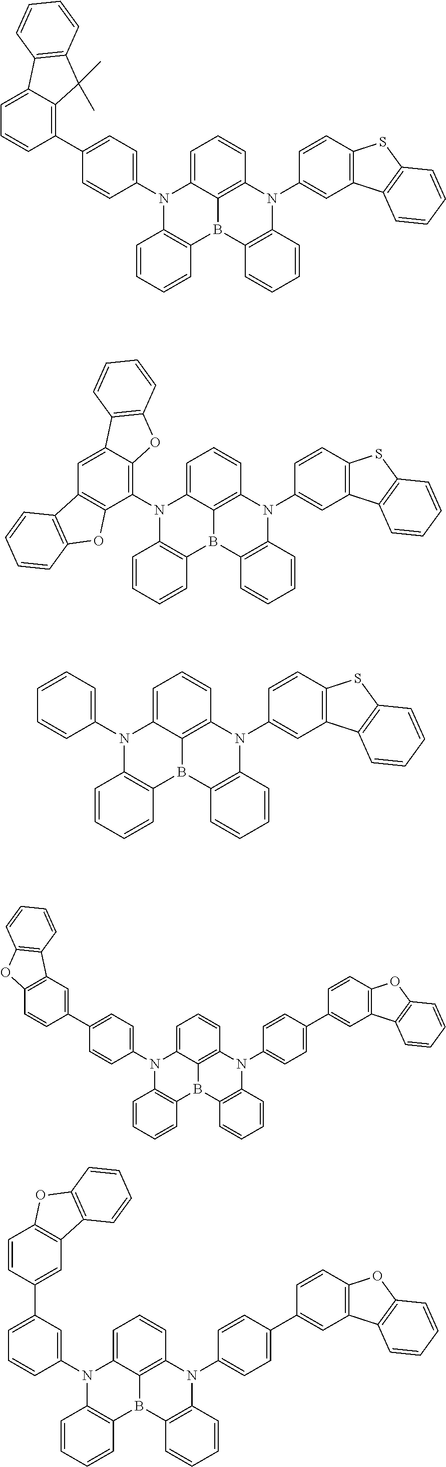 [SMILES: CC1(C)c2ccccc2-c2cccc(-c3ccc(N4c5ccccc5B5c6ccccc6N(c6ccc7sc8ccccc8c7c6)c6cccc4c65)cc3)c21 ; c1ccc2c(c1)B1c3ccccc3N(c3c4oc5ccccc5c4cc4c3oc3ccccc34)c3cccc(c31)N2c1ccc2sc3ccccc3c2c1 ; c1ccc(N2c3ccccc3B3c4ccccc4N(c4ccc5sc6ccccc6c5c4)c4cccc2c43)cc1 ; c1ccc2c(c1)B1c3ccccc3N(c3ccc(-c4ccc5oc6ccccc6c5c4)cc3)c3cccc(c31)N2c1ccc(-c2ccc3oc4ccccc4c3c2)cc1 ; c1cc(-c2ccc3oc4ccccc4c3c2)cc(N2c3ccccc3B3c4ccccc4N(c4ccc(-c5ccc6oc7ccccc7c6c5)cc4)c4cccc2c43)c1]

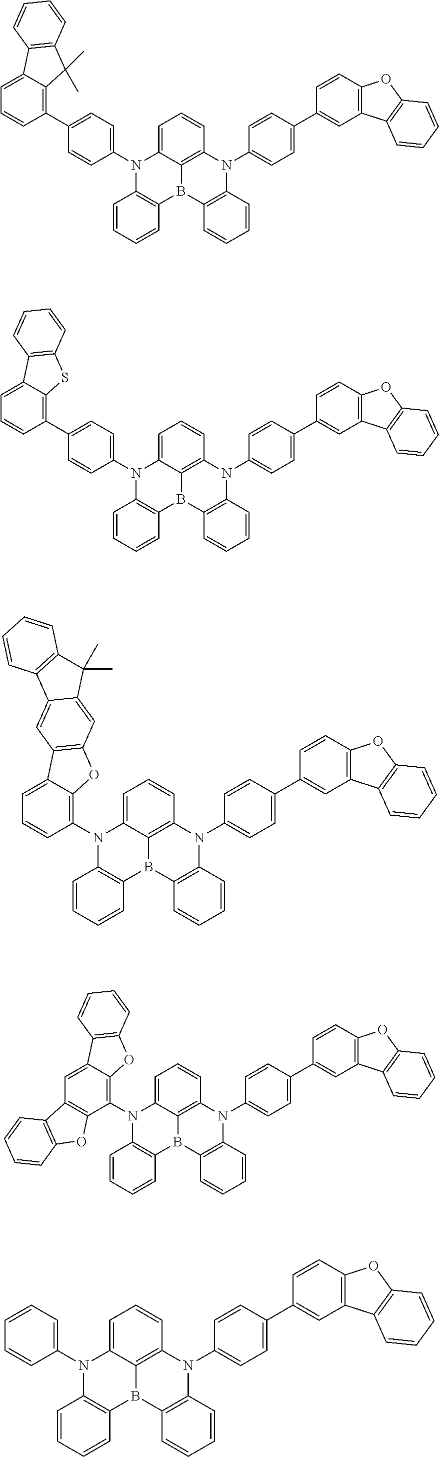 [SMILES: CC1(C)c2ccccc2-c2cccc(-c3ccc(N4c5ccccc5B5c6ccccc6N(c6ccc(-c7ccc8oc9ccccc9c8c7)cc6)c6cccc4c65)cc3)c21 ; c1ccc2c(c1)B1c3ccccc3N(c3ccc(-c4cccc5c4sc4ccccc45)cc3)c3cccc(c31)N2c1ccc(-c2ccc3oc4ccccc4c3c2)cc1 ; CC1(C)c2ccccc2-c2cc3c(cc21)oc1c(N2c4ccccc4B4c5ccccc5N(c5ccc(-c6ccc7oc8ccccc8c7c6)cc5)c5cccc2c54)cccc13 ; c1ccc2c(c1)B1c3ccccc3N(c3c4oc5ccccc5c4cc4c3oc3ccccc34)c3cccc(c31)N2c1ccc(-c2ccc3oc4ccccc4c3c2)cc1 ; c1ccc(N2c3ccccc3B3c4ccccc4N(c4ccc(-c5ccc6oc7ccccc7c6c5)cc4)c4cccc2c43)cc1]

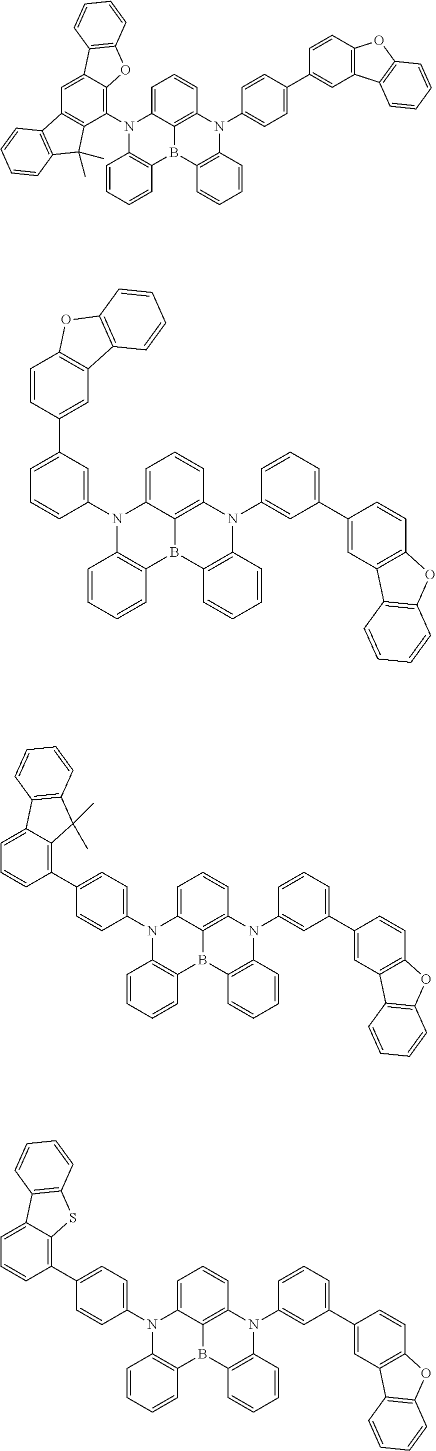 [SMILES: CC1(C)c2ccccc2-c2cc3c(oc4ccccc43)c(N3c4ccccc4B4c5ccccc5N(c5ccc(-c6ccc7oc8ccccc8c7c6)cc5)c5cccc3c54)c21 ; c1cc(-c2ccc3oc4ccccc4c3c2)cc(N2c3ccccc3B3c4ccccc4N(c4cccc(-c5ccc6oc7ccccc7c6c5)c4)c4cccc2c43)c1 ; CC1(C)c2ccccc2-c2cccc(-c3ccc(N4c5ccccc5B5c6ccccc6N(c6cccc(-c7ccc8oc9ccccc9c8c7)c6)c6cccc4c65)cc3)c21 ; c1cc(-c2ccc3oc4ccccc4c3c2)cc(N2c3ccccc3B3c4ccccc4N(c4ccc(-c5cccc6c5sc5ccccc56)cc4)c4cccc2c43)c1]

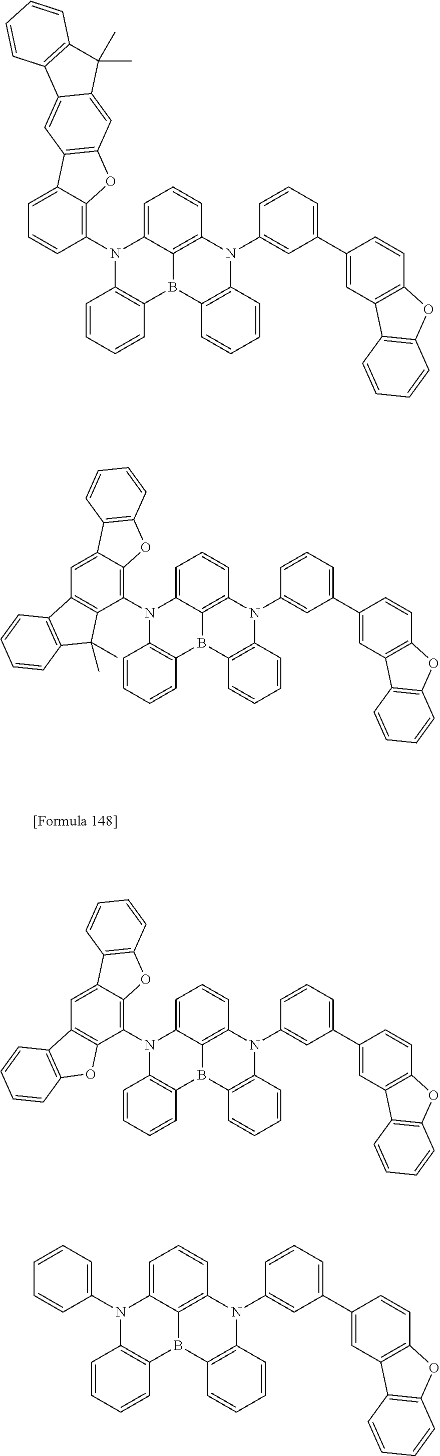 [SMILES: CC1(C)c2ccccc2-c2cc3c(cc21)oc1c(N2c4ccccc4B4c5ccccc5N(c5cccc(-c6ccc7oc8ccccc8c7c6)c5)c5cccc2c54)cccc13 ; CC1(C)c2ccccc2-c2cc3c(oc4ccccc43)c(N3c4ccccc4B4c5ccccc5N(c5cccc(-c6ccc7oc8ccccc8c7c6)c5)c5cccc3c54)c21 ; c1cc(-c2ccc3oc4ccccc4c3c2)cc(N2c3ccccc3B3c4ccccc4N(c4c5oc6ccccc6c5cc5c4oc4ccccc45)c4cccc2c43)c1 ; c1ccc(N2c3ccccc3B3c4ccccc4N(c4cccc(-c5ccc6oc7ccccc7c6c5)c4)c4cccc2c43)cc1]

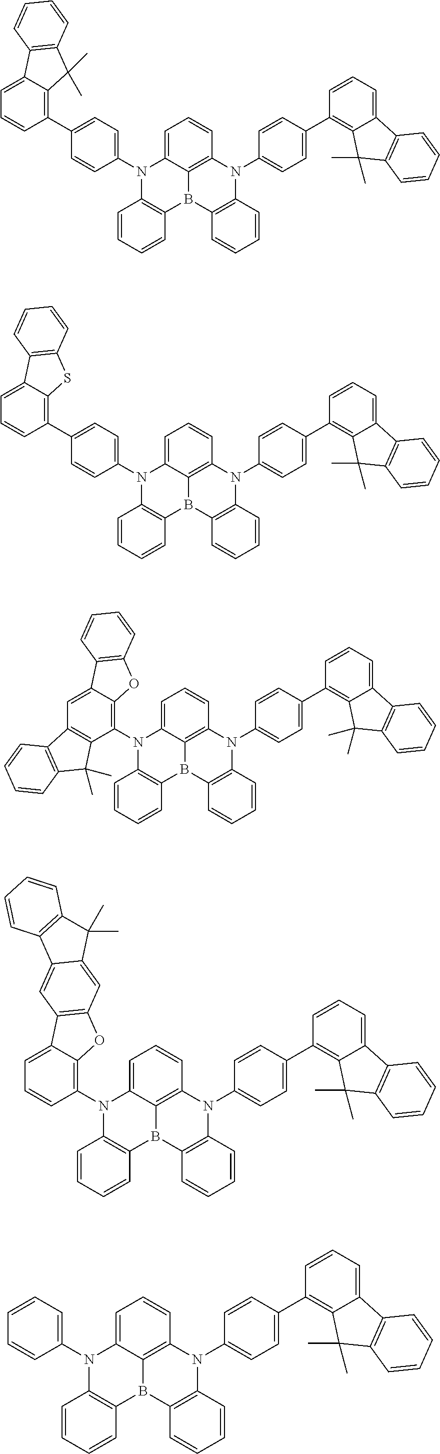

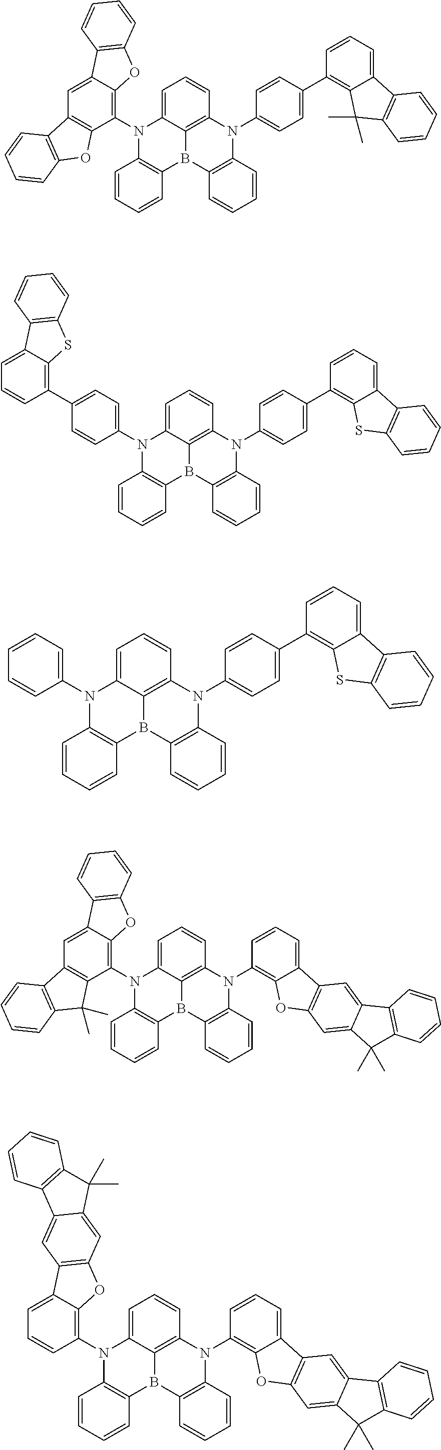 [SMILES: CC1(C)c2ccccc2-c2cccc(-c3ccc(N4c5ccccc5B5c6ccccc6N(c6c7oc8ccccc8c7cc7c6oc6ccccc67)c6cccc4c65)cc3)c21 ; c1ccc2c(c1)B1c3ccccc3N(c3ccc(-c4cccc5c4sc4ccccc45)cc3)c3cccc(c31)N2c1ccc(-c2cccc3c2sc2ccccc23)cc1 ; c1ccc(N2c3ccccc3B3c4ccccc4N(c4ccc(-c5cccc6c5sc5ccccc56)cc4)c4cccc2c43)cc1 ; CC1(C)c2ccccc2-c2cc3c(cc21)oc1c(N2c4ccccc4B4c5ccccc5N(c5c6c(cc7c5oc5ccccc57)-c5ccccc5C6(C)C)c5cccc2c54)cccc13 ; CC1(C)c2ccccc2-c2cc3c(cc21)oc1c(N2c4ccccc4B4c5ccccc5N(c5cccc6c5oc5cc7c(cc56)-c5ccccc5C7(C)C)c5cccc2c54)cccc13]

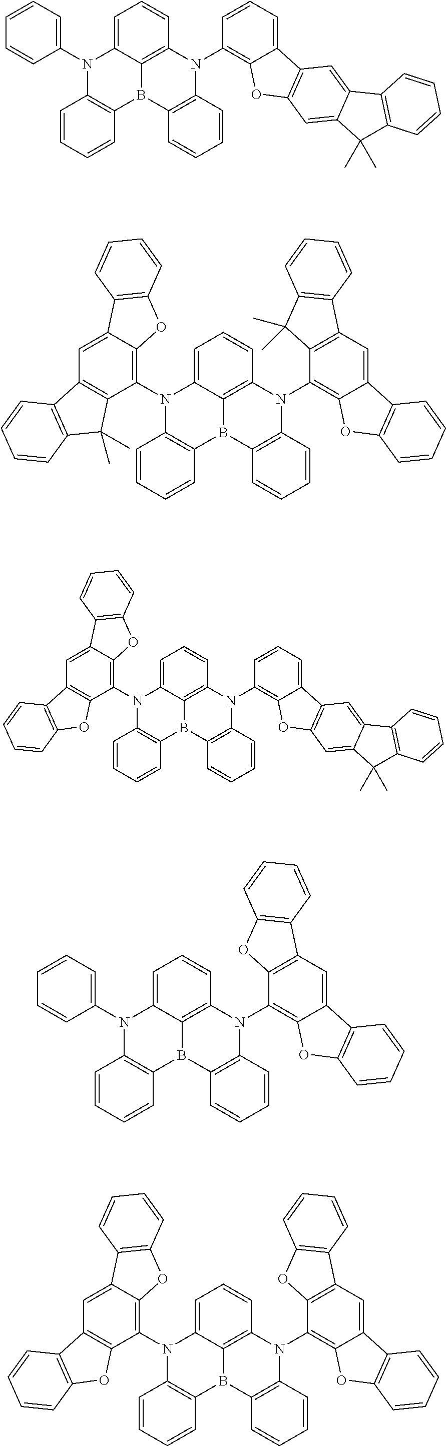 [SMILES: CC1(C)c2ccccc2-c2cc3c(cc21)oc1c(N2c4ccccc4B4c5ccccc5N(c5ccccc5)c5cccc2c54)cccc13 ; CC1(C)c2ccccc2-c2cc3c(oc4ccccc43)c(N3c4ccccc4B4c5ccccc5N(c5c6c(cc7c5oc5ccccc57)-c5ccccc5C6(C)C)c5cccc3c54)c21 ; CC1(C)c2ccccc2-c2cc3c(cc21)oc1c(N2c4ccccc4B4c5ccccc5N(c5c6oc7ccccc7c6cc6c5oc5ccccc56)c5cccc2c54)cccc13 ; c1ccc(N2c3ccccc3B3c4ccccc4N(c4c5oc6ccccc6c5cc5c4oc4ccccc45)c4cccc2c43)cc1 ; c1ccc2c(c1)B1c3ccccc3N(c3c4oc5ccccc5c4cc4c3oc3ccccc34)c3cccc(c31)N2c1c2oc3ccccc3c2cc2c1oc1ccccc12]

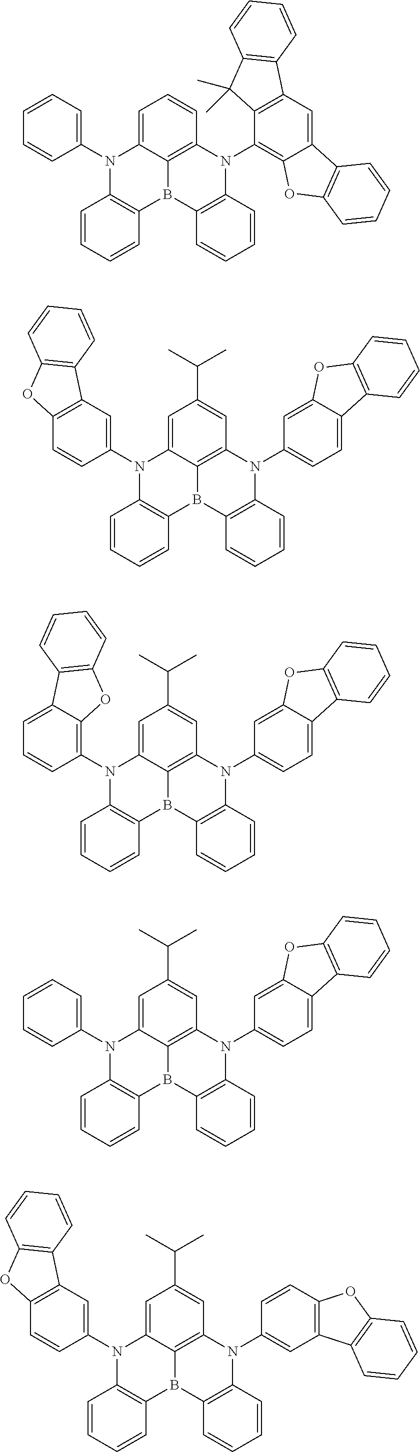 [SMILES: CC1(C)c2ccccc2-c2cc3c(oc4ccccc43)c(N3c4ccccc4B4c5ccccc5N(c5ccccc5)c5cccc3c54)c21 ; CC(C)c1cc2c3c(c1)N(c1ccc4oc5ccccc5c4c1)c1ccccc1B3c1ccccc1N2c1ccc2c(c1)oc1ccccc12 ; CC(C)c1cc2c3c(c1)N(c1cccc4c1oc1ccccc14)c1ccccc1B3c1ccccc1N2c1ccc2c(c1)oc1ccccc12 ; CC(C)c1cc2c3c(c1)N(c1ccc4c(c1)oc1ccccc14)c1ccccc1B3c1ccccc1N2c1ccccc1 ; CC(C)c1cc2c3c(c1)N(c1ccc4oc5ccccc5c4c1)c1ccccc1B3c1ccccc1N2c1ccc2oc3ccccc3c2c1]

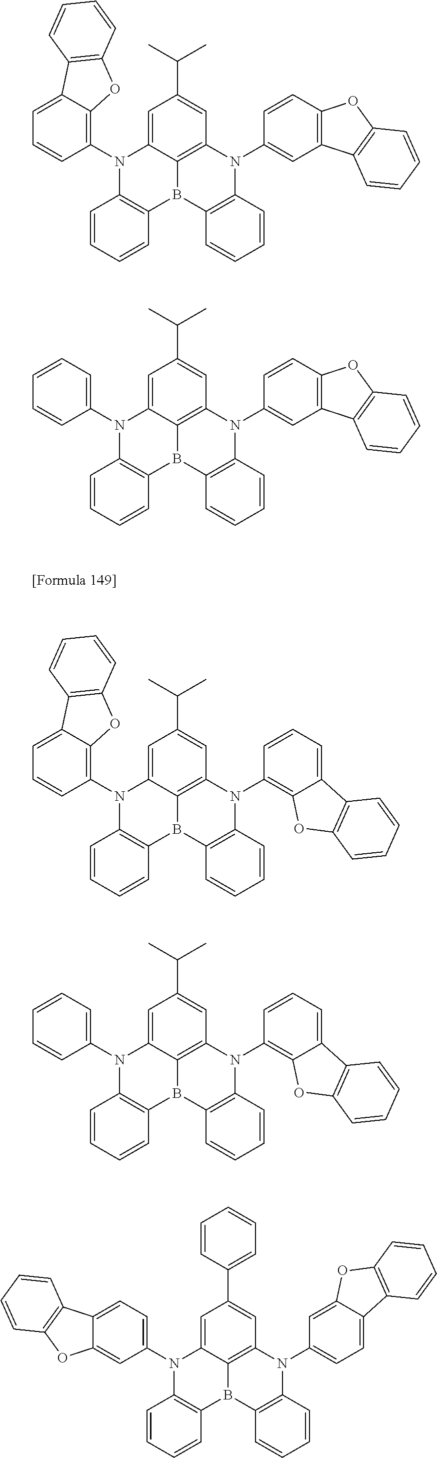 [SMILES: CC(C)c1cc2c3c(c1)N(c1cccc4c1oc1ccccc14)c1ccccc1B3c1ccccc1N2c1ccc2oc3ccccc3c2c1 ; CC(C)c1cc2c3c(c1)N(c1ccc4oc5ccccc5c4c1)c1ccccc1B3c1ccccc1N2c1ccccc1 ; CC(C)c1cc2c3c(c1)N(c1cccc4c1oc1ccccc14)c1ccccc1B3c1ccccc1N2c1cccc2c1oc1ccccc12 ; CC(C)c1cc2c3c(c1)N(c1cccc4c1oc1ccccc14)c1ccccc1B3c1ccccc1N2c1ccccc1 ; c1ccc(-c2cc3c4c(c2)N(c2ccc5c(c2)oc2ccccc25)c2ccccc2B4c2ccccc2N3c2ccc3c(c2)oc2ccccc23)cc1]

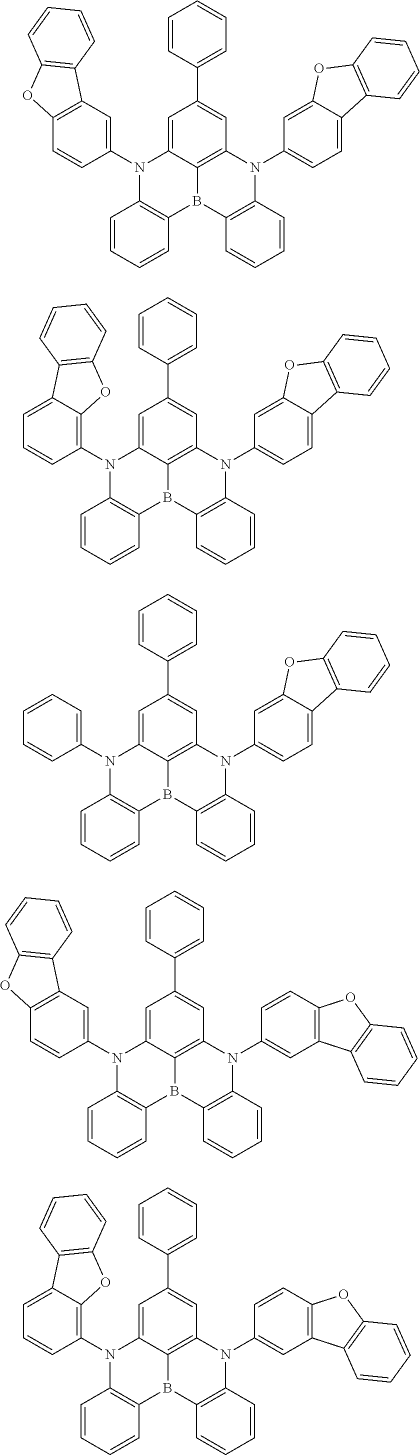

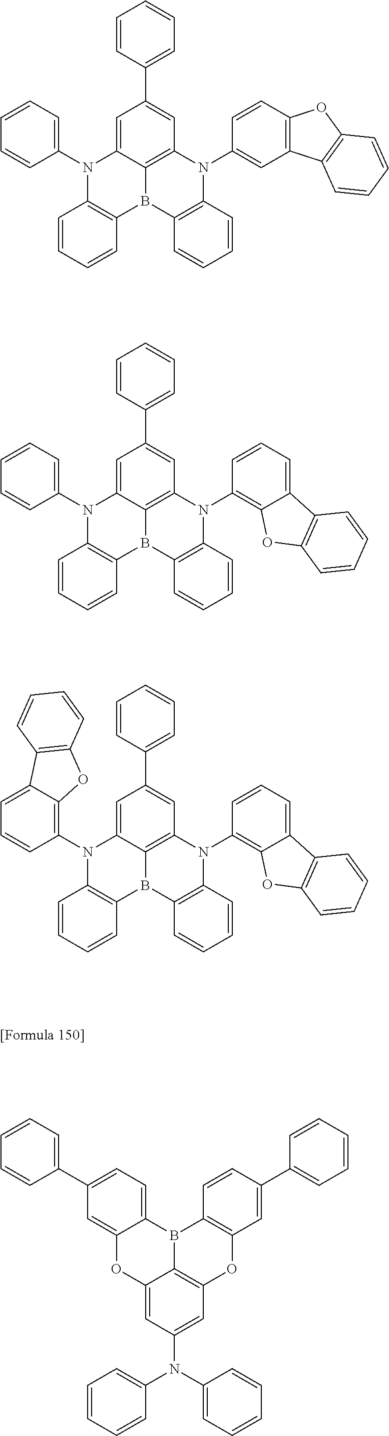 [SMILES: c1ccc(-c2cc3c4c(c2)N(c2ccc5oc6ccccc6c5c2)c2ccccc2B4c2ccccc2N3c2ccccc2)cc1 ; c1ccc(-c2cc3c4c(c2)N(c2cccc5c2oc2ccccc25)c2ccccc2B4c2ccccc2N3c2ccccc2)cc1 ; c1ccc(-c2cc3c4c(c2)N(c2cccc5c2oc2ccccc25)c2ccccc2B4c2ccccc2N3c2cccc3c2oc2ccccc23)cc1 ; c1ccc(-c2ccc3c(c2)Oc2cc(N(c4ccccc4)c4ccccc4)cc4c2B3c2ccc(-c3ccccc3)cc2O4)cc1]

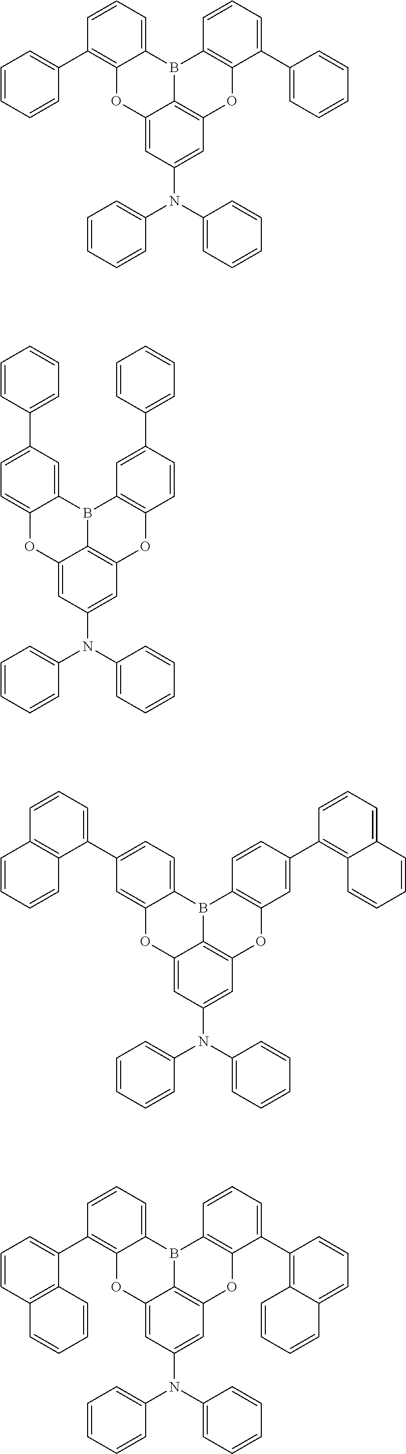 [SMILES: c1ccc(-c2cccc3c2Oc2cc(N(c4ccccc4)c4ccccc4)cc4c2B3c2cccc(-c3ccccc3)c2O4)cc1 ; c1ccc(-c2ccc3c(c2)B2c4cc(-c5ccccc5)ccc4Oc4cc(N(c5ccccc5)c5ccccc5)cc(c42)O3)cc1 ; c1ccc(N(c2ccccc2)c2cc3c4c(c2)Oc2cc(-c5cccc6ccccc56)ccc2B4c2ccc(-c4cccc5ccccc45)cc2O3)cc1 ; c1ccc(N(c2ccccc2)c2cc3c4c(c2)Oc2c(cccc2-c2cccc5ccccc25)B4c2cccc(-c4cccc5ccccc45)c2O3)cc1]

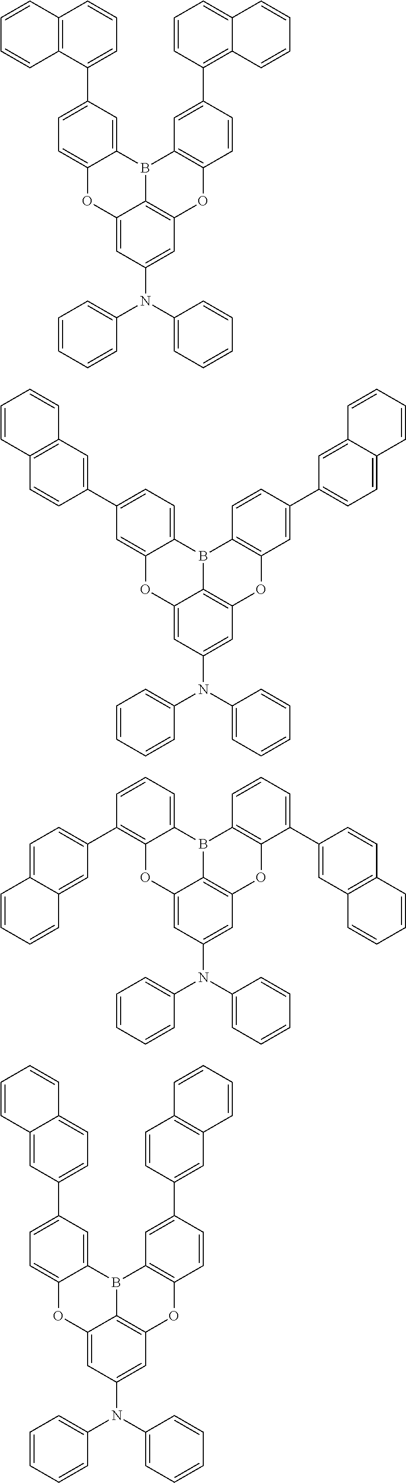

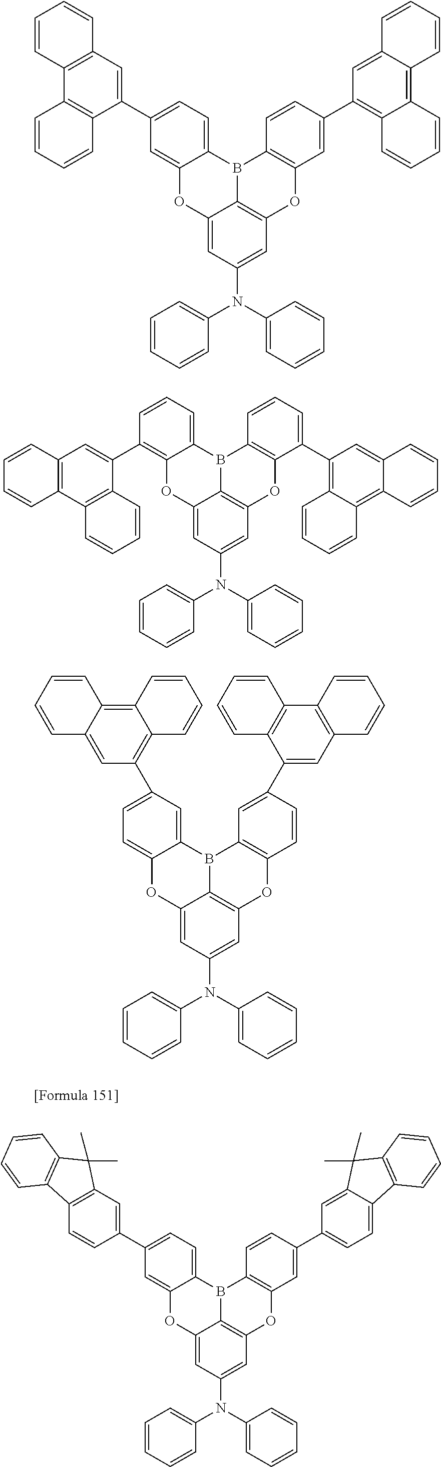

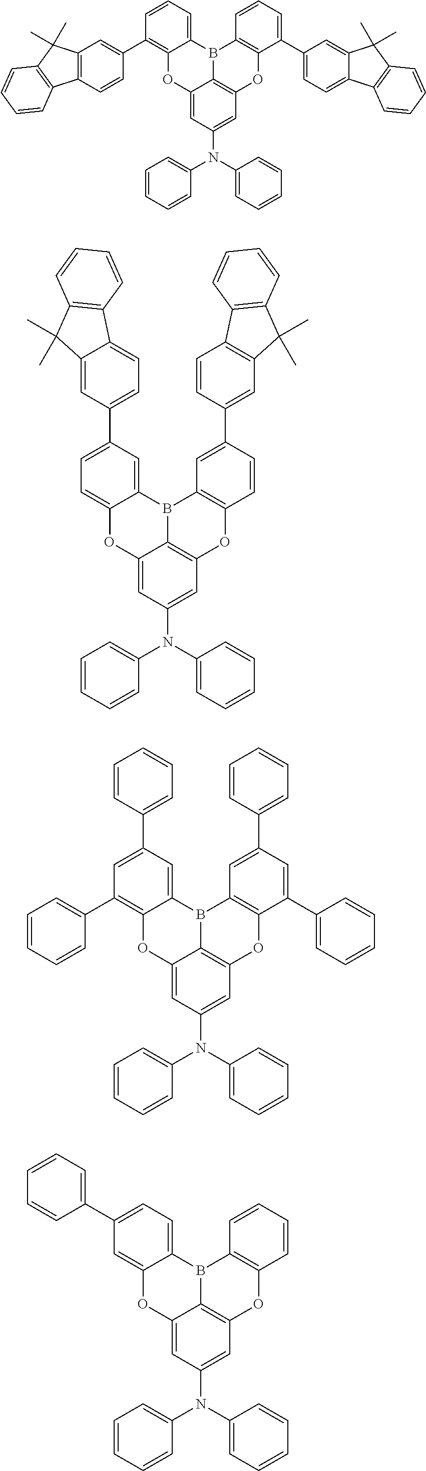

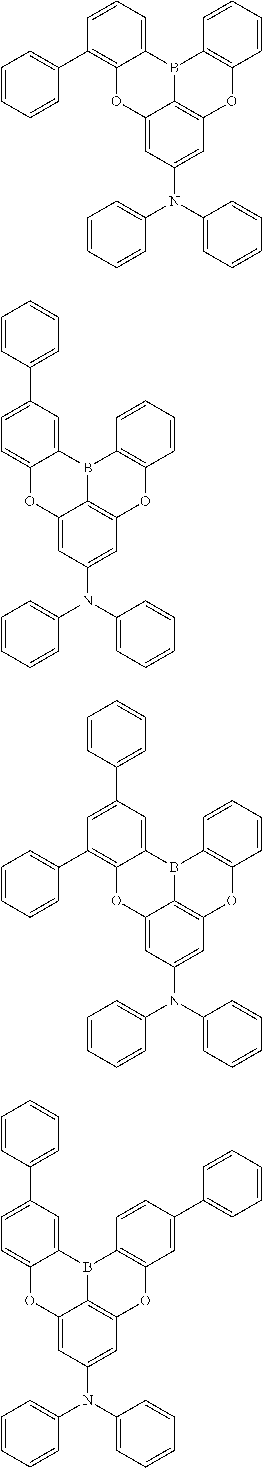

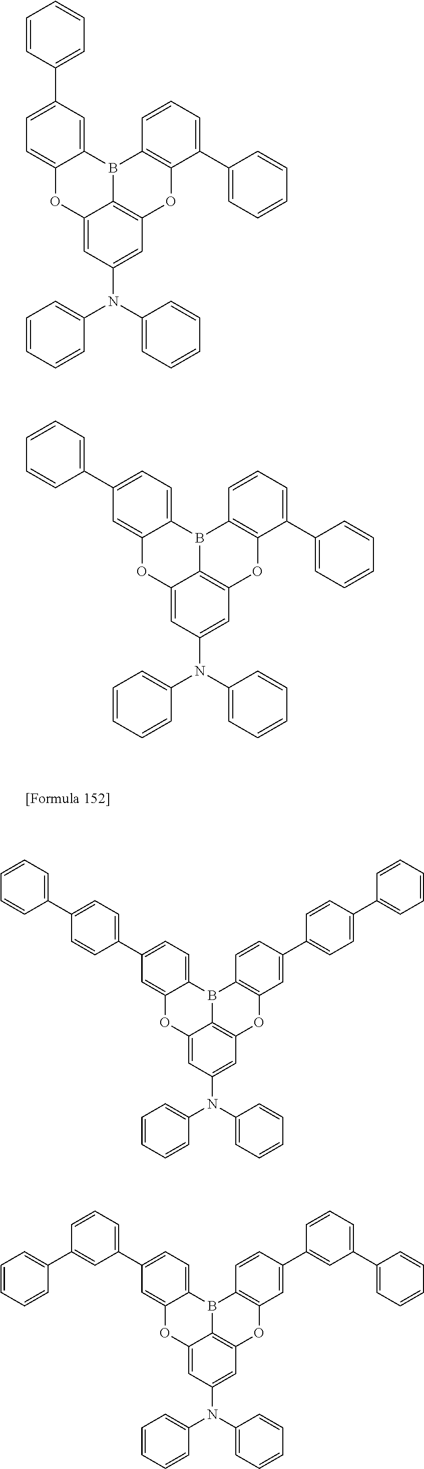 [SMILES: c1ccc(-c2ccc3c(c2)B2c4cccc(-c5ccccc5)c4Oc4cc(N(c5ccccc5)c5ccccc5)cc(c42)O3)cc1 ; c1ccc(-c2ccc3c(c2)Oc2cc(N(c4ccccc4)c4ccccc4)cc4c2B3c2cccc(-c3ccccc3)c2O4)cc1 ; c1ccc(-c2ccc(-c3ccc4c(c3)Oc3cc(N(c5ccccc5)c5ccccc5)cc5c3B4c3ccc(-c4ccc(-c6ccccc6)cc4)cc3O5)cc2)cc1 ; c1ccc(-c2cccc(-c3ccc4c(c3)Oc3cc(N(c5ccccc5)c5ccccc5)cc5c3B4c3ccc(-c4cccc(-c6ccccc6)c4)cc3O5)c2)cc1]

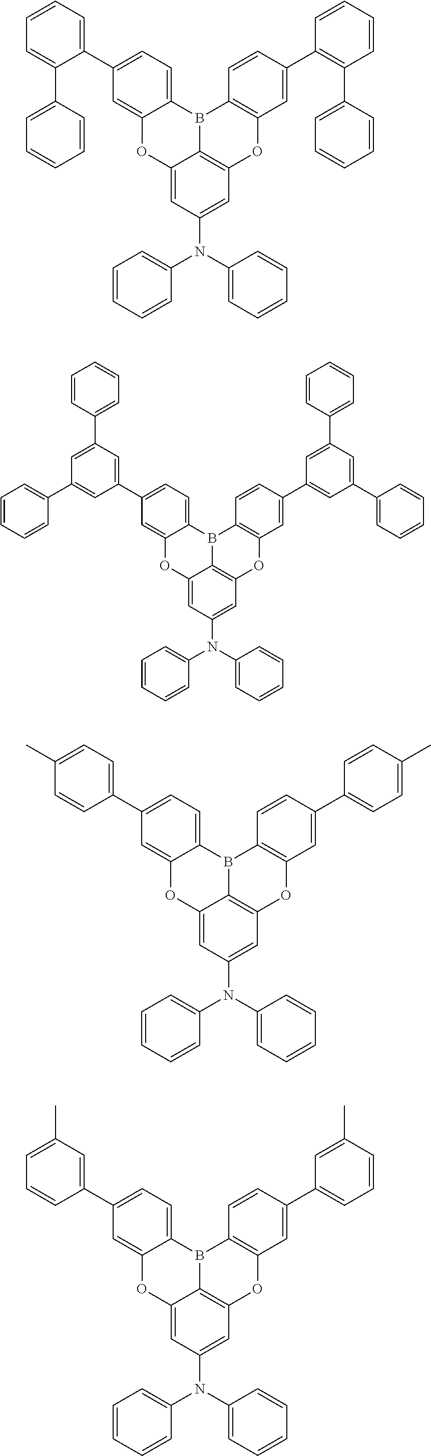

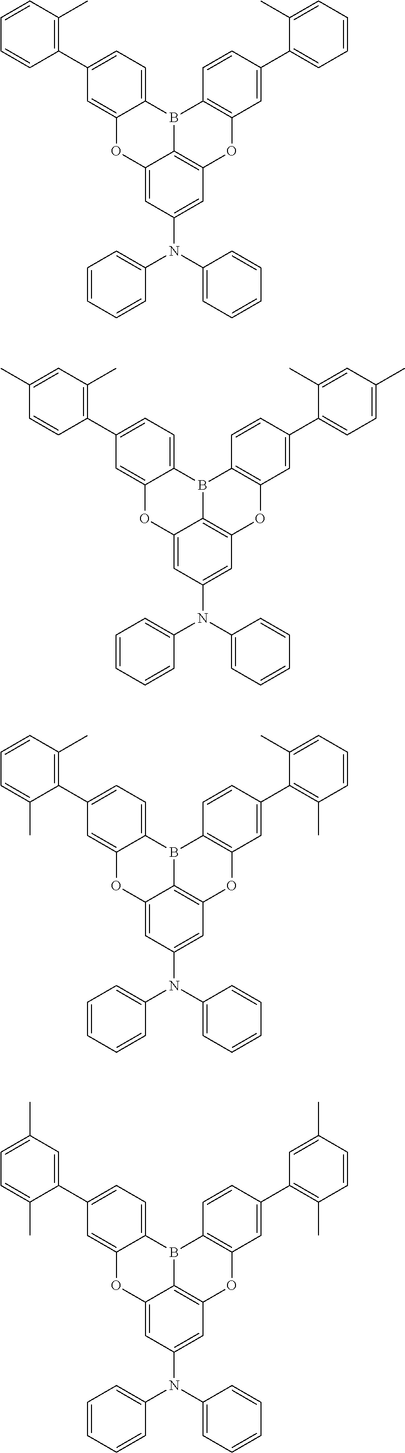

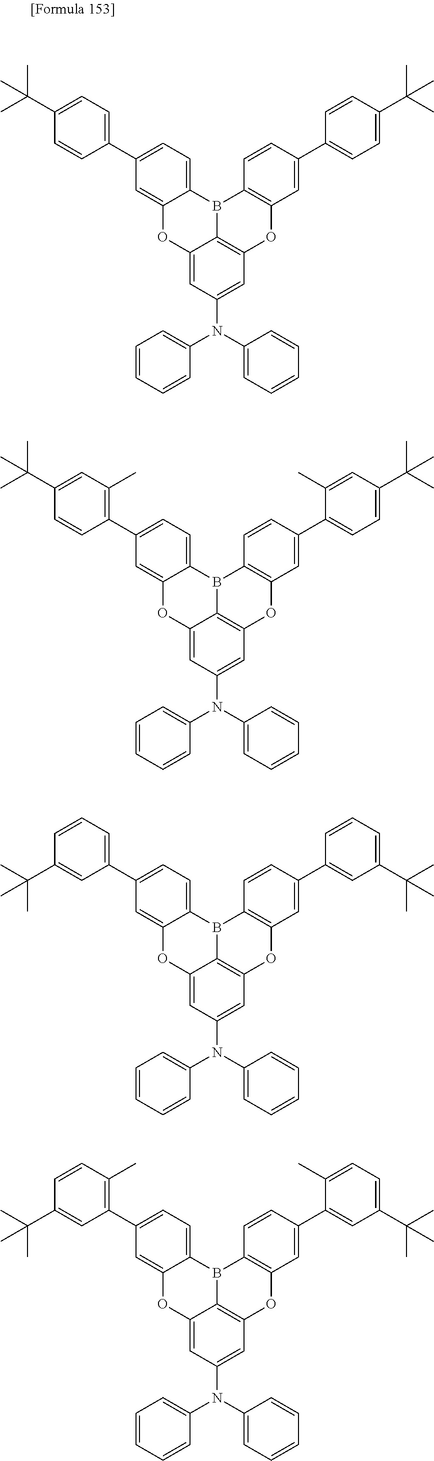

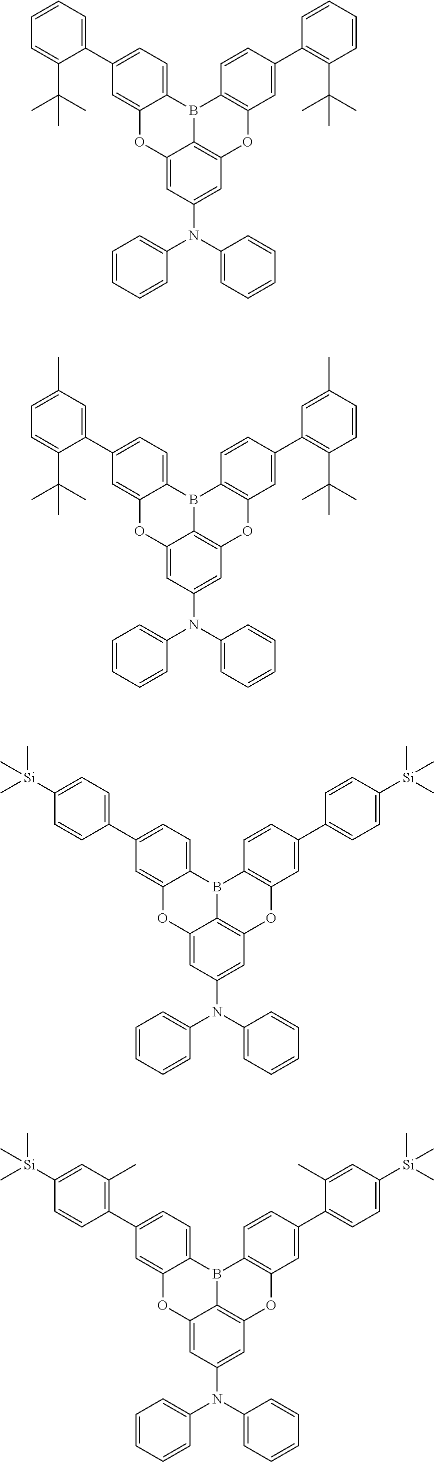

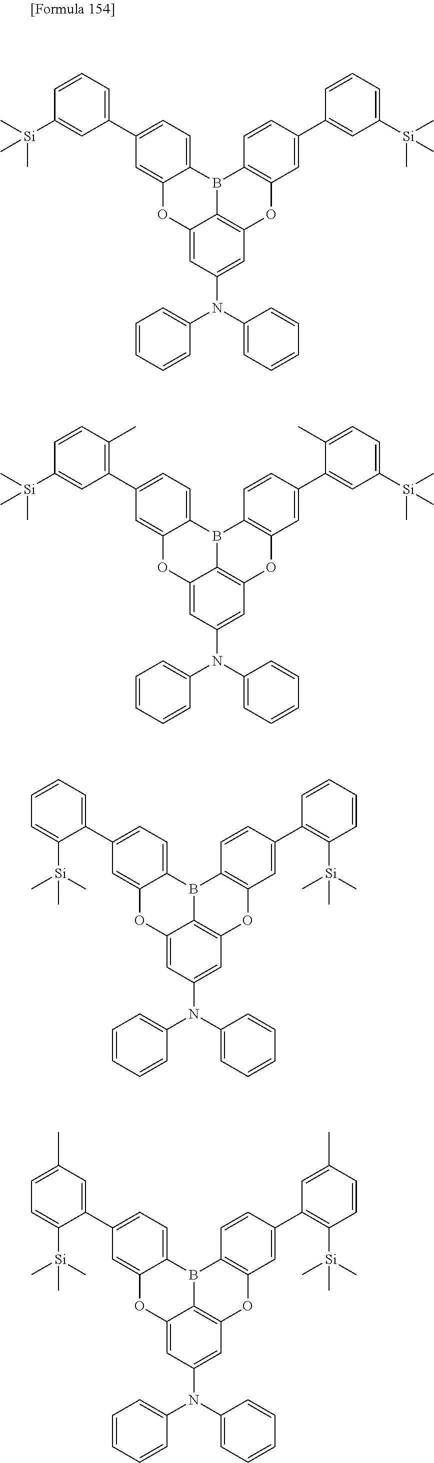

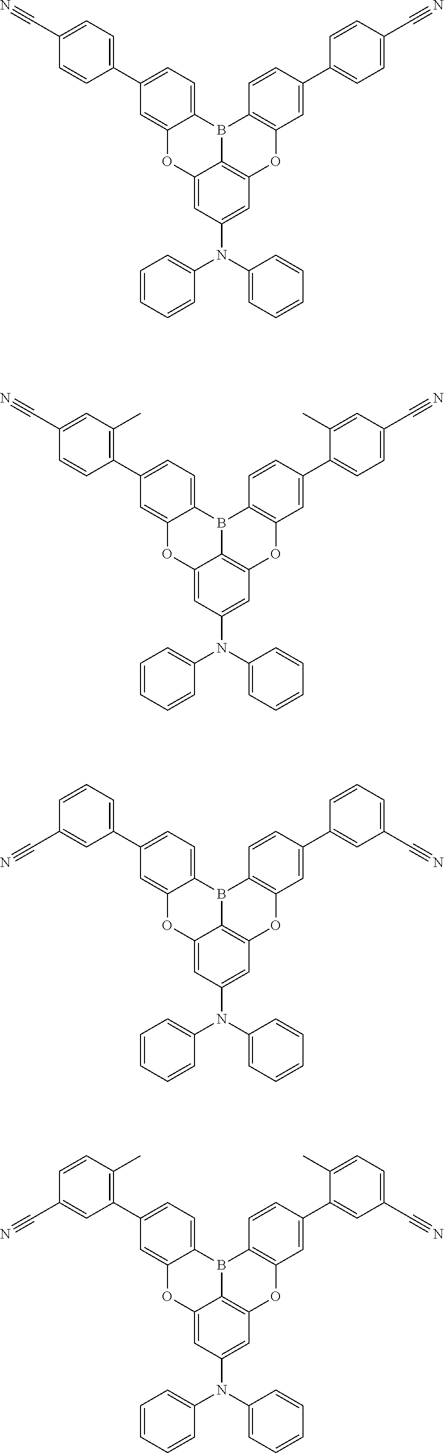 [SMILES: N#Cc1ccc(-c2ccc3c(c2)Oc2cc(N(c4ccccc4)c4ccccc4)cc4c2B3c2ccc(-c3ccc(C#N)cc3)cc2O4)cc1 ; Cc1cc(C#N)ccc1-c1ccc2c(c1)Oc1cc(N(c3ccccc3)c3ccccc3)cc3c1B2c1ccc(-c2ccc(C#N)cc2C)cc1O3 ; N#Cc1cccc(-c2ccc3c(c2)Oc2cc(N(c4ccccc4)c4ccccc4)cc4c2B3c2ccc(-c3cccc(C#N)c3)cc2O4)c1 ; Cc1ccc(C#N)cc1-c1ccc2c(c1)Oc1cc(N(c3ccccc3)c3ccccc3)cc3c1B2c1ccc(-c2cc(C#N)ccc2C)cc1O3]

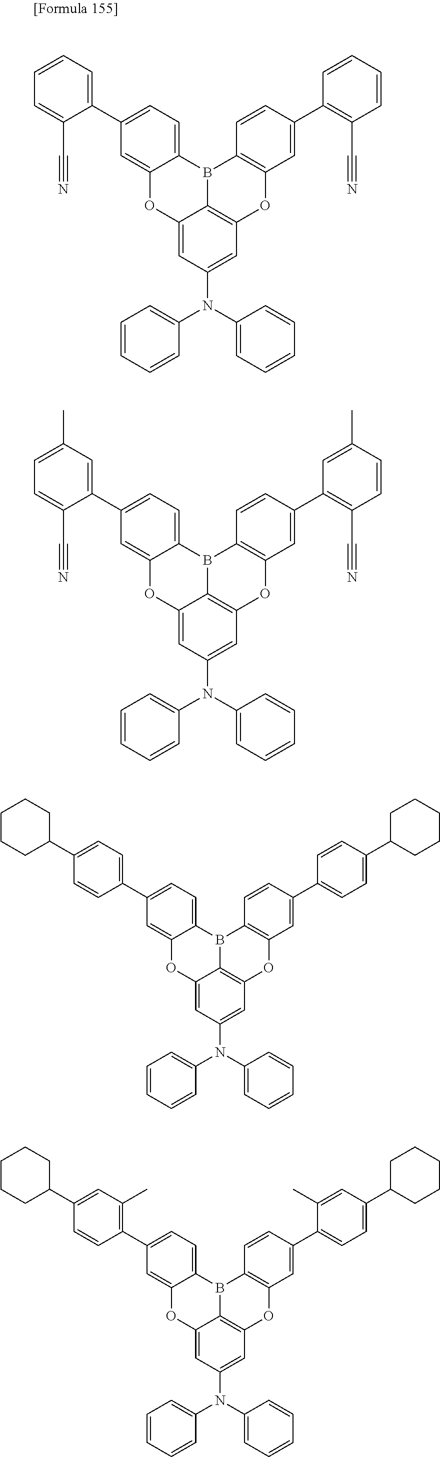 [SMILES: N#Cc1ccccc1-c1ccc2c(c1)Oc1cc(N(c3ccccc3)c3ccccc3)cc3c1B2c1ccc(-c2ccccc2C#N)cc1O3 ; Cc1ccc(C#N)c(-c2ccc3c(c2)Oc2cc(N(c4ccccc4)c4ccccc4)cc4c2B3c2ccc(-c3cc(C)ccc3C#N)cc2O4)c1 ; c1ccc(N(c2ccccc2)c2cc3c4c(c2)Oc2cc(-c5ccc(C6CCCCC6)cc5)ccc2B4c2ccc(-c4ccc(C5CCCCC5)cc4)cc2O3)cc1 ; Cc1cc(C2CCCCC2)ccc1-c1ccc2c(c1)Oc1cc(N(c3ccccc3)c3ccccc3)cc3c1B2c1ccc(-c2ccc(C4CCCCC4)cc2C)cc1O3]

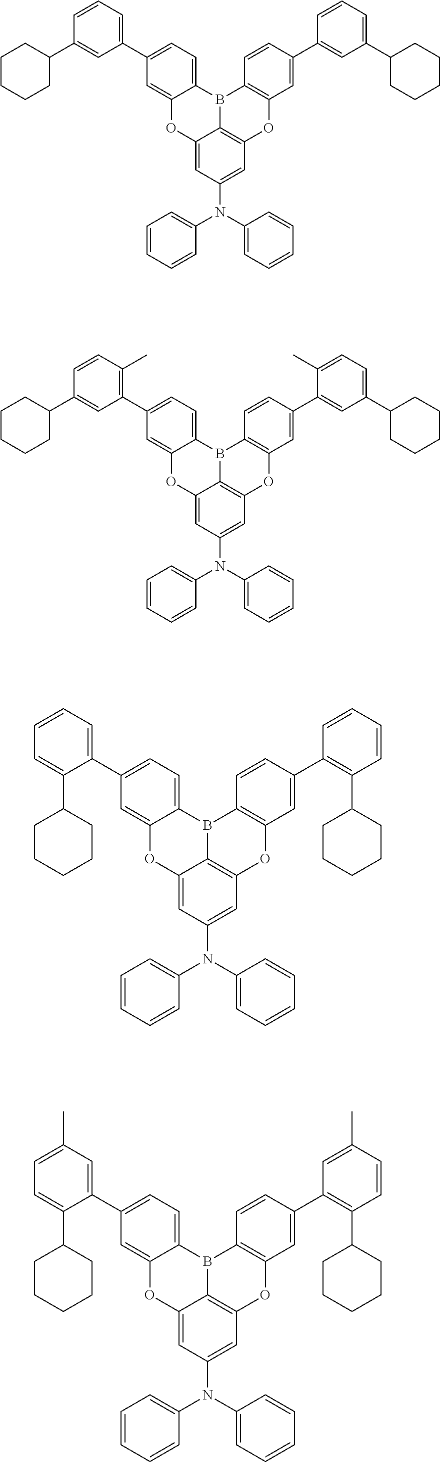 [SMILES: c1ccc(N(c2ccccc2)c2cc3c4c(c2)Oc2cc(-c5cccc(C6CCCCC6)c5)ccc2B4c2ccc(-c4cccc(C5CCCCC5)c4)cc2O3)cc1 ; Cc1ccc(C2CCCCC2)cc1-c1ccc2c(c1)Oc1cc(N(c3ccccc3)c3ccccc3)cc3c1B2c1ccc(-c2cc(C4CCCCC4)ccc2C)cc1O3 ; c1ccc(N(c2ccccc2)c2cc3c4c(c2)Oc2cc(-c5ccccc5C5CCCCC5)ccc2B4c2ccc(-c4ccccc4C4CCCCC4)cc2O3)cc1 ; Cc1ccc(C2CCCCC2)c(-c2ccc3c(c2)Oc2cc(N(c4ccccc4)c4ccccc4)cc4c2B3c2ccc(-c3cc(C)ccc3C3CCCCC3)cc2O4)c1]

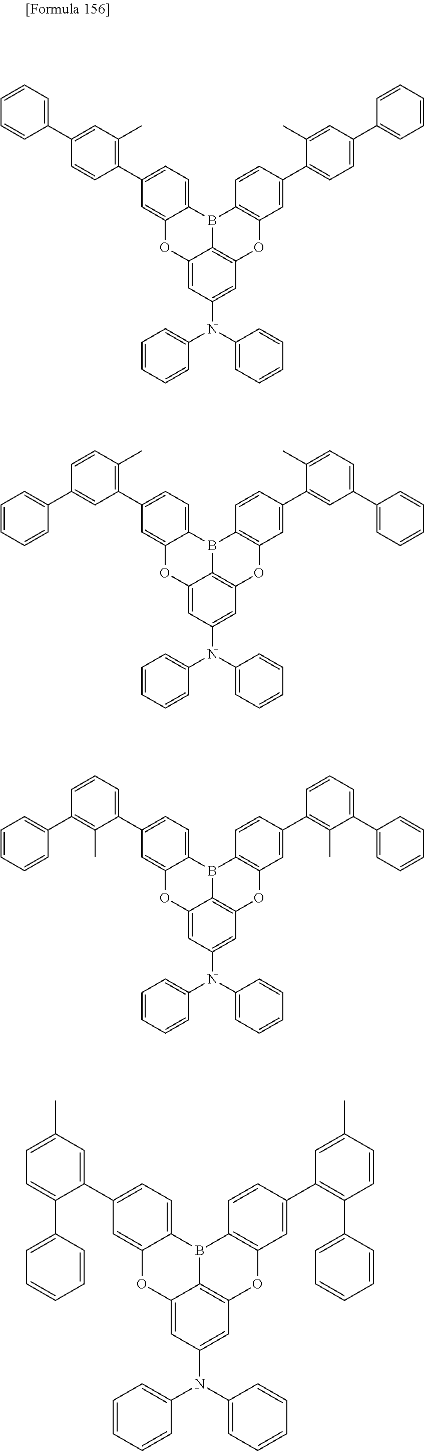 [SMILES: Cc1cc(-c2ccccc2)ccc1-c1ccc2c(c1)Oc1cc(N(c3ccccc3)c3ccccc3)cc3c1B2c1ccc(-c2ccc(-c4ccccc4)cc2C)cc1O3 ; Cc1ccc(-c2ccccc2)cc1-c1ccc2c(c1)Oc1cc(N(c3ccccc3)c3ccccc3)cc3c1B2c1ccc(-c2cc(-c4ccccc4)ccc2C)cc1O3 ; Cc1c(-c2ccccc2)cccc1-c1ccc2c(c1)Oc1cc(N(c3ccccc3)c3ccccc3)cc3c1B2c1ccc(-c2cccc(-c4ccccc4)c2C)cc1O3 ; Cc1ccc(-c2ccccc2)c(-c2ccc3c(c2)Oc2cc(N(c4ccccc4)c4ccccc4)cc4c2B3c2ccc(-c3cc(C)ccc3-c3ccccc3)cc2O4)c1]

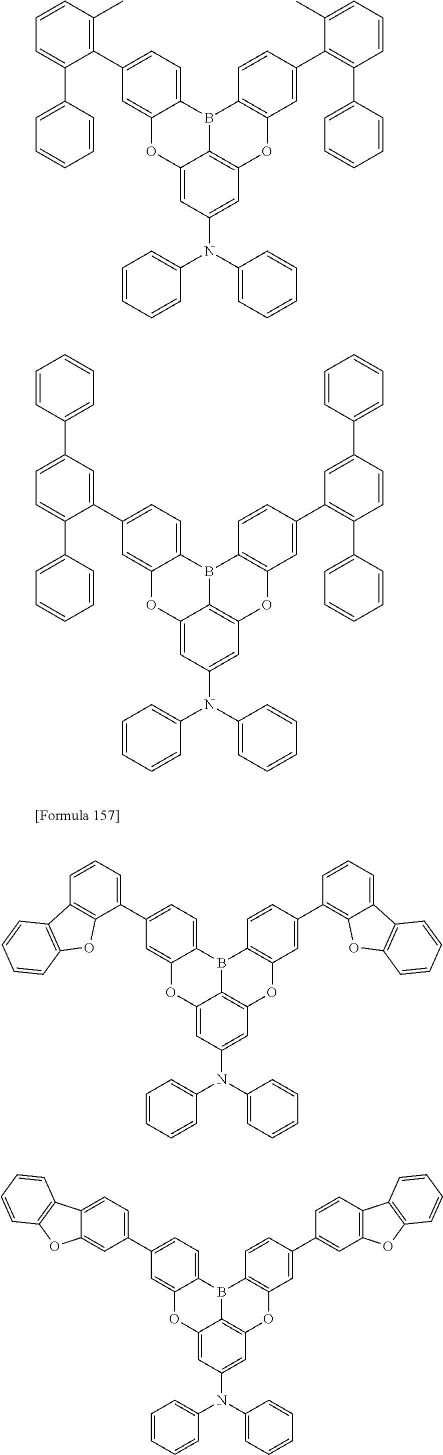 [SMILES: Cc1cccc(-c2ccccc2)c1-c1ccc2c(c1)Oc1cc(N(c3ccccc3)c3ccccc3)cc3c1B2c1ccc(-c2c(C)cccc2-c2ccccc2)cc1O3 ; c1ccc(-c2ccc(-c3ccccc3)c(-c3ccc4c(c3)Oc3cc(N(c5ccccc5)c5ccccc5)cc5c3B4c3ccc(-c4cc(-c6ccccc6)ccc4-c4ccccc4)cc3O5)c2)cc1 ; c1ccc(N(c2ccccc2)c2cc3c4c(c2)Oc2cc(-c5cccc6c5oc5ccccc56)ccc2B4c2ccc(-c4cccc5c4oc4ccccc45)cc2O3)cc1 ; c1ccc(N(c2ccccc2)c2cc3c4c(c2)Oc2cc(-c5ccc6c(c5)oc5ccccc56)ccc2B4c2ccc(-c4ccc5c(c4)oc4ccccc45)cc2O3)cc1]

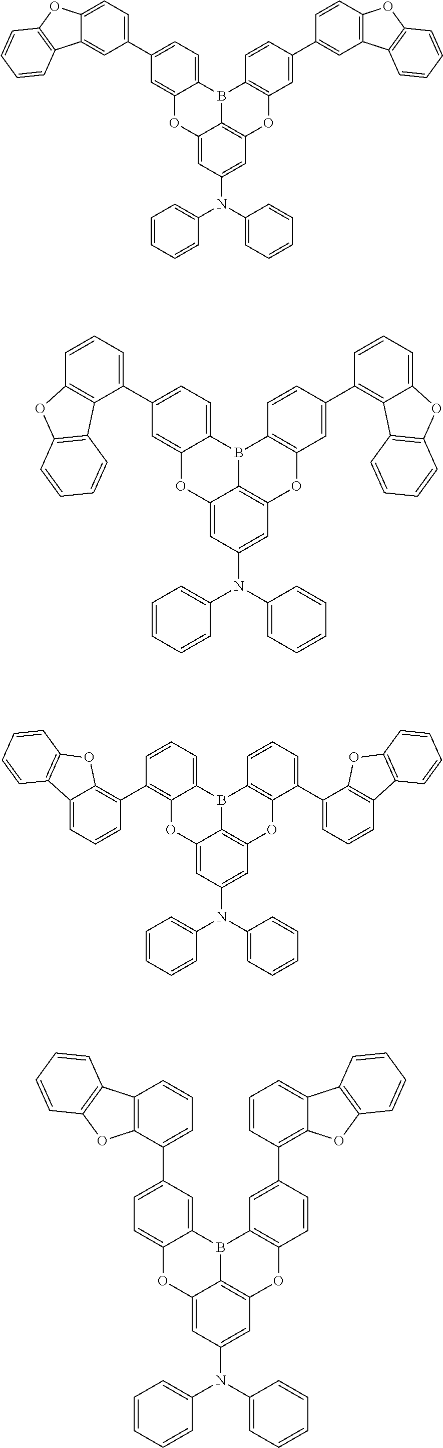 [SMILES: c1ccc(N(c2ccccc2)c2cc3c4c(c2)Oc2cc(-c5ccc6oc7ccccc7c6c5)ccc2B4c2ccc(-c4ccc5oc6ccccc6c5c4)cc2O3)cc1 ; c1ccc(N(c2ccccc2)c2cc3c4c(c2)Oc2cc(-c5cccc6oc7ccccc7c56)ccc2B4c2ccc(-c4cccc5oc6ccccc6c45)cc2O3)cc1 ; c1ccc(N(c2ccccc2)c2cc3c4c(c2)Oc2c(cccc2-c2cccc5c2oc2ccccc25)B4c2cccc(-c4cccc5c4oc4ccccc45)c2O3)cc1 ; c1ccc(N(c2ccccc2)c2cc3c4c(c2)Oc2ccc(-c5cccc6c5oc5ccccc56)cc2B4c2cc(-c4cccc5c4oc4ccccc45)ccc2O3)cc1]

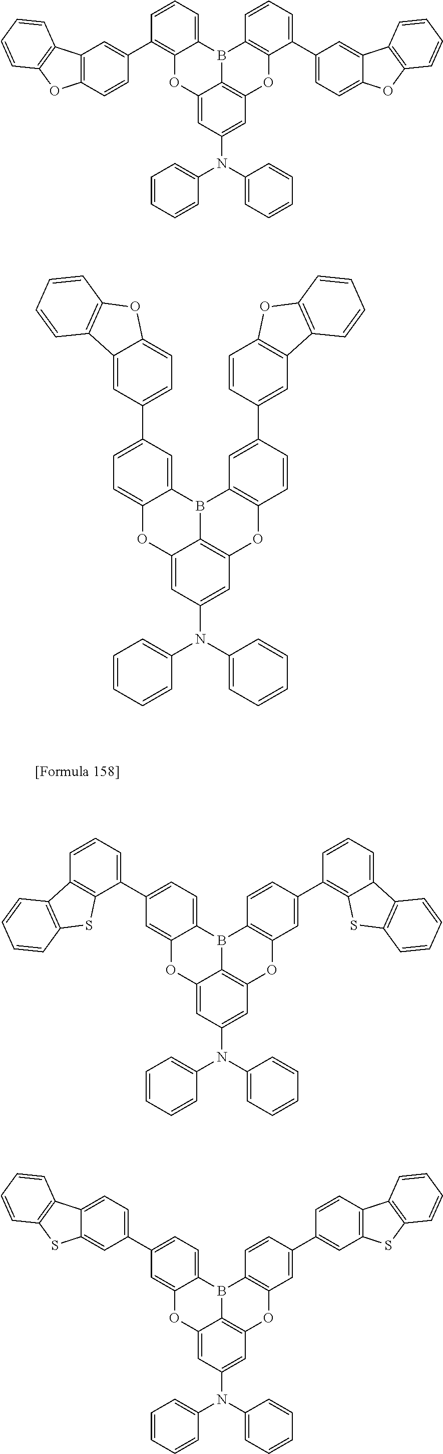 [SMILES: c1ccc(N(c2ccccc2)c2cc3c4c(c2)Oc2c(cccc2-c2ccc5oc6ccccc6c5c2)B4c2cccc(-c4ccc5oc6ccccc6c5c4)c2O3)cc1 ; c1ccc(N(c2ccccc2)c2cc3c4c(c2)Oc2ccc(-c5ccc6oc7ccccc7c6c5)cc2B4c2cc(-c4ccc5oc6ccccc6c5c4)ccc2O3)cc1 ; c1ccc(N(c2ccccc2)c2cc3c4c(c2)Oc2cc(-c5cccc6c5sc5ccccc56)ccc2B4c2ccc(-c4cccc5c4sc4ccccc45)cc2O3)cc1 ; c1ccc(N(c2ccccc2)c2cc3c4c(c2)Oc2cc(-c5ccc6c(c5)sc5ccccc56)ccc2B4c2ccc(-c4ccc5c(c4)sc4ccccc45)cc2O3)cc1]

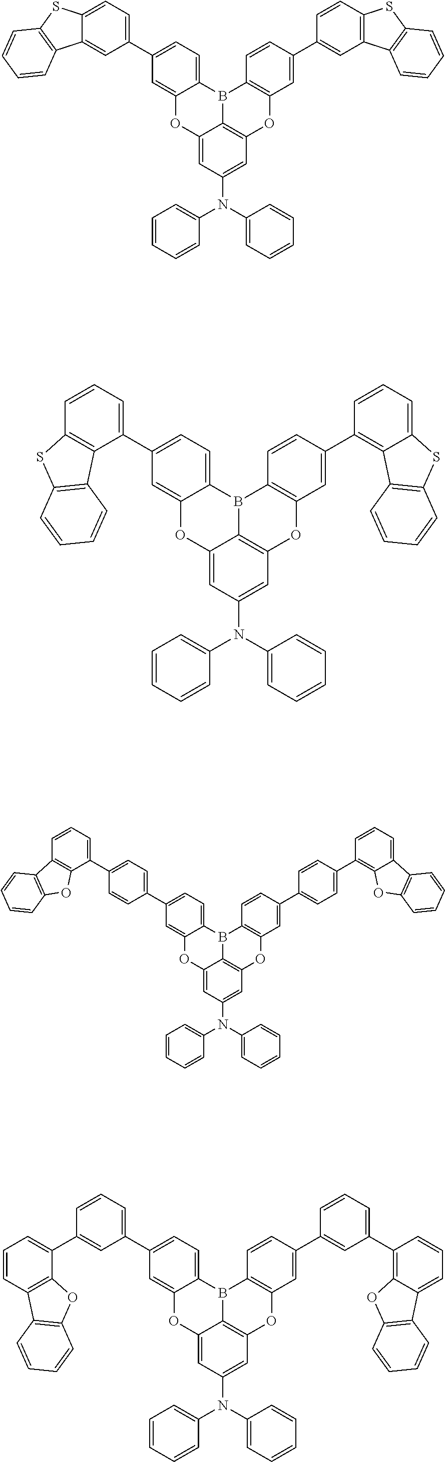 [SMILES: c1ccc(N(c2ccccc2)c2cc3c4c(c2)Oc2cc(-c5ccc6sc7ccccc7c6c5)ccc2B4c2ccc(-c4ccc5sc6ccccc6c5c4)cc2O3)cc1 ; c1ccc(N(c2ccccc2)c2cc3c4c(c2)Oc2cc(-c5cccc6sc7ccccc7c56)ccc2B4c2ccc(-c4cccc5sc6ccccc6c45)cc2O3)cc1 ; c1ccc(N(c2ccccc2)c2cc3c4c(c2)Oc2cc(-c5ccc(-c6cccc7c6oc6ccccc67)cc5)ccc2B4c2ccc(-c4ccc(-c5cccc6c5oc5ccccc56)cc4)cc2O3)cc1 ; c1ccc(N(c2ccccc2)c2cc3c4c(c2)Oc2cc(-c5cccc(-c6cccc7c6oc6ccccc67)c5)ccc2B4c2ccc(-c4cccc(-c5cccc6c5oc5ccccc56)c4)cc2O3)cc1]

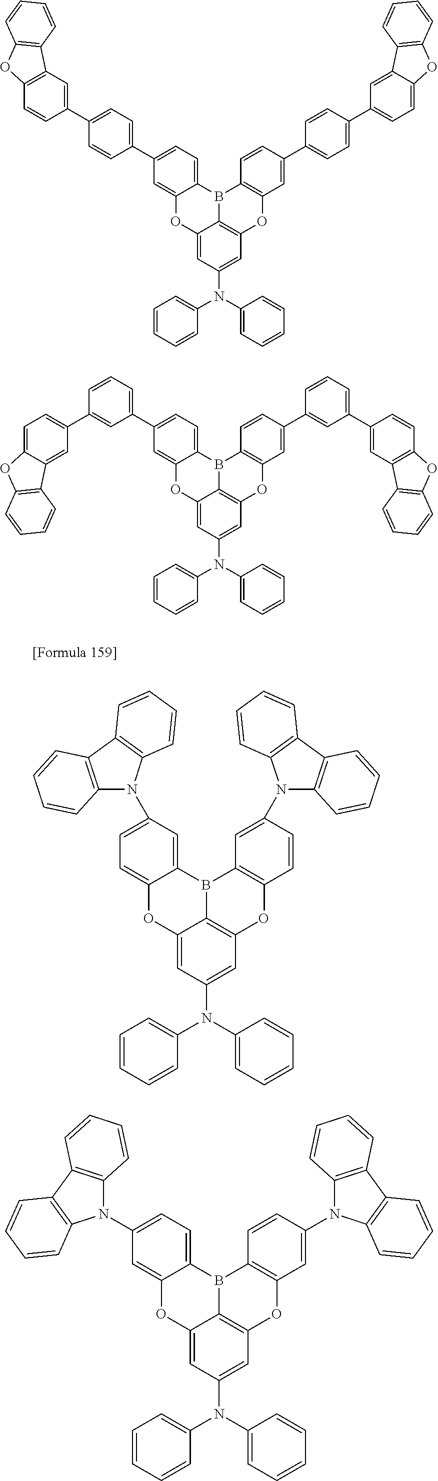 [SMILES: c1ccc(N(c2ccccc2)c2cc3c4c(c2)Oc2cc(-c5ccc(-c6ccc7oc8ccccc8c7c6)cc5)ccc2B4c2ccc(-c4ccc(-c5ccc6oc7ccccc7c6c5)cc4)cc2O3)cc1 ; c1ccc(N(c2ccccc2)c2cc3c4c(c2)Oc2cc(-c5cccc(-c6ccc7oc8ccccc8c7c6)c5)ccc2B4c2ccc(-c4cccc(-c5ccc6oc7ccccc7c6c5)c4)cc2O3)cc1 ; c1ccc(N(c2ccccc2)c2cc3c4c(c2)Oc2ccc(-n5c6ccccc6c6ccccc65)cc2B4c2cc(-n4c5ccccc5c5ccccc54)ccc2O3)cc1 ; c1ccc(N(c2ccccc2)c2cc3c4c(c2)Oc2cc(-n5c6ccccc6c6ccccc65)ccc2B4c2ccc(-n4c5ccccc5c5ccccc54)cc2O3)cc1]

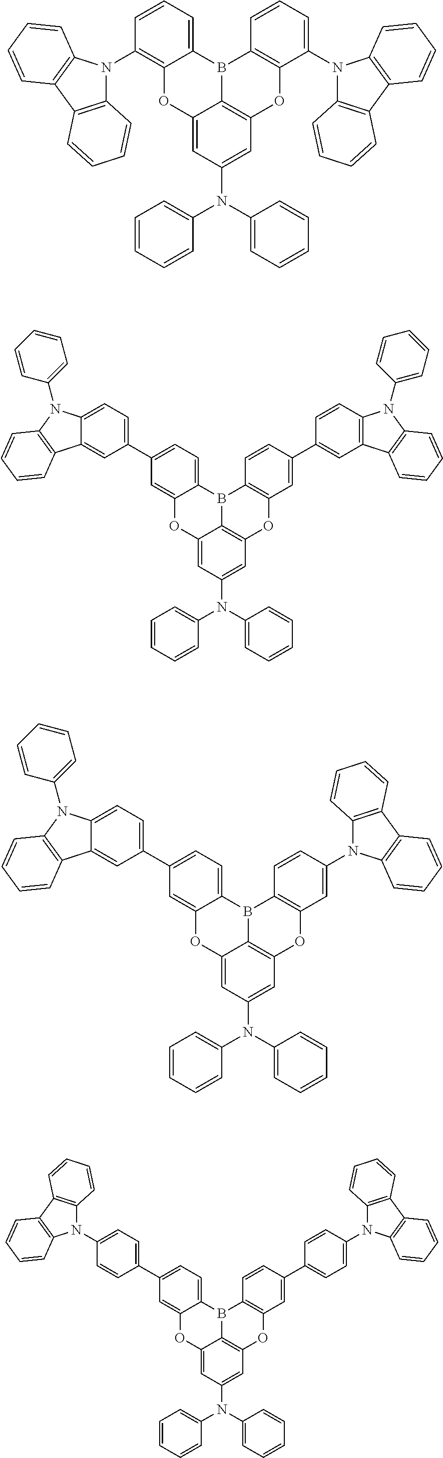 [SMILES: c1ccc(N(c2ccccc2)c2cc3c4c(c2)Oc2c(cccc2-n2c5ccccc5c5ccccc52)B4c2cccc(-n4c5ccccc5c5ccccc54)c2O3)cc1 ; c1ccc(N(c2ccccc2)c2cc3c4c(c2)Oc2cc(-c5ccc6c(c5)c5ccccc5n6-c5ccccc5)ccc2B4c2ccc(-c4ccc5c(c4)c4ccccc4n5-c4ccccc4)cc2O3)cc1 ; c1ccc(N(c2ccccc2)c2cc3c4c(c2)Oc2cc(-n5c6ccccc6c6ccccc65)ccc2B4c2ccc(-c4ccc5c(c4)c4ccccc4n5-c4ccccc4)cc2O3)cc1 ; c1ccc(N(c2ccccc2)c2cc3c4c(c2)Oc2cc(-c5ccc(-n6c7ccccc7c7ccccc76)cc5)ccc2B4c2ccc(-c4ccc(-n5c6ccccc6c6ccccc65)cc4)cc2O3)cc1]

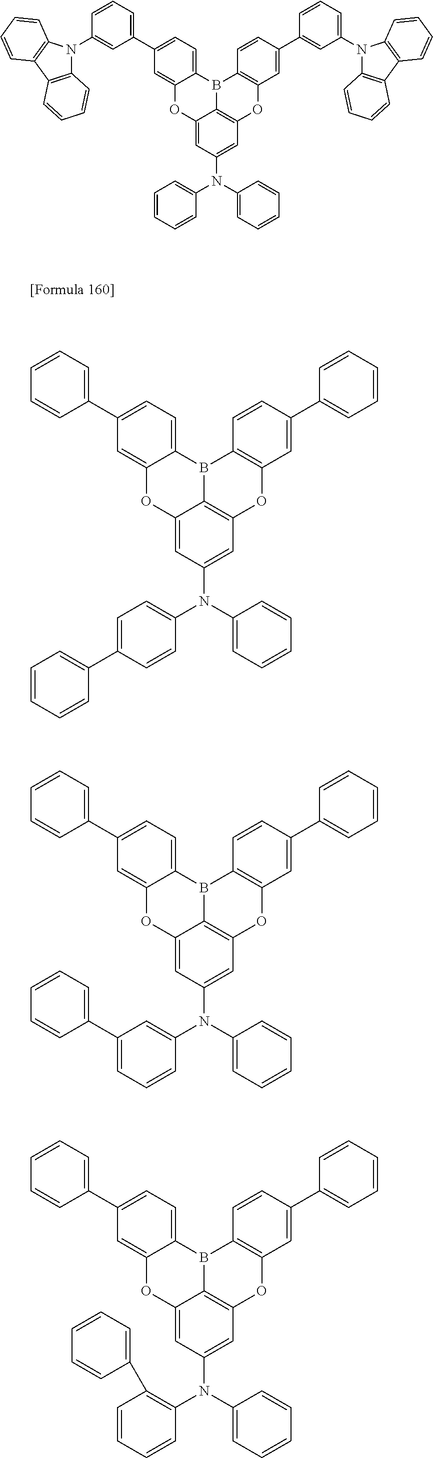 [SMILES: c1ccc(N(c2ccccc2)c2cc3c4c(c2)Oc2cc(-c5cccc(-n6c7ccccc7c7ccccc76)c5)ccc2B4c2ccc(-c4cccc(-n5c6ccccc6c6ccccc65)c4)cc2O3)cc1 ; c1ccc(-c2ccc(N(c3ccccc3)c3cc4c5c(c3)Oc3cc(-c6ccccc6)ccc3B5c3ccc(-c5ccccc5)cc3O4)cc2)cc1 ; c1ccc(-c2cccc(N(c3ccccc3)c3cc4c5c(c3)Oc3cc(-c6ccccc6)ccc3B5c3ccc(-c5ccccc5)cc3O4)c2)cc1 ; c1ccc(-c2ccc3c(c2)Oc2cc(N(c4ccccc4)c4ccccc4-c4ccccc4)cc4c2B3c2ccc(-c3ccccc3)cc2O4)cc1]

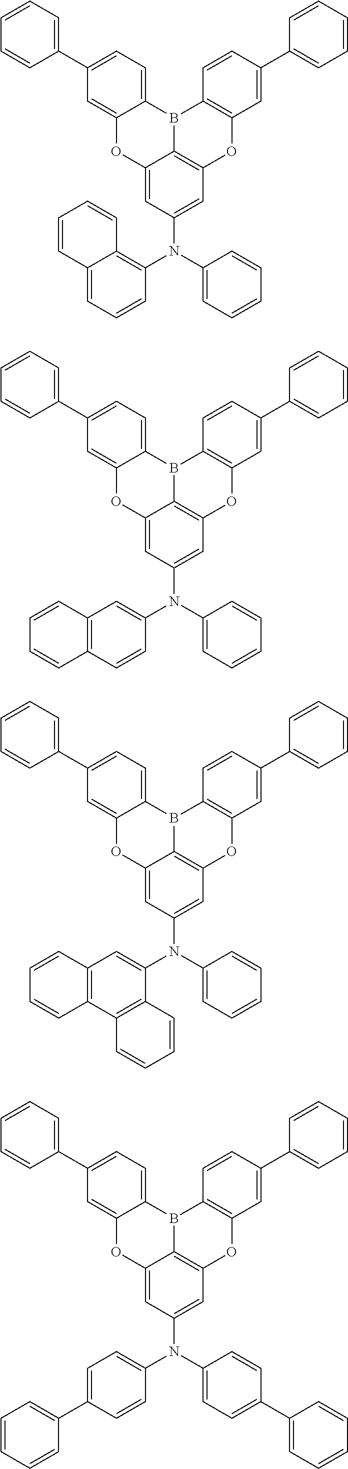

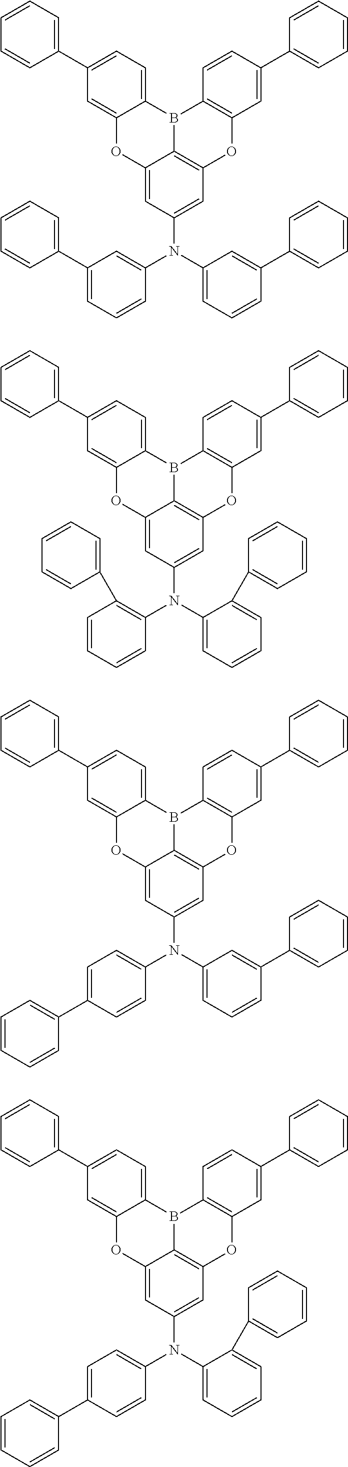

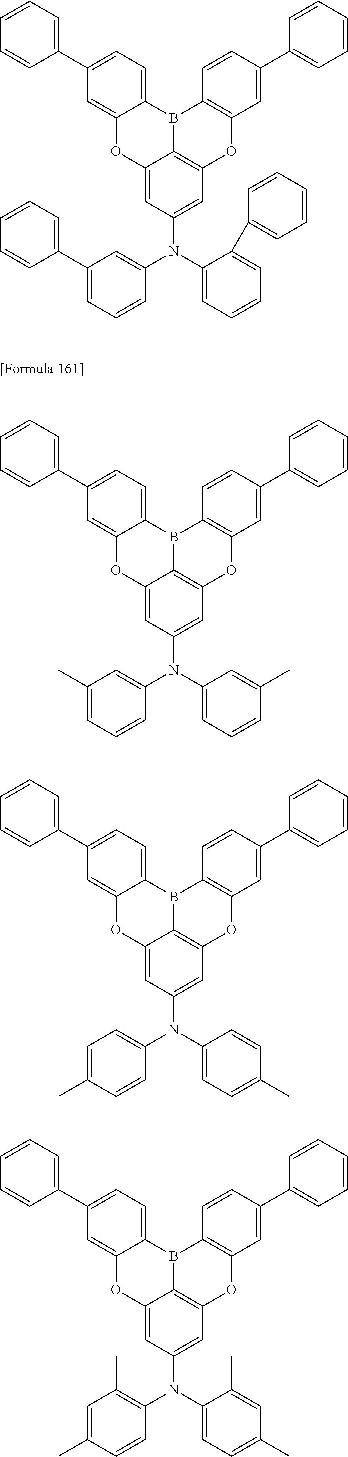 [SMILES: c1ccc(-c2cccc(N(c3cc4c5c(c3)Oc3cc(-c6ccccc6)ccc3B5c3ccc(-c5ccccc5)cc3O4)c3ccccc3-c3ccccc3)c2)cc1 ; Cc1cccc(N(c2cccc(C)c2)c2cc3c4c(c2)Oc2cc(-c5ccccc5)ccc2B4c2ccc(-c4ccccc4)cc2O3)c1 ; Cc1ccc(N(c2ccc(C)cc2)c2cc3c4c(c2)Oc2cc(-c5ccccc5)ccc2B4c2ccc(-c4ccccc4)cc2O3)cc1 ; Cc1ccc(N(c2cc3c4c(c2)Oc2cc(-c5ccccc5)ccc2B4c2ccc(-c4ccccc4)cc2O3)c2ccc(C)cc2C)c(C)c1]

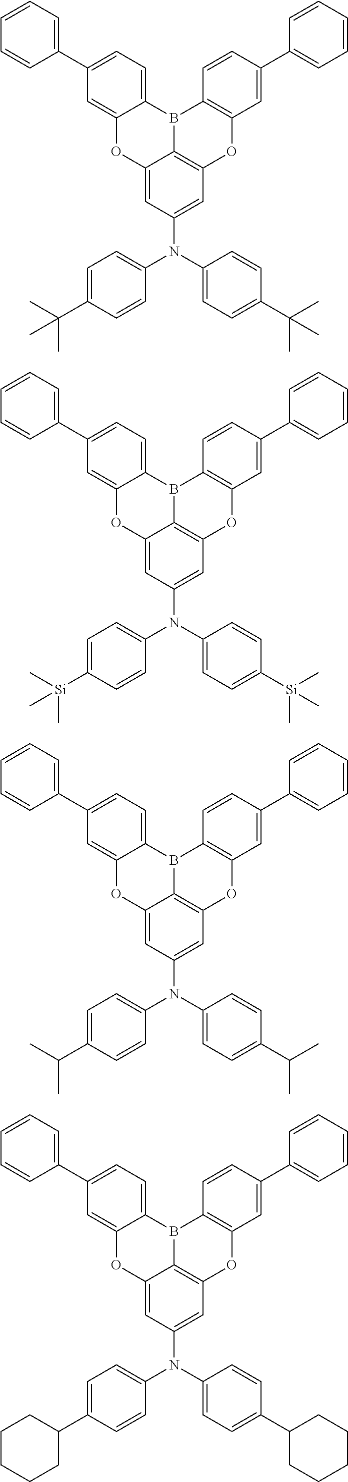

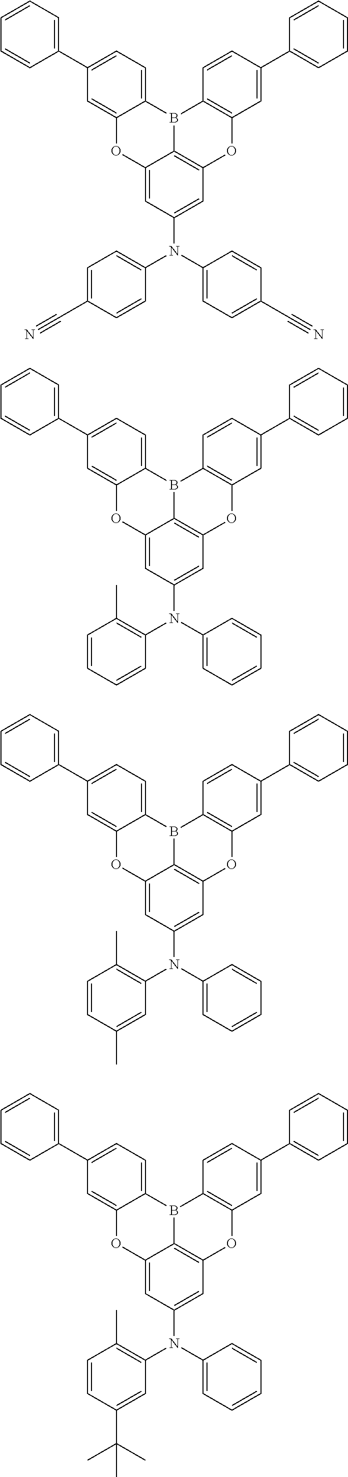

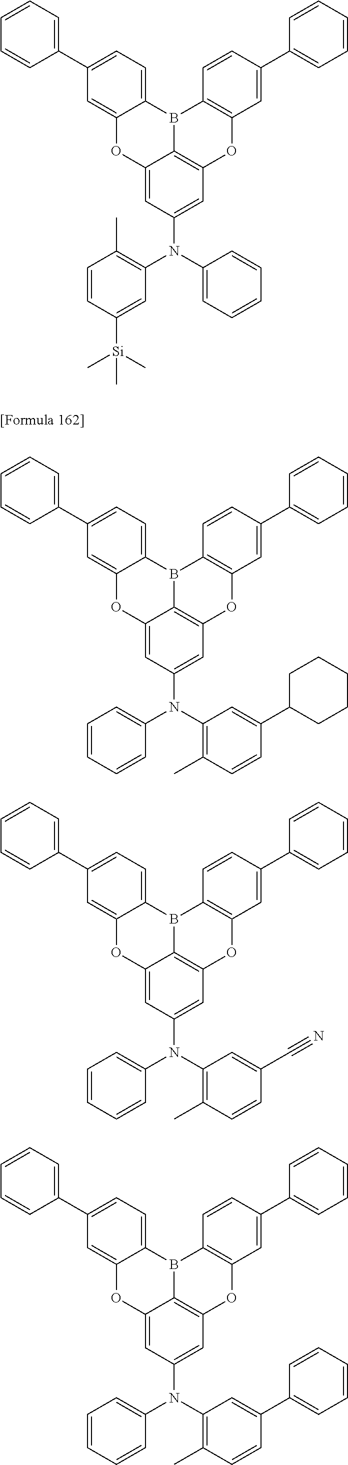 [SMILES: Cc1ccc([Si](C)(C)C)cc1N(c1ccccc1)c1cc2c3c(c1)Oc1cc(-c4ccccc4)ccc1B3c1ccc(-c3ccccc3)cc1O2 ; Cc1ccc(C2CCCCC2)cc1N(c1ccccc1)c1cc2c3c(c1)Oc1cc(-c4ccccc4)ccc1B3c1ccc(-c3ccccc3)cc1O2 ; Cc1ccc(C#N)cc1N(c1ccccc1)c1cc2c3c(c1)Oc1cc(-c4ccccc4)ccc1B3c1ccc(-c3ccccc3)cc1O2 ; Cc1ccc(-c2ccccc2)cc1N(c1ccccc1)c1cc2c3c(c1)Oc1cc(-c4ccccc4)ccc1B3c1ccc(-c3ccccc3)cc1O2]

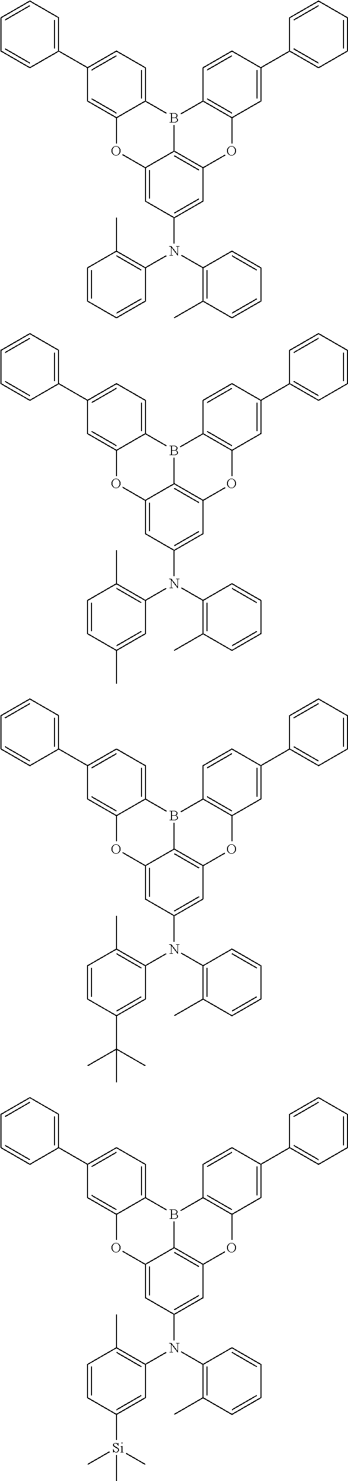 [SMILES: Cc1ccccc1N(c1cc2c3c(c1)Oc1cc(-c4ccccc4)ccc1B3c1ccc(-c3ccccc3)cc1O2)c1ccccc1C ; Cc1ccc(C)c(N(c2cc3c4c(c2)Oc2cc(-c5ccccc5)ccc2B4c2ccc(-c4ccccc4)cc2O3)c2ccccc2C)c1 ; Cc1ccccc1N(c1cc2c3c(c1)Oc1cc(-c4ccccc4)ccc1B3c1ccc(-c3ccccc3)cc1O2)c1cc(C(C)(C)C)ccc1C ; Cc1ccccc1N(c1cc2c3c(c1)Oc1cc(-c4ccccc4)ccc1B3c1ccc(-c3ccccc3)cc1O2)c1cc([Si](C)(C)C)ccc1C]

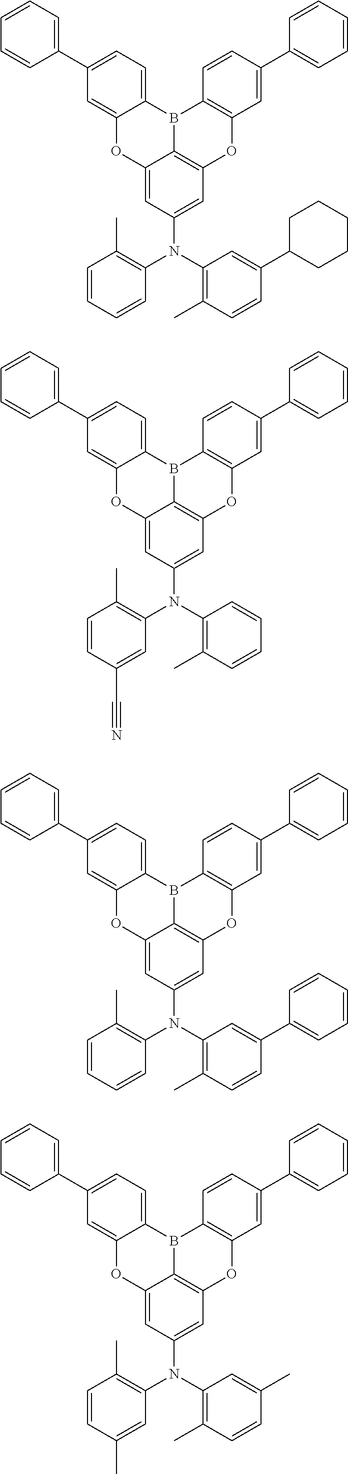 [SMILES: Cc1ccccc1N(c1cc2c3c(c1)Oc1cc(-c4ccccc4)ccc1B3c1ccc(-c3ccccc3)cc1O2)c1cc(C2CCCCC2)ccc1C ; Cc1ccccc1N(c1cc2c3c(c1)Oc1cc(-c4ccccc4)ccc1B3c1ccc(-c3ccccc3)cc1O2)c1cc(C#N)ccc1C ; Cc1ccccc1N(c1cc2c3c(c1)Oc1cc(-c4ccccc4)ccc1B3c1ccc(-c3ccccc3)cc1O2)c1cc(-c2ccccc2)ccc1C ; Cc1ccc(C)c(N(c2cc3c4c(c2)Oc2cc(-c5ccccc5)ccc2B4c2ccc(-c4ccccc4)cc2O3)c2cc(C)ccc2C)c1]

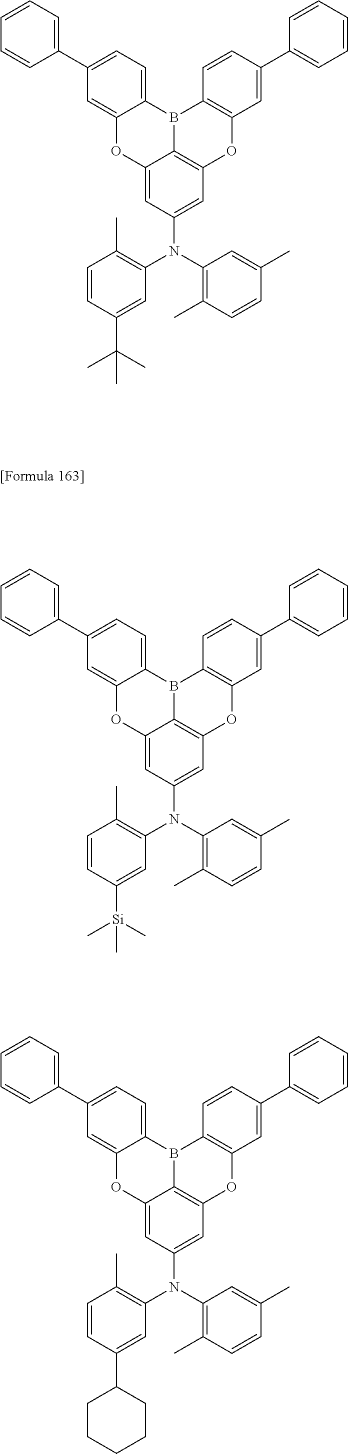 [SMILES: Cc1ccc(C)c(N(c2cc3c4c(c2)Oc2cc(-c5ccccc5)ccc2B4c2ccc(-c4ccccc4)cc2O3)c2cc(C(C)(C)C)ccc2C)c1 ; Cc1ccc(C)c(N(c2cc3c4c(c2)Oc2cc(-c5ccccc5)ccc2B4c2ccc(-c4ccccc4)cc2O3)c2cc([Si](C)(C)C)ccc2C)c1 ; Cc1ccc(C)c(N(c2cc3c4c(c2)Oc2cc(-c5ccccc5)ccc2B4c2ccc(-c4ccccc4)cc2O3)c2cc(C3CCCCC3)ccc2C)c1]

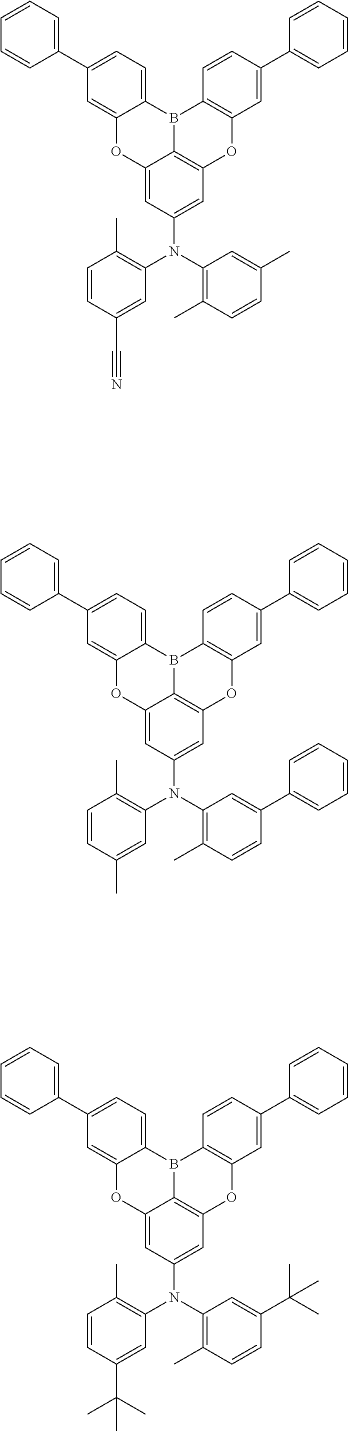 [SMILES: Cc1ccc(C)c(N(c2cc3c4c(c2)Oc2cc(-c5ccccc5)ccc2B4c2ccc(-c4ccccc4)cc2O3)c2cc(C#N)ccc2C)c1 ; Cc1ccc(C)c(N(c2cc3c4c(c2)Oc2cc(-c5ccccc5)ccc2B4c2ccc(-c4ccccc4)cc2O3)c2cc(-c3ccccc3)ccc2C)c1 ; Cc1ccc(C(C)(C)C)cc1N(c1cc2c3c(c1)Oc1cc(-c4ccccc4)ccc1B3c1ccc(-c3ccccc3)cc1O2)c1cc(C(C)(C)C)ccc1C]

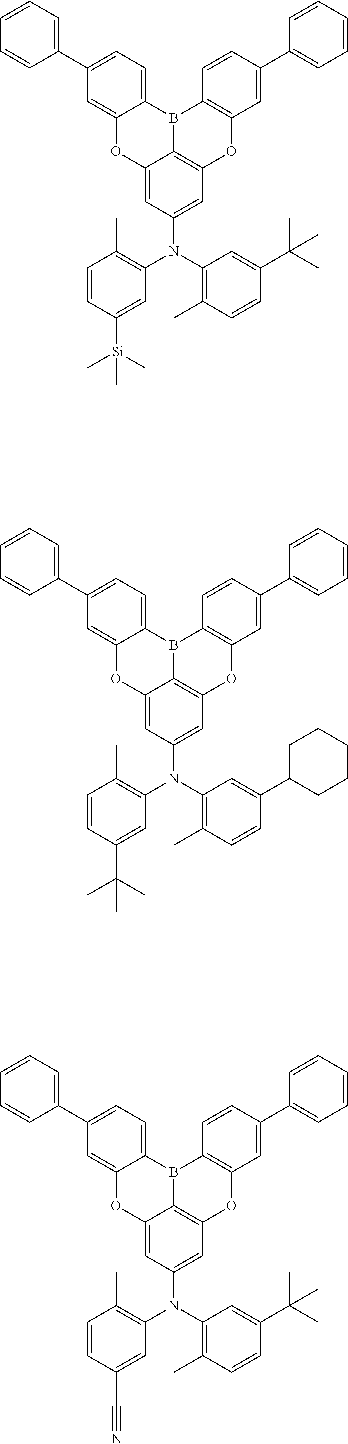 [SMILES: Cc1ccc(C(C)(C)C)cc1N(c1cc2c3c(c1)Oc1cc(-c4ccccc4)ccc1B3c1ccc(-c3ccccc3)cc1O2)c1cc([Si](C)(C)C)ccc1C ; Cc1ccc(C2CCCCC2)cc1N(c1cc2c3c(c1)Oc1cc(-c4ccccc4)ccc1B3c1ccc(-c3ccccc3)cc1O2)c1cc(C(C)(C)C)ccc1C ; Cc1ccc(C#N)cc1N(c1cc2c3c(c1)Oc1cc(-c4ccccc4)ccc1B3c1ccc(-c3ccccc3)cc1O2)c1cc(C(C)(C)C)ccc1C]

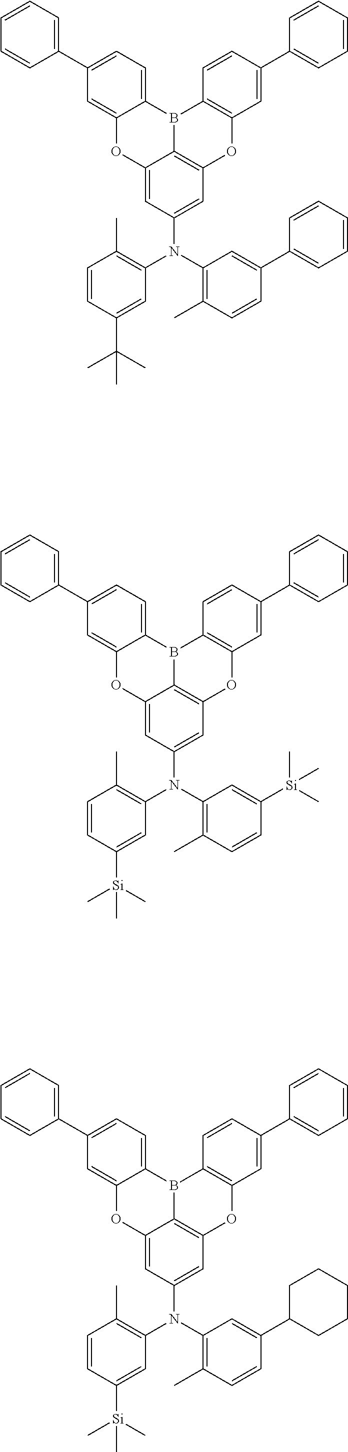 [SMILES: Cc1ccc(-c2ccccc2)cc1N(c1cc2c3c(c1)Oc1cc(-c4ccccc4)ccc1B3c1ccc(-c3ccccc3)cc1O2)c1cc(C(C)(C)C)ccc1C ; Cc1ccc([Si](C)(C)C)cc1N(c1cc2c3c(c1)Oc1cc(-c4ccccc4)ccc1B3c1ccc(-c3ccccc3)cc1O2)c1cc([Si](C)(C)C)ccc1C ; Cc1ccc(C2CCCCC2)cc1N(c1cc2c3c(c1)Oc1cc(-c4ccccc4)ccc1B3c1ccc(-c3ccccc3)cc1O2)c1cc([Si](C)(C)C)ccc1C]

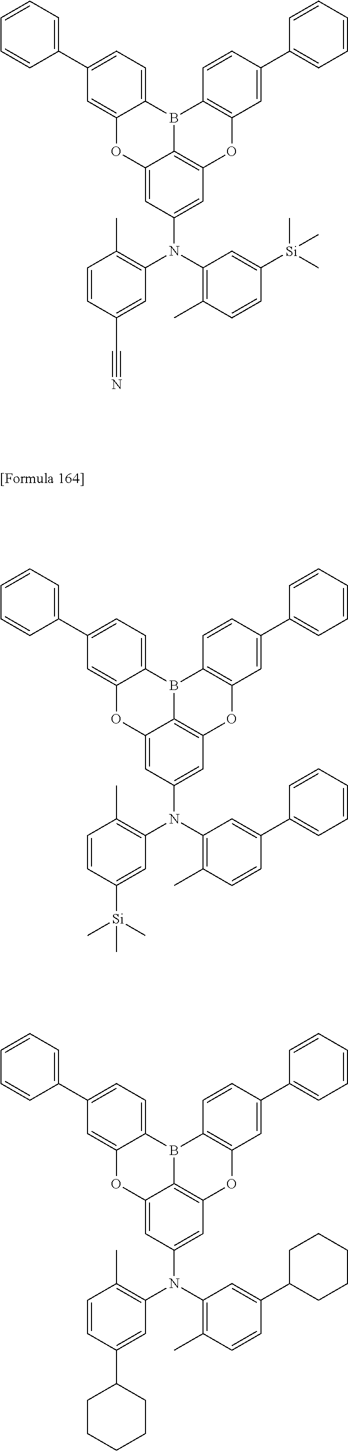 [SMILES: Cc1ccc(C#N)cc1N(c1cc2c3c(c1)Oc1cc(-c4ccccc4)ccc1B3c1ccc(-c3ccccc3)cc1O2)c1cc([Si](C)(C)C)ccc1C ; Cc1ccc(-c2ccccc2)cc1N(c1cc2c3c(c1)Oc1cc(-c4ccccc4)ccc1B3c1ccc(-c3ccccc3)cc1O2)c1cc([Si](C)(C)C)ccc1C ; Cc1ccc(C2CCCCC2)cc1N(c1cc2c3c(c1)Oc1cc(-c4ccccc4)ccc1B3c1ccc(-c3ccccc3)cc1O2)c1cc(C2CCCCC2)ccc1C]

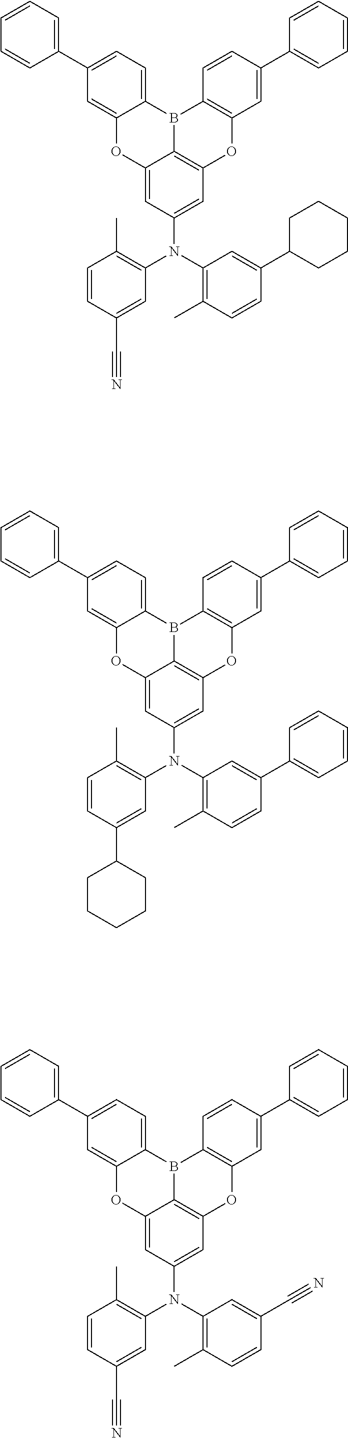 [SMILES: Cc1ccc(C#N)cc1N(c1cc2c3c(c1)Oc1cc(-c4ccccc4)ccc1B3c1ccc(-c3ccccc3)cc1O2)c1cc(C2CCCCC2)ccc1C ; Cc1ccc(-c2ccccc2)cc1N(c1cc2c3c(c1)Oc1cc(-c4ccccc4)ccc1B3c1ccc(-c3ccccc3)cc1O2)c1cc(C2CCCCC2)ccc1C ; Cc1ccc(C#N)cc1N(c1cc2c3c(c1)Oc1cc(-c4ccccc4)ccc1B3c1ccc(-c3ccccc3)cc1O2)c1cc(C#N)ccc1C]

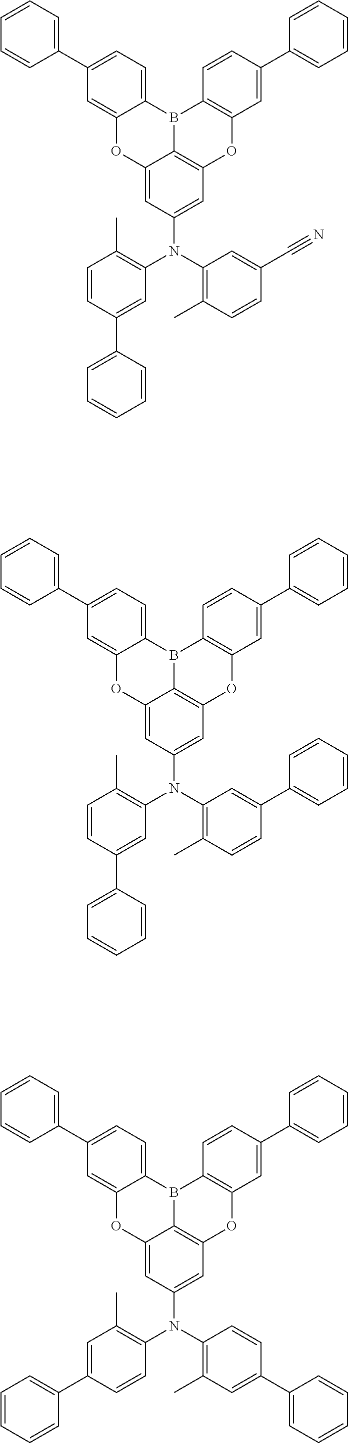 [SMILES: Cc1ccc(C#N)cc1N(c1cc2c3c(c1)Oc1cc(-c4ccccc4)ccc1B3c1ccc(-c3ccccc3)cc1O2)c1cc(-c2ccccc2)ccc1C ; Cc1ccc(-c2ccccc2)cc1N(c1cc2c3c(c1)Oc1cc(-c4ccccc4)ccc1B3c1ccc(-c3ccccc3)cc1O2)c1cc(-c2ccccc2)ccc1C ; Cc1cc(-c2ccccc2)ccc1N(c1cc2c3c(c1)Oc1cc(-c4ccccc4)ccc1B3c1ccc(-c3ccccc3)cc1O2)c1ccc(-c2ccccc2)cc1C]

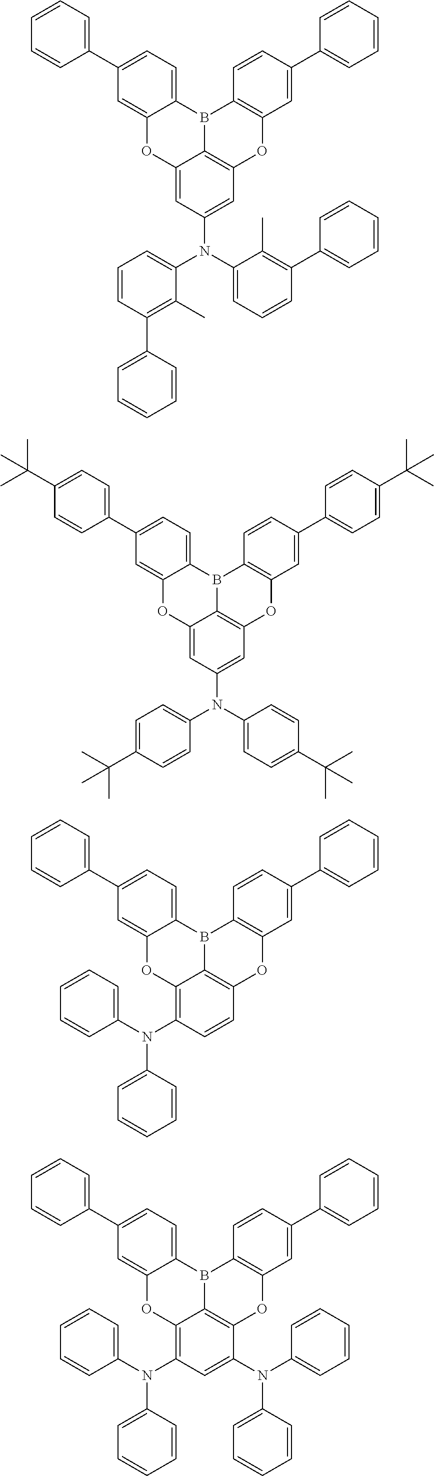

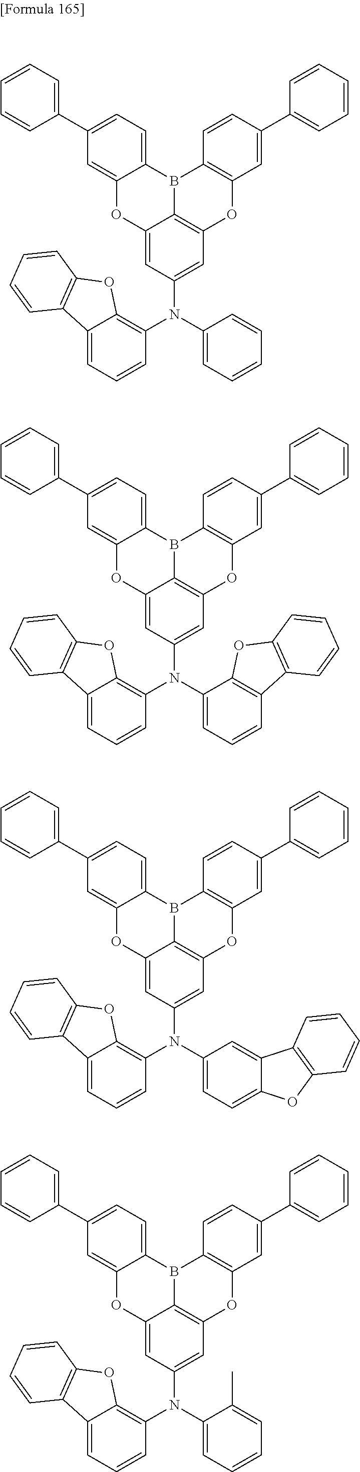 [SMILES: c1ccc(-c2ccc3c(c2)Oc2cc(N(c4ccccc4)c4cccc5c4oc4ccccc45)cc4c2B3c2ccc(-c3ccccc3)cc2O4)cc1 ; c1ccc(-c2ccc3c(c2)Oc2cc(N(c4cccc5c4oc4ccccc45)c4cccc5c4oc4ccccc45)cc4c2B3c2ccc(-c3ccccc3)cc2O4)cc1 ; c1ccc(-c2ccc3c(c2)Oc2cc(N(c4ccc5oc6ccccc6c5c4)c4cccc5c4oc4ccccc45)cc4c2B3c2ccc(-c3ccccc3)cc2O4)cc1 ; Cc1ccccc1N(c1cc2c3c(c1)Oc1cc(-c4ccccc4)ccc1B3c1ccc(-c3ccccc3)cc1O2)c1cccc2c1oc1ccccc12]

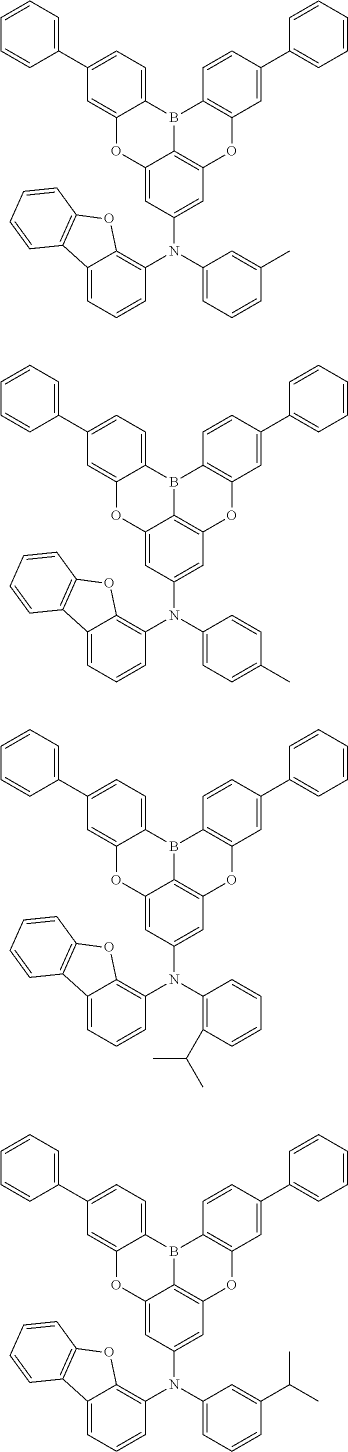 [SMILES: Cc1cccc(N(c2cc3c4c(c2)Oc2cc(-c5ccccc5)ccc2B4c2ccc(-c4ccccc4)cc2O3)c2cccc3c2oc2ccccc23)c1 ; Cc1ccc(N(c2cc3c4c(c2)Oc2cc(-c5ccccc5)ccc2B4c2ccc(-c4ccccc4)cc2O3)c2cccc3c2oc2ccccc23)cc1 ; CC(C)c1ccccc1N(c1cc2c3c(c1)Oc1cc(-c4ccccc4)ccc1B3c1ccc(-c3ccccc3)cc1O2)c1cccc2c1oc1ccccc12 ; CC(C)c1cccc(N(c2cc3c4c(c2)Oc2cc(-c5ccccc5)ccc2B4c2ccc(-c4ccccc4)cc2O3)c2cccc3c2oc2ccccc23)c1]

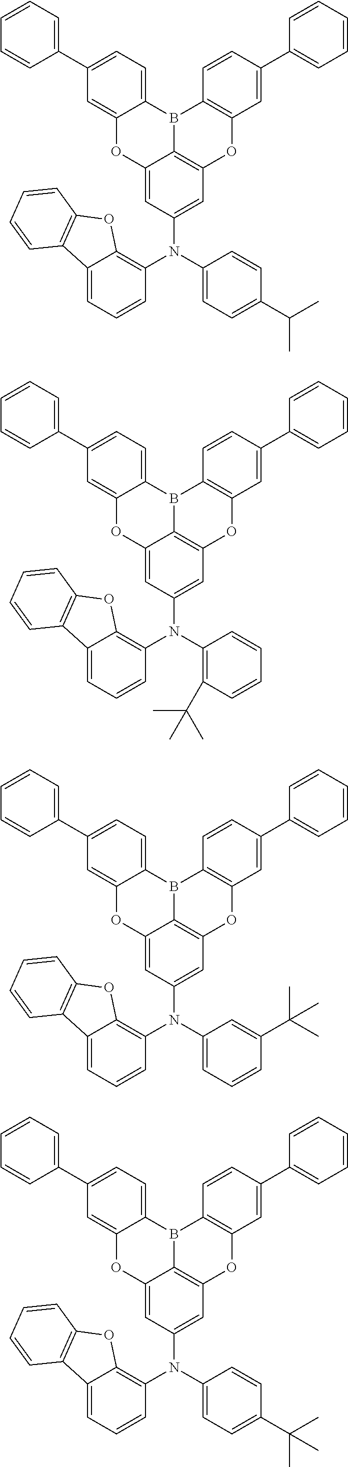

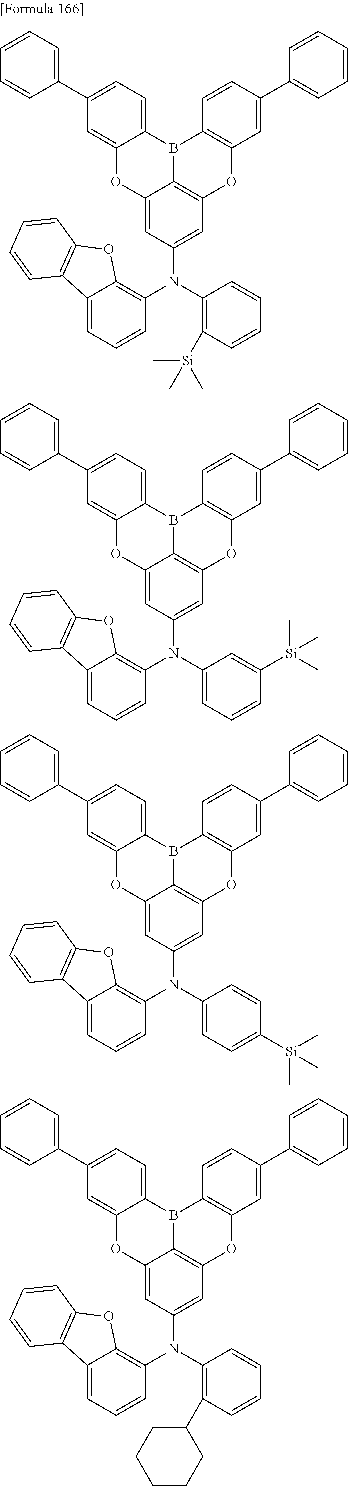

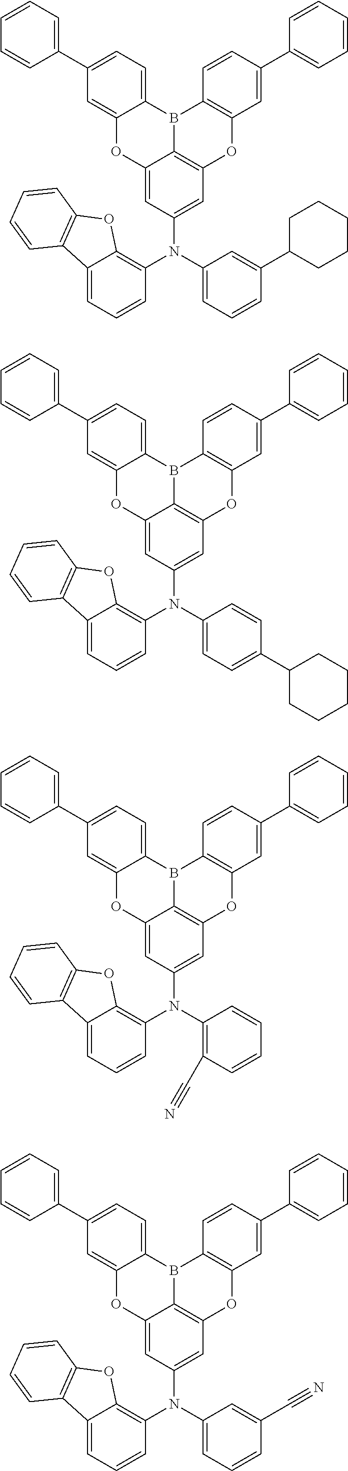

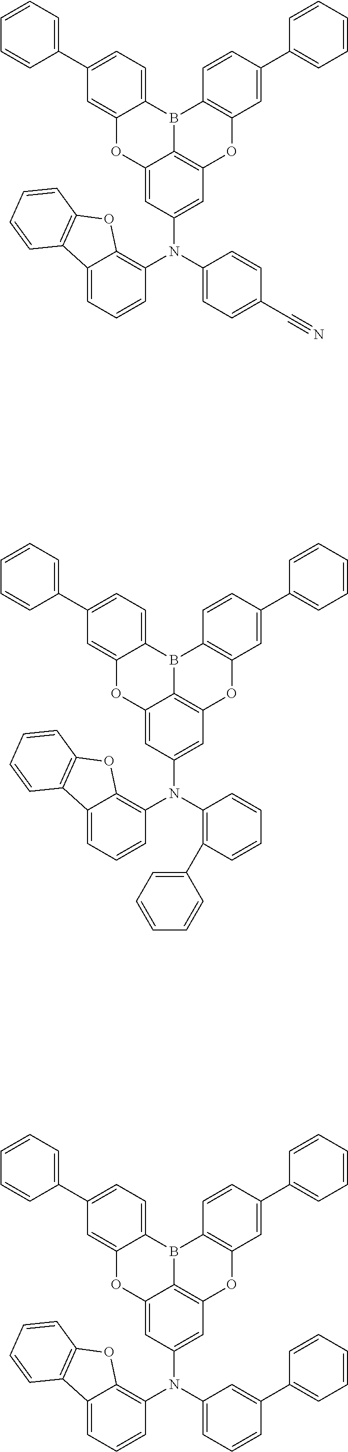 [SMILES: N#Cc1ccc(N(c2cc3c4c(c2)Oc2cc(-c5ccccc5)ccc2B4c2ccc(-c4ccccc4)cc2O3)c2cccc3c2oc2ccccc23)cc1 ; c1ccc(-c2ccc3c(c2)Oc2cc(N(c4ccccc4-c4ccccc4)c4cccc5c4oc4ccccc45)cc4c2B3c2ccc(-c3ccccc3)cc2O4)cc1 ; c1ccc(-c2cccc(N(c3cc4c5c(c3)Oc3cc(-c6ccccc6)ccc3B5c3ccc(-c5ccccc5)cc3O4)c3cccc4c3oc3ccccc34)c2)cc1]

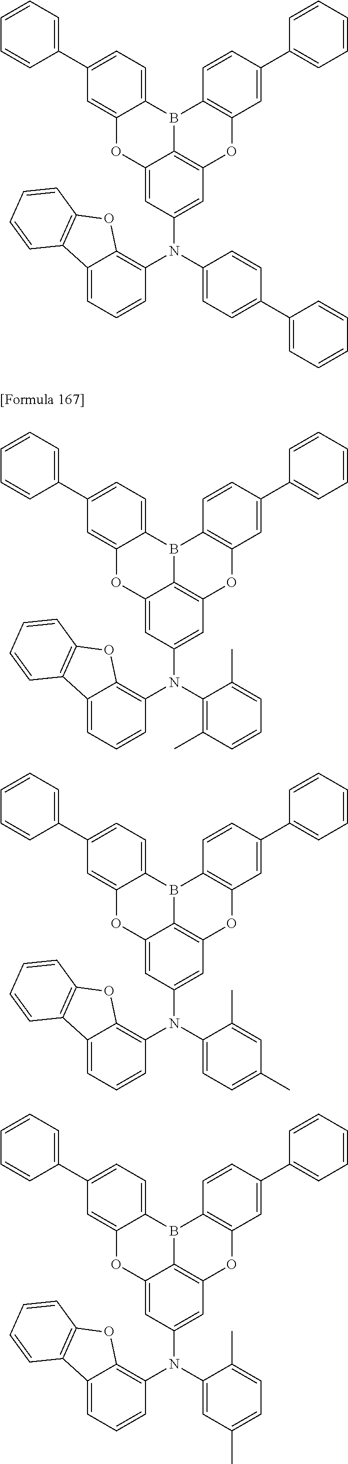

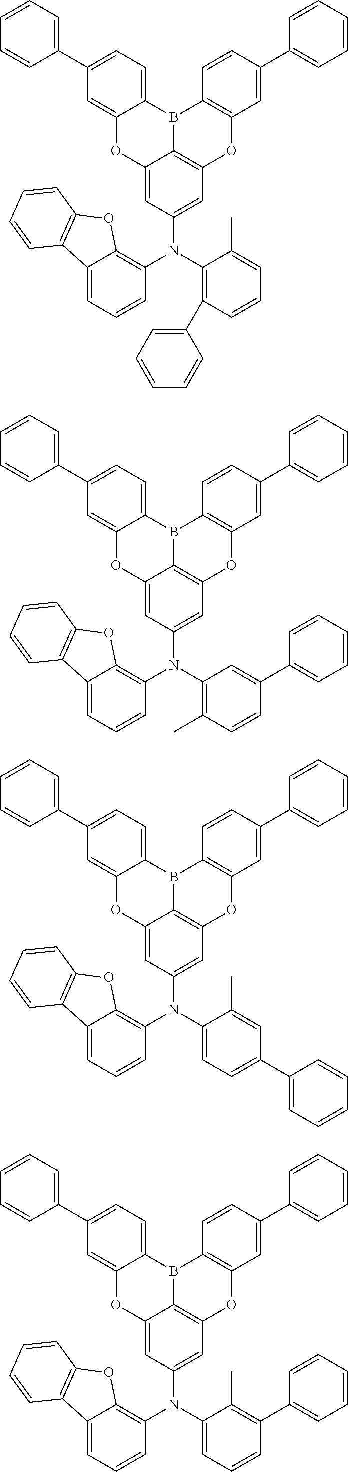

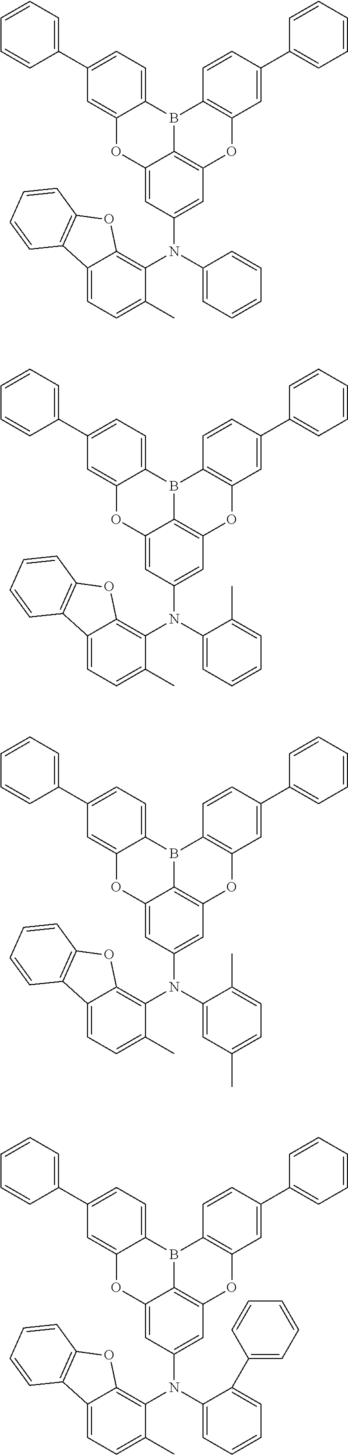 [SMILES: Cc1ccc2c(oc3ccccc32)c1N(c1ccccc1)c1cc2c3c(c1)Oc1cc(-c4ccccc4)ccc1B3c1ccc(-c3ccccc3)cc1O2 ; Cc1ccccc1N(c1cc2c3c(c1)Oc1cc(-c4ccccc4)ccc1B3c1ccc(-c3ccccc3)cc1O2)c1c(C)ccc2c1oc1ccccc12 ; Cc1ccc(C)c(N(c2cc3c4c(c2)Oc2cc(-c5ccccc5)ccc2B4c2ccc(-c4ccccc4)cc2O3)c2c(C)ccc3c2oc2ccccc23)c1 ; Cc1ccc2c(oc3ccccc32)c1N(c1cc2c3c(c1)Oc1cc(-c4ccccc4)ccc1B3c1ccc(-c3ccccc3)cc1O2)c1ccccc1-c1ccccc1]

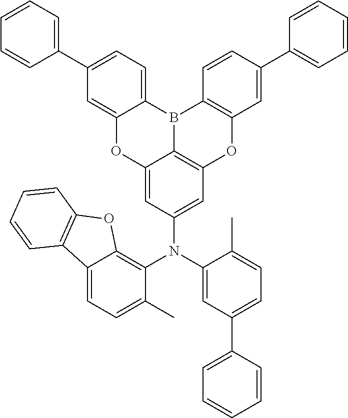 [SMILES: Cc1ccc(-c2ccccc2)cc1N(c1cc2c3c(c1)Oc1cc(-c4ccccc4)ccc1B3c1ccc(-c3ccccc3)cc1O2)c1c(C)ccc2c1oc1ccccc12]

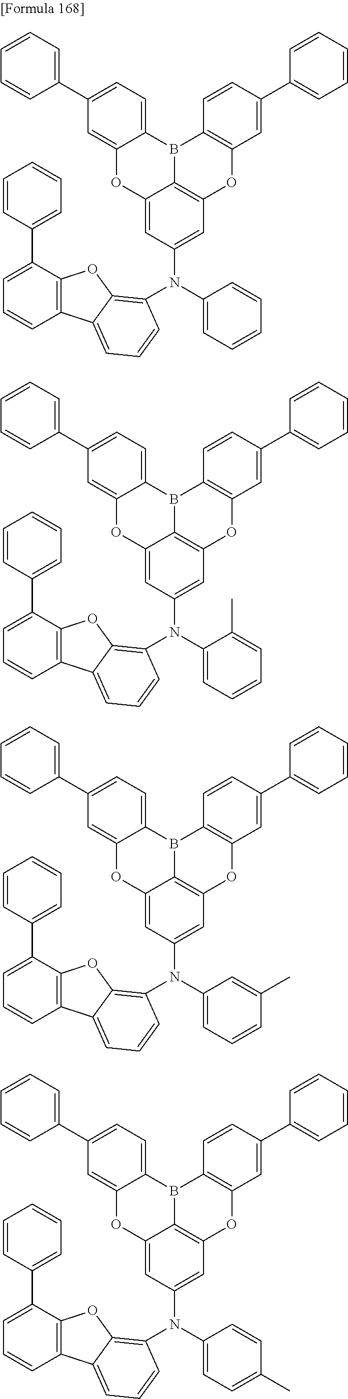 [SMILES: c1ccc(-c2ccc3c(c2)Oc2cc(N(c4ccccc4)c4cccc5c4oc4c(-c6ccccc6)cccc45)cc4c2B3c2ccc(-c3ccccc3)cc2O4)cc1 ; Cc1ccccc1N(c1cc2c3c(c1)Oc1cc(-c4ccccc4)ccc1B3c1ccc(-c3ccccc3)cc1O2)c1cccc2c1oc1c(-c3ccccc3)cccc12 ; Cc1cccc(N(c2cc3c4c(c2)Oc2cc(-c5ccccc5)ccc2B4c2ccc(-c4ccccc4)cc2O3)c2cccc3c2oc2c(-c4ccccc4)cccc23)c1 ; Cc1ccc(N(c2cc3c4c(c2)Oc2cc(-c5ccccc5)ccc2B4c2ccc(-c4ccccc4)cc2O3)c2cccc3c2oc2c(-c4ccccc4)cccc23)cc1]

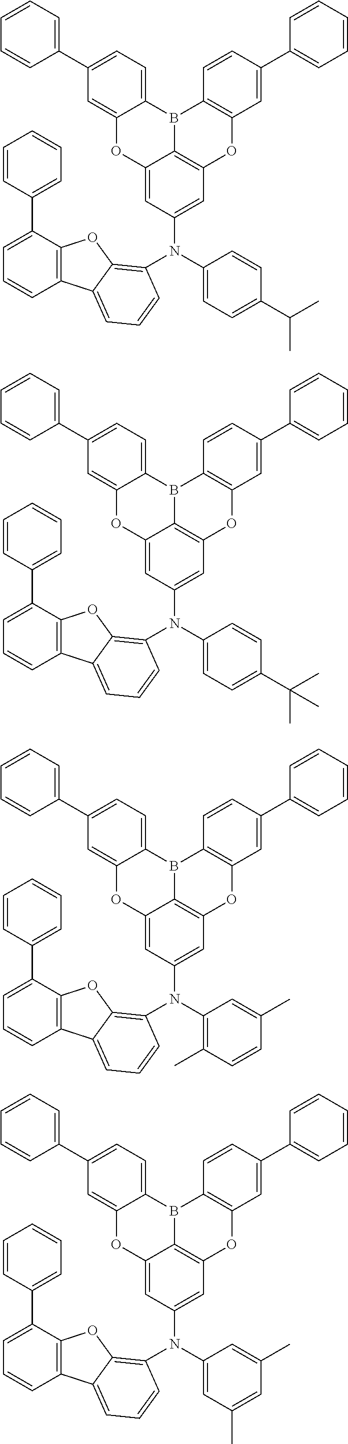

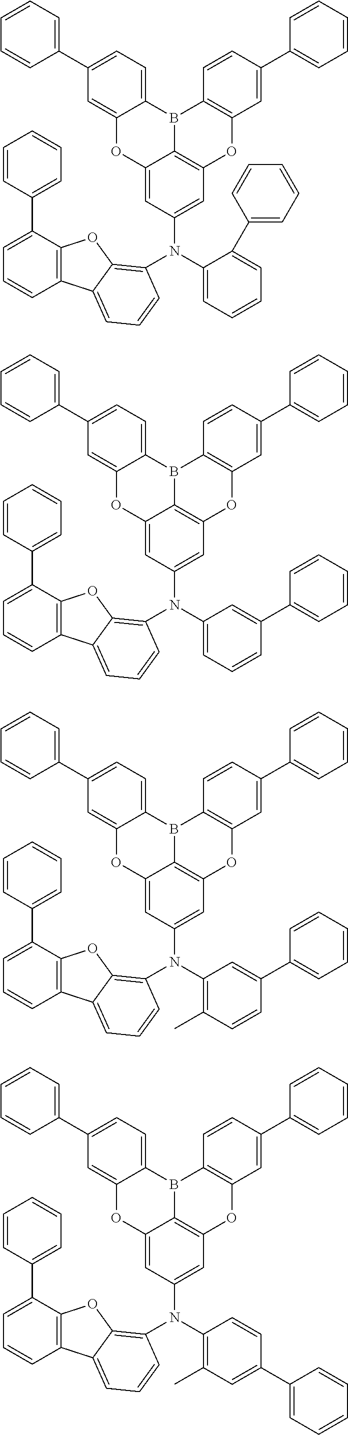 [SMILES: c1ccc(-c2ccc3c(c2)Oc2cc(N(c4ccccc4-c4ccccc4)c4cccc5c4oc4c(-c6ccccc6)cccc45)cc4c2B3c2ccc(-c3ccccc3)cc2O4)cc1 ; c1ccc(-c2cccc(N(c3cc4c5c(c3)Oc3cc(-c6ccccc6)ccc3B5c3ccc(-c5ccccc5)cc3O4)c3cccc4c3oc3c(-c5ccccc5)cccc34)c2)cc1 ; Cc1ccc(-c2ccccc2)cc1N(c1cc2c3c(c1)Oc1cc(-c4ccccc4)ccc1B3c1ccc(-c3ccccc3)cc1O2)c1cccc2c1oc1c(-c3ccccc3)cccc12 ; Cc1cc(-c2ccccc2)ccc1N(c1cc2c3c(c1)Oc1cc(-c4ccccc4)ccc1B3c1ccc(-c3ccccc3)cc1O2)c1cccc2c1oc1c(-c3ccccc3)cccc12]

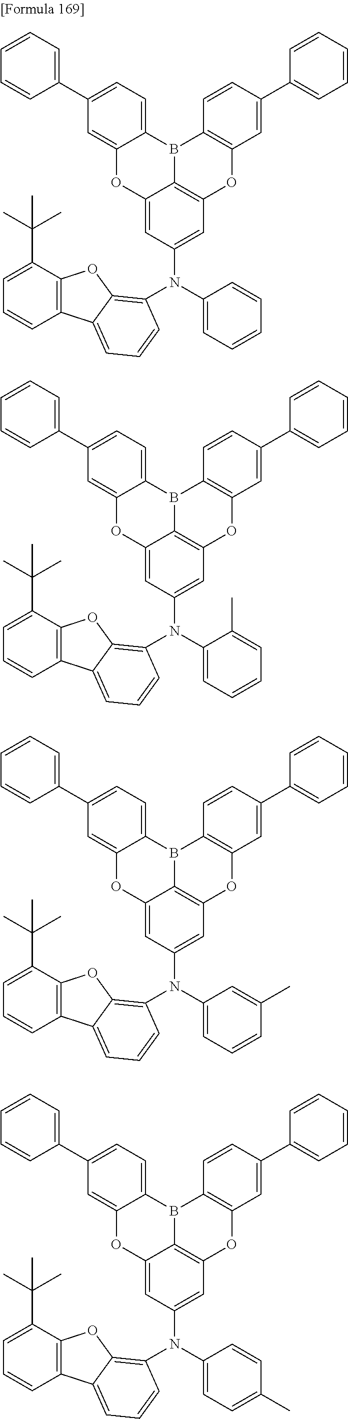 [SMILES: CC(C)(C)c1cccc2c1oc1c(N(c3ccccc3)c3cc4c5c(c3)Oc3cc(-c6ccccc6)ccc3B5c3ccc(-c5ccccc5)cc3O4)cccc12 ; Cc1ccccc1N(c1cc2c3c(c1)Oc1cc(-c4ccccc4)ccc1B3c1ccc(-c3ccccc3)cc1O2)c1cccc2c1oc1c(C(C)(C)C)cccc12 ; Cc1cccc(N(c2cc3c4c(c2)Oc2cc(-c5ccccc5)ccc2B4c2ccc(-c4ccccc4)cc2O3)c2cccc3c2oc2c(C(C)(C)C)cccc23)c1 ; Cc1ccc(N(c2cc3c4c(c2)Oc2cc(-c5ccccc5)ccc2B4c2ccc(-c4ccccc4)cc2O3)c2cccc3c2oc2c(C(C)(C)C)cccc23)cc1]

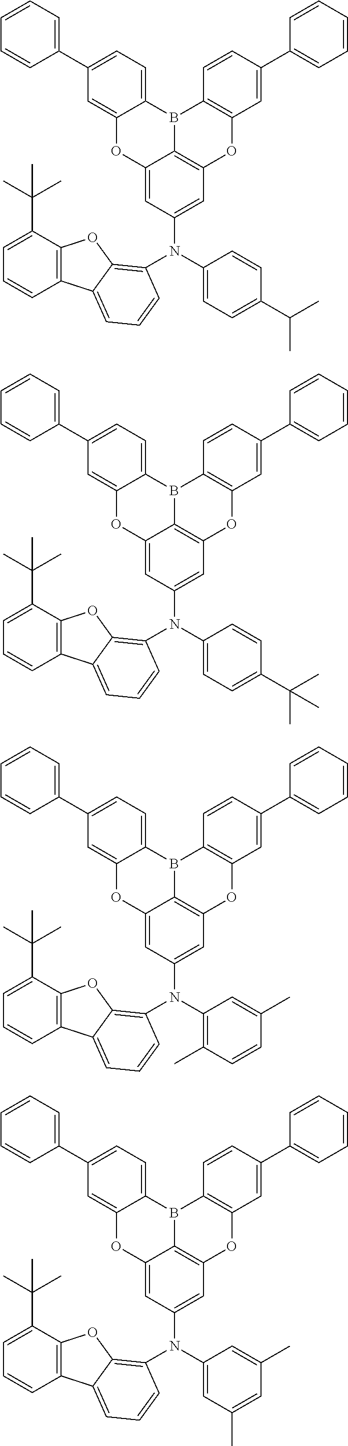

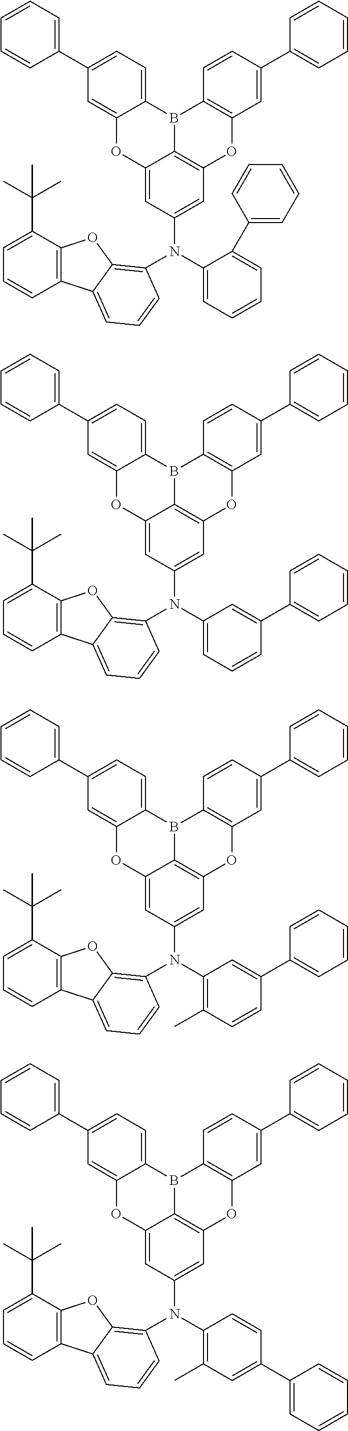 [SMILES: CC(C)(C)c1cccc2c1oc1c(N(c3cc4c5c(c3)Oc3cc(-c6ccccc6)ccc3B5c3ccc(-c5ccccc5)cc3O4)c3ccccc3-c3ccccc3)cccc12 ; CC(C)(C)c1cccc2c1oc1c(N(c3cccc(-c4ccccc4)c3)c3cc4c5c(c3)Oc3cc(-c6ccccc6)ccc3B5c3ccc(-c5ccccc5)cc3O4)cccc12 ; Cc1ccc(-c2ccccc2)cc1N(c1cc2c3c(c1)Oc1cc(-c4ccccc4)ccc1B3c1ccc(-c3ccccc3)cc1O2)c1cccc2c1oc1c(C(C)(C)C)cccc12 ; Cc1cc(-c2ccccc2)ccc1N(c1cc2c3c(c1)Oc1cc(-c4ccccc4)ccc1B3c1ccc(-c3ccccc3)cc1O2)c1cccc2c1oc1c(C(C)(C)C)cccc12]

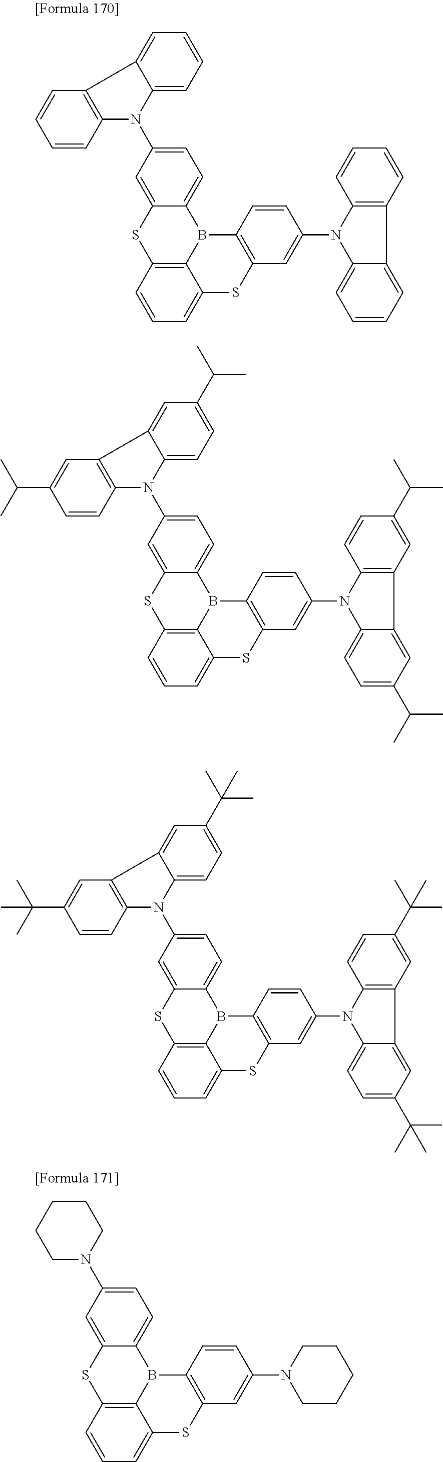

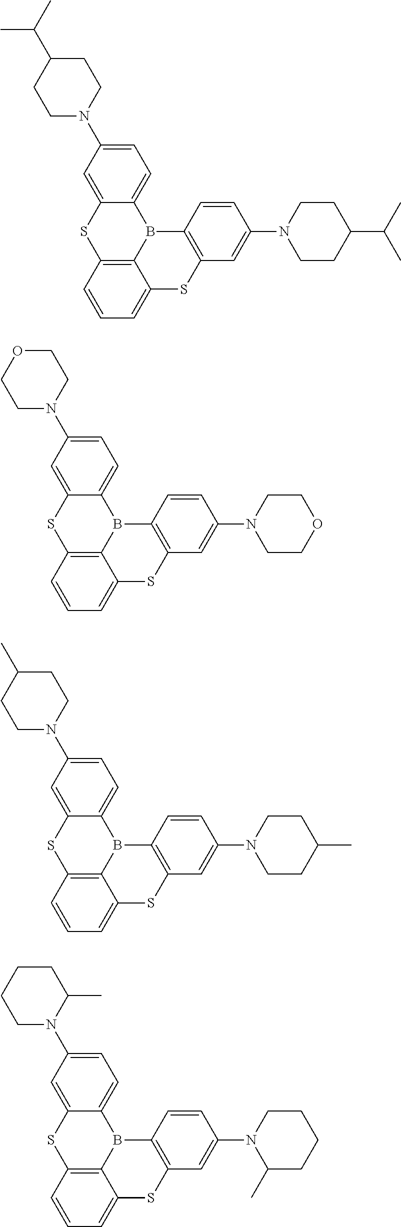

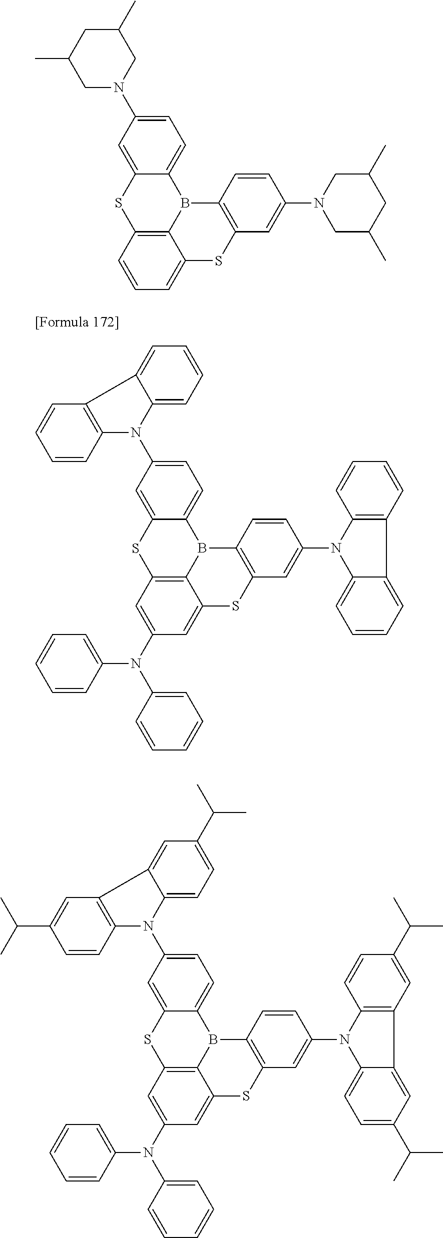

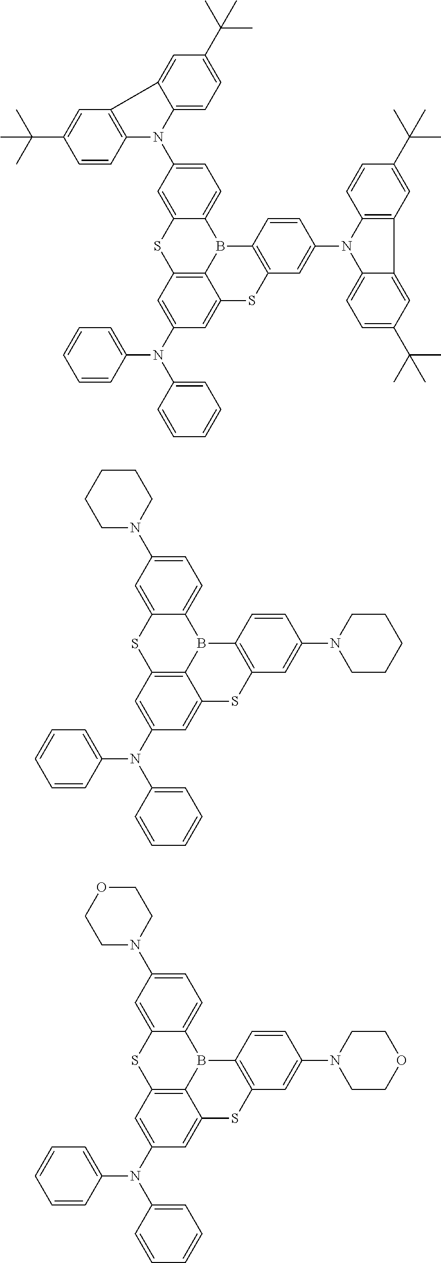

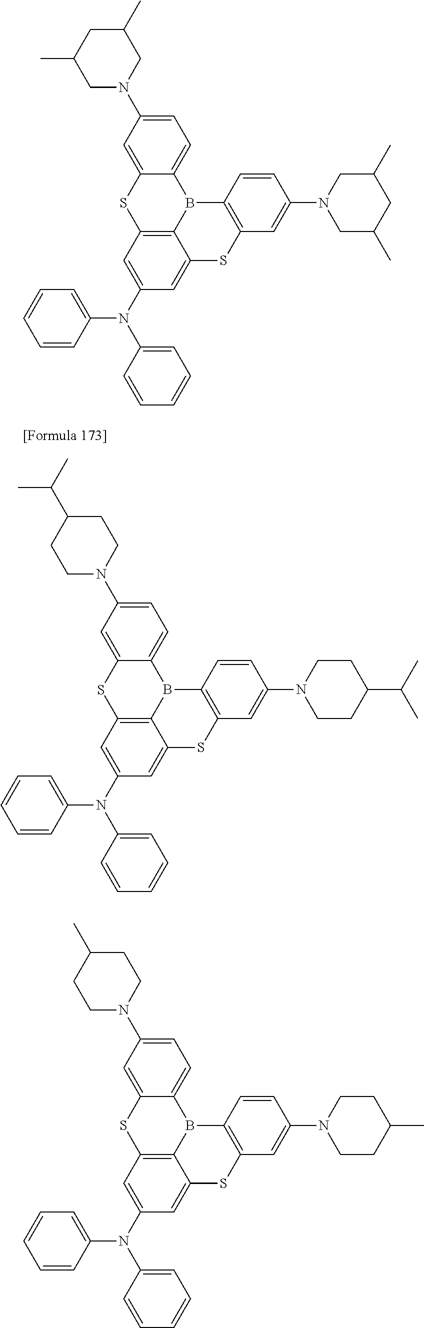 [SMILES: CC1CC(C)CN(c2ccc3c(c2)Sc2cc(N(c4ccccc4)c4ccccc4)cc4c2B3c2ccc(N3CC(C)CC(C)C3)cc2S4)C1 ; CC(C)C1CCN(c2ccc3c(c2)Sc2cc(N(c4ccccc4)c4ccccc4)cc4c2B3c2ccc(N3CCC(C(C)C)CC3)cc2S4)CC1 ; CC1CCN(c2ccc3c(c2)Sc2cc(N(c4ccccc4)c4ccccc4)cc4c2B3c2ccc(N3CCC(C)CC3)cc2S4)CC1]

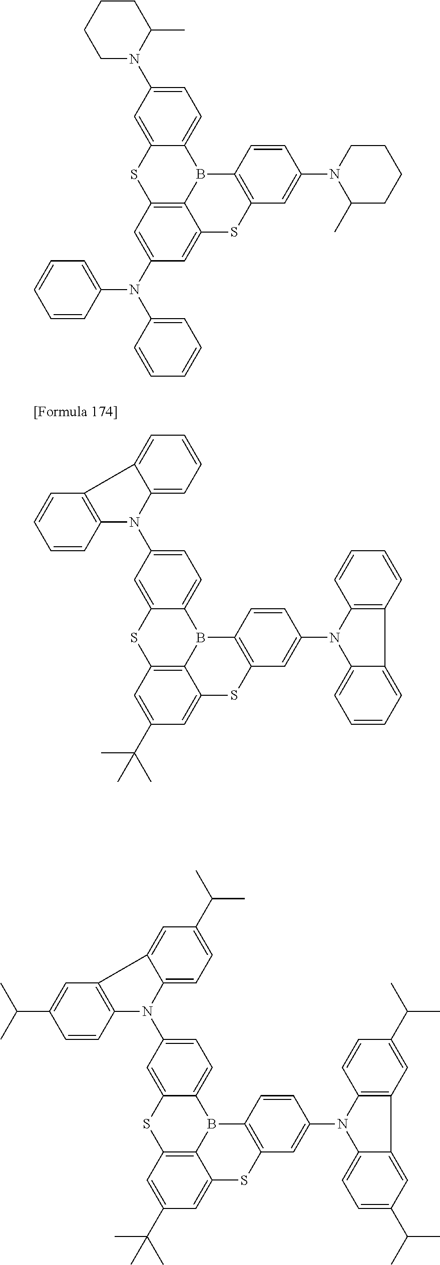 [SMILES: CC1CCCCN1c1ccc2c(c1)Sc1cc(N(c3ccccc3)c3ccccc3)cc3c1B2c1ccc(N2CCCCC2C)cc1S3 ; CC(C)(C)c1cc2c3c(c1)Sc1cc(-n4c5ccccc5c5ccccc54)ccc1B3c1ccc(-n3c4ccccc4c4ccccc43)cc1S2 ; CC(C)c1ccc2c(c1)c1cc(C(C)C)ccc1n2-c1ccc2c(c1)Sc1cc(C(C)(C)C)cc3c1B2c1ccc(-n2c4ccc(C(C)C)cc4c4cc(C(C)C)ccc42)cc1S3]

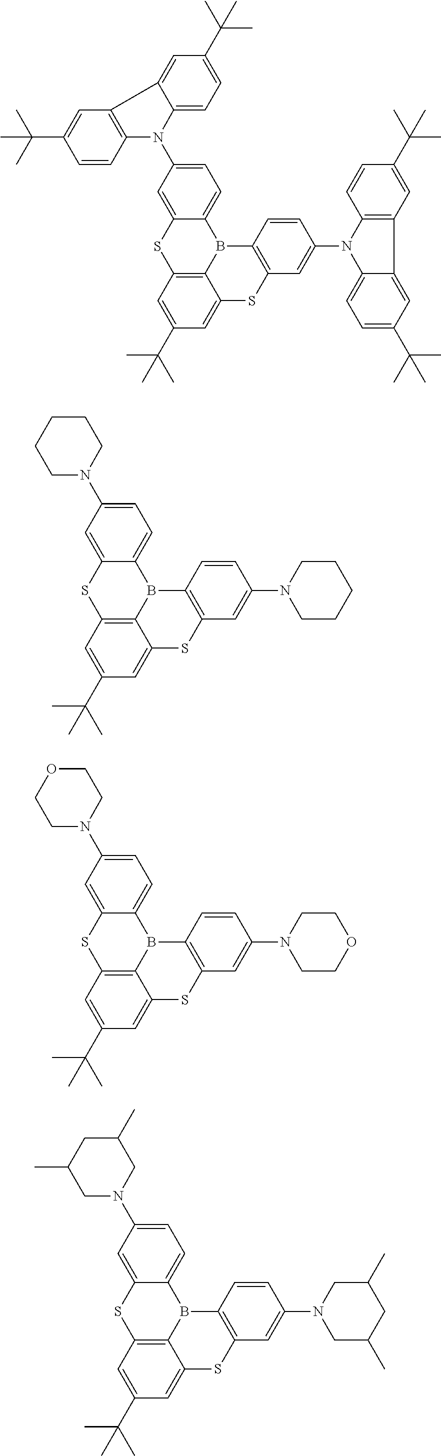

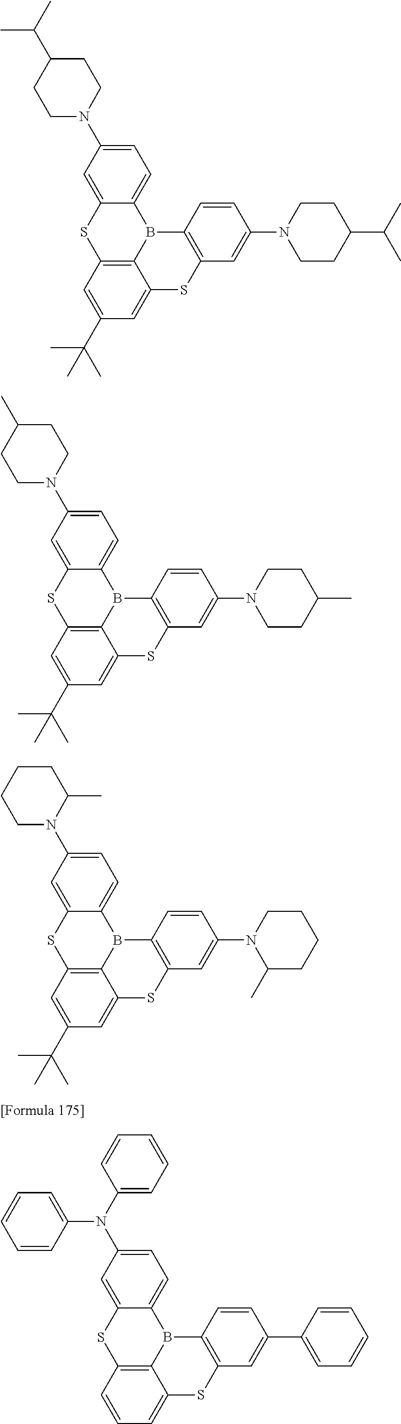

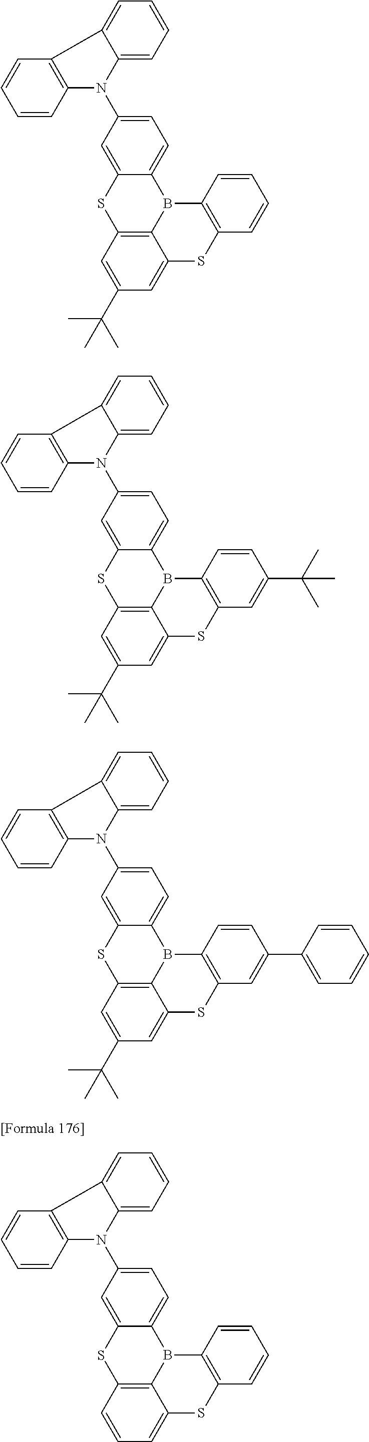

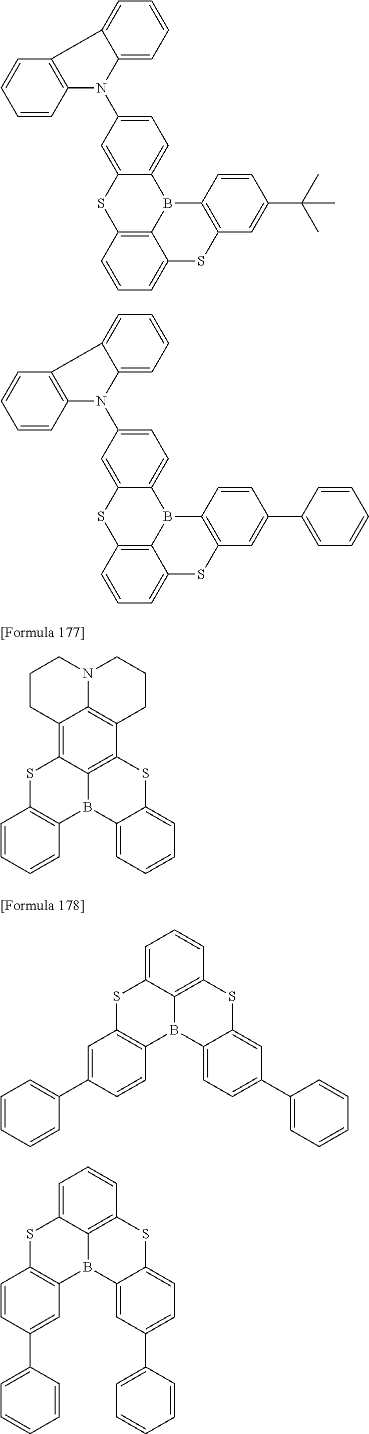

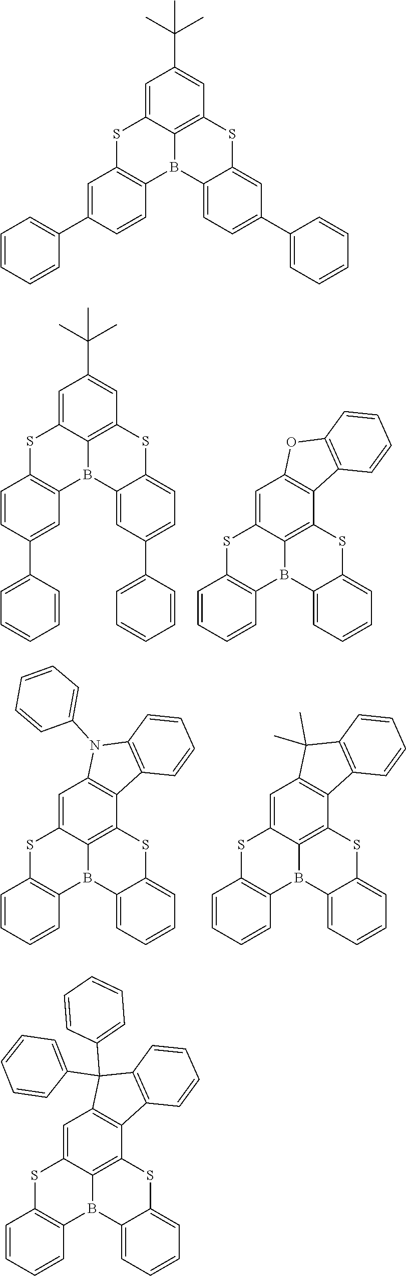

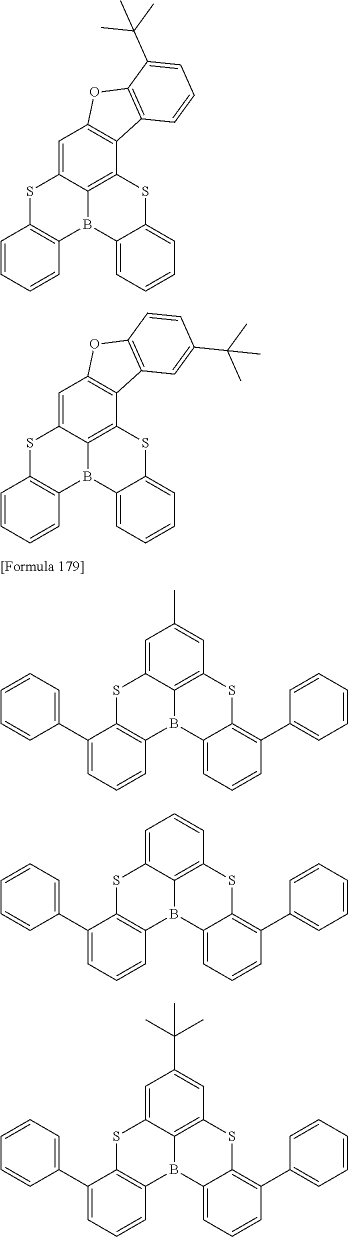

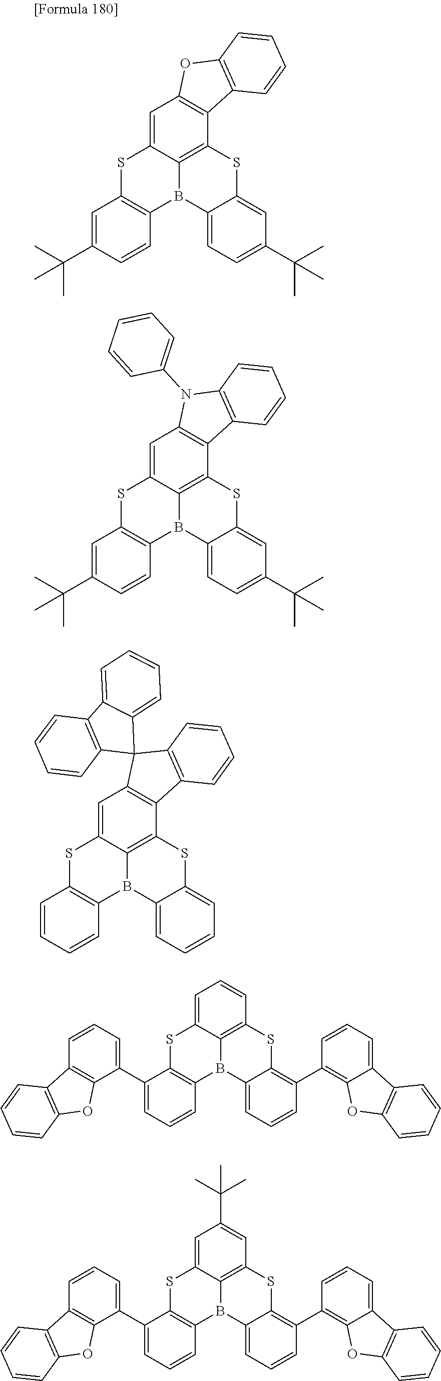

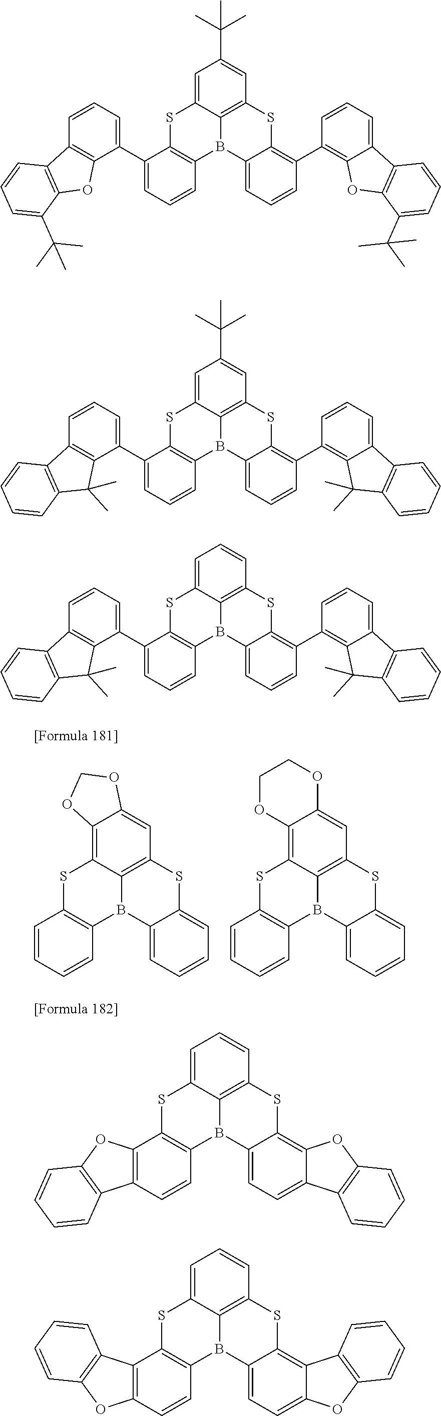

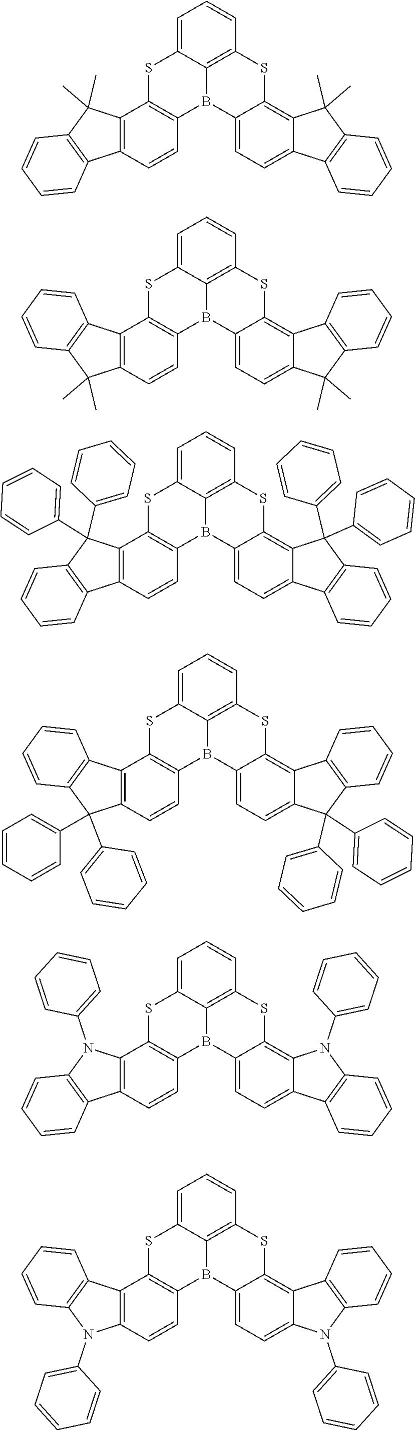

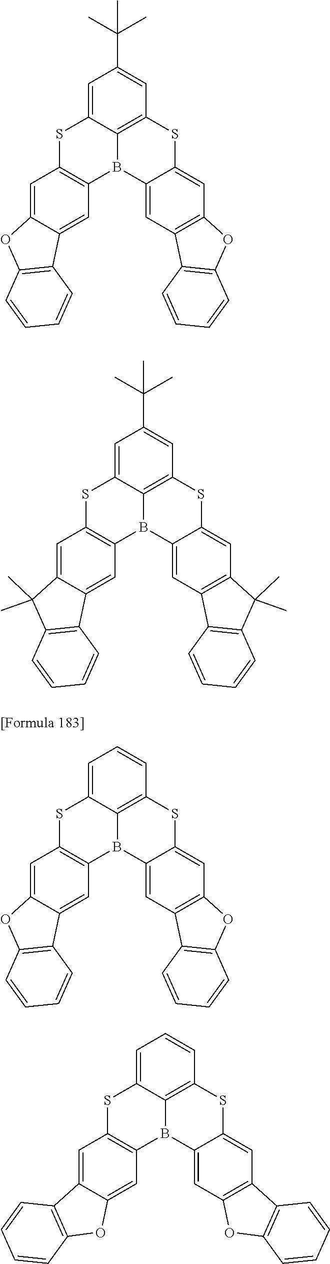

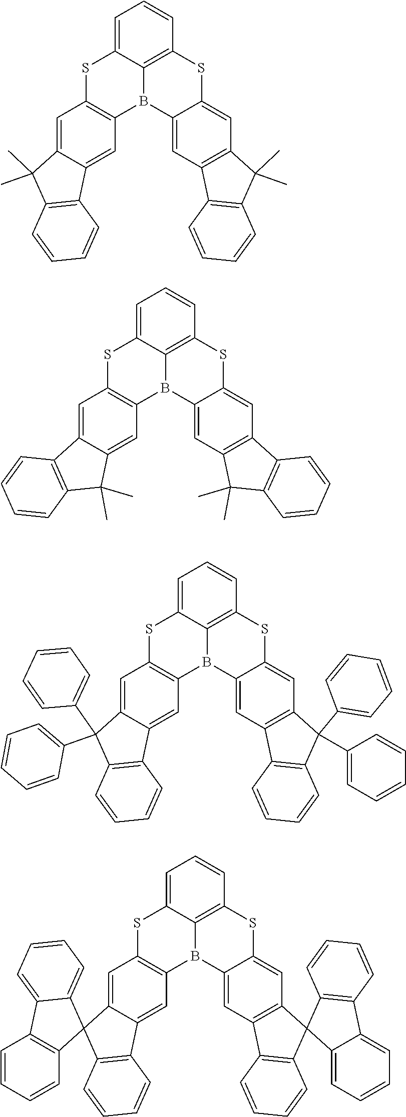

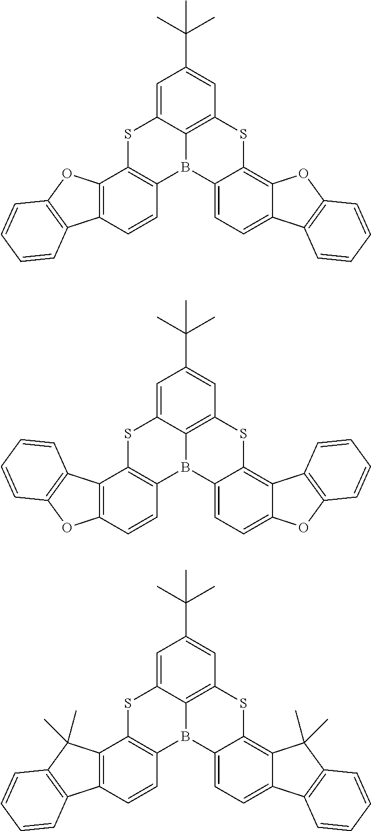 [SMILES: CC(C)(C)c1cc2c3c(c1)Sc1c(ccc4c1oc1ccccc14)B3c1ccc3c(oc4ccccc43)c1S2 ; CC(C)(C)c1cc2c3c(c1)Sc1c(ccc4oc5ccccc5c14)B3c1ccc3oc4ccccc4c3c1S2 ; CC(C)(C)c1cc2c3c(c1)Sc1c(ccc4c1C(C)(C)c1ccccc1-4)B3c1ccc3c(c1S2)C(C)(C)c1ccccc1-3]

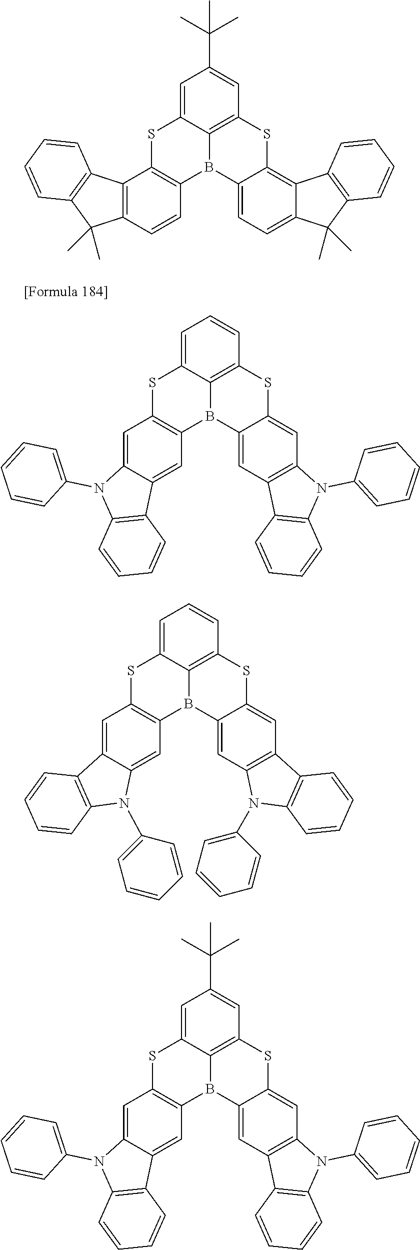

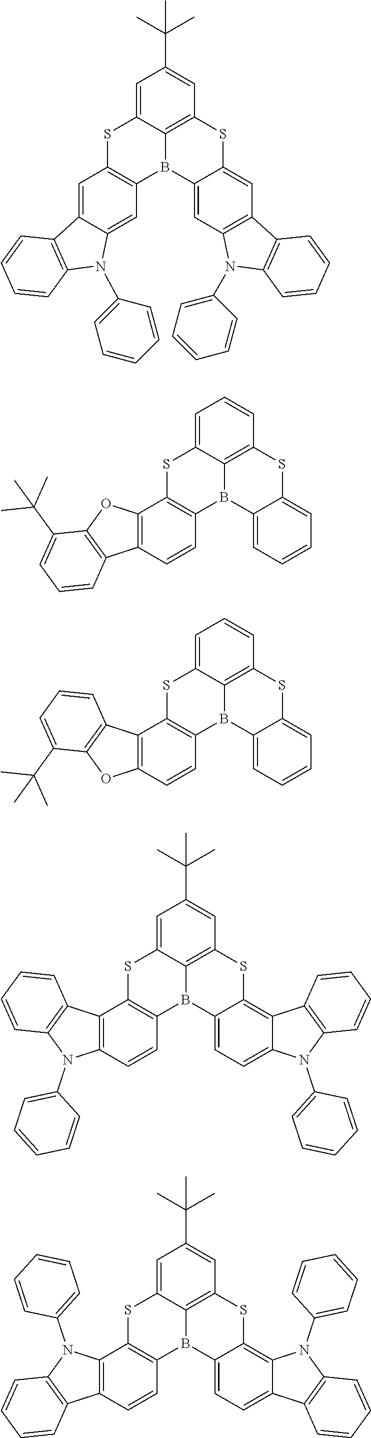

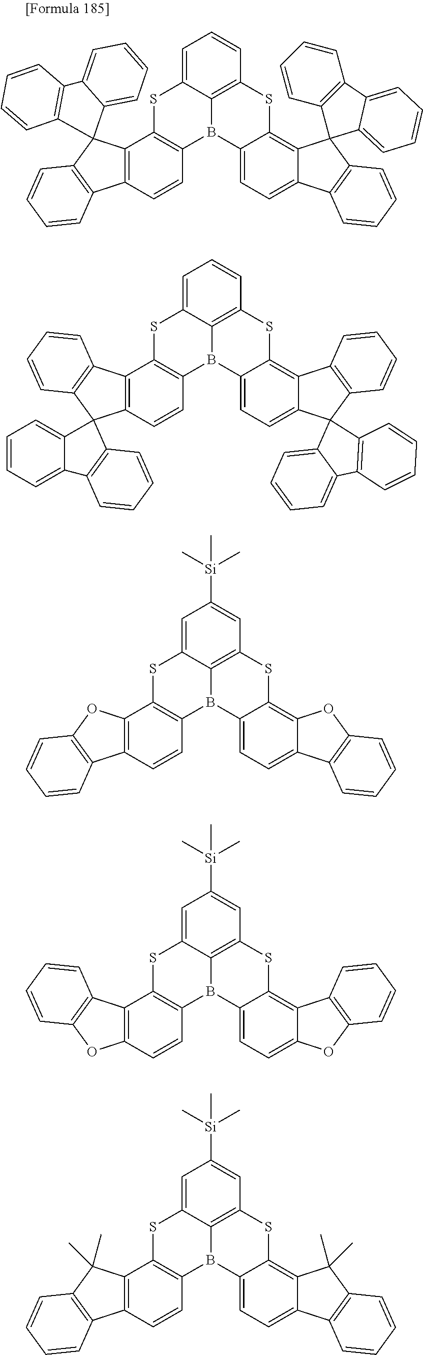 [SMILES: c1cc2c3c(c1)Sc1c(ccc4c1C1(c5ccccc5-c5ccccc51)c1ccccc1-4)B3c1ccc3c(c1S2)C1(c2ccccc2-c2ccccc21)c1ccccc1-3 ; c1cc2c3c(c1)Sc1c(ccc4c1-c1ccccc1C41c4ccccc4-c4ccccc41)B3c1ccc3c(c1S2)-c1ccccc1C31c2ccccc2-c2ccccc21 ; C[Si](C)(C)c1cc2c3c(c1)Sc1c(ccc4c1oc1ccccc14)B3c1ccc3c(oc4ccccc43)c1S2 ; C[Si](C)(C)c1cc2c3c(c1)Sc1c(ccc4oc5ccccc5c14)B3c1ccc3oc4ccccc4c3c1S2 ; CC1(C)c2ccccc2-c2ccc3c(c21)Sc1cc([Si](C)(C)C)cc2c1B3c1ccc3c(c1S2)C(C)(C)c1ccccc1-3]

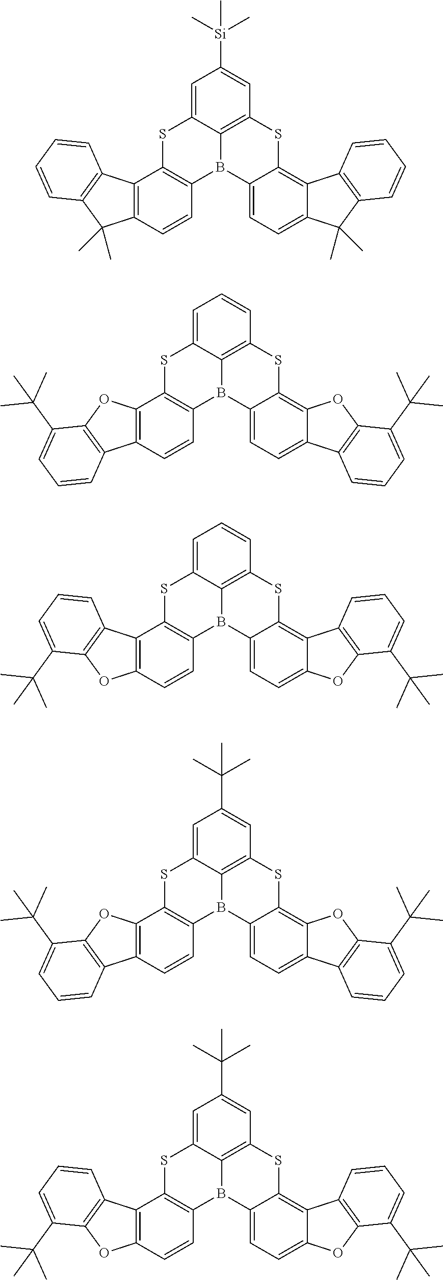

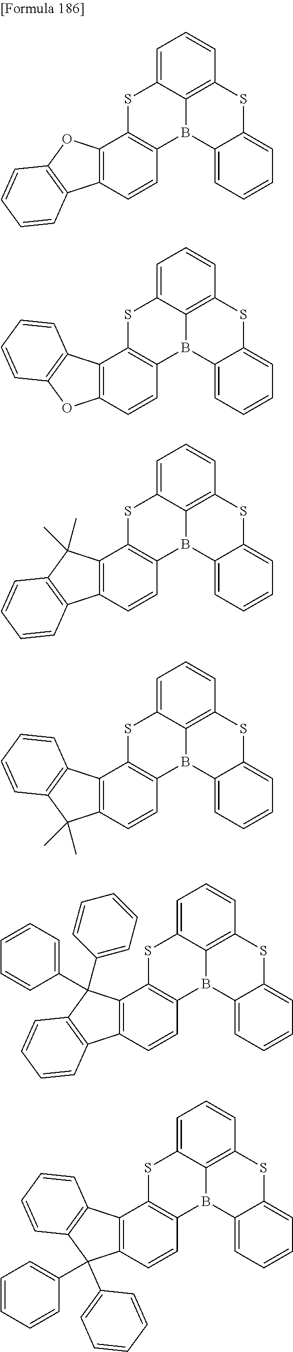 [SMILES: c1ccc2c(c1)Sc1cccc3c1B2c1ccc2c(oc4ccccc42)c1S3 ; c1ccc2c(c1)Sc1cccc3c1B2c1ccc2oc4ccccc4c2c1S3 ; CC1(C)c2ccccc2-c2ccc3c(c21)Sc1cccc2c1B3c1ccccc1S2 ; CC1(C)c2ccccc2-c2c1ccc1c2Sc2cccc3c2B1c1ccccc1S3 ; c1ccc(C2(c3ccccc3)c3ccccc3-c3ccc4c(c32)Sc2cccc3c2B4c2ccccc2S3)cc1 ; c1ccc(C2(c3ccccc3)c3ccccc3-c3c2ccc2c3Sc3cccc4c3B2c2ccccc2S4)cc1]

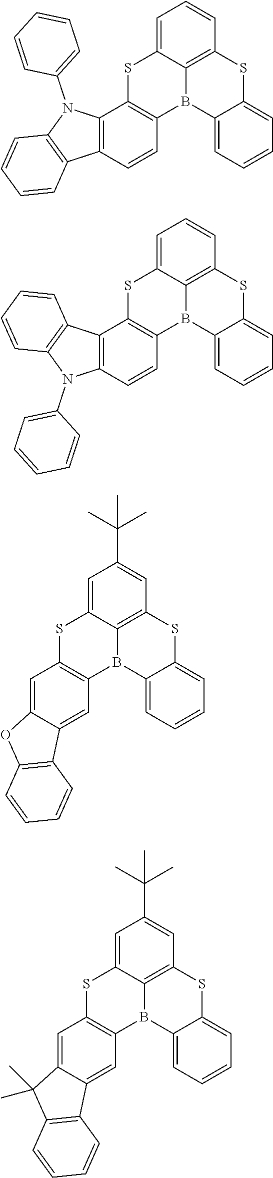 [SMILES: c1ccc(-n2c3ccccc3c3ccc4c(c32)Sc2cccc3c2B4c2ccccc2S3)cc1 ; c1ccc(-n2c3ccccc3c3c4c(ccc32)B2c3ccccc3Sc3cccc(c32)S4)cc1 ; CC(C)(C)c1cc2c3c(c1)Sc1cc4oc5ccccc5c4cc1B3c1ccccc1S2 ; CC(C)(C)c1cc2c3c(c1)Sc1cc4c(cc1B3c1ccccc1S2)-c1ccccc1C4(C)C]

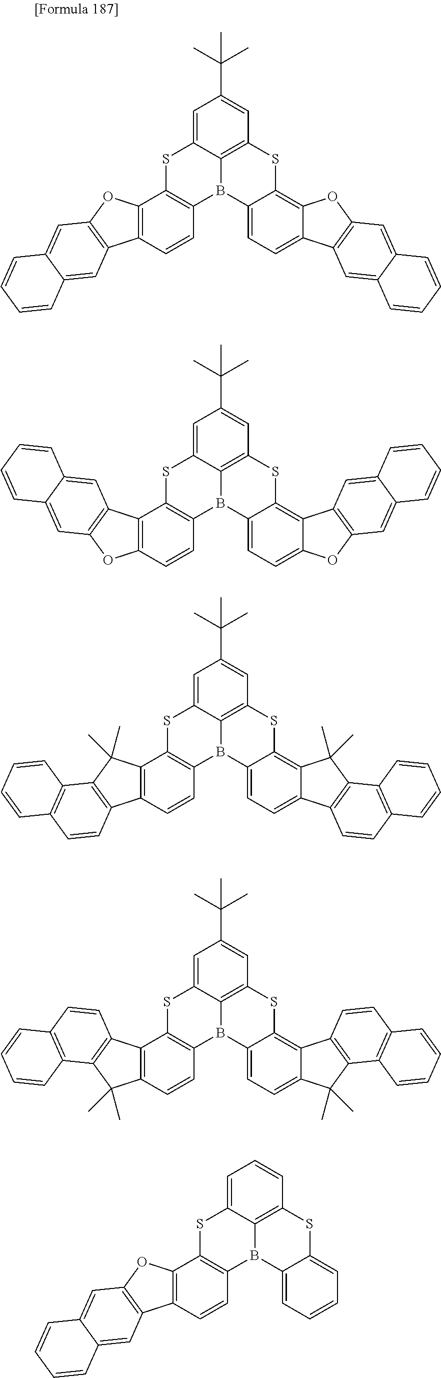 [SMILES: CC(C)(C)c1cc2c3c(c1)Sc1c(ccc4c1oc1cc5ccccc5cc14)B3c1ccc3c(oc4cc5ccccc5cc43)c1S2 ; CC(C)(C)c1cc2c3c(c1)Sc1c(ccc4oc5cc6ccccc6cc5c14)B3c1ccc3oc4cc5ccccc5cc4c3c1S2 ; CC(C)(C)c1cc2c3c(c1)Sc1c(ccc4c1C(C)(C)c1c-4ccc4ccccc14)B3c1ccc3c(c1S2)C(C)(C)c1c-3ccc2ccccc12 ; CC(C)(C)c1cc2c3c(c1)Sc1c(ccc4c1-c1ccc5ccccc5c1C4(C)C)B3c1ccc3c(c1S2)-c1ccc2ccccc2c1C3(C)C ; c1ccc2c(c1)Sc1cccc3c1B2c1ccc2c(oc4cc5ccccc5cc42)c1S3]

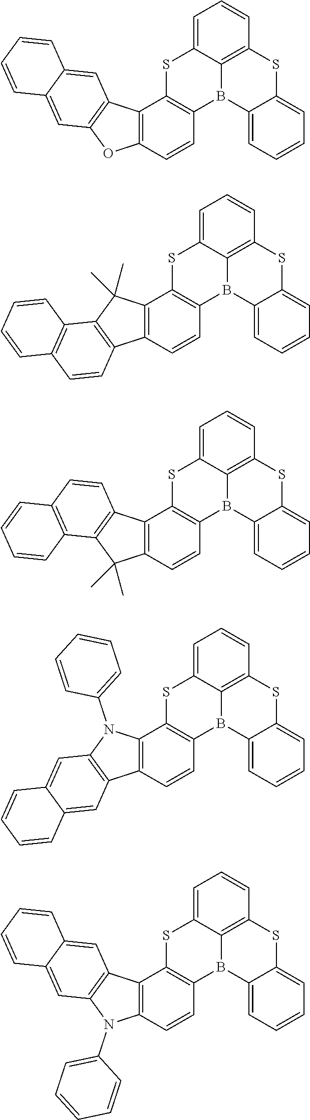 [SMILES: c1ccc2c(c1)Sc1cccc3c1B2c1ccc2oc4cc5ccccc5cc4c2c1S3 ; CC1(C)c2c(ccc3c2Sc2cccc4c2B3c2ccccc2S4)-c2ccc3ccccc3c21 ; CC1(C)c2ccc3c(c2-c2ccc4ccccc4c21)Sc1cccc2c1B3c1ccccc1S2 ; c1ccc(-n2c3cc4ccccc4cc3c3ccc4c(c32)Sc2cccc3c2B4c2ccccc2S3)cc1 ; c1ccc(-n2c3cc4ccccc4cc3c3c4c(ccc32)B2c3ccccc3Sc3cccc(c32)S4)cc1]

Relationship between First Compound and Second Compound in Emitting Layer

In the organic EL device 1 of the first exemplary embodiment, a singlet energy S₁(M1) of the first compound and a singlet energy S₁(M2) of the second compound preferably satisfy a relationship of a numerical formula (Numerical Formula 1) below.

S₁(M1)>S₁(M2) (Numerical Formula 1).

An energy gap T_{77K}(M1) at 77 [K] of the first compound is preferably larger than an energy gap T_{77K}(M2) at 77 [K] of the second compound. Specifically, a relationship represented by a numerical formula below (Numerical Formula 4) is preferably satisfied.

T_{77K}(M1)>T_{77K}(M2) (Numerical Formula 4)

When the organic EL device 1 of the first exemplary embodiment emits light, it is preferable that the second compound emits light in the emitting layer 5.

When the organic EL device 1 of the first exemplary embodiment emits light, it is more preferable that the second compound emits light and the other compound (i.e. a compound(s) other than the second compound) does not emit light in the emitting layer 5.

It has been known that an organic EL device using the compound represented by the formula (2) emits light with high efficiency. However, EQE (External Quantum Efficiency) is considerably decreased in a high-current-density area at or around 10 mA/cm² (i.e. a practical area). Accordingly, in order to solve the above problem, it is found in the invention that the first compound having the specifically selected molecular skeleton is contained in the emitting layer in addition to the compound (second compound) represented by the formula (2), whereby the compound represented by the formula (2) emits light with high efficiency in the high-current-density area and the lifetime of the device is increased. It should be noted that the first compound specifically selected in the invention is chemically stable in oxidation and reduction reactions.

The presence of the first compound having the molecular skeleton selected in the invention and the second compound represented by the formula (2) in the emitting layer allows highly efficient light emission in the high-current-density area. It is believed that a large number of radical species are generated in the high-current-density area due to the large amount of carriers (electrons and holes) injected into the emitting layer. It is speculated that the first compound having the molecular skeleton selected in the invention, which is chemically stable in oxidation and reduction reactions, generates less unstable radical species that cause quenching reaction with excitons contributing to light emission, and, consequently, the highly efficient light emission is maintained in the high-current-density area.

Further, it is believed that the first compound having the molecular skeleton selected in the invention, which is chemically stable in oxidation and reduction reactions, contributes to increase in the lifetime of the device. Preferable examples of the specific molecular structure exhibiting chemical stability in oxidation and reduction reactions include azine skeleton, cyano skeleton, and carbazole skeleton.

It should be noted that, in order to keep the high efficiency in the high-current-density area, it is especially preferable in the invention that an absorption spectrum of the compound represented by the formula (2) well overlaps (i.e. has a large overlapping area) with an emission spectrum of the first compound. Specifically, it is speculated that the first compound is preferably a compound represented by the formula (11E).

### Relationship Between Triplet Energy and Energy Gap at 77 [K]

Description will be made on a relationship between a triplet energy and an energy gap at 77 [K]. In the first exemplary embodiment, the energy gap at 77 [K] is different from a typically defined triplet energy in some aspects.

The triplet energy is measured as follows. Firstly, a target compound for measurement is dissolved in an appropriate solvent to prepare a solution and the solution is encapsulated in a quartz glass tube to prepare a sample. A phosphorescent spectrum (ordinate axis: phosphorescent luminous intensity, abscissa axis: wavelength) of the sample is measured at a low temperature (77K). A tangent is drawn to the rise of the phosphorescent spectrum on the short-wavelength side. The triplet energy is calculated by a predetermined conversion equation based on a wavelength value at an intersection of the tangent and the abscissa axis.

The delayed fluorescent compound usable in the first exemplary embodiment is preferably a compound having a small ΔST. When ΔST is small, intersystem crossing and inverse intersystem crossing are likely to occur even at a low temperature (77K), so that the singlet state and the triplet state coexist. As a result, the spectrum to be measured in the same manner as the above includes emission from both the singlet state and the triplet state. Although it is difficult to distinguish the emission from the singlet state from the emission from the triplet state, the value of the triplet energy is basically considered dominant.

Accordingly, in the first exemplary embodiment, the triplet energy is measured by the same method as a typical triplet energy T, but a value measured in the following manner is referred to as an energy gap T_{77K} in order to differentiate the measured energy from the typical triplet energy in a strict meaning. The measurement target compound is dissolved in EPA (diethyl ether:isopentane:ethanol=5:5:2 (by volume ratio)) such that a concentration of the compound becomes 10 μmol/L. The obtained solution is put into a quartz cell to provide a measurement sample. A phosphorescent spectrum (ordinate axis: phosphorescent luminous intensity, abscissa axis: wavelength) of the sample is measured at a low temperature (77K). A tangent is drawn to a rise of the phosphorescent spectrum on the short-wavelength side. An energy amount is calculated as an energy gap T_{77K} at 77[K] by the following conversion equation (F1) based on a wavelength value λ_{edge} [nm] at an intersection of the tangent and the abscissa axis.

T_{77K} [eV]=1239.85/λ_{edge} Conversion Equation (F1):

The tangent to the rise of the phosphorescence spectrum on the short-wavelength side is drawn as follows. While moving on a curve of the phosphorescence spectrum from the short-wavelength side to the maximum spectral value closest to the short-wavelength side among the maximum spectral values, a tangent is checked at each point on the curve toward the long-wavelength of the phosphorescence spectrum. An inclination of the tangent is increased as the curve rises (i.e., a value of the ordinate axis is increased). A tangent drawn at a point of the maximum inclination (i.e., a tangent at an inflection point) is defined as the tangent to the rise of the phosphorescence spectrum on the short-wavelength side.

The maximum with peak intensity being 15% or less of the maximum peak intensity of the spectrum is not included in the above-mentioned maximum closest to the short-wavelength side of the spectrum. The tangent drawn at a point of the maximum spectral value being closest to the short-wavelength side and having the maximum inclination is defined as a tangent to the rise of the phosphorescence spectrum on the short-wavelength side.

For phosphorescence measurement, a spectrophotofluorometer body F-4500 (manufactured by Hitachi High-Technologies Corporation) is usable. The measurement instrument is not limited to the above. A combination of a cooling unit, a low temperature container, an excitation light source and a light-receiving unit may be used for measurement.

### Singlet Energy S₁

A method of measuring a singlet energy S₁ using a solution (hereinafter, occasionally referred to as a solution method) is exemplified by a method below.

10 μmol/L of a toluene solution of the measurement target compound is prepared and put in a quartz cell to prepare a sample. An absorption spectrum (ordinate axis: luminous intensity, abscissa axis: wavelength) of the sample is measured at a normal temperature (300K). A tangent is drawn to the fall of the absorption spectrum on the long-wavelength side, and a wavelength value λedge [nm] at an intersection of the tangent and the abscissa axis is substituted in the following conversion equation (F2) to calculate a singlet energy.

S₁ [eV]=1239.85/λ_{edge} Conversion Equation (F2):

An absorption spectrum measurement device is not limited to but exemplified by a spectrophotometer (device name: U3310 manufactured by Hitachi, Ltd.).

The tangent to the fall of the absorption spectrum on the long-wavelength side is drawn as follows. While moving on a curve of the absorption spectrum from the maximum spectral value closest to the long-wavelength side in a long-wavelength direction, a tangent at each point on the curve was checked. An inclination of the tangent is decreased and increased in a repeated manner as the curve falls (i.e., a value of the ordinate axis is decreased). A tangent drawn at a point of the minimum inclination closest to the long-wavelength side (except when absorbance is 0.1 or less) is defined as the tangent to the fall of the absorption spectrum on the long-wavelength side.

The maximum absorbance of 0.2 or less is not included in the above-mentioned maximum absorbance on the long-wavelength side.

### Content Ratio of Compounds in Emitting Layer

A content ratio between the first compound and the second compound in the emitting layer 5 is preferably in an exemplary range below.

The content ratio of the first compound is preferably in a range from 90 mass % to 99.9 mass %, more preferably in a range from 95 mass % to 99.9 mass %, further preferably in a range from 99 mass % to 99.9 mass %.

The content ratio of the second compound is preferably in a range from 0.01 mass % to 10 mass %, more preferably in a range from 0.01 mass % to 5 mass %, further preferably in a range from 0.01 mass % to 1 mass %.

It should be noted that the emitting layer 5 of the exemplary embodiment may further contain material(s) other than the first and second compounds.

### Film Thickness of Emitting Layer

A film thickness of the emitting layer 5 is preferably in a range from 5 nm to 50 nm, more preferably in a range from 7 nm to 50 nm, and further preferably in a range from 10 nm to 50 nm. At 5 nm or more of the film thickness, the emitting layer 5 is easily formable and chromaticity of the emitting layer 5 is easily adjustable. When the film thickness of the emitting layer 5 is 50 nm or less, an increase in the drive voltage is suppressible.

### TADF Mechanism

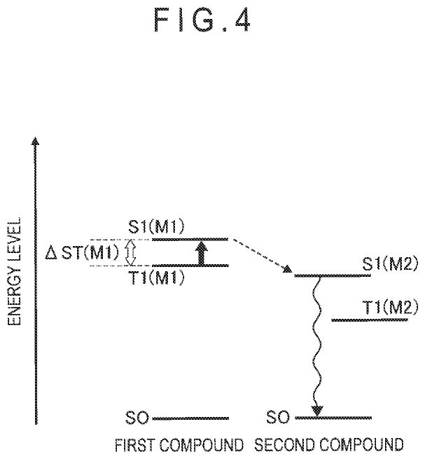

FIG. 4 shows an exemplary relationship between energy levels of the first and second compounds in the emitting layer. In FIG. 4, S0 represents a ground state. S1(M1) represents the lowest singlet state of the first compound. T1(M1) represents the lowest triplet state of the first compound. S1(M2) represents the lowest singlet state of the second compound. T1(M2) represents the lowest triplet state of the second compound.

A dashed arrow directed from S1(M1) to S1(M2) in FIG. 4 represents Förster energy transfer from the lowest singlet state of the first compound to the second compound.

As shown in FIG. 4, when a compound having a small ΔST(M1) is used as the first compound, inverse intersystem crossing from the lowest triplet state T1(M1) to the lowest singlet state S1(M1) can be caused by a heat energy. Accordingly, Förster energy transfer from the lowest singlet state S1(M1) of the first compound to the second compound is caused to generate the lowest singlet state S1(M2). As a result, fluorescence from the lowest singlet state S1(M2) of the second compound is observable. It is inferred that the internal quantum efficiency can be theoretically raised up to 100% also by using delayed fluorescence by the TADF mechanism.

### Substrate

A substrate 2 is used as a support for the organic EL device 1. For instance, glass, quartz, plastics and the like are usable for the substrate 2. A flexible substrate is also usable. The flexible substrate is a bendable substrate, which is exemplified by a plastic substrate. Examples of the material for the plastic substrate include polycarbonate, polyarylate, polyethersulfone, polypropylene, polyester, polyvinyl fluoride, polyvinyl chloride, polyimide, and polyethylene naphthalate. Moreover, an inorganic vapor deposition film is also usable.

### Anode

Preferable examples of a material for the anode 3 formed on the substrate 2 include metal, an alloy, an electroconductive compound, and a mixture thereof, which have a large work function (specifically, 4.0 eV or more). Specific examples of the material for the anode include ITO (Indium Tin Oxide), indium tin oxide containing silicon or silicon oxide, indium zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), or nitrides of the metal materials (e.g., titanium nitride) are usable.

The above materials are typically deposited as a film by sputtering. For instance, indium zinc oxide can be deposited as a film by sputtering using a target that is obtained by adding zinc oxide in a range from 1 mass % to 10 mass % to indium oxide. Moreover, for instance, indium oxide containing tungsten oxide and zinc oxide can be deposited as a film by sputtering using a target that is obtained by adding tungsten oxide in a range from 0.5 mass % to mass % and zinc oxide in a range from 0.1 mass % to 1 mass % to indium oxide. In addition, vapor deposition, coating, ink jet printing, spin coating and the like may be used for forming a film.

Among the organic layers formed on the anode 3, the hole injecting layer 6 formed in contact with the anode 3 is formed using a composite material that facilitates injection of holes irrespective of the work function of the anode 3. Accordingly, a material usable as an electrode material (e.g., metal, alloy, an electrically conductive compound, a mixture thereof, and elements belonging to Groups 1 and 2 of the periodic table of the elements) is usable as the material for the anode 3.

The elements belonging to Groups 1 and 2 of the periodic table of the elements, which are materials having a small work function, a rare earth metal and alloy thereof are also usable as the material for the anode 3. The elements belonging to Group 1 of the periodic table of the elements are alkali metal. The elements belonging to Group 2 of the periodic table of the elements are alkaline earth metal. Examples of alkali metal are lithium (Li) and cesium (Cs). Examples of alkaline earth metal are magnesium (Mg), calcium (Ca), and strontium (Sr). Examples of the rare earth metal are europium (Eu) and ytterbium (Yb). Examples of the alloys including these metals are MgAg and AlLi.

When the anode 3 is formed of the alkali metal, alkaline earth metal and alloy thereof, vapor deposition or sputtering is usable. Further, when the anode is formed of silver paste and the like, coating, ink jet printing or the like is usable.

### Hole Injecting Layer

The hole injecting layer 6 is a layer containing a highly hole-injectable substance. Examples of the highly hole-injectable substance include molybdenum oxide, titanium oxide, vanadium oxide, rhenium oxide, ruthenium oxide, chromium oxide, zirconium oxide, hafnium oxide, tantalum oxide, silver oxide, tungsten oxide, and manganese oxide.

In addition, the examples of the highly hole-injectable substance further include: an aromatic amine compound, which is a low-molecule compound, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl(abbreviation: DPAB), 4,4′-bis(N-{4-[N′-(3-methyl phenyl)-N′-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazole-3-yl)-N-phenylamino]-9-phenylcarbazole (abbreviation: PCzPCA1), 3,6-bis[N-(9-phenylcarbazole-3-yl)-N-phenylamino]-9-phenylcarbazole (abbreviation: PCzPCA2), and 3-[N-(1-naphthyl)-N-(9-phenylcarbazole-3-yl)amino]-9-phenylcarbazole (abbreviation: PCzPCN1); and dipyrazino[2,3-f:20,30-h]quinoxaline-2,3,6,7,10,11-hexacarbonitrile (HAT-CN).

Moreover, a high-molecule compound is also usable as the highly hole-injectable substance. Examples of the high-molecule compound are an oligomer, dendrimer and polymer. Specific examples of the high-molecule compound include poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamido](abbreviation: PTPDMA), and poly[N,N′-bis(4-butylphenyl)-N,N′-bis(phenyl)benzidine] (abbreviation: Poly-TPD). Furthermore, the examples of the high-molecule compound include a high-molecule compound added with an acid such as poly(3,4-ethylene dioxythiophene)/poly(styrene sulfonic acid) (PEDOT/PSS), and polyaniline/poly(styrene sulfonic acid) (PAni/PSS).

### Hole Transporting Layer

The hole transporting layer 7 is a layer containing a highly hole-transportable substance. An aromatic amine compound, carbazole derivative, anthracene derivative and the like are usable for the hole transporting layer 7. Specific examples of a material for the hole transporting layer include 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4-phenyl-4′-(9-phenylfluorene-9-yl)triphenylamine (abbreviation: BAFLP), 4,4′-bis[N-(9,9-dimethylfluorene-2-yl)-N-phenylamino]biphenyl (abbreviation: DFLDPBi), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluorene-2-yl)-N-phenylamino]biphenyl (abbreviation: BSPB). The above-described substances mostly have a hole mobility of 10⁻⁶ cm²/(V·s) or more.

A carbazole derivative (e.g., CBP, 9-[4-(N-carbazolyl)]phenyl-10-phenylanthracene (CzPA), and 9-phenyl-3-[4-(10-phenyl-9-anthryl)phenyl]-9H-carbazole (PCzPA)), an anthracene derivative (e.g., t-BuDNA, DNA, and DPAnth) and the like may be used for the hole transporting layer 7. A high polymer compound such as poly(N-vinylcarbazole) (abbreviation: PVK) and poly(4-vinyltriphenylamine) (abbreviation: PVTPA) is also usable.

However, any substance having a hole transporting performance higher than an electron transporting performance may be used in addition to the above substances. A highly hole-transportable substance may be provided in the form of a single layer or a laminated layer of two or more layers of the above substance(s).

When the hole transporting layer includes two or more layers, one of the layers with a larger energy gap is preferably provided closer to the emitting layer 5.

### Electron Transporting Layer

The electron transporting layer 8 is a layer containing a highly electron-transportable substance. As the electron transporting layer 8, (1) a metal complex such as an aluminum complex, beryllium complex and zinc complex, (2) a heteroaromatic compound such as an imidazole derivative, benzimidazole derivative, azine derivative, carbazole derivative, and phenanthroline derivative, and (3) a high-molecule compound are usable. Specifically, as a low-molecule organic compound, a metal complex such as Alq, tris(4-methyl-8-quinolinato)aluminum (abbreviation: Almq₃), bis(10-hydroxybenzo[h]quinolinato)beryllium (abbreviation: BeBq₂), BAlq, Znq, ZnPBO and ZnBTZ are usable. In addition to the metal complex, a heteroaromatic compound such as 2-(4-biphenyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenyl)-1,2,4-triazole (abbreviation: TAZ), 3-(4-tert-butylphenyl)-4-(4-ethylphenyl)-5-(4-biphenyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation: BzOs) are usable. In the first exemplary embodiment, a benzimidazole compound is suitably usable. The above-described substances mostly have an electron mobility of 10⁻⁶ cm²/(V·s) or more. However, any substance having an electron transporting performance higher than a hole transporting performance may be used for the electron transporting layer 8 in addition to the above substances. The electron transporting layer 8 may be provided in the form of a single layer or a laminated layer of two or more layers of the above substance(s).

Moreover, a high-molecule compound is also usable for the electron transporting layer 8. For instance, poly[(9,9-dihexylfluorene-2,7-diyl)-co-(pyridine-3,5-diyl)] (abbreviation: PF-Py), poly[(9,9-dioctylfluorene-2,7-diyl)-co-(2,2′-bipyridine-6,6′-diyl)] (abbreviation: PF-BPy) and the like are usable.

### Electron Injecting Layer

The electron injecting layer 9 is a layer containing a highly electron-injectable substance. For the electron injecting layer 9, an alkali metal, alkaline earth metal or a compound thereof are usable, examples of which include lithium (Li), cesium (Cs), calcium (Ca), lithium fluoride (LiF), cesium fluoride (CsF), calcium fluoride (CaF2), and lithium oxide (LiOx). In addition, a substance obtained by blending an alkali metal, alkaline earth metal or a compound thereof in the electron transportable substance, specifically, for instance, a substance obtained by blending magnesium (Mg) in Alq may be used. With this substance, electrons can be more efficiently injected from the cathode 4.

Alternatively, a composite material provided by mixing an organic compound with an electron donor may be used for the electron injecting layer 9. The composite material exhibits excellent electron injecting performance and electron transporting performance since the electron donor generates electrons in the organic compound. In this arrangement, the organic compound is preferably a material exhibiting excellent transporting performance of the generated electrons. Specifically, for instance, the above-described substance for the electron transporting layer 8 (e.g., the metal complex and heteroaromatic compound) is usable. The electron donor may be any substance exhibiting electron donating performance to the organic compound. Specifically, an alkali metal, an alkaline earth metal and a rare earth metal are preferable, examples of which include lithium, cesium, magnesium, calcium, erbium and ytterbium. Moreover, an alkali metal oxide or alkaline earth metal oxide is preferably used as the electron donor, examples of which include lithium oxide, calcium oxide, and barium oxide. Further, Lewis base such as magnesium oxide is also usable. Furthermore, an organic compound such as tetrathiafulvalene (abbreviation: TTF) is also usable.

### Cathode

Metal, alloy, an electrically conductive compound, a mixture thereof and the like, which have a small work function, specifically, of 3.8 eV or less, are preferably usable as a material for the cathode 4. Specific examples of the material for the cathode are the elements belonging to Groups 1 and 2 of the periodic table of the elements, a rare earth metal and alloys thereof. The elements belonging to Group 1 of the periodic table of the elements are alkali metal. The elements belonging to Group 2 of the periodic table of the elements are alkaline earth metal. Examples of alkali metal are lithium (Li) and cesium (Cs). Examples of alkaline earth metal are magnesium (Mg), calcium (Ca), and strontium (Sr). Examples of the rare earth metal are europium (Eu) and ytterbium (Yb). Examples of the alloys including these metals are MgAg and AlLi.

When the cathode 4 is formed of the alkali metal, alkaline earth metal and alloy thereof, vapor deposition or sputtering is usable. Further, when the anode is formed of silver paste and the like, coating, ink jet printing or the like is usable.

By providing the electron injecting layer 9, various conductive materials such as Al, Ag, ITO, graphene and indium tin oxide containing silicon or silicon oxide are usable for forming the cathode 4 irrespective of the magnitude of the work function. The conductive materials can be deposited as a film by sputtering, ink jet printing, spin coating and the like.

### Layer Formation Method(s)

A method for forming each layer of the organic EL device 1 in the exemplary embodiment is subject to no limitation except for the above particular description, where known methods such as dry film-forming and wet film-forming are applicable. Examples of the dry film-forming include vacuum deposition, sputtering, plasma and ion plating. Examples of the wet film-forming include spin coating, dipping, flow coating and ink-jet.

### Film Thickness

There is no restriction except for the above particular description for a film thickness of each of the organic layers of the organic EL device 1 in the first exemplary embodiment. The thickness is usually preferably in a range from several nanometers to 1 μm in order to cause less defects (e.g., pin holes) and prevent deterioration in the efficiency due to the necessity in applying high voltage.

Herein, numerical ranges defined with the use of “to” means a range whose lower limit is a value recited before “to” and whose upper limit is a value recited after “to.”

Herein, the number of carbon atoms forming a ring (also referred to as ring carbon atoms) means the number of carbon atoms included in atoms forming the ring itself of a compound in which the atoms are bonded to form the ring (e.g., a monocyclic compound, a fused ring compound, a cross-linked compound, a carbocyclic compound, and a heterocyclic compound). When the ring is substituted by a substituent, carbon atom(s) included in the substituent is not counted as the ring carbon atoms. The same applies to the “ring carbon atoms” described below, unless particularly noted. For instance, a benzene ring has 6 ring carbon atoms, a naphthalene ring has 10 ring carbon atoms, a pyridinyl group has 5 ring carbon atoms, and a furanyl group has 4 ring carbon atoms. When a benzene ring or a naphthalene ring is substituted, for instance, by an alkyl group, the carbon atoms of the alkyl group are not counted as the ring carbon atoms. For instance, when a fluorene ring (inclusive of a spirofluorene ring) is bonded as a substituent to a fluorene ring, the carbon atoms of the fluorene ring as a substituent are not counted as the ring carbon atoms.

Herein, the number of atoms forming a ring (also referred to as ring atoms) means the number of atoms forming the ring itself of a compound in which the atoms are bonded to form the ring (e.g., a monocyclic compound, a fused ring compound, a cross-linked compound, a carbocyclic compound, and a heterocyclic compound). Atom(s) not forming the ring and atom(s) included in the substituent substituting the ring are not counted as the ring atoms. The same applies to the “ring atoms” described below, unless particularly noted. For instance, a pyridine ring has 6 ring atoms, a quinazoline ring has 10 ring atoms, and a furan ring has 5 ring atoms. Hydrogen atoms bonded to carbon atoms of each of the pyridine ring or the quinazoline ring and atoms forming a substituent are not counted as the ring atoms. For instance, when a fluorene ring (inclusive of a spirofluorene ring) is bonded as a substituent to a fluorene ring, the atoms of the fluorene ring as a substituent are not counted as the ring atoms.

Next, each of substituents described in the above formulae will be described.

Examples of the aryl group having 6 to 30 ring carbon atoms (occasionally referred to as an aromatic hydrocarbon group) herein are a phenyl group, biphenyl group, terphenyl group, naphthyl group, anthryl group, phenanthryl group, fluorenyl group, pyrenyl group, chrysenyl group, fluoranthenyl group, benz[a]anthryl group, benzo[c]phenanthryl group, triphenylenyl group, benzo[k]fluoranthenyl group, benzo[g]chrysenyl group, benzo[b]triphenylenyl group, picenyl group, and perylenyl group.

Herein, the aryl group preferably has 6 to 20 ring carbon atoms, more preferably 6 to 14 ring carbon atoms, further preferably 6 to 12 ring carbon atoms, unless otherwise defined. Among the aryl group, a phenyl group, biphenyl group, naphthyl group, phenanthryl group, terphenyl group and fluorenyl group are particularly preferable. A carbon atom at a position 9 of each of 1-fluorenyl group, 2-fluorenyl group, 3-fluorenyl group and 4-fluorenyl group is preferably substituted by at least one group selected from the group consisting of a substituted or unsubstituted alkyl group having 1 to 30 carbon atoms and a substituted or unsubstituted aryl group having 6 to 18 ring carbon atoms later described in the exemplary embodiment.

The heteroaryl group (occasionally, referred to as heterocyclic group, heteroaromatic ring group or aromatic heterocyclic group) having 5 to 30 ring atoms preferably contains at least one atom selected from the group consisting of nitrogen, sulfur, oxygen, silicon, selenium atom and germanium atom, and more preferably contains at least one atom selected from the group consisting of nitrogen, sulfur and oxygen.

Examples of the heterocyclic group having 5 to 30 ring atoms in the first exemplary embodiment are a pyridyl group, pyrimidinyl group, pyrazinyl group, pyridazynyl group, triazinyl group, quinolyl group, isoquinolinyl group, naphthyridinyl group, phthalazinyl group, quinoxalinyl group, quinazolinyl group, phenanthridinyl group, acridinyl group, phenanthrolinyl group, pyrrolyl group, imidazolyl group, pyrazolyl group, triazolyl group, tetrazolyl group, indolyl group, benzimidazolyl group, indazolyl group, imidazopyridinyl group, benzotriazolyl group, carbazolyl group, furyl group, thienyl group, oxazolyl group, thiazolyl group, isoxazolyl group, isothiazolyl group, oxadiazolyl group, thiadiazolyl group, benzofuranyl group, benzothienyl group, benzoxazolyl group, benzothiazolyl group, benzisoxazolyl group, benzisothiazolyl group, benzoxadiazolyl group, benzothiadiazolyl group, dibenzofuranyl group, dibenzothienyl group, piperidinyl group, pyrrolidinyl group, piperazinyl group, morpholyl group, phenazinyl group, phenothiazinyl group, and phenoxazinyl group.

Herein, the heterocyclic group preferably has 5 to 20 ring atoms, more preferably 5 to 14 ring atoms. Among the above heterocyclic group, a 1-dibenzofuranyl group, 2-dibenzofuranyl group, 3-dibenzofuranyl group, 4-dibenzofuranyl group, 1-dibenzothienyl group, 2-dibenzothienyl group, 3-dibenzothienyl group, 4-dibenzothienyl group, 1-carbazolyl group, 2-carbazolyl group, 3-carbazolyl group, 4-carbazolyl group, and 9-carbazolyl group are further preferable. A nitrogen atom at a position 9 of each of 1-carbazolyl group, 2-carbazolyl group, 3-carbazolyl group and 4-carbazolyl group is preferably substituted by at least one group selected from the group consisting of a substituted or unsubstituted aryl group having 6 to 30 ring carbon atoms and a substituted or unsubstituted heterocyclic group having 5 to 30 ring atoms described herein.

Herein, the heterocyclic group may be a group derived from any one of partial structures represented by formulae (XY-1) to (XY-18).

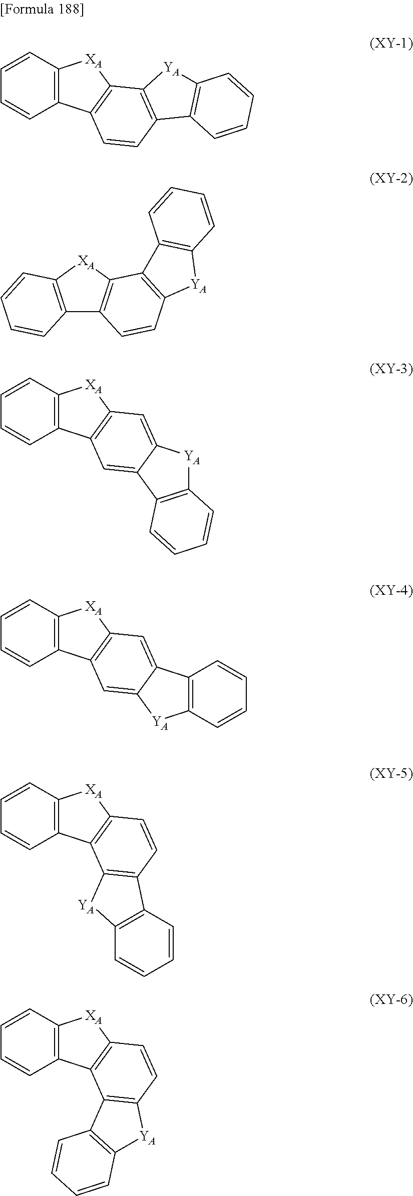

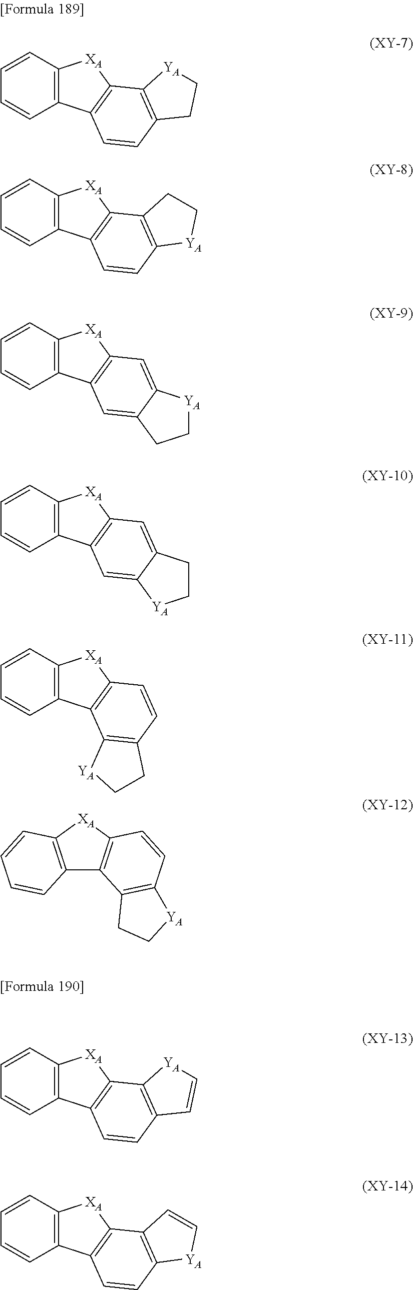

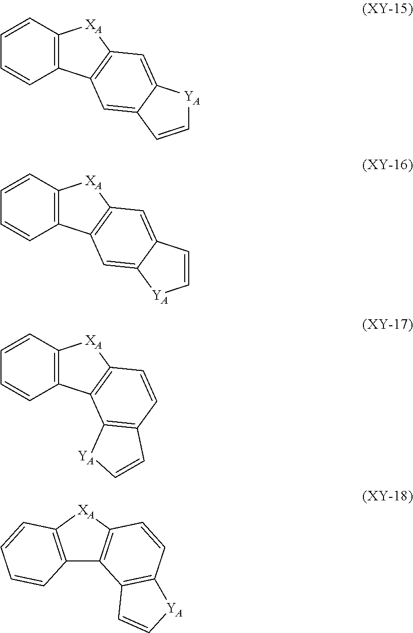

In the formulae (XY-1) to (XY-18), X_{A} and Y_{A} are each independently a hetero atom, and are preferably an oxygen atom, sulfur atom, selenium atom, silicon atom or germanium atom. The partial structures represented by the formulae (XY-1) to (XY-18) may each have a bond(s) in any position to become a heterocyclic group, in which the heterocyclic group may be substituted.

Herein, examples of the substituted or unsubstituted carbazolyl group may include a group in which a carbazole ring is further fused with a ring(s) as shown in the following formulae. Such a group may be substituted. The group may be bonded in any position as desired.

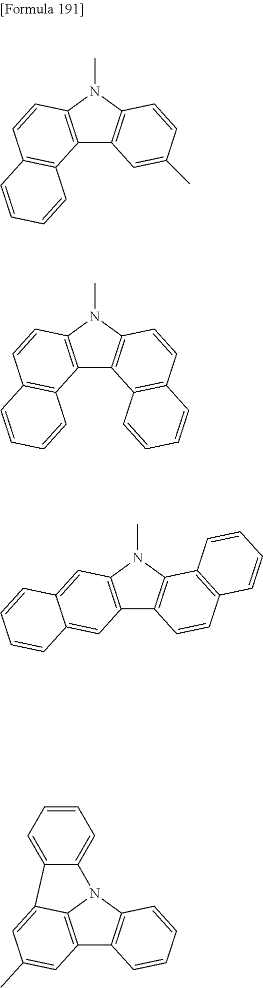

The alkyl group having 1 to 30 carbon atoms herein may be linear, branched or cyclic. Alternatively, the alkyl group having 1 to 30 carbon atoms herein may be an alkyl halide group.

Examples of the linear or branched alkyl group include: a methyl group, ethyl group, n-propyl group, isopropyl group, n-butyl group, s-butyl group, isobutyl group, t-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, neopentyl group, amyl group, isoamyl group, 1-methylpentyl group, 2-methylpentyl group, 1-pentylhexyl group, 1-butylpentyl group, 1-heptyloctyl group, and 3-methylpentyl group.

Herein, the linear or branched alkyl group preferably has 1 to 10 carbon atoms, more preferably 1 to 6 carbon atoms. Among the linear or branched alkyl group, a methyl group, ethyl group, propyl group, isopropyl group, n-butyl group, s-butyl group, isobutyl group, t-butyl group, n-pentyl group, n-hexyl group, amyl group, isoamyl group and neopentyl group are further preferable.

Examples of the cyclic alkyl group herein include a cycloalkyl group having 3 to 30 ring carbon atoms.

Examples of the cycloalkyl group having 3 to 30 herein are a cyclopropyl group, cyclobutyl group, cyclopentyl group, cyclohexyl group, 4-metylcyclohexyl group, adamantyl group and norbornyl group. The cycloalkyl group preferably has 3 to 10 ring carbon atoms, more preferably 5 to 8 ring carbon atoms. Among the cycloalkyl group, a cyclopentyl group or a cyclohexyl group is further preferable.

Herein, examples of the alkyl halide group provided by substituting an alkyl group with a halogen atom include an alkyl halide group provided by substituting the above alkyl group having 1 to 30 carbon atoms with one or more halogen atoms, preferably a fluorine atom(s).

Herein, examples of the alkyl halide group having 1 to 30 carbon atoms include a fluoromethyl group, difluoromethyl group, trifluoromethyl group, fluoroethyl group, trifiuoromethylmethyl group, trifluoroethyl group and pentafluoroethyl group.

Herein, examples of the substituted silyl group include an alkylsilyl group having 3 to 30 carbon atoms and an arylsilyl group having 6 to 30 ring carbon atoms.

The alkylsilyl group having 3 to 30 carbon atoms herein is exemplified by a trialkylsilyl group having the above examples of the alkyl group having 1 to 30 carbon atoms. Specific examples of the alkylsilyl group are a trimethylsilyl group, triethylsilyl group, tri-n-butylsilyl group, tri-n-octylsilyl group, triisobutylsilyl group, dimethylethylsilyl group, dimethylisopropylsilyl group, dimethyl-n-propylsilyl group, dimethyl-n-butylsilyl group, dimethyl-t-butylsilyl group, diethylisopropylsilyl group, vinyl dimethylsilyl group, propyldimethylsilyl group, and triisopropylsilyl group. Three alkyl groups in the trialkylsilyl group may be mutually the same or different.

Examples of the arylsilyl group having 6 to 30 ring carbon atoms herein include a dialkylarylsilyl group, alkyldiarylsilyl group and triarylsilyl group.

The dialkylarylsilyl group is exemplified by a dialkylarylsilyl group including two alkyl groups selected from the group of the alkyl groups listed as the examples of the alkyl group having 1 to 30 carbon atoms and one aryl group selected from the group of the aryl groups listed as the examples of the aryl group having 6 to 30 ring carbon atoms. The dialkylarylsilyl group preferably has 8 to 30 carbon atoms.

The alkyldiarylsilyl group is exemplified by an alkyldiarylsilyl group including one alkyl group selected from the group of the alkyl groups listed as the examples of the alkyl group having 1 to 30 carbon atoms and two aryl groups selected from the group of the aryl groups listed as the examples of the aryl group having 6 to 30 ring carbon atoms. The alkyldiarylsilyl group preferably has 13 to 30 carbon atoms.

The triarylsilyl group is exemplified by a triarylsilyl group including three aryl groups selected from the group of the examples of the aryl group having 6 to 30 ring carbon atoms. The triarylsilyl group preferably has 18 to 30 carbon atoms.

Herein, an aryl group included in an aralkyl group (occasionally referred to as an arylalkyl group) is an aromatic hydrocarbon group or a heterocyclic group.

Herein, the aralkyl group having 7 to 30 carbon atoms is preferably an aralkyl group including an aryl group having 6 to 30 ring carbon atoms and is represented by —Z₃—Z₄. Z₃ is exemplified by an alkylene group corresponding to the above alkyl group having 1 to 30 carbon atoms. Z₄ is exemplified by the above aryl group having 6 to 30 ring carbon atoms. This aralkyl group is preferably an aralkyl group including an aryl moiety having 6 to 30 carbon atoms, preferably 6 to 20 carbon atoms, more preferably 6 to 12 carbon atoms and an alkyl moiety having 1 to 30 carbon atoms, preferably 1 to 20 carbon atoms, more preferably 1 to 10 carbon atoms, further preferably 1 to 6 carbon atoms. Examples of the aralkyl group include a benzyl group, 2-phenylpropane-2-yl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, and 2-β-naphthylisopropyl group.

Herein, a substituted phosphoryl group is represented by a formula (P) below.

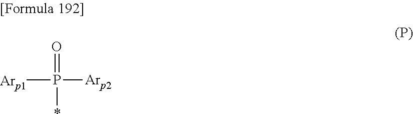

In the above formula (P), Ar_{P1} and Ar_{P2} are preferably each independently a substituent selected from the group consisting of an alkyl group having 1 to 30 carbon atoms and an aryl group having 6 to 30 ring carbon atoms, more preferably a substituent selected from the group consisting of an alkyl group having 1 to 10 carbon atoms and an aryl group having 6 to 20 ring carbon atoms, further preferably a substituent selected from the group consisting of an alkyl group having 1 to 6 carbon atoms and an aryl group having 6 to 14 ring carbon atoms.

Herein, the alkoxy group having 1 to 30 carbon atoms is represented by —OZ₁. Z₁ is exemplified by the above alkyl group having 1 to 30 carbon atoms. Examples of the alkoxy group include a methoxy group, ethoxy group, propoxy group, butoxy group, pentyloxy group and hexyloxy group. The alkoxy group preferably has 1 to 20 carbon atoms.

A halogenated alkoxy group provided by substituting an alkoxy group with a halogen atom is exemplified by one provided by substituting an alkoxy group having 1 to 30 carbon atoms with one or more fluorine atoms.

Herein, an aryl group included in an aryloxy group (occasionally referred to as an arylalkoxy group) also includes a heteroaryl group.

Herein, the arylalkoxy group having 6 to 30 ring carbon atoms is represented by —OZ₂. Z₂ is exemplified by the above aryl group having 6 to 30 ring carbon atoms. The arylalkoxy group preferably has 6 to 20 ring carbon atoms. The arylalkoxy group is exemplified by a phenoxy group.

Herein, a substituted amino group is represented by —NHR_{V} or —N(R_{V})₂. Examples of R_{V} include the above alkyl group having 1 to 30 carbon atoms, the above aryl group having 6 to 30 ring carbon atoms, and the above heteroaryl group having 5 to 30 ring atoms.

Herein, an alkylthio group having 1 to 30 carbon atoms and an arylthio group having 6 to 30 ring carbon atoms are represented by —SR_{V}. Examples of R_{V} include the above alkyl group having 1 to 30 carbon atoms and the above aryl group having 6 to 30 ring carbon atoms. The alkythio group preferably has 1 to 20 carbon atoms, and the arylthio group has 6 to 20 ring carbon atoms.

Herein, examples of the halogen atom include a fluorine atom, chlorine atom, bromine tom and iodine atom, among which a fluorine atom is preferable.

Herein, “carbon atoms forming a ring (ring carbon atoms)” mean carbon atoms forming a saturated ring, unsaturated ring, or aromatic ring. “Atoms forming a ring (ring atoms)” mean carbon atoms and hetero atoms forming a hetero ring including a saturated ring, unsaturated ring, and aromatic ring.

Herein, a hydrogen atom includes isotope having different numbers of neutrons, specifically, protium, deuterium and tritium.

Herein, a substituent when referring to the “substituted or unsubstituted” is at least one group selected from the group consisting of an aryl group having 6 to 30 ring carbon atoms, heteroaryl group having 5 to 30 ring atoms, (linear or branched) alkyl group having 1 to 30 carbon atoms, cycloalkyl group having 3 to 30 ring carbon atoms, alkyl halide group having 1 to 30 carbon atoms, alkylsilyl group having 3 to 30 carbon atoms, arylsilyl group having 6 to 30 ring carbon atoms, alkoxy group having 1 to 30 carbon atoms, aryloxy group having 6 to 30 carbon atoms, substituted amino group, alkylthio group having 1 to 30 carbon atoms, arylthio group having 6 to 30 ring carbon atoms, aralkyl group having 7 to 30 carbon atoms, (linear or branched) alkenyl group having 2 to 30 carbon atoms, halogen atom, alkynyl group having 2 to 30 carbon atoms, cyano group, hydroxyl group, nitro group, and carboxy group.

Herein, the substituent when referring to the “substituted or unsubstituted” is preferably at least one group selected from the group consisting of an aryl group having 6 to 30 ring carbon atoms, heteroaryl group having 5 to 30 ring atoms, (linear or branched) alkyl group having 1 to 30 carbon atoms, halogen atom, and cyano group, more preferably, the specific examples of the substituent that are rendered preferable in the description of each of the substituents.

Herein, the substituent when referring to the “substituted or unsubstituted” may be further substituted by at least one group selected from the group consisting of an aryl group having 6 to 30 ring carbon atoms, heteroaryl group having 5 to 30 ring atoms, (linear or branched) alkyl group having 1 to 30 carbon atoms, cycloalkyl group having 3 to 30 carbon atoms, alkyl halide group having 1 to 30 carbon atoms, alkylsilyl group having 3 to 30 carbon atoms, arylsilyl group having 6 to 30 ring carbon atoms, alkoxy group having 1 to 30 carbon atoms, aryloxy group having 6 to 30 carbon atoms, substituted amino group, alkylthio group having 1 to 30 carbon atoms, arylthio group having 6 to 30 ring carbon atoms, aralkyl group having 7 to 30 carbon atoms, alkenyl group having 2 to 30 carbon atoms, alkynyl group having 2 to carbon atoms, halogen atom, cyano group, hydroxyl group, nitro group, and carboxy group. In addition, plural ones of these substituents may be mutually bonded to form a ring.

Herein, a substituent further substituting the substituent when referring to the “substituted or unsubstituted” is preferably at least one group selected from the group consisting of an aryl group having 6 to 30 ring carbon atoms, heteroaryl group having 5 to 30 ring atoms, (linear or branched) alkyl group having 1 to 30 carbon atoms, halogen atom, and cyano group, more preferably the specific examples of the substituent that are rendered preferable in the description of each of the substituents.

“Unsubstituted” in “substituted or unsubstituted” means that a group is not substituted by the above-described substituents but bonded with a hydrogen atom.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of a substituted ZZ group.

Herein, “XX to YY atoms” in the description of “substituted or unsubstituted ZZ group having XX to YY atoms” represent atoms of an unsubstituted ZZ group and does not include atoms of a substituent(s) of a substituted ZZ group.

The same as the above applies to “substituted or unsubstituted” as for a compound or a partial structure thereof described herein.

Herein, when substituents are mutually bonded to form a ring, the structure of the ring is a saturated ring, unsaturated ring, aromatic hydrocarbon ring, or a heterocyclic ring.

Herein, examples of the aromatic hydrocarbon group and the heterocyclic group in the linking group include divalent or higher-valent groups obtained by removing at least one atom from the above monovalent groups.

The organic EL device according to the first exemplary embodiment emits light with high efficiency.

Further, luminous efficiency of the organic EL device of the first exemplary embodiment is improvable especially in a blue wavelength region.

### Electronic Device

The organic EL device 1 according to the first exemplary embodiment of the invention is usable in an electronic device such as a display unit and a light-emitting unit. Examples of the display unit include display components such as an organic EL panel module, TV, mobile phone, tablet, and personal computer. Examples of the light-emitting unit include an illuminator and a vehicle light.

### Second Exemplary Embodiment

An arrangement of an organic EL device according to a second exemplary embodiment will be described below. In the description of the second exemplary embodiment, the same components as those in the first exemplary embodiment are denoted by the same reference signs and names to simplify or omit an explanation of the components. In the second exemplary embodiment, the same materials and compounds as described in the first exemplary embodiment are usable, unless otherwise specified.

The organic EL device according to the second exemplary embodiment is different from the organic EL device according to the first exemplary embodiment in that the emitting layer further contains a third compound. Other components are the same as those in the first exemplary embodiment.

### Third Compound

A singlet energy S₁(M3) of the third compound and the singlet energy S₁(M1) of the first compound preferably satisfy a relationship of a numerical formula (Numerical Formula 2) below.

S₁(M3)>S₁(M1) (Numerical Formula 2).

The third compound may be a compound exhibiting delayed fluorescence or a compound exhibiting no delayed fluorescence.

The third compound is also preferably a host material (occasionally referred to as a matrix material). When the first compound and the third compound are the host materials, one of the compounds may be referred to as a first host material and the other of the compounds may be referred to as a second host material.

The third compound is not particularly limited, but is preferably a compound other than an amine compound. For instance, a carbazole derivative, dibenzofuran derivative and dibenzothiophene derivative are usable as the third compound. However, the third compound is not limited thereto.

The third compound preferably has at least one of a partial structure represented by a formula (31) below, a partial structure represented by a formula (32), a partial structure represented by a formula (33), and a partial structure represented by a formula (34) below in one molecule.

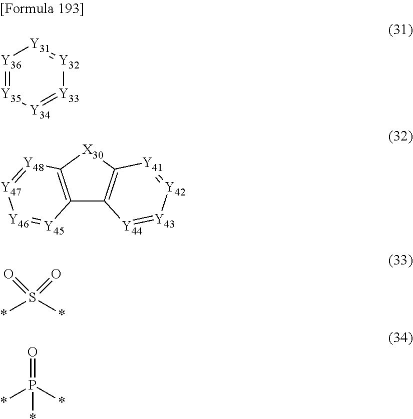

In the formula (31): Y₃₁ to Y₃₆ each independently represent a nitrogen atom or a carbon atom bonded to another atom in the molecule of the third compound, where at least one of Y₃₁ to Y₃₆ is a carbon atom bonded to another atom in the molecule of the third compound.

In the formula (32): Y₄₁ to Y₄₈ each independently represent a nitrogen atom or a carbon atom bonded to another atom in the molecule of the third compound, where at least one of Y₄₁ to Y₄₈ is a carbon atom bonded to another atom in the molecule of the third compound.

X₃₀ is a nitrogen atom bonded to another atom in the molecule of the third compound, or an oxygen atom or a sulfur atom.

* in the formulae (33) to (34) each independently represent a bonding position with another atom or another structure in the molecule of the third compound.

In the organic EL device of the second exemplary embodiment, the third compound preferably has at least one of the partial structure represented by the formula (31) and the partial structure represented by the formula (32) in one molecule.

In the organic EL device of the second exemplary embodiment, X₃₀ in the formula (32) is preferably a nitrogen atom or an oxygen atom.

In the organic EL device of the second exemplary embodiment, the third compound is more preferably a compound having the partial structure represented by the formula (32), a partial structure represented by a formula (3a) below, and a partial structure represented by a formula (3b) below.

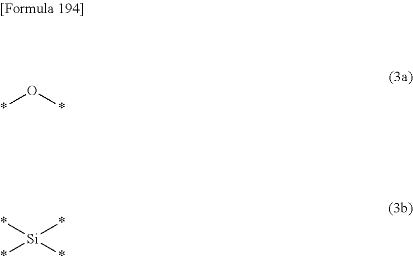

* in the formulae (3a) and (3b) each independently represent a bonding position with another atom or another structure in the molecule of the third compound.

In the organic EL device of the second exemplary embodiment, at least two of Y₄₁ to Y₄₈ in the formula (32) are preferably carbon atoms bonded to other atoms in the molecule of the third compound; and a cyclic structure including the carbon atoms is preferably formed.

For instance, the partial structure represented by the formula (32) is preferably a partial structure selected from the group consisting of partial structures represented by formulae (321), (322), (323), (324), (325) and (326) below.

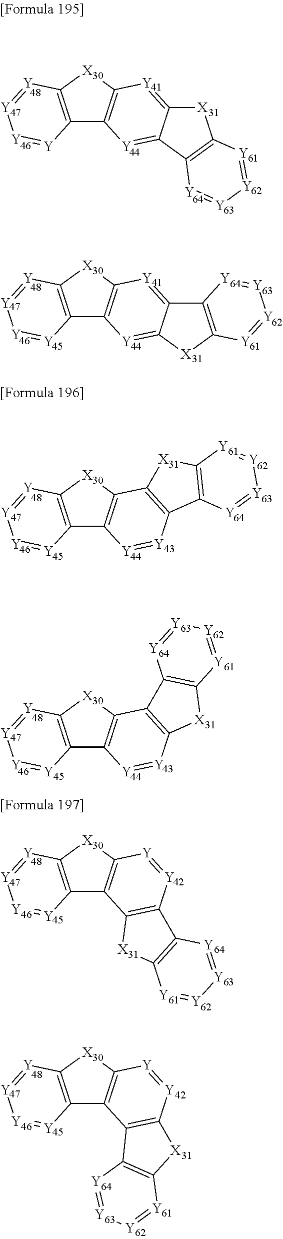

In the formulae (321) to (326): X₃₀ are each independently a nitrogen atom bonded to another atom in the molecule of the third compound, or an oxygen atom or a sulfur atom;

Y₄₁ to Y₄₈ each independently represent a nitrogen atom or a carbon atom bonded to another atom in the molecule of the third compound;

X₃₁ are each independently a nitrogen atom bonded to another atom in the molecule of the third compound, an oxygen atom, a sulfur atom or a carbon atom bonded to another atom in the molecule of the third compound; and

Y₆₁ to Y₆₄ each independently represent a nitrogen atom or a carbon atom bonded to another atom in the molecule of the third compound.

In the second exemplary embodiment, the third compound preferably includes the partial structure represented by the formula (323) among the formulae (321) to (326).

The partial structure represented by the formula (31) is in a form of at least one group selected from the group consisting of groups represented by formulae (31a) and (31b) below and is preferably contained in the third compound.

The third compound preferably includes at least one of the partial structure represented by the formula (31a) and the partial structure represented by the formula (31b). For the third compound, bonding positions are preferably both situated in meta positions as in the partial structures represented by the formulae (31a) and (31b) in order to keep a high energy gap T_{77K}(M3) at 77 [K].

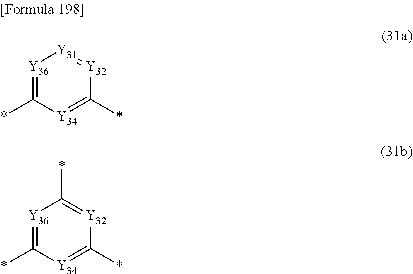

In the formula (31a), Y₃₁, Y₃₂, Y₃₄, and Y₃₆ are each independently a nitrogen atom or CR₃₁.

In the formula (31b), Y₃₂, Y₃₄, and Y₃₆ are each independently a nitrogen atom or CR₃₁.

In the above formulae (31a) and (31b): R₃₁ is each independently a hydrogen atom or a substituent;

R₃₁ serving as the substituent is each independently a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted or unsubstituted silyl group, a substituted germanium group, a substituted phosphine oxide group, a halogen atom, a cyano group, a nitro group, and a substituted or unsubstituted carboxy group,

with a proviso that the substituted or unsubstituted aryl group having 6 to 30 ring carbon atoms in R₃₁ is preferably a non-fused ring.

* in the formulae (31a) and (31b) each independently represent a bonding position with another atom or another structure in the molecule of the third compound.

In the formula (31a), Y₃₁, Y₃₂, Y₃₄ and Y₃₆ are preferably each independently CR₃₁, a plurality of R₃₁ being mutually the same or different.

Further, in the formula (31b), Y₃₂, Y₃₄ and Y₃₆ are preferably each independently CR₃₁, a plurality of R₃₁ being mutually the same or different.

The substituted germanium group is preferably represented by —Ge(R₃₀₁)₃. R₃₀₁ are each independently a substituent. The substituent R₃₀₁ is preferably a group selected from the group consisting of a substituted or unsubstituted alkyl group having 1 to 30 carbon atoms or a substituted or unsubstituted aryl group having 6 to 30 ring carbon atoms. A plurality of R₃₀₁ are mutually the same or different.

The partial structure represented by the formula (32) is preferably contained in the third compound in the form of at least one group selected from the group consisting of groups represented by formulae (35) to (39) and (30a) below.

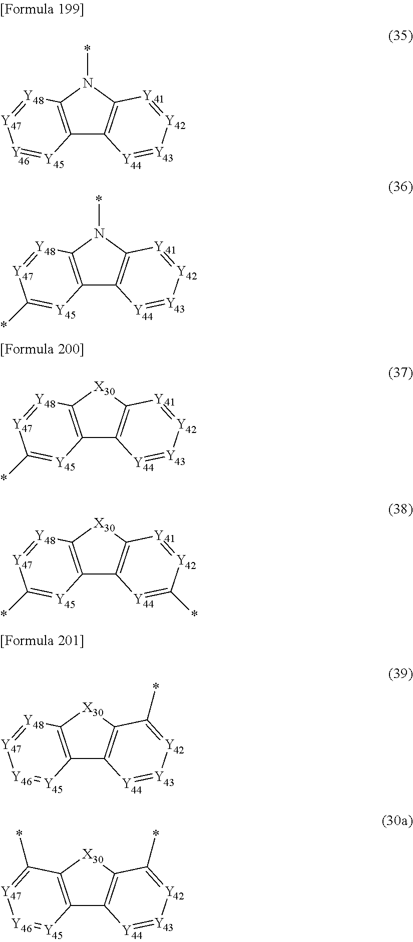

In the formula (359), Y₄₁ to Y₄₈ each independently represent a nitrogen atom or CR₃₂.

In the formulae (36) and (37), Y₄₁ to Y₄₅, Y₄₇, and Y₄₈ each independently represent a nitrogen atom or CR₃₂.

In the formula (38), Y₄₁, Y₄₂, Y₄₄, Y₄₅; Y₄₇, and Y₄₈ each independently represent a nitrogen atom or CR₃₂.

In the formula (39), Y₄₂ to Y₄₈ each independently represent a nitrogen atom or CR₃₂.

In the formula (30a), Y₄₂ to Y₄₇ each independently represent a nitrogen atom or CR₃₂.

In the above formulae (35) to (39) and (30a): R₃₂ is each independently a hydrogen atom or a substituent;

R₃₂ serving as the substituent is selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted or unsubstituted silyl group, a substituted germanium group, a substituted phosphine oxide group, a halogen atom, a cyano group, a nitro group, and a substituted or unsubstituted carboxy group; and

a plurality of R₃₂ are mutually the same or different.

* in the formulae (35) and (36) each independently represent a bonding position with another atom or another structure in the molecule of the third compound.

In the above formulae (37) to (39) and (30a): X₃₀ represents NR₃₃, an oxygen atom or a sulfur atom;

R₃₃ is a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted or unsubstituted silyl group, a substituted germanium group, a substituted phosphine oxide group, a fluorine atom, a cyano group, a nitro group, and a substituted or unsubstituted carboxy group; and

a plurality of R₃₃ are mutually the same or different, where the substituted or unsubstituted aryl group having 6 to 30 ring carbon atoms in R₃₃ is preferably a non-fused ring.

* in the formulae (35) to (39) and (30a) each independently represent a bonding position with another atom or another structure in the molecule of the third compound.

In the formula (35), Y₄₁ to Y₄₈ are each independently preferably CR₃₂. In the formulae (36) and (37), Y₄₁ to Y₄₅, Y₄₇ and Y₄₈ are each independently preferably CR₃₂. In the formula (38), Y₄₁, Y₄₂, Y₄₄, Y₄₅, Y₄₇ and Y₄₈ are each independently preferably CR₃₂. In the formula (39), Y₄₂ to Y₄₈ are each independently preferably CR₃₂. In the formula (30a), Y₄₂ to Y₄₇ are each independently preferably CR₃₂. A plurality of R₃₂ may be mutually the same or different.

In the third compound, X₃₀ is preferably an oxygen atom or a sulfur atom, more preferably an oxygen atom.

In the third compound, R₃₁ and R₃₂ each independently represent a hydrogen atom or a substituent. R₃₁ and R₃₂ serving as the substituents are preferably each independently a group selected from the group consisting of a fluorine atom, a cyano group, a substituted or unsubstituted alkyl group having 1 to 30 carbon atoms, a substituted or unsubstituted aryl group having 6 to 30 ring carbon atoms, and a substituted or unsubstituted heteroaryl group having to 30 ring atoms. R₃₁ and R₃₂ are more preferably a hydrogen atom, a cyano group, a substituted or unsubstituted aryl group having 6 to 30 ring carbon atoms, or a substituted or unsubstituted heteroaryl group having 5 to 30 ring atoms. When R₃₁ and R₃₂ serving as the substituents are each a substituted or unsubstituted aryl group having 6 to 30 ring carbon atoms, the aryl group is preferably a non-fused ring.

The third compound is also preferably an aromatic hydrocarbon compound or an aromatic heterocyclic compound. The third compound preferably contains no fused aromatic hydrocarbon ring in a molecule.

### Method of Manufacturing Third Compound

The third compound can be manufactured by methods disclosed in International Publication No. WO2012/153780, International Publication No. WO2013/038650, and the like. Moreover, the third compound can be exemplarily manufactured with use of a known alternative reaction and a starting material depending on a target object.

Examples of the substituent for the third compound are shown below, but the invention is not limited thereto.

Specific examples of the aryl group (occasionally referred to as an aromatic hydrocarbon group) include a phenyl group, tolyl group, xylyl group, naphthyl group, phenanthryl group, pyrenyl group, chrysenyl group, benzo[c]phenanthryl group, benzo[g]chrysenyl group, benzoanthryl group, triphenylenyl group, fluorenyl group, 9,9-dimethylfluorenyl group, benzofluorenyl group, dibenzofluorenyl group, biphenyl group, terphenyl group, quarterphenyl group and fluoranthenyl group, among which a phenyl group, biphenyl group, terphenyl group, quarterphenyl group, naphthyl group, triphenylenyl group and fluorenyl group are preferable.

Specific examples of the aryl group having a substituent include a tolyl group, xylyl group and 9,9-dimethylfluorenyl group.

As is understood from the specific examples, the aryl group includes both fused aryl group and non-fused aryl group.

Preferable examples of the aryl group include a phenyl group, biphenyl group, terphenyl group, quarterphenyl group, naphthyl group, triphenylenyl group and fluorenyl group.

Specific examples of the aromatic heterocyclic group (occasionally referred to as a heteroaryl group, heteroaromatic ring group or heterocyclic group) include a pyrrolyl group, pyrazolyl group, pyrazinyl group, pyrimidinyl group, pyridazynyl group, pyridyl group, triazinyl group, indolyl group, isoindolyl group, imidazolyl group, benzimidazolyl group, indazolyl group, imidazo[1,2-a]pyridinyl group, furyl group, benzofuranyl group, isobenzofuranyl group, dibenzofuranyl group, azadibenzofuranyl group, thiophenyl group, benzothienyl group, dibenzothienyl group, azadibenzothienyl group, quinolyl group, isoquinolyl group, quinoxalinyl group, quinazolinyl group, naphthyridinyl group, carbazolyl group, azacarbazolyl group, phenanthridinyl group, acridinyl group, phenanthrolinyl group, phenazinyl group, phenothiazinyl group, phenoxazinyl group, oxazolyl group, oxadiazolyl group, furazanyl group, benzoxazolyl group, thienyl group, thiazolyl group, thiadiazolyl group, benzothiazolyl group, triazolyl group and tetrazolyl group, among which a dibenzofuranyl group, dibenzothienyl group, carbazolyl group, pyridyl group, pyrimidinyl group, triazinyl group, azadibenzofuranyl group and azadibenzothienyl group are preferable.

Preferable examples of the heteroaryl group include a dibenzofuranyl group, dibenzothienyl group, carbazolyl group, pyridyl group, pyrimidinyl group, triazinyl group, azadibenzofuranyl group or azadibenzothienyl group. Further preferable examples of the heteroaryl group include a dibenzofuranyl group, dibenzothienyl group, azadibenzofuranyl group and azadibenzothienyl group.

In the third compound, the substituted silyl group is also preferably a group selected from the group consisting of a substituted or unsubstituted trialkylsilyl group, a substituted or unsubstituted arylalkylsilyl group, and a substituted or unsubstituted triarylsilyl group.

Specific examples of the substituted or unsubstituted trialkylsilyl group include trimethylsilyl group and triethylsilyl group.

Specific examples of the substituted or unsubstituted arylalkylsilyl group include diphenylmethylsilyl group, ditolylmethylsilyl group, and phenyldimethylsilyl group.

Specific examples of the substituted or unsubstituted triarylsilyl group include triphenylsilyl group and tritolylsilyl group.

In the third compound, the substituted phosphine oxide group is also preferably a substituted or unsubstituted diarylphosphine oxide group.

Specific examples of the substituted or unsubstituted diaryl phosphine oxide group include a diphenyl phosphine oxide group and ditolyl phosphine oxide group.

In the third compound, a substituted carboxy group is exemplified by a benzoyloxy group.

Specific examples of the third compound of the second exemplary embodiment are shown below. It should be noted that the third compound according to the invention is not limited to these specific examples.

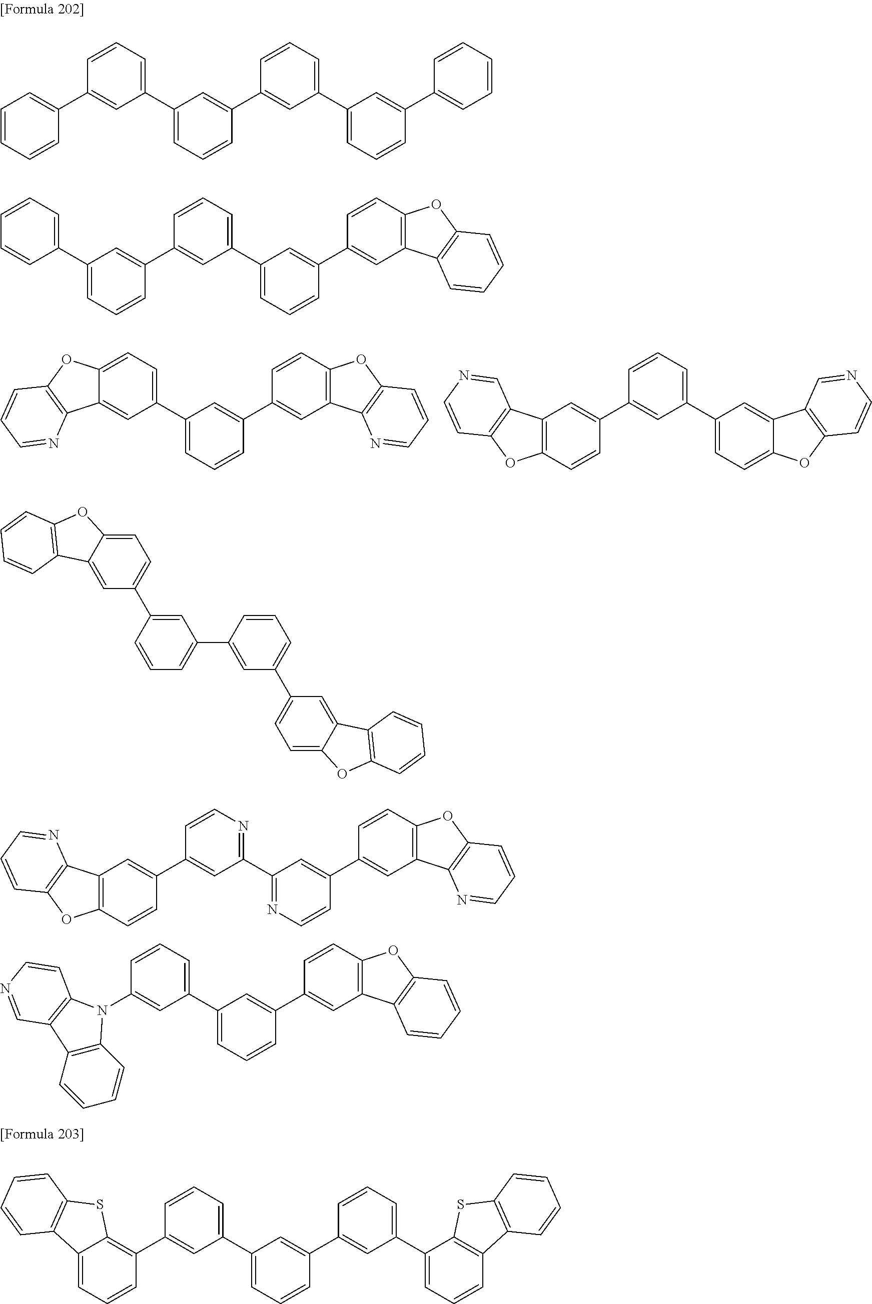

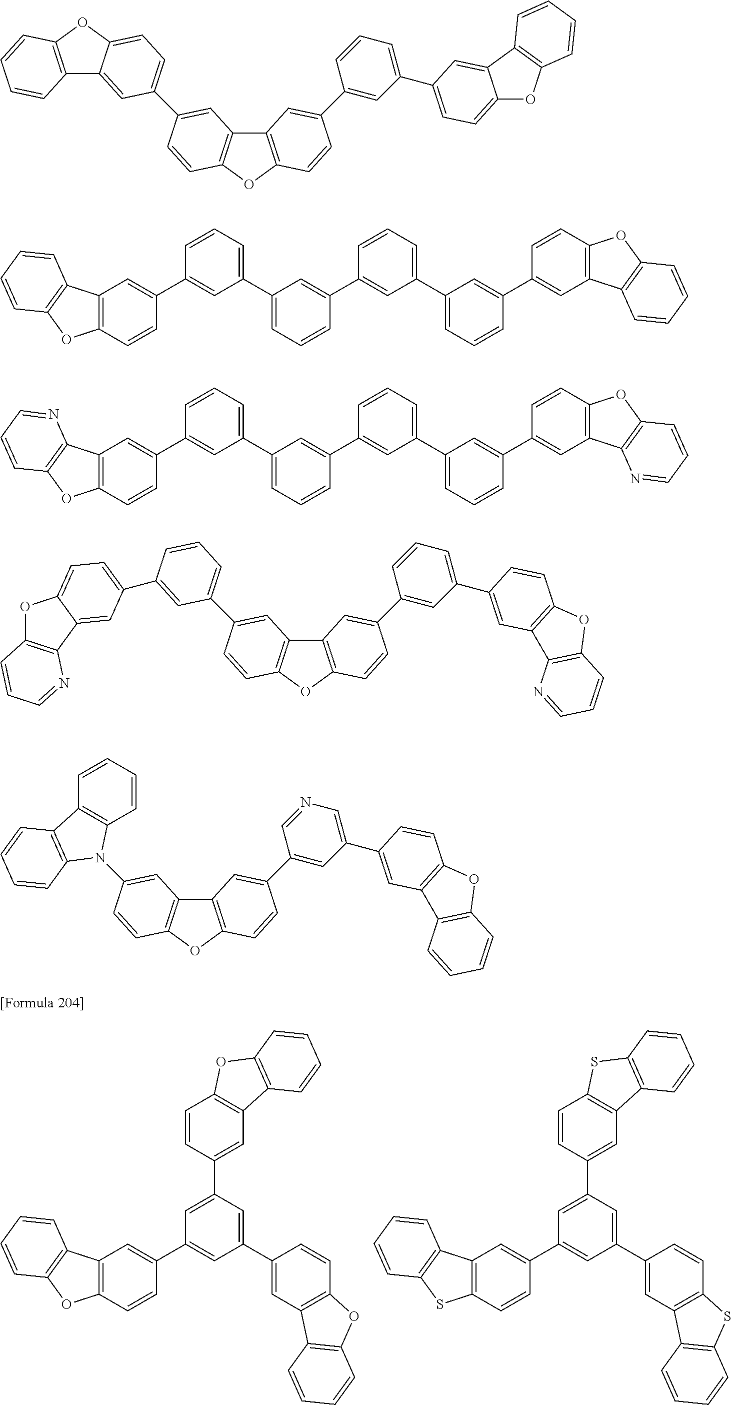

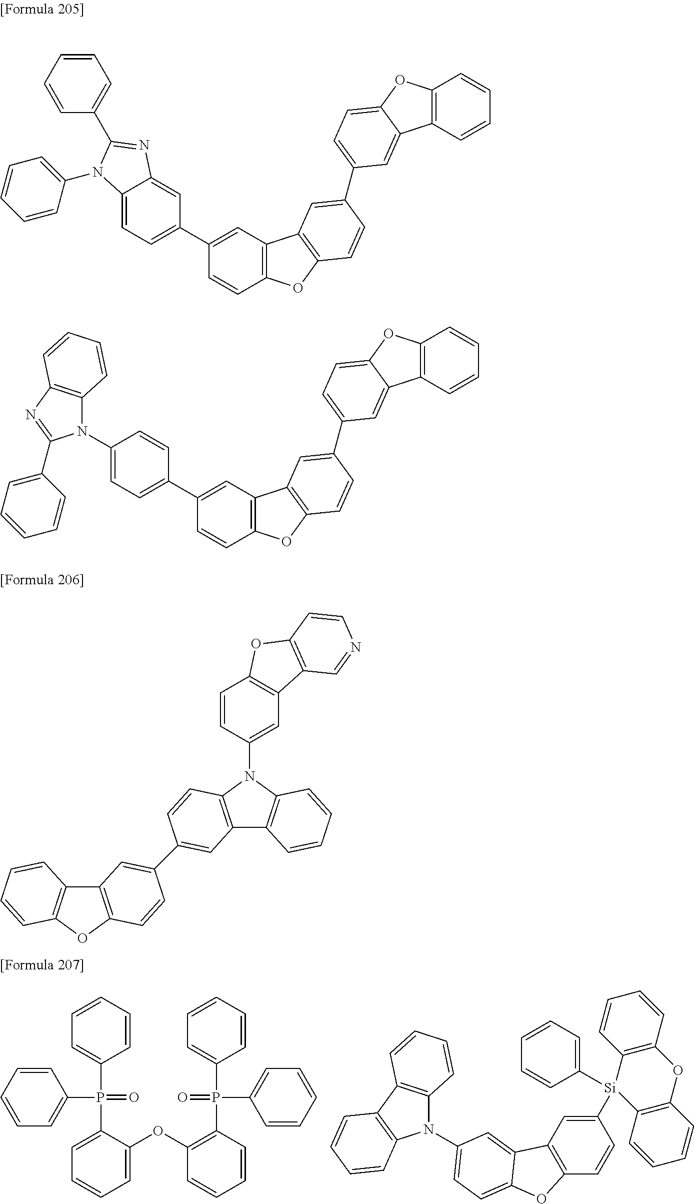

### Relationship Between First Compound, Second Compound and Third Compound in Emitting Layer

The first compound, the second compound, and the third compound in the emitting layer preferably satisfy the relationships represented by the above numerical formulae (Numerical Formulae 1 and 2). Specifically, a relationship represented by a numerical formula below (Numerical Formula 3) is preferably satisfied.

S₁(M3)>S₁(M1)>S₁(M2) (Numerical Formula 3)

The energy gap T_{77K}(M3) at 77 [K] of the third compound is preferably larger than the energy gap T_{77K}(M1) at 77 [K] of the first compound. Specifically, a relationship represented by a numerical formula below (Numerical Formula 5) is preferably satisfied.

T_{77K}(M3)>T_{77K}(M1) (Numerical Formula 5)

The energy gap T_{77K}(M3) at 77 [K] of the third compound is preferably larger than the energy gap T_{77K}(M2) at 77 [K] of the second compound. Specifically, a relationship represented by a numerical formula below (Numerical Formula 6) is preferably satisfied.

T_{77K}(M3)>T_{77K}(M2) (Numerical Formula 6)

The first compound, the second compound, and the third compound in the emitting layer preferably satisfy the relationships represented by the numerical formulae (Numerical Formulae 4 and 5). Specifically, a relationship represented by a numerical formula below (Numerical Formula 7) is preferably satisfied.

T_{77K}(M3)>T_{77K}(M1)>T_{77K}(M2) (Numerical Formula 7)

When the organic EL device in the second exemplary embodiment emits light, it is preferable that the second compound mainly emits light in the emitting layer.

### Content Ratio of Compounds in Emitting Layer

A content ratio between the first compound, the second compound and the third compound in the emitting layer is preferably in an exemplary range below.

The content ratio of the first compound is preferably in a range from 10 mass % to 80 mass %, more preferably in a range from 10 mass % to 60 mass %, further preferably in a range from 20 mass % to 60 mass %.

The content ratio of the second compound is preferably in a range from 0.01 mass % to 10 mass %, more preferably in a range from 0.01 mass % to 5 mass %, further preferably in a range from 0.01 mass % to 1 mass %.

A content ratio of the third compound is preferably in a range from 10 mass % to 80 mass %.

An upper limit of a total content ratio of the first compound, second compound and third compound in the emitting layer is 100 mass %. It should be noted that the emitting layer of the second exemplary embodiment may further contain material(s) other than the first, second and third compounds.

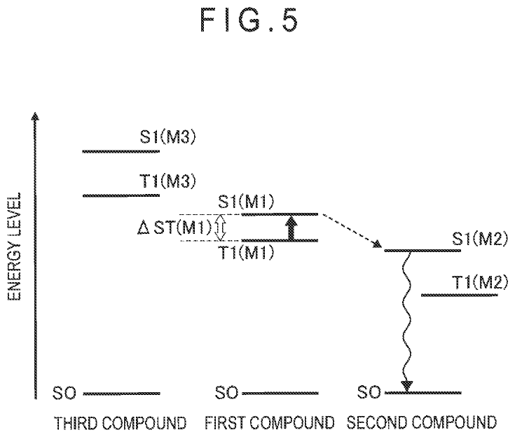

FIG. 5 shows an example of a relationship between energy levels of the first, second and third compounds in the emitting layer. In FIG. 5, S0 represents a ground state. S1(M1) represents the lowest singlet state of the first compound. T1(M1) represents the lowest triplet state of the first compound. S1(M2) represents the lowest singlet state of the second compound. T1(M2) represents the lowest triplet state of the second compound. S1(M3) represents the lowest singlet state of the third compound. T1(M3) represents the lowest triplet state of the third compound. A dashed arrow directed from S1(M1) to S1(M2) in FIG. 5 represents Förster energy transfer from the lowest singlet state of the first compound to the lowest singlet state of the second compound.

As shown in FIG. 5, when a compound having a small ΔST(M1) is used as the first compound, inverse intersystem crossing from the lowest triplet state T1(M1) to the lowest singlet state S1(M1) can be caused by a heat energy. Accordingly, Förster energy transfer from the lowest singlet state S1(M1) of the first compound to the second compound is caused to generate the lowest singlet state S1(M2). As a result, fluorescence from the lowest singlet state S1(M2) of the second compound is observable. It is inferred that the internal quantum efficiency can be theoretically raised up to 100% also by using delayed fluorescence by the TADF mechanism.

The organic EL device according to the second exemplary embodiment emits light with high efficiency.

Further, luminous efficiency of the organic EL device of the second exemplary embodiment is improvable especially in a blue wavelength region.

The emitting layer of the organic EL device according to the second exemplary embodiment includes the delayed fluorescent first compound, the fluorescent second compound, and the third compound having a larger singlet energy than the first compound, whereby the luminous efficiency of the organic EL device is improved. It is inferred that the luminous efficiency is improved because the carrier balance of the emitting layer is improved by containing the third compound. In the organic EL device of the second exemplary embodiment, the second compound may be a delayed fluorescent compound.

The organic EL device according to the second exemplary embodiment is usable in an electronic device such as a display unit and a light-emitting unit as in the organic EL device according to the first exemplary embodiment.

### Modification of Embodiments

It should be noted that the invention is not limited to the above exemplary embodiments but may include any modification and improvement as long as such modification and improvement are compatible with the invention.

The emitting layer is not limited to a single layer. In some embodiments, the emitting layer is provided in a form of a laminate of a plurality of emitting layers. When the organic EL device has a plurality of emitting layers, it is only required that at least one of the emitting layers satisfies the conditions described in the above exemplary embodiments. For instance, in some embodiments, the rest of the emitting layers is a fluorescent emitting layer or a phosphorescent emitting layer using emission by electronic transition from the triplet state directly to the ground state.

When the organic EL device includes the plurality of emitting layers, in some embodiments, the plurality of emitting layers are adjacent to each other, or provide a so-called tandem-type organic EL device in which a plurality of emitting units are layered through an intermediate layer.

For instance, a blocking layer is provided in contact with at least one of an anode-side and a cathode-side of the emitting layer in some embodiments. It is preferable that the blocking layer is adjacent to the emitting layer and blocks at least one of holes, electrons and excitons.

For instance, when the blocking layer is provided in contact with the cathode-side of the emitting layer, the blocking layer permits transport of electrons, but prevents holes from reaching a layer provided near the cathode (e.g., the electron transporting layer) beyond the blocking layer. When the organic EL device includes the electron transporting layer, the blocking layer is preferably interposed between the emitting layer and the electron transporting layer.

When the blocking layer is provided in contact with the emitting layer near the anode, the blocking layer permits transport of holes, but prevents electrons from reaching a layer provided near the anode (e.g., the hole transporting layer) beyond the blocking layer. When the organic EL device includes the hole transporting layer, the blocking layer is preferably interposed between the emitting layer and the hole transporting layer.

Further, a blocking layer may be provided in contact with the emitting layer to prevent an excitation energy from leaking from the emitting layer into a layer in the vicinity thereof. Excitons generated in the emitting layer are prevented from moving into a layer provided near the electrode (e.g., the electron transporting layer and the hole transporting layer) beyond the blocking layer.

The emitting layer and the blocking layer are preferably bonded to each other.

Specific structure and shape of the components in the present invention may be designed in any manner as long as an object of the present invention can be achieved.

### EXAMPLES

Examples of the invention will be described below. However, the invention is by no means limited by these Examples.

### Compounds

Compounds used for preparing the organic EL device are shown below.

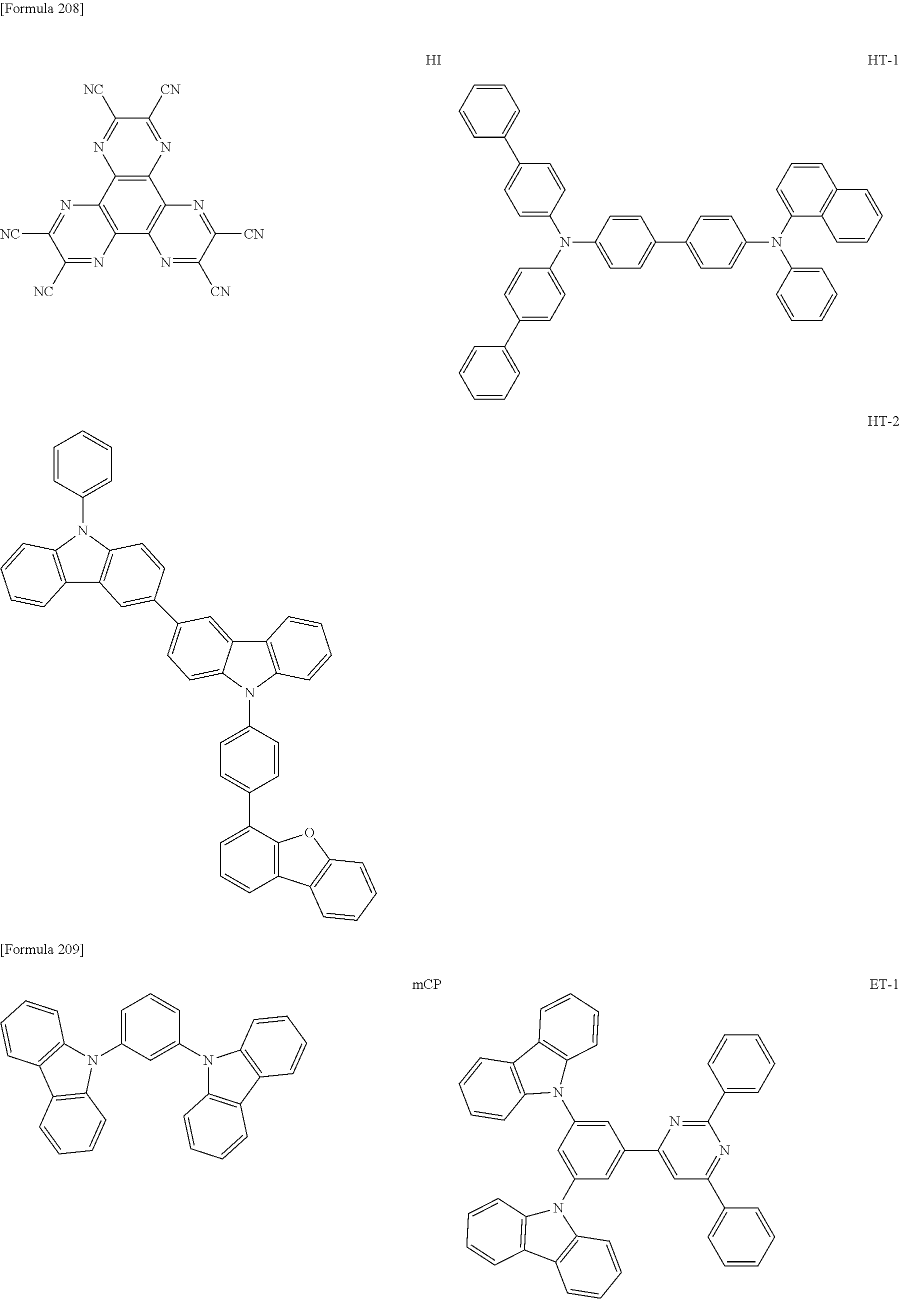 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccccc5)c5cccc6ccccc56)cc4)cc3)cc2)cc1 ; c1ccc(-n2c3ccccc3c3cc(-c4ccc5c(c4)c4ccccc4n5-c4ccc(-c5cccc6c5oc5ccccc56)cc4)ccc32)cc1 ; c1cc(-n2c3ccccc3c3ccccc32)cc(-n2c3ccccc3c3ccccc32)c1 ; c1ccc(-c2cc(-c3cc(-n4c5ccccc5c5ccccc54)cc(-n4c5ccccc5c5ccccc54)c3)nc(-c3ccccc3)n2)cc1]

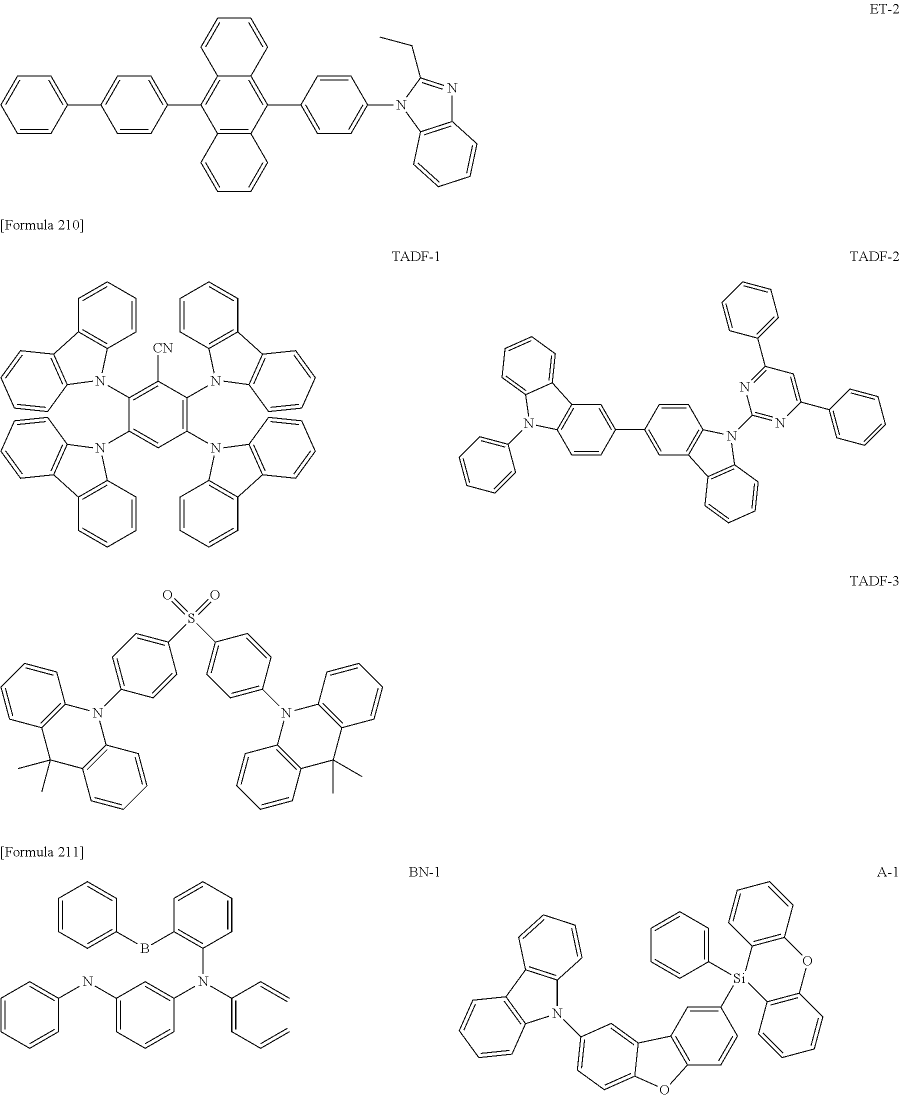

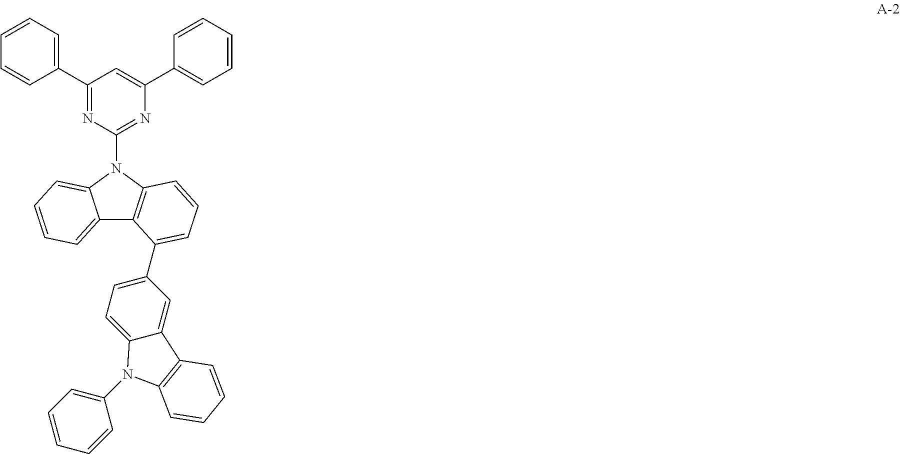 [SMILES: c1ccc(-c2cc(-c3ccccc3)nc(-n3c4ccccc4c4c(-c5ccc6c(c5)c5ccccc5n6-c5ccccc5)cccc43)n2)cc1]

### Evaluation of Compounds

A method of measuring properties of the compounds is described below.

### Delayed Fluorescence

Occurrence of delayed fluorescence was determined by measuring transient PL (PhotoLuminescence) using a device shown in FIG. 2. A sample was prepared by co-depositing the compound TADF-1 and the compound TH-2 on a quartz substrate at a ratio of the compound TADF-1 of 12 mass % to form a 100-nm-thick thin film. Emission from the compound TADF-1 include: Prompt emission observed immediately when the excited state is achieved by exciting the compound TADF-1 with a pulse beam (i.e., a beam emitted from a pulse laser unit) having an absorbable wavelength; and Delayed emission observed not immediately when but after the excited state is achieved. When the amount of Prompt emission is denoted by X_{P} and the amount of Delayed emission is denoted by X_{D}, the delayed fluorescence in Examples means that a value of X_{D}/X_{P} is 0.05 or more.

It was found that the value of X_{D}/X_{P} in the compound TADF-1 was 0.05 or more. The transient PL of each of the samples prepared using the compounds TADF-2 and TADF-3 was measured in the same manner as the above. It was then found that the value of X_{D}/X_{P} was 0.05 or more.

The amount of Prompt emission and the amount of Delayed emission can be obtained through the same method as a method described in “Nature 492, 234-238, 2012.” A device used for calculating the amounts of Prompt Emission and Delayed Emission is not limited to the device of FIG. 2 and a device described in the above document.

### Singlet Energy S₁

The singlet energy S₁ of each of the compounds TADF-1, TADF-2, TADF-3, BN-1, A-1, and A-2 was measured through the above-described solution method.

The singlet energy S₁ of the compound TADF-1 was 2.9 eV.

The singlet energy S₁ of the compound TADF-2 was 3.0 eV.

The singlet energy S₁ of the compound TADF-3 was 3.0 eV.

The singlet energy S₁ of the compound BN-1 was 2.7 eV.

The singlet energy S₁ of the compound A-1 was 3.5 eV.

The singlet energy S₁ of the compound A-2 was 3.1 eV.

### Main Peak Wavelength of Compounds

A toluene, in which the measurement target compound was dissolved at a concentration in a range from 10⁻⁶ mol/L to 10⁻⁵ mol/L, was prepared and the emission spectrum of the toluene solution was measured. In the emission spectrum, a peak wavelength of the emission spectrum at the maximum luminous intensity was defined as a main peak wavelength.

The main peak wavelength of the compound BN-1 was 452 nm.

### Preparation of Organic EL Device

Organic EL devices were prepared in the following manner and evaluated.

### Example 1

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes. A film of ITO was 130 nm thick.

After the glass substrate having the transparent electrode line was cleaned, the glass substrate was mounted on a substrate holder of a vacuum vapor-deposition apparatus. Initially, a compound HI was vapor-deposited on a surface of the glass substrate where the transparent electrode line was provided in a manner to cover the transparent electrode, thereby forming a 5-nm-thick hole injecting layer.

Next, the compound HT-1 was vapor-deposited on the hole injecting layer to form an 80-nm-thick first hole transporting layer on the HI film.

Subsequently, the compound HT-2 was vapor-deposited on the first hole transporting layer to form a 10-nm-thick second hole transporting layer.

Further, a compound mCP was vapor-deposited on the second hole transporting layer to form a 5-nm-thick third hole transporting layer.

Next, the compound TADF-1 (the first compound), the compound BN-1 (the second compound) and the compound A-1 (the third compound) were co-deposited on the third hole transporting layer to form a 25-nm-thick emitting layer. In the emitting layer, the concentrations of the compounds TADF-1, BN-1 and A-1 were 24 mass %, 1 mass % and 75 mass %, respectively.

The compound ET-1 was then vapor-deposited on the emitting layer to form a 5-nm-thick first electron transporting layer.

The compound ET-2 was then vapor-deposited on the first electron transporting layer to form a 20-nm-thick second electron transporting layer.

Next, lithium fluoride (LiF) was vapor-deposited on the second electron transporting layer to form a 1-nm-thick electron injecting electrode (cathode).

A metal aluminum (Al) was then deposited on the electron injecting electrode to form an 80-nm-thick metal Al cathode.

A device arrangement of the organic EL device in Example 1 is schematically shown as follows.

ITO (130)/HI (5)/HT-1 (80)/HT-2 (10)/mCP (5)/A-1:TADF-1:BN-1 (25, 75%:24%:1%)/ET-1 (5): ET-2 (20)/LiF (1)/Al (80)

Numerals in parentheses represent a film thickness (unit: nm). The numerals represented by percentage in parentheses indicate a ratio (mass %) of the first, second and third compounds in the emitting layer.

### Example 2

An organic EL device of Example 2 was prepared in the same manner as the organic EL device of Example 1 except that the concentration of the compound TADF-1 was determined at 99 mass %, the concentration of the compound BN-1 was determined at 1 mass %, and the compound A-1 was not used in the emitting layer of Example 1.

A device arrangement of the organic EL device in Example 2 is schematically shown as follows.

ITO (130)/HI (5)/HT-1 (80)/HT-2 (10)/mCP (5)/TADF-1:BN-1 (25, 99%:1%)/ET-1 (5): ET-2 (20)/LiF (1)/Al (80)

### Example 3

An organic EL device of Example 3 was prepared in the same manner as the organic EL device of Example 1 except that the compound TADF-2 was used in place of the compound TADF-1 and the compound A-2 was used in place of the compound A-1 in the emitting layer of Example 1.

A device arrangement of the organic EL device in Example 3 is schematically shown as follows.

ITO (130)/HI (5)/HT-1 (80)/HT-2 (10)/mCP (5)/A-2:TADF-2:BN-1 (25, 75%:24%:1%)/ET-1 (5): ET-2 (20)/LiF (1)/Al (80)

### Comparative 1

An organic EL device of Comparative 1 was prepared in the same manner as the organic EL device of Example 1 except that the concentration of the compound A-1 was determined at 99 mass %, the concentration of the compound BN-1 was determined at 1 mass %, and the compound TADF-1 was not used in the emitting layer of Example 1.

A device arrangement of the organic EL device of Comparative 1 is schematically shown as follows.

ITO (130)/HI (5)/HT-1 (80)/HT-2 (10)/mCP (5)/A-1:BN-1 (25, 99%:1%)/ET-1 (5): ET-2 (20)/LiF (1)/Al (80)

### Comparative 2

An organic EL device of Comparative 2 was prepared in the same manner as the organic EL device of Example 1 except that a compound TADF-3 was used in place of the compound TADF-1 in the emitting layer of Example 1.

A device arrangement of the organic EL device of Comparative 2 is schematically shown as follows.

ITO (130)/HI (5)/HT-1 (80)/HT-2 (10)/mCP (5)/A-1:TADF-3:BN-1 (25, 75%:24%:1%)/ET-1 (5): ET-2 (20)/LiF (1)/Al (80)

### Comparative 3

An organic EL device of Comparative 3 was prepared in the same manner as the organic EL device of Comparative 1 except that the compound mCP was used in place of the compound A-1, the concentration of the compound mCP was determined at 99 mass %, and the concentration of the compound BN-1 was determined at 1 mass % in the emitting layer of Comparative 1.

A device arrangement of the organic EL device of Comparative 3 is schematically shown as follows.

ITO (130)/HI (5)/HT-1 (80)/HT-2 (10)/mCP (5)/mCP:BN-1 (25, 99%:1%)/ET-1 (5): ET-2 (20)/LiF (1)/Al (80)

### Evaluation 1 of Organic EL Devices

The prepared organic EL devices of Examples 1 to 3 and Comparatives 1 to 3 were evaluated as follows. The evaluation results are shown in Table 1.

### External Quantum Efficiency EQE and Main Peak Wavelength λp

Voltage was applied on each of the organic EL devices such that a current density was 10 mA/cm², where spectral radiance spectra were measured by a spectroradiometer (CS-1000 manufactured by Konica Minolta, Inc.).

The external quantum efficiency EQE (unit: %) was calculated based on the obtained spectral-radiance spectra, assuming that the spectra was provided under a Lambertian radiation.

Voltage was applied on each of the organic EL devices such that a current density was 0.1 mA/cm², where spectral radiance spectrum was measured by the spectroradiometer (CS-1000 manufactured by Konica Minolta, Inc.) and a main peak wavelength λp (unit: nm) was calculated from the obtained spectral radiance spectrum.

TABLE 1

| | EQE | λ p |
|---|---|---|
| | [%] | [nm] |
| EXAMPLE 1 | 12.25 | 457 |
| EXAMPLE 2 | 7.88 | 461 |
| EXAMPLE 3 | 5.70 | 461 |
| COMPARATIVE 1 | 2.56 | 457 |
| COMPARATIVE 2 | 2.10 | 457 |
| COMPARATIVE 3 | 1.98 | 457 |

The organic EL devices of Examples 1 to 3, which contained the first compound and second compound represented by the formula (2) in the emitting layer, exhibited improved luminous efficiency in the high-current-density area as compared with the organic EL devices of Comparatives 1 to 3.

### Evaluation 2 of Organic EL Devices

The prepared organic EL devices of Examples 1 and 3 and Comparative 2 were evaluated as follows. The evaluation results are shown in Table 2.

### Lifetime LT95 and Lifetime LT50

A continuous direct-current test was conducted on the organic EL devices at an initial current density of 10 mA/cm², where a time elapsed before a luminance intensity was reduced to 95% of the initial luminance intensity and a time elapsed before a luminance intensity was reduced to 50% of the initial luminance intensity were measured and were defined as lifetime LT95 (unit: hr.) and LT50 (unit: hr.), respectively.

TABLE 2

| | LT95 | LT50 |
|---|---|---|
| | [hrs] | [hrs] |
| EXAMPLE 1 | 0.7 | 10.4 |
| EXAMPLE 3 | 0.9 | 19.7 |
| COMPARATIVE 2 | <0.1 | 1.0 |

As shown in Table 2, it was determined that the lifetime of the organic EL devices of Examples 1 and 3 was longer than the lifetime of the organic EL device of Comparative 2.

### EXPLANATION OF CODES

1 . . . organic EL device, 2 . . . substrate, 3 . . . anode, 4 . . . cathode, 5 . . . emitting layer, 6 . . . hole injecting layer, 7 . . . hole transporting layer, 8 . . . electron transporting layer, 9 . . . electron injecting layer

1: An organic electroluminescence device, comprising:
an anode;
an emitting layer; and
a cathode, wherein
the emitting layer comprises a first compound and a second compound,
the first compound is a thermally activated delayed fluorescent compound,
a singlet energy S₁(M1) of the first compound and a singlet energy S₁(M2) of the second compound satisfy a relationship of Numerical Formula 1:
S₁(M1)>S₁(M2) (Numerical Formula 1),
the first compound is compound represented by a formula (1): 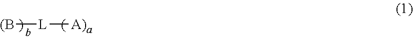
wherein A is a group having a partial structure selected from formulae (a-1) to (a-2): 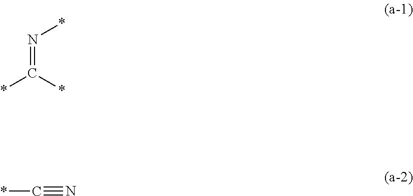
B is a group having a partial structure selected from formulae (b-1) to (b-4): 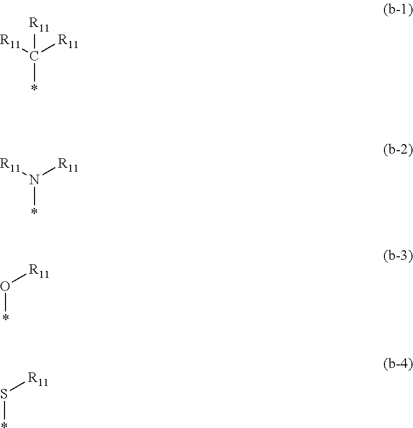
wherein R₁₁ is each independently a hydrogen atom or a substituent;
R₁₁ serving as the substituent is a group selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms;
when a plurality of R₁₁ are present, the plurality of R₁₁ are mutually the same or different, and are mutually bonded to form a ring or not bonded to form no ring,
L is a single bond or a linking group;
L serving as the linking group is a group derived from a group selected from the group consisting of a substituted or unsubstituted aryl group having 6 to 30 ring carbon atoms, a substituted or unsubstituted heteroaryl group having 5 to 30 ring atoms, and a group formed by mutually bonding two to five of the above aryl and/or heteroaryl groups, where the mutually bonded groups are the same or different;
a is an integer in a range from 1 to 5 and represents the number of A directly bonded to L;
when a is an integer in a range from 2 to 5, the plurality of A are mutually the same or different;
b is an integer in a range from 1 to 5 and represents the number of B directly bonded to L; and
when b is an integer in a range from 2 to 5, the plurality of B are mutually the same or different, and
the second compound is a compound represented by a formula (2): 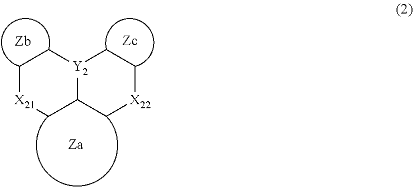
wherein Za ring, Zb ring and Zc ring are each independently a cyclic structure selected from the group consisting of a substituted or unsubstituted aryl ring having 6 to 30 ring carbon atoms, and a substituted or unsubstituted heteroaryl ring having 5 to 30 ring atoms;
X₂₁ and X₂₂ are each independently an oxygen atom, NRa, or a sulfur atom;
when X₂₁ is NRa, Ra is bonded to Za ring or Zb ring to form a ring or is not bonded to form no ring;
when X₂₂ is NRa, Ra is bonded to Za ring or Zc ring to form a ring or is not bonded to form no ring;
Ra is each independently a group selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms;
Y₂ is any one of a boron atom, a phosphorus atom, SiRb, P═O, or P═S; and
Rb is each independently a group selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms.

2: The organic electroluminescence device according to claim 1, wherein
the second compound is a compound represented by a formula (2A): 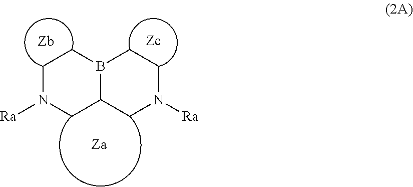
wherein Za ring, Zb ring, Zc ring, and Ra represent the same as Za ring, Zb ring, Zc ring, and Ra in the formula (2), respectively.

3: The organic electroluminescence device according to claim 1, wherein
the second compound is a compound represented by a formula (21): 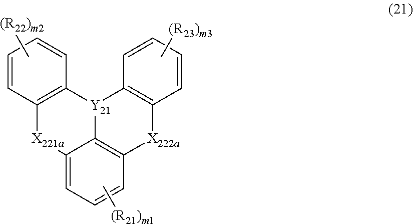
wherein X₂₂₁ₐ and X₂₂₂ₐ, which are mutually the same, are any one of oxygen atoms, NRa, and sulfur atoms;
m1 is 3, and each of m2 and m3 is 4;
R₂₁ to R₂₃ are each independently a hydrogen atom or a substituent;
R₂₁ to R₂₃ serving as the substituents are each independently a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted aryloxy group having 6 to 30 ring carbon atoms, a substituted or unsubstituted amino group, and a substituted silyl group; and
Y₂₁ represents the same as Y₂ in the formula (2).

4: The organic electroluminescence device according to claim 3, wherein
the second compound is a compound represented by a formula (21A): 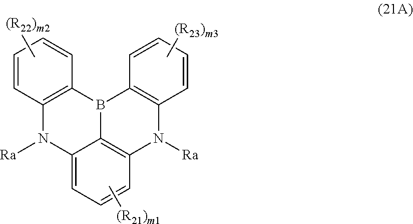
wherein Ra, m1 to m3, and R₂₁ to R₂₃ represent the same as Ra, m1 to m3, and R₂₁ to R₂₃ in the formula (21), respectively.

5: The organic electroluminescence device according to claim 1, wherein Ra is a substituted or unsubstituted aryl group having 6 to 30 ring carbon atoms.

6: The organic electroluminescence device according to to claim 1, wherein Ra is a substituted or unsubstituted phenyl group.

7: The organic electroluminescence device according to claim 1,
wherein Ra in the formula (2) is not bonded to any of Za ring and Zb ring to form no ring, and Ra in the formula (2) is not bonded to any of Za ring and Zc ring to form no ring.

8: The organic electroluminescence device according to claim 1, wherein the second compound is a thermally activated delayed fluorescent compound.

9: The organic electroluminescence device according to claim 1, wherein when the organic electroluminescence device emits light, the second compound emits light in the emitting layer.

10: The organic electroluminescence device according to claim 1, wherein the first compound is a compound represented by a formula (11A): 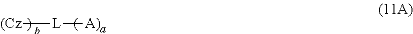
wherein A, L, a, and b respectively represent the same as A, L, a, and b in the formula (1); and
Cz is a group represented by a formula (11a): 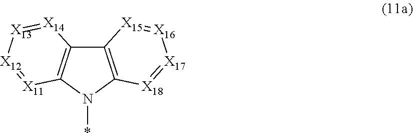
wherein X₁₁ to X₁₈ are each independently a nitrogen atom or CRx;
Rx is each independently a hydrogen atom or a substituent;
Rx serving as the substituent is a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxyl group;
a plurality of Rx are mutually the same or different;
when a plurality of ones of X₁₁ to X₁₈ are CRx and Rx are substituents, Rx are bonded to each other to form a ring, or are not bonded to form no ring; and
* represents a bonding position to a carbon atom of the group represented by L or A in the formula (11A).

11: The organic electroluminescence device according to claim 10, wherein
the first compound is a compound represented by a formula (11B):
Cz-Az (11B)
wherein Cz represents the same as Cz in the formula (11A); and
Az is a cyclic structure selected from the group consisting of a substituted or unsubstituted pyridine group, a substituted or unsubstituted pyrimidine group, a substituted or unsubstituted triazine group, and a substituted or unsubstituted pyrazine group.

12: The organic electroluminescence device according to claim 10, wherein
the first compound is a compound represented by a formula (11E): 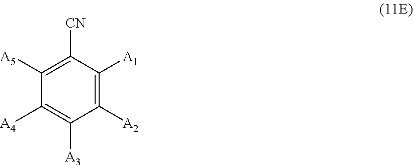
wherein A₁ to A₅ are each independently a hydrogen atom or a substituent; and
A₁ to A₅ serving as the substituents are each independently a group selected from the group consisting of a cyano group, a substituted or unsubstituted aryl group having 6 to 30 ring carbon atoms, and a substituted or unsubstituted heteroaryl group having 5 to 30 ring atoms,
with a proviso that at least one of A₁ to A₅ is a group represented by the formula (11a).

13: The organic electroluminescence device according to claim 1, wherein
the emitting layer further comprises a third compound, and
the third compound has at least one of a partial structure represented by a formula (31), a partial structure represented by a formula (32), a partial structure represented by a formula (33), or a partial structure represented by a formula (34) in one molecule: 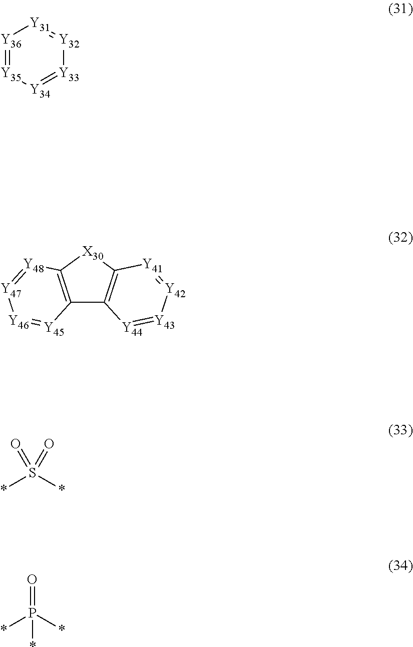
wherein Y₃₁ to Y₃₆ each independently represent a nitrogen atom or a carbon atom bonded to another atom in the molecule of the third compound, at least one of Y₃₁ to Y₃₆ being the carbon atom bonded to another atom in the molecule of the third compound,
Y₄₁ to Y₄₈ each independently represent a nitrogen atom or a carbon atom bonded to another atom in the molecule of the third compound, at least one of Y₄₁ to Y₄₈ being the carbon atom bonded to another atom in the molecule of the third compound; and
X₃₀ is a nitrogen atom bonded to another atom in the molecule of the third compound, or an oxygen atom or a sulfur atom, and
* each independently represent a bonding position with another atom or another structure in the molecule of the third compound.

14: The organic electroluminescence device according to claim 13, wherein
X₃₀ in the formula (32) is a nitrogen atom or an oxygen atom.

15: The organic electroluminescence device according to claim 13, wherein
a singlet energy S₁(M1) of the first compound and a singlet energy S₁(M3) of the third compound satisfy a relationship of Numerical Formula 2:
S₁(M3)>S₁(M1) (Numerical Formula 2).

16: The organic electroluminescence device according to claim 1, further comprising:
a hole transporting layer between the anode and the emitting layer.

17: The organic electroluminescence device according to claim 1, further comprising:
an electron transporting layer between the cathode and the emitting layer.

18: An electronic device, comprising
the organic electroluminescence device according to claim 1.
